(19) United States
(12) Patent Application Publication
(10) Pub. No.: US 2025/0380610 A1
(43) Pub. Date: Dec. 11, 2025

(54) ORGANIC ELECTROLUMINESCENT MATERIAL AND DEVICE

(71) Applicant: BEIJING SUMMER SPROUT TECHNOLOGY CO., LTD., Beijing (CN)

(72) Inventors: Zheng Wang, Beijing (CN); Hongbo Li, Beijing (CN); Zhen Wang, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/226,975

(22) Filed: Jun. 3, 2025

(30) Foreign Application Priority Data
Jun. 7, 2024 (CN) 202410740173.0
Dec. 17, 2024 (CN) 202411862929.5

(51) Int. Cl. H10K 85/30; C07B 59/00; C07F 15/00; C09K 11/02; C09K 11/06; H10K 50/12; H10K 85/60; H10K 101/00

(52) U.S. Cl. CPC H10K 85/342; C07B 59/004; C07F 15/0033; C09K 11/02; C09K 11/06; H10K 85/654; H10K 85/6572; H10K 85/6574; C07B 2200/05; C09K 2211/1007; C09K 2211/1029; C09K 2211/1088; C09K 2211/185; H10K 50/12; H10K 2101/90

(57) ABSTRACT

Provided is a metal complex comprising a ligand La having a structure of Formula 1. The metal complex may be used as a charge transport material, a light-emitting material and a host material in an electroluminescent device. These new metal complexes can provide better device performance and, in particular, have apparent advantages in aspects such as CE, PE and EQE and achieve an object of effectively adjusting emitted colors, thereby better improving the overall performance of the electroluminescent devices. Further provided are an electroluminescent device and a compound combination. These electroluminescent devices or compound combinations comprise the metal complex and have relatively good application prospects.

### CROSS-REFERENCE TO RELATED APPLICATION(S)

This application claims priority to Chinese Patent Application No. 202410740173.0 filed Jun. 7, 2024, and Chinese Patent Application No. 202411862929.5 filed Dec. 17, 2024, the disclosure of which are incorporated herein by reference in their entireties.

### TECHNICAL FIELD

The present disclosure relates to compounds for organic electronic devices such as organic light-emitting devices. More particularly, the present disclosure relates to a metal complex comprising a ligand La having a structure of Formula 1 and an electroluminescent device and compound combination comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron transport layer and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN115710290A (or U.S. patent family US20230189629A1) discloses a metal complex. The metal complex comprises a ligand structure shown in the following structure:

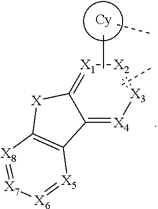

Moreover, the application discloses the following metal complex:

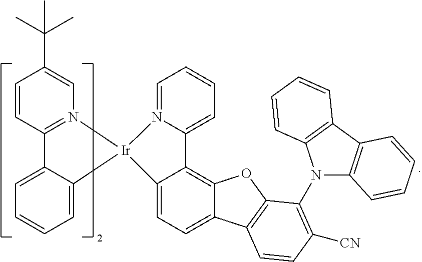

However, the application has neither disclosed nor taught an ortho-substituent with a particular structure on the ring Cy and an effect on device performance when X₄ is substituted.

The present disclosure provides a new metal complex comprising a ligand La having a structure of Formula 1. The metal complex may be used as a charge transport material, a light-emitting material and a host material in an electroluminescent device. These new metal complexes can provide better device performance.

### SUMMARY

The present disclosure aims to provide a series of new metal complexes (compounds) each comprising a ligand La having a structure of Formula 1 to solve at least part of the above-mentioned problems. The metal complexes may be used as light-emitting materials in organic electroluminescent devices. These new metal complexes can provide better device performance.

According to an embodiment of the present disclosure, disclosed is a metal complex; the metal complex comprises a metal M and a ligand La coordinated to the metal M;
wherein the metal M is selected from a metal with a relative atomic mass greater than 40, and La has a structure represented by Formula 1:

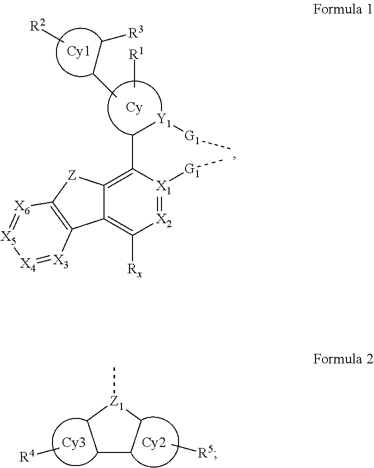

wherein,
G₁ is, at each occurrence identically or differently, selected from a single bond, O or S;
X₁ is, at each occurrence identically or differently, selected from C or N and joined to the metal M through G₁;
X₂ to X₆ are, at each occurrence identically or differently, selected from CRₓ′ or N;
Y₁ is, at each occurrence identically or differently, selected from C or N and joined to the metal M through G₁;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
the ring Cy is, at each occurrence identically or differently, selected from an aromatic ring having 6 to 24 ring atoms which comprises Y₁, a heteroaromatic ring having 5 to 24 ring atoms which comprises Y₁ or a combination thereof;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R², R⁴ and R⁵ represent, at each occurrence identically or differently, mono-substitution, multiple substitutions or non-substitution;
in the ring Cy, at least one R¹ is adjacent to the ring Cy1;
in the ring Cy1, R³ is adjacent to the ring Cy;
R¹, R², R³, R⁴, R⁵, R′, Rₓ′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₃ to X₆ is selected from CRₓ′, and Rₓ′ has, at each occurrence identically or differently, a structure of Formula 2; at least one of X₃ to X₆ is selected from CRₓ′, and Rₓ′ is selected from cyano or fluorine;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R², R³, R⁴ and R⁵ can be optionally joined to form a ring; and
“- - -” represents a joining position.

According to another embodiment of the present disclosure, further disclosed is use of the metal complex in an electroluminescent device.

According to another embodiment of the present disclosure, further disclosed is an electroluminescent device comprising an anode, a cathode and an organic layer disposed between the anode and the cathode, wherein the organic layer comprises the metal complex comprising the ligand La having the structure of Formula 1.

According to another embodiment of the present disclosure, further disclosed is a compound combination comprising the metal complex comprising the ligand La having the structure of Formula 1.

The new metal complexes disclosed in the present disclosure may be used as light-emitting materials in electroluminescent devices. These new metal complexes can provide better device performance and, in particular, have apparent effects and advantages in aspects such as CE, PE and EQE and achieve the effective adjustment of emitted colors, thereby better improving the overall performance of the electroluminescent devices.

### BRIEF DESCRIPTION OF DRAWINGS

FIG. 1 is a schematic diagram of an organic light-emitting device that may comprise a compound and a compound combination disclosed herein.

FIG. 2 is a schematic diagram of another organic light-emitting device that may comprise a compound and a compound combination disclosed herein.

### DETAILED DESCRIPTION

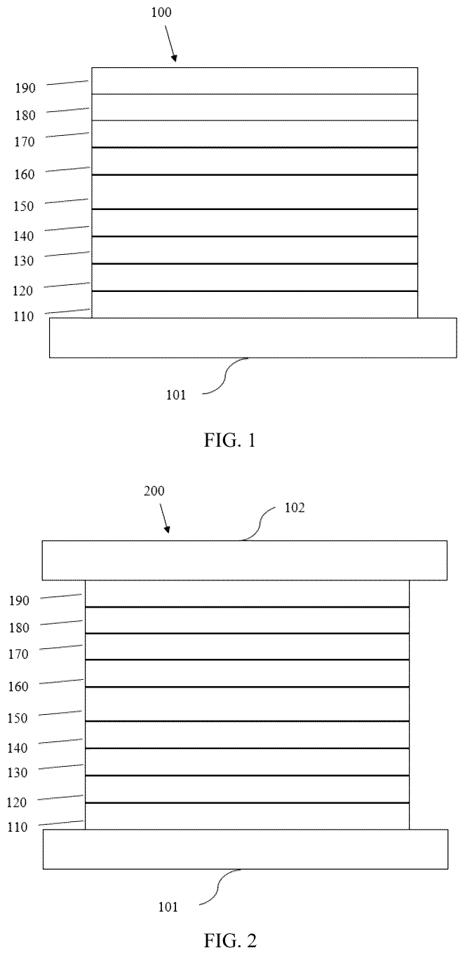

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly on the exterior of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group or an aromatic ring—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocyclyl—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or a heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolopyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, substituted carboxylic acid group, substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refers to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

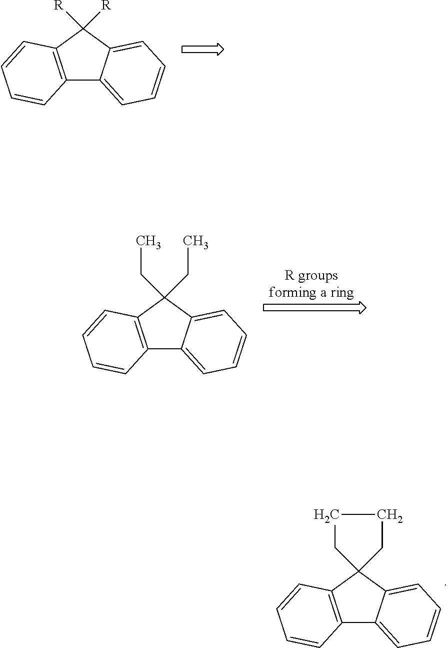

The expression that adjacent substituents can be optionally joined to form a ring is also intended to mean that two substituents bonded to carbon atoms which are directly bonded to each other are joined to each other via a chemical bond to form a ring, which can be exemplified by the following formula:

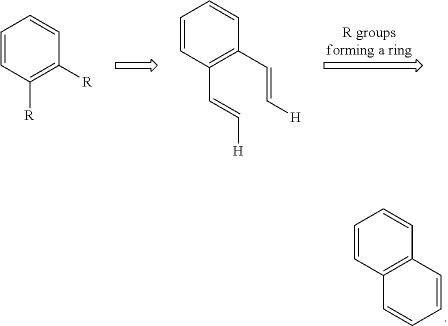

The expression that adjacent substituents can be optionally joined to form a ring is also intended to mean that two substituents bonded to further distant carbon atoms are joined to each other via a chemical bond to form a ring, which can be exemplified by the following formula:

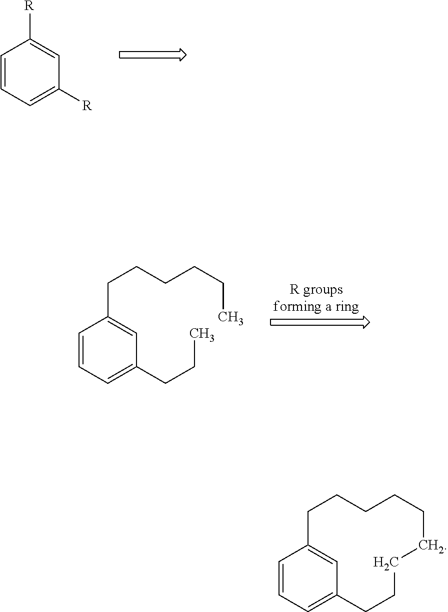

Furthermore, the expression that adjacent substituents can be optionally joined to form a ring is also intended to mean that, in the case where one of the two adjacent substituents represents hydrogen, the second substituent is bonded at a position at which the hydrogen atom is bonded, thereby forming a ring. This is exemplified by the following formula:

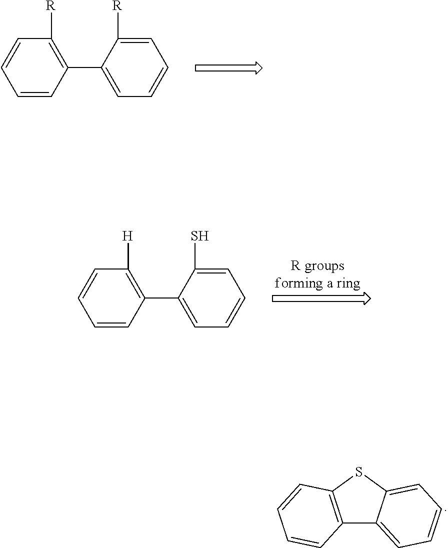

According to an embodiment of the present disclosure, disclosed is a metal complex; the metal complex comprises a metal M and a ligand La coordinated to the metal M;
wherein the metal M is selected from a metal with a relative atomic mass greater than 40, and La has a structure represented by Formula 1:

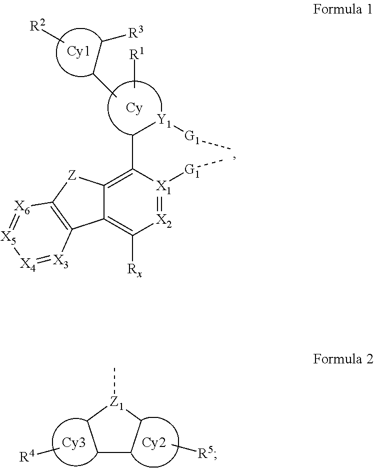

wherein,
G₁ is, at each occurrence identically or differently, selected from a single bond, O or S;
X₁ is, at each occurrence identically or differently, selected from C or N and joined to the metal M through G₁;
X₂ to X₆ are, at each occurrence identically or differently, selected from CRₓ′ or N;
Y₁ is, at each occurrence identically or differently, selected from C or N and joined to the metal M through G₁;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
the ring Cy is, at each occurrence identically or differently, selected from an aromatic ring having 6 to 24 ring atoms which comprises Y₁, a heteroaromatic ring having 5 to 24 ring atoms which comprises Y₁ or a combination thereof;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R², R⁴ and R⁵ represent, at each occurrence identically or differently, mono-substitution, multiple substitutions or non-substitution;
in the ring Cy, at least one R¹ is adjacent to the ring Cy1;
in the ring Cy1, R³ is adjacent to the ring Cy;
R¹, R², R³, R⁴, R⁵, R′, Rₓ′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₃ to X₆ is selected from CRₓ′, and Rₓ′ has, at each occurrence identically or differently, a structure of Formula 2; at least one of X₃ to X₆ is selected from CRₓ′, and Rₓ′ is selected from cyano or fluorine;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R², R³, R⁴ and R⁵ can be optionally joined to form a ring; and
“- - -” represents a joining position.

In the present disclosure, the expression that “in the ring Cy, at least one R¹ is adjacent to the ring Cy1” means that in the ring Cy, at least one R¹ and the ring Cy1 are at ortho positions, that is, at least one R¹ and the ring Cy1 are ortho-groups in the ring Cy.

R¹ represents, at each occurrence identically or differently, mono-substitution, multiple substitutions or non-substitution;
when R¹ represents mono-substitution, in the ring Cy, R¹ is adjacent to the ring Cy1; and
when R¹ represents multiple substitutions, in the ring Cy, at least one R¹ is adjacent to the ring Cy1, and remaining R¹ are adjacent to or not adjacent to the ring Cy1.

In the present disclosure, the expression that “in the ring Cy1, R³ is adjacent to the ring Cy” means that in the ring Cy1, R³ and the ring Cy are at ortho positions, that is, R³ and the ring Cy are ortho-groups in the ring Cy1.

In the present disclosure, the expression that “adjacent substituents R², R³, R⁴ and R⁵ can be optionally joined to form a ring” is intended to mean that any one or more of groups of adjacent substituents, such as two substituents R², two substituents R⁴, two substituents R⁵, substituents R² and R³, and substituents R⁴ and R⁵, can be joined to form a ring. Obviously, it is also possible that none of these substituents are joined to form a ring.

According to an embodiment of the present disclosure, at least one of X₅ and X₆ is selected from CRₓ′, and Rₓ′ has, at each occurrence identically or differently, the structure of Formula 2.

According to an embodiment of the present disclosure, X₆ is selected from CRₓ′, and Rₓ′ has, at each occurrence identically or differently, the structure of Formula 2.

According to an embodiment of the present disclosure, at least one of X₅ and X₆ is selected from CRₓ′, and Rₓ′ is selected from cyano or fluorine.

According to an embodiment of the present disclosure, X₅ is selected from CRₓ′, and Rₓ′ is selected from cyano or fluorine.

According to an embodiment of the present disclosure, disclosed is a metal complex; the metal complex comprises a metal M and a ligand La coordinated to the metal M, wherein the metal M is selected from a metal with a relative atomic mass greater than 40, and La has a structure represented by Formula 1-a:

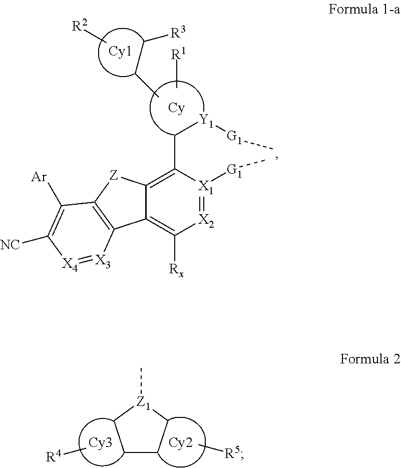

wherein,
Ar has, at each occurrence identically or differently, a structure of Formula 2;
G₁ is, at each occurrence identically or differently, selected from a single bond, O or S;
X₁ is, at each occurrence identically or differently, selected from C or N and joined to the metal M through G₁;
X₂, X₃ and X₄ are, at each occurrence identically or differently, selected from CRₓ′ or N, and Y₁ is, at each occurrence identically or differently, selected from C or N and joined to the metal M through G₁;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
the ring Cy is, at each occurrence identically or differently, selected from an aromatic ring having 6 to 24 ring atoms which comprises Y₁, a heteroaromatic ring having 5 to 24 ring atoms which comprises Y₁ or a combination thereof;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R², R⁴ and R⁵ represent, at each occurrence identically or differently, mono-substitution, multiple substitutions or non-substitution;
in the ring Cy, at least one R¹ is adjacent to the ring Cy1;
in the ring Cy1, R³ is adjacent to the ring Cy;
R¹, R², R³, R⁴, R⁵, R′, Rₓ′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R², R³, R⁴ and R⁵ can be optionally joined to form a ring; and
“- - -” represents a joining position.

According to an embodiment of the present disclosure, the ring Cy is, at each occurrence identically or differently, selected from a heteroaromatic ring having 5 to 24 ring atoms which comprises Y₁, wherein Y₁ is selected from C or N, preferably N; the ring Cy1, the ring Cy2 and the ring Cy3 are, at each occurrence identically or differently, selected from substituted or unsubstituted aromatic ring having 6 to 24 ring atoms.

According to an embodiment of the present disclosure, the ring Cy, the ring Cy1, the ring Cy2 and the ring Cy3 are, at each occurrence identically or differently, selected from the group consisting of: a pyrrole ring, a furan ring, a thiophene ring, an imidazole ring, a pyrazole ring, a thiazole ring, an oxazole ring, a benzene ring, a pyridine ring, a pyrazine ring, a pyridazine ring, a pyrimidine ring, a triazine ring, an indole ring, a benzimidazole ring, a benzofuran ring, a benzothiophene ring, a benzothiazole ring, a benzoxazole ring, a dibenzofuran ring, a dibenzothiophene ring, a carbazole ring and a pyridoindole ring.

According to an embodiment of the present disclosure, the ring Cy1, the ring Cy2 and the ring Cy3 are, at each occurrence identically or differently, selected from the group consisting of: a benzene ring, a pyridine ring, an indole ring, a benzimidazole ring, a carbazole ring, a pyridoindole ring, a benzofuran ring, a benzothiophene ring, a benzothiazole ring, a benzoxazole ring, a dibenzofuran ring and a dibenzothiophene ring.

According to an embodiment of the present disclosure, the ring Cy1, the ring Cy2 and the ring Cy3 are, at each occurrence identically or differently, selected from the group consisting of: a benzene ring and a pyridine ring.

According to an embodiment of the present disclosure,

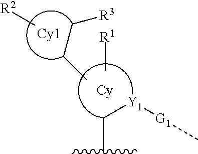

in Formula 1 is, at each occurrence identically or differently, selected from any structure of the group consisting of the following:

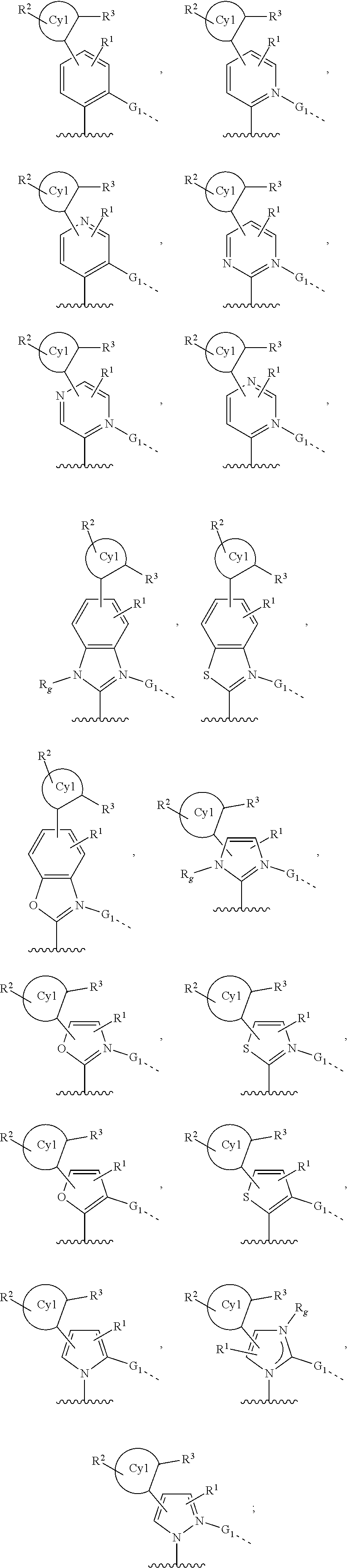

wherein G₁ is, at each occurrence identically or differently, selected from a single bond, O or S and joined to the metal M;
the ring Cy1 is, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹ and R² represent, at each occurrence identically or differently, mono-substitution, multiple substitutions or non-substitution;
at least one R¹ is adjacent to the ring Cy1;
R¹, R², R³ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
“ [symbol] ” represents a joining position.

According to an embodiment of the present disclosure,

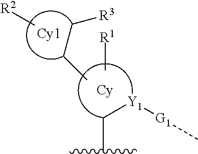

in Formula 1 is, at each occurrence identically or differently, selected from any structure of the group consisting of the following:

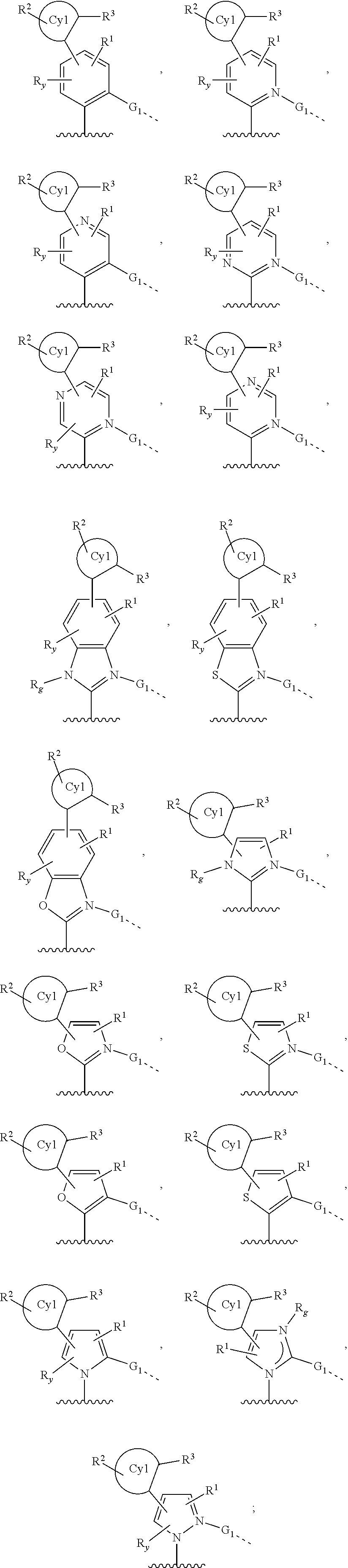

wherein G₁ is, at each occurrence identically or differently, selected from a single bond, O or S and joined to the metal M;
the ring Cy1 is, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R² and R_{y} represent, at each occurrence identically or differently, mono-substitution, multiple substitutions or non-substitution;
R¹ is adjacent to the ring Cy1;
R¹, R², R³, R_{y} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
“ [symbol] ” represents a joining position.

According to an embodiment of the present disclosure, the metal complex has a general formula of M(La)ₘ(Lb)ₙ;
wherein La and Lb are a first ligand and a second ligand coordinated to the metal M, respectively, and La and Lb can be optionally joined to form a multidentate ligand;
m is selected from 1, 2 or 3, n is selected from 0, 1 or 2, and m+n equals the oxidation state of the metal M; when m is greater than or equal to 2, multiple La are the same or different; when n is equal to 2, two Lb are the same or different; Lb is, at each occurrence identically or differently, selected from a structure represented by any one of the group consisting of the following:

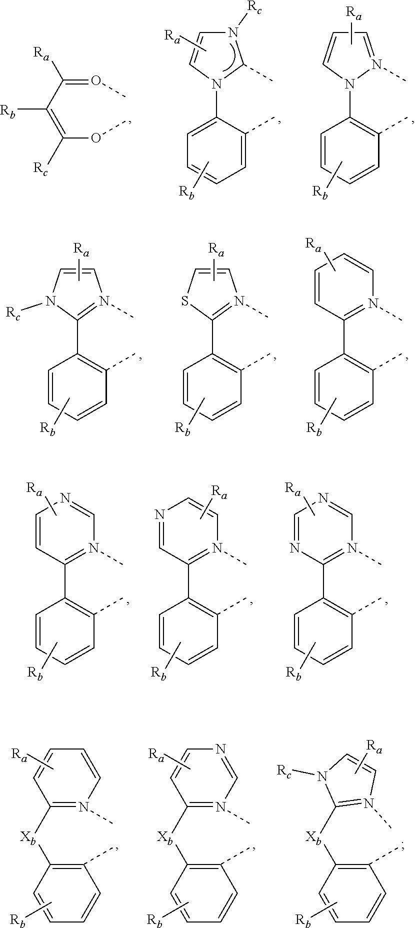

wherein,
X_{b} is, at each occurrence identically or differently, selected from the group consisting of: O, S, Se, NR_{N1} and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{c2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is also possible that none of these substituents are joined to form a ring. For example, adjacent substituents Rₐ and R_{b} in

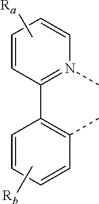

can be optionally joined to form a ring. When Rₐ is optionally joined to form a ring,

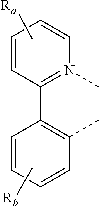

may form a structure of

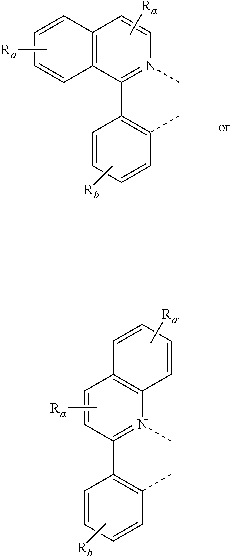

According to an embodiment of the present disclosure, the metal M is selected from the group consisting of Cu, Ag, Au, Ru, Rh, Pd, Os, Ir and Pt.

According to an embodiment of the present disclosure, M is selected from Pt or Ir.

According to an embodiment of the present disclosure, the metal complex Ir(La)ₘ(Lb)ₙ has a structure represented by Formula 3A or Formula 3B:

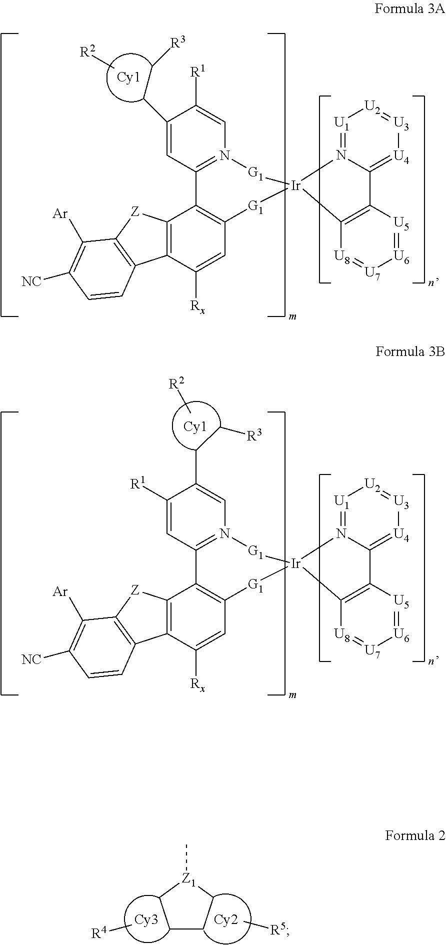

wherein,
m is selected from 1, 2 or 3, n is selected from 0, 1 or 2, and m+n=3; when m is greater than or equal to 2, multiple La are the same or different; when n is equal to 2, two Lb are the same or different;
Ar has, at each occurrence identically or differently, the structure of Formula 2;
G₁ is, at each occurrence identically or differently, selected from a single bond, O or S;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
U₁ to U₄ are, at each occurrence identically or differently, selected from CRₐ or N;
U₅ to U₈ are, at each occurrence identically or differently, selected from CR_{b} or N;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R², R⁴ and R⁵ represent, at each occurrence identically or differently, mono-substitution, multiple substitutions or non-substitution;
in the ring Cy1, R³ is adjacent to a pyridine ring;
R¹, R², R³, R⁴, R⁵, Rₐ, R_{b}, R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R², R³, R⁴ and R⁵ can be optionally joined to form a ring.

According to an embodiment of the present disclosure, adjacent substituents Rₐ and R_{b} can be optionally joined to form a ring.

In the present disclosure, the expression that “adjacent substituents Rₐ and R_{b} can be optionally joined to form a ring” is intended to mean that any one or more of groups of adjacent substituents, such as two substituents Rₐ, two substituents R_{b}, and substituents Rₐ and R_{b}, can be joined to form a ring. Obviously, it is also possible that none of these substituents are joined to form a ring.

According to an embodiment of the present disclosure, the metal complex Ir(La)ₘ(Lb)ₙ has a structure represented by Formula 3C or Formula 3D:

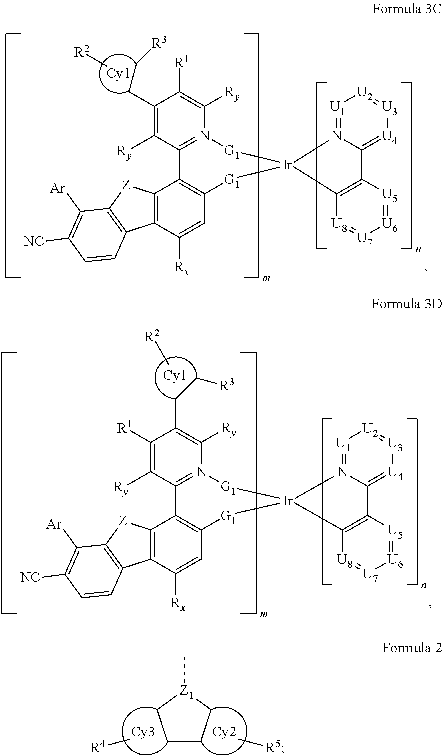

wherein,
m is selected from 1, 2 or 3, n is selected from 0, 1 or 2, and m+n=3; when m is greater than or equal to 2, multiple La are the same or different; when n is equal to 2, two Lb are the same or different;
Ar has, at each occurrence identically or differently, the structure of Formula 2;
G₁ is, at each occurrence identically or differently, selected from a single bond, O or S;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
U₁ to U₄ are, at each occurrence identically or differently, selected from CRₐ or N;
U₅ to U₈ are, at each occurrence identically or differently, selected from CR_{b} or N;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R², R⁴ and R⁵ represent, at each occurrence identically or differently, mono-substitution, multiple substitutions or non-substitution;
in the ring Cy1, R³ is adjacent to a pyridine ring;
R¹, R², R³, R⁴, R⁵, R_{y}, Rₐ, R_{b}, R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R², R³, R⁴, R⁵, Rₐ and R_{b} can be optionally joined to form a ring.

In the present disclosure, the expression that “adjacent substituents R², R³, R⁴, R⁵, Rₐ and R_{b} can be optionally joined to form a ring” is intended to mean that any one or more of groups of adjacent substituents, such as two substituents R², two substituents R⁴, two substituents R⁵, substituents R² and R³, substituents R⁴ and R⁵, and substituents Rₐ and R_{b}, can be joined to form a ring. Obviously, it is also possible that none of these substituents are joined to form a ring.

According to an embodiment of the present disclosure, G₁ is, at each occurrence, selected from a single bond.

According to an embodiment of the present disclosure, Z is, at each occurrence identically or differently, selected from O, S or Se.

According to an embodiment of the present disclosure, Z is, at each occurrence identically or differently, selected from O or S.

According to an embodiment of the present disclosure, Z is, at each occurrence, selected from O.

According to an embodiment of the present disclosure, Rₓ is, at each occurrence identically or differently, selected from the group consisting of: fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms and combinations thereof.

According to an embodiment of the present disclosure, Rₓ is, at each occurrence identically or differently, selected from the group consisting of: substituted or unsubstituted alkyl having 1 to 20 carbon atoms, substituted or unsubstituted cycloalkyl having 3 to 20 ring carbon atoms and substituted or unsubstituted aryl having 6 to 30 carbon atoms.

According to an embodiment of the present disclosure, R¹ and R³ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof, at least one of R¹ and/or R³ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof.

According to an embodiment of the present disclosure, R¹ and R³ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof, at least one of R¹ and/or R³ is, at each occurrence identically or differently, selected from the group consisting of: substituted or unsubstituted alkyl having 1 to 20 carbon atoms, substituted or unsubstituted cycloalkyl having 3 to 20 ring carbon atoms and combinations thereof.

According to an embodiment of the present disclosure, one or more R² are present, and R² is, at each occurrence identically or differently, selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof.

According to an embodiment of the present disclosure, one or more R are present, and R² is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, R¹, R³ and at least one R² are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof.

According to an embodiment of the present disclosure, R¹, R³ and at least one R² are, at each occurrence identically or differently, selected from the group consisting of: substituted or unsubstituted alkyl having 1 to 20 carbon atoms, substituted or unsubstituted cycloalkyl having 3 to 20 ring carbon atoms and combinations thereof.

According to an embodiment of the present disclosure, at least one of U₁ to U₄ is selected from CRₐ, and/or at least one of U₅ to U₈ is selected from CR_{b}, wherein Rₐ and R_{b} are selected from substituted or unsubstituted alkyl having 1 to 20 carbon atoms, substituted or unsubstituted cycloalkyl having 3 to 20 ring carbon atoms or a combination thereof, and the total number of carbon atoms in Rₐ and R_{b} is greater than or equal to 2.

According to an embodiment of the present disclosure, at least one of U₁ to U₄ is selected from CRₐ, and/or at least one of U₅ to U₈ is selected from CR_{b}, wherein Rₐ and R_{b} are selected from substituted or unsubstituted alkyl having 1 to 20 carbon atoms, substituted or unsubstituted cycloalkyl having 3 to 20 ring carbon atoms or a combination thereof, and the total number of carbon atoms in Rₐ and R_{b} is greater than or equal to 4.

According to an embodiment of the present disclosure, Z₁ is, at each occurrence, selected from N.

According to an embodiment of the present disclosure, R⁴ and R⁵ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof; and adjacent substituents R⁴ and R⁵ can be optionally joined to form a ring.

According to an embodiment of the present disclosure, R⁴ and R⁵ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R⁴ and R⁵ are, at each occurrence identically or differently, selected from the group consisting of: hydrogen, deuterium, fluorine, substituted or unsubstituted alkyl having 1 to 12 carbon atoms, substituted or unsubstituted cycloalkyl having 3 to 10 ring carbon atoms, substituted or unsubstituted aryl having 6 to 18 carbon atoms, substituted or unsubstituted heteroaryl having 3 to 18 carbon atoms and combinations thereof.

According to an embodiment of the present disclosure, R⁴ and R⁵ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms and combinations thereof.

According to an embodiment of the present disclosure, R⁴ and R⁵ are, at each occurrence identically or differently, selected from the group consisting of: hydrogen, deuterium, fluorine, substituted or unsubstituted alkyl having 1 to 12 carbon atoms, substituted or unsubstituted cycloalkyl having 3 to 10 ring carbon atoms and combinations thereof.

According to an embodiment of the present disclosure, Ar is, at each occurrence identically or differently, selected from the group consisting of Ar1 to Ar104, wherein the structures of Ar1 to Ar104 are referred to in claim 16.

According to another embodiment of the present disclosure, La is, at each occurrence identically or differently, selected from the group consisting of La-1-k and La-2-k, wherein the structures of La-1-k and La-2-k are referred to in claim 17.

According to an embodiment of the present disclosure, Lb is, at each occurrence identically or differently, selected from the group consisting of Lb1 to Lb167, wherein the structures of Lb1 to Lb167 are referred to in claim 18.

According to another embodiment of the present disclosure, the metal complex has a structure of IrLa(Lb)₂, wherein the two Lb are the same, La is selected from the group consisting of La-1-k and La-2-k, k is selected from 1 to 5080, and Lb is selected from the group consisting of Lb1 to Lb167.

According to another embodiment of the present disclosure, the metal complex is selected from the group consisting of Metal Complex 1 to Metal Complex 3815, wherein Metal Complex 1 to Metal Complex 3815 are referred to in claim 19.

According to another embodiment of the present disclosure, optionally, Metal Complex 1 to Metal Complex 3815 can be partially or fully deuterated.

According to another embodiment of the present disclosure, further disclosed is use of the metal complex in an electroluminescent device.

According to another embodiment of the present disclosure, further disclosed is an electroluminescent device comprising an anode, a cathode and an organic layer disposed between the anode and the cathode, wherein the organic layer comprises the metal complex comprising the ligand Lₐ having the structure of Formula 1.

According to another embodiment of the present disclosure, the organic layer is a light-emitting layer, and the metal complex is a light-emitting material.

According to another embodiment of the present disclosure, the light-emitting layer emits green light or white light.

According to an embodiment of the present disclosure, the organic layer further comprises a host material.

According to another embodiment of the present disclosure, the light-emitting layer comprises a first host compound.

According to another embodiment of the present disclosure, the light-emitting layer further comprises a second host compound.

According to another embodiment of the present disclosure, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to another embodiment of the present disclosure, the first host compound has a structure represented by Formula 4:

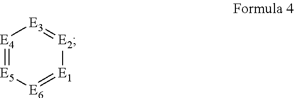

wherein,
E₁ to E₆ are, at each occurrence identically or differently, selected from C, CRₑ or N, at least two of E₁ to E₆ are N, and at least one of E₁ to E₆ is C and is joined to Formula A:

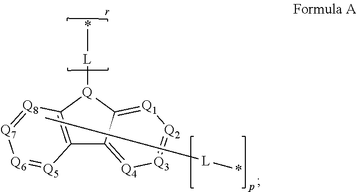

wherein,
Q is, at each occurrence identically or differently, selected from the group consisting of O, S, Se, N, NR″, CR″R″, SiR″R″, GeR″R″ and R″C═CR″; when two R″ are present at the same time, the two R″ may be the same or different;
p is 0 or 1; r is 0 or 1;
when Q is selected from N, p is 0, and r is 1;
when Q is selected from the group consisting of O, S, Se, NR″, CR″R″, SiR″R″, GeR″R″ and R″C═CR″, p is 1, and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₑ, R″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“*” represents a position where Formula Ais joined to Formula 4; and
adjacent substituents Rₑ, R″ and R_{q} can be optionally joined to form a ring.

In the present disclosure, the expression that “adjacent substituents Rₑ, R″ and R_{q} can be optionally joined to form a ring” is intended to mean that any one or more of groups of adjacent substituents, such as two substituents Rₑ, two substituents R″, two substituents R_{q}, and two substituents R″ and R_{q}, can be joined to form a ring. Obviously, it is also possible that none of these substituents are joined to form a ring.

According to another embodiment of the present disclosure, E₁ to E₆ are, at each occurrence identically or differently, selected from C, CRₑ or N, three of E₁ to E₆ are N, at least one of E₁ to E₆ is CRₑ, and Rₑ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof, and/or
Q is, at each occurrence identically or differently, selected from O, S, N or NR″; and/or
at least one or at least two of Q₁ to Q₈ are selected from CR_{q}, and R_{q} is selected from substituted or unsubstituted aryl having 6 to 30 carbon atoms, substituted or unsubstituted heteroaryl having 5 to 30 carbon atoms or a combination thereof, and/or
L is, at each occurrence identically or differently, selected from a single bond, substituted or unsubstituted arylene having 6 to 20 carbon atoms, substituted or unsubstituted heteroarylene having 3 to 20 carbon atoms or a combination thereof.

According to another embodiment of the present disclosure, the first host compound is selected from the group consisting of H-1 to H-243, wherein the structures of H-1 to H-243 are shown as follows:

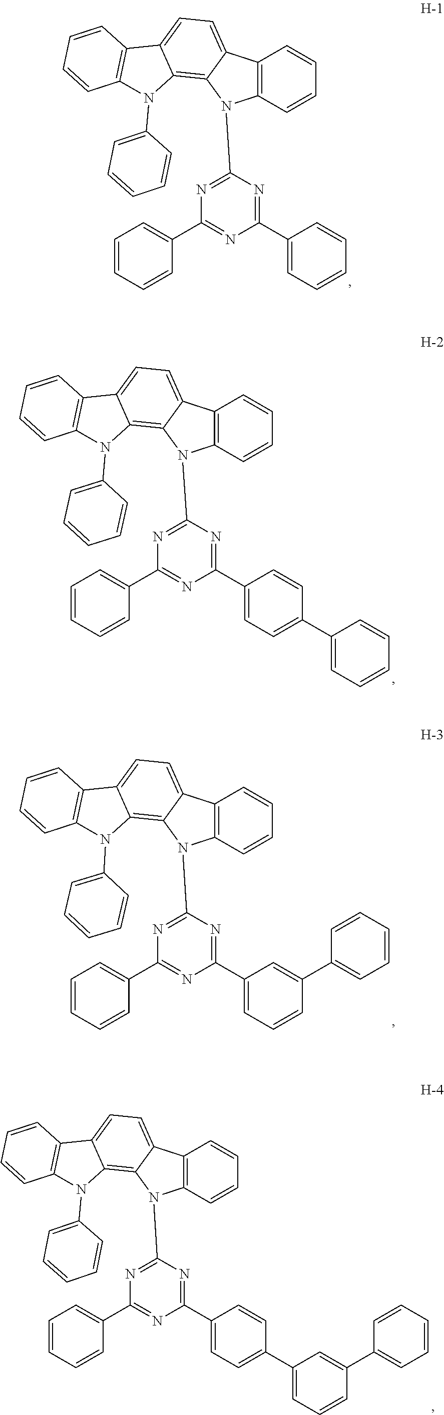 [SMILES: c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2cccc(-c3ccc(-c4nc(-c5ccccc5)nc(-n5c6ccccc6c6ccc7c8ccccc8n(-c8ccccc8)c7c65)n4)cc3)c2)cc1]

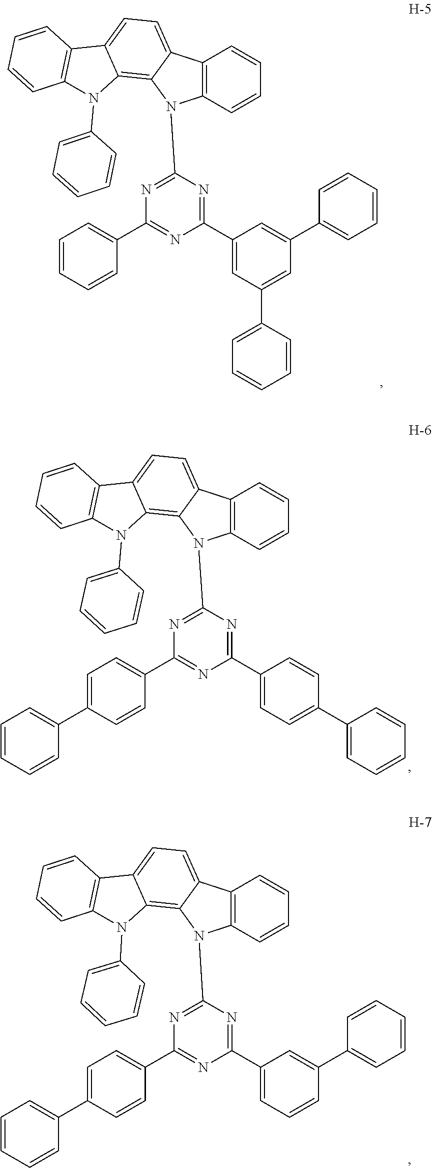 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1]

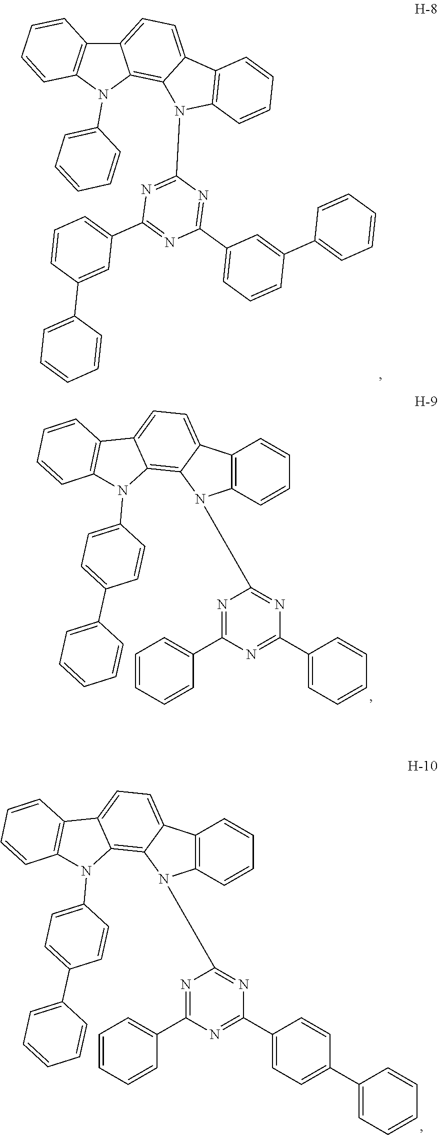

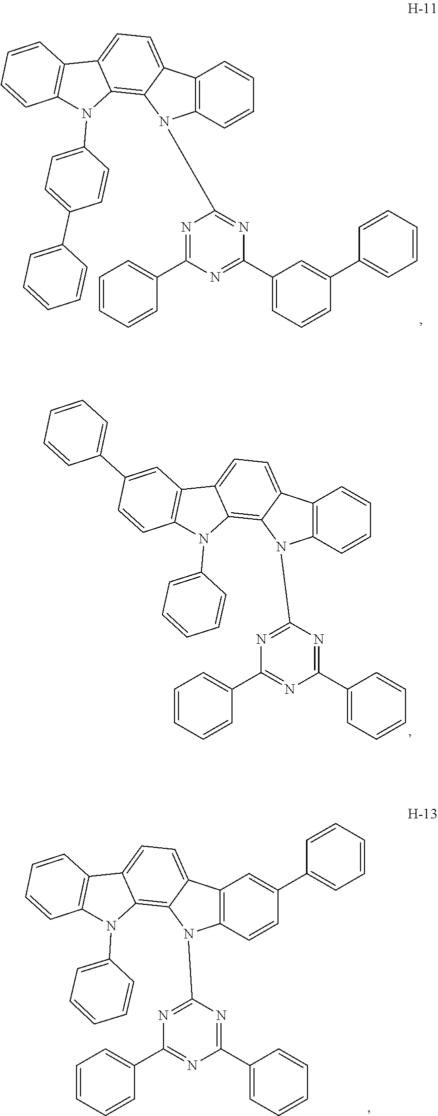 [SMILES: c1ccc(-c2ccc(-n3c4ccccc4c4ccc5c6ccccc6n(-c6nc(-c7ccccc7)nc(-c7cccc(-c8ccccc8)c7)n6)c5c43)cc2)cc1 ; c1ccc(-c2ccc3c(c2)c2ccc4c5ccccc5n(-c5nc(-c6ccccc6)nc(-c6ccccc6)n5)c4c2n3-c2ccccc2)cc1 ; c1ccc(-c2ccc3c(c2)c2ccc4c5ccccc5n(-c5ccccc5)c4c2n3-c2nc(-c3ccccc3)nc(-c3ccccc3)n2)cc1]

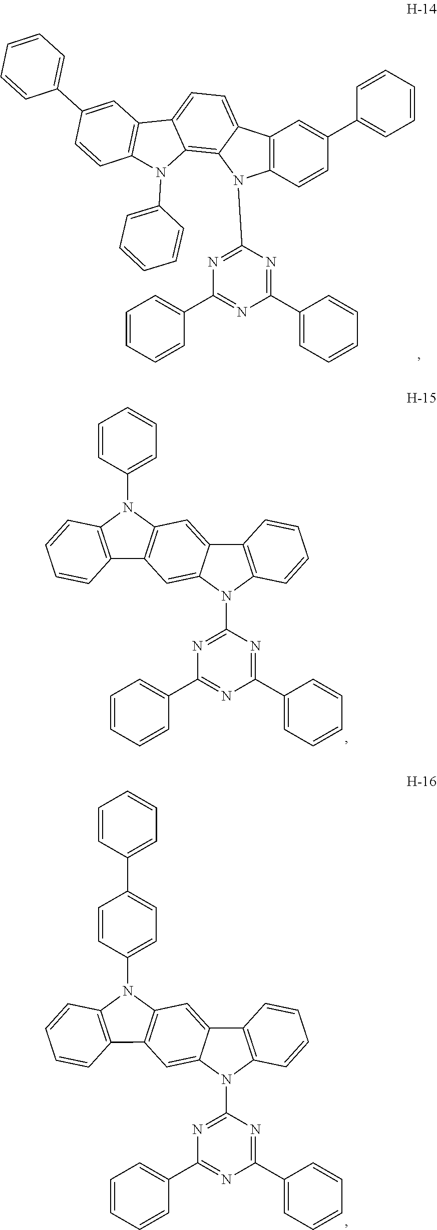 [SMILES: c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2nc(-c3ccccc3)nc(-n3c4ccccc4c4cc5c(cc43)c3ccccc3n5-c3ccccc3)n2)cc1 ; c1ccc(-c2ccc(-n3c4ccccc4c4cc5c(cc43)c3ccccc3n5-c3nc(-c4ccccc4)nc(-c4ccccc4)n3)cc2)cc1]

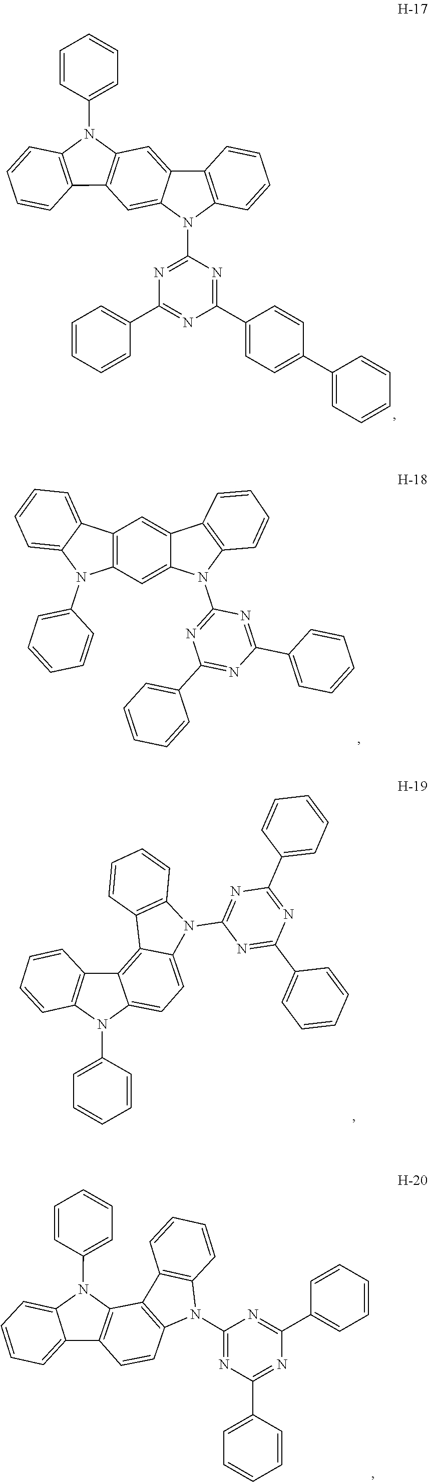 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4c5c6ccccc6n(-c6ccccc6)c5ccc43)n2)cc1 ; c1ccc(-c2nc(-c3ccccc3)nc(-n3c4ccccc4c4c3ccc3c5ccccc5n(-c5ccccc5)c34)n2)cc1]

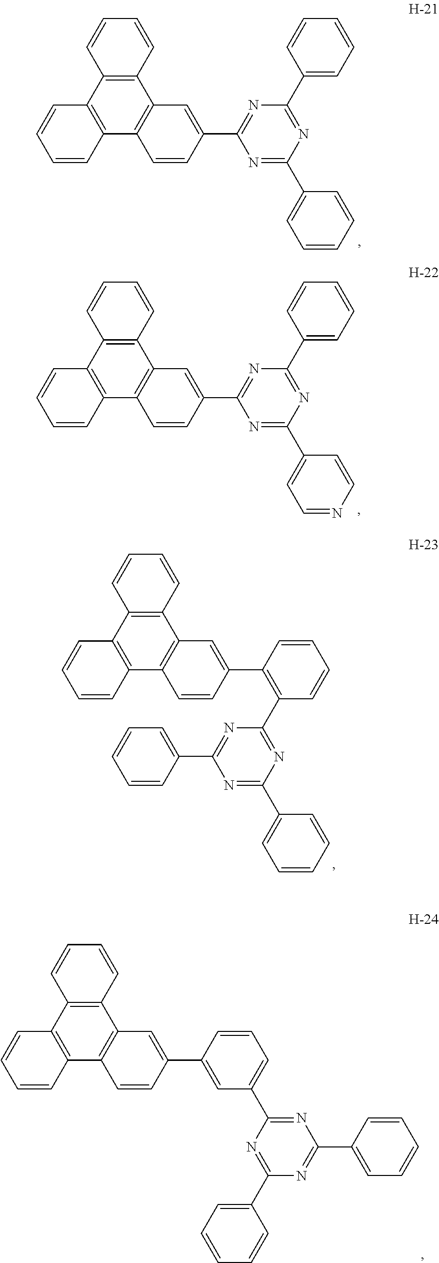

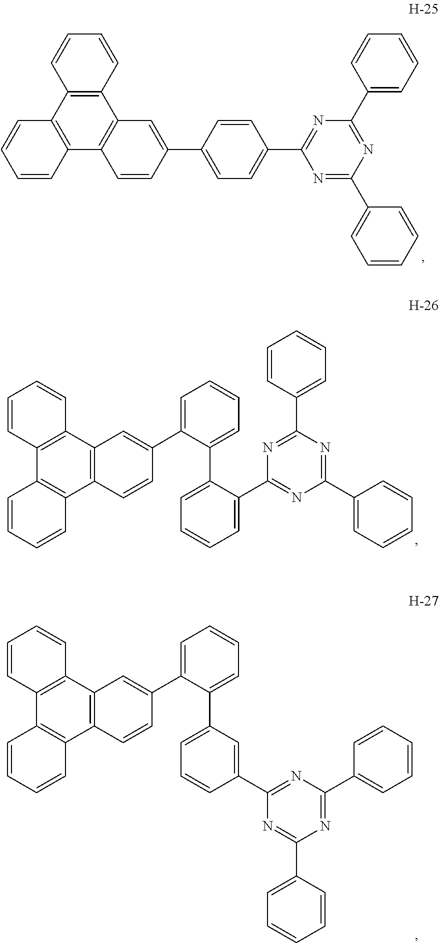 [SMILES: c1ccc(-c2nc(-c3ccccc3)nc(-c3ccc(-c4ccc5c6ccccc6c6ccccc6c5c4)cc3)n2)cc1 ; c1ccc(-c2nc(-c3ccccc3)nc(-c3ccccc3-c3ccccc3-c3ccc4c5ccccc5c5ccccc5c4c3)n2)cc1 ; c1ccc(-c2nc(-c3ccccc3)nc(-c3cccc(-c4ccccc4-c4ccc5c6ccccc6c6ccccc6c5c4)c3)n2)cc1]

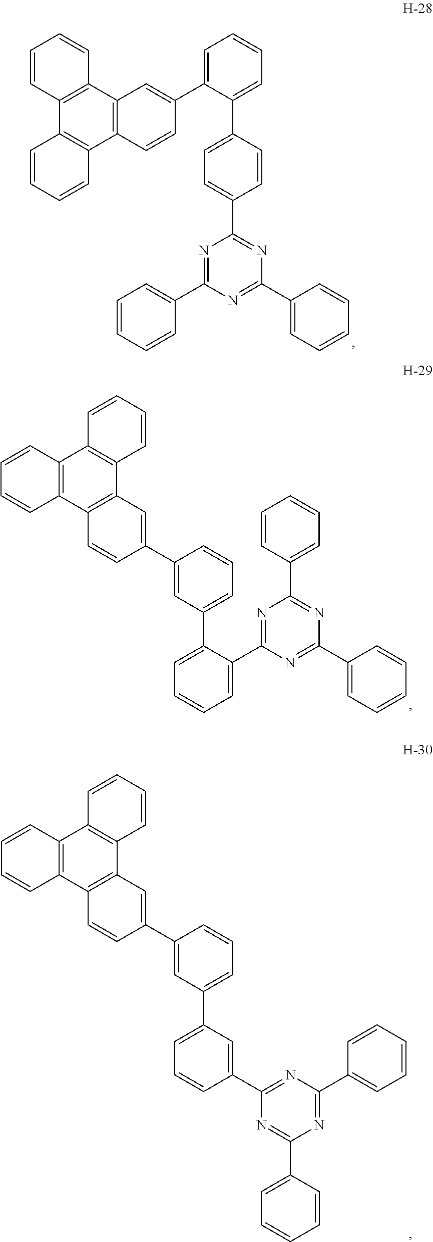 [SMILES: c1ccc(-c2nc(-c3ccccc3)nc(-c3ccc(-c4ccccc4-c4ccc5c6ccccc6c6ccccc6c5c4)cc3)n2)cc1 ; c1ccc(-c2nc(-c3ccccc3)nc(-c3ccccc3-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

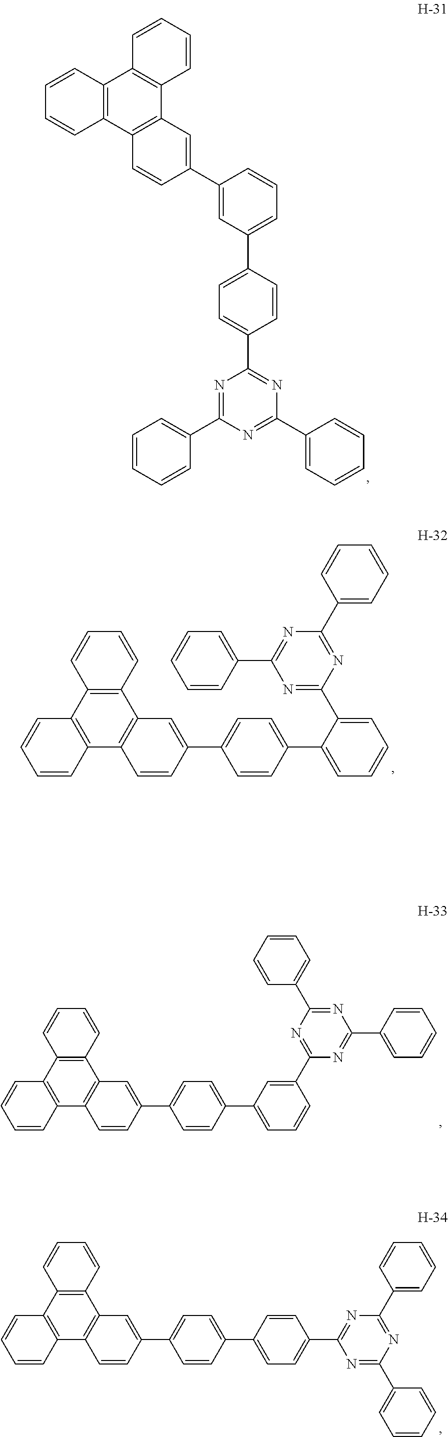 [SMILES: c1ccc(-c2nc(-c3ccccc3)nc(-c3ccc(-c4cccc(-c5ccc6c7ccccc7c7ccccc7c6c5)c4)cc3)n2)cc1 ; c1ccc(-c2nc(-c3ccccc3)nc(-c3ccccc3-c3ccc(-c4ccc5c6ccccc6c6ccccc6c5c4)cc3)n2)cc1 ; c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1]

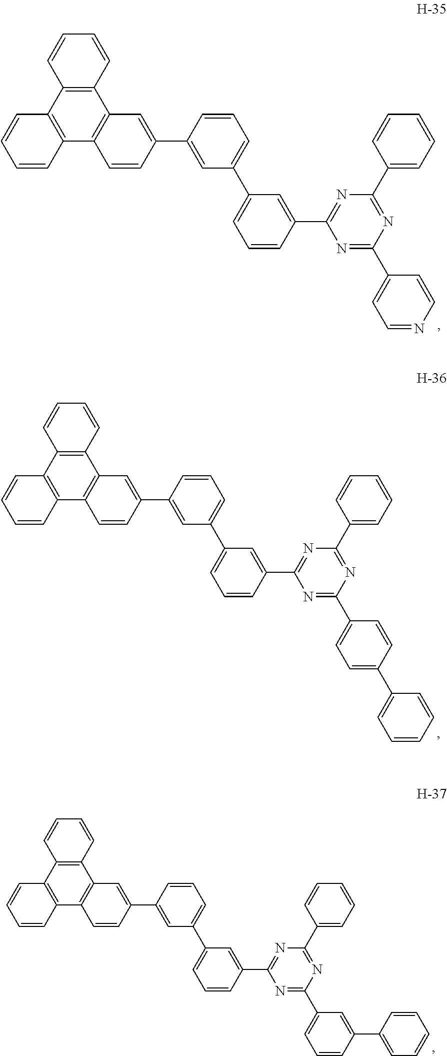 [SMILES: c1ccc(-c2nc(-c3ccncc3)nc(-c3cccc(-c4cccc(-c5ccc6c7ccccc7c7ccccc7c6c5)c4)c3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1]

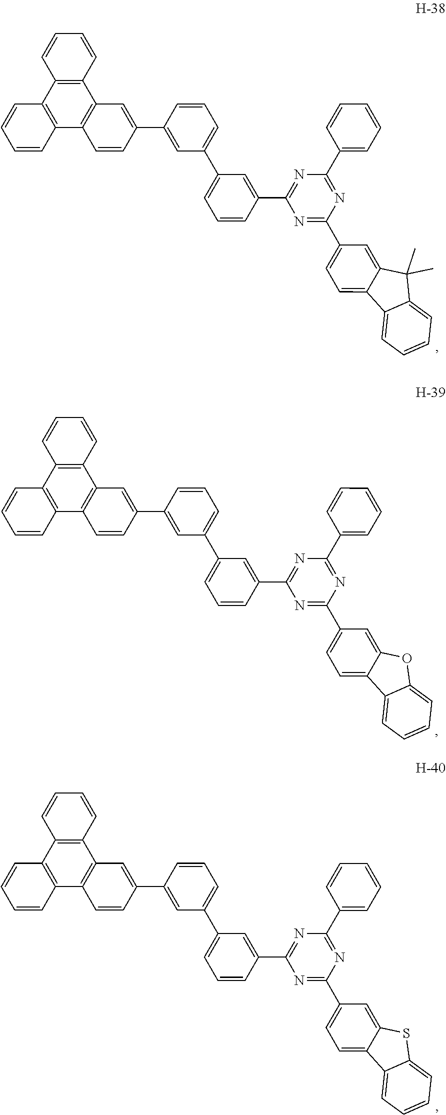 [SMILES: CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1]

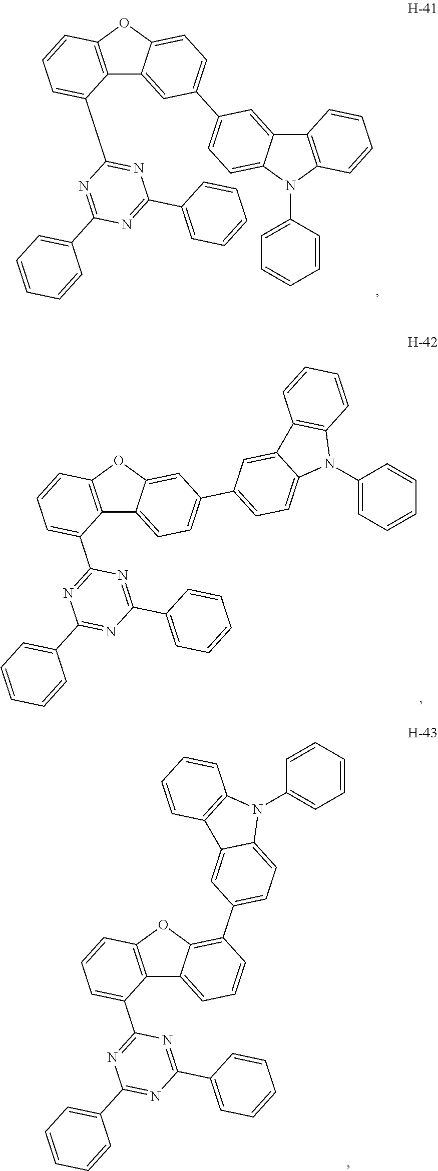 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1]

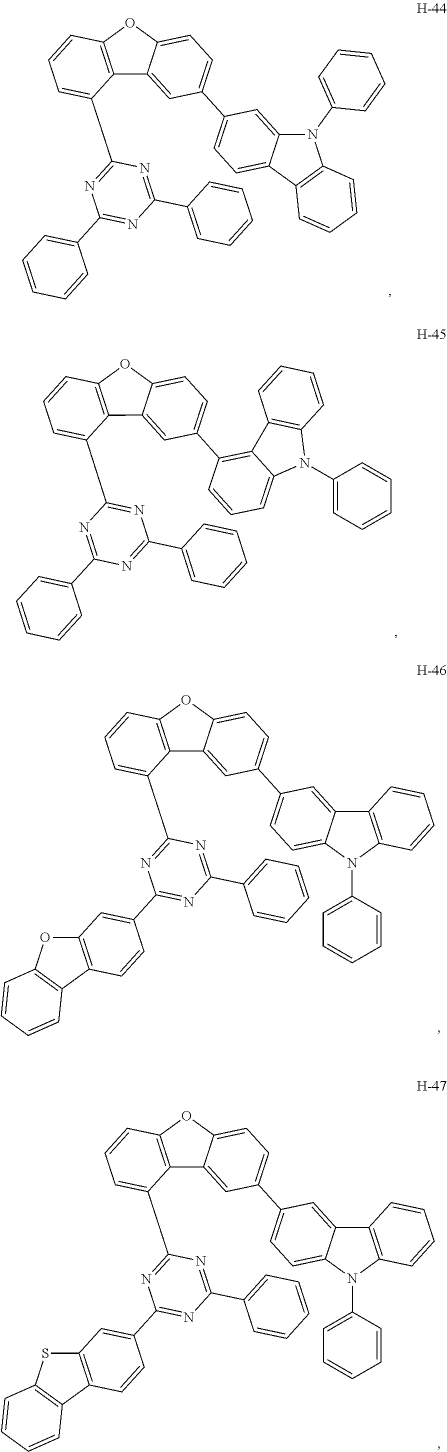 [SMILES: c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; c1ccc(-c2nc(-c3ccc4c(c3)sc3ccccc34)nc(-c3cccc4oc5ccc(-c6ccc7c(c6)c6ccccc6n7-c6ccccc6)cc5c34)n2)cc1]

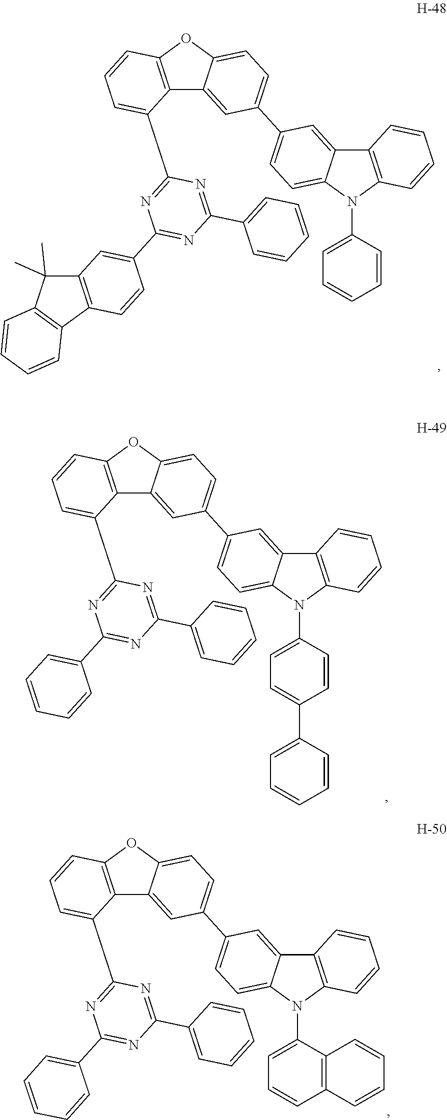 [SMILES: CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6cccc7ccccc67)cc5c34)n2)cc1]

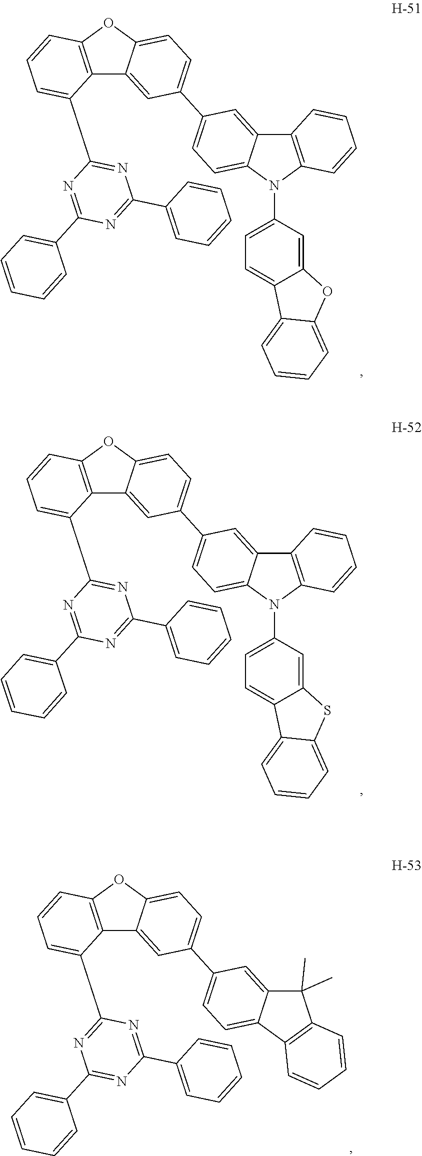 [SMILES: c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; c1ccc(-c2nc(-c3ccccc3)nc(-c3cccc4oc5ccc(-c6ccc7c(c6)c6ccccc6n7-c6ccc7c(c6)sc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21]

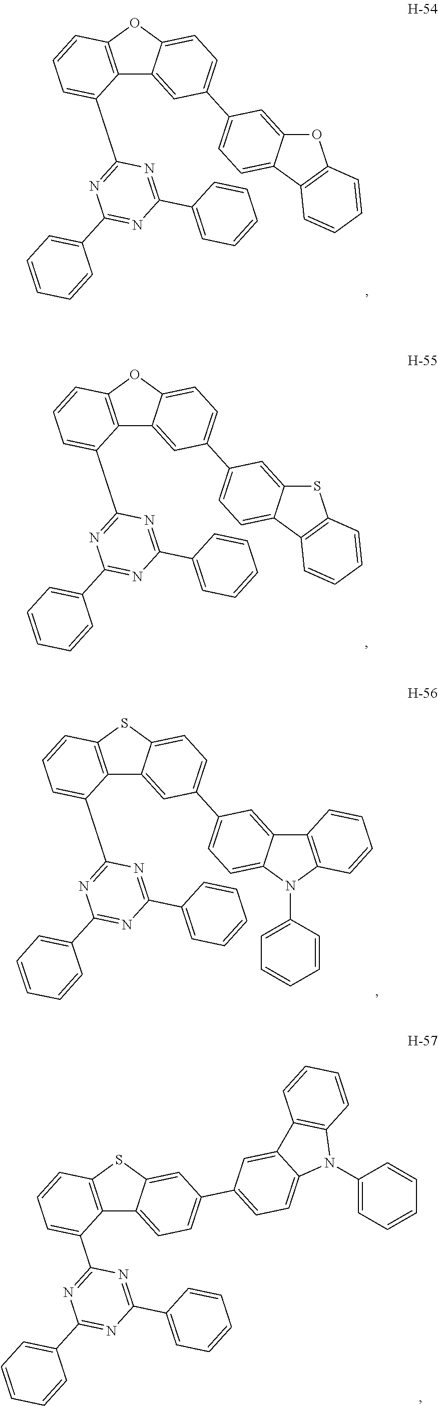 [SMILES: c1ccc(-c2nc(-c3ccccc3)nc(-c3cccc4oc5ccc(-c6ccc7c(c6)oc6ccccc67)cc5c34)n2)cc1 ; c1ccc(-c2nc(-c3ccccc3)nc(-c3cccc4oc5ccc(-c6ccc7c(c6)sc6ccccc67)cc5c34)n2)cc1 ; c1ccc(-c2nc(-c3ccccc3)nc(-c3cccc4sc5ccc(-c6ccc7c(c6)c6ccccc6n7-c6ccccc6)cc5c34)n2)cc1 ; c1ccc(-c2nc(-c3ccccc3)nc(-c3cccc4sc5cc(-c6ccc7c(c6)c6ccccc6n7-c6ccccc6)ccc5c34)n2)cc1]

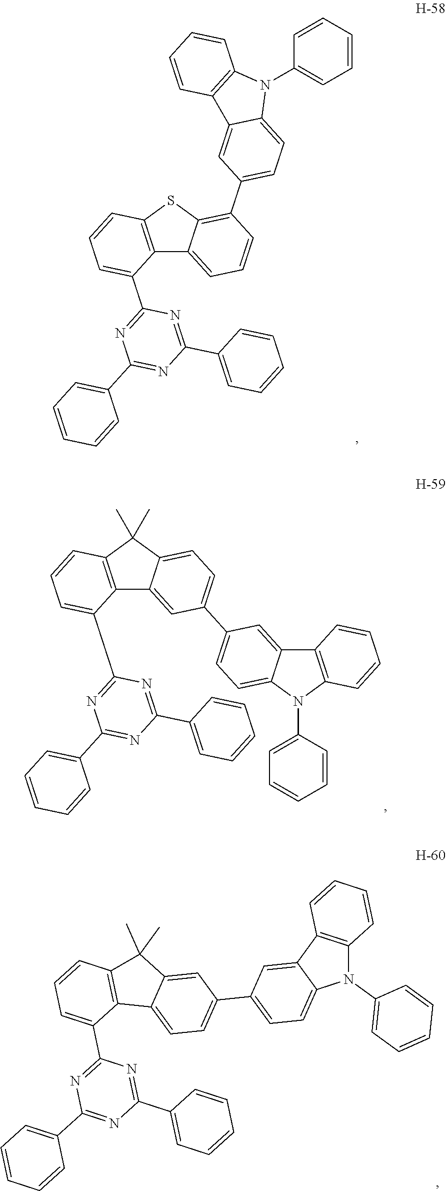 [SMILES: c1ccc(-c2nc(-c3ccccc3)nc(-c3cccc4sc5c(-c6ccc7c(c6)c6ccccc6n7-c6ccccc6)cccc5c34)n2)cc1 ; CC1(C)c2ccc(-c3ccc4c(c3)c3ccccc3n4-c3ccccc3)cc2-c2c(-c3nc(-c4ccccc4)nc(-c4ccccc4)n3)cccc21 ; CC1(C)c2cc(-c3ccc4c(c3)c3ccccc3n4-c3ccccc3)ccc2-c2c(-c3nc(-c4ccccc4)nc(-c4ccccc4)n3)cccc21]

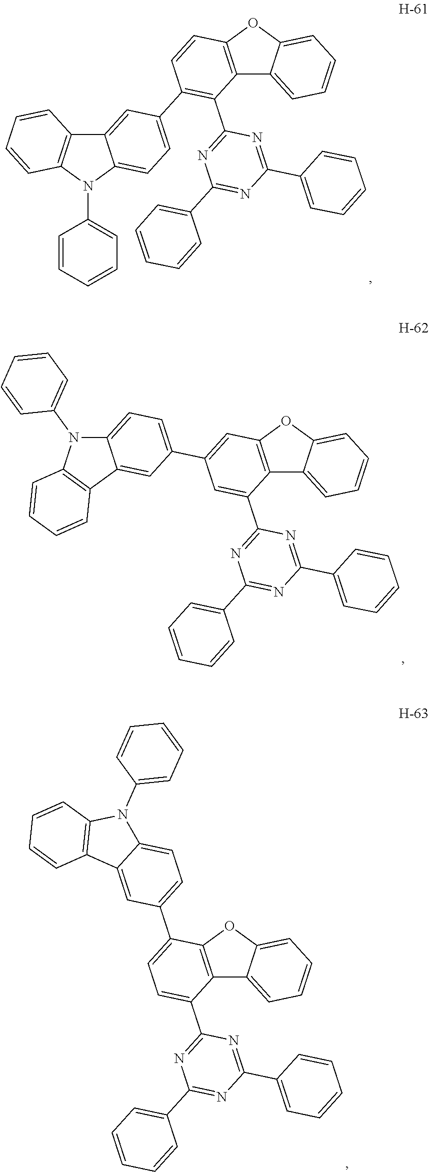 [SMILES: c1ccc(-c2nc(-c3ccccc3)nc(-c3c(-c4ccc5c(c4)c4ccccc4n5-c4ccccc4)ccc4oc5ccccc5c34)n2)cc1 ; c1ccc(-c2nc(-c3ccccc3)nc(-c3cc(-c4ccc5c(c4)c4ccccc4n5-c4ccccc4)cc4oc5ccccc5c34)n2)cc1 ; c1ccc(-c2nc(-c3ccccc3)nc(-c3ccc(-c4ccc5c(c4)c4ccccc4n5-c4ccccc4)c4oc5ccccc5c34)n2)cc1]

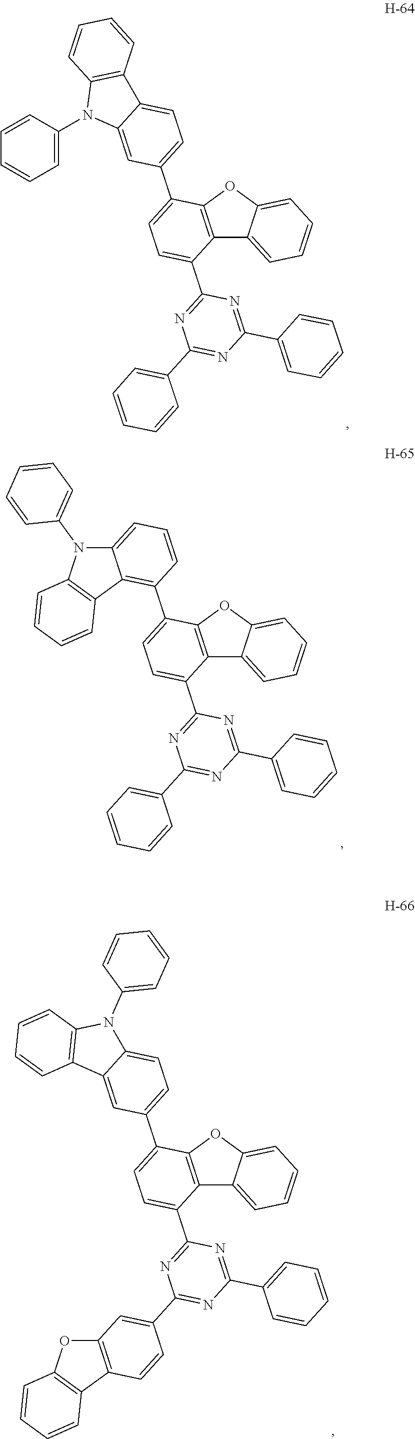 [SMILES: c1ccc(-c2nc(-c3ccccc3)nc(-c3ccc(-c4ccc5c6ccccc6n(-c6ccccc6)c5c4)c4oc5ccccc5c34)n2)cc1 ; c1ccc(-c2nc(-c3ccccc3)nc(-c3ccc(-c4cccc5c4c4ccccc4n5-c4ccccc4)c4oc5ccccc5c34)n2)cc1 ; c1ccc(-c2nc(-c3ccc4c(c3)oc3ccccc34)nc(-c3ccc(-c4ccc5c(c4)c4ccccc4n5-c4ccccc4)c4oc5ccccc5c34)n2)cc1]

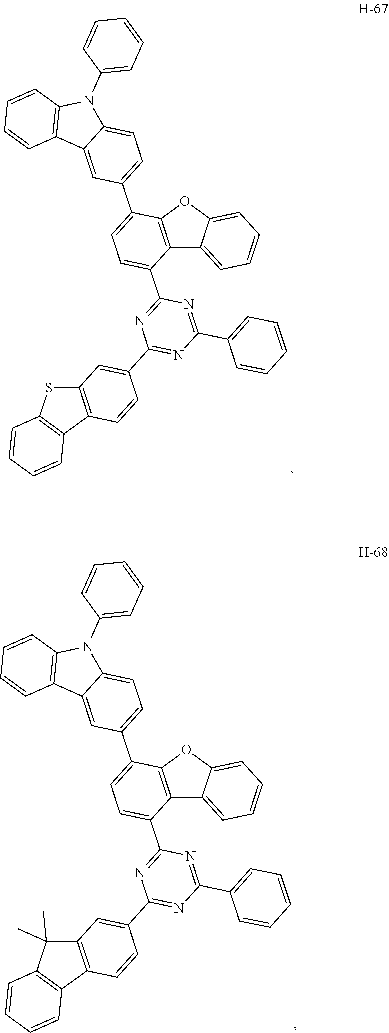 [SMILES: c1ccc(-c2nc(-c3ccc4c(c3)sc3ccccc34)nc(-c3ccc(-c4ccc5c(c4)c4ccccc4n5-c4ccccc4)c4oc5ccccc5c34)n2)cc1 ; CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21]

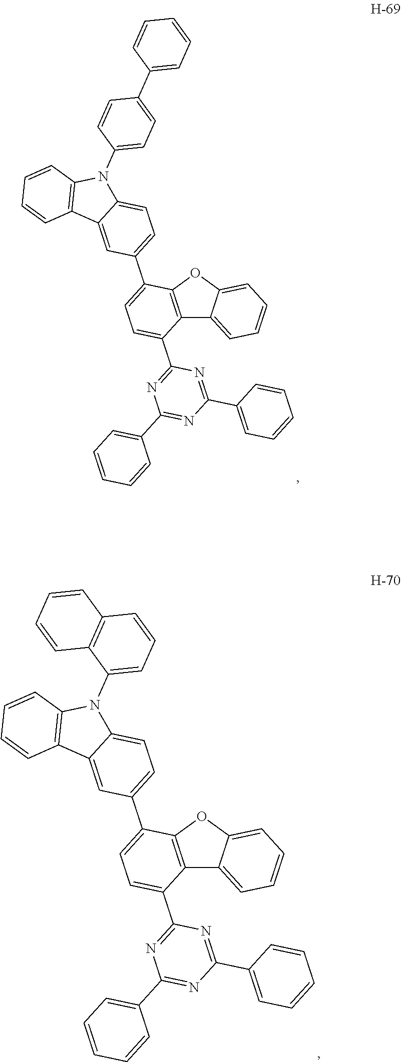 [SMILES: c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1 ; c1ccc(-c2nc(-c3ccccc3)nc(-c3ccc(-c4ccc5c(c4)c4ccccc4n5-c4cccc5ccccc45)c4oc5ccccc5c34)n2)cc1]

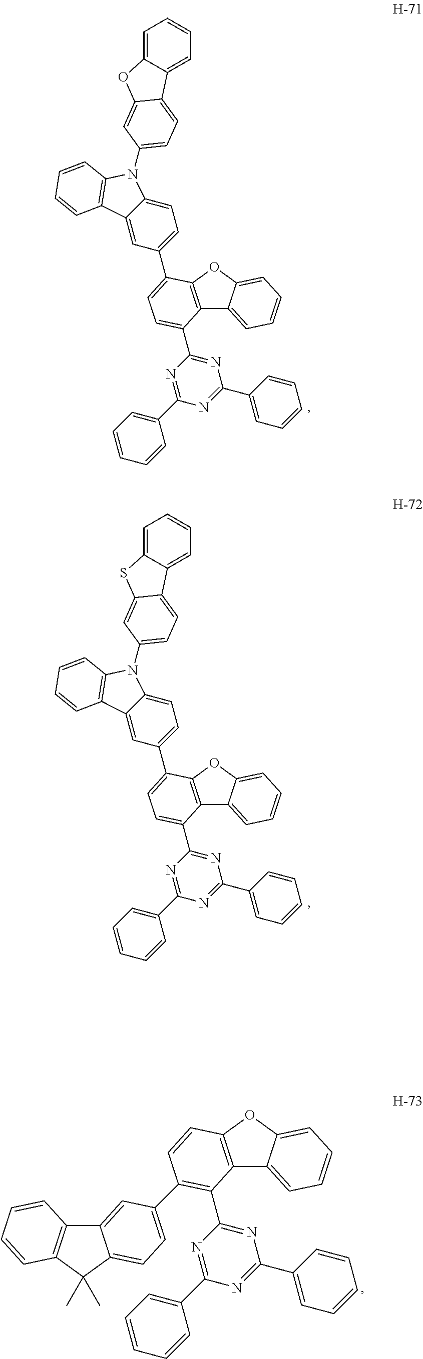 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccccc3)nc(-c3ccc(-c4ccc5c(c4)c4ccccc4n5-c4ccc5c(c4)sc4ccccc45)c4oc5ccccc5c34)n2)cc1 ; CC1(C)c2ccccc2-c2cc(-c3ccc4oc5ccccc5c4c3-c3nc(-c4ccccc4)nc(-c4ccccc4)n3)ccc21]

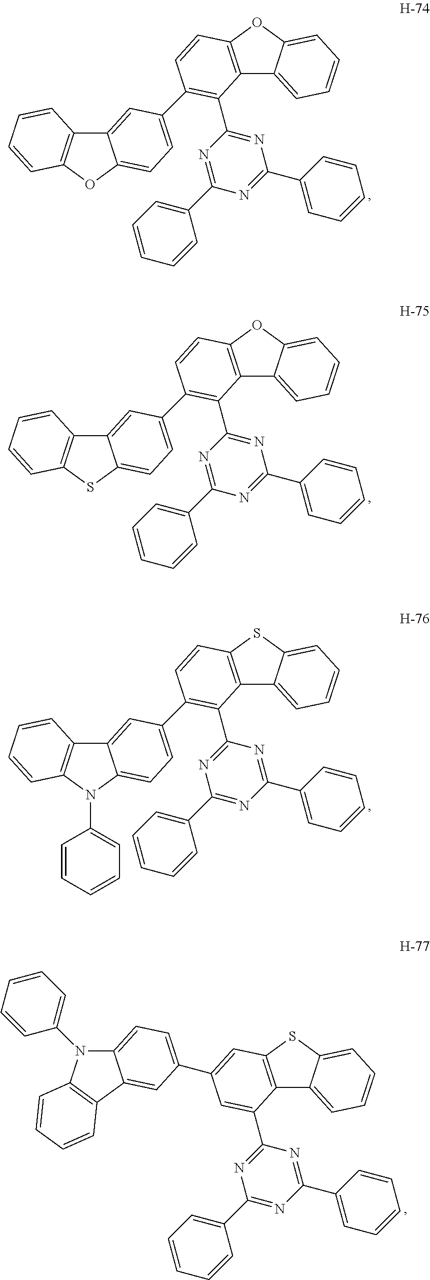 [SMILES: c1ccc(-c2nc(-c3ccccc3)nc(-c3c(-c4ccc5oc6ccccc6c5c4)ccc4oc5ccccc5c34)n2)cc1 ; c1ccc(-c2nc(-c3ccccc3)nc(-c3c(-c4ccc5sc6ccccc6c5c4)ccc4oc5ccccc5c34)n2)cc1 ; c1ccc(-c2nc(-c3ccccc3)nc(-c3c(-c4ccc5c(c4)c4ccccc4n5-c4ccccc4)ccc4sc5ccccc5c34)n2)cc1 ; c1ccc(-c2nc(-c3ccccc3)nc(-c3cc(-c4ccc5c(c4)c4ccccc4n5-c4ccccc4)cc4sc5ccccc5c34)n2)cc1]

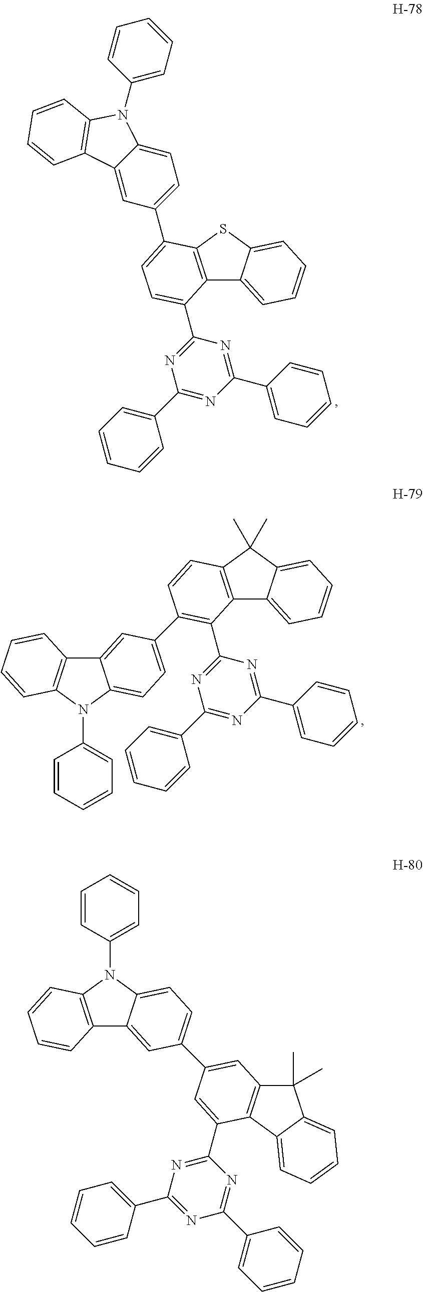 [SMILES: c1ccc(-c2nc(-c3ccccc3)nc(-c3ccc(-c4ccc5c(c4)c4ccccc4n5-c4ccccc4)c4sc5ccccc5c34)n2)cc1 ; CC1(C)c2ccccc2-c2c1ccc(-c1ccc3c(c1)c1ccccc1n3-c1ccccc1)c2-c1nc(-c2ccccc2)nc(-c2ccccc2)n1 ; CC1(C)c2ccccc2-c2c(-c3nc(-c4ccccc4)nc(-c4ccccc4)n3)cc(-c3ccc4c(c3)c3ccccc3n4-c3ccccc3)cc21]

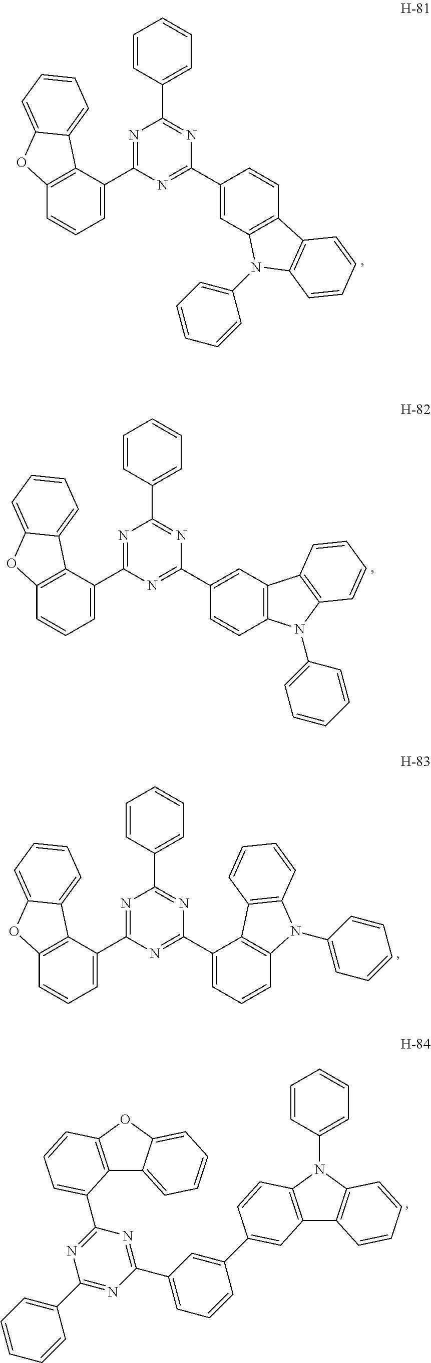 [SMILES: c1ccc(-c2nc(-c3ccc4c5ccccc5n(-c5ccccc5)c4c3)nc(-c3cccc4oc5ccccc5c34)n2)cc1 ; c1ccc(-c2nc(-c3ccc4c(c3)c3ccccc3n4-c3ccccc3)nc(-c3cccc4oc5ccccc5c34)n2)cc1 ; c1ccc(-c2nc(-c3cccc4oc5ccccc5c34)nc(-c3cccc4c3c3ccccc3n4-c3ccccc3)n2)cc1 ; c1ccc(-c2nc(-c3cccc(-c4ccc5c(c4)c4ccccc4n5-c4ccccc4)c3)nc(-c3cccc4oc5ccccc5c34)n2)cc1]

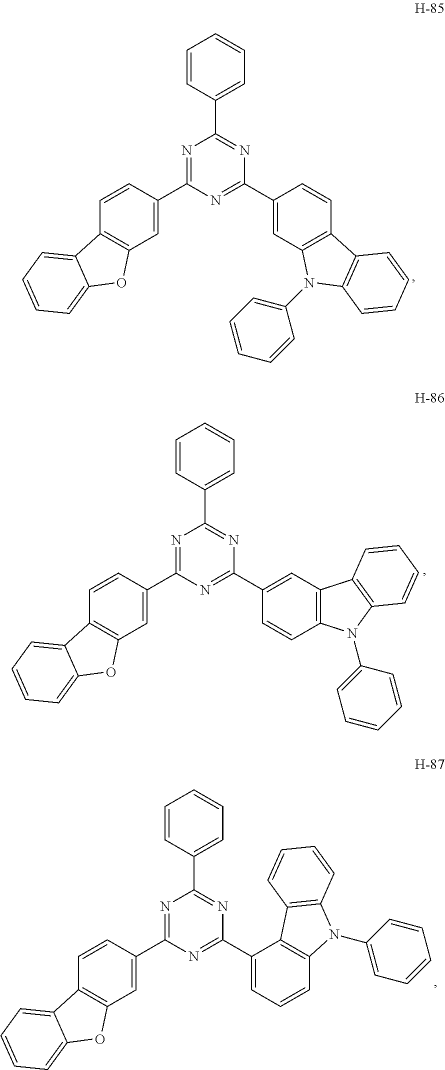 [SMILES: c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1]

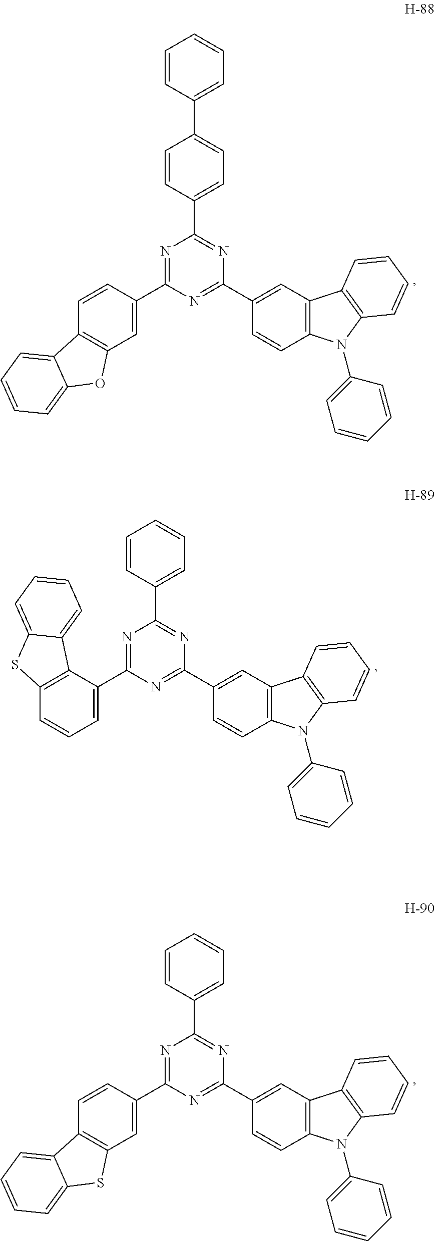 [SMILES: c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)c3ccccc3n4-c3ccccc3)nc(-c3cccc4sc5ccccc5c34)n2)cc1 ; c1ccc(-c2nc(-c3ccc4c(c3)sc3ccccc34)nc(-c3ccc4c(c3)c3ccccc3n4-c3ccccc3)n2)cc1]

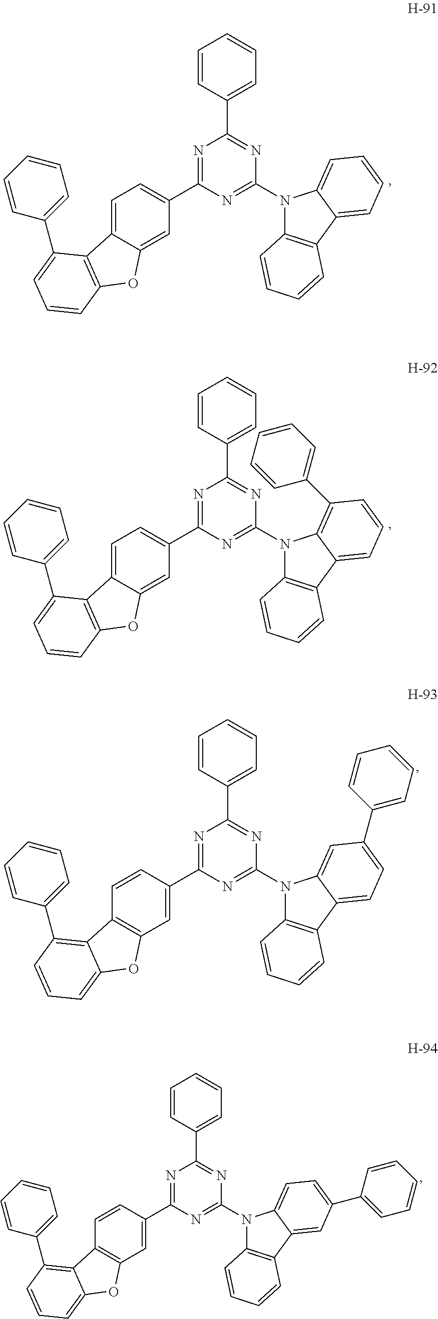 [SMILES: c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccc4c(c3)oc3cccc(-c5ccccc5)c34)nc(-n3c4ccccc4c4cccc(-c5ccccc5)c43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1]

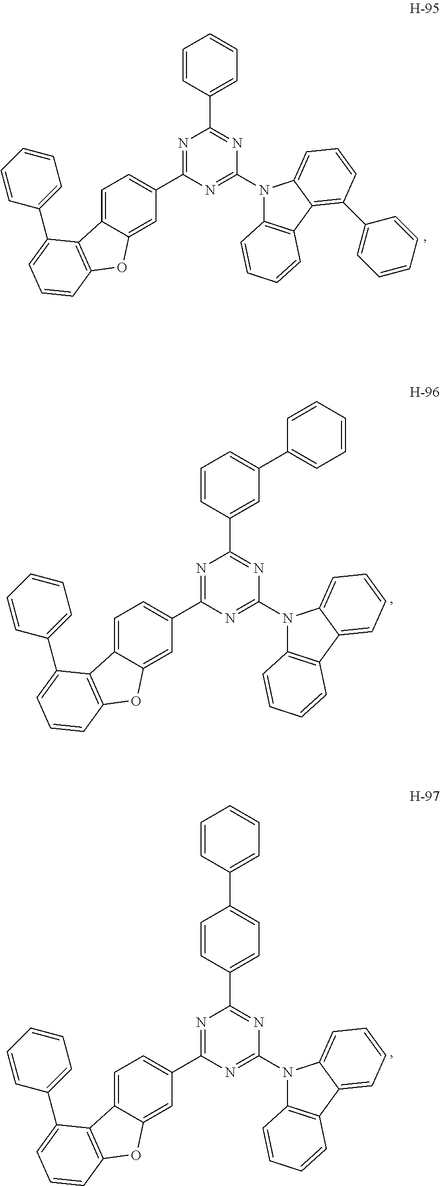 [SMILES: c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1]

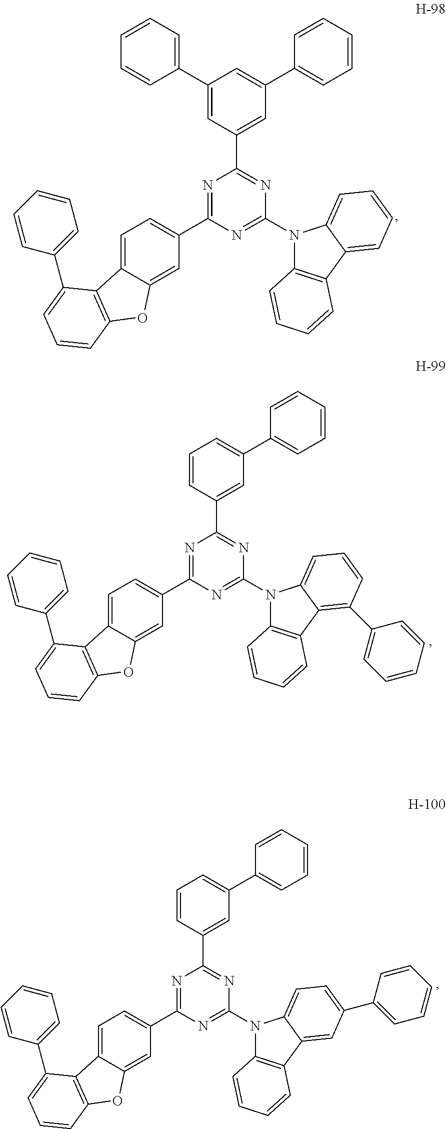 [SMILES: c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1]

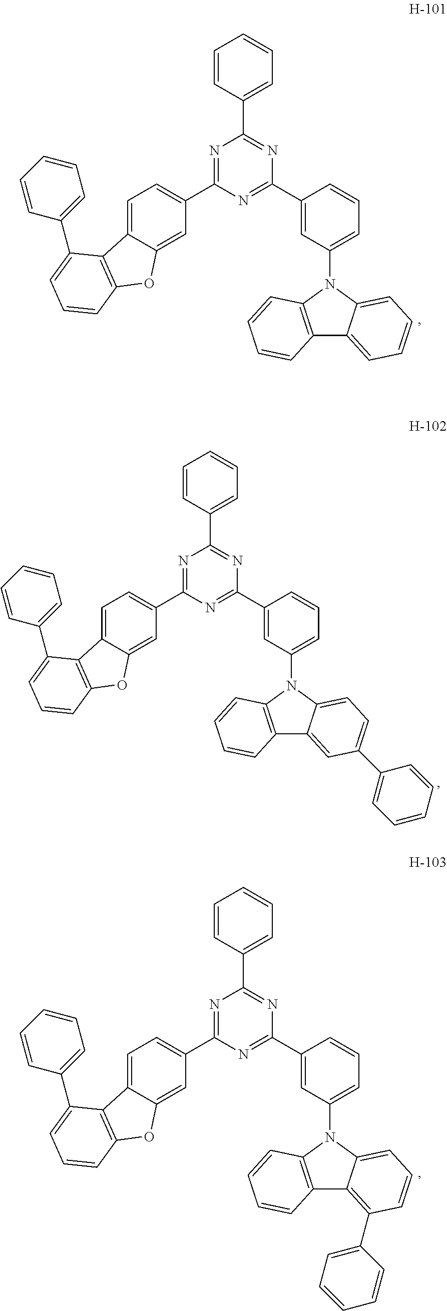 [SMILES: c1ccc(-c2nc(-c3cccc(-n4c5ccccc5c5ccccc54)c3)nc(-c3ccc4c(c3)oc3cccc(-c5ccccc5)c34)n2)cc1 ; c1ccc(-c2ccc3c(c2)c2ccccc2n3-c2cccc(-c3nc(-c4ccccc4)nc(-c4ccc5c(c4)oc4cccc(-c6ccccc6)c45)n3)c2)cc1 ; c1ccc(-c2nc(-c3cccc(-n4c5ccccc5c5c(-c6ccccc6)cccc54)c3)nc(-c3ccc4c(c3)oc3cccc(-c5ccccc5)c34)n2)cc1]

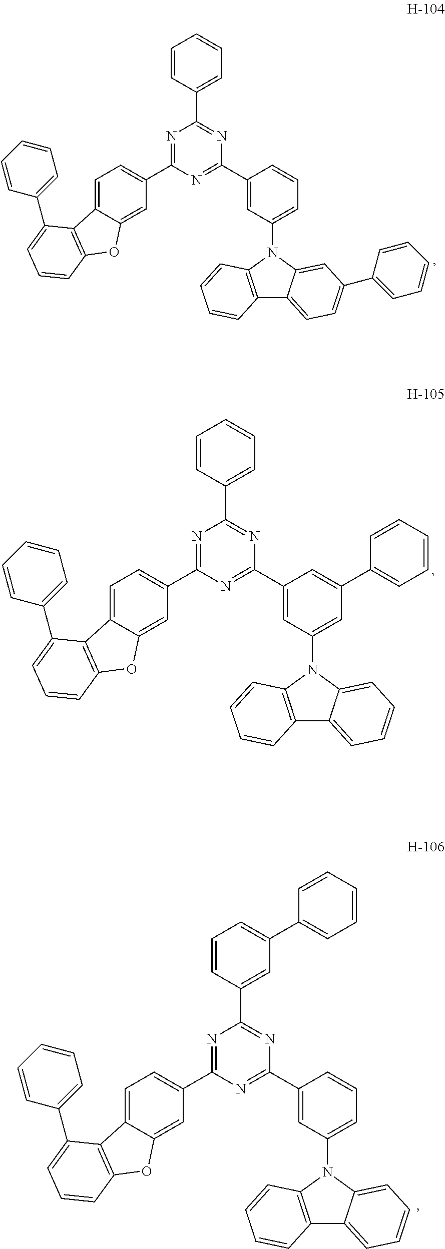 [SMILES: c1ccc(-c2ccc3c4ccccc4n(-c4cccc(-c5nc(-c6ccccc6)nc(-c6ccc7c(c6)oc6cccc(-c8ccccc8)c67)n5)c4)c3c2)cc1 ; c1ccc(-c2cc(-c3nc(-c4ccccc4)nc(-c4ccc5c(c4)oc4cccc(-c6ccccc6)c45)n3)cc(-n3c4ccccc4c4ccccc43)c2)cc1 ; c1ccc(-c2cccc(-c3nc(-c4cccc(-n5c6ccccc6c6ccccc65)c4)nc(-c4ccc5c(c4)oc4cccc(-c6ccccc6)c45)n3)c2)cc1]

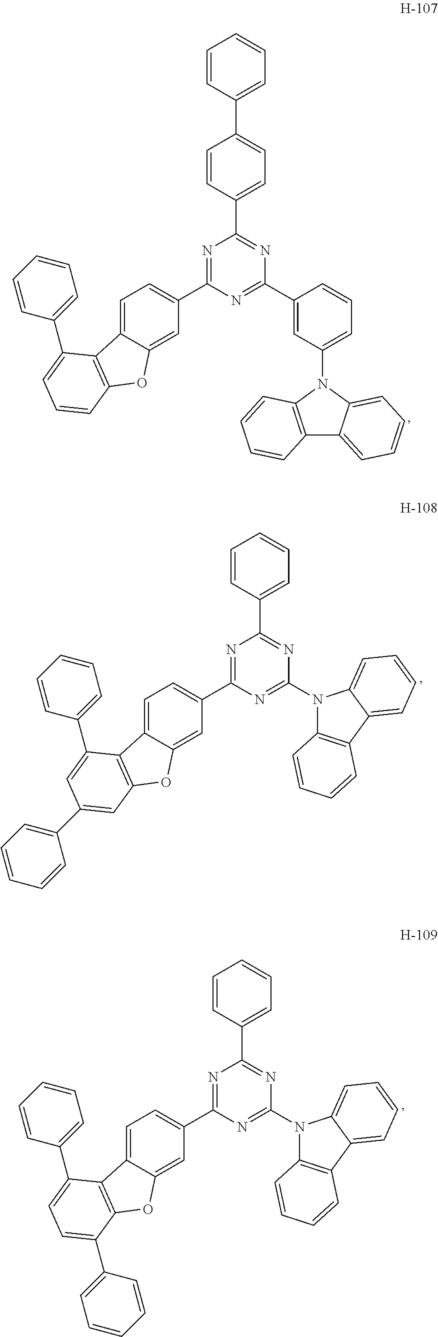 [SMILES: c1ccc(-c2ccc(-c3nc(-c4cccc(-n5c6ccccc6c6ccccc65)c4)nc(-c4ccc5c(c4)oc4cccc(-c6ccccc6)c45)n3)cc2)cc1 ; c1ccc(-c2cc(-c3ccccc3)c3c(c2)oc2cc(-c4nc(-c5ccccc5)nc(-n5c6ccccc6c6ccccc65)n4)ccc23)cc1 ; c1ccc(-c2nc(-c3ccc4c(c3)oc3c(-c5ccccc5)ccc(-c5ccccc5)c34)nc(-n3c4ccccc4c4ccccc43)n2)cc1]

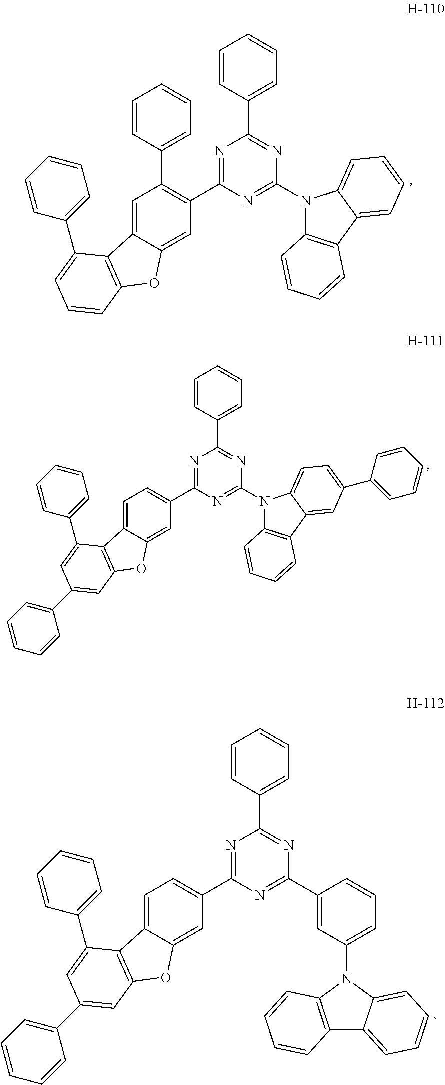 [SMILES: c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1]

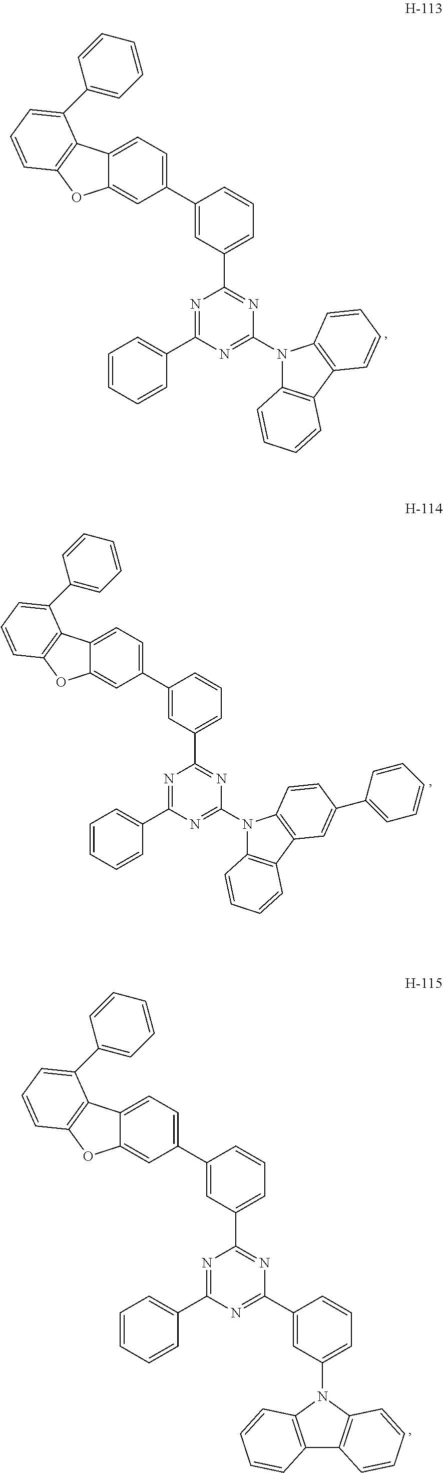 [SMILES: c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4ccc5c(c4)oc4cccc(-c6ccccc6)c45)c3)n2)cc1 ; c1ccc(-c2nc(-c3cccc(-c4ccc5c(c4)oc4cccc(-c6ccccc6)c45)c3)nc(-c3cccc(-n4c5ccccc5c5ccccc54)c3)n2)cc1]

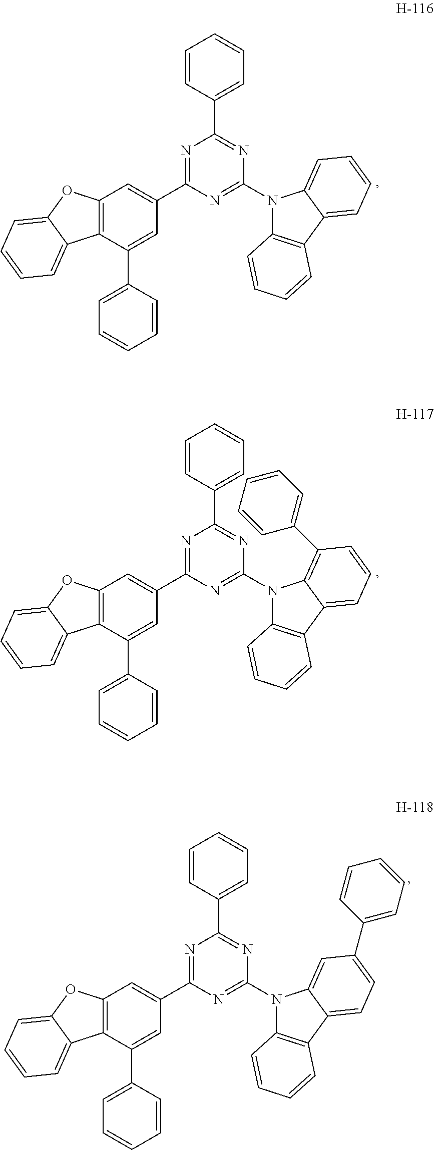 [SMILES: c1ccc(-c2nc(-c3cc(-c4ccccc4)c4c(c3)oc3ccccc34)nc(-n3c4ccccc4c4ccccc43)n2)cc1 ; c1ccc(-c2nc(-c3cc(-c4ccccc4)c4c(c3)oc3ccccc34)nc(-n3c4ccccc4c4cccc(-c5ccccc5)c43)n2)cc1 ; c1ccc(-c2ccc3c4ccccc4n(-c4nc(-c5ccccc5)nc(-c5cc(-c6ccccc6)c6c(c5)oc5ccccc56)n4)c3c2)cc1]

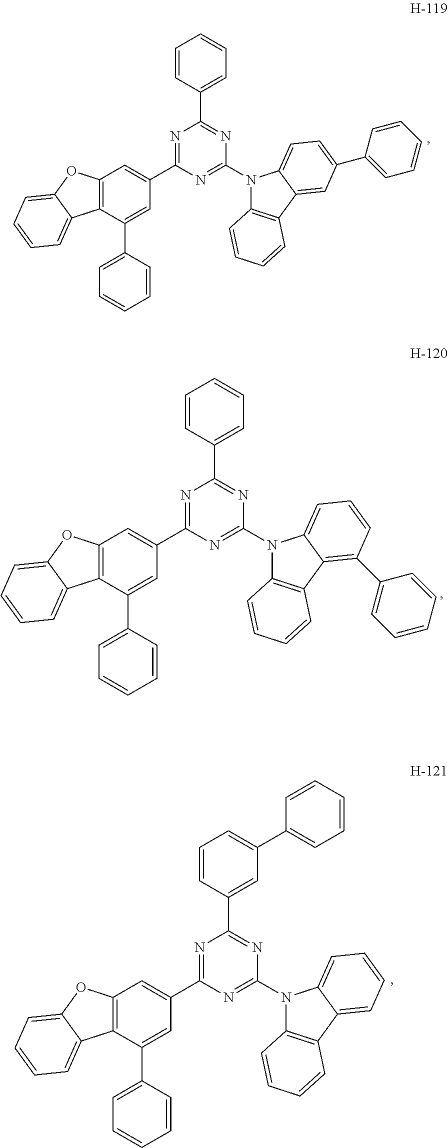 [SMILES: c1ccc(-c2ccc3c(c2)c2ccccc2n3-c2nc(-c3ccccc3)nc(-c3cc(-c4ccccc4)c4c(c3)oc3ccccc34)n2)cc1 ; c1ccc(-c2nc(-c3cc(-c4ccccc4)c4c(c3)oc3ccccc34)nc(-n3c4ccccc4c4c(-c5ccccc5)cccc43)n2)cc1 ; c1ccc(-c2cccc(-c3nc(-c4cc(-c5ccccc5)c5c(c4)oc4ccccc45)nc(-n4c5ccccc5c5ccccc54)n3)c2)cc1]

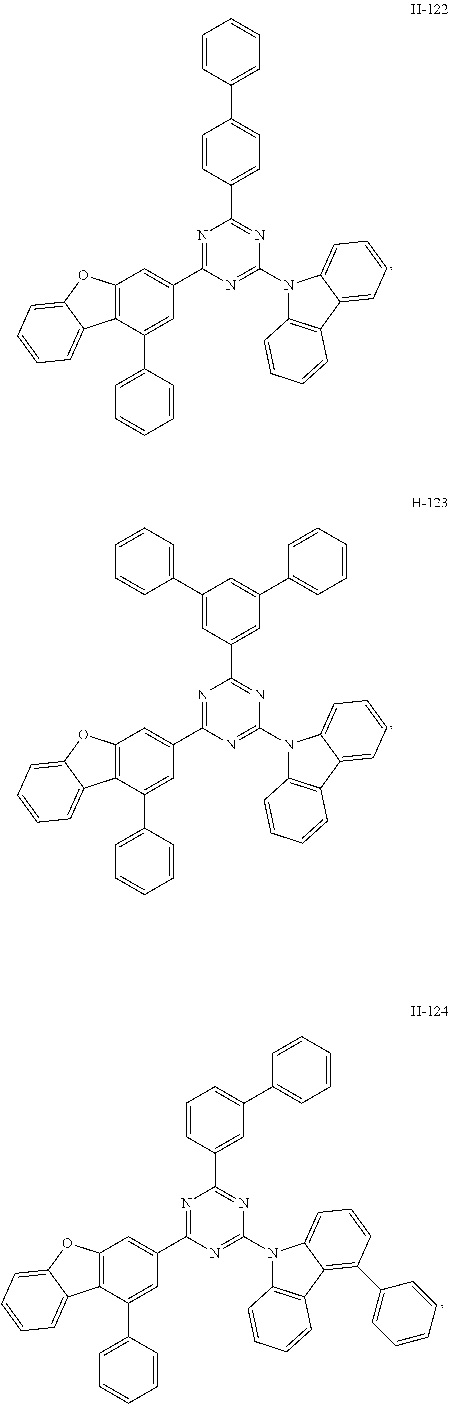 [SMILES: c1ccc(-c2ccc(-c3nc(-c4cc(-c5ccccc5)c5c(c4)oc4ccccc45)nc(-n4c5ccccc5c5ccccc54)n3)cc2)cc1 ; c1ccc(-c2cc(-c3ccccc3)cc(-c3nc(-c4cc(-c5ccccc5)c5c(c4)oc4ccccc45)nc(-n4c5ccccc5c5ccccc54)n3)c2)cc1 ; c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1]

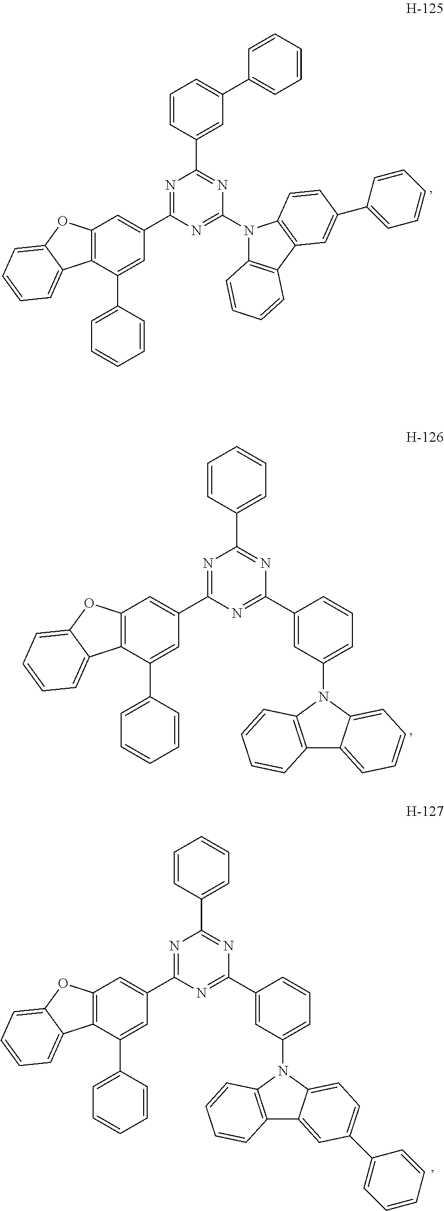 [SMILES: c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3cc(-c4ccccc4)c4c(c3)oc3ccccc34)n2)cc1 ; c1ccc(-c2ccc3c(c2)c2ccccc2n3-c2cccc(-c3nc(-c4ccccc4)nc(-c4cc(-c5ccccc5)c5c(c4)oc4ccccc45)n3)c2)cc1]

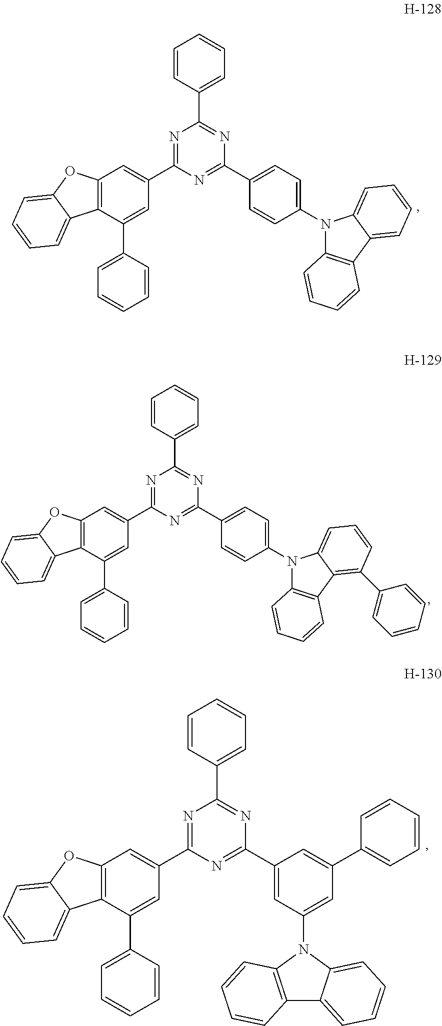 [SMILES: c1ccc(-c2nc(-c3ccc(-n4c5ccccc5c5ccccc54)cc3)nc(-c3cc(-c4ccccc4)c4c(c3)oc3ccccc34)n2)cc1 ; c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2cc(-c3nc(-c4ccccc4)nc(-c4cc(-c5ccccc5)c5c(c4)oc4ccccc45)n3)cc(-n3c4ccccc4c4ccccc43)c2)cc1]

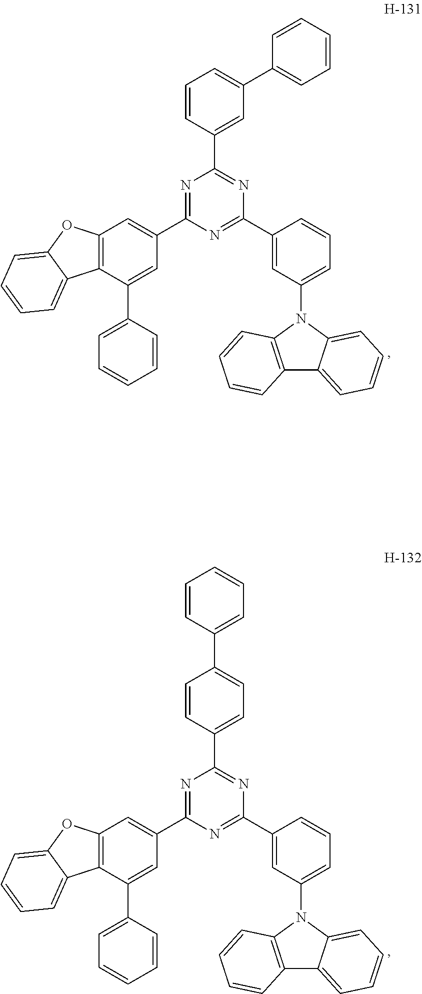 [SMILES: c1ccc(-c2cccc(-c3nc(-c4cccc(-n5c6ccccc6c6ccccc65)c4)nc(-c4cc(-c5ccccc5)c5c(c4)oc4ccccc45)n3)c2)cc1 ; c1ccc(-c2ccc(-c3nc(-c4cccc(-n5c6ccccc6c6ccccc65)c4)nc(-c4cc(-c5ccccc5)c5c(c4)oc4ccccc45)n3)cc2)cc1]

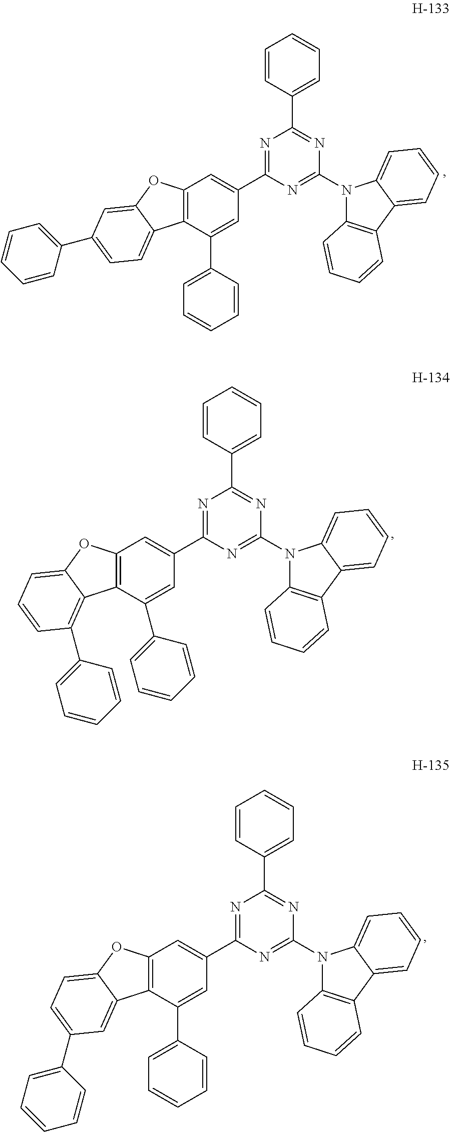 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2nc(-c3cc(-c4ccccc4)c4c(c3)oc3cccc(-c5ccccc5)c34)nc(-n3c4ccccc4c4ccccc43)n2)cc1 ; c1ccc(-c2ccc3oc4cc(-c5nc(-c6ccccc6)nc(-n6c7ccccc7c7ccccc76)n5)cc(-c5ccccc5)c4c3c2)cc1]

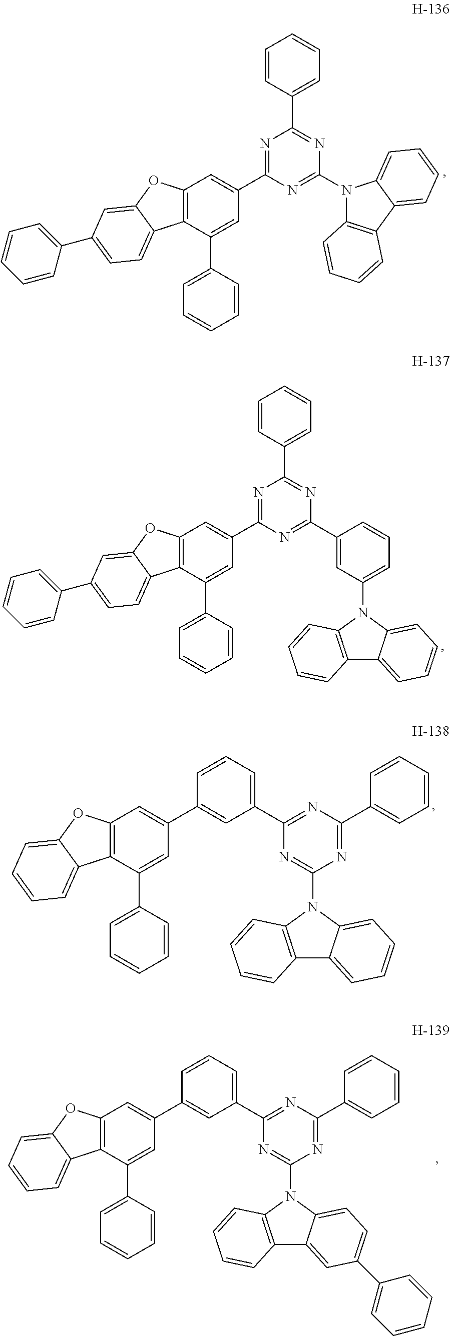 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1]

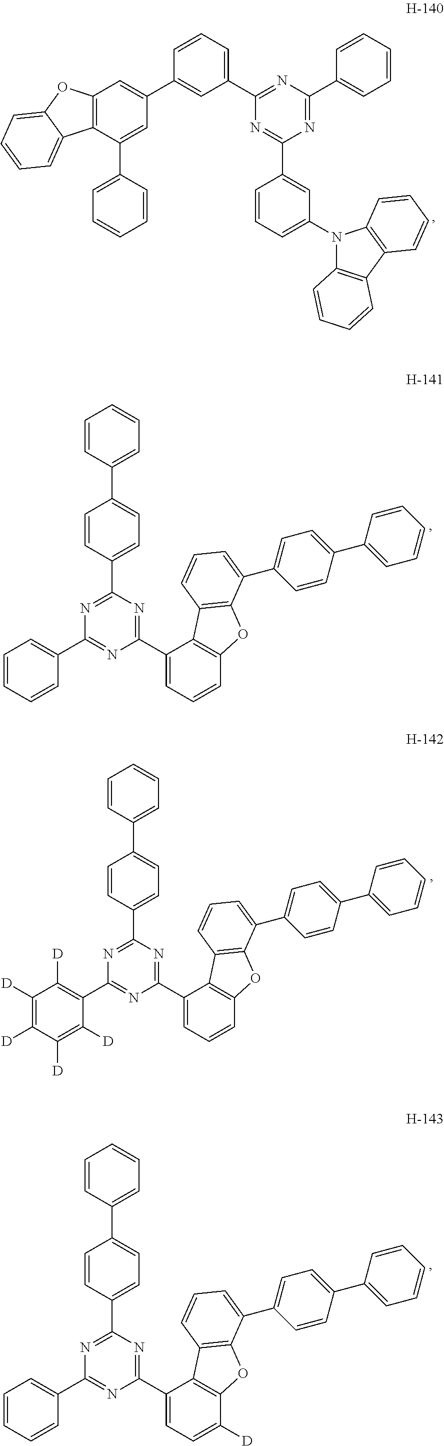 [SMILES: c1ccc(-c2nc(-c3cccc(-c4cc(-c5ccccc5)c5c(c4)oc4ccccc45)c3)nc(-c3cccc(-n4c5ccccc5c5ccccc54)c3)n2)cc1 ; c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12]

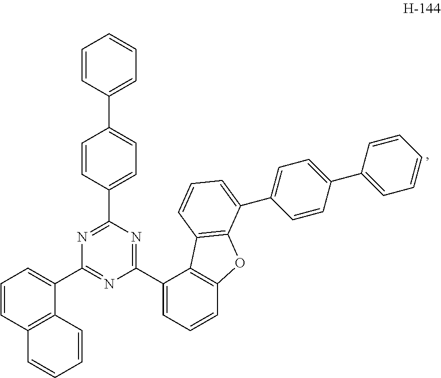 [SMILES: c1ccc(-c2ccc(-c3nc(-c4cccc5ccccc45)nc(-c4cccc5oc6c(-c7ccc(-c8ccccc8)cc7)cccc6c45)n3)cc2)cc1]

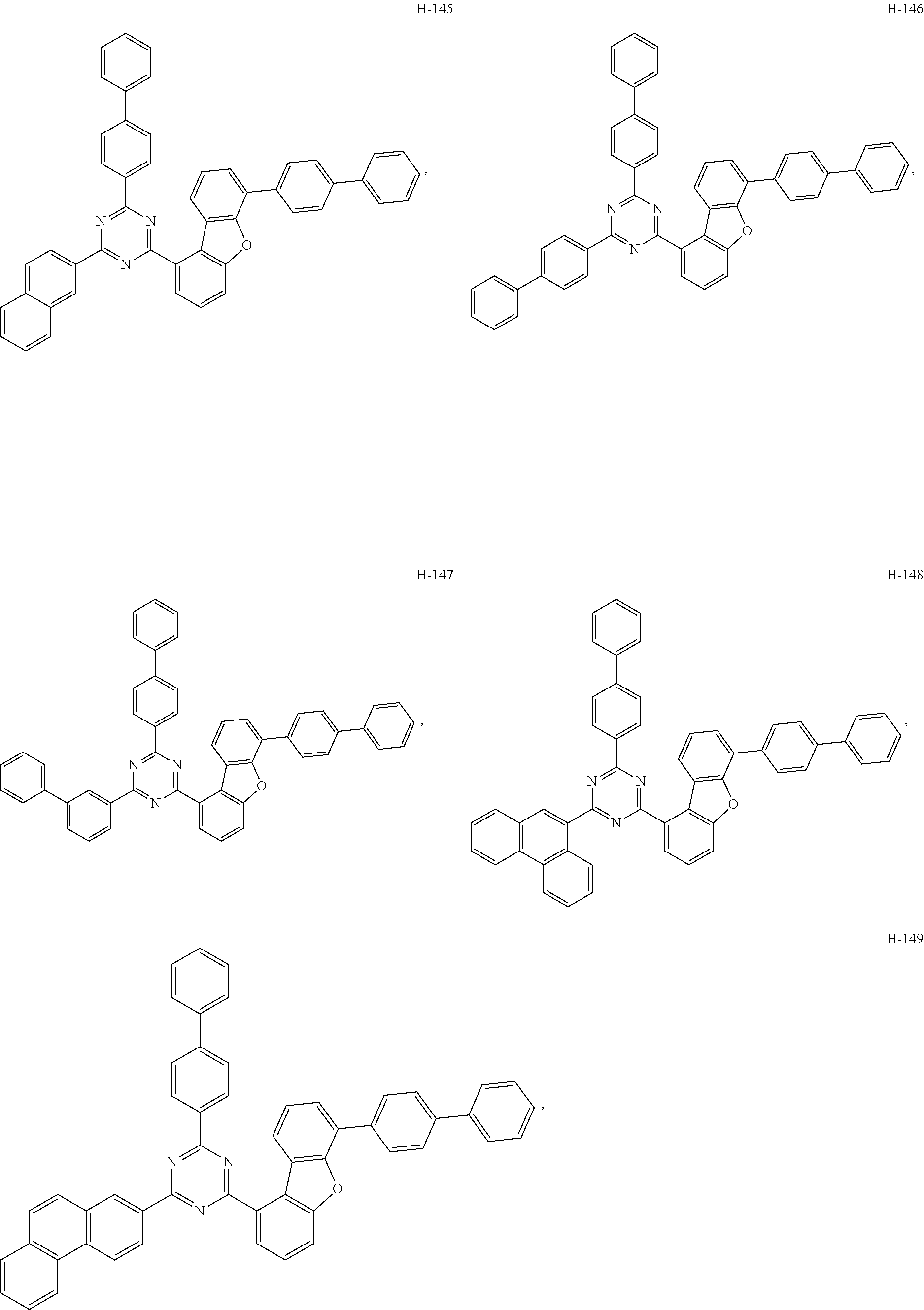 [SMILES: c1ccc(-c2ccc(-c3nc(-c4ccc5ccccc5c4)nc(-c4cccc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1 ; c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1]

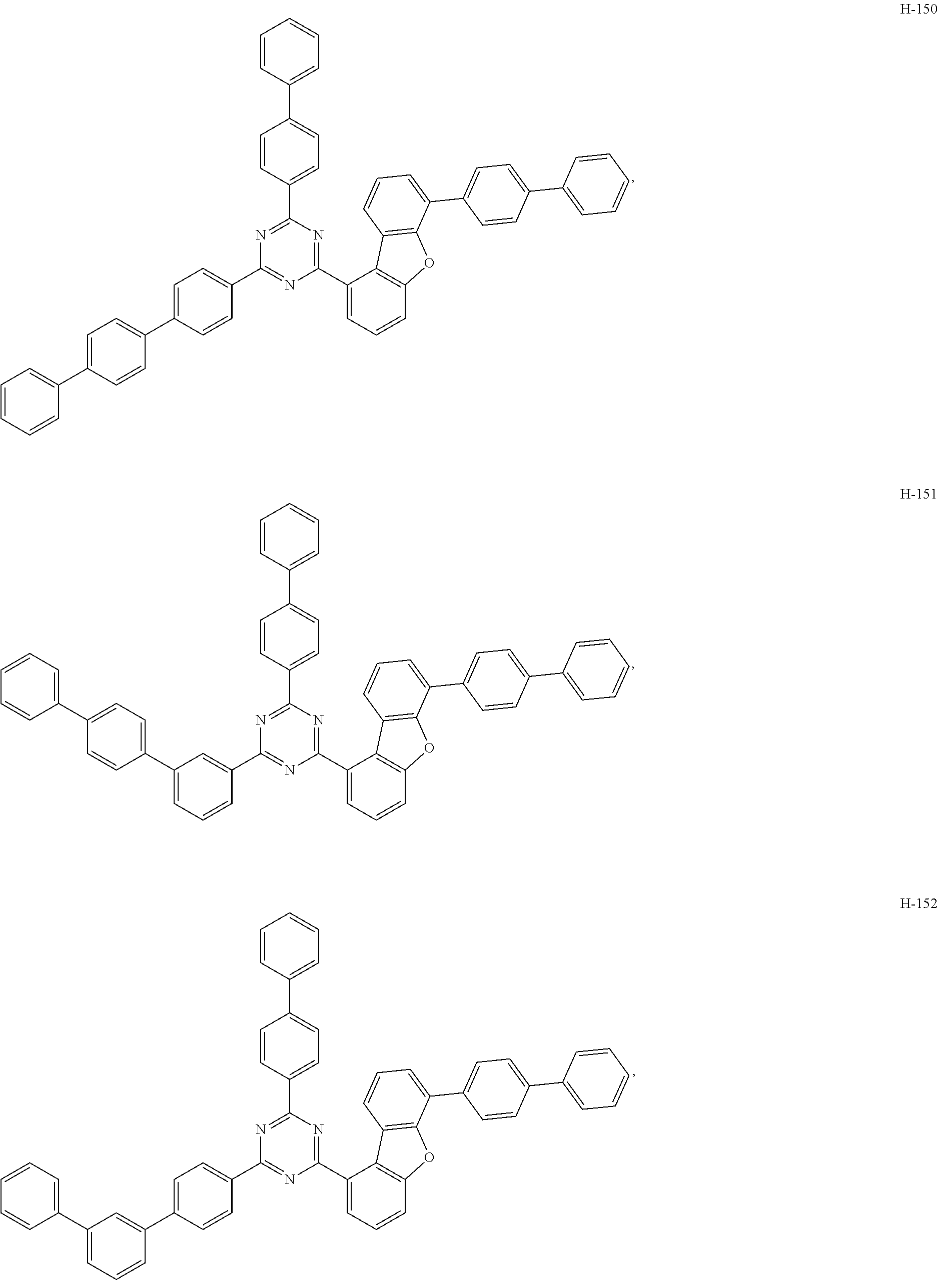 [SMILES: c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1 ; c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1]

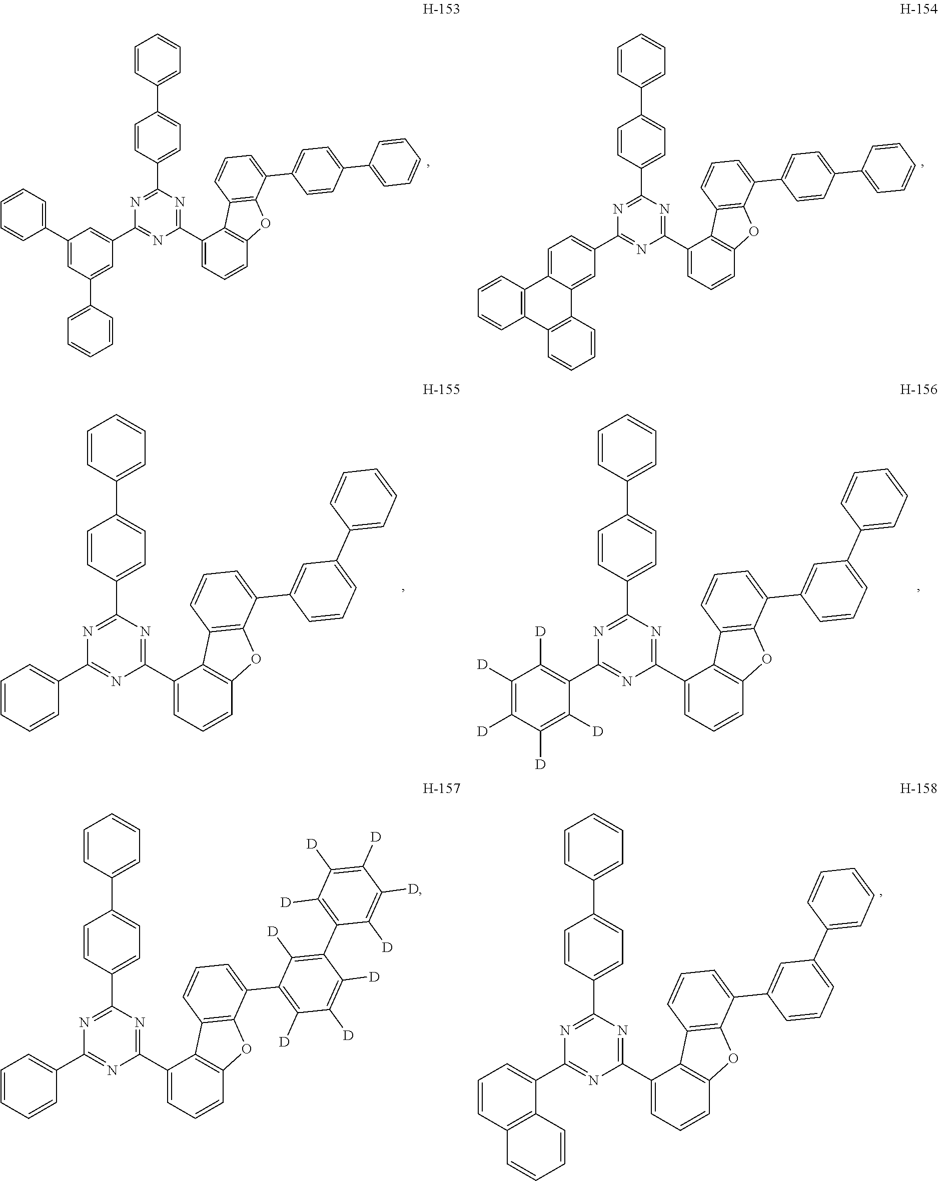

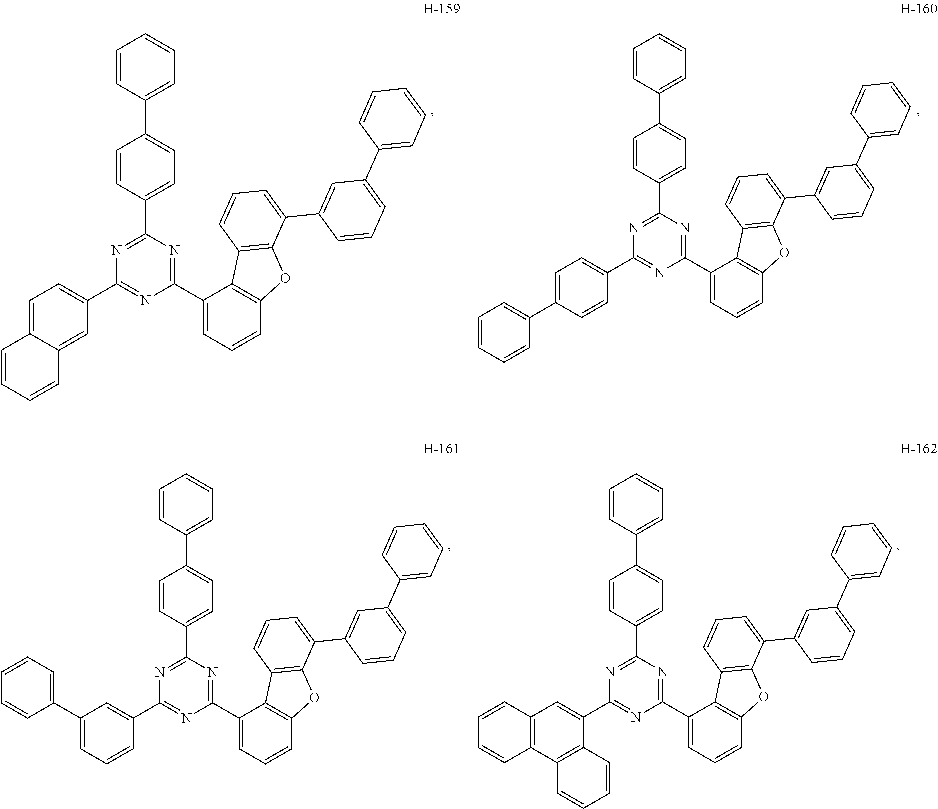 [SMILES: c1ccc(-c2ccc(-c3nc(-c4ccc5ccccc5c4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4cc5ccccc5c5ccccc45)nc(-c4cccc5oc6c(-c7cccc(-c8ccccc8)c7)cccc6c45)n3)cc2)cc1]

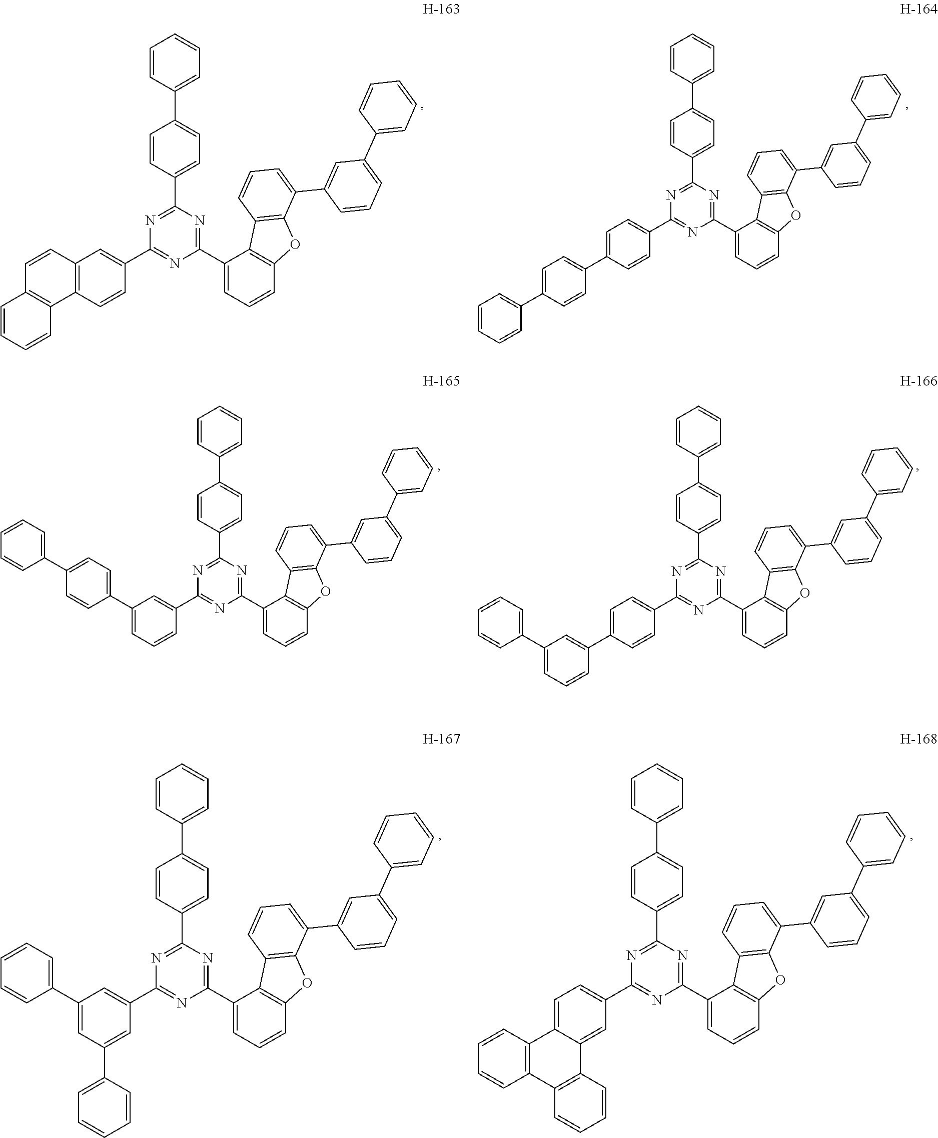

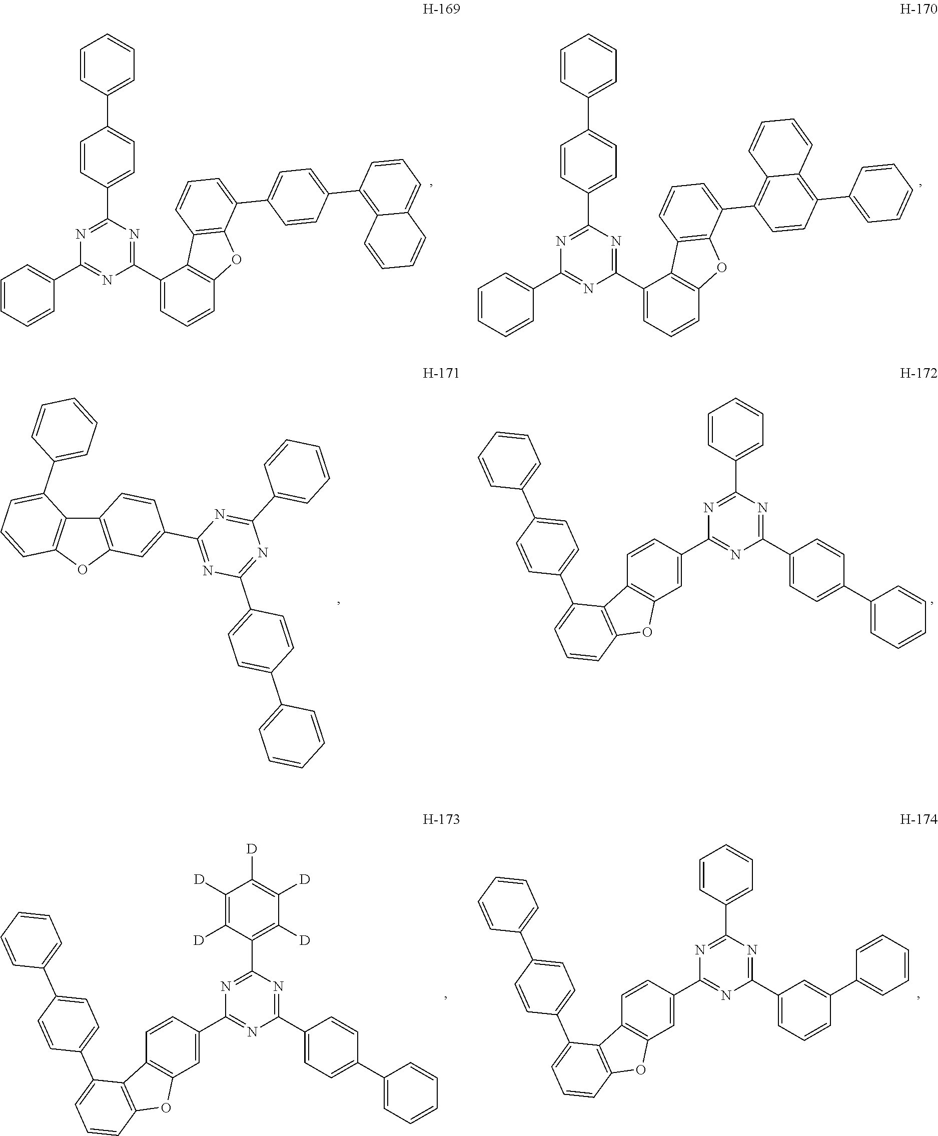

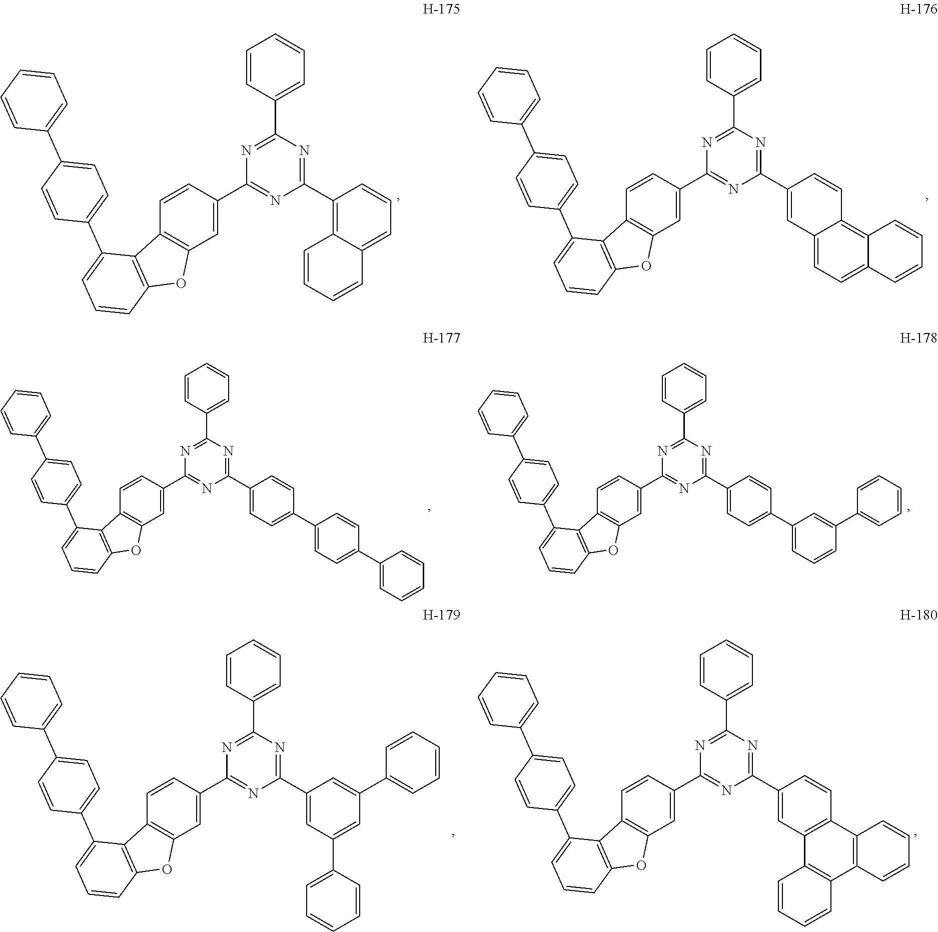

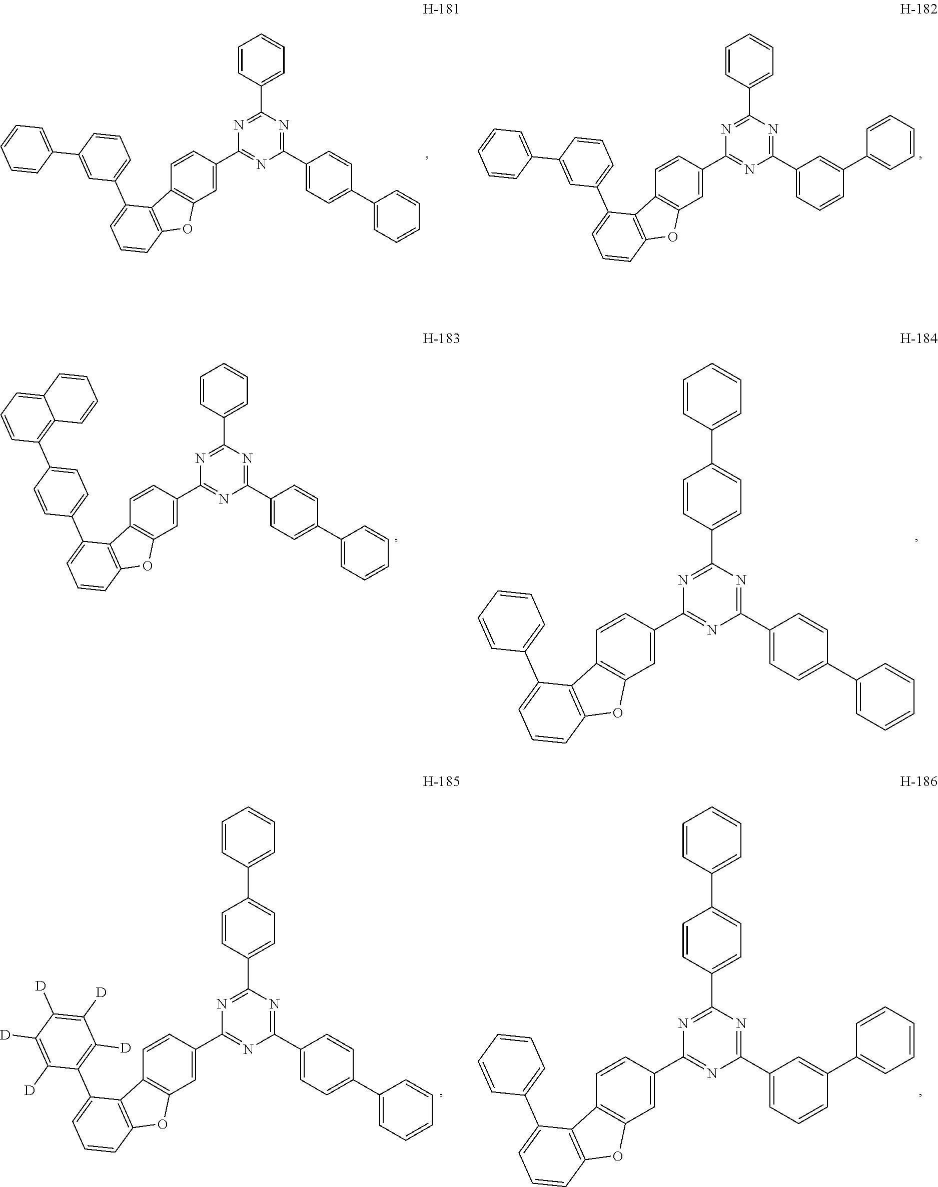

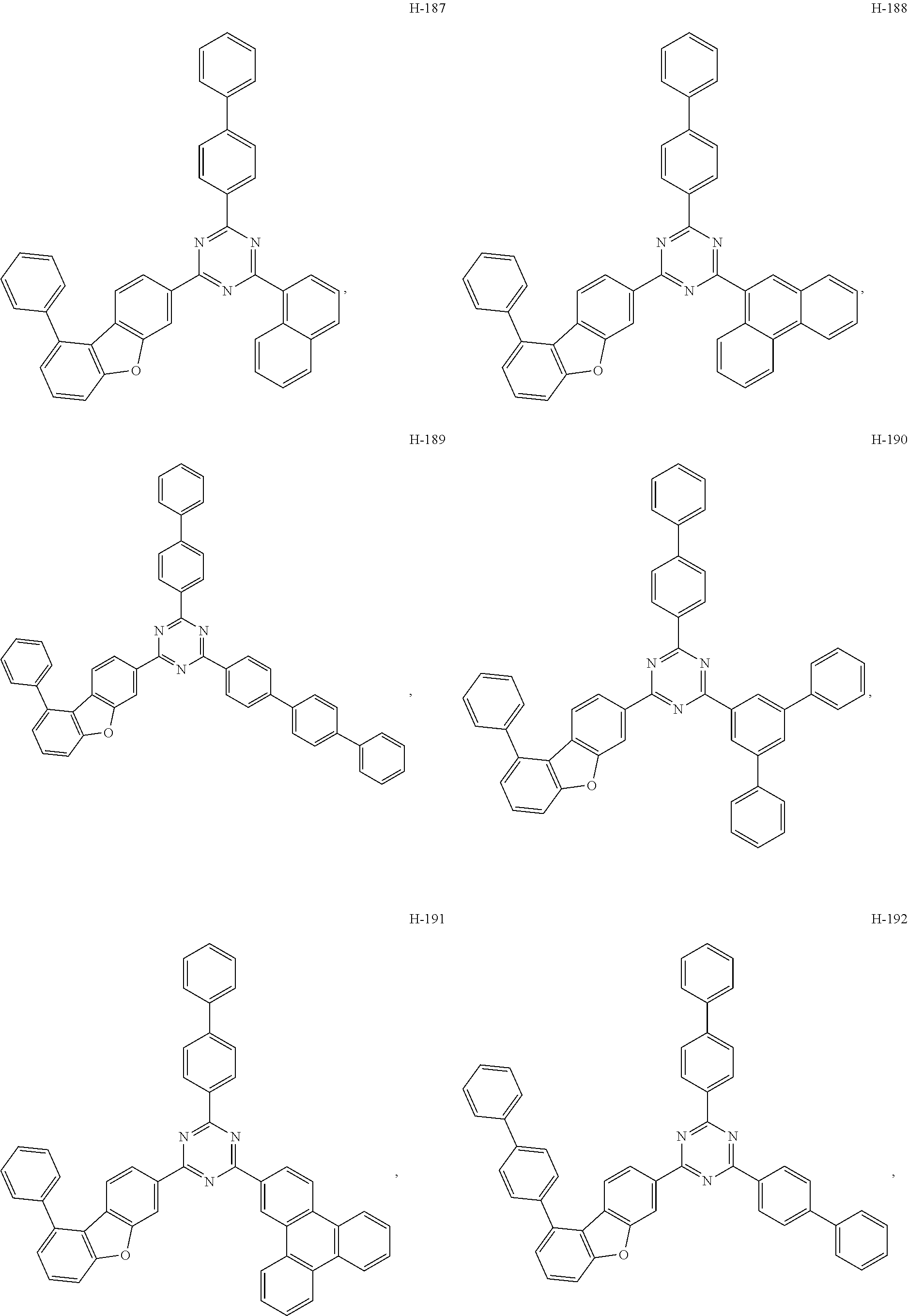

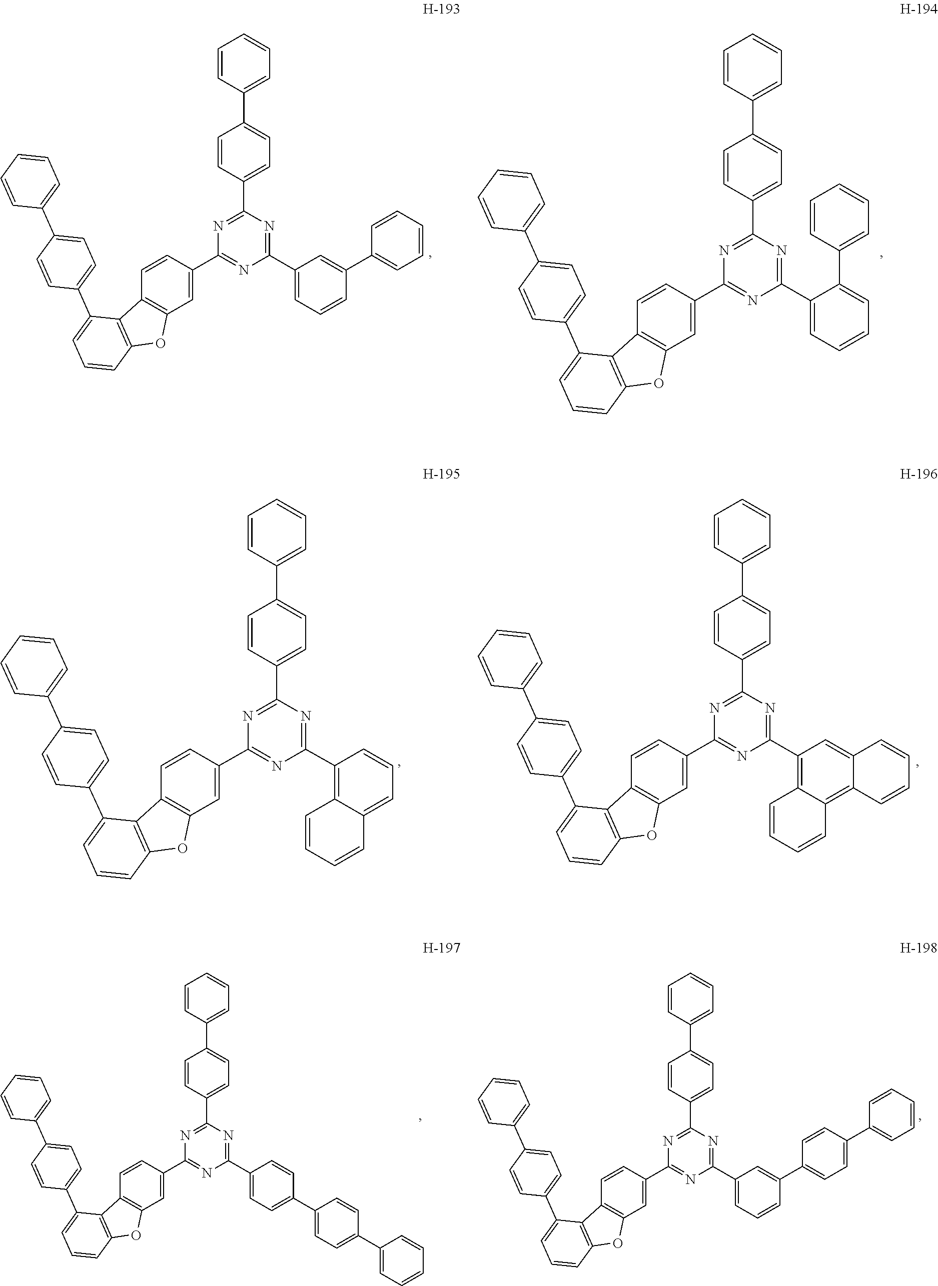

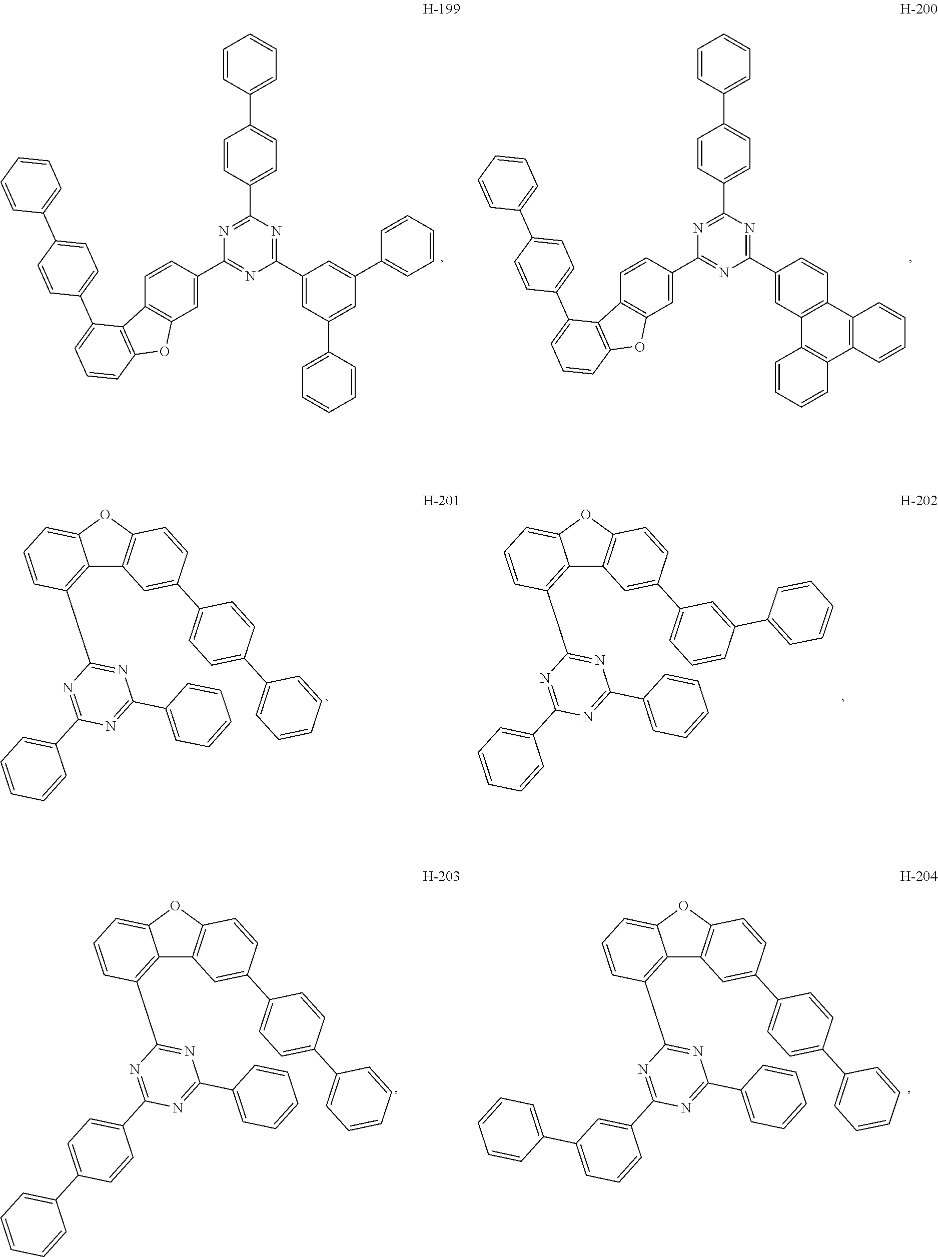

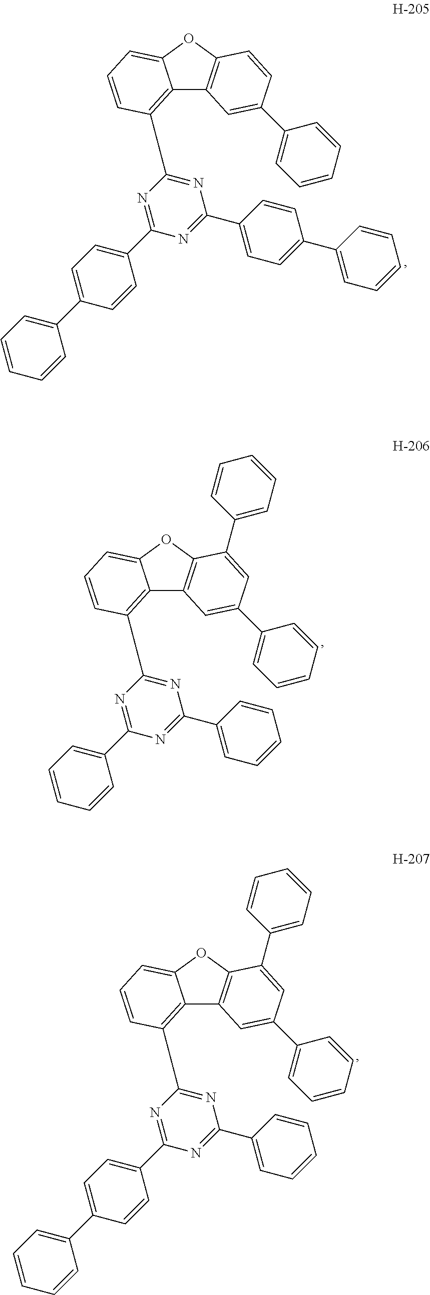 [SMILES: c1ccc(-c2ccc(-c3nc(-c4ccc(-c5ccccc5)cc4)nc(-c4cccc5oc6ccc(-c7ccccc7)cc6c45)n3)cc2)cc1 ; c1ccc(-c2cc(-c3ccccc3)c3oc4cccc(-c5nc(-c6ccccc6)nc(-c6ccccc6)n5)c4c3c2)cc1 ; c1ccc(-c2ccc(-c3nc(-c4ccccc4)nc(-c4cccc5oc6c(-c7ccccc7)cc(-c7ccccc7)cc6c45)n3)cc2)cc1]

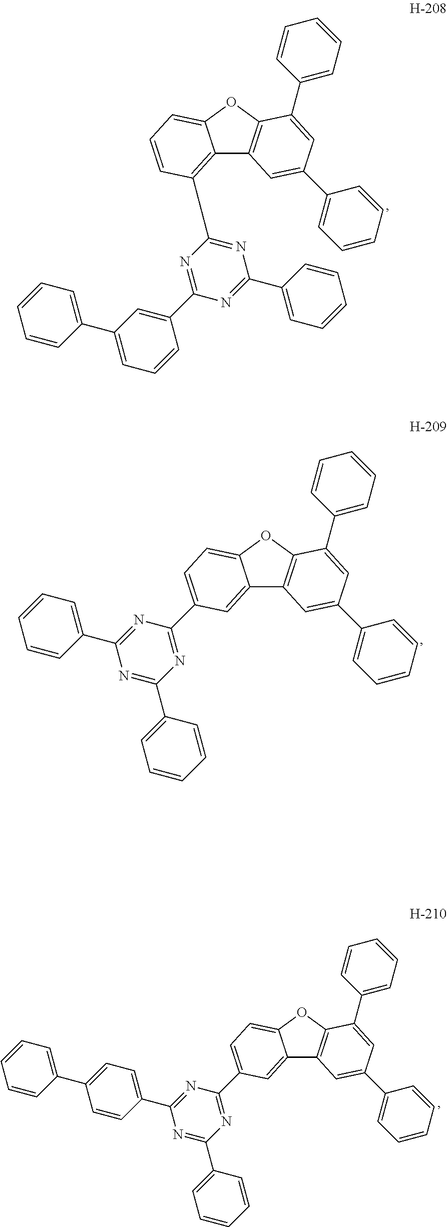 [SMILES: c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1]

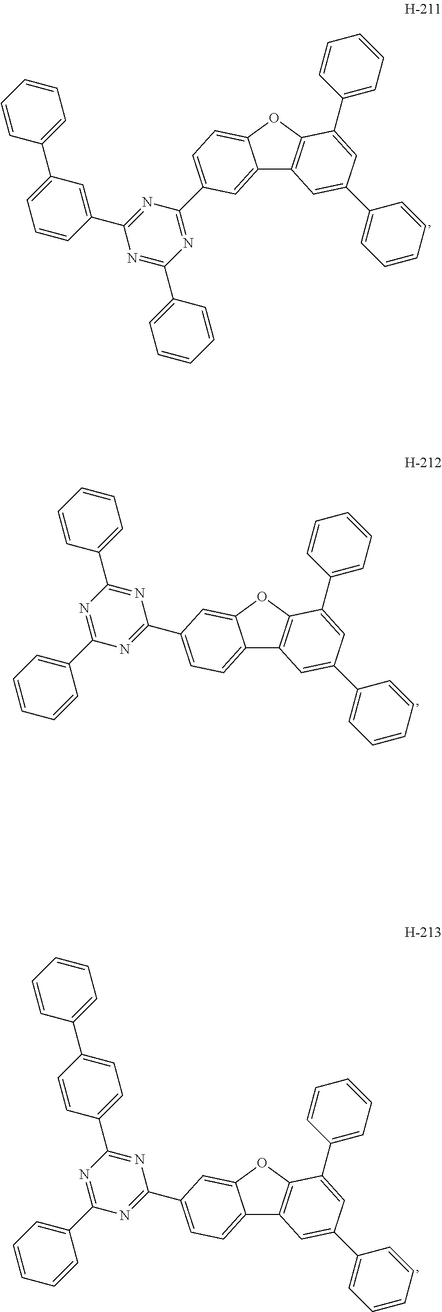 [SMILES: c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2cc(-c3ccccc3)c3oc4cc(-c5nc(-c6ccccc6)nc(-c6ccccc6)n5)ccc4c3c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1]

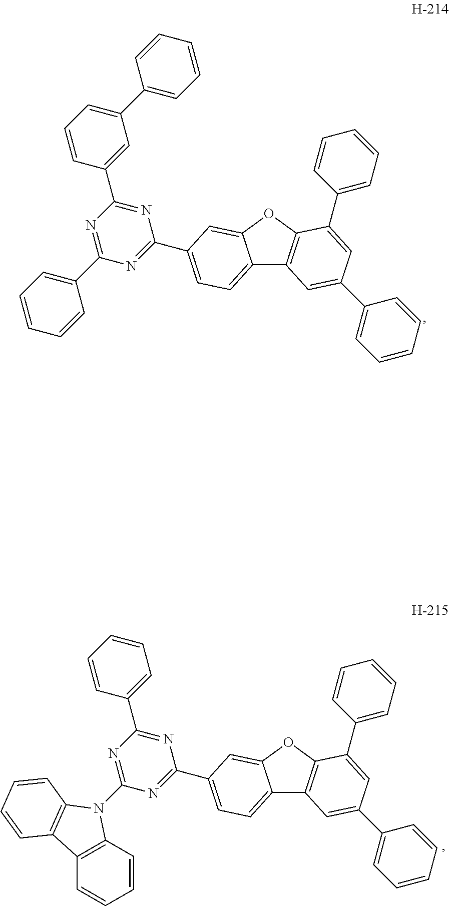 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1]

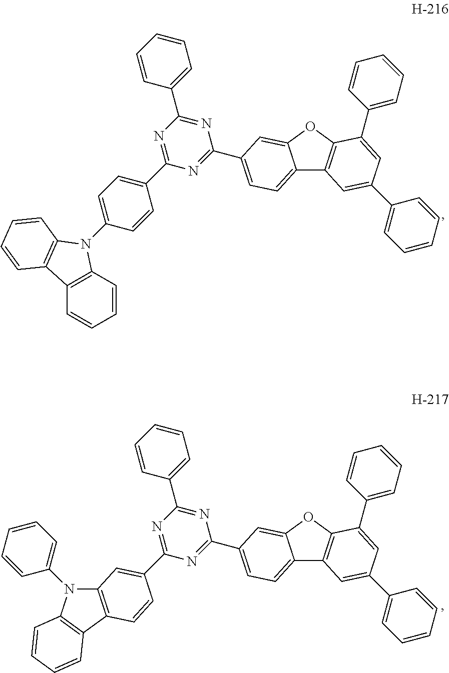 [SMILES: c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1]

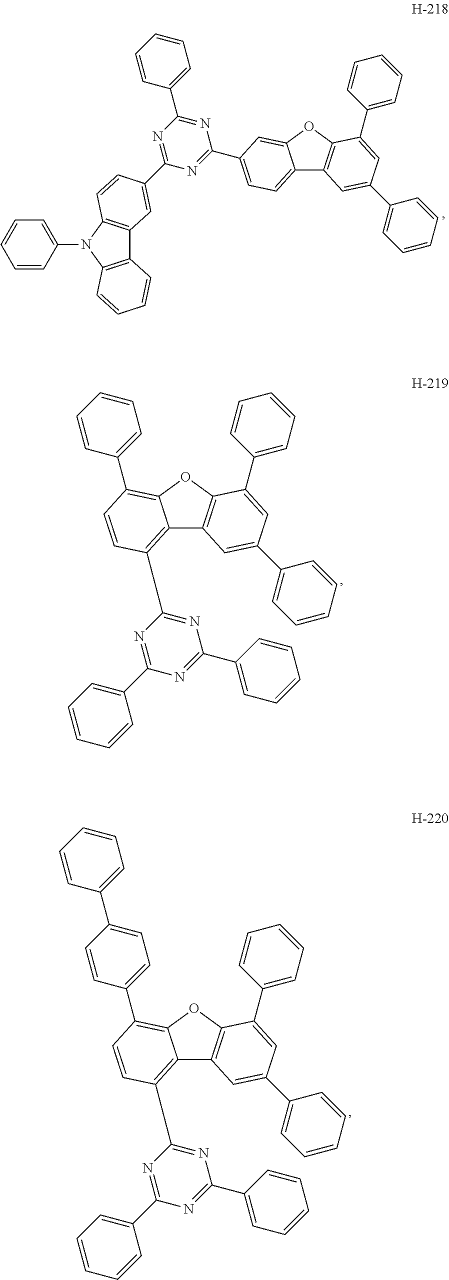 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2cc(-c3ccccc3)c3oc4c(-c5ccccc5)ccc(-c5nc(-c6ccccc6)nc(-c6ccccc6)n5)c4c3c2)cc1 ; c1ccc(-c2ccc(-c3ccc(-c4nc(-c5ccccc5)nc(-c5ccccc5)n4)c4c3oc3c(-c5ccccc5)cc(-c5ccccc5)cc34)cc2)cc1]

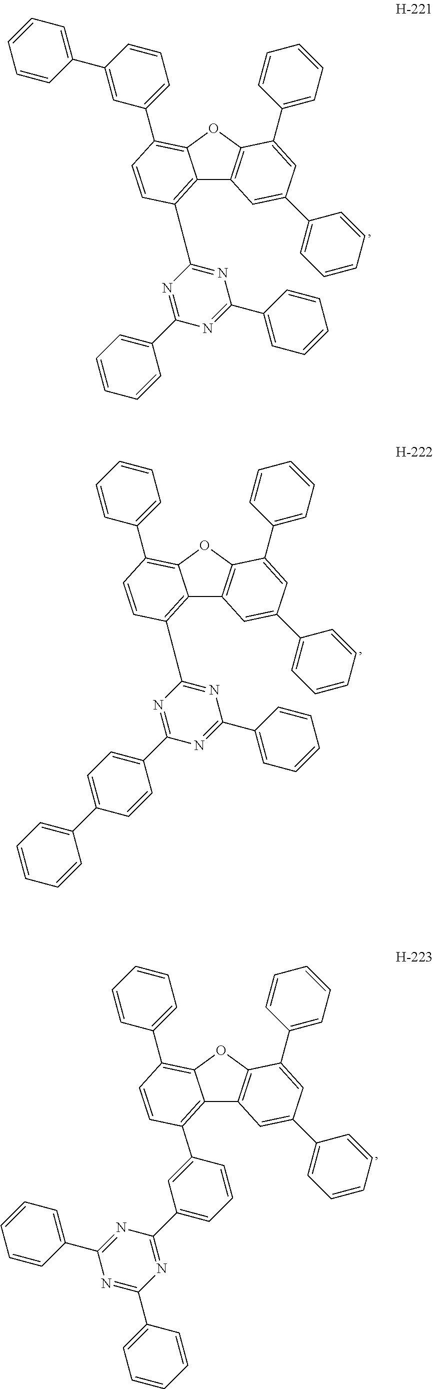 [SMILES: c1ccc(-c2cccc(-c3ccc(-c4nc(-c5ccccc5)nc(-c5ccccc5)n4)c4c3oc3c(-c5ccccc5)cc(-c5ccccc5)cc34)c2)cc1 ; c1ccc(-c2ccc(-c3nc(-c4ccccc4)nc(-c4ccc(-c5ccccc5)c5oc6c(-c7ccccc7)cc(-c7ccccc7)cc6c45)n3)cc2)cc1 ; c1ccc(-c2cc(-c3ccccc3)c3oc4c(-c5ccccc5)ccc(-c5cccc(-c6nc(-c7ccccc7)nc(-c7ccccc7)n6)c5)c4c3c2)cc1]

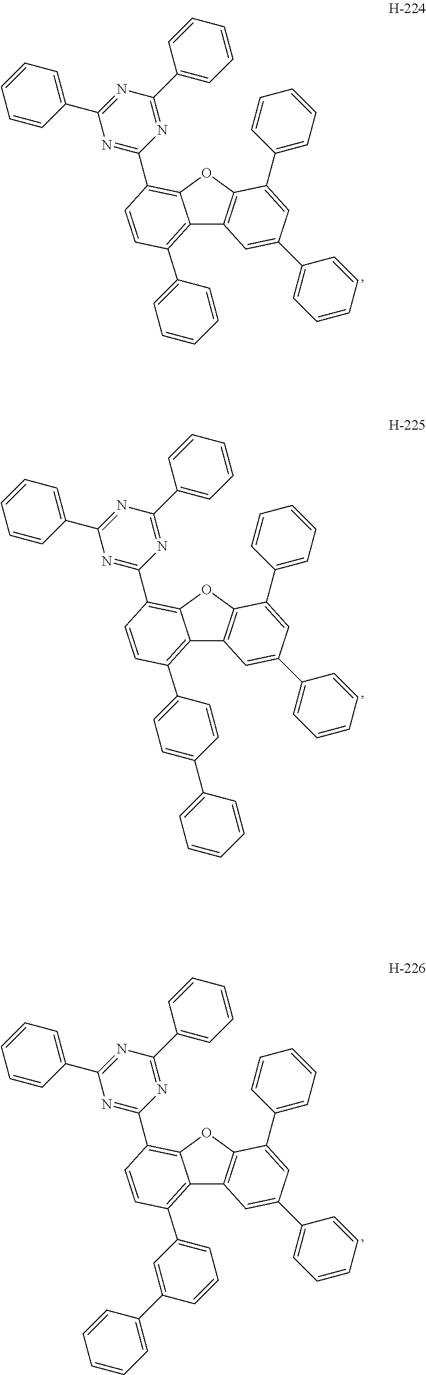 [SMILES: c1ccc(-c2cc(-c3ccccc3)c3oc4c(-c5nc(-c6ccccc6)nc(-c6ccccc6)n5)ccc(-c5ccccc5)c4c3c2)cc1 ; c1ccc(-c2ccc(-c3ccc(-c4nc(-c5ccccc5)nc(-c5ccccc5)n4)c4oc5c(-c6ccccc6)cc(-c6ccccc6)cc5c34)cc2)cc1 ; c1ccc(-c2cccc(-c3ccc(-c4nc(-c5ccccc5)nc(-c5ccccc5)n4)c4oc5c(-c6ccccc6)cc(-c6ccccc6)cc5c34)c2)cc1]

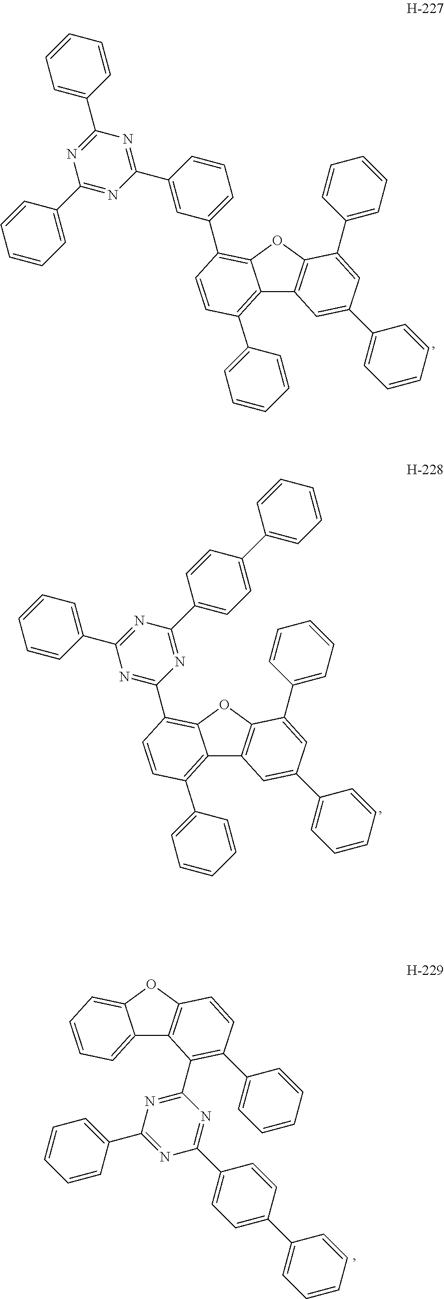 [SMILES: c1ccc(-c2cc(-c3ccccc3)c3oc4c(-c5cccc(-c6nc(-c7ccccc7)nc(-c7ccccc7)n6)c5)ccc(-c5ccccc5)c4c3c2)cc1 ; c1ccc(-c2ccc(-c3nc(-c4ccccc4)nc(-c4ccc(-c5ccccc5)c5c4oc4c(-c6ccccc6)cc(-c6ccccc6)cc45)n3)cc2)cc1 ; c1ccc(-c2ccc(-c3nc(-c4ccccc4)nc(-c4c(-c5ccccc5)ccc5oc6ccccc6c45)n3)cc2)cc1]

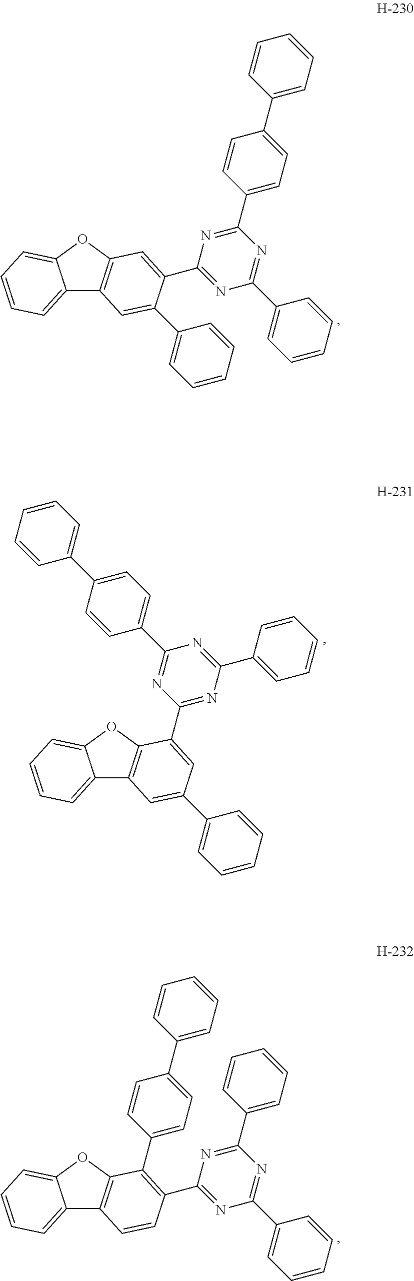 [SMILES: c1ccc(-c2ccc(-c3nc(-c4ccccc4)nc(-c4cc5oc6ccccc6c5cc4-c4ccccc4)n3)cc2)cc1 ; c1ccc(-c2ccc(-c3nc(-c4ccccc4)nc(-c4cc(-c5ccccc5)cc5c4oc4ccccc45)n3)cc2)cc1 ; c1ccc(-c2ccc(-c3c(-c4nc(-c5ccccc5)nc(-c5ccccc5)n4)ccc4c3oc3ccccc34)cc2)cc1]

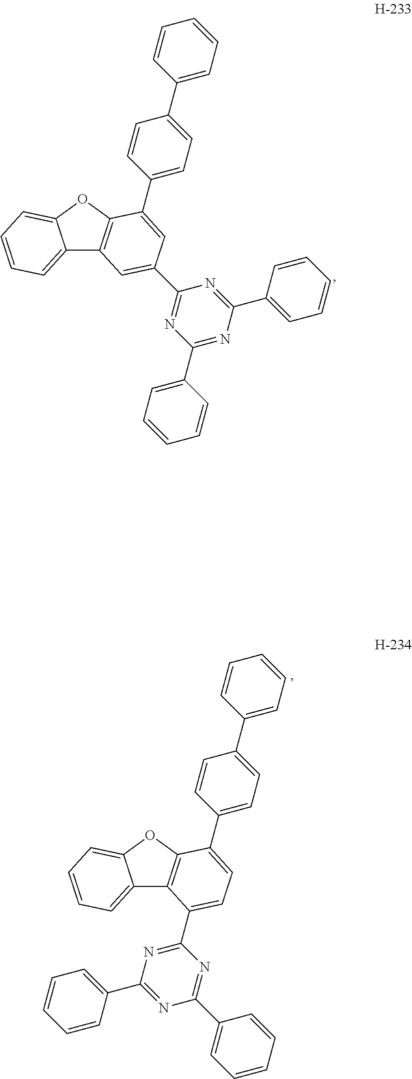 [SMILES: c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1]

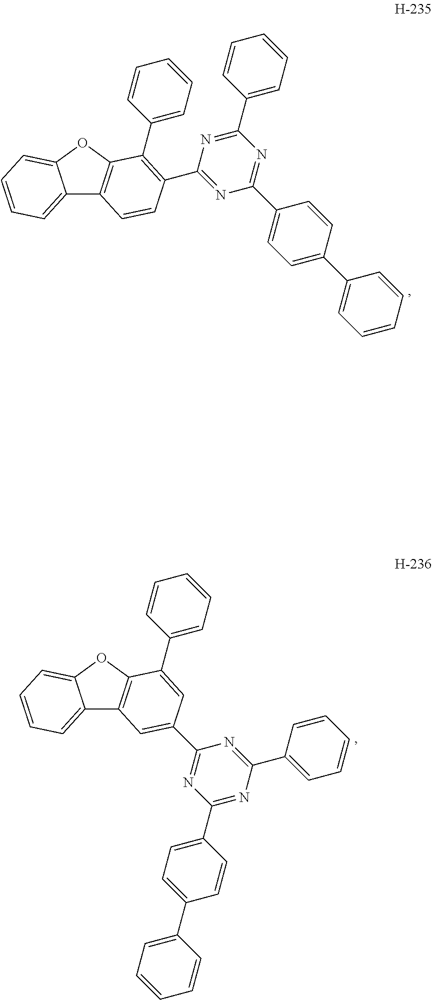 [SMILES: c1ccc(-c2ccc(-c3nc(-c4ccccc4)nc(-c4ccc5c(oc6ccccc65)c4-c4ccccc4)n3)cc2)cc1 ; c1ccc(-c2ccc(-c3nc(-c4ccccc4)nc(-c4cc(-c5ccccc5)c5oc6ccccc6c5c4)n3)cc2)cc1]

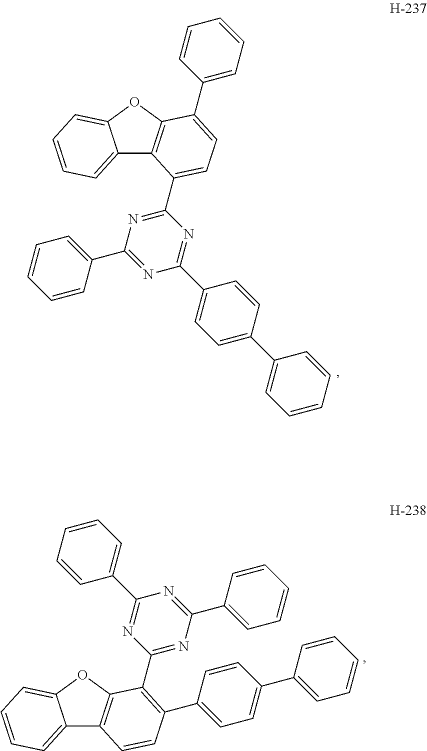 [SMILES: c1ccc(-c2ccc(-c3nc(-c4ccccc4)nc(-c4ccc(-c5ccccc5)c5oc6ccccc6c45)n3)cc2)cc1 ; c1ccc(-c2ccc(-c3ccc4c(oc5ccccc54)c3-c3nc(-c4ccccc4)nc(-c4ccccc4)n3)cc2)cc1]

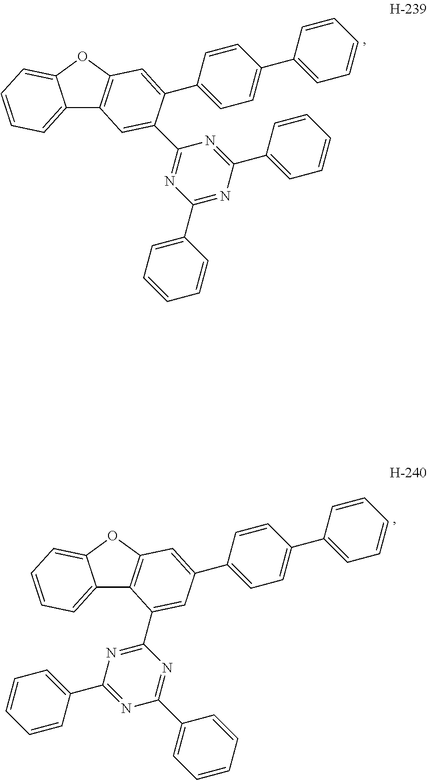 [SMILES: c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1]

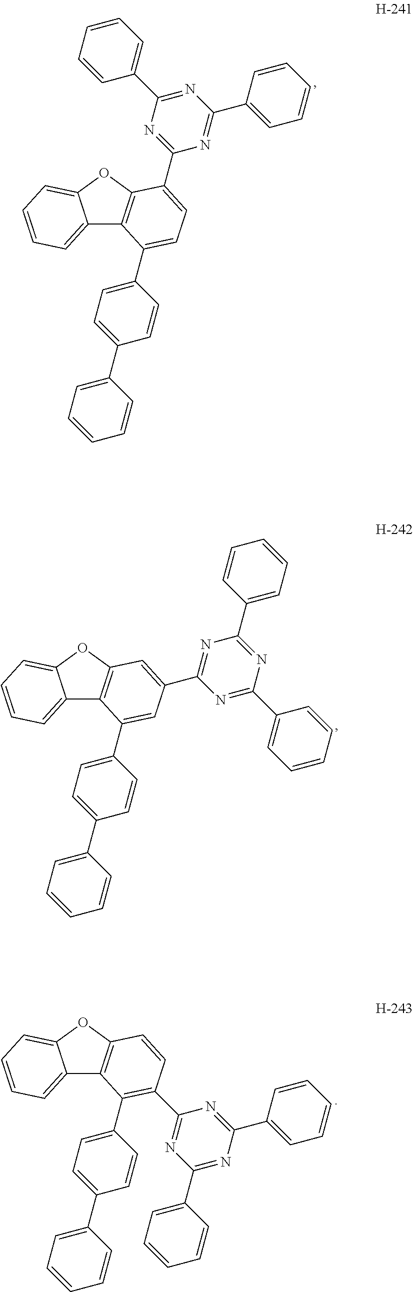 [SMILES: c1ccc(-c2ccc(-c3ccc(-c4nc(-c5ccccc5)nc(-c5ccccc5)n4)c4oc5ccccc5c34)cc2)cc1 ; c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1]

According to another embodiment of the present disclosure, the first host compound is selected from the group consisting of H-244 to H-308, wherein the structures of H-244 to H-308 are shown as follows:

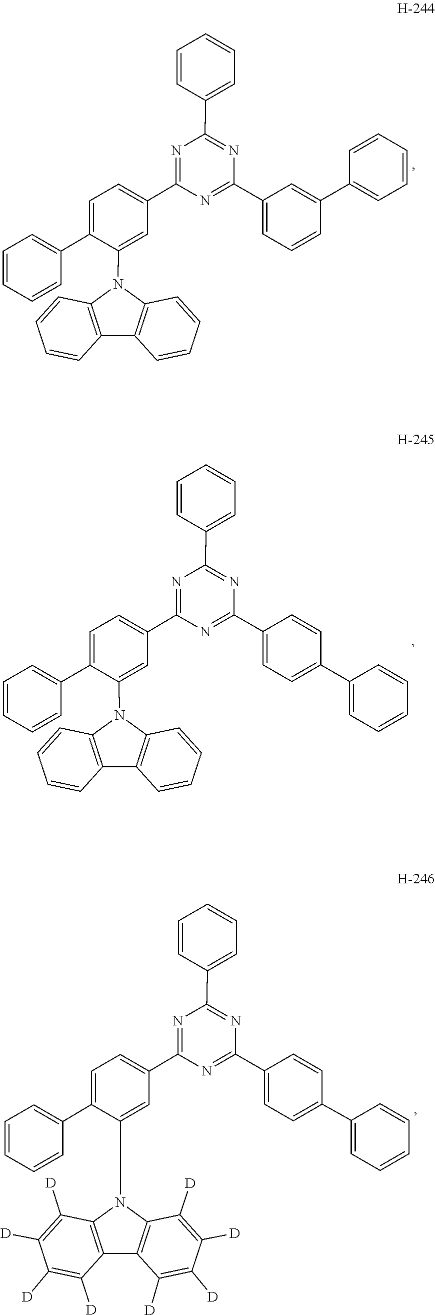 [SMILES: c1ccc(-c2cccc(-c3nc(-c4ccccc4)nc(-c4ccc(-c5ccccc5)c(-n5c6ccccc6c6ccccc65)c4)n3)c2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; [2H]c1c([2H])c([2H])c2c(c1[2H])c1c([2H])c([2H])c([2H])c([2H])c1n2-c1cc(-c2nc(-c3ccccc3)nc(-c3ccc(-c4ccccc4)cc3)n2)ccc1-c1ccccc1]

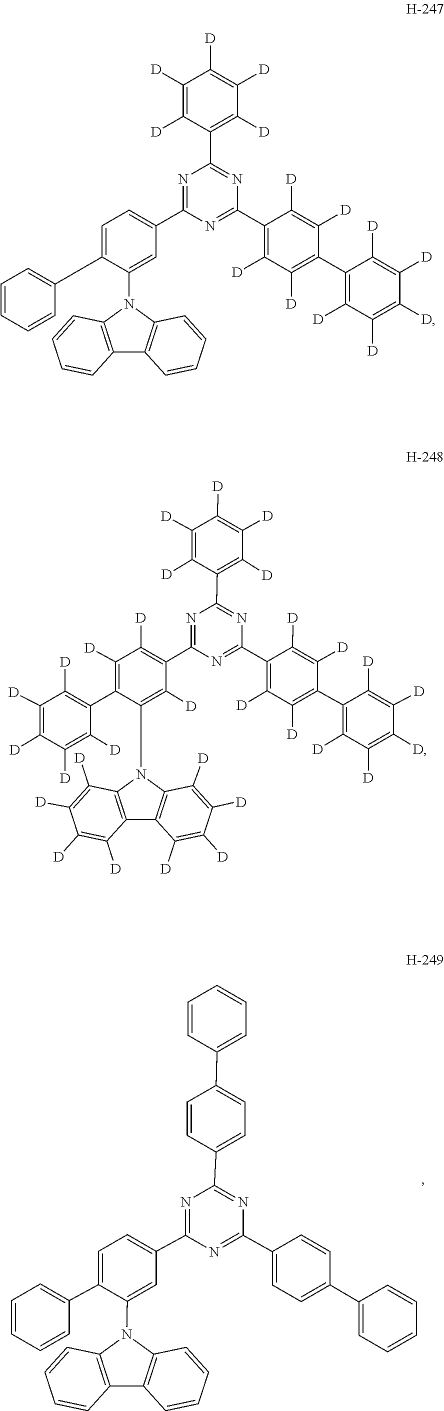

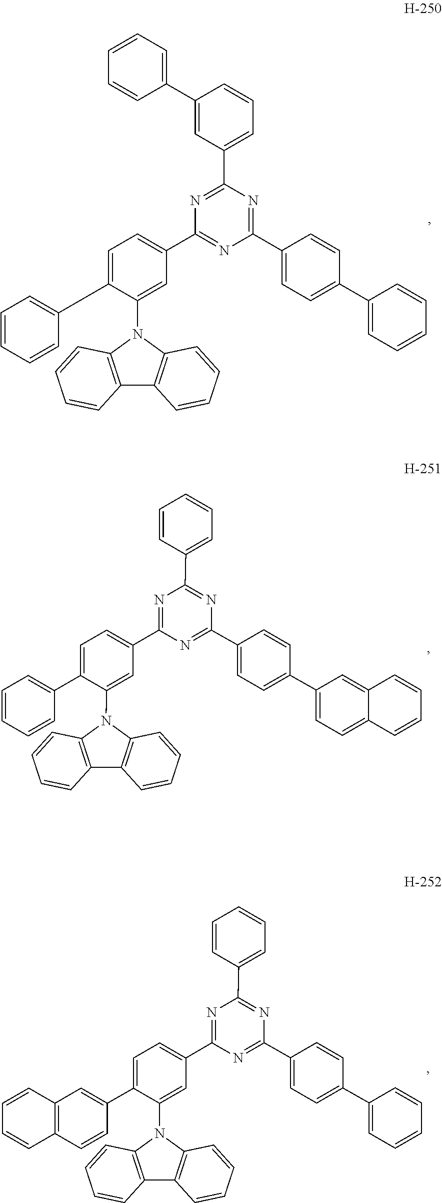 [SMILES: c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccc6ccccc6c5)c(-n5c6ccccc6c6ccccc65)c4)n3)cc2)cc1]

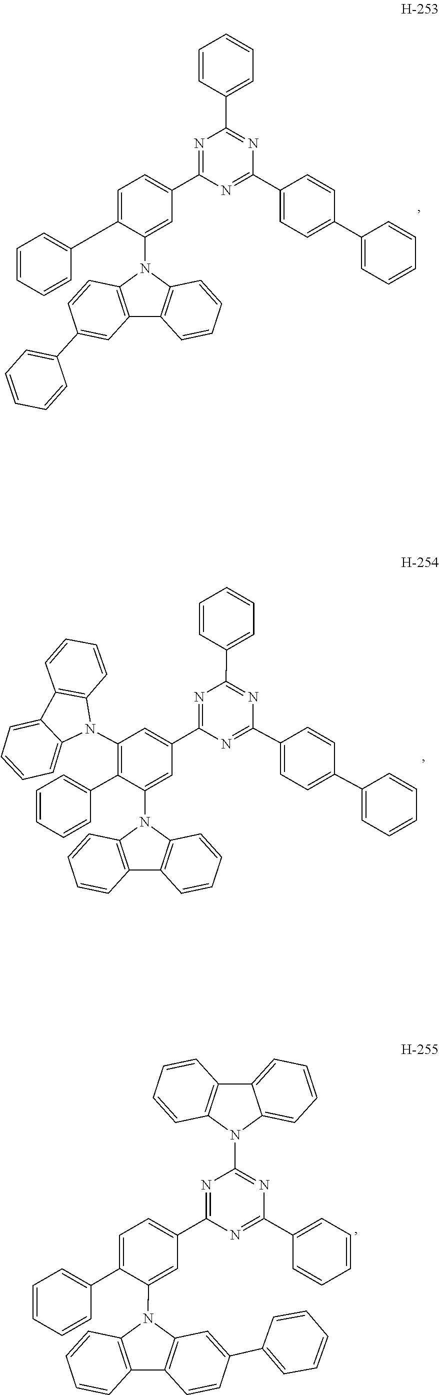 [SMILES: c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1 ; c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1 ; c1ccc(-c2ccc3c4ccccc4n(-c4cc(-c5nc(-c6ccccc6)nc(-n6c7ccccc7c7ccccc76)n5)ccc4-c4ccccc4)c3c2)cc1]

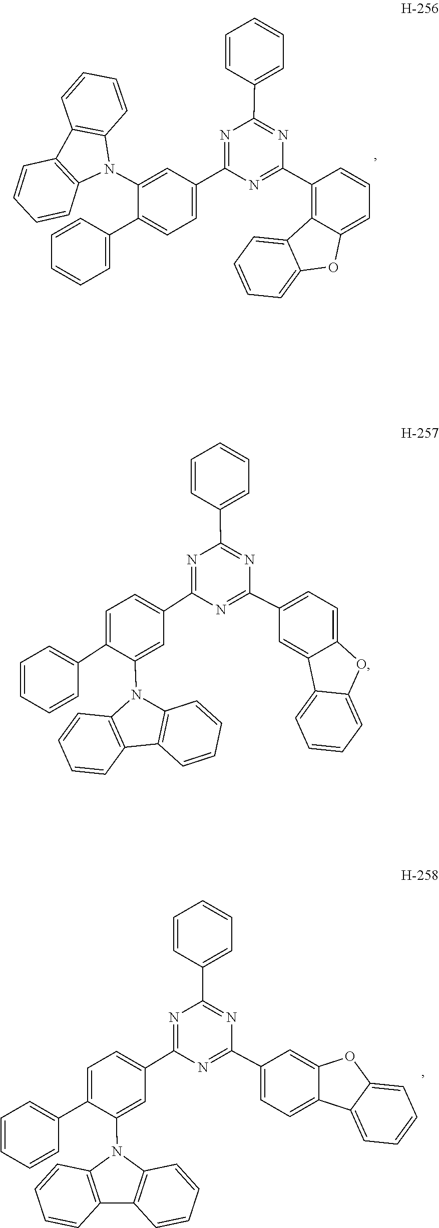 [SMILES: c1ccc(-c2nc(-c3ccc(-c4ccccc4)c(-n4c5ccccc5c5ccccc54)c3)nc(-c3cccc4oc5ccccc5c34)n2)cc1 ; c1ccc(-c2nc(-c3ccc(-c4ccccc4)c(-n4c5ccccc5c5ccccc54)c3)nc(-c3ccc4oc5ccccc5c4c3)n2)cc1 ; c1ccc(-c2nc(-c3ccc(-c4ccccc4)c(-n4c5ccccc5c5ccccc54)c3)nc(-c3ccc4c(c3)oc3ccccc34)n2)cc1]

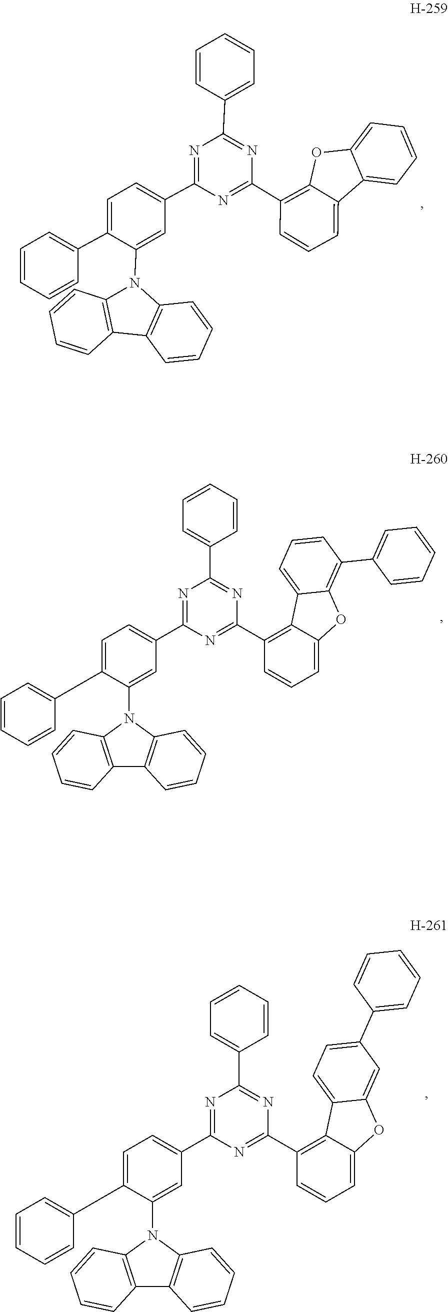 [SMILES: c1ccc(-c2nc(-c3ccc(-c4ccccc4)c(-n4c5ccccc5c5ccccc54)c3)nc(-c3cccc4c3oc3ccccc34)n2)cc1 ; c1ccc(-c2nc(-c3ccc(-c4ccccc4)c(-n4c5ccccc5c5ccccc54)c3)nc(-c3cccc4oc5c(-c6ccccc6)cccc5c34)n2)cc1 ; c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1]

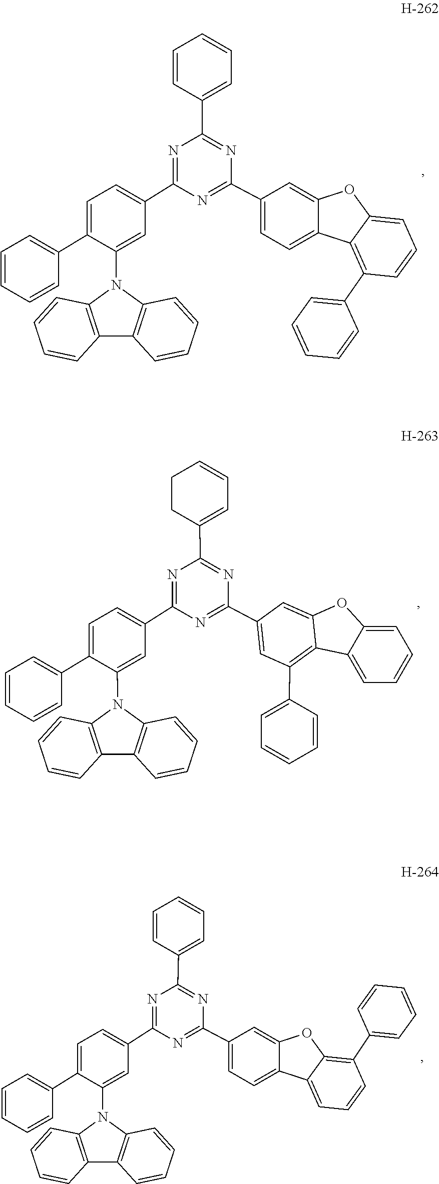 [SMILES: c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1 ; C1=CCCC(c2nc(-c3ccc(-c4ccccc4)c(-n4c5ccccc5c5ccccc54)c3)nc(-c3cc(-c4ccccc4)c4c(c3)oc3ccccc34)n2)=C1 ; c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1]

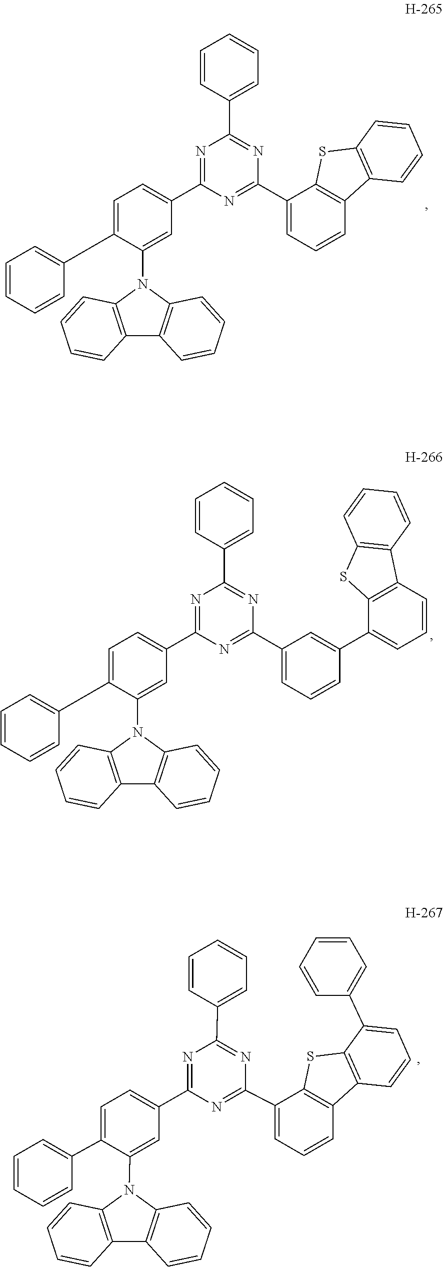 [SMILES: c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3cccc(-c4cccc5c4sc4ccccc45)c3)nc(-c3ccc(-c4ccccc4)c(-n4c5ccccc5c5ccccc54)c3)n2)cc1 ; c1ccc(-c2nc(-c3ccc(-c4ccccc4)c(-n4c5ccccc5c5ccccc54)c3)nc(-c3cccc4c3sc3c(-c5ccccc5)cccc34)n2)cc1]

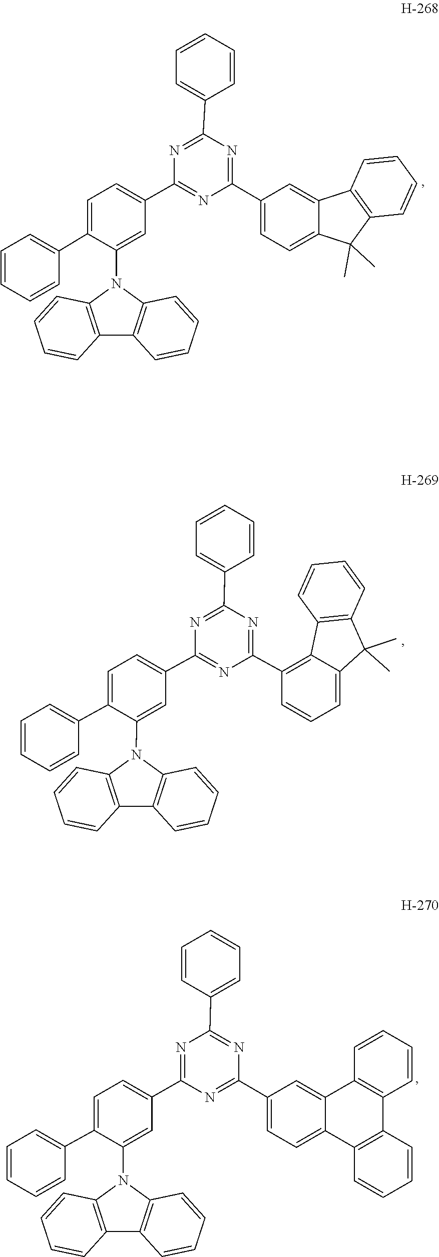 [SMILES: CC1(C)c2ccccc2-c2cc(-c3nc(-c4ccccc4)nc(-c4ccc(-c5ccccc5)c(-n5c6ccccc6c6ccccc65)c4)n3)ccc21 ; CC1(C)c2ccccc2-c2c(-c3nc(-c4ccccc4)nc(-c4ccc(-c5ccccc5)c(-n5c6ccccc6c6ccccc65)c4)n3)cccc21 ; c1ccc(-c2nc(-c3ccc(-c4ccccc4)c(-n4c5ccccc5c5ccccc54)c3)nc(-c3ccc4c5ccccc5c5ccccc5c4c3)n2)cc1]

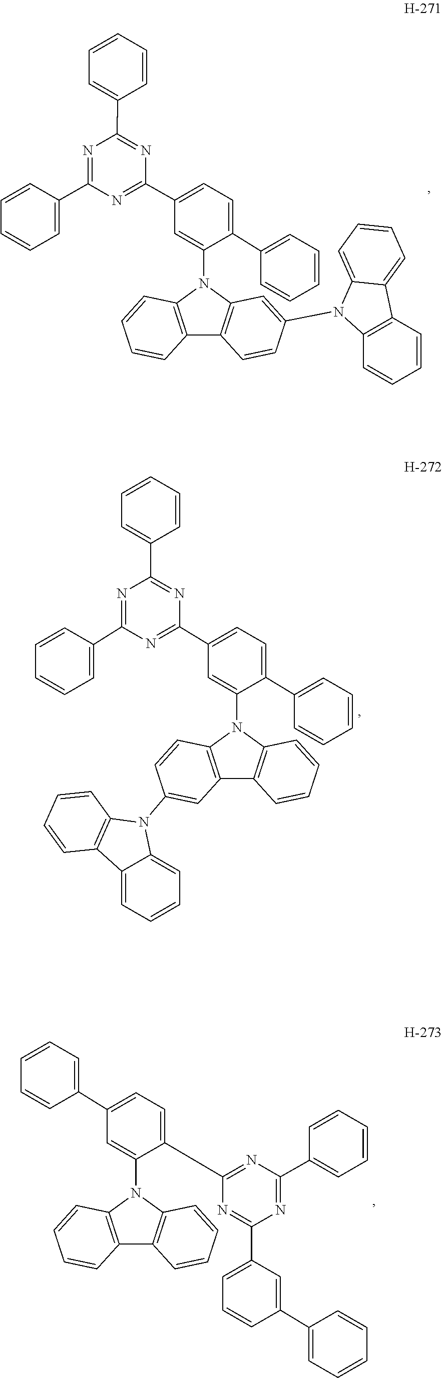 [SMILES: c1ccc(-c2nc(-c3ccccc3)nc(-c3ccc(-c4ccccc4)c(-n4c5ccccc5c5ccc(-n6c7ccccc7c7ccccc76)cc54)c3)n2)cc1 ; c1ccc(-c2nc(-c3ccccc3)nc(-c3ccc(-c4ccccc4)c(-n4c5ccccc5c5cc(-n6c7ccccc7c7ccccc76)ccc54)c3)n2)cc1 ; c1ccc(-c2cccc(-c3nc(-c4ccccc4)nc(-c4ccc(-c5ccccc5)cc4-n4c5ccccc5c5ccccc54)n3)c2)cc1]

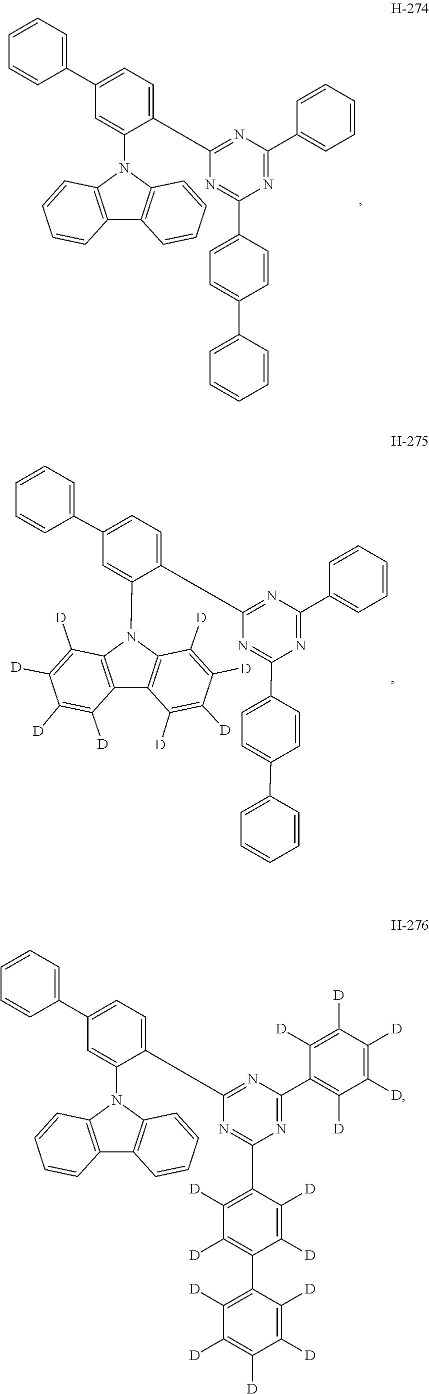

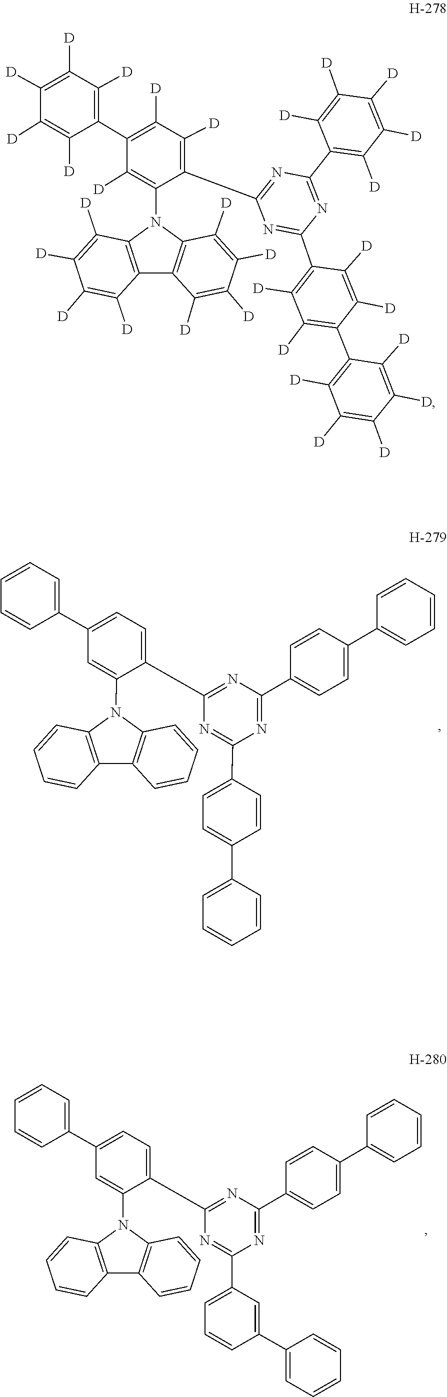

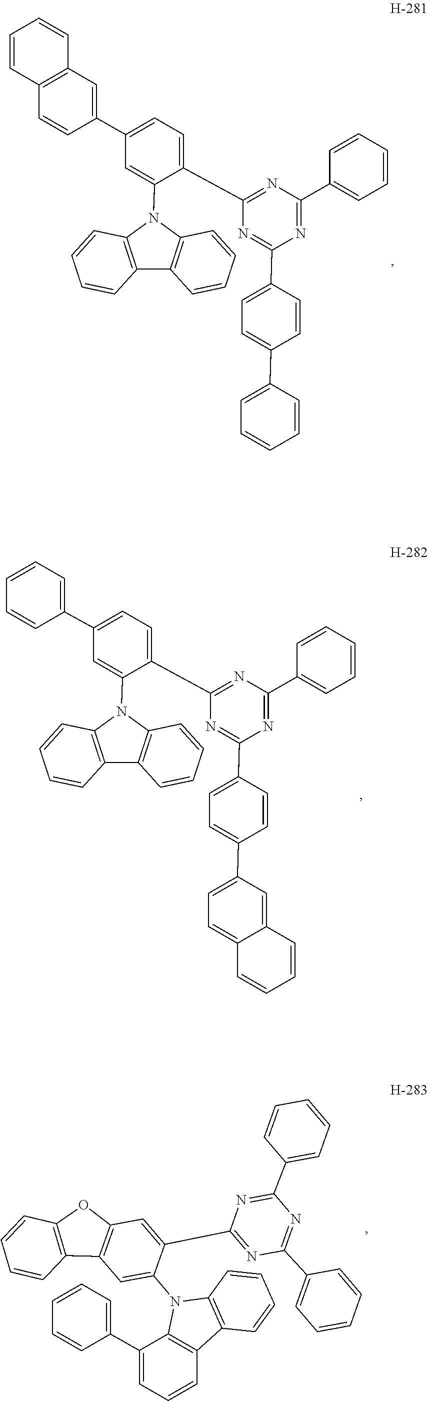 [SMILES: c1ccc(-c2ccc(-c3nc(-c4ccccc4)nc(-c4ccc(-c5ccc6ccccc6c5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4)n3)c(-n3c4ccccc4c4ccccc43)c2)cc1 ; c1ccc(-c2nc(-c3ccccc3)nc(-c3cc4oc5ccccc5c4cc3-n3c4ccccc4c4cccc(-c5ccccc5)c43)n2)cc1]

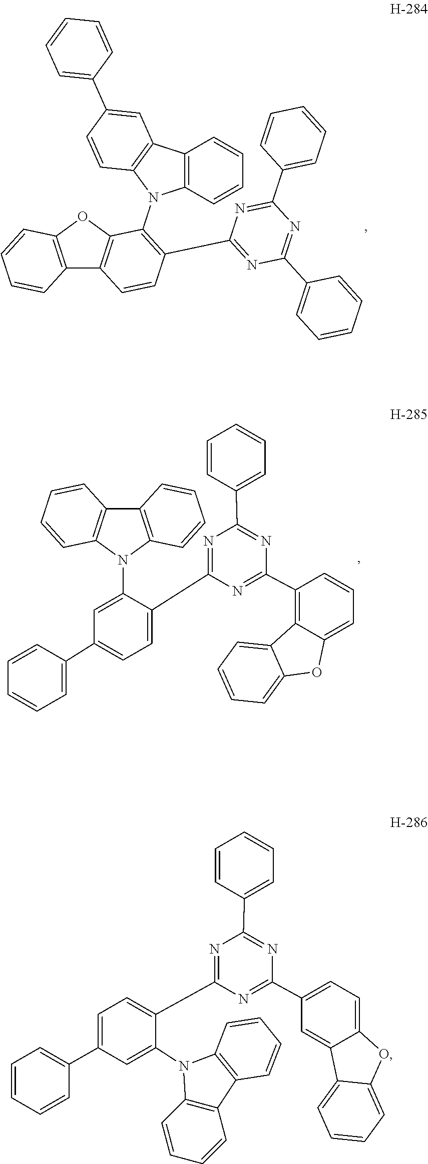 [SMILES: c1ccc(-c2ccc3c(c2)c2ccccc2n3-c2c(-c3nc(-c4ccccc4)nc(-c4ccccc4)n3)ccc3c2oc2ccccc23)cc1 ; c1ccc(-c2ccc(-c3nc(-c4ccccc4)nc(-c4cccc5oc6ccccc6c45)n3)c(-n3c4ccccc4c4ccccc43)c2)cc1 ; c1ccc(-c2ccc(-c3nc(-c4ccccc4)nc(-c4ccc5oc6ccccc6c5c4)n3)c(-n3c4ccccc4c4ccccc43)c2)cc1]

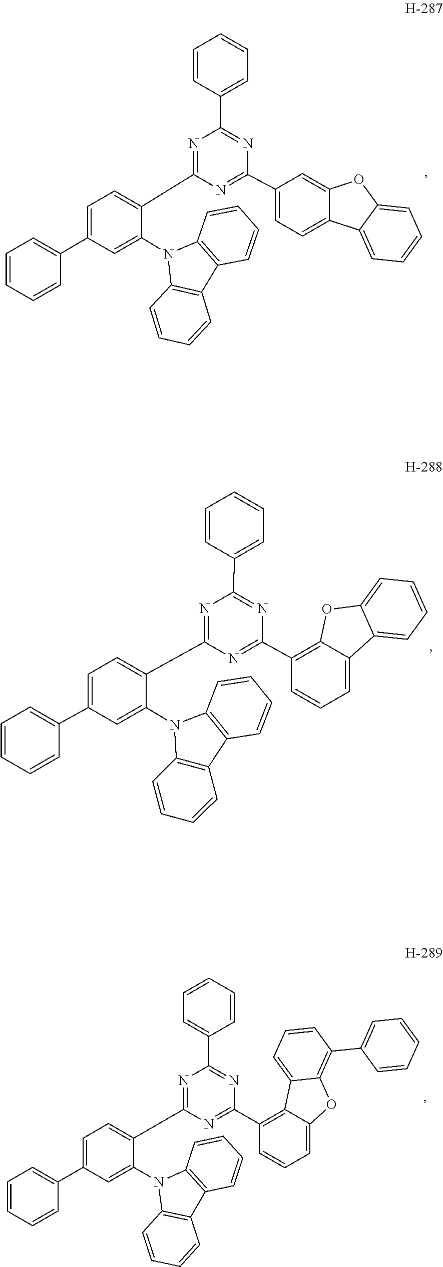 [SMILES: c1ccc(-c2ccc(-c3nc(-c4ccccc4)nc(-c4ccc5c(c4)oc4ccccc45)n3)c(-n3c4ccccc4c4ccccc43)c2)cc1 ; c1ccc(-c2ccc(-c3nc(-c4ccccc4)nc(-c4cccc5c4oc4ccccc45)n3)c(-n3c4ccccc4c4ccccc43)c2)cc1 ; c1ccc(-c2ccc(-c3nc(-c4ccccc4)nc(-c4cccc5oc6c(-c7ccccc7)cccc6c45)n3)c(-n3c4ccccc4c4ccccc43)c2)cc1]

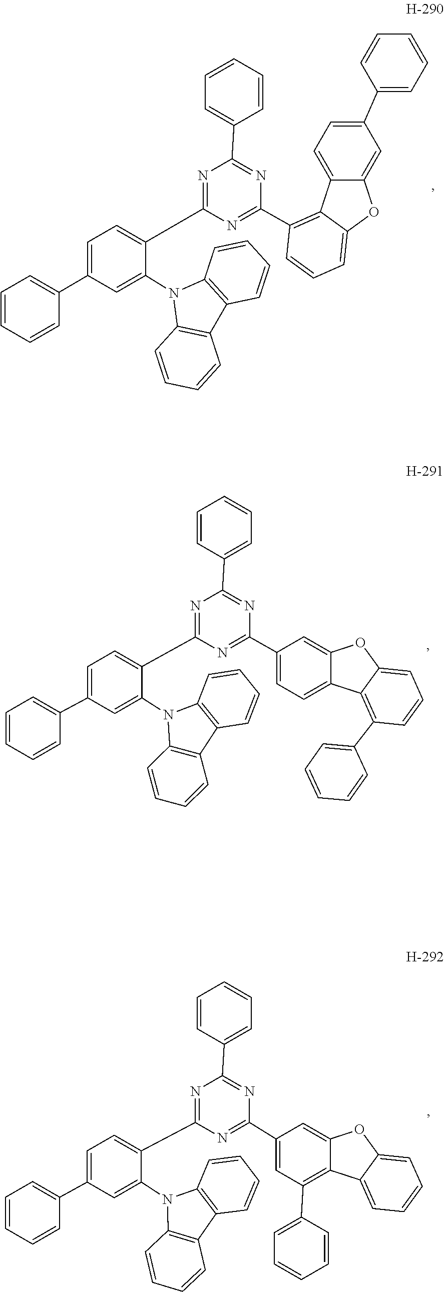 [SMILES: c1ccc(-c2ccc(-c3nc(-c4ccccc4)nc(-c4cccc5oc6cc(-c7ccccc7)ccc6c45)n3)c(-n3c4ccccc4c4ccccc43)c2)cc1 ; c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1 ; c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1]

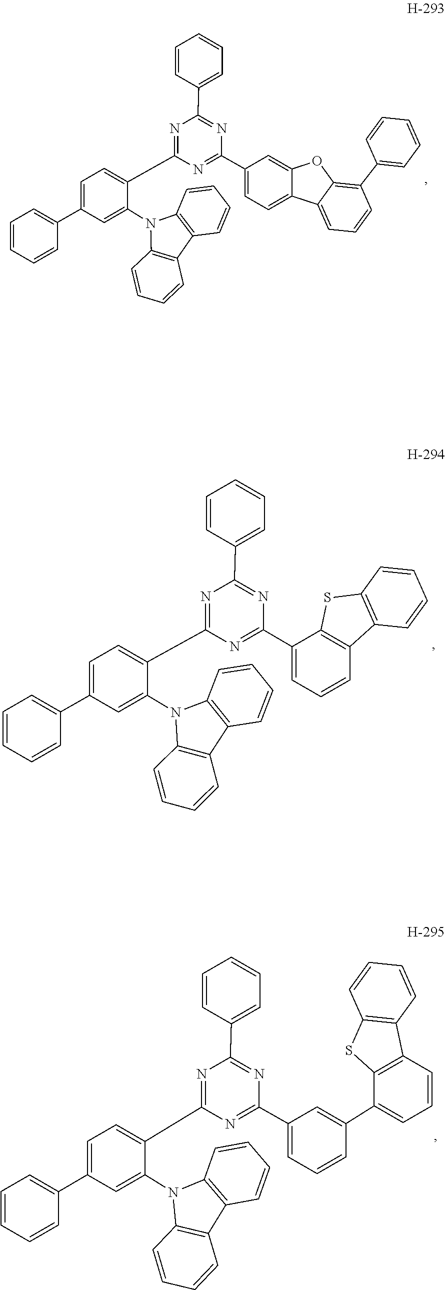 [SMILES: c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1 ; c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1]

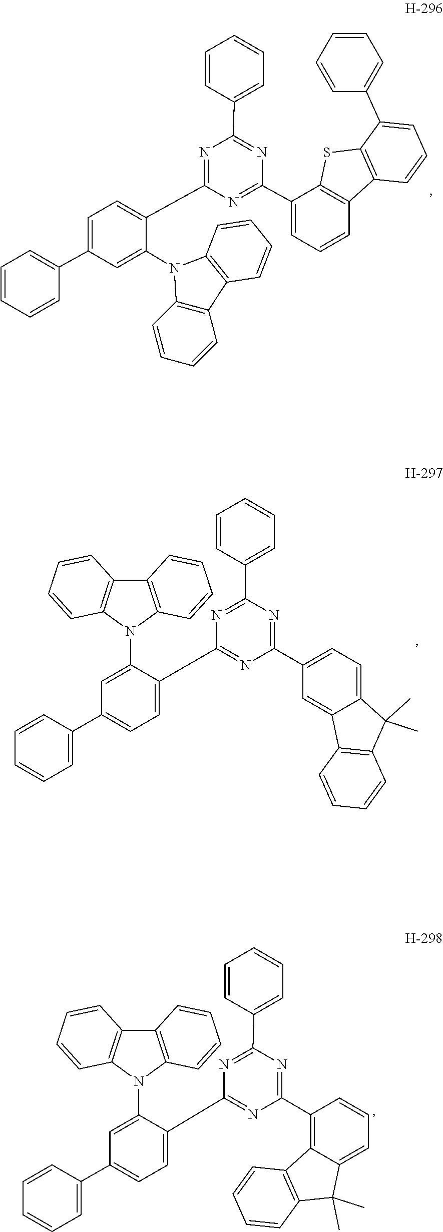 [SMILES: c1ccc(-c2ccc(-c3nc(-c4ccccc4)nc(-c4cccc5c4sc4c(-c6ccccc6)cccc45)n3)c(-n3c4ccccc4c4ccccc43)c2)cc1 ; CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21]

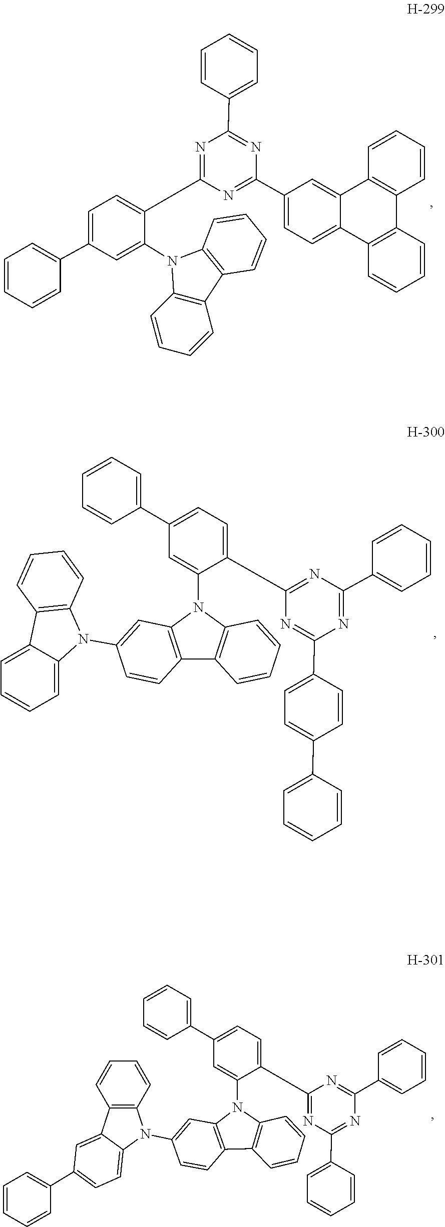 [SMILES: c1ccc(-c2ccc(-c3nc(-c4ccccc4)nc(-c4ccc5c6ccccc6c6ccccc6c5c4)n3)c(-n3c4ccccc4c4ccccc43)c2)cc1 ; c1ccc(-c2ccc(-c3nc(-c4ccccc4)nc(-c4ccc(-c5ccccc5)cc4-n4c5ccccc5c5ccc(-n6c7ccccc7c7ccccc76)cc54)n3)cc2)cc1 ; c1ccc(-c2ccc(-c3nc(-c4ccccc4)nc(-c4ccccc4)n3)c(-n3c4ccccc4c4ccc(-n5c6ccccc6c6cc(-c7ccccc7)ccc65)cc43)c2)cc1]

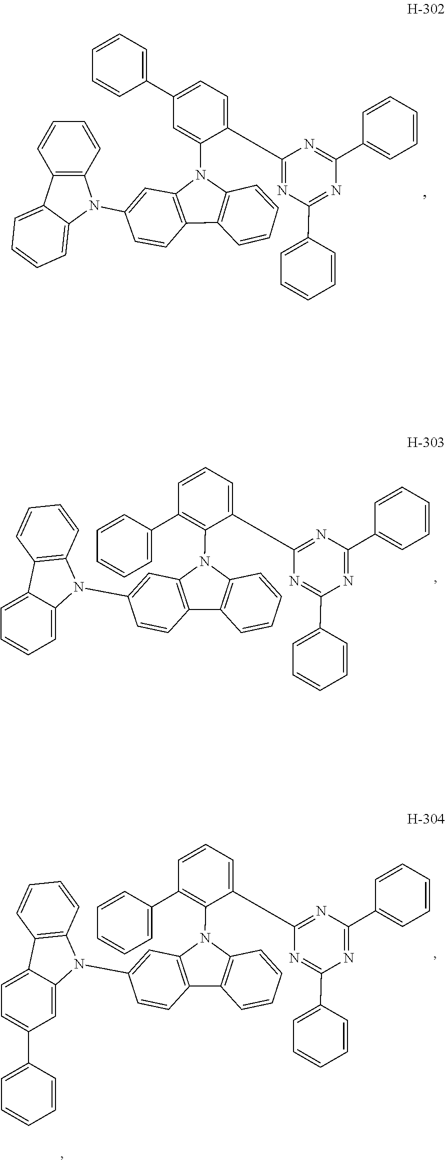 [SMILES: c1ccc(-c2ccc(-c3nc(-c4ccccc4)nc(-c4ccccc4)n3)c(-n3c4ccccc4c4ccc(-n5c6ccccc6c6ccccc65)cc43)c2)cc1 ; c1ccc(-c2nc(-c3ccccc3)nc(-c3cccc(-c4ccccc4)c3-n3c4ccccc4c4ccc(-n5c6ccccc6c6ccccc65)cc43)n2)cc1 ; c1ccc(-c2ccc3c4ccccc4n(-c4ccc5c6ccccc6n(-c6c(-c7ccccc7)cccc6-c6nc(-c7ccccc7)nc(-c7ccccc7)n6)c5c4)c3c2)cc1]

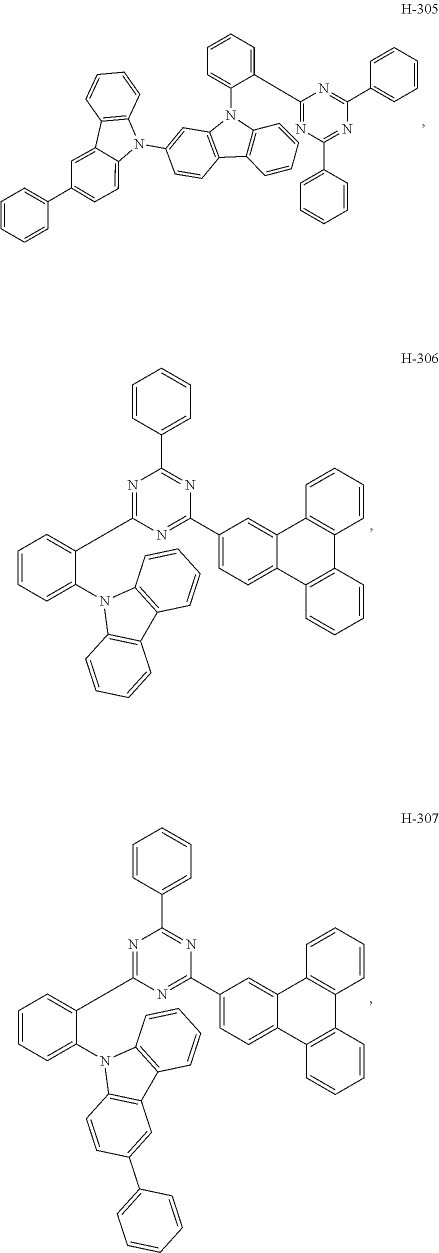 [SMILES: c1ccc(-c2ccc3c(c2)c2ccccc2n3-c2ccc3c4ccccc4n(-c4ccccc4-c4nc(-c5ccccc5)nc(-c5ccccc5)n4)c3c2)cc1 ; c1ccc(-c2nc(-c3ccc4c5ccccc5c5ccccc5c4c3)nc(-c3ccccc3-n3c4ccccc4c4ccccc43)n2)cc1 ; c1ccc(-c2ccc3c(c2)c2ccccc2n3-c2ccccc2-c2nc(-c3ccccc3)nc(-c3ccc4c5ccccc5c5ccccc5c4c3)n2)cc1]

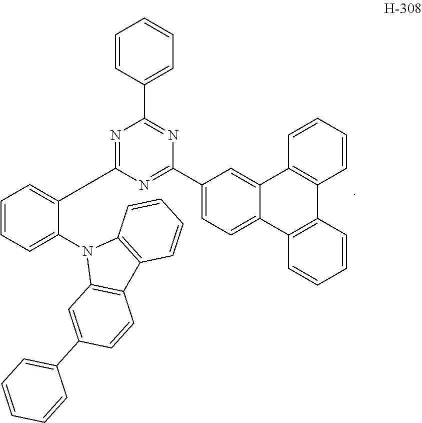 [SMILES: c1ccc(-c2ccc3c4ccccc4n(-c4ccccc4-c4nc(-c5ccccc5)nc(-c5ccc6c7ccccc7c7ccccc7c6c5)n4)c3c2)cc1]

According to another embodiment of the present disclosure, hydrogen in Compound H-1 to Compound H-308 described above can be partially or fully substituted with deuterium.

According to another embodiment of the present disclosure, the second host compound has a structure represented by Formula 5 or Formula 6:

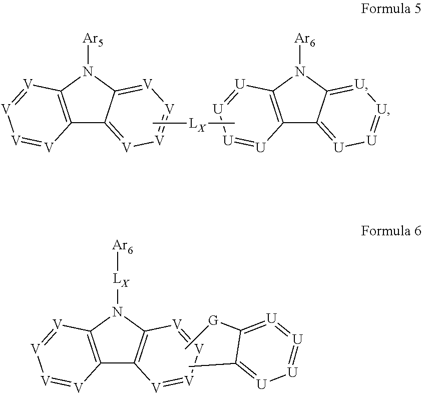

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CRᵥ or N, and at least one of V is C and is joined to Lₓ;
U is, at each occurrence identically or differently, selected from C, CRᵤ or N, and at least one of U is C and is joined to Lₓ;
R_{g}, Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₆ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and Rᵤ can be optionally joined to form a ring.

According to another embodiment of the present disclosure, the second host compound has a structure represented by one of Formula 5-a to Formula 5-p:

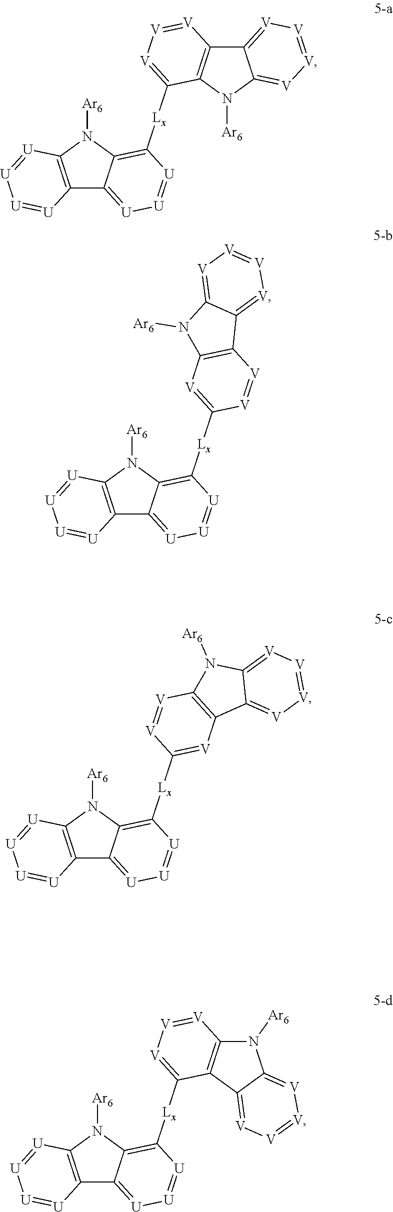

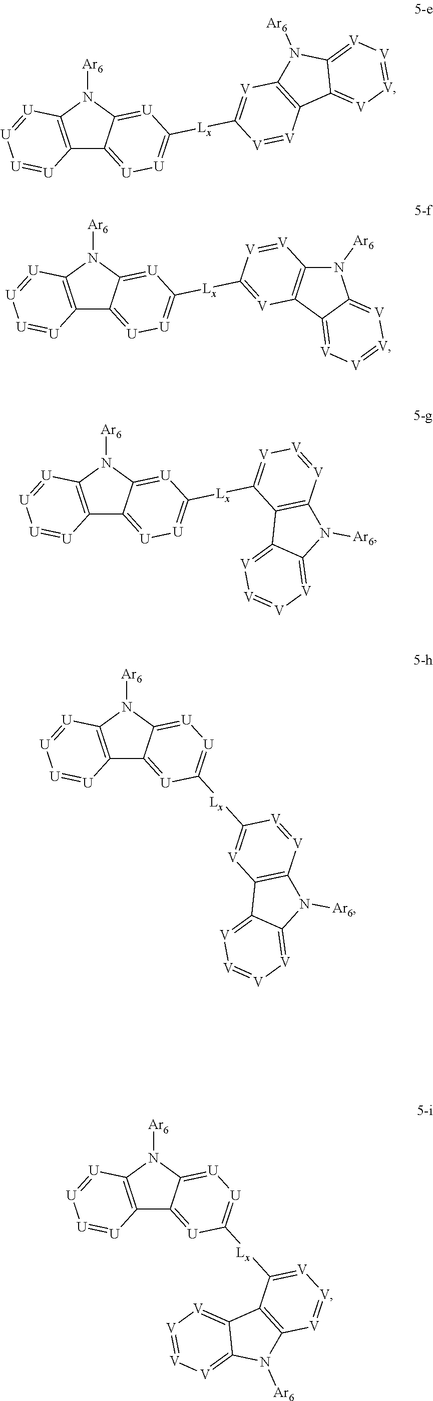

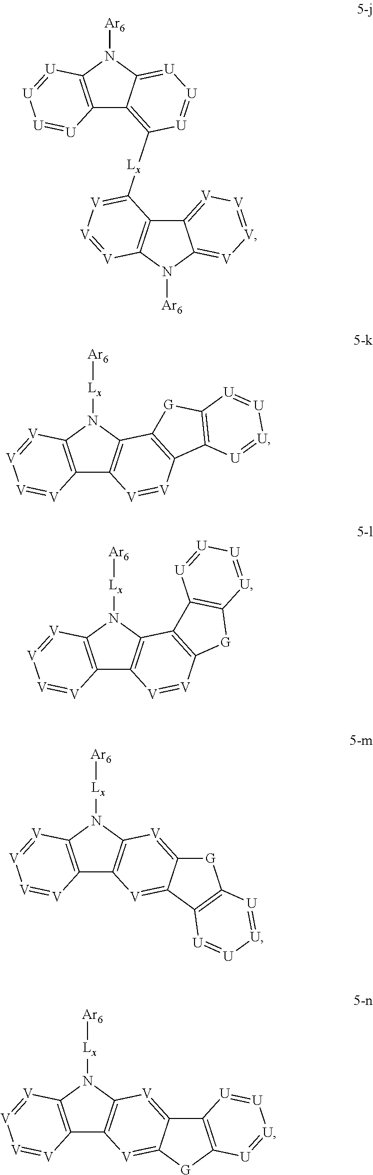

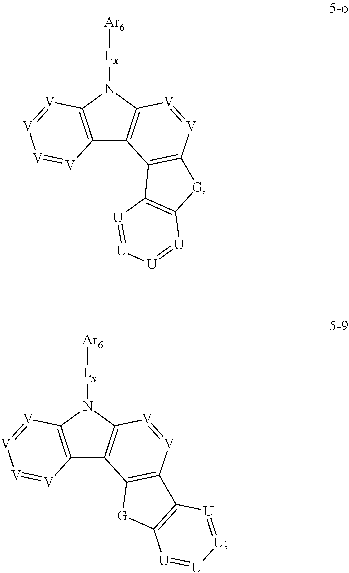

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CRᵥ or N, and at least one of V is C and is joined to Lₓ;
U is, at each occurrence identically or differently, selected from C, CRᵤ or N, and at least one of U is C and is joined to Lₓ;
R_{g}, Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₆ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and Rᵤ can be optionally joined to form a ring.

In the present disclosure, the expression that “adjacent substituents R_{g}, Rᵥ and Rᵤ can be optionally joined to form a ring” is intended to mean that any one or more of groups of adjacent substituents, such as two substituents R_{g}, two substituents Rᵥ, two substituents Rᵤ, substituents Rᵥ and Rᵤ, substituents Rᵥ and R_{g}, and substituents R_{g} and Rᵤ, can be joined to form a ring. Obviously, it is also possible that none of these substituents are joined to form a ring.

According to another embodiment of the present disclosure, the second host compound is selected from the group consisting of PH-1 to PH-50, wherein the structures of PH-1 to PH-50 are shown as follows:

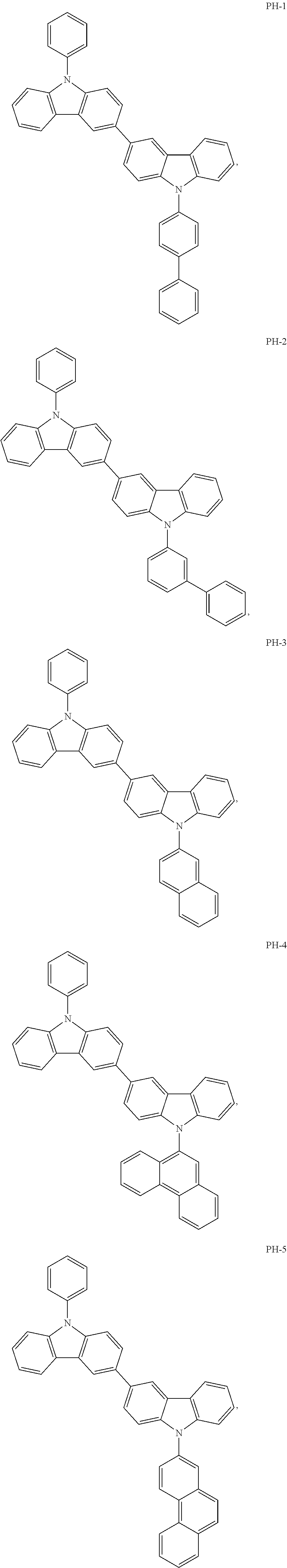 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1]

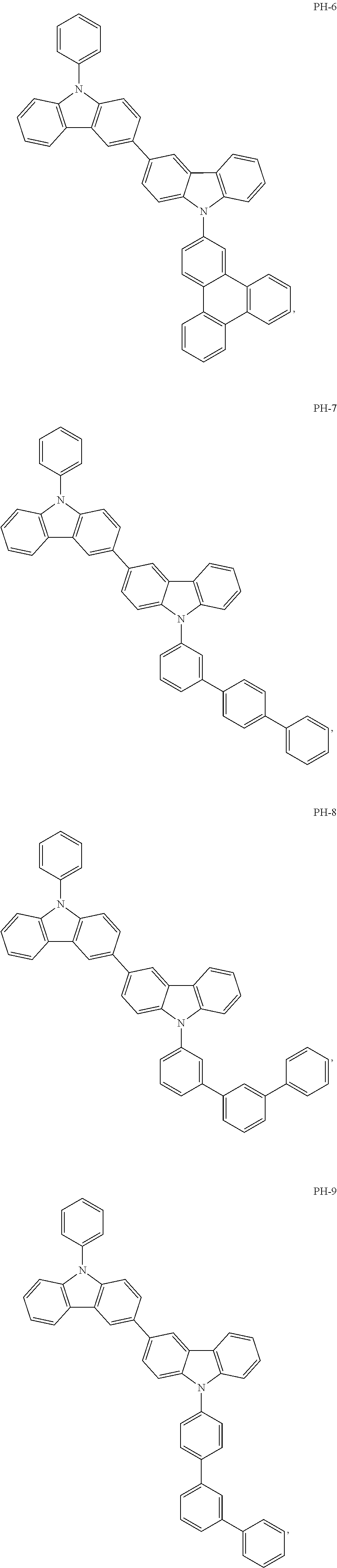 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

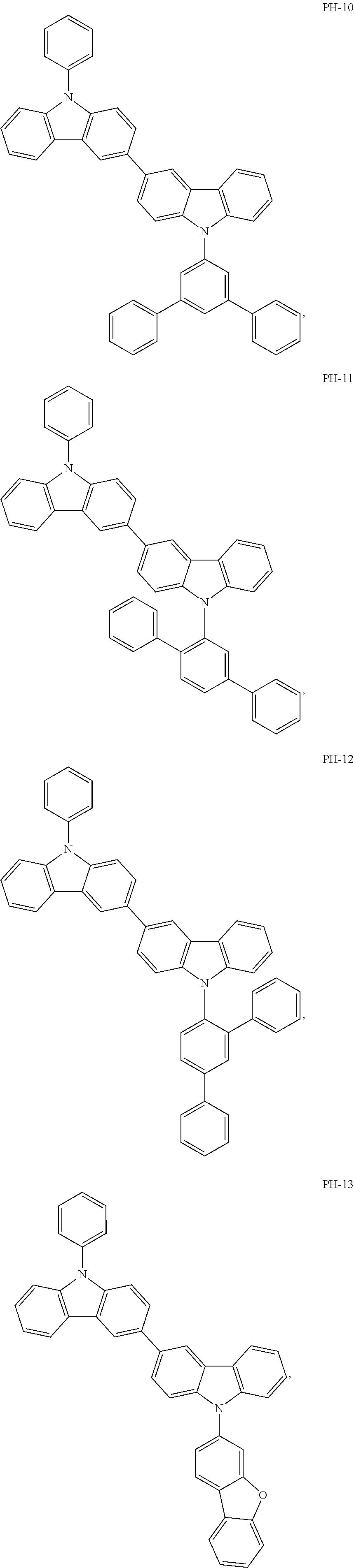 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1 ; c1ccc(-n2c3ccccc3c3cc(-c4ccc5c(c4)c4ccccc4n5-c4ccc5c(c4)oc4ccccc45)ccc32)cc1]

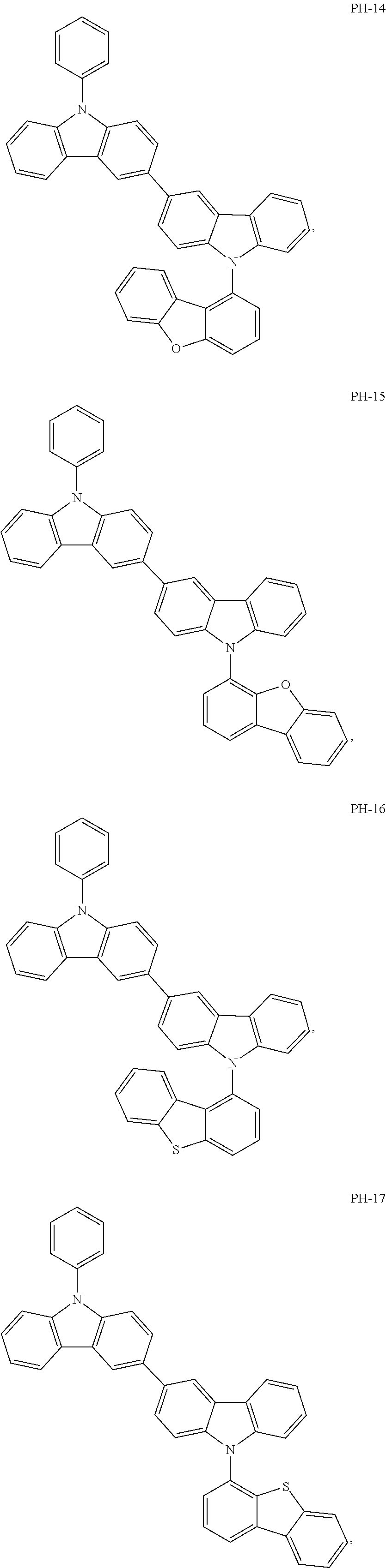 [SMILES: c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1]

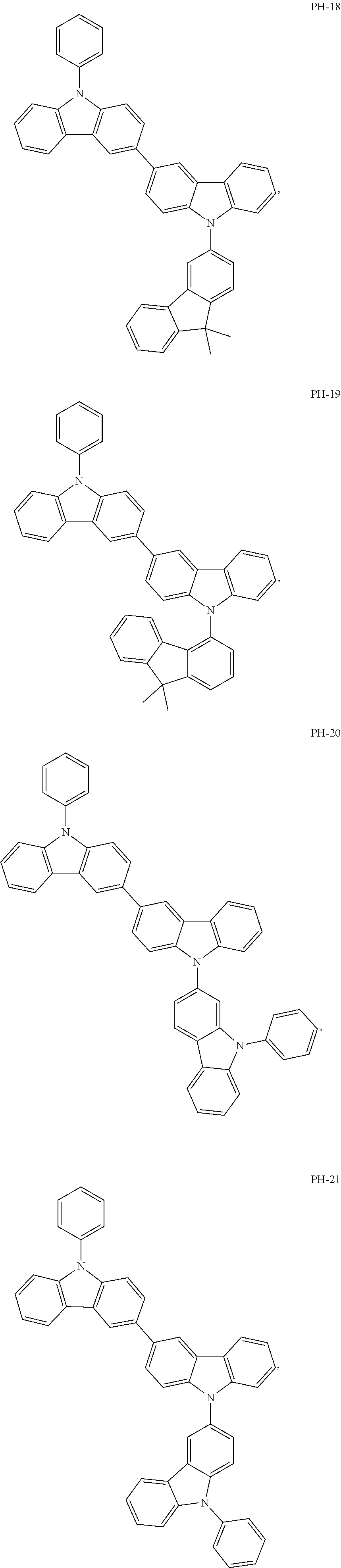 [SMILES: CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

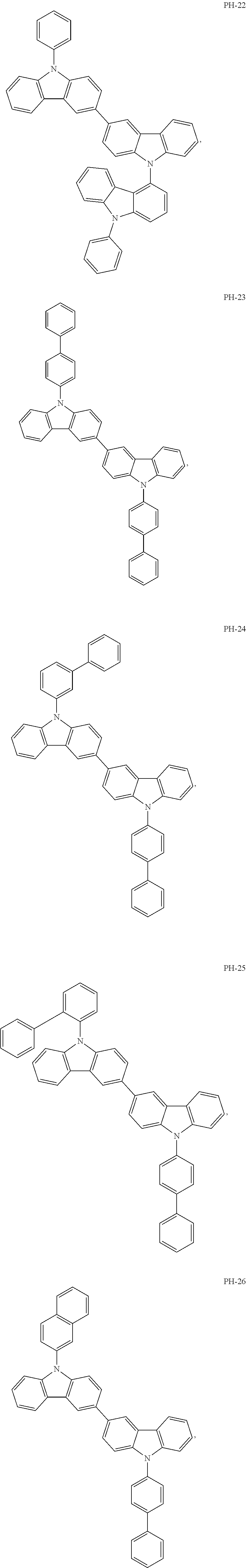 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1]

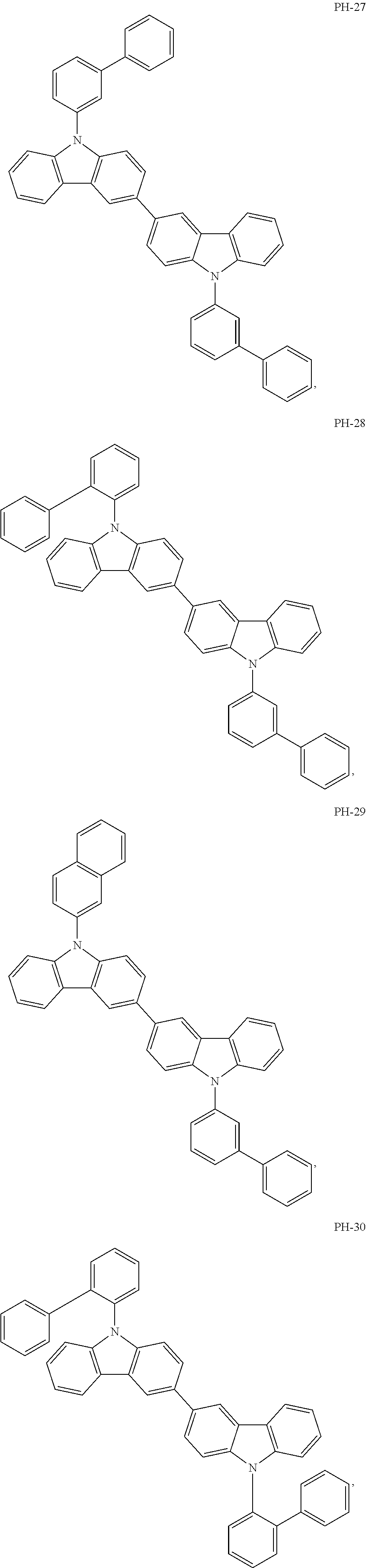 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1]

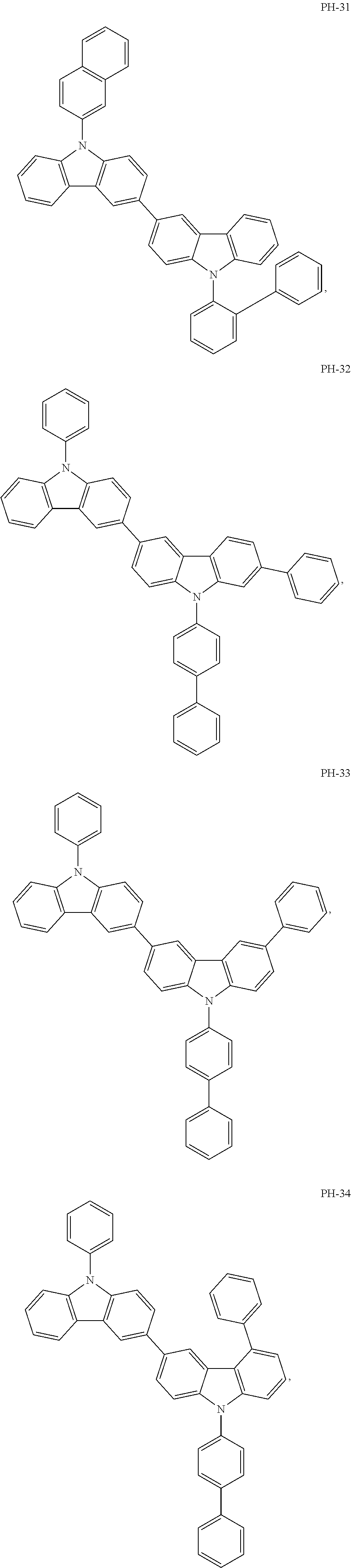 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

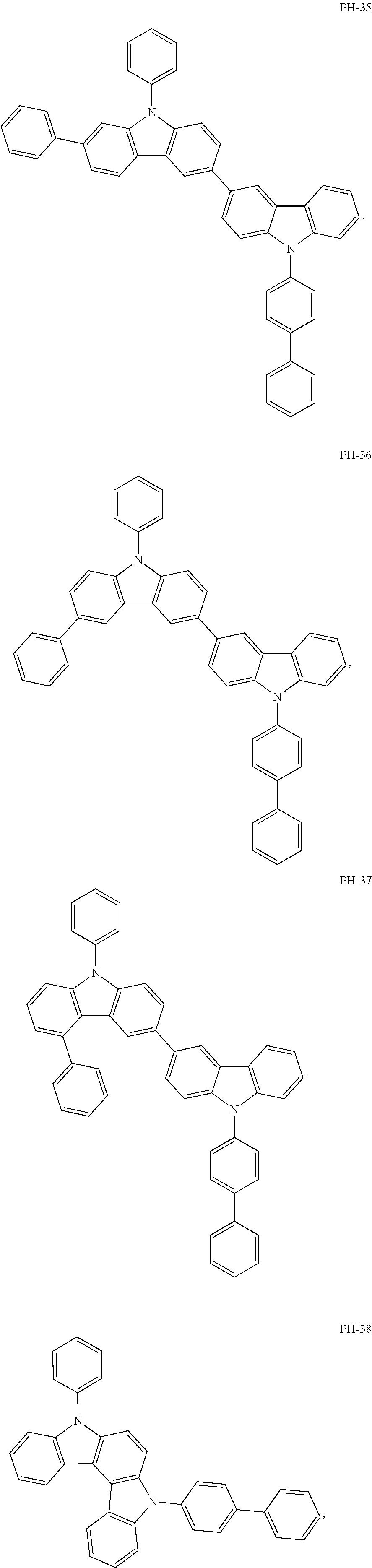 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1]

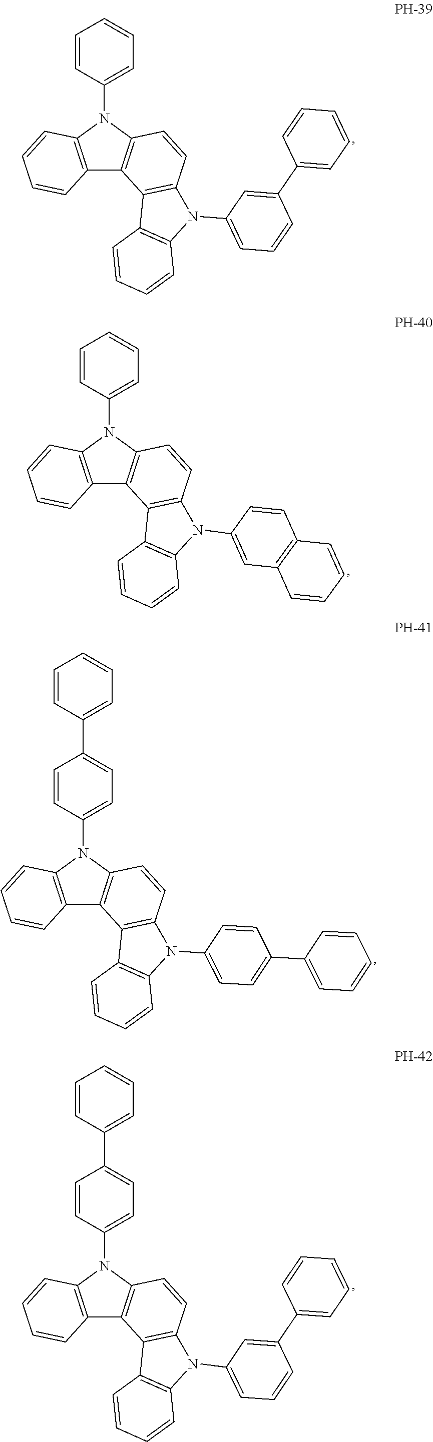

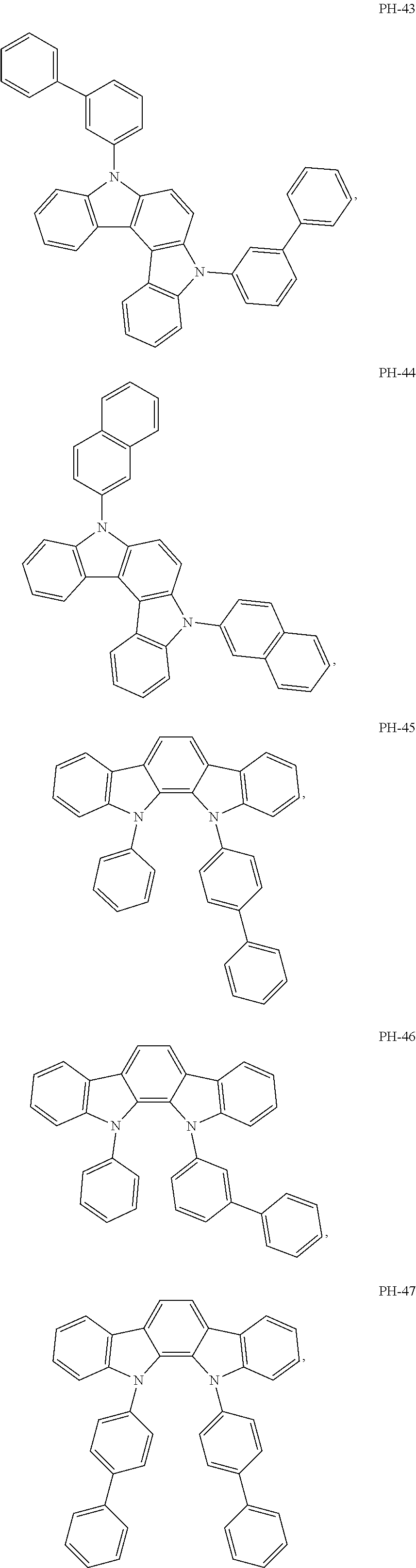

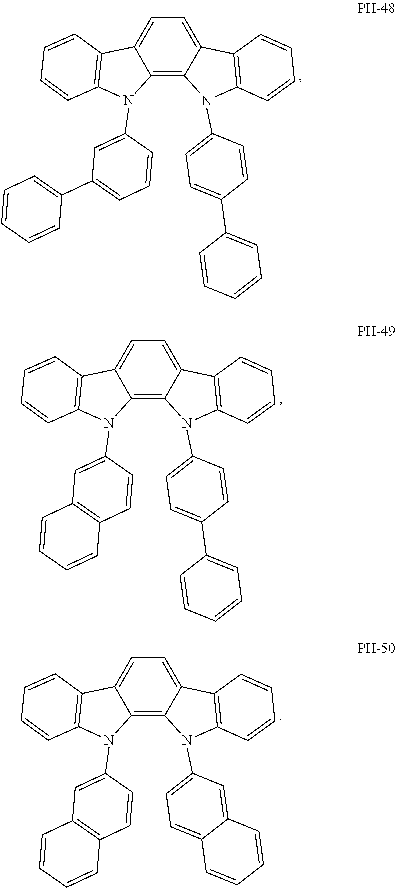 [SMILES: c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to another embodiment of the present disclosure, the second host compound is selected from the group consisting of PH-51 to PH-107, wherein the structures of PH-51 to PH-107 are shown as follows:

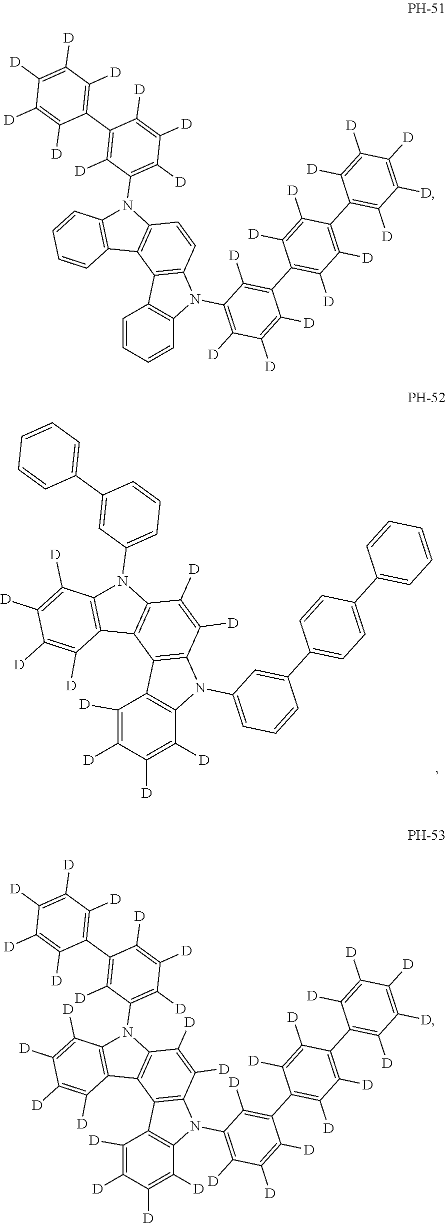

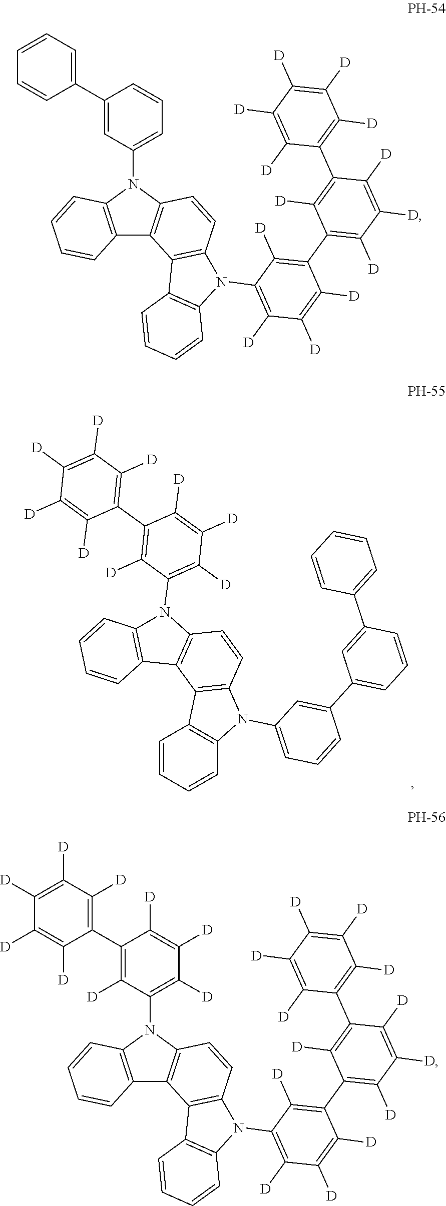

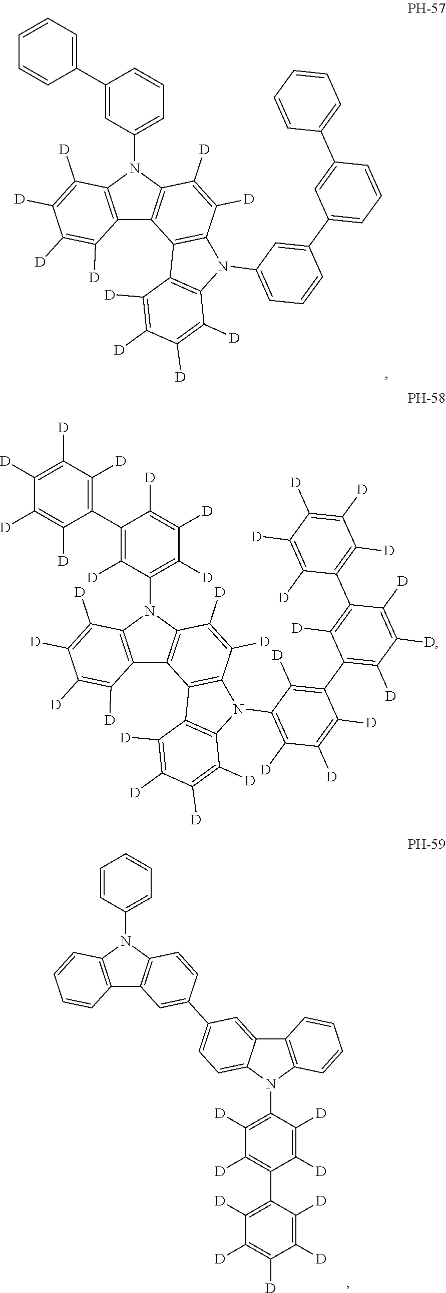

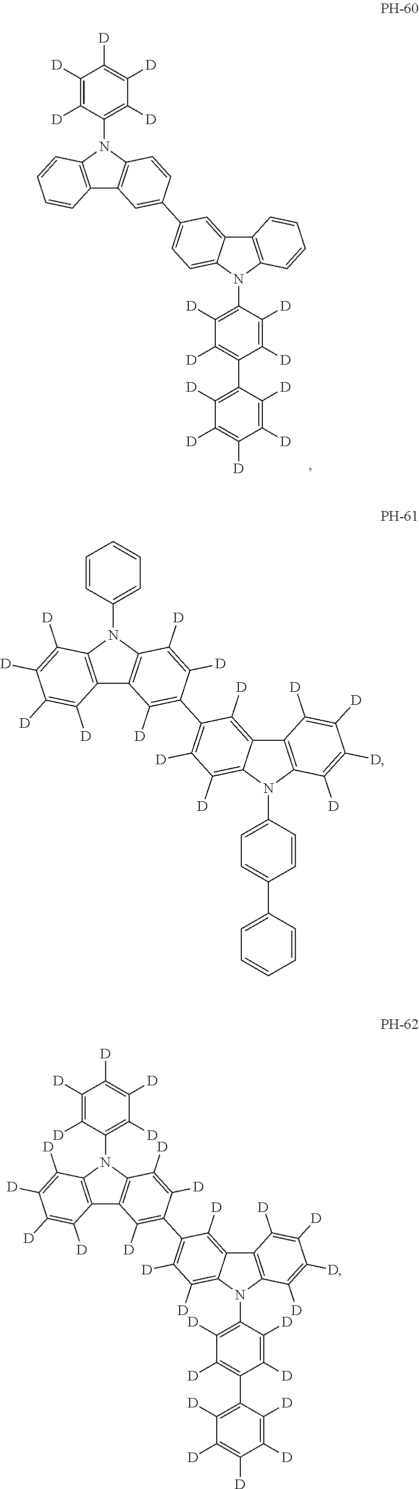

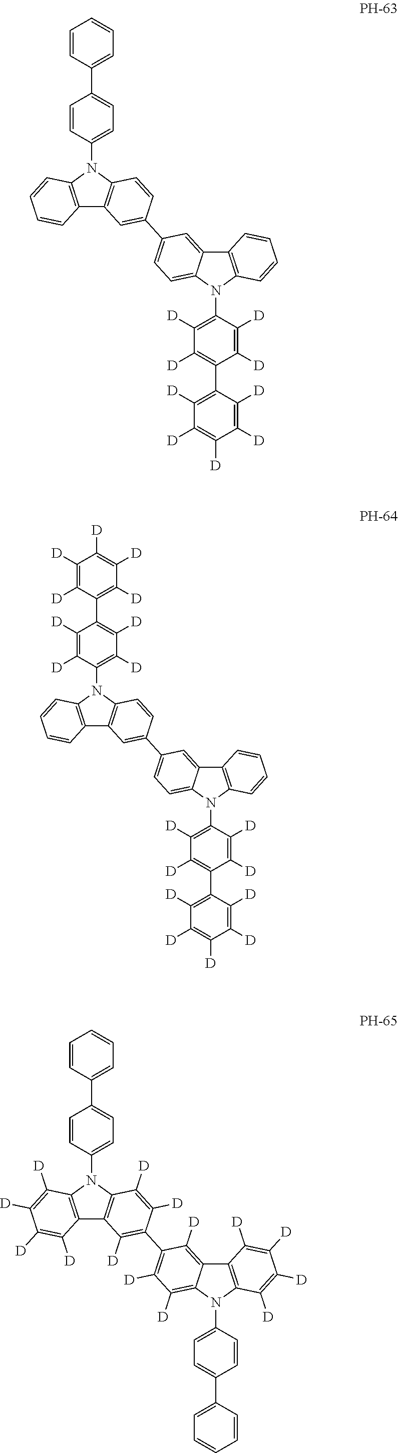 [SMILES: [2H]c1c([2H])c([2H])c(-c2c([2H])c([2H])c(-n3c4ccccc4c4cc(-c5ccc6c(c5)c5ccccc5n6-c5ccc(-c6ccccc6)cc5)ccc43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c(-c6c([2H])c([2H])c([2H])c([2H])c6[2H])c([2H])c5[2H])ccc43)c([2H])c2[2H])c([2H])c1[2H] ; [2H]c1c([2H])c([2H])c2c(c1[2H])c1c([2H])c(-c3c([2H])c([2H])c4c(c3[2H])c3c([2H])c([2H])c([2H])c([2H])c3n4-c3ccc(-c4ccccc4)cc3)c([2H])c([2H])c1n2-c1ccc(-c2ccccc2)cc1]

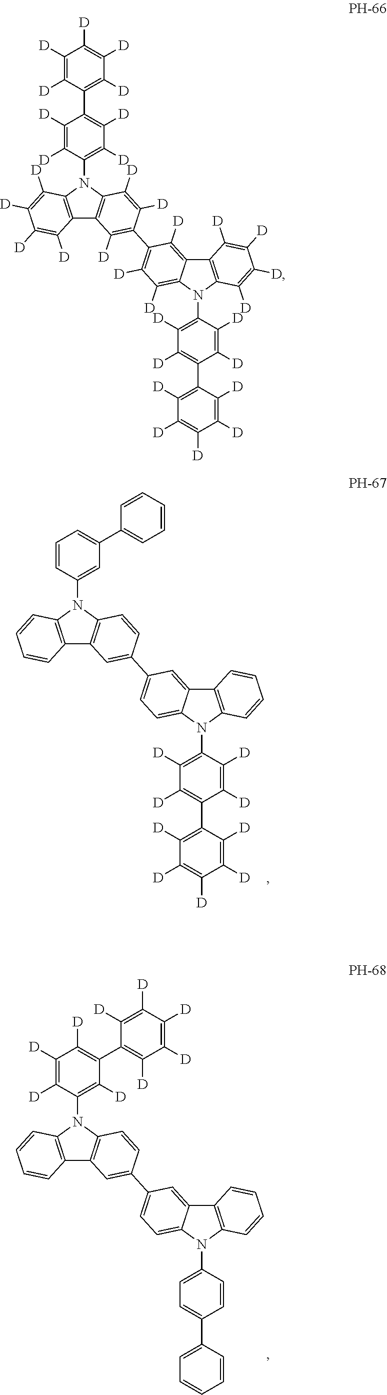

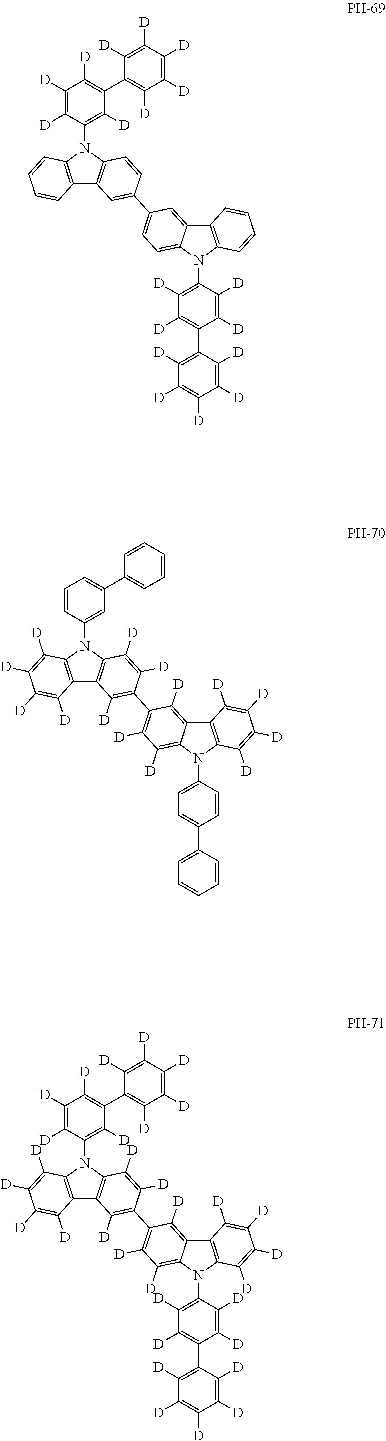

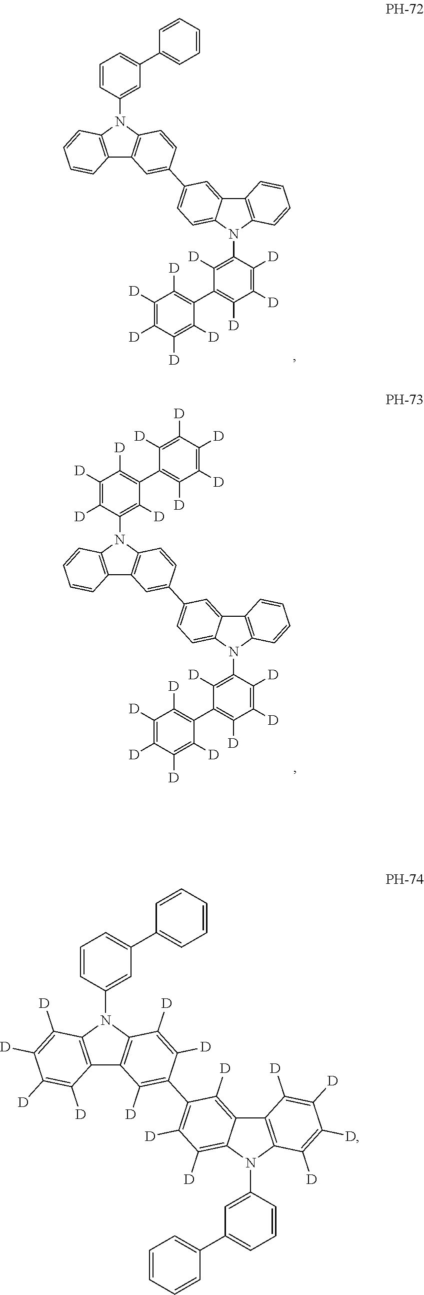

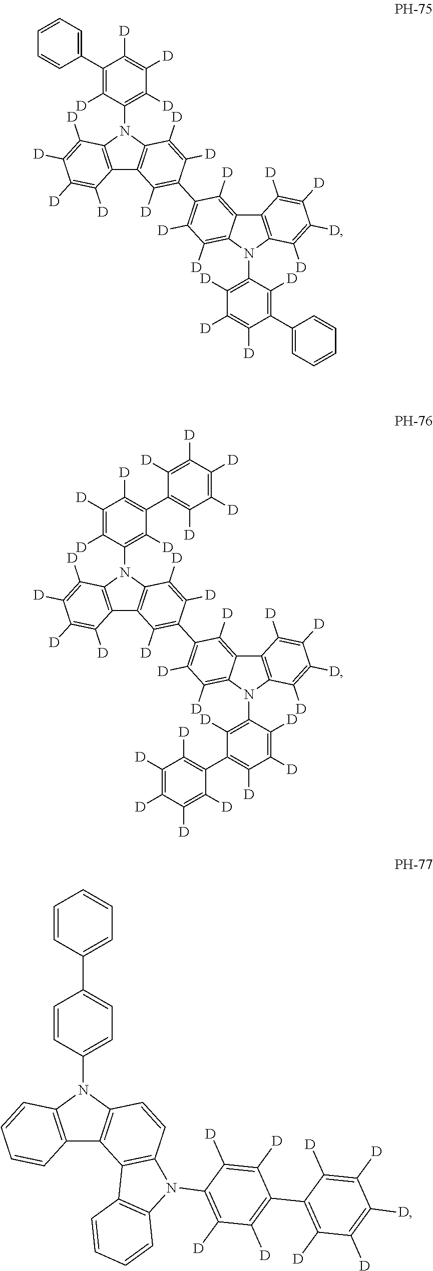

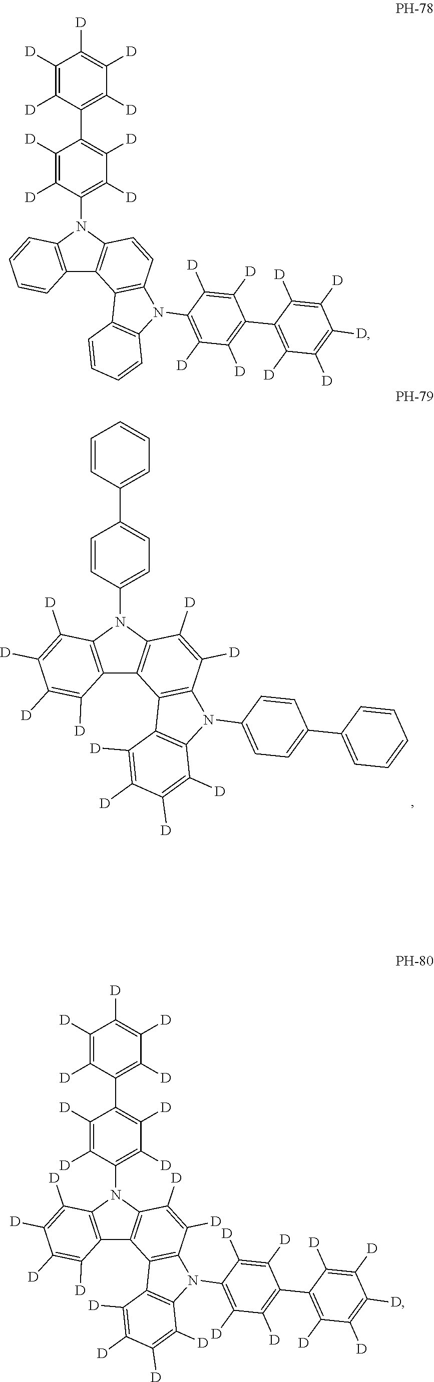

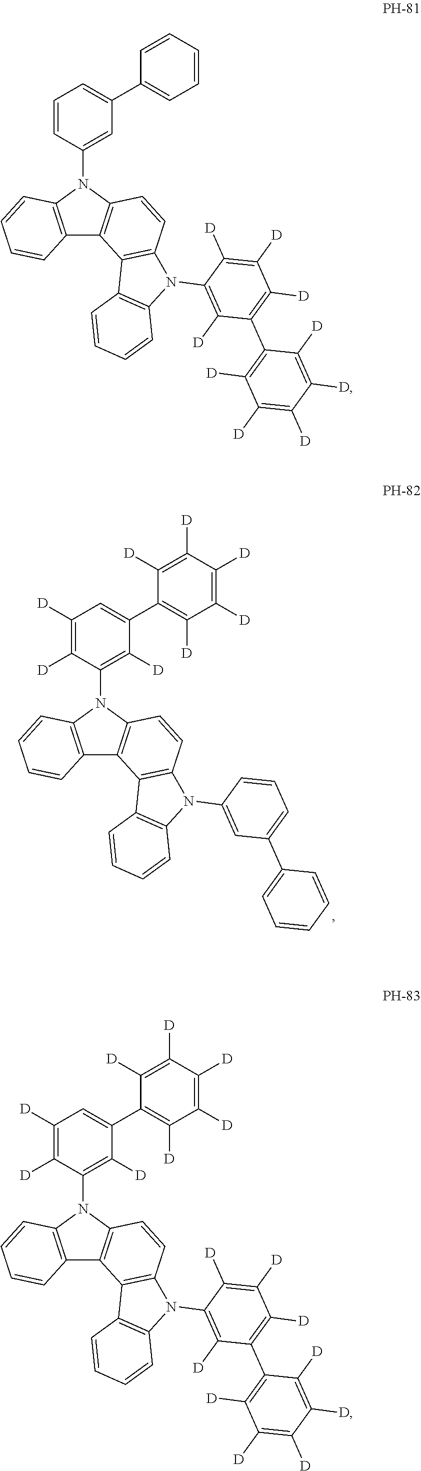

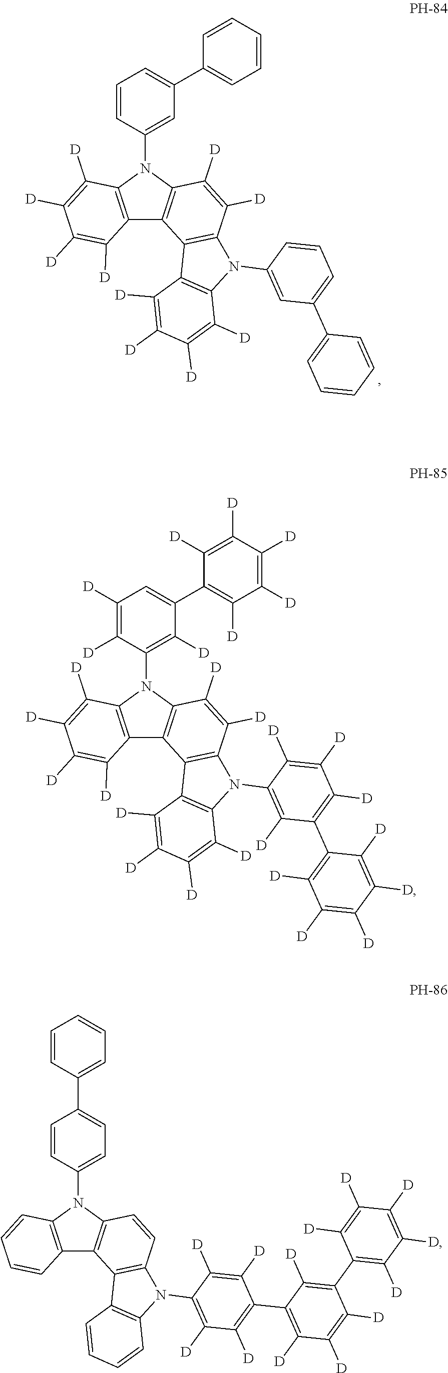

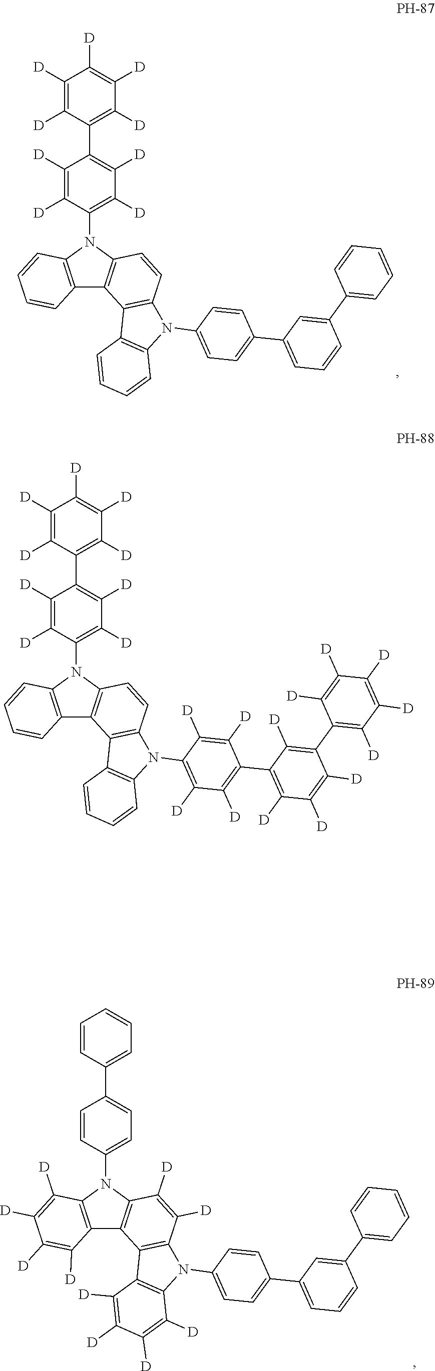 [SMILES: [2H]c1c([2H])c([2H])c(-c2c([2H])c([2H])c(-n3c4ccccc4c4c5c6ccccc6n(-c6ccc(-c7cccc(-c8ccccc8)c7)cc6)c5ccc43)c([2H])c2[2H])c([2H])c1[2H] ; [2H]c1c([2H])c([2H])c(-c2c([2H])c([2H])c(-n3c4ccccc4c4c5c6ccccc6n(-c6c([2H])c([2H])c(-c7c([2H])c([2H])c([2H])c(-c8c([2H])c([2H])c([2H])c([2H])c8[2H])c7[2H])c([2H])c6[2H])c5ccc43)c([2H])c2[2H])c([2H])c1[2H] ; [2H]c1c([2H])c([2H])c2c(c1[2H])c1c3c4c([2H])c([2H])c([2H])c([2H])c4n(-c4ccc(-c5cccc(-c6ccccc6)c5)cc4)c3c([2H])c([2H])c1n2-c1ccc(-c2ccccc2)cc1]

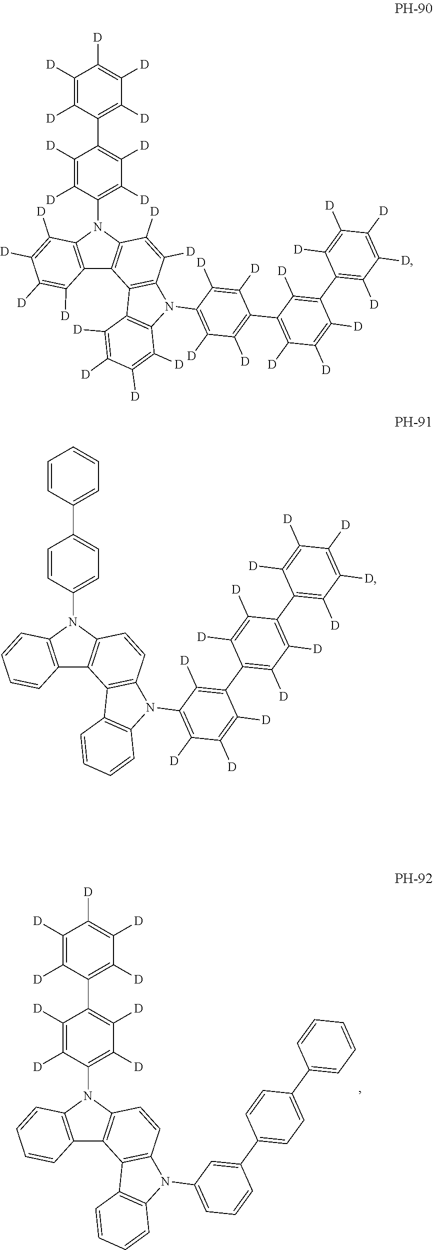

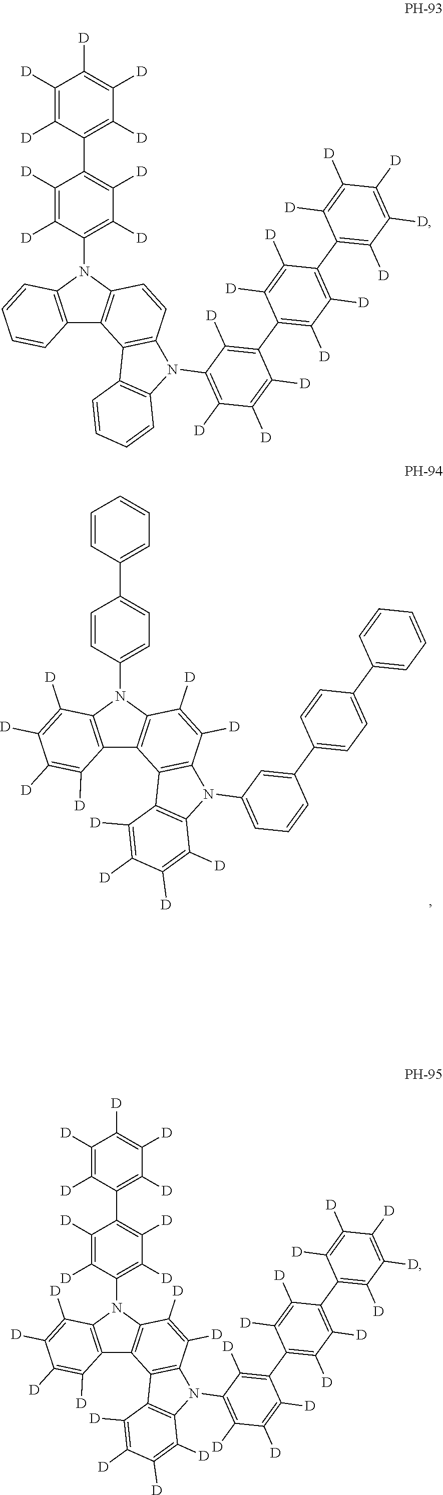

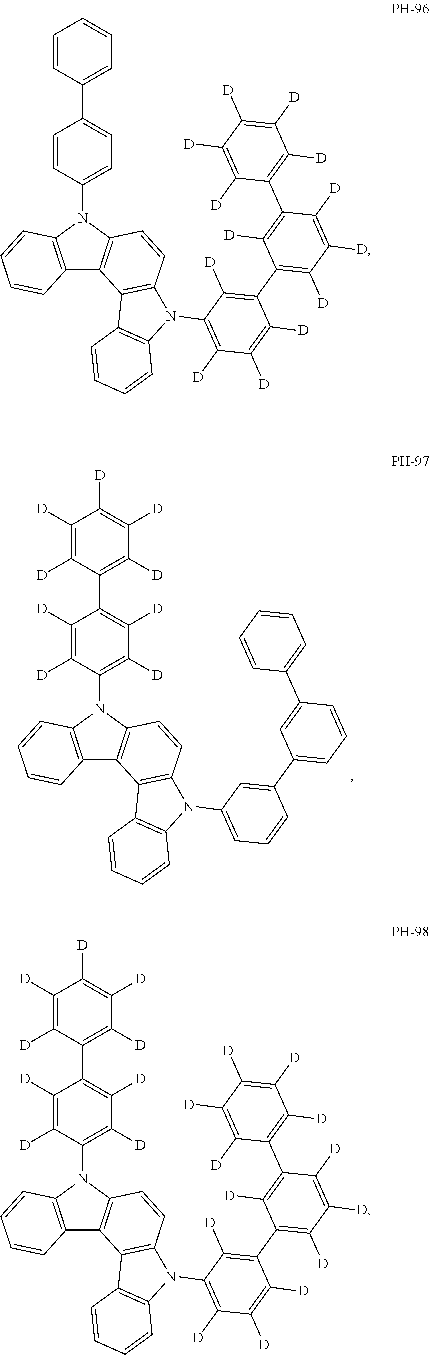

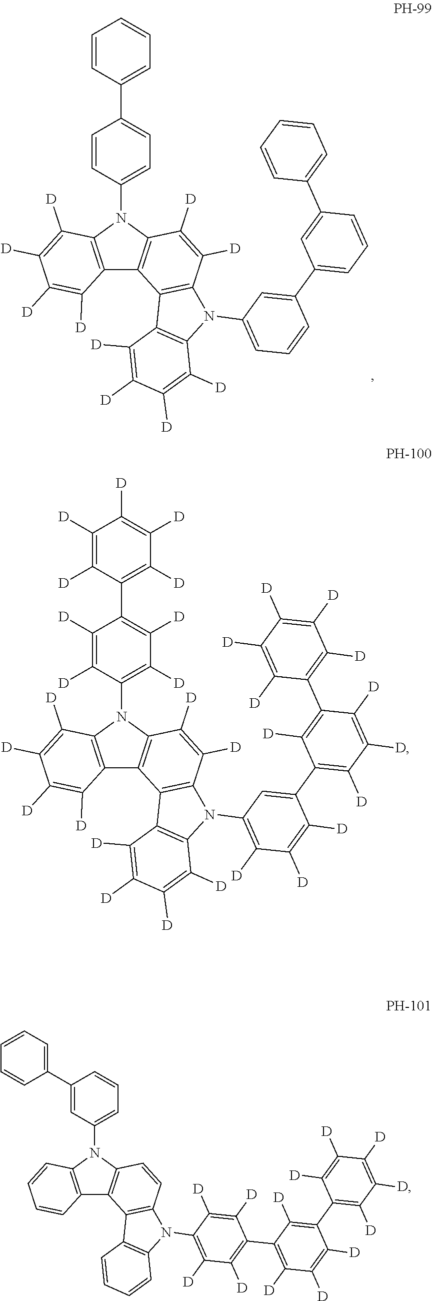

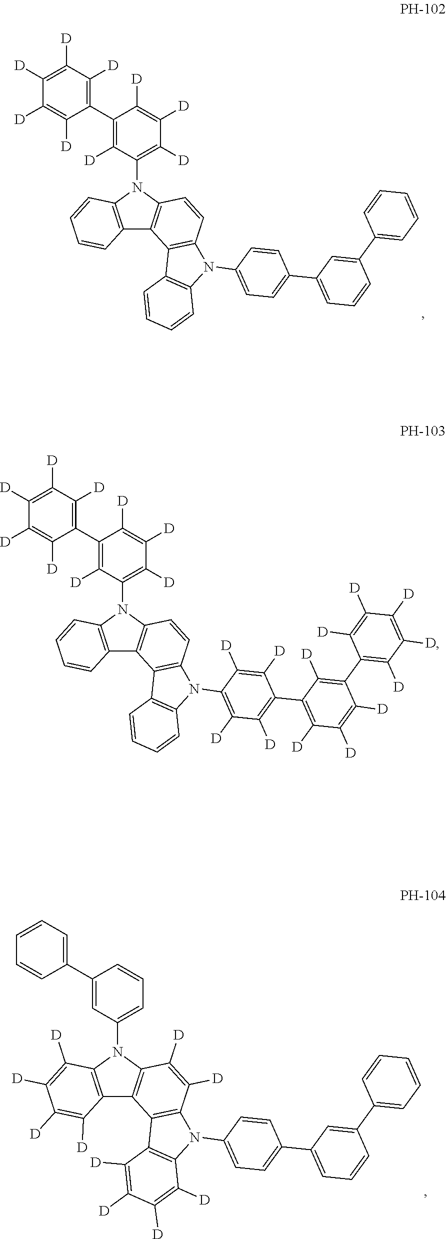

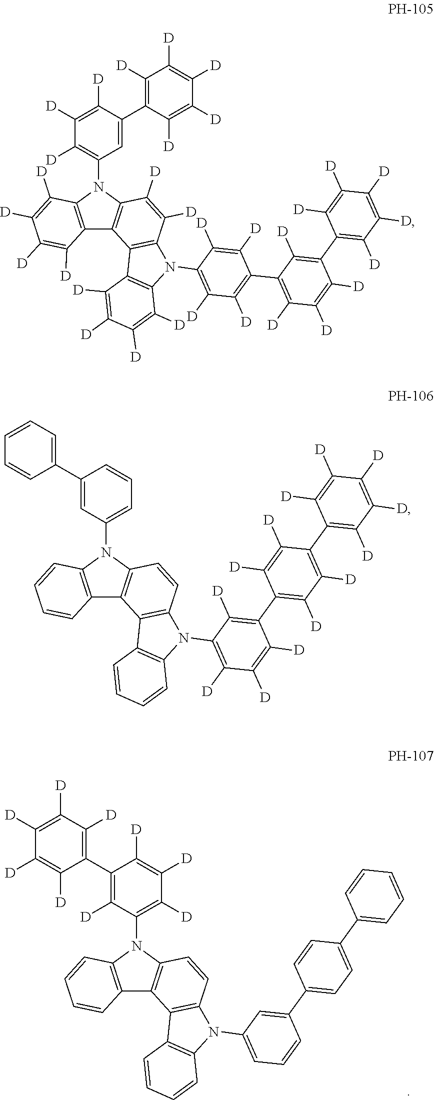

According to an embodiment of the present disclosure, hydrogen in Compound PH-1 to Compound PH-107 described above can be partially or fully substituted with deuterium.

According to an embodiment of the present disclosure, the organic electroluminescent device further comprises a hole injection layer. The hole injection layer may be a functional layer comprising a single material or a functional layer comprising a plurality of materials, wherein the contained plurality of materials used most commonly are the hole transporting material doped with a certain proportion of p-type conductive doping material. Common p-type doping materials are as follows:

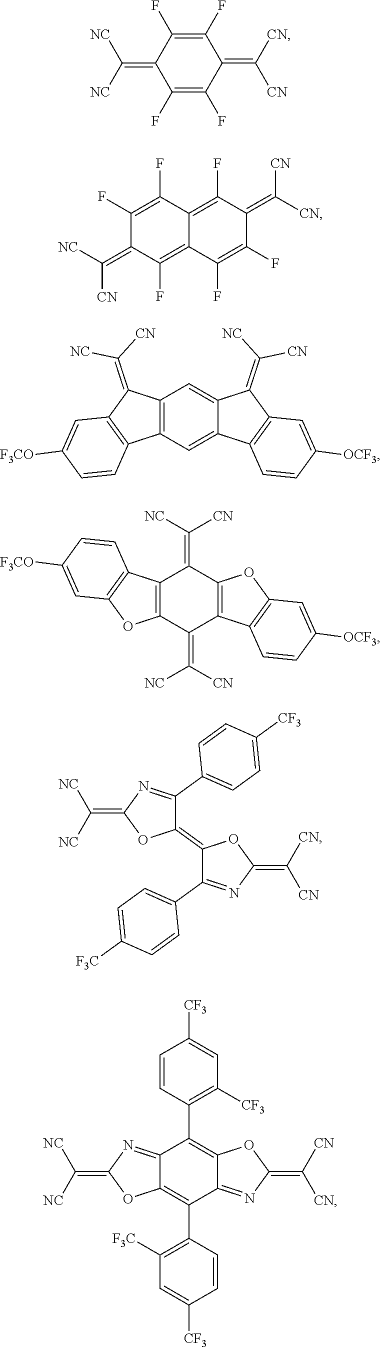

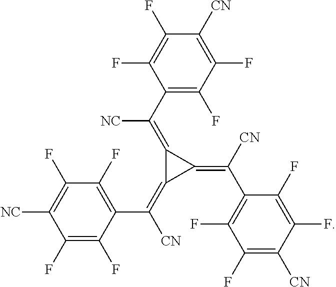 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

According to another embodiment of the present disclosure, in the the light-emitting layer, the metal complex is doped in the first host compound and the second host compound, and a weight of the metal complex accounts for 1% to 30% of a total weight of the light-emitting layer.

According to another embodiment of the present disclosure, the weight of the metal complex accounts for 3% to 13% of the total weight of the light-emitting layer.

According to another embodiment of the present disclosure, further disclosed is a compound combination comprising the metal complex comprising the ligand La having the structure of Formula 1.

Combination with Other Materials

The materials described in the present disclosure for a particular layer in an organic light-emitting device can be used in combination with various other materials present in the device. The combinations of these materials are described in more detail in U.S. Pat. Pub. No. US20160359122A1 at paragraphs 0132-0161, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, compounds disclosed herein may be used in combination with a wide variety of light-emitting dopants, hosts, transport layers, blocking layers, injection layers, electrodes and other layers that may be present. The combination of these materials is described in detail in paragraphs 0080-0101 of U.S. Pat. Pub. No. US20150349273A1, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

A method for preparing the compound of the present disclosure is not limited herein. Typically, the following compounds are used as examples without limitation, and synthesis routes and preparation methods thereof are described below.

### Synthesis Example 1: Synthesis of Metal Complex 2186

### Step 1:

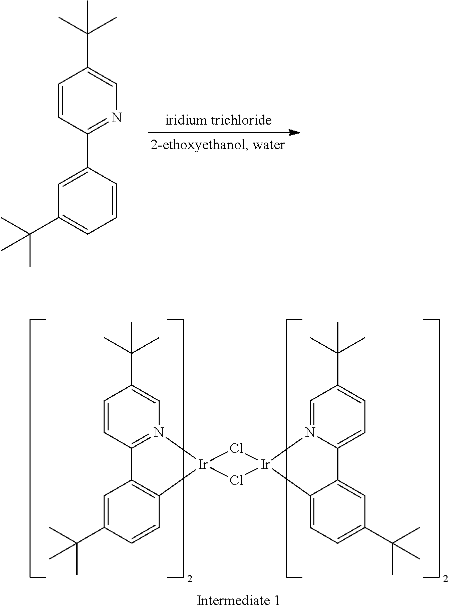

5-Tert-butyl-2-(3-tert-butylphenyl)-pyridine (4.7 g, 17.6 mmol), iridium trichloride trihydrate (1.5 g, 4.2 mmol), 120 mL of 2-ethoxyethanol and 40 mL of water were sequentially added to a dry 500 mL round-bottom flask, purged with nitrogen three times, and heated and stirred for 24 h at 130° C. under nitrogen protection. The mixture was cooled, filtered, washed three times with methanol and n-hexane respectively, and pumped to dryness to obtain 3.0 g of Intermediate 1 (with a yield of 96%).

### Step 2:

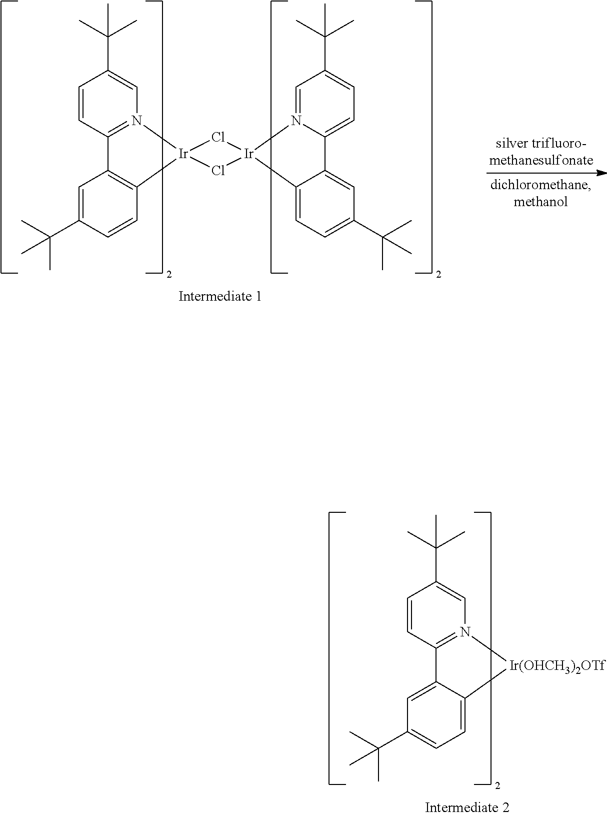

Intermediate 1 (3.0 g, 2.0 mmol), 100 mL of anhydrous dichloromethane, 10 mL of methanol and silver trifluoromethanesulfonate (1.1 g, 4.3 mmol) were sequentially added to a dry 250 mL round-bottom flask, purged with nitrogen three times, and stirred overnight at room temperature under nitrogen protection. The mixture was filtered through diatomite and washed twice with dichloromethane. The organic phases below were collected and concentrated under reduced pressure to obtain 3.7 g of Intermediate 2 as a yellow solid (with a yield of 100%).

### Step 3:

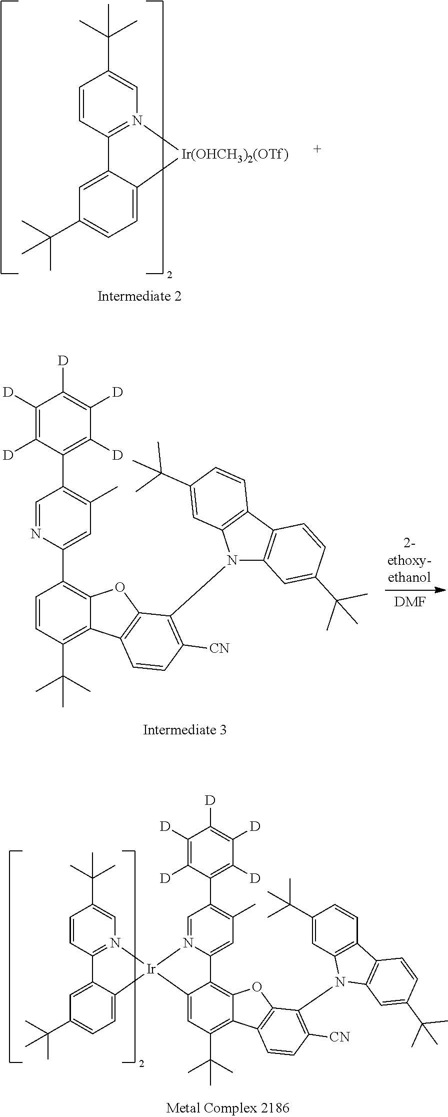

Intermediate 2 (3.6 g, 3.9 mmol), Intermediate 3 (3.8 g, 5.4 mmol), 2-ethoxyethanol (50 mL) and DMF (50 mL) were sequentially added to a dry 250 mL round-bottom flask, and heated to react for 100 h at 100° C. under N₂ protection. After the reaction was cooled, the system was concentrated under reduced pressure and purified through column chromatography to obtain Metal Complex 2186 as a yellow solid (3.1 g, with a yield of 56%).

### Synthesis Example 2: Synthesis of Metal Complex 2176

### Step 1:

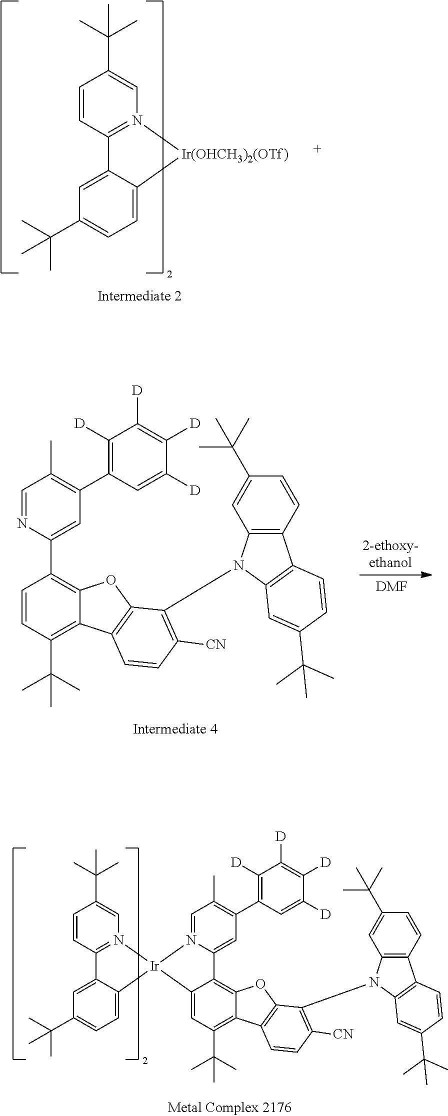

Intermediate 2 (1.9 g, 2.2 mmol), Intermediate 4 (0.9 g, 2.0 mmol), 2-ethoxyethanol (30 mL) and DMF (30 mL) were sequentially added to a dry 250 mL round-bottom flask, and heated to react for 120 h at 100° C. under N₂ protection. After the reaction was cooled, the system was filtered through diatomite. The system was washed twice with methanol and washed twice with n-hexane. Yellow solids on the diatomite were dissolved with dichloromethane. The organic phases were collected, concentrated under reduced pressure, and purified through column chromatography to obtain Metal Complex 2176 as a yellow solid (1.0 g, with a yield of 40.3%).

### Synthesis Example 3: Synthesis of Metal Complex 2920

### Step 1:

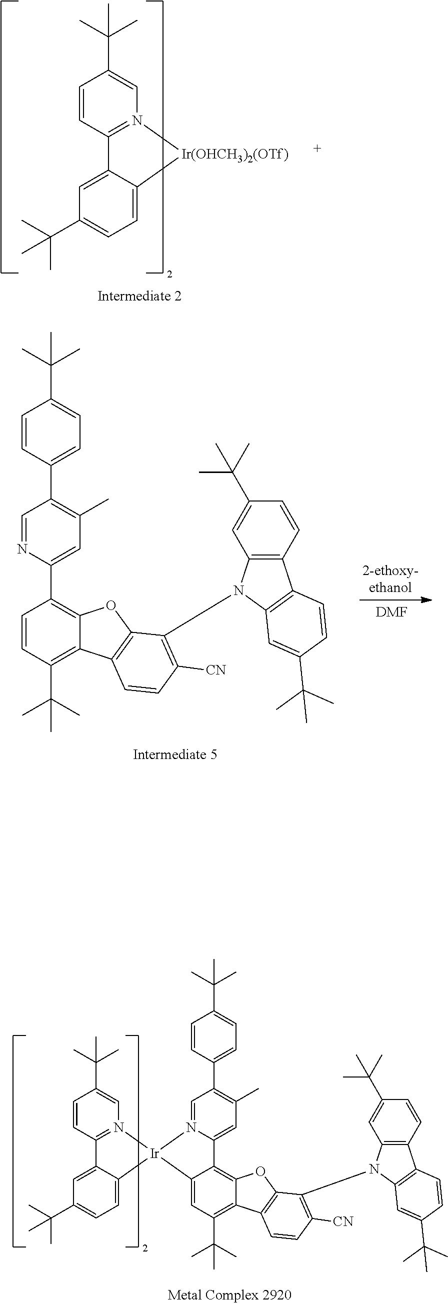

Intermediate 2 (1.6 g, 1.7 mmol), Intermediate 5 (1.6 g, 2.1 mmol), 2-ethoxyethanol (30 mL) and DMF (30 mL) were sequentially added to a dry 250 mL round-bottom flask, and heated to react for 120 h at 100° C. under N₂ protection. After the reaction was cooled, the system was filtered through diatomite. The system was washed twice with methanol and washed twice with n-hexane. Yellow solids on the diatomite were dissolved with dichloromethane. The organic phases were collected, concentrated under reduced pressure, and purified through column chromatography to obtain Metal Complex 2920 as a yellow solid (1.0 g, with a yield of 39.9%).

### Synthesis Example 4: Synthesis of Metal Complex 3797

### Step 1:

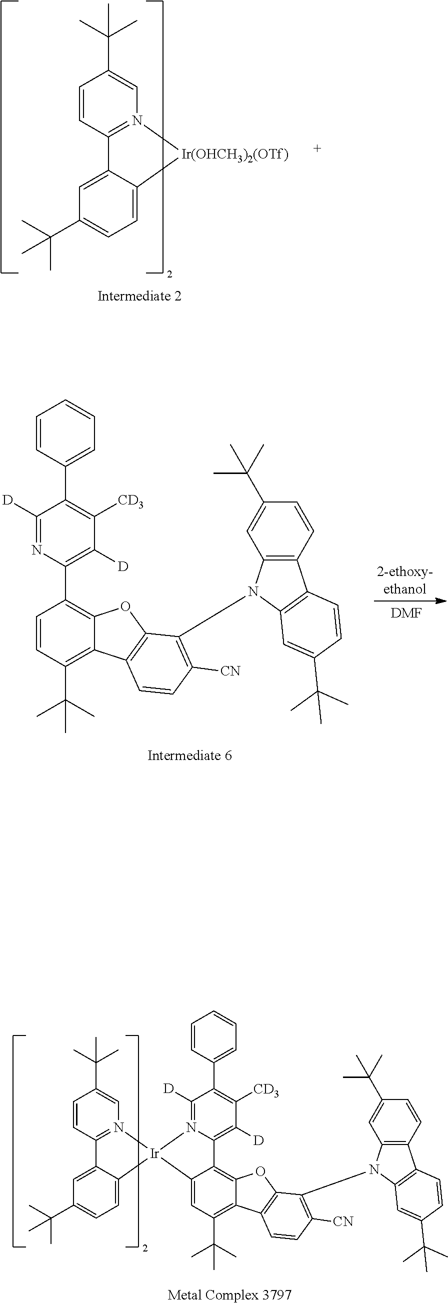

Intermediate 2 (3.3 g, 3.6 mmol), Intermediate 6 (3.5 g, 5.0 mmol), 2-ethoxyethanol (60 mL) and DMF (60 mL) were sequentially added to a dry 250 mL round-bottom flask, and heated to react for 120 h at 100° C. under N₂ protection. After the reaction was cooled, the system was filtered through diatomite. The system was washed twice with methanol and washed twice with n-hexane. Yellow solids on the diatomite were dissolved with dichloromethane. The organic phases were collected, concentrated under reduced pressure, and purified through column chromatography to obtain Metal Complex 3797 as a yellow solid (3.6 g, with a yield of 71%).

Those skilled in the art will appreciate that the above preparation methods are merely exemplary. Those skilled in the art can obtain other compound structures of the present disclosure through the modifications of the preparation methods.

### Device Example

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 10⁻⁸ Torr. Compound HT and Compound PD were deposited for use as a hole injection layer (HIL). Compound HT was used as a hole transport layer (HTL). Compound PH-1 was used as an electron blocking layer (EBL). Metal Complex 2186 of the present disclosure was doped in Compound PH-1 and Compound H-91, all of which were co-deposited for use as an emissive layer (EML). On the EML, Compound H-1 was used as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Example 2

The implementation mode in Device Example 2 was the same as that in Device Example 1, except that in the emissive layer, Metal Complex 2186 was replaced with Metal Complex 2176 of the present disclosure.

### Device Comparative Example 1

The implementation mode in Device Comparative Example 1 was the same as that in Device Example 1, except that in the emissive layer, Metal Complex 2186 was replaced with GD1.

Detailed structures and thicknesses of layers of the devices are shown in the following table. A layer using more than one material is obtained by doping different compounds at their weight ratio as recorded.

TABLE 1
Device structures in Device Examples 1 and 2 and Device Comparative Example 1

| Device ID | HIL | HTL | EBL | EML | HBL | ETL |
|---|---|---|---|---|---|---|
| Example 1 | Compound | Compound | Compound | Compound | CompoundH-1 | Compound |
| | HT:Compound | HT | PH-1 | PH-1:Compound | (50 Å) | ET:Liq (2:3) |
| | PD (97:3) | (350 Å) | (50 Å) | H-91:Metal Complex | | (350 Å) |
| | (100 Å) | | | 2186 (47:47:6) | | |
| | | | | (400 Å) | | |
| Example 2 | Compound | Compound | Compound | Compound | Compound | Compound |
| | HT:Compound | HT | PH-1 | PH-1:Compound | H-1 (50 Å) | ET:Liq (2:3) |
| | PD (97:3) | (350 Å) | (50 Å) | H-91:Metal Complex | | (350 Å) |
| | (100 Å) | | | 2176 (47:47:6) | | |
| | | | | (400 Å) | | |
| Comparative | Compound | Compound | Compound | Compound | Compound | Compound |
| Example 1 | HT:Compound | HT | PH-1 | PH-1:Compound | H-1 (50 Å) | ET:Liq (2:3) |
| | PD (97:3) | (350 Å) | (50 Å) | H-91:GD1 (47:47:6) | | (350 Å) |
| | (100 Å) | | | (400 Å) | | |

The materials used in the devices have the following structures:

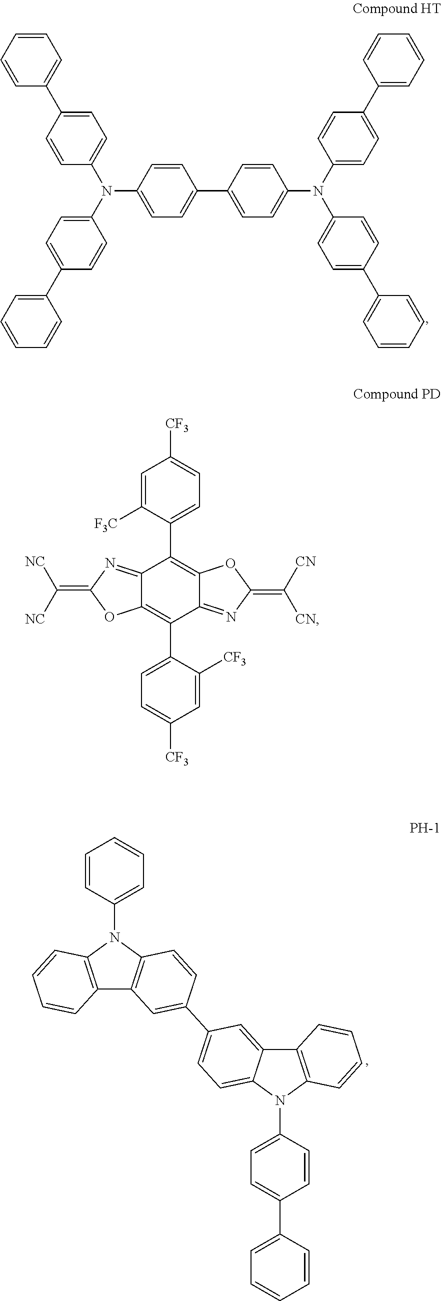 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(-n3c4ccccc4c4cc(-c5ccc6c(c5)c5ccccc5n6-c5ccccc5)ccc43)cc2)cc1]

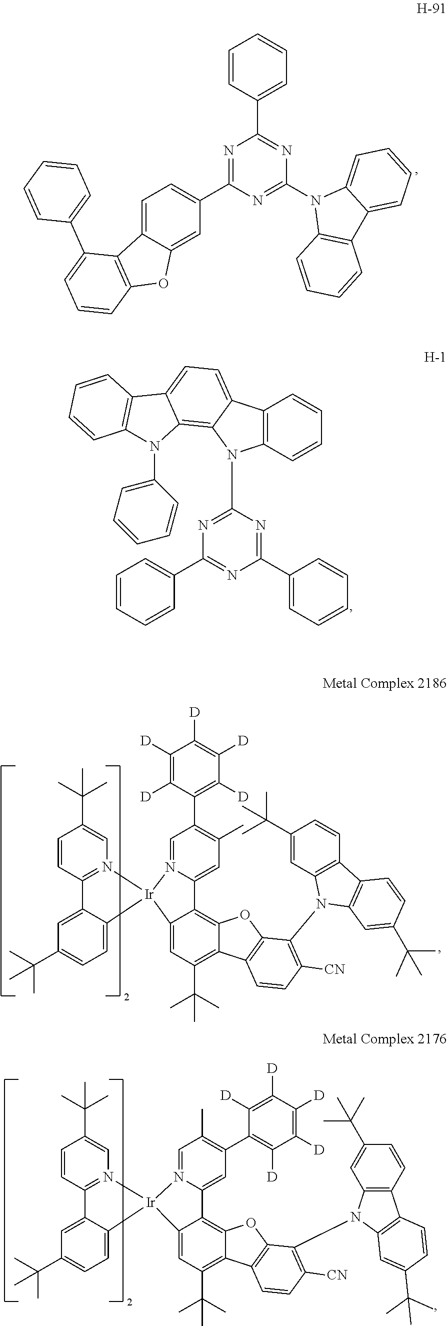

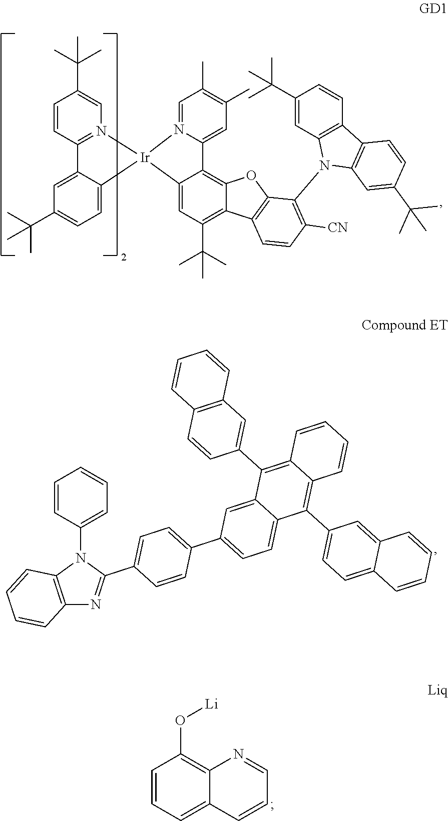

The current-voltage-luminance (IVL) characteristics of the devices were measured. The CIE data, maximum emission wavelength λₘₐₓ, current efficiency (CE), power efficiency (PE) and external quantum efficiency (EQE) of/the devices were measured at 1000 cd/N². The data are recorded and shown in Table 2.

TABLE 2
Device data in Device Examples 1 and
2 and Device Comparative Example 1

| | | λₘₐₓ | CE | PE | EQE |
|---|---|---|---|---|---|
| Device ID | CIE (x, y) | (nm) | (cd/A) | (lm/W) | (%) |
| Example 1 | (0.322, 0.651) | 531 | 114.33 | 118.25 | 28.44 |
| Example 2 | (0.331, 0.643) | 530 | 114.59 | 122.48 | 28.82 |
| Comparative | (0.281, 0.671) | 524 | 106.00 | 109.55 | 27.34 |
| Example 1 | | | | | |

As can be seen from the data in Table 2, Metal Complex 2186 used in Example 1 and Metal Complex 2176 used in Example 2 differ from GD1 used in Comparative Example 1 in structure only in that Metal Complex 2186 used in Example 1 and Metal Complex 2176 used in Example 2 have the particular structure La of the present disclosure where ortho-substituted alkyl and aryl structures are contained in pyridine joined to a dibenzofuran structure, while two alkyl are present in pyridine joined to a dibenzofuran structure of GD1 used in Comparative Example 1. The results indicate that on the basis of very high CE, PE and EQE of Comparative Example 1, Examples 1 and 2 of the present disclosure further obtain significant improvements compared with device performance CE, PE and EQE of Comparative Example 1. Moreover, compared with Comparative Example 1, Examples 1 and 2 have relatively apparent red shift in emitted colors and effectively adjust the emitted colors.

### Device Example 3

The implementation mode in Device Example 3 was the same as that in Device Example 1, except that in the emissive layer (EML), Compound PH-1 was replaced with Compound PH-75 and Compound H-91 was replaced with Compound H-250.

### Device Comparative Example 2

The implementation mode in Device Comparative Example 2 was the same as that in Device Example 3, except that Metal Complex 2186 was replaced with GD1.

Detailed structures and thicknesses of layers of the devices are shown in the following table. A layer using more than one material is obtained by doping different compounds at their weight ratio as recorded.

TABLE 3
Device structures in Device Example 3 and Device Comparative Example 2

| Device ID | HIL | HTL | EBL | EML | HBL | ETL |
|---|---|---|---|---|---|---|
| Example 3 | Compound | Compound | Compound | Compound | Compound | Compound |
| | HT:Compound | HT | PH-1 | PH-75:Compound | H-1 (50 Å) | ET:Liq (2:3) |
| | PD (97:3) | (350 Å) | (50 Å) | H-250:Metal | | (350 Å) |
| | (100 Å) | | | Complex 2186 | | |
| | | | | (63:27:10) (400 Å) | | |
| Comparative | Compound | Compound | Compound | Compound | Compound | Compound |
| Example 2 | HT:Compound | HT | PH-1 | PH-75:Compound | H-1 (50 Å) | ET:Liq (2:3) |
| | PD (97:3) | (350 Å) | (50 Å) | H-250:GD1 | | (350 Å) |
| | (100 Å) | | | (63:27:10) (400 Å) | | |

The materials used in the devices have the following structures:

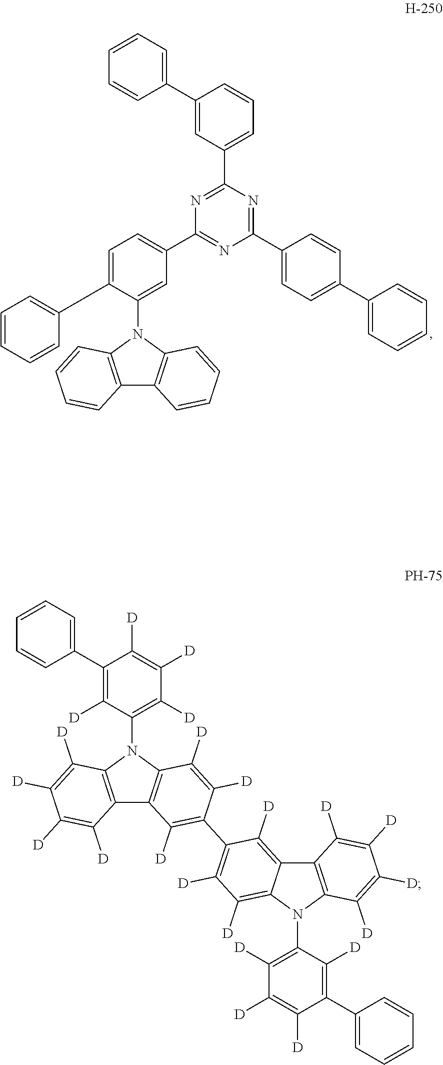

The current-voltage-luminance (IVL) characteristics of the devices were measured. The CIE data, maximum emission wavelength λₘₐₓ, current efficiency (CE), power efficiency (PE) and external quantum efficiency (EQE) of the devices were measured at 1000 cd/m². The data are recorded and shown in Table 4.

TABLE 4
Device data in Device Example 3
and Device Comparative Example 2

| | | λₘₐₓ | CE | PE | EQE |
|---|---|---|---|---|---|
| Device ID | CIE (x, y) | (nm) | (cd/A) | (lm/W) | (%) |
| Example 3 | (0.328, 0.646) | 531 | 112 | 106 | 27.97 |
| Comparative | (0.281, 0.672) | 524 | 105 | 98 | 26.96 |
| Example 2 | | | | | |

As can be seen from the data in Table 4, Metal Complex 2186 used in Example 3 differs from GD1 used in Comparative Example 2 in structure only in that Metal Complex 2186 used in Example 3 has the particular structure La of the present disclosure where ortho-substituted alkyl and aryl structures are contained in pyridine joined to a dibenzofuran structure, while two alkyl are present in pyridine joined to a dibenzofuran structure of GD1 used in Comparative Example 2. The results indicate that on the basis of very high CE, PE and EQE of Comparative Example 2, Example 3 of the present disclosure further obtains a significant improvement compared with device performance CE, PE and EQE of Comparative Example 2. Moreover, compared with Comparative Example 2, Example 3 has relatively apparent red shift in emitted colors and effectively adjusts the emitted colors.

The above data indicate that the metal complexes with the characteristics of the present disclosure all exhibit more advantageous CE, PE and EQE effects in the devices with different host materials and achieve the object of effectively adjusting the emitted colors, thereby better improving the overall performance of the electroluminescent devices.

### Device Example 4

The implementation mode in Device Example 4 was the same as that in Device Example 1, except that in the emissive layer, Metal Complex 2186 was replaced with Metal Complex 2920 of the present disclosure.

### Device Example 5

The implementation mode in Device Example 5 was the same as that in Device Example 1, except that in the emissive layer, Metal Complex 2186 was replaced with Metal Complex 3797 of the present disclosure.

Detailed structures and thicknesses of layers of the devices are shown in the following table. A layer using more than one material is obtained by doping different compounds at their weight ratio as recorded.

TABLE 5
Device structures in Device Examples 4 and 5

| Device ID | HIL | HTL | EBL | EML | HBL | ETL |
|---|---|---|---|---|---|---|
| Example 4 | Compound | Compound | Compound | Compound | Compound | Compound |
| | HT:Compound | HT | PH-1 | PH-1:Compound | H-1 (50 Å) | ET:Liq (2:3) |
| | PD (97:3) | (350 Å) | (50 Å) | H-91:Metal Complex | | (350 Å) |
| | (100 Å) | | | 2920 (47:47:6) (400 Å) | | |
| Example 5 | Compound | Compound | Compound | Compound | Compound | Compound |
| | HT:Compound | HT | PH-1 | PH-1:Compound | H-1 (50 Å) | ET:Liq (2:3) |
| | PD (97:3) | (350 Å) | (50 Å) | H-91:Metal Complex | | (350 Å) |
| | (100 Å) | | | 3797 (47:47:6) (400 Å) | | |

The new materials used in the devices have the following structures:

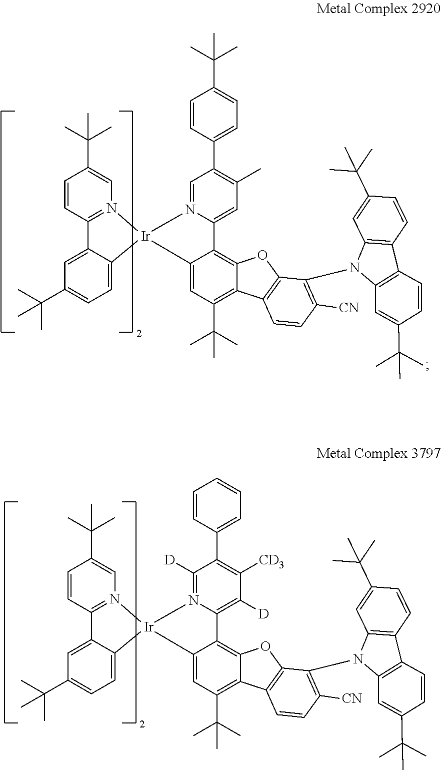

The current-voltage-luminance (IVL) characteristics of the devices were measured. The CIE data, maximum emission wavelength λₘₐₓ, current efficiency (CE), power efficiency (PE) and external quantum efficiency (EQE) of the devices were measured at 1000 cd/m². The data are recorded and shown in Table 6.

TABLE 6
Device data in Device Examples 4 and 5

| | | λₘₐₓ | CE | PE | EQE |
|---|---|---|---|---|---|
| Device ID | CIE (x, y) | (nm) | (cd/A) | (lm/W) | (%) |
| Example 4 | (0.317, 0.654) | 530 | 112.78 | 122.73 | 28.32 |
| Example 5 | (0.320, 0.652) | 531 | 114.75 | 120.32 | 28.30 |

As can be seen from the data in Table 6, using Metal Complex 2920 with the particular structure La of the present disclosure in Example 4 and using Metal Complex 3797 with the particular structure La of the present disclosure in Example 5 both obtain excellent device performance. The above data indicate that the metal complexes with the characteristics of the present disclosure have more advantageous CE, PE and EQE effects and achieve the object of effectively adjusting the emitted colors, thereby better improving the overall performance of the electroluminescent devices.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand La coordinated to the metal M;
wherein the metal M is selected from a metal with a relative atomic mass greater than 40, and La has a structure represented by Formula 1: 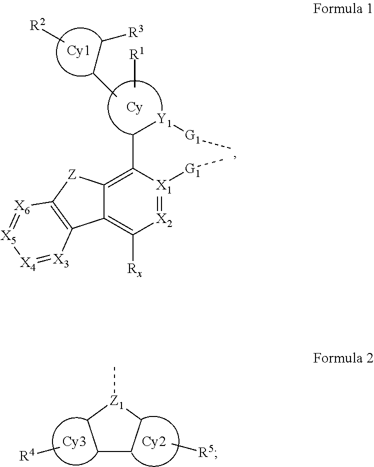
wherein,
G₁ is, at each occurrence identically or differently, selected from a single bond, O or S;
X₁ is, at each occurrence identically or differently, selected from C or N and joined to the metal M through G₁;
X₂ to X₆ are, at each occurrence identically or differently, selected from CRₓ′ or N;
Y₁ is, at each occurrence identically or differently, selected from C or N and joined to the metal M through G₁;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
the ring Cy is, at each occurrence identically or differently, selected from an aromatic ring having 6 to 24 ring atoms which comprises Y₁, a heteroaromatic ring having 5 to 24 ring atoms which comprises Y₁ or a combination thereof;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R², R⁴ and R⁵ represent, at each occurrence identically or differently, mono-substitution, multiple substitutions or non-substitution, and in the ring Cy, at least one R¹ is adjacent to the ring Cy1;
in the ring Cy1, R³ is adjacent to the ring Cy;
R¹, R², R³, R⁴, R⁵, R′, Rₓ′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₃ to X₆ is selected from CRₓ′, and Rₓ′ has, at each occurrence identically or differently, a structure of Formula 2; at least one of X₃ to X₆ is selected from CRₓ′, and Rₓ′ is selected from cyano or fluorine;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; adjacent substituents R², R³, R⁴ and R⁵ can be optionally joined to form a ring; and
“- - -” represents a joining position.

2. The metal complex according to claim 1, wherein La has a structure represented by Formula 1-a: 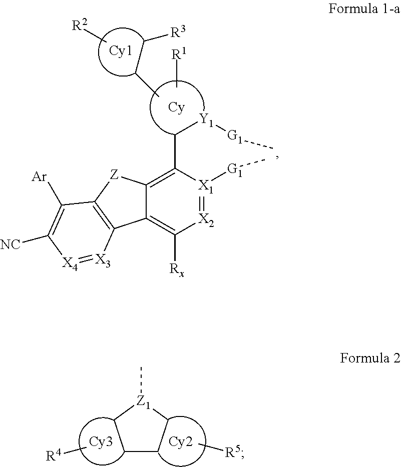
wherein,
Ar has, at each occurrence identically or differently, the structure of Formula 2;
G₁ is, at each occurrence identically or differently, selected from a single bond, O or S;
X₁ is, at each occurrence identically or differently, selected from C or N and joined to the metal M through G₁;
X₂, X₃ and X₄ are, at each occurrence identically or differently, selected from CRₓ′ or N;
Y₁ is, at each occurrence identically or differently, selected from C or N and joined to the metal M through G₁;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
the ring Cy is, at each occurrence identically or differently, selected from an aromatic ring having 6 to 24 ring atoms which comprises Y₁, a heteroaromatic ring having 5 to 24 ring atoms which comprises Y₁ or a combination thereof;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R¹, R², R⁴ and R⁵ represent, at each occurrence identically or differently, mono-substitution, multiple substitutions or non-substitution;
in the ring Cy, at least one R¹ is adjacent to the ring Cy1;
in the ring Cy1, R³ is adjacent to the ring Cy;
R¹, R², R³, R⁴, R⁵, Rₓ′, R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R², R³, R⁴ and R⁵ can be optionally joined to form a ring; and
“- - -” represents a joining position.

3. The metal complex according to claim 1, wherein the ring Cy is, at each occurrence identically or differently, selected from a heteroaromatic ring having 5 to 24 ring atoms which comprises Y₁, wherein Y₁ is selected from C or N, preferably N; the ring Cy1, the ring Cy2 and the ring Cy3 are, at each occurrence identically or differently, selected from substituted or unsubstituted aromatic ring having 6 to 24 ring atoms;
preferably, the ring Cy, the ring Cy1, the ring Cy2 and the ring Cy3 are, at each occurrence identically or differently, selected from the group consisting of: a pyrrole ring, a furan ring, a thiophene ring, an imidazole ring, a pyrazole ring, a thiazole ring, an oxazole ring, a benzene ring, a pyridine ring, a pyrazine ring, a pyridazine ring, a pyrimidine ring, a triazine ring, an indole ring, a benzimidazole ring, a benzofuran ring, a benzothiophene ring, a benzothiazole ring, a benzoxazole ring, a dibenzofuran ring, a dibenzothiophene ring, a carbazole ring and a pyridoindole ring;
preferably, the ring Cy1, the ring Cy2 and the ring Cy3 are, at each occurrence identically or differently, selected from the group consisting of: a benzene ring, a pyridine ring, an indole ring, a benzimidazole ring, a carbazole ring, a pyridoindole ring, a benzofuran ring, a benzothiophene ring, a benzothiazole ring, a benzoxazole ring, a dibenzofuran ring and a dibenzothiophene ring; and
preferably, the ring Cy1, the ring Cy2 and the ring Cy3 are, at each occurrence identically or differently, selected from the group consisting of: a benzene ring and a pyridine ring.

4. The metal complex according to claim 2, wherein the metal complex has a general formula of M(La)ₘ(Lb)ₙ;
wherein La and Lb are a first ligand and a second ligand coordinated to the metal M, respectively, and La and Lb can be optionally joined to form a multidentate ligand;
m is selected from 1, 2 or 3, n is selected from 0, 1 or 2, and m+n equals the oxidation state of the metal M; when m is greater than or equal to 2, multiple La are the same or different; when n is equal to 2, two Lb are the same or different;
Lb is, at each occurrence identically or differently, selected from a structure represented by any one of the group consisting of the following: 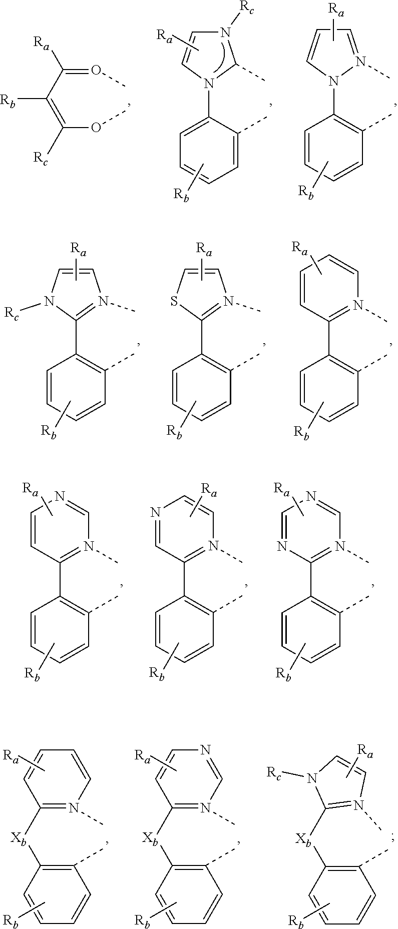
X_{b} is, at each occurrence identically or differently, selected from the group consisting of: O, S, Se, NR_{N1} and CR_{c1}R_{c2};
Rₐ and R_{b} represent, at each occurrence identically or differently, mono-substitution, multiple substitutions or non-substitution;
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

5. The metal complex according to claim 1, wherein the metal M is selected from the group consisting of Cu, Ag, Au, Rᵤ, Rh, Pd, Os, Ir and Pt; preferably, M is selected from Pt or Ir.

6. The metal complex according to claim 1, wherein the metal complex has a general formula of Ir(La)ₘ(Lb)ₙ, and Ir(La)ₘ(Lb)ₙ has a structure represented by Formula 3A or Formula 3B: 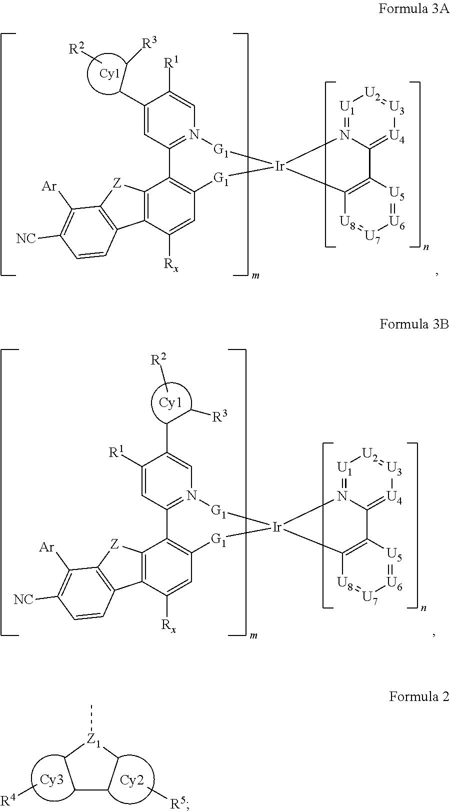
wherein,
m is selected from 1, 2 or 3, n is selected from 0, 1 or 2, and m+n=3; when m is greater than or equal to 2, multiple La are the same or different; when n is equal to 2, two Lb are the same or different;
Ar has, at each occurrence identically or differently, the structure of Formula 2;
G₁ is, at each occurrence identically or differently, selected from a single bond, O or S;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
U₁ to U₄ are, at each occurrence identically or differently, selected from CRₐ or N;
U₅ to U₈ are, at each occurrence identically or differently, selected from CR_{b} or N;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R², R⁴ and R⁵ represent, at each occurrence identically or differently, mono-substitution, multiple substitutions or non-substitution;
in the ring Cy1, R³ is adjacent to a pyridine ring;
R¹, R², R³, R⁴, R⁵, Rₐ, R_{b}, R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R², R³, R⁴ and R⁵ can be optionally joined to form a ring.

7. The metal complex according to claim 1, wherein the metal complex has a general formula of Ir(La)ₘ(Lb)ₙ, and Ir(La)ₘ(Lb)ₙ has a structure represented by Formula 3C or Formula 3D: 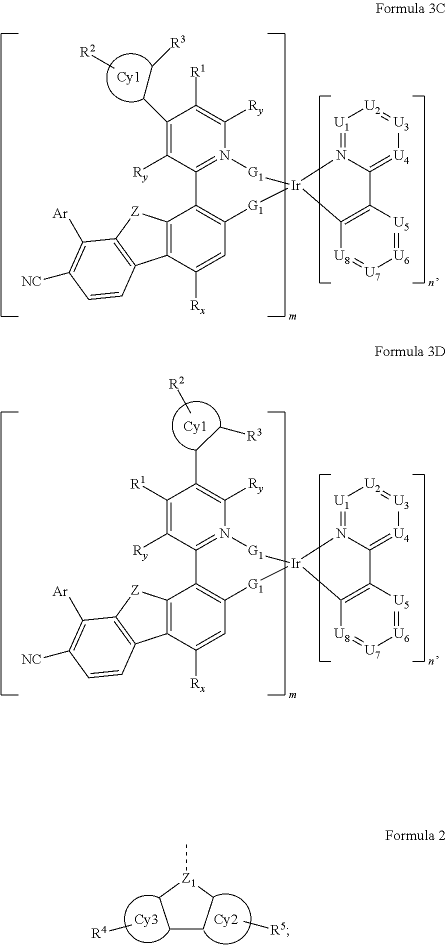
m is selected from 1, 2 or 3, n is selected from 0, 1 or 2, and m+n=3; when m is greater than or equal to 2, multiple La are the same or different; when n is equal to 2, two Lb are the same or different;
Ar has, at each occurrence identically or differently, the structure of Formula 2;
G₁ is, at each occurrence identically or differently, selected from a single bond, O or S;
Z is, at each occurrence identically or differently, selected from the group consisting of O, S, Se, NR′, CR′R′, SiR′R′ and GeR′R′; when two R′ are present at the same time, the two R′ are the same or different;
Z₁ is, at each occurrence identically or differently, selected from N, B, P, CR″, SiR″ or GeR″;
U₁ to U₄ are, at each occurrence identically or differently, selected from CRₐ or N;
U₅ to U₈ are, at each occurrence identically or differently, selected from CR_{b} or N;
the ring Cy1, the ring Cy2 and the ring Cy3 are, at each occurrence identically or differently, selected from substituted or unsubstituted aromatic ring having 6 to 24 ring atoms, substituted or unsubstituted heteroaromatic ring having 5 to 24 ring atoms or a combination thereof;
R², R⁴ and R⁵ represent, at each occurrence identically or differently, mono-substitution, multiple substitutions or non-substitution;
in the ring Cy1, R³ is adjacent to a pyridine ring;
R¹, R², R³, R⁴, R⁵, R_{y}, Rₐ, R_{b}, R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R¹ and/or R³ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Rₓ is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R², R³, R⁴, R⁵, Rₐ and R_{b} can be optionally joined to form a ring.

8. The metal complex according to claim 1, wherein G₁ is, at each occurrence, selected from a single bond.

9. The metal complex according to claim 1, wherein Z₁ is, at each occurrence, selected from N; Z is, at each occurrence identically or differently, selected from O, S or Se; preferably, Z is, at each occurrence identically or differently, selected from O or S; more preferably, Z is, at each occurrence, selected from O.

10. The metal complex according to claim 1, wherein Rₓ is, at each occurrence identically or differently, selected from the group consisting of: fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms and combinations thereof; and
preferably, Rₓ is, at each occurrence identically or differently, selected from the group consisting of: substituted or unsubstituted alkyl having 1 to 20 carbon atoms, substituted or unsubstituted cycloalkyl having 3 to 20 ring carbon atoms and substituted or unsubstituted aryl having 6 to 30 carbon atoms.

11. The metal complex according to claim 1, wherein R¹ and R³ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof;
at least one of R¹ and/or R³ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof; and
preferably, R¹ and R³ are, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof, at least one of R¹ and/or R³ is, at each occurrence identically or differently, selected from the group consisting of: substituted or unsubstituted alkyl having 1 to 20 carbon atoms, substituted or unsubstituted cycloalkyl having 3 to 20 ring carbon atoms and combinations thereof.

12. The metal complex according to claim 1, wherein one or more R² are present, and R² is, at each occurrence identically or differently, selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof; and
preferably, one or more R² are present, and R² is, at each occurrence identically or differently, selected from the group consisting of: deuterium, substituted or unsubstituted alkyl having 1 to 20 carbon atoms, substituted or unsubstituted cycloalkyl having 3 to 20 ring carbon atoms and combinations thereof.

13. The metal complex according to claim 1, wherein R¹, R³ and at least one R² are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted alkylsilyl having 3 to 20 carbon atoms, substituted or unsubstituted alkylgermanyl having 3 to 20 carbon atoms and combinations thereof; and
preferably, R¹, R³ and at least one R² are, at each occurrence identically or differently, selected from the group consisting of: substituted or unsubstituted alkyl having 1 to 20 carbon atoms, substituted or unsubstituted cycloalkyl having 3 to 20 ring carbon atoms and combinations thereof.

14. The metal complex according to claim 7, wherein at least one of U₁ to U₄ is selected from CRₐ, and/or at least one of U₅ to U₈ is selected from CR_{b}, wherein Rₐ and R_{b} are selected from substituted or unsubstituted alkyl having 1 to 20 carbon atoms, substituted or unsubstituted cycloalkyl having 3 to 20 ring carbon atoms or a combination thereof, and the total number of carbon atoms in Rₐ and R_{b} is greater than or equal to 2; and
preferably, at least one of U₁ to U₄ is selected from CRₐ, and/or at least one of U₅ to U₈ is selected from CR_{b}, wherein Rₐ and R_{b} are selected from substituted or unsubstituted alkyl having 1 to 20 carbon atoms, substituted or unsubstituted cycloalkyl having 3 to 20 ring carbon atoms or a combination thereof, and the total number of carbon atoms in Rₐ and R_{b} is greater than or equal to 4.

15. The metal complex according to claim 7, wherein R⁴ and R⁵ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms and combinations thereof, and adjacent substituents R⁴ and R⁵ can be optionally joined to form a ring;
preferably, R⁴ and R⁵ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
more preferably, R⁴ and R⁵ are, at each occurrence identically or differently, selected from the group consisting of: hydrogen, deuterium, fluorine, substituted or unsubstituted alkyl having 1 to 12 carbon atoms, substituted or unsubstituted cycloalkyl having 3 to 10 ring carbon atoms, substituted or unsubstituted aryl having 6 to 18 carbon atoms, substituted or unsubstituted heteroaryl having 3 to 18 carbon atoms and combinations thereof;
more preferably, R⁴ and R⁵ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms and combinations thereof; and
more preferably, R⁴ and R⁵ are, at each occurrence identically or differently, selected from the group consisting of: hydrogen, deuterium, fluorine, substituted or unsubstituted alkyl having 1 to 12 carbon atoms, substituted or unsubstituted cycloalkyl having 3 to 10 ring carbon atoms and combinations thereof.

16. The metal complex according to claim 4, wherein Ar is, at each occurrence identically or differently, selected from the group consisting of Ar1 to Ar104, wherein the structures of Ar1 to Ar104 are as follows: 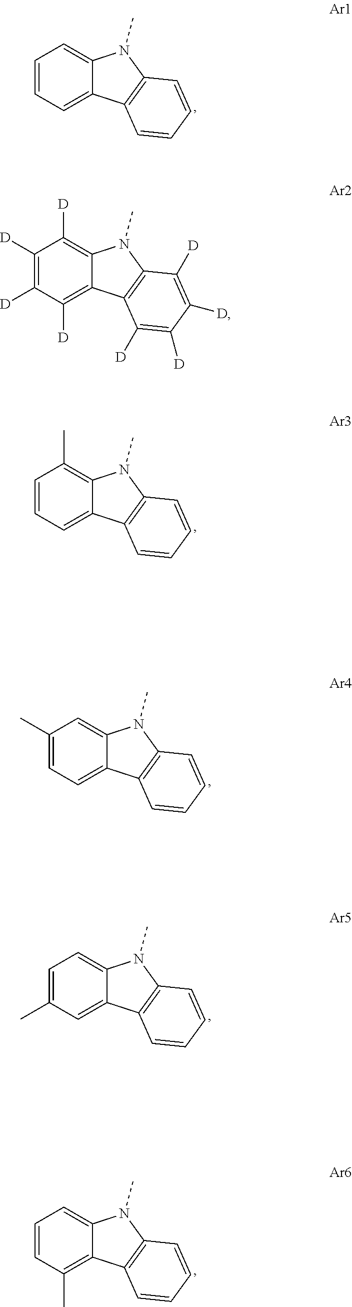 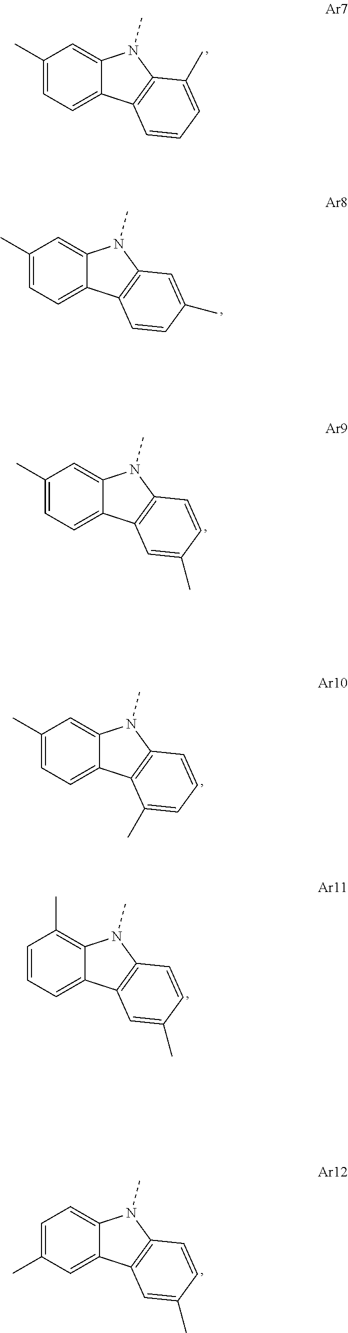 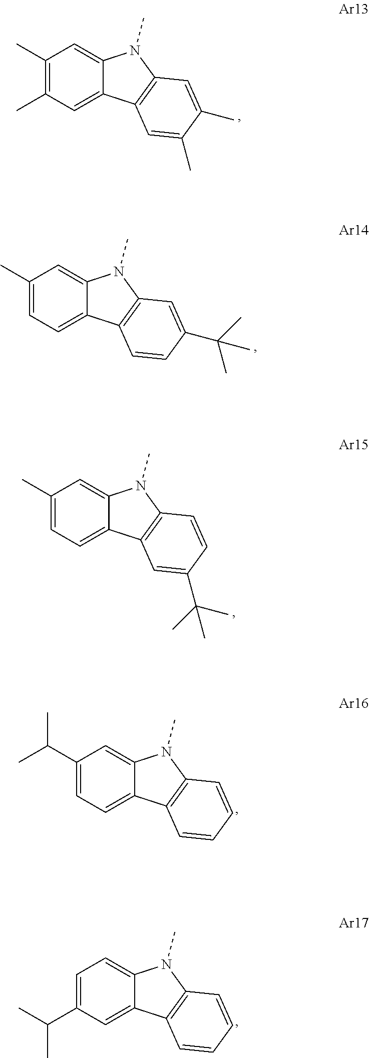 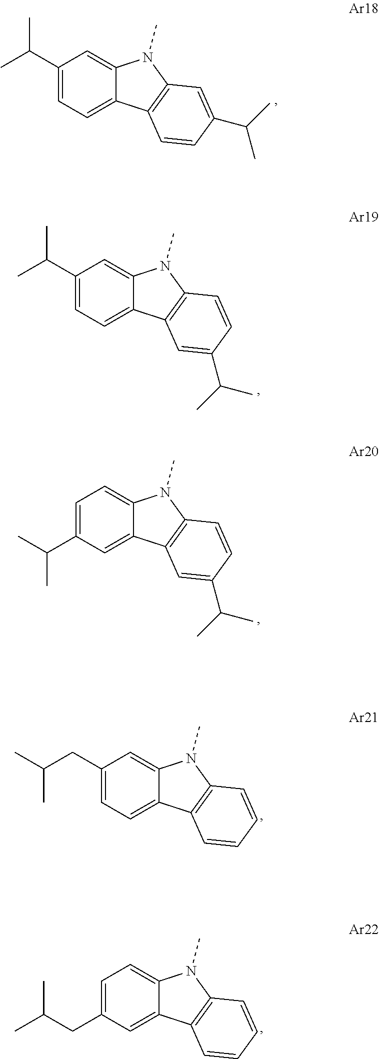 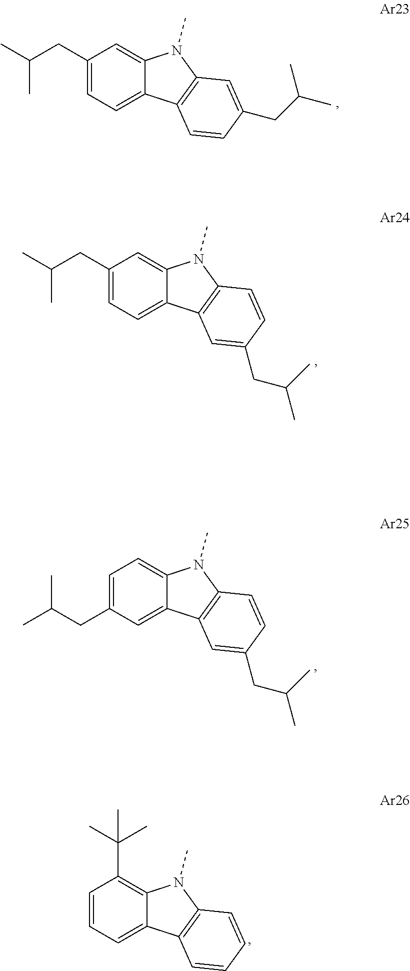 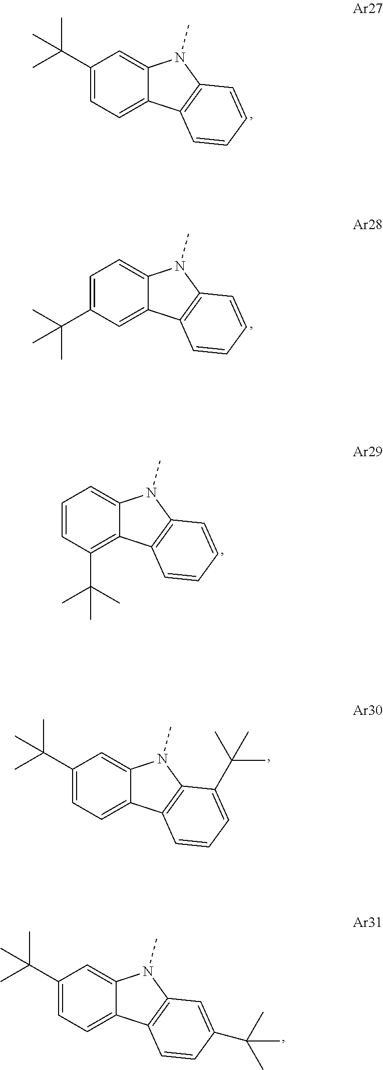 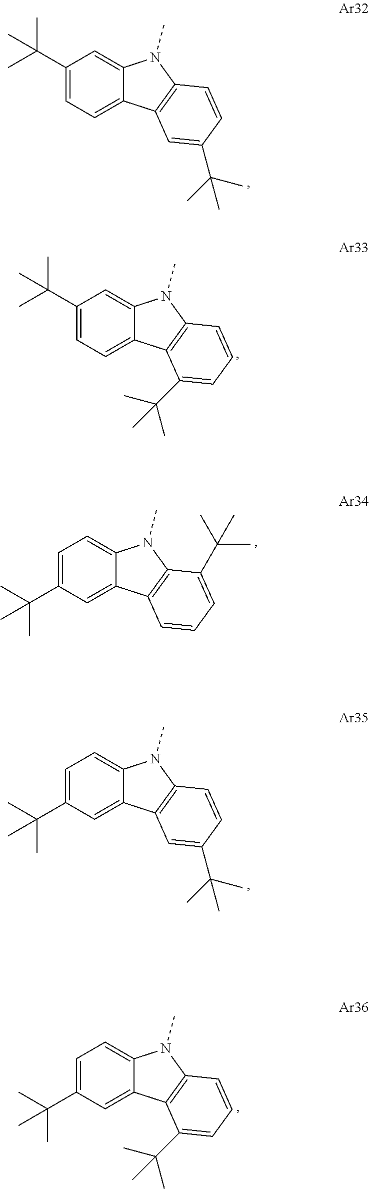 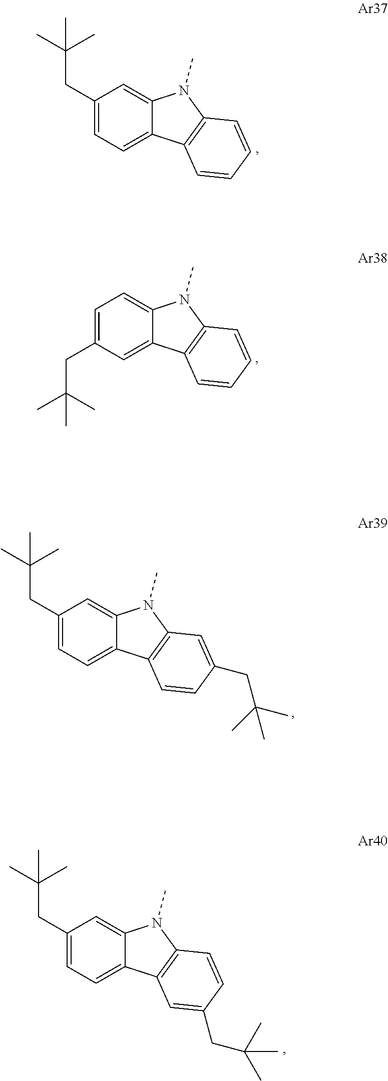 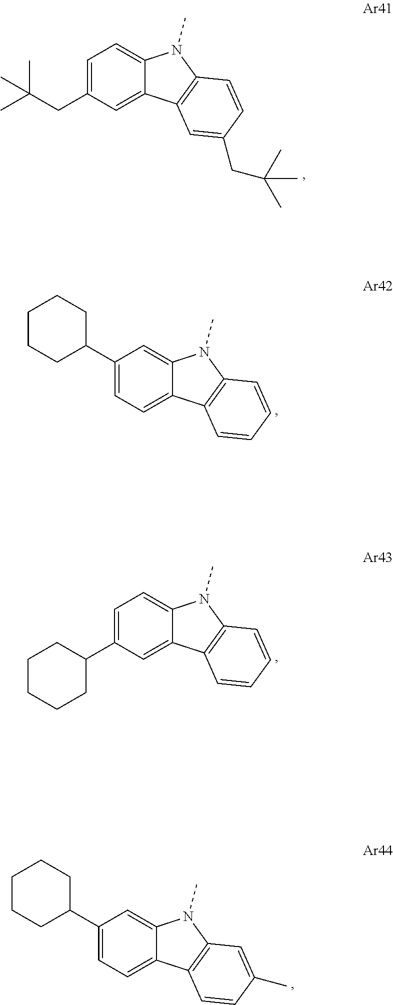 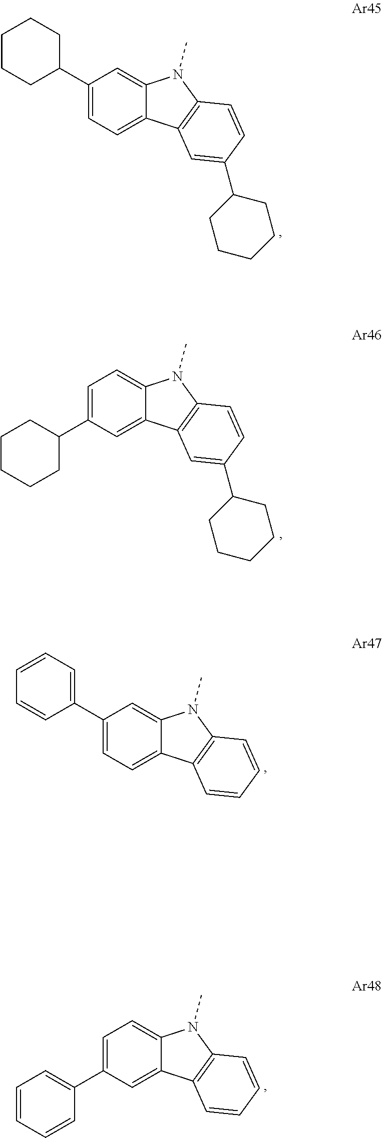 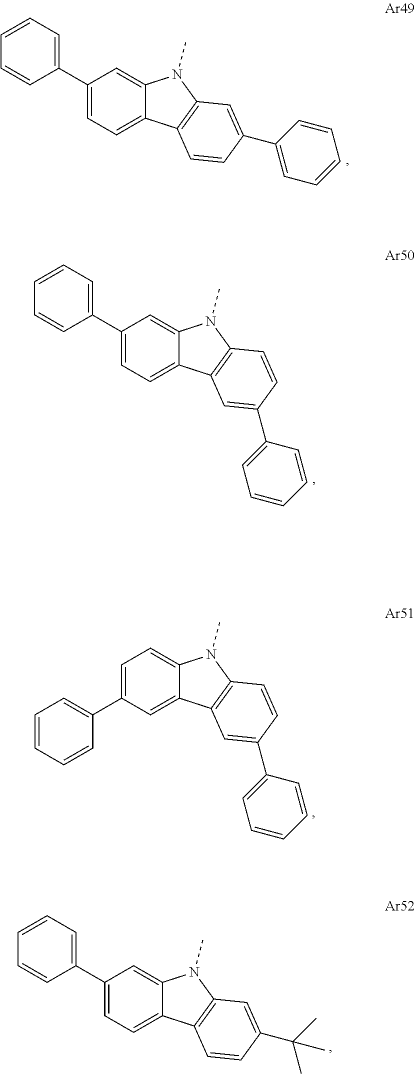 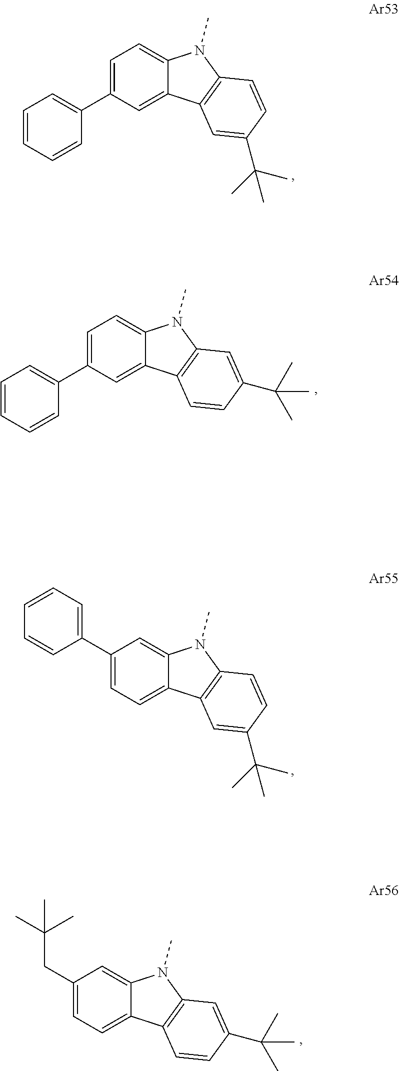 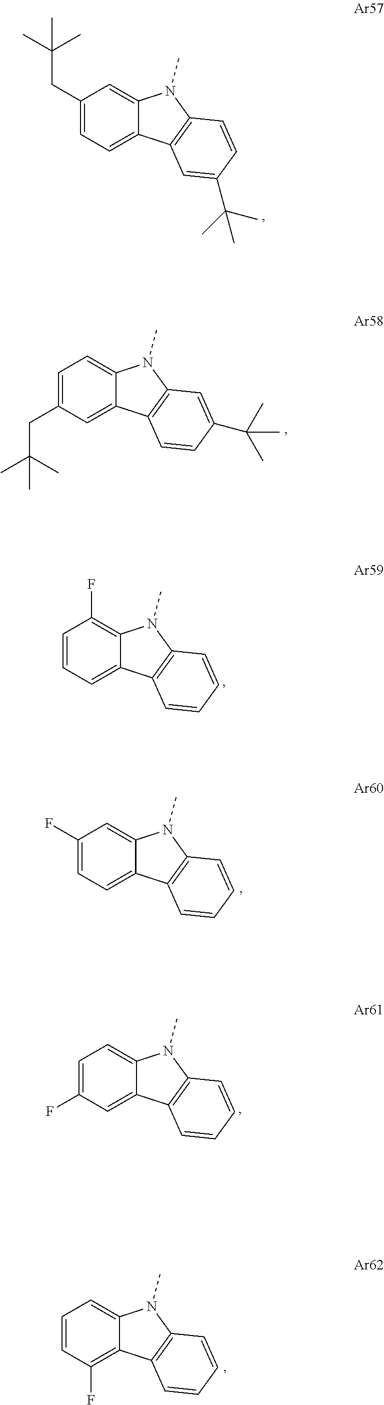 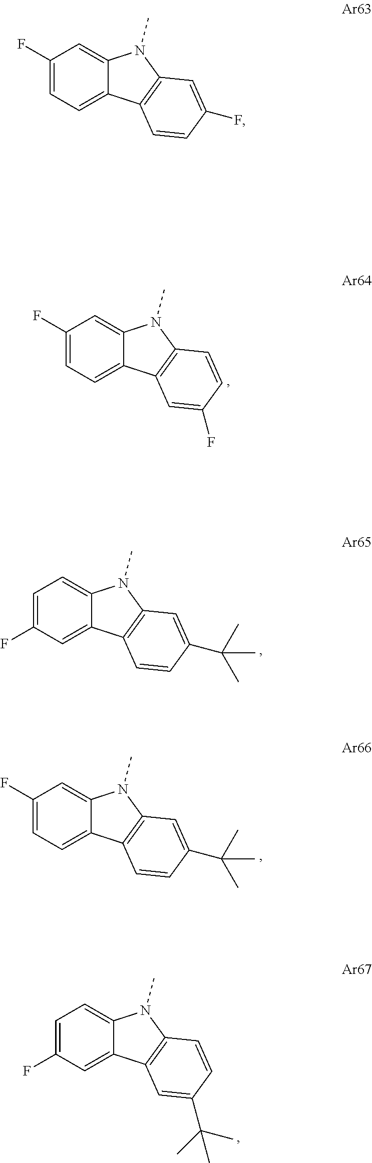 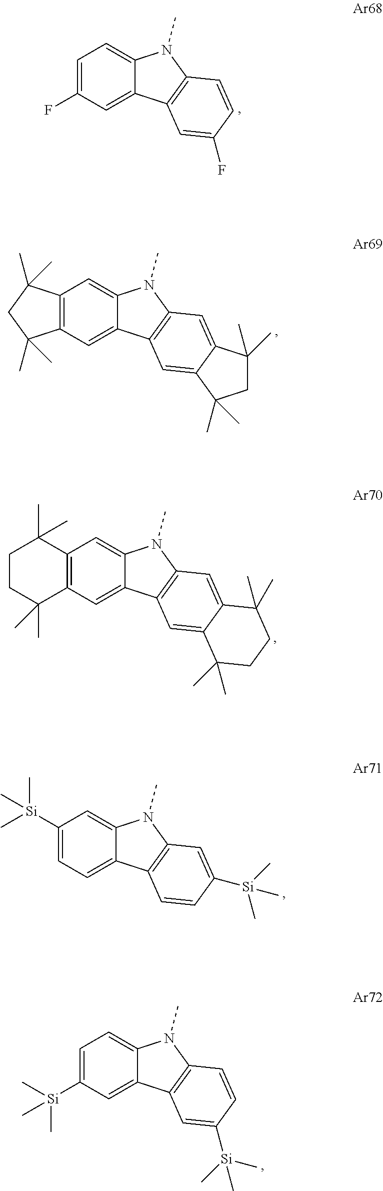 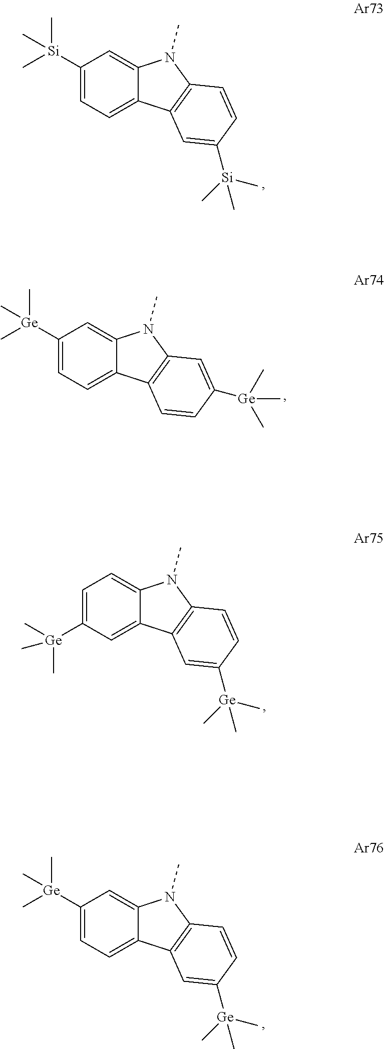 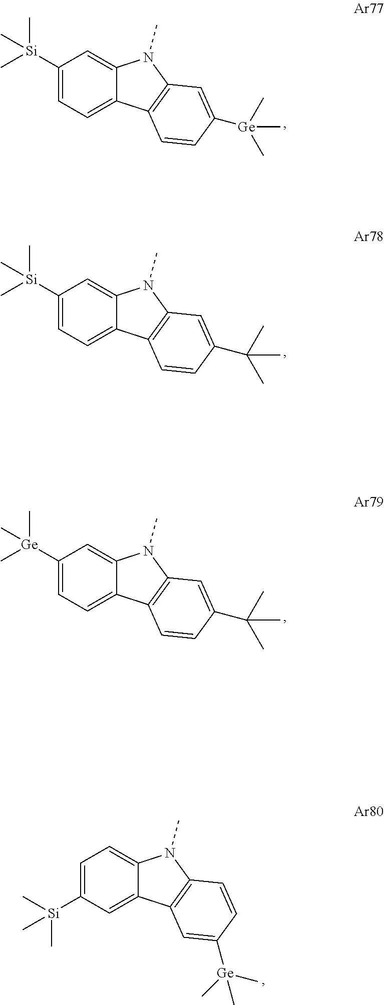 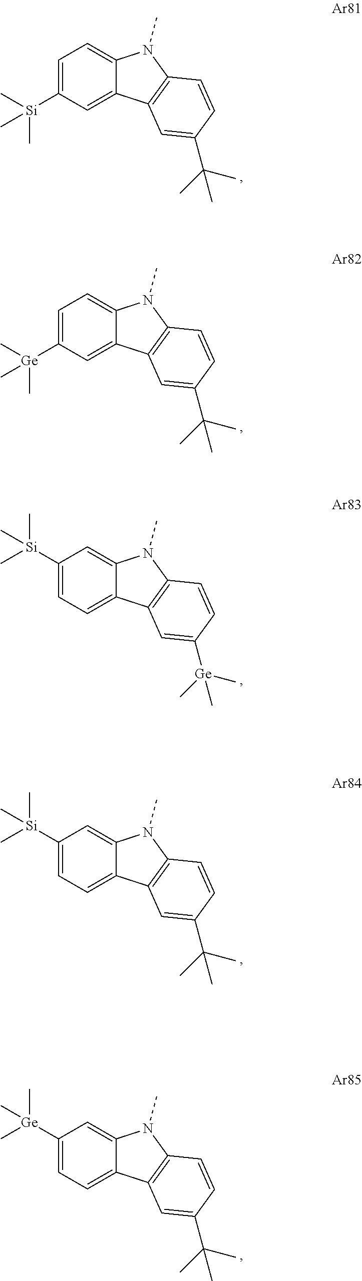 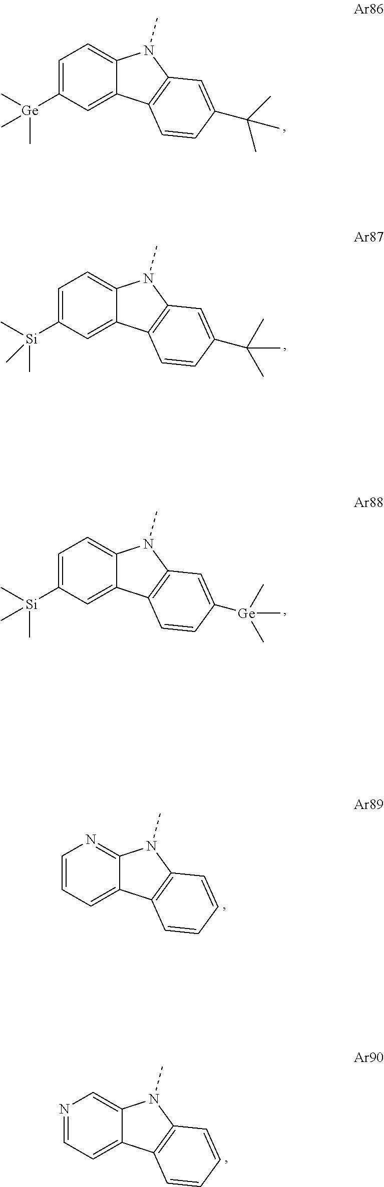 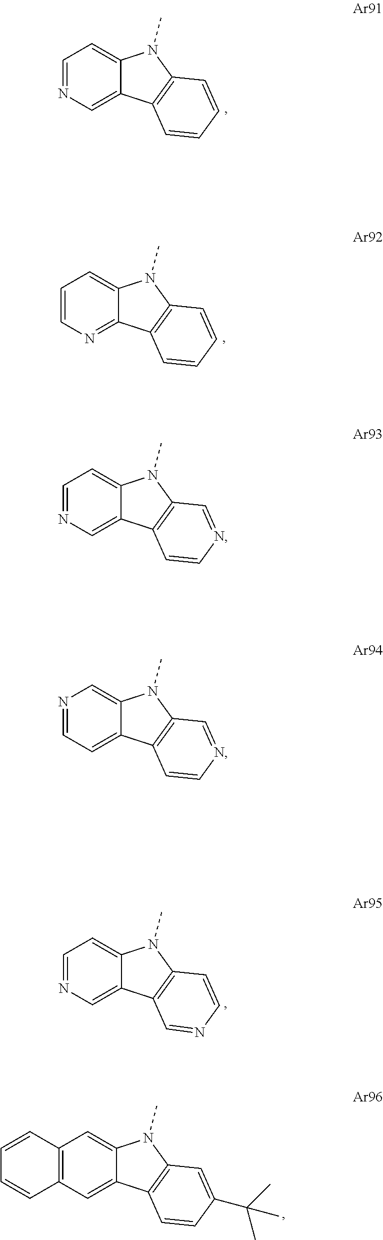 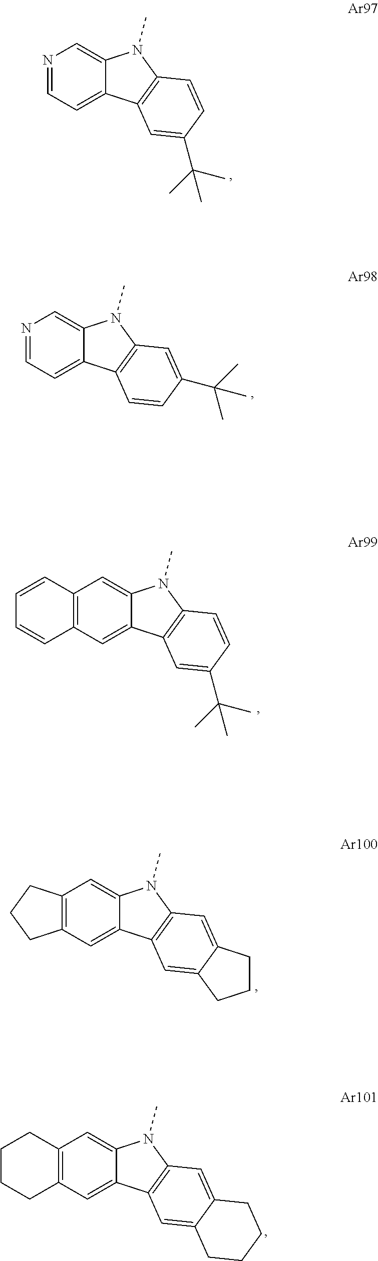 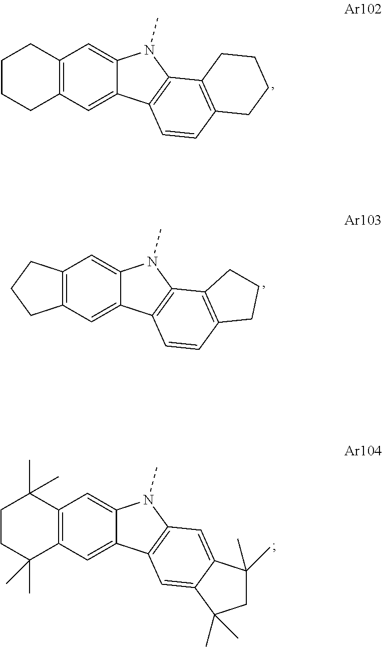
wherein optionally, hydrogen in Ar1 to Ar104 can be partially or fully substituted with deuterium.

17. The metal complex according to claim 16, wherein La is, at each occurrence identically or differently, selected from the group consisting of La-1-k and La-2-k, wherein the structures of La-1-k and La-2-k are as follows:
La-1-k has the following structure: 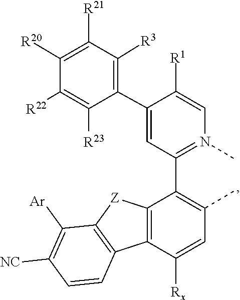
and La-2-k has the following structure: 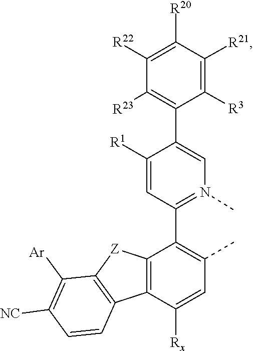
wherein k, Z, Ar, R¹, R²⁰, R³, R²¹, R²², R²³ and Rₓ are described in detail in the following table:

| k | Z | Ar | R¹ | R²⁰ | R³ | Rₓ | R²¹ | R²² | R²³ |
|---|---|---|---|---|---|---|---|---|---|
| 1 | O | Ar1 | P1 | H | H | P6 | H | H | H |
| 2 | O | Ar2 | P1 | H | H | P6 | H | H | H |
| 3 | O | Ar3 | P1 | H | H | P6 | H | H | H |
| 4 | O | Ar4 | P1 | H | H | P6 | H | H | H |
| 5 | O | Ar5 | P1 | H | H | P6 | H | H | H |
| 6 | O | Ar6 | P1 | H | H | P6 | H | H | H |
| 7 | O | Ar7 | P1 | H | H | P6 | H | H | H |
| 8 | O | Ar8 | P1 | H | H | P6 | H | H | H |
| 9 | O | Ar9 | P1 | H | H | P6 | H | H | H |
| 10 | O | Ar10 | P1 | H | H | P6 | H | H | H |
| 11 | O | Ar11 | P1 | H | H | P6 | H | H | H |
| 12 | O | Ar12 | P1 | H | H | P6 | H | H | H |
| 13 | O | Ar13 | P1 | H | H | P6 | H | H | H |
| 14 | O | Ar14 | P1 | H | H | P6 | H | H | H |
| 15 | O | Ar15 | P1 | H | H | P6 | H | H | H |
| 16 | O | Ar16 | P1 | H | H | P6 | H | H | H |
| 17 | O | Ar17 | P1 | H | H | P6 | H | H | H |
| 18 | O | Ar18 | P1 | H | H | P6 | H | H | H |
| 19 | O | Ar19 | P1 | H | H | P6 | H | H | H |
| 20 | O | Ar20 | P1 | H | H | P6 | H | H | H |
| 21 | O | Ar21 | P1 | H | H | P6 | H | H | H |
| 22 | O | Ar22 | P1 | H | H | P6 | H | H | H |
| 23 | O | Ar23 | P1 | H | H | P6 | H | H | H |
| 24 | O | Ar24 | P1 | H | H | P6 | H | H | H |
| 25 | O | Ar25 | P1 | H | H | P6 | H | H | H |
| 26 | O | Ar26 | P1 | H | H | P6 | H | H | H |
| 27 | O | Ar27 | P1 | H | H | P6 | H | H | H |
| 28 | O | Ar28 | P1 | H | H | P6 | H | H | H |
| 29 | O | Ar29 | P1 | H | H | P6 | H | H | H |
| 30 | O | Ar30 | P1 | H | H | P6 | H | H | H |
| 31 | O | Ar31 | P1 | H | H | P6 | H | H | H |
| 32 | O | Ar32 | P1 | H | H | P6 | H | H | H |
| 33 | O | Ar33 | P1 | H | H | P6 | H | H | H |
| 34 | O | Ar34 | P1 | H | H | P6 | H | H | H |
| 35 | O | Ar35 | P1 | H | H | P6 | H | H | H |
| 36 | O | Ar36 | P1 | H | H | P6 | H | H | H |
| 37 | O | Ar37 | P1 | H | H | P6 | H | H | H |
| 38 | O | Ar38 | P1 | H | H | P6 | H | H | H |
| 39 | O | Ar39 | P1 | H | H | P6 | H | H | H |
| 40 | O | Ar40 | P1 | H | H | P6 | H | H | H |
| 41 | O | Ar41 | P1 | H | H | P6 | H | H | H |
| 42 | O | Ar42 | P1 | H | H | P6 | H | H | H |
| 43 | O | Ar43 | P1 | H | H | P6 | H | H | H |
| 44 | O | Ar44 | P1 | H | H | P6 | H | H | H |
| 45 | O | Ar45 | P1 | H | H | P6 | H | H | H |
| 46 | O | Ar46 | P1 | H | H | P6 | H | H | H |
| 47 | O | Ar47 | P1 | H | H | P6 | H | H | H |
| 48 | O | Ar48 | P1 | H | H | P6 | H | H | H |
| 49 | O | Ar49 | P1 | H | H | P6 | H | H | H |
| 50 | O | Ar50 | P1 | H | H | P6 | H | H | H |
| 51 | O | Ar51 | P1 | H | H | P6 | H | H | H |
| 52 | O | Ar52 | P1 | H | H | P6 | H | H | H |
| 53 | O | Ar53 | P1 | H | H | P6 | H | H | H |
| 54 | O | Ar54 | P1 | H | H | P6 | H | H | H |
| 55 | O | Ar55 | P1 | H | H | P6 | H | H | H |
| 56 | O | Ar56 | P1 | H | H | P6 | H | H | H |
| 57 | O | Ar57 | P1 | H | H | P6 | H | H | H |
| 58 | O | Ar58 | P1 | H | H | P6 | H | H | H |
| 59 | O | Ar59 | P1 | H | H | P6 | H | H | H |
| 60 | O | Ar60 | P1 | H | H | P6 | H | H | H |
| 61 | O | Ar61 | P1 | H | H | P6 | H | H | H |
| 62 | O | Ar62 | P1 | H | H | P6 | H | H | H |
| 63 | O | Ar63 | P1 | H | H | P6 | H | H | H |
| 64 | O | Ar64 | P1 | H | H | P6 | H | H | H |
| 65 | O | Ar65 | P1 | H | H | P6 | H | H | H |
| 66 | O | Ar66 | P1 | H | H | P6 | H | H | H |
| 67 | O | Ar67 | P1 | H | H | P6 | H | H | H |
| 68 | O | Ar68 | P1 | H | H | P6 | H | H | H |
| 69 | O | Ar69 | P1 | H | H | P6 | H | H | H |
| 70 | O | Ar70 | P1 | H | H | P6 | H | H | H |
| 71 | O | Ar71 | P1 | H | H | P6 | H | H | H |
| 72 | O | Ar72 | P1 | H | H | P6 | H | H | H |
| 73 | O | Ar73 | P1 | H | H | P6 | H | H | H |
| 74 | O | Ar74 | P1 | H | H | P6 | H | H | H |
| 75 | O | Ar75 | P1 | H | H | P6 | H | H | H |
| 76 | O | Ar76 | P1 | H | H | P6 | H | H | H |
| 77 | O | Ar77 | P1 | H | H | P6 | H | H | H |
| 78 | O | Ar78 | P1 | H | H | P6 | H | H | H |
| 79 | O | Ar79 | P1 | H | H | P6 | H | H | H |
| 80 | O | Ar80 | P1 | H | H | P6 | H | H | H |
| 81 | O | Ar81 | P1 | H | H | P6 | H | H | H |
| 82 | O | Ar82 | P1 | H | H | P6 | H | H | H |
| 83 | O | Ar83 | P1 | H | H | P6 | H | H | H |
| 84 | O | Ar84 | P1 | H | H | P6 | H | H | H |
| 85 | O | Ar85 | P1 | H | H | P6 | H | H | H |
| 86 | O | Ar86 | P1 | H | H | P6 | H | H | H |
| 87 | O | Ar87 | P1 | H | H | P6 | H | H | H |
| 88 | O | Ar88 | P1 | H | H | P6 | H | H | H |
| 89 | O | Ar89 | P1 | H | H | P6 | H | H | H |
| 90 | O | Ar90 | P1 | H | H | P6 | H | H | H |
| 91 | O | Ar91 | P1 | H | H | P6 | H | H | H |
| 92 | O | Ar92 | P1 | H | H | P6 | H | H | H |
| 93 | O | Ar93 | P1 | H | H | P6 | H | H | H |
| 94 | O | Ar94 | P1 | H | H | P6 | H | H | H |
| 95 | O | Ar95 | P1 | H | H | P6 | H | H | H |
| 96 | O | Ar96 | P1 | H | H | P6 | H | H | H |
| 97 | O | Ar97 | P1 | H | H | P6 | H | H | H |
| 98 | O | Ar98 | P1 | H | H | P6 | H | H | H |
| 99 | O | Ar99 | P1 | H | H | P6 | H | H | H |
| 100 | O | Ar100 | P1 | H | H | P6 | H | H | H |
| 101 | O | Ar101 | P1 | H | H | P6 | H | H | H |
| 102 | O | Ar102 | P1 | H | H | P6 | H | H | H |
| 103 | O | Ar103 | P1 | H | H | P6 | H | H | H |
| 104 | O | Ar104 | P1 | H | H | P6 | H | H | H |
| 105 | O | Ar1 | P2 | H | H | P6 | H | H | H |
| 106 | O | Ar2 | P2 | H | H | P6 | H | H | H |
| 107 | O | Ar3 | P2 | H | H | P6 | H | H | H |
| 108 | O | Ar4 | P2 | H | H | P6 | H | H | H |
| 109 | O | Ar5 | P2 | H | H | P6 | H | H | H |
| 110 | O | Ar6 | P2 | H | H | P6 | H | H | H |
| 111 | O | Ar7 | P2 | H | H | P6 | H | H | H |
| 112 | O | Ar8 | P2 | H | H | P6 | H | H | H |
| 113 | O | Ar9 | P2 | H | H | P6 | H | H | H |
| 114 | O | Ar10 | P2 | H | H | P6 | H | H | H |
| 115 | O | Ar11 | P2 | H | H | P6 | H | H | H |
| 116 | O | Ar12 | P2 | H | H | P6 | H | H | H |
| 117 | O | Ar13 | P2 | H | H | P6 | H | H | H |
| 118 | O | Ar14 | P2 | H | H | P6 | H | H | H |
| 119 | O | Ar15 | P2 | H | H | P6 | H | H | H |
| 120 | O | Ar16 | P2 | H | H | P6 | H | H | H |
| 121 | O | Ar17 | P2 | H | H | P6 | H | H | H |
| 122 | O | Ar18 | P2 | H | H | P6 | H | H | H |
| 123 | O | Ar19 | P2 | H | H | P6 | H | H | H |
| 124 | O | Ar20 | P2 | H | H | P6 | H | H | H |
| 125 | O | Ar21 | P2 | H | H | P6 | H | H | H |
| 126 | O | Ar22 | P2 | H | H | P6 | H | H | H |
| 127 | O | Ar23 | P2 | H | H | P6 | H | H | H |
| 128 | O | Ar24 | P2 | H | H | P6 | H | H | H |
| 129 | O | Ar25 | P2 | H | H | P6 | H | H | H |
| 130 | O | Ar26 | P2 | H | H | P6 | H | H | H |
| 131 | O | Ar27 | P2 | H | H | P6 | H | H | H |
| 132 | O | Ar28 | P2 | H | H | P6 | H | H | H |
| 133 | O | Ar29 | P2 | H | H | P6 | H | H | H |
| 134 | O | Ar30 | P2 | H | H | P6 | H | H | H |
| 135 | O | Ar31 | P2 | H | H | P6 | H | H | H |
| 136 | O | Ar32 | P2 | H | H | P6 | H | H | H |
| 137 | O | Ar33 | P2 | H | H | P6 | H | H | H |
| 138 | O | Ar34 | P2 | H | H | P6 | H | H | H |
| 139 | O | Ar35 | P2 | H | H | P6 | H | H | H |
| 140 | O | Ar36 | P2 | H | H | P6 | H | H | H |
| 141 | O | Ar37 | P2 | H | H | P6 | H | H | H |
| 142 | O | Ar38 | P2 | H | H | P6 | H | H | H |
| 143 | O | Ar39 | P2 | H | H | P6 | H | H | H |
| 144 | O | Ar40 | P2 | H | H | P6 | H | H | H |
| 145 | O | Ar41 | P2 | H | H | P6 | H | H | H |
| 146 | O | Ar42 | P2 | H | H | P6 | H | H | H |
| 147 | O | Ar43 | P2 | H | H | P6 | H | H | H |
| 148 | O | Ar44 | P2 | H | H | P6 | H | H | H |
| 149 | O | Ar45 | P2 | H | H | P6 | H | H | H |
| 150 | O | Ar46 | P2 | H | H | P6 | H | H | H |
| 151 | O | Ar47 | P2 | H | H | P6 | H | H | H |
| 152 | O | Ar48 | P2 | H | H | P6 | H | H | H |
| 153 | O | Ar49 | P2 | H | H | P6 | H | H | H |
| 154 | O | Ar50 | P2 | H | H | P6 | H | H | H |
| 155 | O | Ar51 | P2 | H | H | P6 | H | H | H |
| 156 | O | Ar52 | P2 | H | H | P6 | H | H | H |
| 157 | O | Ar53 | P2 | H | H | P6 | H | H | H |
| 158 | O | Ar54 | P2 | H | H | P6 | H | H | H |
| 159 | O | Ar55 | P2 | H | H | P6 | H | H | H |
| 160 | O | Ar56 | P2 | H | H | P6 | H | H | H |
| 161 | O | Ar57 | P2 | H | H | P6 | H | H | H |
| 162 | O | Ar58 | P2 | H | H | P6 | H | H | H |
| 163 | O | Ar59 | P2 | H | H | P6 | H | H | H |
| 164 | O | Ar60 | P2 | H | H | P6 | H | H | H |
| 165 | O | Ar61 | P2 | H | H | P6 | H | H | H |
| 166 | O | Ar62 | P2 | H | H | P6 | H | H | H |
| 167 | O | Ar63 | P2 | H | H | P6 | H | H | H |
| 168 | O | Ar64 | P2 | H | H | P6 | H | H | H |
| 169 | O | Ar65 | P2 | H | H | P6 | H | H | H |
| 170 | O | Ar66 | P2 | H | H | P6 | H | H | H |
| 171 | O | Ar67 | P2 | H | H | P6 | H | H | H |
| 172 | O | Ar68 | P2 | H | H | P6 | H | H | H |
| 173 | O | Ar69 | P2 | H | H | P6 | H | H | H |
| 174 | O | Ar70 | P2 | H | H | P6 | H | H | H |
| 175 | O | Ar71 | P2 | H | H | P6 | H | H | H |
| 176 | O | Ar72 | P2 | H | H | P6 | H | H | H |
| 177 | O | Ar73 | P2 | H | H | P6 | H | H | H |
| 178 | O | Ar74 | P2 | H | H | P6 | H | H | H |
| 179 | O | Ar75 | P2 | H | H | P6 | H | H | H |
| 180 | O | Ar76 | P2 | H | H | P6 | H | H | H |
| 181 | O | Ar77 | P2 | H | H | P6 | H | H | H |
| 182 | O | Ar78 | P2 | H | H | P6 | H | H | H |
| 183 | O | Ar79 | P2 | H | H | P6 | H | H | H |
| 184 | O | Ar80 | P2 | H | H | P6 | H | H | H |
| 185 | O | Ar81 | P2 | H | H | P6 | H | H | H |
| 186 | O | Ar82 | P2 | H | H | P6 | H | H | H |
| 187 | O | Ar83 | P2 | H | H | P6 | H | H | H |
| 188 | O | Ar84 | P2 | H | H | P6 | H | H | H |
| 189 | O | Ar85 | P2 | H | H | P6 | H | H | H |
| 190 | O | Ar86 | P2 | H | H | P6 | H | H | H |
| 191 | O | Ar87 | P2 | H | H | P6 | H | H | H |
| 192 | O | Ar88 | P2 | H | H | P6 | H | H | H |
| 193 | O | Ar89 | P2 | H | H | P6 | H | H | H |
| 194 | O | Ar90 | P2 | H | H | P6 | H | H | H |
| 195 | O | Ar91 | P2 | H | H | P6 | H | H | H |
| 196 | O | Ar92 | P2 | H | H | P6 | H | H | H |
| 197 | O | Ar93 | P2 | H | H | P6 | H | H | H |
| 198 | O | Ar94 | P2 | H | H | P6 | H | H | H |
| 199 | O | Ar95 | P2 | H | H | P6 | H | H | H |
| 200 | O | Ar96 | P2 | H | H | P6 | H | H | H |
| 201 | O | Ar97 | P2 | H | H | P6 | H | H | H |
| 202 | O | Ar98 | P2 | H | H | P6 | H | H | H |
| 203 | O | Ar99 | P2 | H | H | P6 | H | H | H |
| 204 | O | Ar100 | P2 | H | H | P6 | H | H | H |
| 205 | O | Ar101 | P2 | H | H | P6 | H | H | H |
| 206 | O | Ar102 | P2 | H | H | P6 | H | H | H |
| 207 | O | Ar103 | P2 | H | H | P6 | H | H | H |
| 208 | O | Ar104 | P2 | H | H | P6 | H | H | H |
| 209 | O | Ar1 | P11 | H | H | P6 | H | H | H |
| 210 | O | Ar2 | P11 | H | H | P6 | H | H | H |
| 211 | O | Ar3 | P11 | H | H | P6 | H | H | H |
| 212 | O | Ar4 | P11 | H | H | P6 | H | H | H |
| 213 | O | Ar5 | P11 | H | H | P6 | H | H | H |
| 214 | O | Ar6 | P11 | H | H | P6 | H | H | H |
| 215 | O | Ar7 | P11 | H | H | P6 | H | H | H |
| 216 | O | Ar8 | P11 | H | H | P6 | H | H | H |
| 217 | O | Ar9 | P11 | H | H | P6 | H | H | H |
| 218 | O | Ar10 | P11 | H | H | P6 | H | H | H |
| 219 | O | Ar11 | P11 | H | H | P6 | H | H | H |
| 220 | O | Ar12 | P11 | H | H | P6 | H | H | H |
| 221 | O | Ar13 | P11 | H | H | P6 | H | H | H |
| 222 | O | Ar14 | P11 | H | H | P6 | H | H | H |
| 223 | O | Ar15 | P11 | H | H | P6 | H | H | H |
| 224 | O | Ar16 | P11 | H | H | P6 | H | H | H |
| 225 | O | Ar17 | P11 | H | H | P6 | H | H | H |
| 226 | O | Ar18 | P11 | H | H | P6 | H | H | H |
| 227 | O | Ar19 | P11 | H | H | P6 | H | H | H |
| 228 | O | Ar20 | P11 | H | H | P6 | H | H | H |
| 229 | O | Ar21 | P11 | H | H | P6 | H | H | H |
| 230 | O | Ar22 | P11 | H | H | P6 | H | H | H |
| 231 | O | Ar23 | P11 | H | H | P6 | H | H | H |
| 232 | O | Ar24 | P11 | H | H | P6 | H | H | H |
| 233 | O | Ar25 | P11 | H | H | P6 | H | H | H |
| 234 | O | Ar26 | P11 | H | H | P6 | H | H | H |
| 235 | O | Ar27 | P11 | H | H | P6 | H | H | H |
| 236 | O | Ar28 | P11 | H | H | P6 | H | H | H |
| 237 | O | Ar29 | P11 | H | H | P6 | H | H | H |
| 238 | O | Ar30 | P11 | H | H | P6 | H | H | H |
| 239 | O | Ar31 | P11 | H | H | P6 | H | H | H |
| 240 | O | Ar32 | P11 | H | H | P6 | H | H | H |
| 241 | O | Ar33 | P11 | H | H | P6 | H | H | H |
| 242 | O | Ar34 | P11 | H | H | P6 | H | H | H |
| 243 | O | Ar35 | P11 | H | H | P6 | H | H | H |
| 244 | O | Ar36 | P11 | H | H | P6 | H | H | H |
| 245 | O | Ar37 | P11 | H | H | P6 | H | H | H |
| 246 | O | Ar38 | P11 | H | H | P6 | H | H | H |
| 247 | O | Ar39 | P11 | H | H | P6 | H | H | H |
| 248 | O | Ar40 | P11 | H | H | P6 | H | H | H |
| 249 | O | Ar41 | P11 | H | H | P6 | H | H | H |
| 250 | O | Ar42 | P11 | H | H | P6 | H | H | H |
| 251 | O | Ar43 | P11 | H | H | P6 | H | H | H |
| 252 | O | Ar44 | P11 | H | H | P6 | H | H | H |
| 253 | O | Ar45 | P11 | H | H | P6 | H | H | H |
| 254 | O | Ar46 | P11 | H | H | P6 | H | H | H |
| 255 | O | Ar47 | P11 | H | H | P6 | H | H | H |
| 256 | O | Ar48 | P11 | H | H | P6 | H | H | H |
| 257 | O | Ar49 | P11 | H | H | P6 | H | H | H |
| 258 | O | Ar50 | P11 | H | H | P6 | H | H | H |
| 259 | O | Ar51 | P11 | H | H | P6 | H | H | H |
| 260 | O | Ar52 | P11 | H | H | P6 | H | H | H |
| 261 | O | Ar53 | P11 | H | H | P6 | H | H | H |
| 262 | O | Ar54 | P11 | H | H | P6 | H | H | H |
| 263 | O | Ar55 | P11 | H | H | P6 | H | H | H |
| 264 | O | Ar56 | P11 | H | H | P6 | H | H | H |
| 265 | O | Ar57 | P11 | H | H | P6 | H | H | H |
| 266 | O | Ar58 | P11 | H | H | P6 | H | H | H |
| 267 | O | Ar59 | P11 | H | H | P6 | H | H | H |
| 268 | O | Ar60 | P11 | H | H | P6 | H | H | H |
| 269 | O | Ar61 | P11 | H | H | P6 | H | H | H |
| 270 | O | Ar62 | P11 | H | H | P6 | H | H | H |
| 271 | O | Ar63 | P11 | H | H | P6 | H | H | H |
| 272 | O | Ar64 | P11 | H | H | P6 | H | H | H |
| 273 | O | Ar65 | P11 | H | H | P6 | H | H | H |
| 274 | O | Ar66 | P11 | H | H | P6 | H | H | H |
| 275 | O | Ar67 | P11 | H | H | P6 | H | H | H |
| 276 | O | Ar68 | P11 | H | H | P6 | H | H | H |
| 277 | O | Ar69 | P11 | H | H | P6 | H | H | H |
| 278 | O | Ar70 | P11 | H | H | P6 | H | H | H |
| 279 | O | Ar71 | P11 | H | H | P6 | H | H | H |
| 280 | O | Ar72 | P11 | H | H | P6 | H | H | H |
| 281 | O | Ar73 | P11 | H | H | P6 | H | H | H |
| 282 | O | Ar74 | P11 | H | H | P6 | H | H | H |
| 283 | O | Ar75 | P11 | H | H | P6 | H | H | H |
| 284 | O | Ar76 | P11 | H | H | P6 | H | H | H |
| 285 | O | Ar77 | P11 | H | H | P6 | H | H | H |
| 286 | O | Ar78 | P11 | H | H | P6 | H | H | H |
| 287 | O | Ar79 | P11 | H | H | P6 | H | H | H |
| 288 | O | Ar80 | P11 | H | H | P6 | H | H | H |
| 289 | O | Ar81 | P11 | H | H | P6 | H | H | H |
| 290 | O | Ar82 | P11 | H | H | P6 | H | H | H |
| 291 | O | Ar83 | P11 | H | H | P6 | H | H | H |
| 292 | O | Ar84 | P11 | H | H | P6 | H | H | H |
| 293 | O | Ar85 | P11 | H | H | P6 | H | H | H |
| 294 | O | Ar86 | P11 | H | H | P6 | H | H | H |
| 295 | O | Ar87 | P11 | H | H | P6 | H | H | H |
| 296 | O | Ar88 | P11 | H | H | P6 | H | H | H |
| 297 | O | Ar89 | P11 | H | H | P6 | H | H | H |
| 298 | O | Ar90 | P11 | H | H | P6 | H | H | H |
| 299 | O | Ar91 | P11 | H | H | P6 | H | H | H |
| 300 | O | Ar92 | P11 | H | H | P6 | H | H | H |
| 301 | O | Ar93 | P11 | H | H | P6 | H | H | H |
| 302 | O | Ar94 | P11 | H | H | P6 | H | H | H |
| 303 | O | Ar95 | P11 | H | H | P6 | H | H | H |
| 304 | O | Ar96 | P11 | H | H | P6 | H | H | H |
| 305 | O | Ar97 | P11 | H | H | P6 | H | H | H |
| 306 | O | Ar98 | P11 | H | H | P6 | H | H | H |
| 307 | O | Ar99 | P11 | H | H | P6 | H | H | H |
| 308 | O | Ar100 | P11 | H | H | P6 | H | H | H |
| 309 | O | Ar101 | P11 | H | H | P6 | H | H | H |
| 310 | O | Ar102 | P11 | H | H | P6 | H | H | H |
| 311 | O | Ar103 | P11 | H | H | P6 | H | H | H |
| 312 | O | Ar104 | P11 | H | H | P6 | H | H | H |
| 313 | O | Ar1 | P12 | H | H | P6 | H | H | H |
| 314 | O | Ar2 | P12 | H | H | P6 | H | H | H |
| 315 | O | Ar3 | P12 | H | H | P6 | H | H | H |
| 316 | O | Ar4 | P12 | H | H | P6 | H | H | H |
| 317 | O | Ar5 | P12 | H | H | P6 | H | H | H |
| 318 | O | Ar6 | P12 | H | H | P6 | H | H | H |
| 319 | O | Ar7 | P12 | H | H | P6 | H | H | H |
| 320 | O | Ar8 | P12 | H | H | P6 | H | H | H |
| 321 | O | Ar9 | P12 | H | H | P6 | H | H | H |
| 322 | O | Ar10 | P12 | H | H | P6 | H | H | H |
| 323 | O | Ar11 | P12 | H | H | P6 | H | H | H |
| 324 | O | Ar12 | P12 | H | H | P6 | H | H | H |
| 325 | O | Ar13 | P12 | H | H | P6 | H | H | H |
| 326 | O | Ar14 | P12 | H | H | P6 | H | H | H |
| 327 | O | Ar15 | P12 | H | H | P6 | H | H | H |
| 328 | O | Ar16 | P12 | H | H | P6 | H | H | H |
| 329 | O | Ar17 | P12 | H | H | P6 | H | H | H |
| 330 | O | Ar18 | P12 | H | H | P6 | H | H | H |
| 331 | O | Ar19 | P12 | H | H | P6 | H | H | H |
| 332 | O | Ar20 | P12 | H | H | P6 | H | H | H |
| 333 | O | Ar21 | P12 | H | H | P6 | H | H | H |
| 334 | O | Ar22 | P12 | H | H | P6 | H | H | H |
| 335 | O | Ar23 | P12 | H | H | P6 | H | H | H |
| 336 | O | Ar24 | P12 | H | H | P6 | H | H | H |
| 337 | O | Ar25 | P12 | H | H | P6 | H | H | H |
| 338 | O | Ar26 | P12 | H | H | P6 | H | H | H |
| 339 | O | Ar27 | P12 | H | H | P6 | H | H | H |
| 340 | O | Ar28 | P12 | H | H | P6 | H | H | H |
| 341 | O | Ar29 | P12 | H | H | P6 | H | H | H |
| 342 | O | Ar30 | P12 | H | H | P6 | H | H | H |
| 343 | O | Ar31 | P12 | H | H | P6 | H | H | H |
| 344 | O | Ar32 | P12 | H | H | P6 | H | H | H |
| 345 | O | Ar33 | P12 | H | H | P6 | H | H | H |
| 346 | O | Ar34 | P12 | H | H | P6 | H | H | H |
| 347 | O | Ar35 | P12 | H | H | P6 | H | H | H |
| 348 | O | Ar36 | P12 | H | H | P6 | H | H | H |
| 349 | O | Ar37 | P12 | H | H | P6 | H | H | H |
| 350 | O | Ar38 | P12 | H | H | P6 | H | H | H |
| 351 | O | Ar39 | P12 | H | H | P6 | H | H | H |
| 352 | O | Ar40 | P12 | H | H | P6 | H | H | H |
| 353 | O | Ar41 | P12 | H | H | P6 | H | H | H |
| 354 | O | Ar42 | P12 | H | H | P6 | H | H | H |
| 355 | O | Ar43 | P12 | H | H | P6 | H | H | H |
| 356 | O | Ar44 | P12 | H | H | P6 | H | H | H |
| 357 | O | Ar45 | P12 | H | H | P6 | H | H | H |
| 358 | O | Ar46 | P12 | H | H | P6 | H | H | H |
| 359 | O | Ar47 | P12 | H | H | P6 | H | H | H |
| 360 | O | Ar48 | P12 | H | H | P6 | H | H | H |
| 361 | O | Ar49 | P12 | H | H | P6 | H | H | H |
| 362 | O | Ar50 | P12 | H | H | P6 | H | H | H |
| 363 | O | Ar51 | P12 | H | H | P6 | H | H | H |
| 364 | O | Ar52 | P12 | H | H | P6 | H | H | H |
| 365 | O | Ar53 | P12 | H | H | P6 | H | H | H |
| 366 | O | Ar54 | P12 | H | H | P6 | H | H | H |
| 367 | O | Ar55 | P12 | H | H | P6 | H | H | H |
| 368 | O | Ar56 | P12 | H | H | P6 | H | H | H |
| 369 | O | Ar57 | P12 | H | H | P6 | H | H | H |
| 370 | O | Ar58 | P12 | H | H | P6 | H | H | H |
| 371 | O | Ar59 | P12 | H | H | P6 | H | H | H |
| 372 | O | Ar60 | P12 | H | H | P6 | H | H | H |
| 373 | O | Ar61 | P12 | H | H | P6 | H | H | H |
| 374 | O | Ar62 | P12 | H | H | P6 | H | H | H |
| 375 | O | Ar63 | P12 | H | H | P6 | H | H | H |
| 376 | O | Ar64 | P12 | H | H | P6 | H | H | H |
| 377 | O | Ar65 | P12 | H | H | P6 | H | H | H |
| 378 | O | Ar66 | P12 | H | H | P6 | H | H | H |
| 379 | O | Ar67 | P12 | H | H | P6 | H | H | H |
| 380 | O | Ar68 | P12 | H | H | P6 | H | H | H |
| 381 | O | Ar69 | P12 | H | H | P6 | H | H | H |
| 382 | O | Ar70 | P12 | H | H | P6 | H | H | H |
| 383 | O | Ar71 | P12 | H | H | P6 | H | H | H |
| 384 | O | Ar72 | P12 | H | H | P6 | H | H | H |
| 385 | O | Ar73 | P12 | H | H | P6 | H | H | H |
| 386 | O | Ar74 | P12 | H | H | P6 | H | H | H |
| 387 | O | Ar75 | P12 | H | H | P6 | H | H | H |
| 388 | O | Ar76 | P12 | H | H | P6 | H | H | H |
| 389 | O | Ar77 | P12 | H | H | P6 | H | H | H |
| 390 | O | Ar78 | P12 | H | H | P6 | H | H | H |
| 391 | O | Ar79 | P12 | H | H | P6 | H | H | H |
| 392 | O | Ar80 | P12 | H | H | P6 | H | H | H |
| 393 | O | Ar81 | P12 | H | H | P6 | H | H | H |
| 394 | O | Ar82 | P12 | H | H | P6 | H | H | H |
| 395 | O | Ar83 | P12 | H | H | P6 | H | H | H |
| 396 | O | Ar84 | P12 | H | H | P6 | H | H | H |
| 397 | O | Ar85 | P12 | H | H | P6 | H | H | H |
| 398 | O | Ar86 | P12 | H | H | P6 | H | H | H |
| 399 | O | Ar87 | P12 | H | H | P6 | H | H | H |
| 400 | O | Ar88 | P12 | H | H | P6 | H | H | H |
| 401 | O | Ar89 | P12 | H | H | P6 | H | H | H |
| 402 | O | Ar90 | P12 | H | H | P6 | H | H | H |
| 403 | O | Ar91 | P12 | H | H | P6 | H | H | H |
| 404 | O | Ar92 | P12 | H | H | P6 | H | H | H |
| 405 | O | Ar93 | P12 | H | H | P6 | H | H | H |
| 406 | O | Ar94 | P12 | H | H | P6 | H | H | H |
| 407 | O | Ar95 | P12 | H | H | P6 | H | H | H |
| 408 | O | Ar96 | P12 | H | H | P6 | H | H | H |
| 409 | O | Ar97 | P12 | H | H | P6 | H | H | H |
| 410 | O | Ar98 | P12 | H | H | P6 | H | H | H |
| 411 | O | Ar99 | P12 | H | H | P6 | H | H | H |
| 412 | O | Ar100 | P12 | H | H | P6 | H | H | H |
| 413 | O | Ar101 | P12 | H | H | P6 | H | H | H |
| 414 | O | Ar102 | P12 | H | H | P6 | H | H | H |
| 415 | O | Ar103 | P12 | H | H | P6 | H | H | H |
| 416 | O | Ar104 | P12 | H | H | P6 | H | H | H |
| 417 | O | Ar1 | P1 | H | H | P1 | H | H | H |
| 418 | O | Ar2 | P1 | H | H | P1 | H | H | H |
| 419 | O | Ar3 | P1 | H | H | P1 | H | H | H |
| 420 | O | Ar4 | P1 | H | H | P1 | H | H | H |
| 421 | O | Ar5 | P1 | H | H | P1 | H | H | H |
| 422 | O | Ar6 | P1 | H | H | P1 | H | H | H |
| 423 | O | Ar7 | P1 | H | H | P1 | H | H | H |
| 424 | O | Ar8 | P1 | H | H | P1 | H | H | H |
| 425 | O | Ar9 | P1 | H | H | P1 | H | H | H |
| 426 | O | Ar10 | P1 | H | H | P1 | H | H | H |
| 427 | O | Ar11 | P1 | H | H | P1 | H | H | H |
| 428 | O | Ar12 | P1 | H | H | P1 | H | H | H |
| 429 | O | Ar13 | P1 | H | H | P1 | H | H | H |
| 430 | O | Ar14 | P1 | H | H | P1 | H | H | H |
| 431 | O | Ar15 | P1 | H | H | P1 | H | H | H |
| 432 | O | Ar16 | P1 | H | H | P1 | H | H | H |
| 433 | O | Ar17 | P1 | H | H | P1 | H | H | H |
| 434 | O | Ar18 | P1 | H | H | P1 | H | H | H |
| 435 | O | Ar19 | P1 | H | H | P1 | H | H | H |
| 436 | O | Ar20 | P1 | H | H | P1 | H | H | H |
| 437 | O | Ar21 | P1 | H | H | P1 | H | H | H |
| 438 | O | Ar22 | P1 | H | H | P1 | H | H | H |
| 439 | O | Ar23 | P1 | H | H | P1 | H | H | H |
| 440 | O | Ar24 | P1 | H | H | P1 | H | H | H |
| 441 | O | Ar25 | P1 | H | H | P1 | H | H | H |
| 442 | O | Ar26 | P1 | H | H | P1 | H | H | H |
| 443 | O | Ar27 | P1 | H | H | P1 | H | H | H |
| 444 | O | Ar28 | P1 | H | H | P1 | H | H | H |
| 445 | O | Ar29 | P1 | H | H | P1 | H | H | H |
| 446 | O | Ar30 | P1 | H | H | P1 | H | H | H |
| 447 | O | Ar31 | P1 | H | H | P1 | H | H | H |
| 448 | O | Ar32 | P1 | H | H | P1 | H | H | H |
| 449 | O | Ar33 | P1 | H | H | P1 | H | H | H |
| 450 | O | Ar34 | P1 | H | H | P1 | H | H | H |
| 451 | O | Ar35 | P1 | H | H | P1 | H | H | H |
| 452 | O | Ar36 | P1 | H | H | P1 | H | H | H |
| 453 | O | Ar37 | P1 | H | H | P1 | H | H | H |
| 454 | O | Ar38 | P1 | H | H | P1 | H | H | H |
| 455 | O | Ar39 | P1 | H | H | P1 | H | H | H |
| 456 | O | Ar40 | P1 | H | H | P1 | H | H | H |
| 457 | O | Ar41 | P1 | H | H | P1 | H | H | H |
| 458 | O | Ar42 | P1 | H | H | P1 | H | H | H |
| 459 | O | Ar43 | P1 | H | H | P1 | H | H | H |
| 460 | O | Ar44 | P1 | H | H | P1 | H | H | H |
| 461 | O | Ar45 | P1 | H | H | P1 | H | H | H |
| 462 | O | Ar46 | P1 | H | H | P1 | H | H | H |
| 463 | O | Ar47 | P1 | H | H | P1 | H | H | H |
| 464 | O | Ar48 | P1 | H | H | P1 | H | H | H |
| 465 | O | Ar49 | P1 | H | H | P1 | H | H | H |
| 466 | O | Ar50 | P1 | H | H | P1 | H | H | H |
| 467 | O | Ar51 | P1 | H | H | P1 | H | H | H |
| 468 | O | Ar52 | P1 | H | H | P1 | H | H | H |
| 469 | O | Ar53 | P1 | H | H | P1 | H | H | H |
| 470 | O | Ar54 | P1 | H | H | P1 | H | H | H |
| 471 | O | Ar55 | P1 | H | H | P1 | H | H | H |
| 472 | O | Ar56 | P1 | H | H | P1 | H | H | H |
| 473 | O | Ar57 | P1 | H | H | P1 | H | H | H |
| 474 | O | Ar58 | P1 | H | H | P1 | H | H | H |
| 475 | O | Ar59 | P1 | H | H | P1 | H | H | H |
| 476 | O | Ar60 | P1 | H | H | P1 | H | H | H |
| 477 | O | Ar61 | P1 | H | H | P1 | H | H | H |
| 478 | O | Ar62 | P1 | H | H | P1 | H | H | H |
| 479 | O | Ar63 | P1 | H | H | P1 | H | H | H |
| 480 | O | Ar64 | P1 | H | H | P1 | H | H | H |
| 481 | O | Ar65 | P1 | H | H | P1 | H | H | H |
| 482 | O | Ar66 | P1 | H | H | P1 | H | H | H |
| 483 | O | Ar67 | P1 | H | H | P1 | H | H | H |
| 484 | O | Ar68 | P1 | H | H | P1 | H | H | H |
| 485 | O | Ar69 | P1 | H | H | P1 | H | H | H |
| 486 | O | Ar70 | P1 | H | H | P1 | H | H | H |
| 487 | O | Ar71 | P1 | H | H | P1 | H | H | H |
| 488 | O | Ar72 | P1 | H | H | P1 | H | H | H |
| 489 | O | Ar73 | P1 | H | H | P1 | H | H | H |
| 490 | O | Ar74 | P1 | H | H | P1 | H | H | H |
| 491 | O | Ar75 | P1 | H | H | P1 | H | H | H |
| 492 | O | Ar76 | P1 | H | H | P1 | H | H | H |
| 493 | O | Ar77 | P1 | H | H | P1 | H | H | H |
| 494 | O | Ar78 | P1 | H | H | P1 | H | H | H |
| 495 | O | Ar79 | P1 | H | H | P1 | H | H | H |
| 496 | O | Ar80 | P1 | H | H | P1 | H | H | H |
| 497 | O | Ar81 | P1 | H | H | P1 | H | H | H |
| 498 | O | Ar82 | P1 | H | H | P1 | H | H | H |
| 499 | O | Ar83 | P1 | H | H | P1 | H | H | H |
| 500 | O | Ar84 | P1 | H | H | P1 | H | H | H |
| 501 | O | Ar85 | P1 | H | H | P1 | H | H | H |
| 502 | O | Ar86 | P1 | H | H | P1 | H | H | H |
| 503 | O | Ar87 | P1 | H | H | P1 | H | H | H |
| 504 | O | Ar88 | P1 | H | H | P1 | H | H | H |
| 505 | O | Ar89 | P1 | H | H | P1 | H | H | H |
| 506 | O | Ar90 | P1 | H | H | P1 | H | H | H |
| 507 | O | Ar91 | P1 | H | H | P1 | H | H | H |
| 508 | O | Ar92 | P1 | H | H | P1 | H | H | H |
| 509 | O | Ar93 | P1 | H | H | P1 | H | H | H |
| 510 | O | Ar94 | P1 | H | H | P1 | H | H | H |
| 511 | O | Ar95 | P1 | H | H | P1 | H | H | H |
| 512 | O | Ar96 | P1 | H | H | P1 | H | H | H |
| 513 | O | Ar97 | P1 | H | H | P1 | H | H | H |
| 514 | O | Ar98 | P1 | H | H | P1 | H | H | H |
| 515 | O | Ar99 | P1 | H | H | P1 | H | H | H |
| 516 | O | Ar100 | P1 | H | H | P1 | H | H | H |
| 517 | O | Ar101 | P1 | H | H | P1 | H | H | H |
| 518 | O | Ar102 | P1 | H | H | P1 | H | H | H |
| 519 | O | Ar103 | P1 | H | H | P1 | H | H | H |
| 520 | O | Ar104 | P1 | H | H | P1 | H | H | H |
| 521 | O | Ar1 | P2 | H | H | P1 | H | H | H |
| 522 | O | Ar2 | P2 | H | H | P1 | H | H | H |
| 523 | O | Ar3 | P2 | H | H | P1 | H | H | H |
| 524 | O | Ar4 | P2 | H | H | P1 | H | H | H |
| 525 | O | Ar5 | P2 | H | H | P1 | H | H | H |
| 526 | O | Ar6 | P2 | H | H | P1 | H | H | H |
| 527 | O | Ar7 | P2 | H | H | P1 | H | H | H |
| 528 | O | Ar8 | P2 | H | H | P1 | H | H | H |
| 529 | O | Ar9 | P2 | H | H | P1 | H | H | H |
| 530 | O | Ar10 | P2 | H | H | P1 | H | H | H |
| 531 | O | Ar11 | P2 | H | H | P1 | H | H | H |
| 532 | O | Ar12 | P2 | H | H | P1 | H | H | H |
| 533 | O | Ar13 | P2 | H | H | P1 | H | H | H |
| 534 | O | Ar14 | P2 | H | H | P1 | H | H | H |
| 535 | O | Ar15 | P2 | H | H | P1 | H | H | H |
| 536 | O | Ar16 | P2 | H | H | P1 | H | H | H |
| 537 | O | Ar17 | P2 | H | H | P1 | H | H | H |
| 538 | O | Ar18 | P2 | H | H | P1 | H | H | H |
| 539 | O | Ar19 | P2 | H | H | P1 | H | H | H |
| 540 | O | Ar20 | P2 | H | H | P1 | H | H | H |
| 541 | O | Ar21 | P2 | H | H | P1 | H | H | H |
| 542 | O | Ar22 | P2 | H | H | P1 | H | H | H |
| 543 | O | Ar23 | P2 | H | H | P1 | H | H | H |
| 544 | O | Ar24 | P2 | H | H | P1 | H | H | H |
| 545 | O | Ar25 | P2 | H | H | P1 | H | H | H |
| 546 | O | Ar26 | P2 | H | H | P1 | H | H | H |
| 547 | O | Ar27 | P2 | H | H | P1 | H | H | H |
| 548 | O | Ar28 | P2 | H | H | P1 | H | H | H |
| 549 | O | Ar29 | P2 | H | H | P1 | H | H | H |
| 550 | O | Ar30 | P2 | H | H | P1 | H | H | H |
| 551 | O | Ar31 | P2 | H | H | P1 | H | H | H |
| 552 | O | Ar32 | P2 | H | H | P1 | H | H | H |
| 553 | O | Ar33 | P2 | H | H | P1 | H | H | H |
| 554 | O | Ar34 | P2 | H | H | P1 | H | H | H |
| 555 | O | Ar35 | P2 | H | H | P1 | H | H | H |
| 556 | O | Ar36 | P2 | H | H | P1 | H | H | H |
| 557 | O | Ar37 | P2 | H | H | P1 | H | H | H |
| 558 | O | Ar38 | P2 | H | H | P1 | H | H | H |
| 559 | O | Ar39 | P2 | H | H | P1 | H | H | H |
| 560 | O | Ar40 | P2 | H | H | P1 | H | H | H |
| 561 | O | Ar41 | P2 | H | H | P1 | H | H | H |
| 562 | O | Ar42 | P2 | H | H | P1 | H | H | H |
| 563 | O | Ar43 | P2 | H | H | P1 | H | H | H |
| 564 | O | Ar44 | P2 | H | H | P1 | H | H | H |
| 565 | O | Ar45 | P2 | H | H | P1 | H | H | H |
| 566 | O | Ar46 | P2 | H | H | P1 | H | H | H |
| 567 | O | Ar47 | P2 | H | H | P1 | H | H | H |
| 568 | O | Ar48 | P2 | H | H | P1 | H | H | H |
| 569 | O | Ar49 | P2 | H | H | P1 | H | H | H |
| 570 | O | Ar50 | P2 | H | H | P1 | H | H | H |
| 571 | O | Ar51 | P2 | H | H | P1 | H | H | H |
| 572 | O | Ar52 | P2 | H | H | P1 | H | H | H |
| 573 | O | Ar53 | P2 | H | H | P1 | H | H | H |
| 574 | O | Ar54 | P2 | H | H | P1 | H | H | H |
| 575 | O | Ar55 | P2 | H | H | P1 | H | H | H |
| 576 | O | Ar56 | P2 | H | H | P1 | H | H | H |
| 577 | O | Ar57 | P2 | H | H | P1 | H | H | H |
| 578 | O | Ar58 | P2 | H | H | P1 | H | H | H |
| 579 | O | Ar59 | P2 | H | H | P1 | H | H | H |
| 580 | O | Ar60 | P2 | H | H | P1 | H | H | H |
| 581 | O | Ar61 | P2 | H | H | P1 | H | H | H |
| 582 | O | Ar62 | P2 | H | H | P1 | H | H | H |
| 583 | O | Ar63 | P2 | H | H | P1 | H | H | H |
| 584 | O | Ar64 | P2 | H | H | P1 | H | H | H |
| 585 | O | Ar65 | P2 | H | H | P1 | H | H | H |
| 586 | O | Ar66 | P2 | H | H | P1 | H | H | H |
| 587 | O | Ar67 | P2 | H | H | P1 | H | H | H |
| 588 | O | Ar68 | P2 | H | H | P1 | H | H | H |
| 589 | O | Ar69 | P2 | H | H | P1 | H | H | H |
| 590 | O | Ar70 | P2 | H | H | P1 | H | H | H |
| 591 | O | Ar71 | P2 | H | H | P1 | H | H | H |
| 592 | O | Ar72 | P2 | H | H | P1 | H | H | H |
| 593 | O | Ar73 | P2 | H | H | P1 | H | H | H |
| 594 | O | Ar74 | P2 | H | H | P1 | H | H | H |
| 595 | O | Ar75 | P2 | H | H | P1 | H | H | H |
| 596 | O | Ar76 | P2 | H | H | P1 | H | H | H |
| 597 | O | Ar77 | P2 | H | H | P1 | H | H | H |
| 598 | O | Ar78 | P2 | H | H | P1 | H | H | H |
| 599 | O | Ar79 | P2 | H | H | P1 | H | H | H |
| 600 | O | Ar80 | P2 | H | H | P1 | H | H | H |
| 601 | O | Ar81 | P2 | H | H | P1 | H | H | H |
| 602 | O | Ar82 | P2 | H | H | P1 | H | H | H |
| 603 | O | Ar83 | P2 | H | H | P1 | H | H | H |
| 604 | O | Ar84 | P2 | H | H | P1 | H | H | H |
| 605 | O | Ar85 | P2 | H | H | P1 | H | H | H |
| 606 | O | Ar86 | P2 | H | H | P1 | H | H | H |
| 607 | O | Ar87 | P2 | H | H | P1 | H | H | H |
| 608 | O | Ar88 | P2 | H | H | P1 | H | H | H |
| 609 | O | Ar89 | P2 | H | H | P1 | H | H | H |
| 610 | O | Ar90 | P2 | H | H | P1 | H | H | H |
| 611 | O | Ar91 | P2 | H | H | P1 | H | H | H |
| 612 | O | Ar92 | P2 | H | H | P1 | H | H | H |
| 613 | O | Ar93 | P2 | H | H | P1 | H | H | H |
| 614 | O | Ar94 | P2 | H | H | P1 | H | H | H |
| 615 | O | Ar95 | P2 | H | H | P1 | H | H | H |
| 616 | O | Ar96 | P2 | H | H | P1 | H | H | H |
| 617 | O | Ar97 | P2 | H | H | P1 | H | H | H |
| 618 | O | Ar98 | P2 | H | H | P1 | H | H | H |
| 619 | O | Ar99 | P2 | H | H | P1 | H | H | H |
| 620 | O | Ar100 | P2 | H | H | P1 | H | H | H |
| 621 | O | Ar101 | P2 | H | H | P1 | H | H | H |
| 622 | O | Ar102 | P2 | H | H | P1 | H | H | H |
| 623 | O | Ar103 | P2 | H | H | P1 | H | H | H |
| 624 | O | Ar104 | P2 | H | H | P1 | H | H | H |
| 625 | O | Ar1 | P11 | H | H | P1 | H | H | H |
| 626 | O | Ar2 | P11 | H | H | P1 | H | H | H |
| 627 | O | Ar3 | P11 | H | H | P1 | H | H | H |
| 628 | O | Ar4 | P11 | H | H | P1 | H | H | H |
| 629 | O | Ar5 | P11 | H | H | P1 | H | H | H |
| 630 | O | Ar6 | P11 | H | H | P1 | H | H | H |
| 631 | O | Ar7 | P11 | H | H | P1 | H | H | H |
| 632 | O | Ar8 | P11 | H | H | P1 | H | H | H |
| 633 | O | Ar9 | P11 | H | H | P1 | H | H | H |
| 634 | O | Ar10 | P11 | H | H | P1 | H | H | H |
| 635 | O | Ar11 | P11 | H | H | P1 | H | H | H |
| 636 | O | Ar12 | P11 | H | H | P1 | H | H | H |
| 637 | O | Ar13 | P11 | H | H | P1 | H | H | H |
| 638 | O | Ar14 | P11 | H | H | P1 | H | H | H |
| 639 | O | Ar15 | P11 | H | H | P1 | H | H | H |
| 640 | O | Ar16 | P11 | H | H | P1 | H | H | H |
| 641 | O | Ar17 | P11 | H | H | P1 | H | H | H |
| 642 | O | Ar18 | P11 | H | H | P1 | H | H | H |
| 643 | O | Ar19 | P11 | H | H | P1 | H | H | H |
| 644 | O | Ar20 | P11 | H | H | P1 | H | H | H |
| 645 | O | Ar21 | P11 | H | H | P1 | H | H | H |
| 646 | O | Ar22 | P11 | H | H | P1 | H | H | H |
| 647 | O | Ar23 | P11 | H | H | P1 | H | H | H |
| 648 | O | Ar24 | P11 | H | H | P1 | H | H | H |
| 649 | O | Ar25 | P11 | H | H | P1 | H | H | H |
| 650 | O | Ar26 | P11 | H | H | P1 | H | H | H |
| 651 | O | Ar27 | P11 | H | H | P1 | H | H | H |
| 652 | O | Ar28 | P11 | H | H | P1 | H | H | H |
| 653 | O | Ar29 | P11 | H | H | P1 | H | H | H |
| 654 | O | Ar30 | P11 | H | H | P1 | H | H | H |
| 655 | O | Ar31 | P11 | H | H | P1 | H | H | H |
| 656 | O | Ar32 | P11 | H | H | P1 | H | H | H |
| 657 | O | Ar33 | P11 | H | H | P1 | H | H | H |
| 658 | O | Ar34 | P11 | H | H | P1 | H | H | H |
| 659 | O | Ar35 | P11 | H | H | P1 | H | H | H |
| 660 | O | Ar36 | P11 | H | H | P1 | H | H | H |
| 661 | O | Ar37 | P11 | H | H | P1 | H | H | H |
| 662 | O | Ar38 | P11 | H | H | P1 | H | H | H |
| 663 | O | Ar39 | P11 | H | H | P1 | H | H | H |
| 664 | O | Ar40 | P11 | H | H | P1 | H | H | H |
| 665 | O | Ar41 | P11 | H | H | P1 | H | H | H |
| 666 | O | Ar42 | P11 | H | H | P1 | H | H | H |
| 667 | O | Ar43 | P11 | H | H | P1 | H | H | H |
| 668 | O | Ar44 | P11 | H | H | P1 | H | H | H |
| 669 | O | Ar45 | P11 | H | H | P1 | H | H | H |
| 670 | O | Ar46 | P11 | H | H | P1 | H | H | H |
| 671 | O | Ar47 | P11 | H | H | P1 | H | H | H |
| 672 | O | Ar48 | P11 | H | H | P1 | H | H | H |
| 673 | O | Ar49 | P11 | H | H | P1 | H | H | H |
| 674 | O | Ar50 | P11 | H | H | P1 | H | H | H |
| 675 | O | Ar51 | P11 | H | H | P1 | H | H | H |
| 676 | O | Ar52 | P11 | H | H | P1 | H | H | H |
| 677 | O | Ar53 | P11 | H | H | P1 | H | H | H |
| 678 | O | Ar54 | P11 | H | H | P1 | H | H | H |
| 679 | O | Ar55 | P11 | H | H | P1 | H | H | H |
| 680 | O | Ar56 | P11 | H | H | P1 | H | H | H |
| 681 | O | Ar57 | P11 | H | H | P1 | H | H | H |
| 682 | O | Ar58 | P11 | H | H | P1 | H | H | H |
| 683 | O | Ar59 | P11 | H | H | P1 | H | H | H |
| 684 | O | Ar60 | P11 | H | H | P1 | H | H | H |
| 685 | O | Ar61 | P11 | H | H | P1 | H | H | H |
| 686 | O | Ar62 | P11 | H | H | P1 | H | H | H |
| 687 | O | Ar63 | P11 | H | H | P1 | H | H | H |
| 688 | O | Ar64 | P11 | H | H | P1 | H | H | H |
| 689 | O | Ar65 | P11 | H | H | P1 | H | H | H |
| 690 | O | Ar66 | P11 | H | H | P1 | H | H | H |
| 691 | O | Ar67 | P11 | H | H | P1 | H | H | H |
| 692 | O | Ar68 | P11 | H | H | P1 | H | H | H |
| 693 | O | Ar69 | P11 | H | H | P1 | H | H | H |
| 694 | O | Ar70 | P11 | H | H | P1 | H | H | H |
| 695 | O | Ar71 | P11 | H | H | P1 | H | H | H |
| 696 | O | Ar72 | P11 | H | H | P1 | H | H | H |
| 697 | O | Ar73 | P11 | H | H | P1 | H | H | H |
| 698 | O | Ar74 | P11 | H | H | P1 | H | H | H |
| 699 | O | Ar75 | P11 | H | H | P1 | H | H | H |
| 700 | O | Ar76 | P11 | H | H | P1 | H | H | H |
| 701 | O | Ar77 | P11 | H | H | P1 | H | H | H |
| 702 | O | Ar78 | P11 | H | H | P1 | H | H | H |
| 703 | O | Ar79 | P11 | H | H | P1 | H | H | H |
| 704 | O | Ar80 | P11 | H | H | P1 | H | H | H |
| 705 | O | Ar81 | P11 | H | H | P1 | H | H | H |
| 706 | O | Ar82 | P11 | H | H | P1 | H | H | H |
| 707 | O | Ar83 | P11 | H | H | P1 | H | H | H |
| 708 | O | Ar84 | P11 | H | H | P1 | H | H | H |
| 709 | O | Ar85 | P11 | H | H | P1 | H | H | H |
| 710 | O | Ar86 | P11 | H | H | P1 | H | H | H |
| 711 | O | Ar87 | P11 | H | H | P1 | H | H | H |
| 712 | O | Ar88 | P11 | H | H | P1 | H | H | H |
| 713 | O | Ar89 | P11 | H | H | P1 | H | H | H |
| 714 | O | Ar90 | P11 | H | H | P1 | H | H | H |
| 715 | O | Ar91 | P11 | H | H | P1 | H | H | H |
| 716 | O | Ar92 | P11 | H | H | P1 | H | H | H |
| 717 | O | Ar93 | P11 | H | H | P1 | H | H | H |
| 718 | O | Ar94 | P11 | H | H | P1 | H | H | H |
| 719 | O | Ar95 | P11 | H | H | P1 | H | H | H |
| 720 | O | Ar96 | P11 | H | H | P1 | H | H | H |
| 721 | O | Ar97 | P11 | H | H | P1 | H | H | H |
| 722 | O | Ar98 | P11 | H | H | P1 | H | H | H |
| 723 | O | Ar99 | P11 | H | H | P1 | H | H | H |
| 724 | O | Ar100 | P11 | H | H | P1 | H | H | H |
| 725 | O | Ar101 | P11 | H | H | P1 | H | H | H |
| 726 | O | Ar102 | P11 | H | H | P1 | H | H | H |
| 727 | O | Ar103 | P11 | H | H | P1 | H | H | H |
| 728 | O | Ar104 | P11 | H | H | P1 | H | H | H |
| 729 | O | Ar1 | P12 | H | H | P1 | H | H | H |
| 730 | O | Ar2 | P12 | H | H | P1 | H | H | H |
| 731 | O | Ar3 | P12 | H | H | P1 | H | H | H |
| 732 | O | Ar4 | P12 | H | H | P1 | H | H | H |
| 733 | O | Ar5 | P12 | H | H | P1 | H | H | H |
| 734 | O | Ar6 | P12 | H | H | P1 | H | H | H |
| 735 | O | Ar7 | P12 | H | H | P1 | H | H | H |
| 736 | O | Ar8 | P12 | H | H | P1 | H | H | H |
| 737 | O | Ar9 | P12 | H | H | P1 | H | H | H |
| 738 | O | Ar10 | P12 | H | H | P1 | H | H | H |
| 739 | O | Ar11 | P12 | H | H | P1 | H | H | H |
| 740 | O | Ar12 | P12 | H | H | P1 | H | H | H |
| 741 | O | Ar13 | P12 | H | H | P1 | H | H | H |
| 742 | O | Ar14 | P12 | H | H | P1 | H | H | H |
| 743 | O | Ar15 | P12 | H | H | P1 | H | H | H |
| 744 | O | Ar16 | P12 | H | H | P1 | H | H | H |
| 745 | O | Ar17 | P12 | H | H | P1 | H | H | H |
| 746 | O | Ar18 | P12 | H | H | P1 | H | H | H |
| 747 | O | Ar19 | P12 | H | H | P1 | H | H | H |
| 748 | O | Ar20 | P12 | H | H | P1 | H | H | H |
| 749 | O | Ar21 | P12 | H | H | P1 | H | H | H |
| 750 | O | Ar22 | P12 | H | H | P1 | H | H | H |
| 751 | O | Ar23 | P12 | H | H | P1 | H | H | H |
| 752 | O | Ar24 | P12 | H | H | P1 | H | H | H |
| 753 | O | Ar25 | P12 | H | H | P1 | H | H | H |
| 754 | O | Ar26 | P12 | H | H | P1 | H | H | H |
| 755 | O | Ar27 | P12 | H | H | P1 | H | H | H |
| 756 | O | Ar28 | P12 | H | H | P1 | H | H | H |
| 757 | O | Ar29 | P12 | H | H | P1 | H | H | H |
| 758 | O | Ar30 | P12 | H | H | P1 | H | H | H |
| 759 | O | Ar31 | P12 | H | H | P1 | H | H | H |
| 760 | O | Ar32 | P12 | H | H | P1 | H | H | H |
| 761 | O | Ar33 | P12 | H | H | P1 | H | H | H |
| 762 | O | Ar34 | P12 | H | H | P1 | H | H | H |
| 763 | O | Ar35 | P12 | H | H | P1 | H | H | H |
| 764 | O | Ar36 | P12 | H | H | P1 | H | H | H |
| 765 | O | Ar37 | P12 | H | H | P1 | H | H | H |
| 766 | O | Ar38 | P12 | H | H | P1 | H | H | H |
| 767 | O | Ar39 | P12 | H | H | P1 | H | H | H |
| 768 | O | Ar40 | P12 | H | H | P1 | H | H | H |
| 769 | O | Ar41 | P12 | H | H | P1 | H | H | H |
| 770 | O | Ar42 | P12 | H | H | P1 | H | H | H |
| 771 | O | Ar43 | P12 | H | H | P1 | H | H | H |
| 772 | O | Ar44 | P12 | H | H | P1 | H | H | H |
| 773 | O | Ar45 | P12 | H | H | P1 | H | H | H |
| 774 | O | Ar46 | P12 | H | H | P1 | H | H | H |
| 775 | O | Ar47 | P12 | H | H | P1 | H | H | H |
| 776 | O | Ar48 | P12 | H | H | P1 | H | H | H |
| 777 | O | Ar49 | P12 | H | H | P1 | H | H | H |
| 778 | O | Ar50 | P12 | H | H | P1 | H | H | H |
| 779 | O | Ar51 | P12 | H | H | P1 | H | H | H |
| 780 | O | Ar52 | P12 | H | H | P1 | H | H | H |
| 781 | O | Ar53 | P12 | H | H | P1 | H | H | H |
| 782 | O | Ar54 | P12 | H | H | P1 | H | H | H |
| 783 | O | Ar55 | P12 | H | H | P1 | H | H | H |
| 784 | O | Ar56 | P12 | H | H | P1 | H | H | H |
| 785 | O | Ar57 | P12 | H | H | P1 | H | H | H |
| 786 | O | Ar58 | P12 | H | H | P1 | H | H | H |
| 787 | O | Ar59 | P12 | H | H | P1 | H | H | H |
| 788 | O | Ar60 | P12 | H | H | P1 | H | H | H |
| 789 | O | Ar61 | P12 | H | H | P1 | H | H | H |
| 790 | O | Ar62 | P12 | H | H | P1 | H | H | H |
| 791 | O | Ar63 | P12 | H | H | P1 | H | H | H |
| 792 | O | Ar64 | P12 | H | H | P1 | H | H | H |
| 793 | O | Ar65 | P12 | H | H | P1 | H | H | H |
| 794 | O | Ar66 | P12 | H | H | P1 | H | H | H |
| 795 | O | Ar67 | P12 | H | H | P1 | H | H | H |
| 796 | O | Ar68 | P12 | H | H | P1 | H | H | H |
| 797 | O | Ar69 | P12 | H | H | P1 | H | H | H |
| 798 | O | Ar70 | P12 | H | H | P1 | H | H | H |
| 799 | O | Ar71 | P12 | H | H | P1 | H | H | H |
| 800 | O | Ar72 | P12 | H | H | P1 | H | H | H |
| 801 | O | Ar73 | P12 | H | H | P1 | H | H | H |
| 802 | O | Ar74 | P12 | H | H | P1 | H | H | H |
| 803 | O | Ar75 | P12 | H | H | P1 | H | H | H |
| 804 | O | Ar76 | P12 | H | H | P1 | H | H | H |
| 805 | O | Ar77 | P12 | H | H | P1 | H | H | H |
| 806 | O | Ar78 | P12 | H | H | P1 | H | H | H |
| 807 | O | Ar79 | P12 | H | H | P1 | H | H | H |
| 808 | O | Ar80 | P12 | H | H | P1 | H | H | H |
| 809 | O | Ar81 | P12 | H | H | P1 | H | H | H |
| 810 | O | Ar82 | P12 | H | H | P1 | H | H | H |
| 811 | O | Ar83 | P12 | H | H | P1 | H | H | H |
| 812 | O | Ar84 | P12 | H | H | P1 | H | H | H |
| 813 | O | Ar85 | P12 | H | H | P1 | H | H | H |
| 814 | O | Ar86 | P12 | H | H | P1 | H | H | H |
| 815 | O | Ar87 | P12 | H | H | P1 | H | H | H |
| 816 | O | Ar88 | P12 | H | H | P1 | H | H | H |
| 817 | O | Ar89 | P12 | H | H | P1 | H | H | H |
| 818 | O | Ar90 | P12 | H | H | P1 | H | H | H |
| 819 | O | Ar91 | P12 | H | H | P1 | H | H | H |
| 820 | O | Ar92 | P12 | H | H | P1 | H | H | H |
| 821 | O | Ar93 | P12 | H | H | P1 | H | H | H |
| 822 | O | Ar94 | P12 | H | H | P1 | H | H | H |
| 823 | O | Ar95 | P12 | H | H | P1 | H | H | H |
| 824 | O | Ar96 | P12 | H | H | P1 | H | H | H |
| 825 | O | Ar97 | P12 | H | H | P1 | H | H | H |
| 826 | O | Ar98 | P12 | H | H | P1 | H | H | H |
| 827 | O | Ar99 | P12 | H | H | P1 | H | H | H |
| 828 | O | Ar100 | P12 | H | H | P1 | H | H | H |
| 829 | O | Ar101 | P12 | H | H | P1 | H | H | H |
| 830 | O | Ar102 | P12 | H | H | P1 | H | H | H |
| 831 | O | Ar103 | P12 | H | H | P1 | H | H | H |
| 832 | O | Ar104 | P12 | H | H | P1 | H | H | H |
| 833 | O | Ar1 | P1 | H | H | P2 | H | H | H |
| 834 | O | Ar2 | P1 | H | H | P2 | H | H | H |
| 835 | O | Ar3 | P1 | H | H | P2 | H | H | H |
| 836 | O | Ar4 | P1 | H | H | P2 | H | H | H |
| 837 | O | Ar5 | P1 | H | H | P2 | H | H | H |
| 838 | O | Ar6 | P1 | H | H | P2 | H | H | H |
| 839 | O | Ar7 | P1 | H | H | P2 | H | H | H |
| 840 | O | Ar8 | P1 | H | H | P2 | H | H | H |
| 841 | O | Ar9 | P1 | H | H | P2 | H | H | H |
| 842 | O | Ar10 | P1 | H | H | P2 | H | H | H |
| 843 | O | Ar11 | P1 | H | H | P2 | H | H | H |
| 844 | O | Ar12 | P1 | H | H | P2 | H | H | H |
| 845 | O | Ar13 | P1 | H | H | P2 | H | H | H |
| 846 | O | Ar14 | P1 | H | H | P2 | H | H | H |
| 847 | O | Ar15 | P1 | H | H | P2 | H | H | H |
| 848 | O | Ar16 | P1 | H | H | P2 | H | H | H |
| 849 | O | Ar17 | P1 | H | H | P2 | H | H | H |
| 850 | O | Ar18 | P1 | H | H | P2 | H | H | H |
| 851 | O | Ar19 | P1 | H | H | P2 | H | H | H |
| 852 | O | Ar20 | P1 | H | H | P2 | H | H | H |
| 853 | O | Ar21 | P1 | H | H | P2 | H | H | H |
| 854 | O | Ar22 | P1 | H | H | P2 | H | H | H |
| 855 | O | Ar23 | P1 | H | H | P2 | H | H | H |
| 856 | O | Ar24 | P1 | H | H | P2 | H | H | H |
| 857 | O | Ar25 | P1 | H | H | P2 | H | H | H |
| 858 | O | Ar26 | P1 | H | H | P2 | H | H | H |
| 859 | O | Ar27 | P1 | H | H | P2 | H | H | H |
| 860 | O | Ar28 | P1 | H | H | P2 | H | H | H |
| 861 | O | Ar29 | P1 | H | H | P2 | H | H | H |
| 862 | O | Ar30 | P1 | H | H | P2 | H | H | H |
| 863 | O | Ar31 | P1 | H | H | P2 | H | H | H |
| 864 | O | Ar32 | P1 | H | H | P2 | H | H | H |
| 865 | O | Ar33 | P1 | H | H | P2 | H | H | H |
| 866 | O | Ar34 | P1 | H | H | P2 | H | H | H |
| 867 | O | Ar35 | P1 | H | H | P2 | H | H | H |
| 868 | O | Ar36 | P1 | H | H | P2 | H | H | H |
| 869 | O | Ar37 | P1 | H | H | P2 | H | H | H |
| 870 | O | Ar38 | P1 | H | H | P2 | H | H | H |
| 871 | O | Ar39 | P1 | H | H | P2 | H | H | H |
| 872 | O | Ar40 | P1 | H | H | P2 | H | H | H |
| 873 | O | Ar41 | P1 | H | H | P2 | H | H | H |
| 874 | O | Ar42 | P1 | H | H | P2 | H | H | H |
| 875 | O | Ar43 | P1 | H | H | P2 | H | H | H |
| 876 | O | Ar44 | P1 | H | H | P2 | H | H | H |
| 877 | O | Ar45 | P1 | H | H | P2 | H | H | H |
| 878 | O | Ar46 | P1 | H | H | P2 | H | H | H |
| 879 | O | Ar47 | P1 | H | H | P2 | H | H | H |
| 880 | O | Ar48 | P1 | H | H | P2 | H | H | H |
| 881 | O | Ar49 | P1 | H | H | P2 | H | H | H |
| 882 | O | Ar50 | P1 | H | H | P2 | H | H | H |
| 883 | O | Ar51 | P1 | H | H | P2 | H | H | H |
| 884 | O | Ar52 | P1 | H | H | P2 | H | H | H |
| 885 | O | Ar53 | P1 | H | H | P2 | H | H | H |
| 886 | O | Ar54 | P1 | H | H | P2 | H | H | H |
| 887 | O | Ar55 | P1 | H | H | P2 | H | H | H |
| 888 | O | Ar56 | P1 | H | H | P2 | H | H | H |
| 889 | O | Ar57 | P1 | H | H | P2 | H | H | H |
| 890 | O | Ar58 | P1 | H | H | P2 | H | H | H |
| 891 | O | Ar59 | P1 | H | H | P2 | H | H | H |
| 892 | O | Ar60 | P1 | H | H | P2 | H | H | H |
| 893 | O | Ar61 | P1 | H | H | P2 | H | H | H |
| 894 | O | Ar62 | P1 | H | H | P2 | H | H | H |
| 895 | O | Ar63 | P1 | H | H | P2 | H | H | H |
| 896 | O | Ar64 | P1 | H | H | P2 | H | H | H |
| 897 | O | Ar65 | P1 | H | H | P2 | H | H | H |
| 898 | O | Ar66 | P1 | H | H | P2 | H | H | H |
| 899 | O | Ar67 | P1 | H | H | P2 | H | H | H |
| 900 | O | Ar68 | P1 | H | H | P2 | H | H | H |
| 901 | O | Ar69 | P1 | H | H | P2 | H | H | H |
| 902 | O | Ar70 | P1 | H | H | P2 | H | H | H |
| 903 | O | Ar71 | P1 | H | H | P2 | H | H | H |
| 904 | O | Ar72 | P1 | H | H | P2 | H | H | H |
| 905 | O | Ar73 | P1 | H | H | P2 | H | H | H |
| 906 | O | Ar74 | P1 | H | H | P2 | H | H | H |
| 907 | O | Ar75 | P1 | H | H | P2 | H | H | H |
| 908 | O | Ar76 | P1 | H | H | P2 | H | H | H |
| 909 | O | Ar77 | P1 | H | H | P2 | H | H | H |
| 910 | O | Ar78 | P1 | H | H | P2 | H | H | H |
| 911 | O | Ar79 | P1 | H | H | P2 | H | H | H |
| 912 | O | Ar80 | P1 | H | H | P2 | H | H | H |
| 913 | O | Ar81 | P1 | H | H | P2 | H | H | H |
| 914 | O | Ar82 | P1 | H | H | P2 | H | H | H |
| 915 | O | Ar83 | P1 | H | H | P2 | H | H | H |
| 916 | O | Ar84 | P1 | H | H | P2 | H | H | H |
| 917 | O | Ar85 | P1 | H | H | P2 | H | H | H |
| 918 | O | Ar86 | P1 | H | H | P2 | H | H | H |
| 919 | O | Ar87 | P1 | H | H | P2 | H | H | H |
| 920 | O | Ar88 | P1 | H | H | P2 | H | H | H |
| 921 | O | Ar89 | P1 | H | H | P2 | H | H | H |
| 922 | O | Ar90 | P1 | H | H | P2 | H | H | H |
| 923 | O | Ar91 | P1 | H | H | P2 | H | H | H |
| 924 | O | Ar92 | P1 | H | H | P2 | H | H | H |
| 925 | O | Ar93 | P1 | H | H | P2 | H | H | H |
| 926 | O | Ar94 | P1 | H | H | P2 | H | H | H |
| 927 | O | Ar95 | P1 | H | H | P2 | H | H | H |
| 928 | O | Ar96 | P1 | H | H | P2 | H | H | H |
| 929 | O | Ar97 | P1 | H | H | P2 | H | H | H |
| 930 | O | Ar98 | P1 | H | H | P2 | H | H | H |
| 931 | O | Ar99 | P1 | H | H | P2 | H | H | H |
| 932 | O | Ar100 | P1 | H | H | P2 | H | H | H |
| 933 | O | Ar101 | P1 | H | H | P2 | H | H | H |
| 934 | O | Ar102 | P1 | H | H | P2 | H | H | H |
| 935 | O | Ar103 | P1 | H | H | P2 | H | H | H |
| 936 | O | Ar104 | P1 | H | H | P2 | H | H | H |
| 937 | O | Ar1 | P2 | H | H | P2 | H | H | H |
| 938 | O | Ar2 | P2 | H | H | P2 | H | H | H |
| 939 | O | Ar3 | P2 | H | H | P2 | H | H | H |
| 940 | O | Ar4 | P2 | H | H | P2 | H | H | H |
| 941 | O | Ar5 | P2 | H | H | P2 | H | H | H |
| 942 | O | Ar6 | P2 | H | H | P2 | H | H | H |
| 943 | O | Ar7 | P2 | H | H | P2 | H | H | H |
| 944 | O | Ar8 | P2 | H | H | P2 | H | H | H |
| 945 | O | Ar9 | P2 | H | H | P2 | H | H | H |
| 946 | O | Ar10 | P2 | H | H | P2 | H | H | H |
| 947 | O | Ar11 | P2 | H | H | P2 | H | H | H |
| 948 | O | Ar12 | P2 | H | H | P2 | H | H | H |
| 949 | O | Ar13 | P2 | H | H | P2 | H | H | H |
| 950 | O | Ar14 | P2 | H | H | P2 | H | H | H |
| 951 | O | Ar15 | P2 | H | H | P2 | H | H | H |
| 952 | O | Ar16 | P2 | H | H | P2 | H | H | H |
| 953 | O | Ar17 | P2 | H | H | P2 | H | H | H |
| 954 | O | Ar18 | P2 | H | H | P2 | H | H | H |
| 955 | O | Ar19 | P2 | H | H | P2 | H | H | H |
| 956 | O | Ar20 | P2 | H | H | P2 | H | H | H |
| 957 | O | Ar21 | P2 | H | H | P2 | H | H | H |
| 958 | O | Ar22 | P2 | H | H | P2 | H | H | H |
| 959 | O | Ar23 | P2 | H | H | P2 | H | H | H |
| 960 | O | Ar24 | P2 | H | H | P2 | H | H | H |
| 961 | O | Ar25 | P2 | H | H | P2 | H | H | H |
| 962 | O | Ar26 | P2 | H | H | P2 | H | H | H |
| 963 | O | Ar27 | P2 | H | H | P2 | H | H | H |
| 964 | O | Ar28 | P2 | H | H | P2 | H | H | H |
| 965 | O | Ar29 | P2 | H | H | P2 | H | H | H |
| 966 | O | Ar30 | P2 | H | H | P2 | H | H | H |
| 967 | O | Ar31 | P2 | H | H | P2 | H | H | H |
| 968 | O | Ar32 | P2 | H | H | P2 | H | H | H |
| 969 | O | Ar33 | P2 | H | H | P2 | H | H | H |
| 970 | O | Ar34 | P2 | H | H | P2 | H | H | H |
| 971 | O | Ar35 | P2 | H | H | P2 | H | H | H |
| 972 | O | Ar36 | P2 | H | H | P2 | H | H | H |
| 973 | O | Ar37 | P2 | H | H | P2 | H | H | H |
| 974 | O | Ar38 | P2 | H | H | P2 | H | H | H |
| 975 | O | Ar39 | P2 | H | H | P2 | H | H | H |
| 976 | O | Ar40 | P2 | H | H | P2 | H | H | H |
| 977 | O | Ar41 | P2 | H | H | P2 | H | H | H |
| 978 | O | Ar42 | P2 | H | H | P2 | H | H | H |
| 979 | O | Ar43 | P2 | H | H | P2 | H | H | H |
| 980 | O | Ar44 | P2 | H | H | P2 | H | H | H |
| 981 | O | Ar45 | P2 | H | H | P2 | H | H | H |
| 982 | O | Ar46 | P2 | H | H | P2 | H | H | H |
| 983 | O | Ar47 | P2 | H | H | P2 | H | H | H |
| 984 | O | Ar48 | P2 | H | H | P2 | H | H | H |
| 985 | O | Ar49 | P2 | H | H | P2 | H | H | H |
| 986 | O | Ar50 | P2 | H | H | P2 | H | H | H |
| 987 | O | Ar51 | P2 | H | H | P2 | H | H | H |
| 988 | O | Ar52 | P2 | H | H | P2 | H | H | H |
| 989 | O | Ar53 | P2 | H | H | P2 | H | H | H |
| 990 | O | Ar54 | P2 | H | H | P2 | H | H | H |
| 991 | O | Ar55 | P2 | H | H | P2 | H | H | H |
| 992 | O | Ar56 | P2 | H | H | P2 | H | H | H |
| 993 | O | Ar57 | P2 | H | H | P2 | H | H | H |
| 994 | O | Ar58 | P2 | H | H | P2 | H | H | H |
| 995 | O | Ar59 | P2 | H | H | P2 | H | H | H |
| 996 | O | Ar60 | P2 | H | H | P2 | H | H | H |
| 997 | O | Ar61 | P2 | H | H | P2 | H | H | H |
| 998 | O | Ar62 | P2 | H | H | P2 | H | H | H |
| 999 | O | Ar63 | P2 | H | H | P2 | H | H | H |
| 1000 | O | Ar64 | P2 | H | H | P2 | H | H | H |
| 1001 | O | Ar65 | P2 | H | H | P2 | H | H | H |
| 1002 | O | Ar66 | P2 | H | H | P2 | H | H | H |
| 1003 | O | Ar67 | P2 | H | H | P2 | H | H | H |
| 1004 | O | Ar68 | P2 | H | H | P2 | H | H | H |
| 1005 | O | Ar69 | P2 | H | H | P2 | H | H | H |
| 1006 | O | Ar70 | P2 | H | H | P2 | H | H | H |
| 1007 | O | Ar71 | P2 | H | H | P2 | H | H | H |
| 1008 | O | Ar72 | P2 | H | H | P2 | H | H | H |
| 1009 | O | Ar73 | P2 | H | H | P2 | H | H | H |
| 1010 | O | Ar74 | P2 | H | H | P2 | H | H | H |
| 1011 | O | Ar75 | P2 | H | H | P2 | H | H | H |
| 1012 | O | Ar76 | P2 | H | H | P2 | H | H | H |
| 1013 | O | Ar77 | P2 | H | H | P2 | H | H | H |
| 1014 | O | Ar78 | P2 | H | H | P2 | H | H | H |
| 1015 | O | Ar79 | P2 | H | H | P2 | H | H | H |
| 1016 | O | Ar80 | P2 | H | H | P2 | H | H | H |
| 1017 | O | Ar81 | P2 | H | H | P2 | H | H | H |
| 1018 | O | Ar82 | P2 | H | H | P2 | H | H | H |
| 1019 | O | Ar83 | P2 | H | H | P2 | H | H | H |
| 1020 | O | Ar84 | P2 | H | H | P2 | H | H | H |
| 1021 | O | Ar85 | P2 | H | H | P2 | H | H | H |
| 1022 | O | Ar86 | P2 | H | H | P2 | H | H | H |
| 1023 | O | Ar87 | P2 | H | H | P2 | H | H | H |
| 1024 | O | Ar88 | P2 | H | H | P2 | H | H | H |
| 1025 | O | Ar89 | P2 | H | H | P2 | H | H | H |
| 1026 | O | Ar90 | P2 | H | H | P2 | H | H | H |
| 1027 | O | Ar91 | P2 | H | H | P2 | H | H | H |
| 1028 | O | Ar92 | P2 | H | H | P2 | H | H | H |
| 1029 | O | Ar93 | P2 | H | H | P2 | H | H | H |
| 1030 | O | Ar94 | P2 | H | H | P2 | H | H | H |
| 1031 | O | Ar95 | P2 | H | H | P2 | H | H | H |
| 1032 | O | Ar96 | P2 | H | H | P2 | H | H | H |
| 1033 | O | Ar97 | P2 | H | H | P2 | H | H | H |
| 1034 | O | Ar98 | P2 | H | H | P2 | H | H | H |
| 1035 | O | Ar99 | P2 | H | H | P2 | H | H | H |
| 1036 | O | Ar100 | P2 | H | H | P2 | H | H | H |
| 1037 | O | Ar101 | P2 | H | H | P2 | H | H | H |
| 1038 | O | Ar102 | P2 | H | H | P2 | H | H | H |
| 1039 | O | Ar103 | P2 | H | H | P2 | H | H | H |
| 1040 | O | Ar104 | P2 | H | H | P2 | H | H | H |
| 1041 | O | Ar1 | P11 | H | H | P2 | H | H | H |
| 1042 | O | Ar2 | P11 | H | H | P2 | H | H | H |
| 1043 | O | Ar3 | P11 | H | H | P2 | H | H | H |
| 1044 | O | Ar4 | P11 | H | H | P2 | H | H | H |
| 1045 | O | Ar5 | P11 | H | H | P2 | H | H | H |
| 1046 | O | Ar6 | P11 | H | H | P2 | H | H | H |
| 1047 | O | Ar7 | P11 | H | H | P2 | H | H | H |
| 1048 | O | Ar8 | P11 | H | H | P2 | H | H | H |
| 1049 | O | Ar9 | P11 | H | H | P2 | H | H | H |
| 1050 | O | Ar10 | P11 | H | H | P2 | H | H | H |
| 1051 | O | Ar11 | P11 | H | H | P2 | H | H | H |
| 1052 | O | Ar12 | P11 | H | H | P2 | H | H | H |
| 1053 | O | Ar13 | P11 | H | H | P2 | H | H | H |
| 1054 | O | Ar14 | P11 | H | H | P2 | H | H | H |
| 1055 | O | Ar15 | P11 | H | H | P2 | H | H | H |
| 1056 | O | Ar16 | P11 | H | H | P2 | H | H | H |
| 1057 | O | Ar17 | P11 | H | H | P2 | H | H | H |
| 1058 | O | Ar18 | P11 | H | H | P2 | H | H | H |
| 1059 | O | Ar19 | P11 | H | H | P2 | H | H | H |
| 1060 | O | Ar20 | P11 | H | H | P2 | H | H | H |
| 1061 | O | Ar21 | P11 | H | H | P2 | H | H | H |
| 1062 | O | Ar22 | P11 | H | H | P2 | H | H | H |
| 1063 | O | Ar23 | P11 | H | H | P2 | H | H | H |
| 1064 | O | Ar24 | P11 | H | H | P2 | H | H | H |
| 1065 | O | Ar25 | P11 | H | H | P2 | H | H | H |
| 1066 | O | Ar26 | P11 | H | H | P2 | H | H | H |
| 1067 | O | Ar27 | P11 | H | H | P2 | H | H | H |
| 1068 | O | Ar28 | P11 | H | H | P2 | H | H | H |
| 1069 | O | Ar29 | P11 | H | H | P2 | H | H | H |
| 1070 | O | Ar30 | P11 | H | H | P2 | H | H | H |
| 1071 | O | Ar31 | P11 | H | H | P2 | H | H | H |
| 1072 | O | Ar32 | P11 | H | H | P2 | H | H | H |
| 1073 | O | Ar33 | P11 | H | H | P2 | H | H | H |
| 1074 | O | Ar34 | P11 | H | H | P2 | H | H | H |
| 1075 | O | Ar35 | P11 | H | H | P2 | H | H | H |
| 1076 | O | Ar36 | P11 | H | H | P2 | H | H | H |
| 1077 | O | Ar37 | P11 | H | H | P2 | H | H | H |
| 1078 | O | Ar38 | P11 | H | H | P2 | H | H | H |
| 1079 | O | Ar39 | P11 | H | H | P2 | H | H | H |
| 1080 | O | Ar40 | P11 | H | H | P2 | H | H | H |
| 1081 | O | Ar41 | P11 | H | H | P2 | H | H | H |
| 1082 | O | Ar42 | P11 | H | H | P2 | H | H | H |
| 1083 | O | Ar43 | P11 | H | H | P2 | H | H | H |
| 1084 | O | Ar44 | P11 | H | H | P2 | H | H | H |
| 1085 | O | Ar45 | P11 | H | H | P2 | H | H | H |
| 1086 | O | Ar46 | P11 | H | H | P2 | H | H | H |
| 1087 | O | Ar47 | P11 | H | H | P2 | H | H | H |
| 1088 | O | Ar48 | P11 | H | H | P2 | H | H | H |
| 1089 | O | Ar49 | P11 | H | H | P2 | H | H | H |
| 1090 | O | Ar50 | P11 | H | H | P2 | H | H | H |
| 1091 | O | Ar51 | P11 | H | H | P2 | H | H | H |
| 1092 | O | Ar52 | P11 | H | H | P2 | H | H | H |
| 1093 | O | Ar53 | P11 | H | H | P2 | H | H | H |
| 1094 | O | Ar54 | P11 | H | H | P2 | H | H | H |
| 1095 | O | Ar55 | P11 | H | H | P2 | H | H | H |
| 1096 | O | Ar56 | P11 | H | H | P2 | H | H | H |
| 1097 | O | Ar57 | P11 | H | H | P2 | H | H | H |
| 1098 | O | Ar58 | P11 | H | H | P2 | H | H | H |
| 1099 | O | Ar59 | P11 | H | H | P2 | H | H | H |
| 1100 | O | Ar60 | P11 | H | H | P2 | H | H | H |
| 1101 | O | Ar61 | P11 | H | H | P2 | H | H | H |
| 1102 | O | Ar62 | P11 | H | H | P2 | H | H | H |
| 1103 | O | Ar63 | P11 | H | H | P2 | H | H | H |
| 1104 | O | Ar64 | P11 | H | H | P2 | H | H | H |
| 1105 | O | Ar65 | P11 | H | H | P2 | H | H | H |
| 1106 | O | Ar66 | P11 | H | H | P2 | H | H | H |
| 1107 | O | Ar67 | P11 | H | H | P2 | H | H | H |
| 1108 | O | Ar68 | P11 | H | H | P2 | H | H | H |
| 1109 | O | Ar69 | P11 | H | H | P2 | H | H | H |
| 1110 | O | Ar70 | P11 | H | H | P2 | H | H | H |
| 1111 | O | Ar71 | P11 | H | H | P2 | H | H | H |
| 1112 | O | Ar72 | P11 | H | H | P2 | H | H | H |
| 1113 | O | Ar73 | P11 | H | H | P2 | H | H | H |
| 1114 | O | Ar74 | P11 | H | H | P2 | H | H | H |
| 1115 | O | Ar75 | P11 | H | H | P2 | H | H | H |
| 1116 | O | Ar76 | P11 | H | H | P2 | H | H | H |
| 1117 | O | Ar77 | P11 | H | H | P2 | H | H | H |
| 1118 | O | Ar78 | P11 | H | H | P2 | H | H | H |
| 1119 | O | Ar79 | P11 | H | H | P2 | H | H | H |
| 1120 | O | Ar80 | P11 | H | H | P2 | H | H | H |
| 1121 | O | Ar81 | P11 | H | H | P2 | H | H | H |
| 1122 | O | Ar82 | P11 | H | H | P2 | H | H | H |
| 1123 | O | Ar83 | P11 | H | H | P2 | H | H | H |
| 1124 | O | Ar84 | P11 | H | H | P2 | H | H | H |
| 1125 | O | Ar85 | P11 | H | H | P2 | H | H | H |
| 1126 | O | Ar86 | P11 | H | H | P2 | H | H | H |
| 1127 | O | Ar87 | P11 | H | H | P2 | H | H | H |
| 1128 | O | Ar88 | P11 | H | H | P2 | H | H | H |
| 1129 | O | Ar89 | P11 | H | H | P2 | H | H | H |
| 1130 | O | Ar90 | P11 | H | H | P2 | H | H | H |
| 1131 | O | Ar91 | P11 | H | H | P2 | H | H | H |
| 1132 | O | Ar92 | P11 | H | H | P2 | H | H | H |
| 1133 | O | Ar93 | P11 | H | H | P2 | H | H | H |
| 1134 | O | Ar94 | P11 | H | H | P2 | H | H | H |
| 1135 | O | Ar95 | P11 | H | H | P2 | H | H | H |
| 1136 | O | Ar96 | P11 | H | H | P2 | H | H | H |
| 1137 | O | Ar97 | P11 | H | H | P2 | H | H | H |
| 1138 | O | Ar98 | P11 | H | H | P2 | H | H | H |
| 1139 | O | Ar99 | P11 | H | H | P2 | H | H | H |
| 1140 | O | Ar100 | P11 | H | H | P2 | H | H | H |
| 1141 | O | Ar101 | P11 | H | H | P2 | H | H | H |
| 1142 | O | Ar102 | P11 | H | H | P2 | H | H | H |
| 1143 | O | Ar103 | P11 | H | H | P2 | H | H | H |
| 1144 | O | Ar104 | P11 | H | H | P2 | H | H | H |
| 1145 | O | Ar1 | P12 | H | H | P2 | H | H | H |
| 1146 | O | Ar2 | P12 | H | H | P2 | H | H | H |
| 1147 | O | Ar3 | P12 | H | H | P2 | H | H | H |
| 1148 | O | Ar4 | P12 | H | H | P2 | H | H | H |
| 1149 | O | Ar5 | P12 | H | H | P2 | H | H | H |
| 1150 | O | Ar6 | P12 | H | H | P2 | H | H | H |
| 1151 | O | Ar7 | P12 | H | H | P2 | H | H | H |
| 1152 | O | Ar8 | P12 | H | H | P2 | H | H | H |
| 1153 | O | Ar9 | P12 | H | H | P2 | H | H | H |
| 1154 | O | Ar10 | P12 | H | H | P2 | H | H | H |
| 1155 | O | Ar11 | P12 | H | H | P2 | H | H | H |
| 1156 | O | Ar12 | P12 | H | H | P2 | H | H | H |
| 1157 | O | Ar13 | P12 | H | H | P2 | H | H | H |
| 1158 | O | Ar14 | P12 | H | H | P2 | H | H | H |
| 1159 | O | Ar15 | P12 | H | H | P2 | H | H | H |
| 1160 | O | Ar16 | P12 | H | H | P2 | H | H | H |
| 1161 | O | Ar17 | P12 | H | H | P2 | H | H | H |
| 1162 | O | Ar18 | P12 | H | H | P2 | H | H | H |
| 1163 | O | Ar19 | P12 | H | H | P2 | H | H | H |
| 1164 | O | Ar20 | P12 | H | H | P2 | H | H | H |
| 1165 | O | Ar21 | P12 | H | H | P2 | H | H | H |
| 1166 | O | Ar22 | P12 | H | H | P2 | H | H | H |
| 1167 | O | Ar23 | P12 | H | H | P2 | H | H | H |
| 1168 | O | Ar24 | P12 | H | H | P2 | H | H | H |
| 1169 | O | Ar25 | P12 | H | H | P2 | H | H | H |
| 1170 | O | Ar26 | P12 | H | H | P2 | H | H | H |
| 1171 | O | Ar27 | P12 | H | H | P2 | H | H | H |
| 1172 | O | Ar28 | P12 | H | H | P2 | H | H | H |
| 1173 | O | Ar29 | P12 | H | H | P2 | H | H | H |
| 1174 | O | Ar30 | P12 | H | H | P2 | H | H | H |
| 1175 | O | Ar31 | P12 | H | H | P2 | H | H | H |
| 1176 | O | Ar32 | P12 | H | H | P2 | H | H | H |
| 1177 | O | Ar33 | P12 | H | H | P2 | H | H | H |
| 1178 | O | Ar34 | P12 | H | H | P2 | H | H | H |
| 1179 | O | Ar35 | P12 | H | H | P2 | H | H | H |
| 1180 | O | Ar36 | P12 | H | H | P2 | H | H | H |
| 1181 | O | Ar37 | P12 | H | H | P2 | H | H | H |
| 1182 | O | Ar38 | P12 | H | H | P2 | H | H | H |
| 1183 | O | Ar39 | P12 | H | H | P2 | H | H | H |
| 1184 | O | Ar40 | P12 | H | H | P2 | H | H | H |
| 1185 | O | Ar41 | P12 | H | H | P2 | H | H | H |
| 1186 | O | Ar42 | P12 | H | H | P2 | H | H | H |
| 1187 | O | Ar43 | P12 | H | H | P2 | H | H | H |
| 1188 | O | Ar44 | P12 | H | H | P2 | H | H | H |
| 1189 | O | Ar45 | P12 | H | H | P2 | H | H | H |
| 1190 | O | Ar46 | P12 | H | H | P2 | H | H | H |
| 1191 | O | Ar47 | P12 | H | H | P2 | H | H | H |
| 1192 | O | Ar48 | P12 | H | H | P2 | H | H | H |
| 1193 | O | Ar49 | P12 | H | H | P2 | H | H | H |
| 1194 | O | Ar50 | P12 | H | H | P2 | H | H | H |
| 1195 | O | Ar51 | P12 | H | H | P2 | H | H | H |
| 1196 | O | Ar52 | P12 | H | H | P2 | H | H | H |
| 1197 | O | Ar53 | P12 | H | H | P2 | H | H | H |
| 1198 | O | Ar54 | P12 | H | H | P2 | H | H | H |
| 1199 | O | Ar55 | P12 | H | H | P2 | H | H | H |
| 1200 | O | Ar56 | P12 | H | H | P2 | H | H | H |
| 1201 | O | Ar57 | P12 | H | H | P2 | H | H | H |
| 1202 | O | Ar58 | P12 | H | H | P2 | H | H | H |
| 1203 | O | Ar59 | P12 | H | H | P2 | H | H | H |
| 1204 | O | Ar60 | P12 | H | H | P2 | H | H | H |
| 1205 | O | Ar61 | P12 | H | H | P2 | H | H | H |
| 1206 | O | Ar62 | P12 | H | H | P2 | H | H | H |
| 1207 | O | Ar63 | P12 | H | H | P2 | H | H | H |
| 1208 | O | Ar64 | P12 | H | H | P2 | H | H | H |
| 1209 | O | Ar65 | P12 | H | H | P2 | H | H | H |
| 1210 | O | Ar66 | P12 | H | H | P2 | H | H | H |
| 1211 | O | Ar67 | P12 | H | H | P2 | H | H | H |
| 1212 | O | Ar68 | P12 | H | H | P2 | H | H | H |
| 1213 | O | Ar69 | P12 | H | H | P2 | H | H | H |
| 1214 | O | Ar70 | P12 | H | H | P2 | H | H | H |
| 1215 | O | Ar71 | P12 | H | H | P2 | H | H | H |
| 1216 | O | Ar72 | P12 | H | H | P2 | H | H | H |
| 1217 | O | Ar73 | P12 | H | H | P2 | H | H | H |
| 1218 | O | Ar74 | P12 | H | H | P2 | H | H | H |
| 1219 | O | Ar75 | P12 | H | H | P2 | H | H | H |
| 1220 | O | Ar76 | P12 | H | H | P2 | H | H | H |
| 1221 | O | Ar77 | P12 | H | H | P2 | H | H | H |
| 1222 | O | Ar78 | P12 | H | H | P2 | H | H | H |
| 1223 | O | Ar79 | P12 | H | H | P2 | H | H | H |
| 1224 | O | Ar80 | P12 | H | H | P2 | H | H | H |
| 1225 | O | Ar81 | P12 | H | H | P2 | H | H | H |
| 1226 | O | Ar82 | P12 | H | H | P2 | H | H | H |
| 1227 | O | Ar83 | P12 | H | H | P2 | H | H | H |
| 1228 | O | Ar84 | P12 | H | H | P2 | H | H | H |
| 1229 | O | Ar85 | P12 | H | H | P2 | H | H | H |
| 1230 | O | Ar86 | P12 | H | H | P2 | H | H | H |
| 1231 | O | Ar87 | P12 | H | H | P2 | H | H | H |
| 1232 | O | Ar88 | P12 | H | H | P2 | H | H | H |
| 1233 | O | Ar89 | P12 | H | H | P2 | H | H | H |
| 1234 | O | Ar90 | P12 | H | H | P2 | H | H | H |
| 1235 | O | Ar91 | P12 | H | H | P2 | H | H | H |
| 1236 | O | Ar92 | P12 | H | H | P2 | H | H | H |
| 1237 | O | Ar93 | P12 | H | H | P2 | H | H | H |
| 1238 | O | Ar94 | P12 | H | H | P2 | H | H | H |
| 1239 | O | Ar95 | P12 | H | H | P2 | H | H | H |
| 1240 | O | Ar96 | P12 | H | H | P2 | H | H | H |
| 1241 | O | Ar97 | P12 | H | H | P2 | H | H | H |
| 1242 | O | Ar98 | P12 | H | H | P2 | H | H | H |
| 1243 | O | Ar99 | P12 | H | H | P2 | H | H | H |
| 1244 | O | Ar100 | P12 | H | H | P2 | H | H | H |
| 1245 | O | Ar101 | P12 | H | H | P2 | H | H | H |
| 1246 | O | Ar102 | P12 | H | H | P2 | H | H | H |
| 1247 | O | Ar103 | P12 | H | H | P2 | H | H | H |
| 1248 | O | Ar104 | P12 | H | H | P2 | H | H | H |
| 1249 | O | Ar1 | P1 | H | H | P8 | H | H | H |
| 1250 | O | Ar2 | P1 | H | H | P8 | H | H | H |
| 1251 | O | Ar3 | P1 | H | H | P8 | H | H | H |
| 1252 | O | Ar4 | P1 | H | H | P8 | H | H | H |
| 1253 | O | Ar5 | P1 | H | H | P8 | H | H | H |
| 1254 | O | Ar6 | P1 | H | H | P8 | H | H | H |
| 1255 | O | Ar7 | P1 | H | H | P8 | H | H | H |
| 1256 | O | Ar8 | P1 | H | H | P8 | H | H | H |
| 1257 | O | Ar9 | P1 | H | H | P8 | H | H | H |
| 1258 | O | Ar10 | P1 | H | H | P8 | H | H | H |
| 1259 | O | Ar11 | P1 | H | H | P8 | H | H | H |
| 1260 | O | Ar12 | P1 | H | H | P8 | H | H | H |
| 1261 | O | Ar13 | P1 | H | H | P8 | H | H | H |
| 1262 | O | Ar14 | P1 | H | H | P8 | H | H | H |
| 1263 | O | Ar15 | P1 | H | H | P8 | H | H | H |
| 1264 | O | Ar16 | P1 | H | H | P8 | H | H | H |
| 1265 | O | Ar17 | P1 | H | H | P8 | H | H | H |
| 1266 | O | Ar18 | P1 | H | H | P8 | H | H | H |
| 1267 | O | Ar19 | P1 | H | H | P8 | H | H | H |
| 1268 | O | Ar20 | P1 | H | H | P8 | H | H | H |
| 1269 | O | Ar21 | P1 | H | H | P8 | H | H | H |
| 1270 | O | Ar22 | P1 | H | H | P8 | H | H | H |
| 1271 | O | Ar23 | P1 | H | H | P8 | H | H | H |
| 1272 | O | Ar24 | P1 | H | H | P8 | H | H | H |
| 1273 | O | Ar25 | P1 | H | H | P8 | H | H | H |
| 1274 | O | Ar26 | P1 | H | H | P8 | H | H | H |
| 1275 | O | Ar27 | P1 | H | H | P8 | H | H | H |
| 1276 | O | Ar28 | P1 | H | H | P8 | H | H | H |
| 1277 | O | Ar29 | P1 | H | H | P8 | H | H | H |
| 1278 | O | Ar30 | P1 | H | H | P8 | H | H | H |
| 1279 | O | Ar31 | P1 | H | H | P8 | H | H | H |
| 1280 | O | Ar32 | P1 | H | H | P8 | H | H | H |
| 1281 | O | Ar33 | P1 | H | H | P8 | H | H | H |
| 1282 | O | Ar34 | P1 | H | H | P8 | H | H | H |
| 1283 | O | Ar35 | P1 | H | H | P8 | H | H | H |
| 1284 | O | Ar36 | P1 | H | H | P8 | H | H | H |
| 1285 | O | Ar37 | P1 | H | H | P8 | H | H | H |
| 1286 | O | Ar38 | P1 | H | H | P8 | H | H | H |
| 1287 | O | Ar39 | P1 | H | H | P8 | H | H | H |
| 1288 | O | Ar40 | P1 | H | H | P8 | H | H | H |
| 1289 | O | Ar41 | P1 | H | H | P8 | H | H | H |
| 1290 | O | Ar42 | P1 | H | H | P8 | H | H | H |
| 1291 | O | Ar43 | P1 | H | H | P8 | H | H | H |
| 1292 | O | Ar44 | P1 | H | H | P8 | H | H | H |
| 1293 | O | Ar45 | P1 | H | H | P8 | H | H | H |
| 1294 | O | Ar46 | P1 | H | H | P8 | H | H | H |
| 1295 | O | Ar47 | P1 | H | H | P8 | H | H | H |
| 1296 | O | Ar48 | P1 | H | H | P8 | H | H | H |
| 1297 | O | Ar49 | P1 | H | H | P8 | H | H | H |
| 1298 | O | Ar50 | P1 | H | H | P8 | H | H | H |
| 1299 | O | Ar51 | P1 | H | H | P8 | H | H | H |
| 1300 | O | Ar52 | P1 | H | H | P8 | H | H | H |
| 1301 | O | Ar53 | P1 | H | H | P8 | H | H | H |
| 1302 | O | Ar54 | P1 | H | H | P8 | H | H | H |
| 1303 | O | Ar55 | P1 | H | H | P8 | H | H | H |
| 1304 | O | Ar56 | P1 | H | H | P8 | H | H | H |
| 1305 | O | Ar57 | P1 | H | H | P8 | H | H | H |
| 1306 | O | Ar58 | P1 | H | H | P8 | H | H | H |
| 1307 | O | Ar59 | P1 | H | H | P8 | H | H | H |
| 1308 | O | Ar60 | P1 | H | H | P8 | H | H | H |
| 1309 | O | Ar61 | P1 | H | H | P8 | H | H | H |
| 1310 | O | Ar62 | P1 | H | H | P8 | H | H | H |
| 1311 | O | Ar63 | P1 | H | H | P8 | H | H | H |
| 1312 | O | Ar64 | P1 | H | H | P8 | H | H | H |
| 1313 | O | Ar65 | P1 | H | H | P8 | H | H | H |
| 1314 | O | Ar66 | P1 | H | H | P8 | H | H | H |
| 1315 | O | Ar67 | P1 | H | H | P8 | H | H | H |
| 1316 | O | Ar68 | P1 | H | H | P8 | H | H | H |
| 1317 | O | Ar69 | P1 | H | H | P8 | H | H | H |
| 1318 | O | Ar70 | P1 | H | H | P8 | H | H | H |
| 1319 | O | Ar71 | P1 | H | H | P8 | H | H | H |
| 1320 | O | Ar72 | P1 | H | H | P8 | H | H | H |
| 1321 | O | Ar73 | P1 | H | H | P8 | H | H | H |
| 1322 | O | Ar74 | P1 | H | H | P8 | H | H | H |
| 1323 | O | Ar75 | P1 | H | H | P8 | H | H | H |
| 1324 | O | Ar76 | P1 | H | H | P8 | H | H | H |
| 1325 | O | Ar77 | P1 | H | H | P8 | H | H | H |
| 1326 | O | Ar78 | P1 | H | H | P8 | H | H | H |
| 1327 | O | Ar79 | P1 | H | H | P8 | H | H | H |
| 1328 | O | Ar80 | P1 | H | H | P8 | H | H | H |
| 1329 | O | Ar81 | P1 | H | H | P8 | H | H | H |
| 1330 | O | Ar82 | P1 | H | H | P8 | H | H | H |
| 1331 | O | Ar83 | P1 | H | H | P8 | H | H | H |
| 1332 | O | Ar84 | P1 | H | H | P8 | H | H | H |
| 1333 | O | Ar85 | P1 | H | H | P8 | H | H | H |
| 1334 | O | Ar86 | P1 | H | H | P8 | H | H | H |
| 1335 | O | Ar87 | P1 | H | H | P8 | H | H | H |
| 1336 | O | Ar88 | P1 | H | H | P8 | H | H | H |
| 1337 | O | Ar89 | P1 | H | H | P8 | H | H | H |
| 1338 | O | Ar90 | P1 | H | H | P8 | H | H | H |
| 1339 | O | Ar91 | P1 | H | H | P8 | H | H | H |
| 1340 | O | Ar92 | P1 | H | H | P8 | H | H | H |
| 1341 | O | Ar93 | P1 | H | H | P8 | H | H | H |
| 1342 | O | Ar94 | P1 | H | H | P8 | H | H | H |
| 1343 | O | Ar95 | P1 | H | H | P8 | H | H | H |
| 1344 | O | Ar96 | P1 | H | H | P8 | H | H | H |
| 1345 | O | Ar97 | P1 | H | H | P8 | H | H | H |
| 1346 | O | Ar98 | P1 | H | H | P8 | H | H | H |
| 1347 | O | Ar99 | P1 | H | H | P8 | H | H | H |
| 1348 | O | Ar100 | P1 | H | H | P8 | H | H | H |
| 1349 | O | Ar101 | P1 | H | H | P8 | H | H | H |
| 1350 | O | Ar102 | P1 | H | H | P8 | H | H | H |
| 1351 | O | Ar103 | P1 | H | H | P8 | H | H | H |
| 1352 | O | Ar104 | P1 | H | H | P8 | H | H | H |
| 1353 | O | Ar1 | P2 | H | H | P8 | H | H | H |
| 1354 | O | Ar2 | P2 | H | H | P8 | H | H | H |
| 1355 | O | Ar3 | P2 | H | H | P8 | H | H | H |
| 1356 | O | Ar4 | P2 | H | H | P8 | H | H | H |
| 1357 | O | Ar5 | P2 | H | H | P8 | H | H | H |
| 1358 | O | Ar6 | P2 | H | H | P8 | H | H | H |
| 1359 | O | Ar7 | P2 | H | H | P8 | H | H | H |
| 1360 | O | Ar8 | P2 | H | H | P8 | H | H | H |
| 1361 | O | Ar9 | P2 | H | H | P8 | H | H | H |
| 1362 | O | Ar10 | P2 | H | H | P8 | H | H | H |
| 1363 | O | Ar11 | P2 | H | H | P8 | H | H | H |
| 1364 | O | Ar12 | P2 | H | H | P8 | H | H | H |
| 1365 | O | Ar13 | P2 | H | H | P8 | H | H | H |
| 1366 | O | Ar14 | P2 | H | H | P8 | H | H | H |
| 1367 | O | Ar15 | P2 | H | H | P8 | H | H | H |
| 1368 | O | Ar16 | P2 | H | H | P8 | H | H | H |
| 1369 | O | Ar17 | P2 | H | H | P8 | H | H | H |
| 1370 | O | Ar18 | P2 | H | H | P8 | H | H | H |
| 1371 | O | Ar19 | P2 | H | H | P8 | H | H | H |
| 1372 | O | Ar20 | P2 | H | H | P8 | H | H | H |
| 1373 | O | Ar21 | P2 | H | H | P8 | H | H | H |
| 1374 | O | Ar22 | P2 | H | H | P8 | H | H | H |
| 1375 | O | Ar23 | P2 | H | H | P8 | H | H | H |
| 1376 | O | Ar24 | P2 | H | H | P8 | H | H | H |
| 1377 | O | Ar25 | P2 | H | H | P8 | H | H | H |
| 1378 | O | Ar26 | P2 | H | H | P8 | H | H | H |
| 1379 | O | Ar27 | P2 | H | H | P8 | H | H | H |
| 1380 | O | Ar28 | P2 | H | H | P8 | H | H | H |
| 1381 | O | Ar29 | P2 | H | H | P8 | H | H | H |
| 1382 | O | Ar30 | P2 | H | H | P8 | H | H | H |
| 1383 | O | Ar31 | P2 | H | H | P8 | H | H | H |
| 1384 | O | Ar32 | P2 | H | H | P8 | H | H | H |
| 1385 | O | Ar33 | P2 | H | H | P8 | H | H | H |
| 1386 | O | Ar34 | P2 | H | H | P8 | H | H | H |
| 1387 | O | Ar35 | P2 | H | H | P8 | H | H | H |
| 1388 | O | Ar36 | P2 | H | H | P8 | H | H | H |
| 1389 | O | Ar37 | P2 | H | H | P8 | H | H | H |
| 1390 | O | Ar38 | P2 | H | H | P8 | H | H | H |
| 1391 | O | Ar39 | P2 | H | H | P8 | H | H | H |
| 1392 | O | Ar40 | P2 | H | H | P8 | H | H | H |
| 1393 | O | Ar41 | P2 | H | H | P8 | H | H | H |
| 1394 | O | Ar42 | P2 | H | H | P8 | H | H | H |
| 1395 | O | Ar43 | P2 | H | H | P8 | H | H | H |
| 1396 | O | Ar44 | P2 | H | H | P8 | H | H | H |
| 1397 | O | Ar45 | P2 | H | H | P8 | H | H | H |
| 1398 | O | Ar46 | P2 | H | H | P8 | H | H | H |
| 1399 | O | Ar47 | P2 | H | H | P8 | H | H | H |
| 1400 | O | Ar48 | P2 | H | H | P8 | H | H | H |
| 1401 | O | Ar49 | P2 | H | H | P8 | H | H | H |
| 1402 | O | Ar50 | P2 | H | H | P8 | H | H | H |
| 1403 | O | Ar51 | P2 | H | H | P8 | H | H | H |
| 1404 | O | Ar52 | P2 | H | H | P8 | H | H | H |
| 1405 | O | Ar53 | P2 | H | H | P8 | H | H | H |
| 1406 | O | Ar54 | P2 | H | H | P8 | H | H | H |
| 1407 | O | Ar55 | P2 | H | H | P8 | H | H | H |
| 1408 | O | Ar56 | P2 | H | H | P8 | H | H | H |
| 1409 | O | Ar57 | P2 | H | H | P8 | H | H | H |
| 1410 | O | Ar58 | P2 | H | H | P8 | H | H | H |
| 1411 | O | Ar59 | P2 | H | H | P8 | H | H | H |
| 1412 | O | Ar60 | P2 | H | H | P8 | H | H | H |
| 1413 | O | Ar61 | P2 | H | H | P8 | H | H | H |
| 1414 | O | Ar62 | P2 | H | H | P8 | H | H | H |
| 1415 | O | Ar63 | P2 | H | H | P8 | H | H | H |
| 1416 | O | Ar64 | P2 | H | H | P8 | H | H | H |
| 1417 | O | Ar65 | P2 | H | H | P8 | H | H | H |
| 1418 | O | Ar66 | P2 | H | H | P8 | H | H | H |
| 1419 | O | Ar67 | P2 | H | H | P8 | H | H | H |
| 1420 | O | Ar68 | P2 | H | H | P8 | H | H | H |
| 1421 | O | Ar69 | P2 | H | H | P8 | H | H | H |
| 1422 | O | Ar70 | P2 | H | H | P8 | H | H | H |
| 1423 | O | Ar71 | P2 | H | H | P8 | H | H | H |
| 1424 | O | Ar72 | P2 | H | H | P8 | H | H | H |
| 1425 | O | Ar73 | P2 | H | H | P8 | H | H | H |
| 1426 | O | Ar74 | P2 | H | H | P8 | H | H | H |
| 1427 | O | Ar75 | P2 | H | H | P8 | H | H | H |
| 1428 | O | Ar76 | P2 | H | H | P8 | H | H | H |
| 1429 | O | Ar77 | P2 | H | H | P8 | H | H | H |
| 1430 | O | Ar78 | P2 | H | H | P8 | H | H | H |
| 1431 | O | Ar79 | P2 | H | H | P8 | H | H | H |
| 1432 | O | Ar80 | P2 | H | H | P8 | H | H | H |
| 1433 | O | Ar81 | P2 | H | H | P8 | H | H | H |
| 1434 | O | Ar82 | P2 | H | H | P8 | H | H | H |
| 1435 | O | Ar83 | P2 | H | H | P8 | H | H | H |
| 1436 | O | Ar84 | P2 | H | H | P8 | H | H | H |
| 1437 | O | Ar85 | P2 | H | H | P8 | H | H | H |
| 1438 | O | Ar86 | P2 | H | H | P8 | H | H | H |
| 1439 | O | Ar87 | P2 | H | H | P8 | H | H | H |
| 1440 | O | Ar88 | P2 | H | H | P8 | H | H | H |
| 1441 | O | Ar89 | P2 | H | H | P8 | H | H | H |
| 1442 | O | Ar90 | P2 | H | H | P8 | H | H | H |
| 1443 | O | Ar91 | P2 | H | H | P8 | H | H | H |
| 1444 | O | Ar92 | P2 | H | H | P8 | H | H | H |
| 1445 | O | Ar93 | P2 | H | H | P8 | H | H | H |
| 1446 | O | Ar94 | P2 | H | H | P8 | H | H | H |
| 1447 | O | Ar95 | P2 | H | H | P8 | H | H | H |
| 1448 | O | Ar96 | P2 | H | H | P8 | H | H | H |
| 1449 | O | Ar97 | P2 | H | H | P8 | H | H | H |
| 1450 | O | Ar98 | P2 | H | H | P8 | H | H | H |
| 1451 | O | Ar99 | P2 | H | H | P8 | H | H | H |
| 1452 | O | Ar100 | P2 | H | H | P8 | H | H | H |
| 1453 | O | Ar101 | P2 | H | H | P8 | H | H | H |
| 1454 | O | Ar102 | P2 | H | H | P8 | H | H | H |
| 1455 | O | Ar103 | P2 | H | H | P8 | H | H | H |
| 1456 | O | Ar104 | P2 | H | H | P8 | H | H | H |
| 1457 | O | Ar1 | P1 | D | D | P8 | D | D | D |
| 1458 | O | Ar2 | P1 | D | D | P8 | D | D | D |
| 1459 | O | Ar3 | P1 | D | D | P8 | D | D | D |
| 1460 | O | Ar4 | P1 | D | D | P8 | D | D | D |
| 1461 | O | Ar5 | P1 | D | D | P8 | D | D | D |
| 1462 | O | Ar6 | P1 | D | D | P8 | D | D | D |
| 1463 | O | Ar7 | P1 | D | D | P8 | D | D | D |
| 1464 | O | Ar8 | P1 | D | D | P8 | D | D | D |
| 1465 | O | Ar9 | P1 | D | D | P8 | D | D | D |
| 1466 | O | Ar10 | P1 | D | D | P8 | D | D | D |
| 1467 | O | Ar11 | P1 | D | D | P8 | D | D | D |
| 1468 | O | Ar12 | P1 | D | D | P8 | D | D | D |
| 1469 | O | Ar13 | P1 | D | D | P8 | D | D | D |
| 1470 | O | Ar14 | P1 | D | D | P8 | D | D | D |
| 1471 | O | Ar15 | P1 | D | D | P8 | D | D | D |
| 1472 | O | Ar16 | P1 | D | D | P8 | D | D | D |
| 1473 | O | Ar17 | P1 | D | D | P8 | D | D | D |
| 1474 | O | Ar18 | P1 | D | D | P8 | D | D | D |
| 1475 | O | Ar19 | P1 | D | D | P8 | D | D | D |
| 1476 | O | Ar20 | P1 | D | D | P8 | D | D | D |
| 1477 | O | Ar21 | P1 | D | D | P8 | D | D | D |
| 1478 | O | Ar22 | P1 | D | D | P8 | D | D | D |
| 1479 | O | Ar23 | P1 | D | D | P8 | D | D | D |
| 1480 | O | Ar24 | P1 | D | D | P8 | D | D | D |
| 1481 | O | Ar25 | P1 | D | D | P8 | D | D | D |
| 1482 | O | Ar26 | P1 | D | D | P8 | D | D | D |
| 1483 | O | Ar27 | P1 | D | D | P8 | D | D | D |
| 1484 | O | Ar28 | P1 | D | D | P8 | D | D | D |
| 1485 | O | Ar29 | P1 | D | D | P8 | D | D | D |
| 1486 | O | Ar30 | P1 | D | D | P8 | D | D | D |
| 1487 | O | Ar31 | P1 | D | D | P8 | D | D | D |
| 1488 | O | Ar32 | P1 | D | D | P8 | D | D | D |
| 1489 | O | Ar33 | P1 | D | D | P8 | D | D | D |
| 1490 | O | Ar34 | P1 | D | D | P8 | D | D | D |
| 1491 | O | Ar35 | P1 | D | D | P8 | D | D | D |
| 1492 | O | Ar36 | P1 | D | D | P8 | D | D | D |
| 1493 | O | Ar37 | P1 | D | D | P8 | D | D | D |
| 1494 | O | Ar38 | P1 | D | D | P8 | D | D | D |
| 1495 | O | Ar39 | P1 | D | D | P8 | D | D | D |
| 1496 | O | Ar40 | P1 | D | D | P8 | D | D | D |
| 1497 | O | Ar41 | P1 | D | D | P8 | D | D | D |
| 1498 | O | Ar42 | P1 | D | D | P8 | D | D | D |
| 1499 | O | Ar43 | P1 | D | D | P8 | D | D | D |
| 1500 | O | Ar44 | P1 | D | D | P8 | D | D | D |
| 1501 | O | Ar45 | P1 | D | D | P8 | D | D | D |
| 1502 | O | Ar46 | P1 | D | D | P8 | D | D | D |
| 1503 | O | Ar47 | P1 | D | D | P8 | D | D | D |
| 1504 | O | Ar48 | P1 | D | D | P8 | D | D | D |
| 1505 | O | Ar49 | P1 | D | D | P8 | D | D | D |
| 1506 | O | Ar50 | P1 | D | D | P8 | D | D | D |
| 1507 | O | Ar51 | P1 | D | D | P8 | D | D | D |
| 1508 | O | Ar52 | P1 | D | D | P8 | D | D | D |
| 1509 | O | Ar53 | P1 | D | D | P8 | D | D | D |
| 1510 | O | Ar54 | P1 | D | D | P8 | D | D | D |
| 1511 | O | Ar55 | P1 | D | D | P8 | D | D | D |
| 1512 | O | Ar56 | P1 | D | D | P8 | D | D | D |
| 1513 | O | Ar57 | P1 | D | D | P8 | D | D | D |
| 1514 | O | Ar58 | P1 | D | D | P8 | D | D | D |
| 1515 | O | Ar59 | P1 | D | D | P8 | D | D | D |
| 1516 | O | Ar60 | P1 | D | D | P8 | D | D | D |
| 1517 | O | Ar61 | P1 | D | D | P8 | D | D | D |
| 1518 | O | Ar62 | P1 | D | D | P8 | D | D | D |
| 1519 | O | Ar63 | P1 | D | D | P8 | D | D | D |
| 1520 | O | Ar64 | P1 | D | D | P8 | D | D | D |
| 1521 | O | Ar65 | P1 | D | D | P8 | D | D | D |
| 1522 | O | Ar66 | P1 | D | D | P8 | D | D | D |
| 1523 | O | Ar67 | P1 | D | D | P8 | D | D | D |
| 1524 | O | Ar68 | P1 | D | D | P8 | D | D | D |
| 1525 | O | Ar69 | P1 | D | D | P8 | D | D | D |
| 1526 | O | Ar70 | P1 | D | D | P8 | D | D | D |
| 1527 | O | Ar71 | P1 | D | D | P8 | D | D | D |
| 1528 | O | Ar72 | P1 | D | D | P8 | D | D | D |
| 1529 | O | Ar73 | P1 | D | D | P8 | D | D | D |
| 1530 | O | Ar74 | P1 | D | D | P8 | D | D | D |
| 1531 | O | Ar75 | P1 | D | D | P8 | D | D | D |
| 1532 | O | Ar76 | P1 | D | D | P8 | D | D | D |
| 1533 | O | Ar77 | P1 | D | D | P8 | D | D | D |
| 1534 | O | Ar78 | P1 | D | D | P8 | D | D | D |
| 1535 | O | Ar79 | P1 | D | D | P8 | D | D | D |
| 1536 | O | Ar80 | P1 | D | D | P8 | D | D | D |
| 1537 | O | Ar81 | P1 | D | D | P8 | D | D | D |
| 1538 | O | Ar82 | P1 | D | D | P8 | D | D | D |
| 1539 | O | Ar83 | P1 | D | D | P8 | D | D | D |
| 1540 | O | Ar84 | P1 | D | D | P8 | D | D | D |
| 1541 | O | Ar85 | P1 | D | D | P8 | D | D | D |
| 1542 | O | Ar86 | P1 | D | D | P8 | D | D | D |
| 1543 | O | Ar87 | P1 | D | D | P8 | D | D | D |
| 1544 | O | Ar88 | P1 | D | D | P8 | D | D | D |
| 1545 | O | Ar89 | P1 | D | D | P8 | D | D | D |
| 1546 | O | Ar90 | P1 | D | D | P8 | D | D | D |
| 1547 | O | Ar91 | P1 | D | D | P8 | D | D | D |
| 1548 | O | Ar92 | P1 | D | D | P8 | D | D | D |
| 1549 | O | Ar93 | P1 | D | D | P8 | D | D | D |
| 1550 | O | Ar94 | P1 | D | D | P8 | D | D | D |
| 1551 | O | Ar95 | P1 | D | D | P8 | D | D | D |
| 1552 | O | Ar96 | P1 | D | D | P8 | D | D | D |
| 1553 | O | Ar97 | P1 | D | D | P8 | D | D | D |
| 1554 | O | Ar98 | P1 | D | D | P8 | D | D | D |
| 1555 | O | Ar99 | P1 | D | D | P8 | D | D | D |
| 1556 | O | Ar100 | P1 | D | D | P8 | D | D | D |
| 1557 | O | Ar101 | P1 | D | D | P8 | D | D | D |
| 1558 | O | Ar102 | P1 | D | D | P8 | D | D | D |
| 1559 | O | Ar103 | P1 | D | D | P8 | D | D | D |
| 1560 | O | Ar104 | P1 | D | D | P8 | D | D | D |
| 1561 | O | Ar1 | P2 | D | D | P8 | D | D | D |
| 1562 | O | Ar2 | P2 | D | D | P8 | D | D | D |
| 1563 | O | Ar3 | P2 | D | D | P8 | D | D | D |
| 1564 | O | Ar4 | P2 | D | D | P8 | D | D | D |
| 1565 | O | Ar5 | P2 | D | D | P8 | D | D | D |
| 1566 | O | Ar6 | P2 | D | D | P8 | D | D | D |
| 1567 | O | Ar7 | P2 | D | D | P8 | D | D | D |
| 1568 | O | Ar8 | P2 | D | D | P8 | D | D | D |
| 1569 | O | Ar9 | P2 | D | D | P8 | D | D | D |
| 1570 | O | Ar10 | P2 | D | D | P8 | D | D | D |
| 1571 | O | Ar11 | P2 | D | D | P8 | D | D | D |
| 1572 | O | Ar12 | P2 | D | D | P8 | D | D | D |
| 1573 | O | Ar13 | P2 | D | D | P8 | D | D | D |
| 1574 | O | Ar14 | P2 | D | D | P8 | D | D | D |
| 1575 | O | Ar15 | P2 | D | D | P8 | D | D | D |
| 1576 | O | Ar16 | P2 | D | D | P8 | D | D | D |
| 1577 | O | Ar17 | P2 | D | D | P8 | D | D | D |
| 1578 | O | Ar18 | P2 | D | D | P8 | D | D | D |
| 1579 | O | Ar19 | P2 | D | D | P8 | D | D | D |
| 1580 | O | Ar20 | P2 | D | D | P8 | D | D | D |
| 1581 | O | Ar21 | P2 | D | D | P8 | D | D | D |
| 1582 | O | Ar22 | P2 | D | D | P8 | D | D | D |
| 1583 | O | Ar23 | P2 | D | D | P8 | D | D | D |
| 1584 | O | Ar24 | P2 | D | D | P8 | D | D | D |
| 1585 | O | Ar25 | P2 | D | D | P8 | D | D | D |
| 1586 | O | Ar26 | P2 | D | D | P8 | D | D | D |
| 1587 | O | Ar27 | P2 | D | D | P8 | D | D | D |
| 1588 | O | Ar28 | P2 | D | D | P8 | D | D | D |
| 1589 | O | Ar29 | P2 | D | D | P8 | D | D | D |
| 1590 | O | Ar30 | P2 | D | D | P8 | D | D | D |
| 1591 | O | Ar31 | P2 | D | D | P8 | D | D | D |
| 1592 | O | Ar32 | P2 | D | D | P8 | D | D | D |
| 1593 | O | Ar33 | P2 | D | D | P8 | D | D | D |
| 1594 | O | Ar34 | P2 | D | D | P8 | D | D | D |
| 1595 | O | Ar35 | P2 | D | D | P8 | D | D | D |
| 1596 | O | Ar36 | P2 | D | D | P8 | D | D | D |
| 1597 | O | Ar37 | P2 | D | D | P8 | D | D | D |
| 1598 | O | Ar38 | P2 | D | D | P8 | D | D | D |
| 1599 | O | Ar39 | P2 | D | D | P8 | D | D | D |
| 1600 | O | Ar40 | P2 | D | D | P8 | D | D | D |
| 1601 | O | Ar41 | P2 | D | D | P8 | D | D | D |
| 1602 | O | Ar42 | P2 | D | D | P8 | D | D | D |
| 1603 | O | Ar43 | P2 | D | D | P8 | D | D | D |
| 1604 | O | Ar44 | P2 | D | D | P8 | D | D | D |
| 1605 | O | Ar45 | P2 | D | D | P8 | D | D | D |
| 1606 | O | Ar46 | P2 | D | D | P8 | D | D | D |
| 1607 | O | Ar47 | P2 | D | D | P8 | D | D | D |
| 1608 | O | Ar48 | P2 | D | D | P8 | D | D | D |
| 1609 | O | Ar49 | P2 | D | D | P8 | D | D | D |
| 1610 | O | Ar50 | P2 | D | D | P8 | D | D | D |
| 1611 | O | Ar51 | P2 | D | D | P8 | D | D | D |
| 1612 | O | Ar52 | P2 | D | D | P8 | D | D | D |
| 1613 | O | Ar53 | P2 | D | D | P8 | D | D | D |
| 1614 | O | Ar54 | P2 | D | D | P8 | D | D | D |
| 1615 | O | Ar55 | P2 | D | D | P8 | D | D | D |
| 1616 | O | Ar56 | P2 | D | D | P8 | D | D | D |
| 1617 | O | Ar57 | P2 | D | D | P8 | D | D | D |
| 1618 | O | Ar58 | P2 | D | D | P8 | D | D | D |
| 1619 | O | Ar59 | P2 | D | D | P8 | D | D | D |
| 1620 | O | Ar60 | P2 | D | D | P8 | D | D | D |
| 1621 | O | Ar61 | P2 | D | D | P8 | D | D | D |
| 1622 | O | Ar62 | P2 | D | D | P8 | D | D | D |
| 1623 | O | Ar63 | P2 | D | D | P8 | D | D | D |
| 1624 | O | Ar64 | P2 | D | D | P8 | D | D | D |
| 1625 | O | Ar65 | P2 | D | D | P8 | D | D | D |
| 1626 | O | Ar66 | P2 | D | D | P8 | D | D | D |
| 1627 | O | Ar67 | P2 | D | D | P8 | D | D | D |
| 1628 | O | Ar68 | P2 | D | D | P8 | D | D | D |
| 1629 | O | Ar69 | P2 | D | D | P8 | D | D | D |
| 1630 | O | Ar70 | P2 | D | D | P8 | D | D | D |
| 1631 | O | Ar71 | P2 | D | D | P8 | D | D | D |
| 1632 | O | Ar72 | P2 | D | D | P8 | D | D | D |
| 1633 | O | Ar73 | P2 | D | D | P8 | D | D | D |
| 1634 | O | Ar74 | P2 | D | D | P8 | D | D | D |
| 1635 | O | Ar75 | P2 | D | D | P8 | D | D | D |
| 1636 | O | Ar76 | P2 | D | D | P8 | D | D | D |
| 1637 | O | Ar77 | P2 | D | D | P8 | D | D | D |
| 1638 | O | Ar78 | P2 | D | D | P8 | D | D | D |
| 1639 | O | Ar79 | P2 | D | D | P8 | D | D | D |
| 1640 | O | Ar80 | P2 | D | D | P8 | D | D | D |
| 1641 | O | Ar81 | P2 | D | D | P8 | D | D | D |
| 1642 | O | Ar82 | P2 | D | D | P8 | D | D | D |
| 1643 | O | Ar83 | P2 | D | D | P8 | D | D | D |
| 1644 | O | Ar84 | P2 | D | D | P8 | D | D | D |
| 1645 | O | Ar85 | P2 | D | D | P8 | D | D | D |
| 1646 | O | Ar86 | P2 | D | D | P8 | D | D | D |
| 1647 | O | Ar87 | P2 | D | D | P8 | D | D | D |
| 1648 | O | Ar88 | P2 | D | D | P8 | D | D | D |
| 1649 | O | Ar89 | P2 | D | D | P8 | D | D | D |
| 1650 | O | Ar90 | P2 | D | D | P8 | D | D | D |
| 1651 | O | Ar91 | P2 | D | D | P8 | D | D | D |
| 1652 | O | Ar92 | P2 | D | D | P8 | D | D | D |
| 1653 | O | Ar93 | P2 | D | D | P8 | D | D | D |
| 1654 | O | Ar94 | P2 | D | D | P8 | D | D | D |
| 1655 | O | Ar95 | P2 | D | D | P8 | D | D | D |
| 1656 | O | Ar96 | P2 | D | D | P8 | D | D | D |
| 1657 | O | Ar97 | P2 | D | D | P8 | D | D | D |
| 1658 | O | Ar98 | P2 | D | D | P8 | D | D | D |
| 1659 | O | Ar99 | P2 | D | D | P8 | D | D | D |
| 1660 | O | Ar100 | P2 | D | D | P8 | D | D | D |
| 1661 | O | Ar101 | P2 | D | D | P8 | D | D | D |
| 1662 | O | Ar102 | P2 | D | D | P8 | D | D | D |
| 1663 | O | Ar103 | P2 | D | D | P8 | D | D | D |
| 1664 | O | Ar104 | P2 | D | D | P8 | D | D | D |
| 1665 | O | Ar1 | P11 | H | H | P8 | H | H | H |
| 1666 | O | Ar2 | P11 | H | H | P8 | H | H | H |
| 1667 | O | Ar3 | P11 | H | H | P8 | H | H | H |
| 1668 | O | Ar4 | P11 | H | H | P8 | H | H | H |
| 1669 | O | Ar5 | P11 | H | H | P8 | H | H | H |
| 1670 | O | Ar6 | P11 | H | H | P8 | H | H | H |
| 1671 | O | Ar7 | P11 | H | H | P8 | H | H | H |
| 1672 | O | Ar8 | P11 | H | H | P8 | H | H | H |
| 1673 | O | Ar9 | P11 | H | H | P8 | H | H | H |
| 1674 | O | Ar10 | P11 | H | H | P8 | H | H | H |
| 1675 | O | Ar11 | P11 | H | H | P8 | H | H | H |
| 1676 | O | Ar12 | P11 | H | H | P8 | H | H | H |
| 1677 | O | Ar13 | P11 | H | H | P8 | H | H | H |
| 1678 | O | Ar14 | P11 | H | H | P8 | H | H | H |
| 1679 | O | Ar15 | P11 | H | H | P8 | H | H | H |
| 1680 | O | Ar16 | P11 | H | H | P8 | H | H | H |
| 1681 | O | Ar17 | P11 | H | H | P8 | H | H | H |
| 1682 | O | Ar18 | P11 | H | H | P8 | H | H | H |
| 1683 | O | Ar19 | P11 | H | H | P8 | H | H | H |
| 1684 | O | Ar20 | P11 | H | H | P8 | H | H | H |
| 1685 | O | Ar21 | P11 | H | H | P8 | H | H | H |
| 1686 | O | Ar22 | P11 | H | H | P8 | H | H | H |
| 1687 | O | Ar23 | P11 | H | H | P8 | H | H | H |
| 1688 | O | Ar24 | P11 | H | H | P8 | H | H | H |
| 1689 | O | Ar25 | P11 | H | H | P8 | H | H | H |
| 1690 | O | Ar26 | P11 | H | H | P8 | H | H | H |
| 1691 | O | Ar27 | P11 | H | H | P8 | H | H | H |
| 1692 | O | Ar28 | P11 | H | H | P8 | H | H | H |
| 1693 | O | Ar29 | P11 | H | H | P8 | H | H | H |
| 1694 | O | Ar30 | P11 | H | H | P8 | H | H | H |
| 1695 | O | Ar31 | P11 | H | H | P8 | H | H | H |
| 1696 | O | Ar32 | P11 | H | H | P8 | H | H | H |
| 1697 | O | Ar33 | P11 | H | H | P8 | H | H | H |
| 1698 | O | Ar34 | P11 | H | H | P8 | H | H | H |
| 1699 | O | Ar35 | P11 | H | H | P8 | H | H | H |
| 1700 | O | Ar36 | P11 | H | H | P8 | H | H | H |
| 1701 | O | Ar37 | P11 | H | H | P8 | H | H | H |
| 1702 | O | Ar38 | P11 | H | H | P8 | H | H | H |
| 1703 | O | Ar39 | P11 | H | H | P8 | H | H | H |
| 1704 | O | Ar40 | P11 | H | H | P8 | H | H | H |
| 1705 | O | Ar41 | P11 | H | H | P8 | H | H | H |
| 1706 | O | Ar42 | P11 | H | H | P8 | H | H | H |
| 1707 | O | Ar43 | P11 | H | H | P8 | H | H | H |
| 1708 | O | Ar44 | P11 | H | H | P8 | H | H | H |
| 1709 | O | Ar45 | P11 | H | H | P8 | H | H | H |
| 1710 | O | Ar46 | P11 | H | H | P8 | H | H | H |
| 1711 | O | Ar47 | P11 | H | H | P8 | H | H | H |
| 1712 | O | Ar48 | P11 | H | H | P8 | H | H | H |
| 1713 | O | Ar49 | P11 | H | H | P8 | H | H | H |
| 1714 | O | Ar50 | P11 | H | H | P8 | H | H | H |
| 1715 | O | Ar51 | P11 | H | H | P8 | H | H | H |
| 1716 | O | Ar52 | P11 | H | H | P8 | H | H | H |
| 1717 | O | Ar53 | P11 | H | H | P8 | H | H | H |
| 1718 | O | Ar54 | P11 | H | H | P8 | H | H | H |
| 1719 | O | Ar55 | P11 | H | H | P8 | H | H | H |
| 1720 | O | Ar56 | P11 | H | H | P8 | H | H | H |
| 1721 | O | Ar57 | P11 | H | H | P8 | H | H | H |
| 1722 | O | Ar58 | P11 | H | H | P8 | H | H | H |
| 1723 | O | Ar59 | P11 | H | H | P8 | H | H | H |
| 1724 | O | Ar60 | P11 | H | H | P8 | H | H | H |
| 1725 | O | Ar61 | P11 | H | H | P8 | H | H | H |
| 1726 | O | Ar62 | P11 | H | H | P8 | H | H | H |
| 1727 | O | Ar63 | P11 | H | H | P8 | H | H | H |
| 1728 | O | Ar64 | P11 | H | H | P8 | H | H | H |
| 1729 | O | Ar65 | P11 | H | H | P8 | H | H | H |
| 1730 | O | Ar66 | P11 | H | H | P8 | H | H | H |
| 1731 | O | Ar67 | P11 | H | H | P8 | H | H | H |
| 1732 | O | Ar68 | P11 | H | H | P8 | H | H | H |
| 1733 | O | Ar69 | P11 | H | H | P8 | H | H | H |
| 1734 | O | Ar70 | P11 | H | H | P8 | H | H | H |
| 1735 | O | Ar71 | P11 | H | H | P8 | H | H | H |
| 1736 | O | Ar72 | P11 | H | H | P8 | H | H | H |
| 1737 | O | Ar73 | P11 | H | H | P8 | H | H | H |
| 1738 | O | Ar74 | P11 | H | H | P8 | H | H | H |
| 1739 | O | Ar75 | P11 | H | H | P8 | H | H | H |
| 1740 | O | Ar76 | P11 | H | H | P8 | H | H | H |
| 1741 | O | Ar77 | P11 | H | H | P8 | H | H | H |
| 1742 | O | Ar78 | P11 | H | H | P8 | H | H | H |
| 1743 | O | Ar79 | P11 | H | H | P8 | H | H | H |
| 1744 | O | Ar80 | P11 | H | H | P8 | H | H | H |
| 1745 | O | Ar81 | P11 | H | H | P8 | H | H | H |
| 1746 | O | Ar82 | P11 | H | H | P8 | H | H | H |
| 1747 | O | Ar83 | P11 | H | H | P8 | H | H | H |
| 1748 | O | Ar84 | P11 | H | H | P8 | H | H | H |
| 1749 | O | Ar85 | P11 | H | H | P8 | H | H | H |
| 1750 | O | Ar86 | P11 | H | H | P8 | H | H | H |
| 1751 | O | Ar87 | P11 | H | H | P8 | H | H | H |
| 1752 | O | Ar88 | P11 | H | H | P8 | H | H | H |
| 1753 | O | Ar89 | P11 | H | H | P8 | H | H | H |
| 1754 | O | Ar90 | P11 | H | H | P8 | H | H | H |
| 1755 | O | Ar91 | P11 | H | H | P8 | H | H | H |
| 1756 | O | Ar92 | P11 | H | H | P8 | H | H | H |
| 1757 | O | Ar93 | P11 | H | H | P8 | H | H | H |
| 1758 | O | Ar94 | P11 | H | H | P8 | H | H | H |
| 1759 | O | Ar95 | P11 | H | H | P8 | H | H | H |
| 1760 | O | Ar96 | P11 | H | H | P8 | H | H | H |
| 1761 | O | Ar97 | P11 | H | H | P8 | H | H | H |
| 1762 | O | Ar98 | P11 | H | H | P8 | H | H | H |
| 1763 | O | Ar99 | P11 | H | H | P8 | H | H | H |
| 1764 | O | Ar100 | P11 | H | H | P8 | H | H | H |
| 1765 | O | Ar101 | P11 | H | H | P8 | H | H | H |
| 1766 | O | Ar102 | P11 | H | H | P8 | H | H | H |
| 1767 | O | Ar103 | P11 | H | H | P8 | H | H | H |
| 1768 | O | Ar104 | P11 | H | H | P8 | H | H | H |
| 1769 | O | Ar1 | P12 | H | H | P8 | H | H | H |
| 1770 | O | Ar2 | P12 | H | H | P8 | H | H | H |
| 1771 | O | Ar3 | P12 | H | H | P8 | H | H | H |
| 1772 | O | Ar4 | P12 | H | H | P8 | H | H | H |
| 1773 | O | Ar5 | P12 | H | H | P8 | H | H | H |
| 1774 | O | Ar6 | P12 | H | H | P8 | H | H | H |
| 1775 | O | Ar7 | P12 | H | H | P8 | H | H | H |
| 1776 | O | Ar8 | P12 | H | H | P8 | H | H | H |
| 1777 | O | Ar9 | P12 | H | H | P8 | H | H | H |
| 1778 | O | Ar10 | P12 | H | H | P8 | H | H | H |
| 1779 | O | Ar11 | P12 | H | H | P8 | H | H | H |
| 1780 | O | Ar12 | P12 | H | H | P8 | H | H | H |
| 1781 | O | Ar13 | P12 | H | H | P8 | H | H | H |
| 1782 | O | Ar14 | P12 | H | H | P8 | H | H | H |
| 1783 | O | Ar15 | P12 | H | H | P8 | H | H | H |
| 1784 | O | Ar16 | P12 | H | H | P8 | H | H | H |
| 1785 | O | Ar17 | P12 | H | H | P8 | H | H | H |
| 1786 | O | Ar18 | P12 | H | H | P8 | H | H | H |
| 1787 | O | Ar19 | P12 | H | H | P8 | H | H | H |
| 1788 | O | Ar20 | P12 | H | H | P8 | H | H | H |
| 1789 | O | Ar21 | P12 | H | H | P8 | H | H | H |
| 1790 | O | Ar22 | P12 | H | H | P8 | H | H | H |
| 1791 | O | Ar23 | P12 | H | H | P8 | H | H | H |
| 1792 | O | Ar24 | P12 | H | H | P8 | H | H | H |
| 1793 | O | Ar25 | P12 | H | H | P8 | H | H | H |
| 1794 | O | Ar26 | P12 | H | H | P8 | H | H | H |
| 1795 | O | Ar27 | P12 | H | H | P8 | H | H | H |
| 1796 | O | Ar28 | P12 | H | H | P8 | H | H | H |
| 1797 | O | Ar29 | P12 | H | H | P8 | H | H | H |
| 1798 | O | Ar30 | P12 | H | H | P8 | H | H | H |
| 1799 | O | Ar31 | P12 | H | H | P8 | H | H | H |
| 1800 | O | Ar32 | P12 | H | H | P8 | H | H | H |
| 1801 | O | Ar33 | P12 | H | H | P8 | H | H | H |
| 1802 | O | Ar34 | P12 | H | H | P8 | H | H | H |
| 1803 | O | Ar35 | P12 | H | H | P8 | H | H | H |
| 1804 | O | Ar36 | P12 | H | H | P8 | H | H | H |
| 1805 | O | Ar37 | P12 | H | H | P8 | H | H | H |
| 1806 | O | Ar38 | P12 | H | H | P8 | H | H | H |
| 1807 | O | Ar39 | P12 | H | H | P8 | H | H | H |
| 1808 | O | Ar40 | P12 | H | H | P8 | H | H | H |
| 1809 | O | Ar41 | P12 | H | H | P8 | H | H | H |
| 1810 | O | Ar42 | P12 | H | H | P8 | H | H | H |
| 1811 | O | Ar43 | P12 | H | H | P8 | H | H | H |
| 1812 | O | Ar44 | P12 | H | H | P8 | H | H | H |
| 1813 | O | Ar45 | P12 | H | H | P8 | H | H | H |
| 1814 | O | Ar46 | P12 | H | H | P8 | H | H | H |
| 1815 | O | Ar47 | P12 | H | H | P8 | H | H | H |
| 1816 | O | Ar48 | P12 | H | H | P8 | H | H | H |
| 1817 | O | Ar49 | P12 | H | H | P8 | H | H | H |
| 1818 | O | Ar50 | P12 | H | H | P8 | H | H | H |
| 1819 | O | Ar51 | P12 | H | H | P8 | H | H | H |
| 1820 | O | Ar52 | P12 | H | H | P8 | H | H | H |
| 1821 | O | Ar53 | P12 | H | H | P8 | H | H | H |
| 1822 | O | Ar54 | P12 | H | H | P8 | H | H | H |
| 1823 | O | Ar55 | P12 | H | H | P8 | H | H | H |
| 1824 | O | Ar56 | P12 | H | H | P8 | H | H | H |
| 1825 | O | Ar57 | P12 | H | H | P8 | H | H | H |
| 1826 | O | Ar58 | P12 | H | H | P8 | H | H | H |
| 1827 | O | Ar59 | P12 | H | H | P8 | H | H | H |
| 1828 | O | Ar60 | P12 | H | H | P8 | H | H | H |
| 1829 | O | Ar61 | P12 | H | H | P8 | H | H | H |
| 1830 | O | Ar62 | P12 | H | H | P8 | H | H | H |
| 1831 | O | Ar63 | P12 | H | H | P8 | H | H | H |
| 1832 | O | Ar64 | P12 | H | H | P8 | H | H | H |
| 1833 | O | Ar65 | P12 | H | H | P8 | H | H | H |
| 1834 | O | Ar66 | P12 | H | H | P8 | H | H | H |
| 1835 | O | Ar67 | P12 | H | H | P8 | H | H | H |
| 1836 | O | Ar68 | P12 | H | H | P8 | H | H | H |
| 1837 | O | Ar69 | P12 | H | H | P8 | H | H | H |
| 1838 | O | Ar70 | P12 | H | H | P8 | H | H | H |
| 1839 | O | Ar71 | P12 | H | H | P8 | H | H | H |
| 1840 | O | Ar72 | P12 | H | H | P8 | H | H | H |
| 1841 | O | Ar73 | P12 | H | H | P8 | H | H | H |
| 1842 | O | Ar74 | P12 | H | H | P8 | H | H | H |
| 1843 | O | Ar75 | P12 | H | H | P8 | H | H | H |
| 1844 | O | Ar76 | P12 | H | H | P8 | H | H | H |
| 1845 | O | Ar77 | P12 | H | H | P8 | H | H | H |
| 1846 | O | Ar78 | P12 | H | H | P8 | H | H | H |
| 1847 | O | Ar79 | P12 | H | H | P8 | H | H | H |
| 1848 | O | Ar80 | P12 | H | H | P8 | H | H | H |
| 1849 | O | Ar81 | P12 | H | H | P8 | H | H | H |
| 1850 | O | Ar82 | P12 | H | H | P8 | H | H | H |
| 1851 | O | Ar83 | P12 | H | H | P8 | H | H | H |
| 1852 | O | Ar84 | P12 | H | H | P8 | H | H | H |
| 1853 | O | Ar85 | P12 | H | H | P8 | H | H | H |
| 1854 | O | Ar86 | P12 | H | H | P8 | H | H | H |
| 1855 | O | Ar87 | P12 | H | H | P8 | H | H | H |
| 1856 | O | Ar88 | P12 | H | H | P8 | H | H | H |
| 1857 | O | Ar89 | P12 | H | H | P8 | H | H | H |
| 1858 | O | Ar90 | P12 | H | H | P8 | H | H | H |
| 1859 | O | Ar91 | P12 | H | H | P8 | H | H | H |
| 1860 | O | Ar92 | P12 | H | H | P8 | H | H | H |
| 1861 | O | Ar93 | P12 | H | H | P8 | H | H | H |
| 1862 | O | Ar94 | P12 | H | H | P8 | H | H | H |
| 1863 | O | Ar95 | P12 | H | H | P8 | H | H | H |
| 1864 | O | Ar96 | P12 | H | H | P8 | H | H | H |
| 1865 | O | Ar97 | P12 | H | H | P8 | H | H | H |
| 1866 | O | Ar98 | P12 | H | H | P8 | H | H | H |
| 1867 | O | Ar99 | P12 | H | H | P8 | H | H | H |
| 1868 | O | Ar100 | P12 | H | H | P8 | H | H | H |
| 1869 | O | Ar101 | P12 | H | H | P8 | H | H | H |
| 1870 | O | Ar102 | P12 | H | H | P8 | H | H | H |
| 1871 | O | Ar103 | P12 | H | H | P8 | H | H | H |
| 1872 | O | Ar104 | P12 | H | H | P8 | H | H | H |
| 1873 | O | Ar1 | P1 | H | H | P11 | H | H | H |
| 1874 | O | Ar2 | P1 | H | H | P11 | H | H | H |
| 1875 | O | Ar3 | P1 | H | H | P11 | H | H | H |
| 1876 | O | Ar4 | P1 | H | H | P11 | H | H | H |
| 1877 | O | Ar5 | P1 | H | H | P11 | H | H | H |
| 1878 | O | Ar6 | P1 | H | H | P11 | H | H | H |
| 1879 | O | Ar7 | P1 | H | H | P11 | H | H | H |
| 1880 | O | Ar8 | P1 | H | H | P11 | H | H | H |
| 1881 | O | Ar9 | P1 | H | H | P11 | H | H | H |
| 1882 | O | Ar10 | P1 | H | H | P11 | H | H | H |
| 1883 | O | Ar11 | P1 | H | H | P11 | H | H | H |
| 1884 | O | Ar12 | P1 | H | H | P11 | H | H | H |
| 1885 | O | Ar13 | P1 | H | H | P11 | H | H | H |
| 1886 | O | Ar14 | P1 | H | H | P11 | H | H | H |
| 1887 | O | Ar15 | P1 | H | H | P11 | H | H | H |
| 1888 | O | Ar16 | P1 | H | H | P11 | H | H | H |
| 1889 | O | Ar17 | P1 | H | H | P11 | H | H | H |
| 1890 | O | Ar18 | P1 | H | H | P11 | H | H | H |
| 1891 | O | Ar19 | P1 | H | H | P11 | H | H | H |
| 1892 | O | Ar20 | P1 | H | H | P11 | H | H | H |
| 1893 | O | Ar21 | P1 | H | H | P11 | H | H | H |
| 1894 | O | Ar22 | P1 | H | H | P11 | H | H | H |
| 1895 | O | Ar23 | P1 | H | H | P11 | H | H | H |
| 1896 | O | Ar24 | P1 | H | H | P11 | H | H | H |
| 1897 | O | Ar25 | P1 | H | H | P11 | H | H | H |
| 1898 | O | Ar26 | P1 | H | H | P11 | H | H | H |
| 1899 | O | Ar27 | P1 | H | H | P11 | H | H | H |
| 1900 | O | Ar28 | P1 | H | H | P11 | H | H | H |
| 1901 | O | Ar29 | P1 | H | H | P11 | H | H | H |
| 1902 | O | Ar30 | P1 | H | H | P11 | H | H | H |
| 1903 | O | Ar31 | P1 | H | H | P11 | H | H | H |
| 1904 | O | Ar32 | P1 | H | H | P11 | H | H | H |
| 1905 | O | Ar33 | P1 | H | H | P11 | H | H | H |
| 1906 | O | Ar34 | P1 | H | H | P11 | H | H | H |
| 1907 | O | Ar35 | P1 | H | H | P11 | H | H | H |
| 1908 | O | Ar36 | P1 | H | H | P11 | H | H | H |
| 1909 | O | Ar37 | P1 | H | H | P11 | H | H | H |
| 1910 | O | Ar38 | P1 | H | H | P11 | H | H | H |
| 1911 | O | Ar39 | P1 | H | H | P11 | H | H | H |
| 1912 | O | Ar40 | P1 | H | H | P11 | H | H | H |
| 1913 | O | Ar41 | P1 | H | H | P11 | H | H | H |
| 1914 | O | Ar42 | P1 | H | H | P11 | H | H | H |
| 1915 | O | Ar43 | P1 | H | H | P11 | H | H | H |
| 1916 | O | Ar44 | P1 | H | H | P11 | H | H | H |
| 1917 | O | Ar45 | P1 | H | H | P11 | H | H | H |
| 1918 | O | Ar46 | P1 | H | H | P11 | H | H | H |
| 1919 | O | Ar47 | P1 | H | H | P11 | H | H | H |
| 1920 | O | Ar48 | P1 | H | H | P11 | H | H | H |
| 1921 | O | Ar49 | P1 | H | H | P11 | H | H | H |
| 1922 | O | Ar50 | P1 | H | H | P11 | H | H | H |
| 1923 | O | Ar51 | P1 | H | H | P11 | H | H | H |
| 1924 | O | Ar52 | P1 | H | H | P11 | H | H | H |
| 1925 | O | Ar53 | P1 | H | H | P11 | H | H | H |
| 1926 | O | Ar54 | P1 | H | H | P11 | H | H | H |
| 1927 | O | Ar55 | P1 | H | H | P11 | H | H | H |
| 1928 | O | Ar56 | P1 | H | H | P11 | H | H | H |
| 1929 | O | Ar57 | P1 | H | H | P11 | H | H | H |
| 1930 | O | Ar58 | P1 | H | H | P11 | H | H | H |
| 1931 | O | Ar59 | P1 | H | H | P11 | H | H | H |
| 1932 | O | Ar60 | P1 | H | H | P11 | H | H | H |
| 1933 | O | Ar61 | P1 | H | H | P11 | H | H | H |
| 1934 | O | Ar62 | P1 | H | H | P11 | H | H | H |
| 1935 | O | Ar63 | P1 | H | H | P11 | H | H | H |
| 1936 | O | Ar64 | P1 | H | H | P11 | H | H | H |
| 1937 | O | Ar65 | P1 | H | H | P11 | H | H | H |
| 1938 | O | Ar66 | P1 | H | H | P11 | H | H | H |
| 1939 | O | Ar67 | P1 | H | H | P11 | H | H | H |
| 1940 | O | Ar68 | P1 | H | H | P11 | H | H | H |
| 1941 | O | Ar69 | P1 | H | H | P11 | H | H | H |
| 1942 | O | Ar70 | P1 | H | H | P11 | H | H | H |
| 1943 | O | Ar71 | P1 | H | H | P11 | H | H | H |
| 1944 | O | Ar72 | P1 | H | H | P11 | H | H | H |
| 1945 | O | Ar73 | P1 | H | H | P11 | H | H | H |
| 1946 | O | Ar74 | P1 | H | H | P11 | H | H | H |
| 1947 | O | Ar75 | P1 | H | H | P11 | H | H | H |
| 1948 | O | Ar76 | P1 | H | H | P11 | H | H | H |
| 1949 | O | Ar77 | P1 | H | H | P11 | H | H | H |
| 1950 | O | Ar78 | P1 | H | H | P11 | H | H | H |
| 1951 | O | Ar79 | P1 | H | H | P11 | H | H | H |
| 1952 | O | Ar80 | P1 | H | H | P11 | H | H | H |
| 1953 | O | Ar81 | P1 | H | H | P11 | H | H | H |
| 1954 | O | Ar82 | P1 | H | H | P11 | H | H | H |
| 1955 | O | Ar83 | P1 | H | H | P11 | H | H | H |
| 1956 | O | Ar84 | P1 | H | H | P11 | H | H | H |
| 1957 | O | Ar85 | P1 | H | H | P11 | H | H | H |
| 1958 | O | Ar86 | P1 | H | H | P11 | H | H | H |
| 1959 | O | Ar87 | P1 | H | H | P11 | H | H | H |
| 1960 | O | Ar88 | P1 | H | H | P11 | H | H | H |
| 1961 | O | Ar89 | P1 | H | H | P11 | H | H | H |
| 1962 | O | Ar90 | P1 | H | H | P11 | H | H | H |
| 1963 | O | Ar91 | P1 | H | H | P11 | H | H | H |
| 1964 | O | Ar92 | P1 | H | H | P11 | H | H | H |
| 1965 | O | Ar93 | P1 | H | H | P11 | H | H | H |
| 1966 | O | Ar94 | P1 | H | H | P11 | H | H | H |
| 1967 | O | Ar95 | P1 | H | H | P11 | H | H | H |
| 1968 | O | Ar96 | P1 | H | H | P11 | H | H | H |
| 1969 | O | Ar97 | P1 | H | H | P11 | H | H | H |
| 1970 | O | Ar98 | P1 | H | H | P11 | H | H | H |
| 1971 | O | Ar99 | P1 | H | H | P11 | H | H | H |
| 1972 | O | Ar100 | P1 | H | H | P11 | H | H | H |
| 1973 | O | Ar101 | P1 | H | H | P11 | H | H | H |
| 1974 | O | Ar102 | P1 | H | H | P11 | H | H | H |
| 1975 | O | Ar103 | P1 | H | H | P11 | H | H | H |
| 1976 | O | Ar104 | P1 | H | H | P11 | H | H | H |
| 1977 | O | Ar1 | P2 | H | H | P11 | H | H | H |
| 1978 | O | Ar2 | P2 | H | H | P11 | H | H | H |
| 1979 | O | Ar3 | P2 | H | H | P11 | H | H | H |
| 1980 | O | Ar4 | P2 | H | H | P11 | H | H | H |
| 1981 | O | Ar5 | P2 | H | H | P11 | H | H | H |
| 1982 | O | Ar6 | P2 | H | H | P11 | H | H | H |
| 1983 | O | Ar7 | P2 | H | H | P11 | H | H | H |
| 1984 | O | Ar8 | P2 | H | H | P11 | H | H | H |
| 1985 | O | Ar9 | P2 | H | H | P11 | H | H | H |
| 1986 | O | Ar10 | P2 | H | H | P11 | H | H | H |
| 1987 | O | Ar11 | P2 | H | H | P11 | H | H | H |
| 1988 | O | Ar12 | P2 | H | H | P11 | H | H | H |
| 1989 | O | Ar13 | P2 | H | H | P11 | H | H | H |
| 1990 | O | Ar14 | P2 | H | H | P11 | H | H | H |
| 1991 | O | Ar15 | P2 | H | H | P11 | H | H | H |
| 1992 | O | Ar16 | P2 | H | H | P11 | H | H | H |
| 1993 | O | Ar17 | P2 | H | H | P11 | H | H | H |
| 1994 | O | Ar18 | P2 | H | H | P11 | H | H | H |
| 1995 | O | Ar19 | P2 | H | H | P11 | H | H | H |
| 1996 | O | Ar20 | P2 | H | H | P11 | H | H | H |
| 1997 | O | Ar21 | P2 | H | H | P11 | H | H | H |
| 1998 | O | Ar22 | P2 | H | H | P11 | H | H | H |
| 1999 | O | Ar23 | P2 | H | H | P11 | H | H | H |
| 2000 | O | Ar24 | P2 | H | H | P11 | H | H | H |
| 2001 | O | Ar25 | P2 | H | H | P11 | H | H | H |
| 2002 | O | Ar26 | P2 | H | H | P11 | H | H | H |
| 2003 | O | Ar27 | P2 | H | H | P11 | H | H | H |
| 2004 | O | Ar28 | P2 | H | H | P11 | H | H | H |
| 2005 | O | Ar29 | P2 | H | H | P11 | H | H | H |
| 2006 | O | Ar30 | P2 | H | H | P11 | H | H | H |
| 2007 | O | Ar31 | P2 | H | H | P11 | H | H | H |
| 2008 | O | Ar32 | P2 | H | H | P11 | H | H | H |
| 2009 | O | Ar33 | P2 | H | H | P11 | H | H | H |
| 2010 | O | Ar34 | P2 | H | H | P11 | H | H | H |
| 2011 | O | Ar35 | P2 | H | H | P11 | H | H | H |
| 2012 | O | Ar36 | P2 | H | H | P11 | H | H | H |
| 2013 | O | Ar37 | P2 | H | H | P11 | H | H | H |
| 2014 | O | Ar38 | P2 | H | H | P11 | H | H | H |
| 2015 | O | Ar39 | P2 | H | H | P11 | H | H | H |
| 2016 | O | Ar40 | P2 | H | H | P11 | H | H | H |
| 2017 | O | Ar41 | P2 | H | H | P11 | H | H | H |
| 2018 | O | Ar42 | P2 | H | H | P11 | H | H | H |
| 2019 | O | Ar43 | P2 | H | H | P11 | H | H | H |
| 2020 | O | Ar44 | P2 | H | H | P11 | H | H | H |
| 2021 | O | Ar45 | P2 | H | H | P11 | H | H | H |
| 2022 | O | Ar46 | P2 | H | H | P11 | H | H | H |
| 2023 | O | Ar47 | P2 | H | H | P11 | H | H | H |
| 2024 | O | Ar48 | P2 | H | H | P11 | H | H | H |
| 2025 | O | Ar49 | P2 | H | H | P11 | H | H | H |
| 2026 | O | Ar50 | P2 | H | H | P11 | H | H | H |
| 2027 | O | Ar51 | P2 | H | H | P11 | H | H | H |
| 2028 | O | Ar52 | P2 | H | H | P11 | H | H | H |
| 2029 | O | Ar53 | P2 | H | H | P11 | H | H | H |
| 2030 | O | Ar54 | P2 | H | H | P11 | H | H | H |
| 2031 | O | Ar55 | P2 | H | H | P11 | H | H | H |
| 2032 | O | Ar56 | P2 | H | H | P11 | H | H | H |
| 2033 | O | Ar57 | P2 | H | H | P11 | H | H | H |
| 2034 | O | Ar58 | P2 | H | H | P11 | H | H | H |
| 2035 | O | Ar59 | P2 | H | H | P11 | H | H | H |
| 2036 | O | Ar60 | P2 | H | H | P11 | H | H | H |
| 2037 | O | Ar61 | P2 | H | H | P11 | H | H | H |
| 2038 | O | Ar62 | P2 | H | H | P11 | H | H | H |
| 2039 | O | Ar63 | P2 | H | H | P11 | H | H | H |
| 2040 | O | Ar64 | P2 | H | H | P11 | H | H | H |
| 2041 | O | Ar65 | P2 | H | H | P11 | H | H | H |
| 2042 | O | Ar66 | P2 | H | H | P11 | H | H | H |
| 2043 | O | Ar67 | P2 | H | H | P11 | H | H | H |
| 2044 | O | Ar68 | P2 | H | H | P11 | H | H | H |
| 2045 | O | Ar69 | P2 | H | H | P11 | H | H | H |
| 2046 | O | Ar70 | P2 | H | H | P11 | H | H | H |
| 2047 | O | Ar71 | P2 | H | H | P11 | H | H | H |
| 2048 | O | Ar72 | P2 | H | H | P11 | H | H | H |
| 2049 | O | Ar73 | P2 | H | H | P11 | H | H | H |
| 2050 | O | Ar74 | P2 | H | H | P11 | H | H | H |
| 2051 | O | Ar75 | P2 | H | H | P11 | H | H | H |
| 2052 | O | Ar76 | P2 | H | H | P11 | H | H | H |
| 2053 | O | Ar77 | P2 | H | H | P11 | H | H | H |
| 2054 | O | Ar78 | P2 | H | H | P11 | H | H | H |
| 2055 | O | Ar79 | P2 | H | H | P11 | H | H | H |
| 2056 | O | Ar80 | P2 | H | H | P11 | H | H | H |
| 2057 | O | Ar81 | P2 | H | H | P11 | H | H | H |
| 2058 | O | Ar82 | P2 | H | H | P11 | H | H | H |
| 2059 | O | Ar83 | P2 | H | H | P11 | H | H | H |
| 2060 | O | Ar84 | P2 | H | H | P11 | H | H | H |
| 2061 | O | Ar85 | P2 | H | H | P11 | H | H | H |
| 2062 | O | Ar86 | P2 | H | H | P11 | H | H | H |
| 2063 | O | Ar87 | P2 | H | H | P11 | H | H | H |
| 2064 | O | Ar88 | P2 | H | H | P11 | H | H | H |
| 2065 | O | Ar89 | P2 | H | H | P11 | H | H | H |
| 2066 | O | Ar90 | P2 | H | H | P11 | H | H | H |
| 2067 | O | Ar91 | P2 | H | H | P11 | H | H | H |
| 2068 | O | Ar92 | P2 | H | H | P11 | H | H | H |
| 2069 | O | Ar93 | P2 | H | H | P11 | H | H | H |
| 2070 | O | Ar94 | P2 | H | H | P11 | H | H | H |
| 2071 | O | Ar95 | P2 | H | H | P11 | H | H | H |
| 2072 | O | Ar96 | P2 | H | H | P11 | H | H | H |
| 2073 | O | Ar97 | P2 | H | H | P11 | H | H | H |
| 2074 | O | Ar98 | P2 | H | H | P11 | H | H | H |
| 2075 | O | Ar99 | P2 | H | H | P11 | H | H | H |
| 2076 | O | Ar100 | P2 | H | H | P11 | H | H | H |
| 2077 | O | Ar101 | P2 | H | H | P11 | H | H | H |
| 2078 | O | Ar102 | P2 | H | H | P11 | H | H | H |
| 2079 | O | Ar103 | P2 | H | H | P11 | H | H | H |
| 2080 | O | Ar104 | P2 | H | H | P11 | H | H | H |
| 2081 | O | Ar1 | P11 | H | H | P11 | H | H | H |
| 2082 | O | Ar2 | P11 | H | H | P11 | H | H | H |
| 2083 | O | Ar3 | P11 | H | H | P11 | H | H | H |
| 2084 | O | Ar4 | P11 | H | H | P11 | H | H | H |
| 2085 | O | Ar5 | P11 | H | H | P11 | H | H | H |
| 2086 | O | Ar6 | P11 | H | H | P11 | H | H | H |
| 2087 | O | Ar7 | P11 | H | H | P11 | H | H | H |
| 2088 | O | Ar8 | P11 | H | H | P11 | H | H | H |
| 2089 | O | Ar9 | P11 | H | H | P11 | H | H | H |
| 2090 | O | Ar10 | P11 | H | H | P11 | H | H | H |
| 2091 | O | Ar11 | P11 | H | H | P11 | H | H | H |
| 2092 | O | Ar12 | P11 | H | H | P11 | H | H | H |
| 2093 | O | Ar13 | P11 | H | H | P11 | H | H | H |
| 2094 | O | Ar14 | P11 | H | H | P11 | H | H | H |
| 2095 | O | Ar15 | P11 | H | H | P11 | H | H | H |
| 2096 | O | Ar16 | P11 | H | H | P11 | H | H | H |
| 2097 | O | Ar17 | P11 | H | H | P11 | H | H | H |
| 2098 | O | Ar18 | P11 | H | H | P11 | H | H | H |
| 2099 | O | Ar19 | P11 | H | H | P11 | H | H | H |
| 2100 | O | Ar20 | P11 | H | H | P11 | H | H | H |
| 2101 | O | Ar21 | P11 | H | H | P11 | H | H | H |
| 2102 | O | Ar22 | P11 | H | H | P11 | H | H | H |
| 2103 | O | Ar23 | P11 | H | H | P11 | H | H | H |
| 2104 | O | Ar24 | P11 | H | H | P11 | H | H | H |
| 2105 | O | Ar25 | P11 | H | H | P11 | H | H | H |
| 2106 | O | Ar26 | P11 | H | H | P11 | H | H | H |
| 2107 | O | Ar27 | P1 | H | H | P11 | H | H | H |
| 2108 | O | Ar28 | P11 | H | H | P11 | H | H | H |
| 2109 | O | Ar29 | P11 | H | H | P1 | H | H | H |
| 2110 | O | Ar30 | P11 | H | H | P11 | H | H | H |
| 2111 | O | Ar31 | P11 | H | H | P11 | H | H | H |
| 2112 | O | Ar32 | P11 | H | H | P1 | H | H | H |
| 2113 | O | Ar33 | P11 | H | H | P11 | H | H | H |
| 2114 | O | Ar34 | P11 | H | H | P11 | H | H | H |
| 2115 | O | Ar35 | P11 | H | H | P11 | H | H | H |
| 2116 | O | Ar36 | P11 | H | H | P11 | H | H | H |
| 2117 | O | Ar37 | P11 | H | H | P11 | H | H | H |
| 2118 | O | Ar38 | P11 | H | H | P11 | H | H | H |
| 2119 | O | Ar39 | P11 | H | H | P11 | H | H | H |
| 2120 | O | Ar40 | P11 | H | H | P11 | H | H | H |
| 2121 | O | Ar41 | P11 | H | H | P11 | H | H | H |
| 2122 | O | Ar42 | P11 | H | H | P11 | H | H | H |
| 2123 | O | Ar43 | P11 | H | H | P11 | H | H | H |
| 2124 | O | Ar44 | P11 | H | H | P11 | H | H | H |
| 2125 | O | Ar45 | P11 | H | H | P11 | H | H | H |
| 2126 | O | Ar46 | P11 | H | H | P11 | H | H | H |
| 2127 | O | Ar47 | P11 | H | H | P11 | H | H | H |
| 2128 | O | Ar48 | P11 | H | H | P11 | H | H | H |
| 2129 | O | Ar49 | P11 | H | H | P11 | H | H | H |
| 2130 | O | Ar50 | P11 | H | H | P11 | H | H | H |
| 2131 | O | Ar51 | P11 | H | H | P11 | H | H | H |
| 2132 | O | Ar52 | P11 | H | H | P11 | H | H | H |
| 2133 | O | Ar53 | P11 | H | H | P11 | H | H | H |
| 2134 | O | Ar54 | P11 | H | H | P11 | H | H | H |
| 2135 | O | Ar55 | P11 | H | H | P11 | H | H | H |
| 2136 | O | Ar56 | P11 | H | H | P11 | H | H | H |
| 2137 | O | Ar57 | P11 | H | H | P11 | H | H | H |
| 2138 | O | Ar58 | P11 | H | H | P11 | H | H | H |
| 2139 | O | Ar59 | P11 | H | H | P11 | H | H | H |
| 2140 | O | Ar60 | P11 | H | H | P11 | H | H | H |
| 2141 | O | Ar61 | P11 | H | H | P11 | H | H | H |
| 2142 | O | Ar62 | P11 | H | H | P11 | H | H | H |
| 2143 | O | Ar63 | P11 | H | H | P11 | H | H | H |
| 2144 | O | Ar64 | P11 | H | H | P11 | H | H | H |
| 2145 | O | Ar65 | P11 | H | H | P11 | H | H | H |
| 2146 | O | Ar66 | P11 | H | H | P11 | H | H | H |
| 2147 | O | Ar67 | P11 | H | H | P11 | H | H | H |
| 2148 | O | Ar68 | P11 | H | H | P11 | H | H | H |
| 2149 | O | Ar69 | P11 | H | H | P11 | H | H | H |
| 2150 | O | Ar70 | P11 | H | H | P11 | H | H | H |
| 2151 | O | Ar71 | P11 | H | H | P11 | H | H | H |
| 2152 | O | Ar72 | P11 | H | H | P11 | H | H | H |
| 2153 | O | Ar73 | P11 | H | H | P11 | H | H | H |
| 2154 | O | Ar74 | P11 | H | H | P11 | H | H | H |
| 2155 | O | Ar75 | P11 | H | H | P11 | H | H | H |
| 2156 | O | Ar76 | P11 | H | H | P11 | H | H | H |
| 2157 | O | Ar77 | P11 | H | H | P11 | H | H | H |
| 2158 | O | Ar78 | P11 | H | H | P11 | H | H | H |
| 2159 | O | Ar79 | P11 | H | H | P11 | H | H | H |
| 2160 | O | Ar80 | P11 | H | H | P11 | H | H | H |
| 2161 | O | Ar81 | P11 | H | H | P11 | H | H | H |
| 2162 | O | Ar82 | P11 | H | H | P11 | H | H | H |
| 2163 | O | Ar83 | P11 | H | H | P11 | H | H | H |
| 2164 | O | Ar84 | P11 | H | H | P11 | H | H | H |
| 2165 | O | Ar85 | P11 | H | H | P11 | H | H | H |
| 2166 | O | Ar86 | P11 | H | H | P11 | H | H | H |
| 2167 | O | Ar87 | P11 | H | H | P11 | H | H | H |
| 2168 | O | Ar88 | P11 | H | H | P11 | H | H | H |
| 2169 | O | Ar89 | P11 | H | H | P11 | H | H | H |
| 2170 | O | Ar90 | P11 | H | H | P11 | H | H | H |
| 2171 | O | Ar91 | P11 | H | H | P11 | H | H | H |
| 2172 | O | Ar92 | P11 | H | H | P11 | H | H | H |
| 2173 | O | Ar93 | P11 | H | H | P11 | H | H | H |
| 2174 | O | Ar94 | P11 | H | H | P11 | H | H | H |
| 2175 | O | Ar95 | P11 | H | H | P11 | H | H | H |
| 2176 | O | Ar96 | P11 | H | H | P11 | H | H | H |
| 2177 | O | Ar97 | P11 | H | H | P11 | H | H | H |
| 2178 | O | Ar98 | P11 | H | H | P11 | H | H | H |
| 2179 | O | Ar99 | P11 | H | H | P11 | H | H | H |
| 2180 | O | Ar100 | P11 | H | H | P11 | H | H | H |
| 2181 | O | Ar101 | P11 | H | H | P11 | H | H | H |
| 2182 | O | Ar102 | P11 | H | H | P11 | H | H | H |
| 2183 | O | Ar103 | P11 | H | H | P11 | H | H | H |
| 2184 | O | Ar104 | P11 | H | H | P11 | H | H | H |
| 2185 | O | Ar1 | P12 | H | H | P11 | H | H | H |
| 2186 | O | Ar2 | P12 | H | H | P11 | H | H | H |
| 2187 | O | Ar3 | P12 | H | H | P11 | H | H | H |
| 2188 | O | Ar4 | P12 | H | H | P11 | H | H | H |
| 2189 | O | Ar5 | P12 | H | H | P11 | H | H | H |
| 2190 | O | Ar6 | P12 | H | H | P11 | H | H | H |
| 2191 | O | Ar7 | P12 | H | H | P11 | H | H | H |
| 2192 | O | Ar8 | P12 | H | H | P11 | H | H | H |
| 2193 | O | Ar9 | P12 | H | H | P11 | H | H | H |
| 2194 | O | Ar10 | P12 | H | H | P11 | H | H | H |
| 2195 | O | Ar11 | P12 | H | H | P11 | H | H | H |
| 2196 | O | Ar12 | P12 | H | H | P11 | H | H | H |
| 2197 | O | Ar13 | P12 | H | H | P11 | H | H | H |
| 2198 | O | Ar14 | P12 | H | H | P11 | H | H | H |
| 2199 | O | Ar15 | P12 | H | H | P11 | H | H | H |
| 2200 | O | Ar16 | P12 | H | H | P11 | H | H | H |
| 2201 | O | Ar17 | P12 | H | H | P11 | H | H | H |
| 2202 | O | Ar18 | P12 | H | H | P11 | H | H | H |
| 2203 | O | Ar19 | P12 | H | H | P11 | H | H | H |
| 2204 | O | Ar20 | P12 | H | H | P11 | H | H | H |
| 2205 | O | Ar21 | P12 | H | H | P11 | H | H | H |
| 2206 | O | Ar22 | P12 | H | H | P11 | H | H | H |
| 2207 | O | Ar23 | P12 | H | H | P11 | H | H | H |
| 2208 | O | Ar24 | P12 | H | H | P11 | H | H | H |
| 2209 | O | Ar25 | P12 | H | H | P11 | H | H | H |
| 2210 | O | Ar26 | P12 | H | H | P11 | H | H | H |
| 2211 | O | Ar27 | P12 | H | H | P11 | H | H | H |
| 2212 | O | Ar28 | P12 | H | H | P11 | H | H | H |
| 2213 | O | Ar29 | P12 | H | H | P11 | H | H | H |
| 2214 | O | Ar30 | P12 | H | H | P11 | H | H | H |
| 2215 | O | Ar31 | P12 | H | H | P11 | H | H | H |
| 2216 | O | Ar32 | P12 | H | H | P11 | H | H | H |
| 2217 | O | Ar33 | P12 | H | H | P11 | H | H | H |
| 2218 | O | Ar34 | P12 | H | H | P11 | H | H | H |
| 2219 | O | Ar35 | P12 | H | H | P11 | H | H | H |
| 2220 | O | Ar36 | P12 | H | H | P11 | H | H | H |
| 2221 | O | Ar37 | P12 | H | H | P11 | H | H | H |
| 2222 | O | Ar38 | P12 | H | H | P11 | H | H | H |
| 2223 | O | Ar39 | P12 | H | H | P11 | H | H | H |
| 2224 | O | Ar40 | P12 | H | H | P11 | H | H | H |
| 2225 | O | Ar41 | P12 | H | H | P11 | H | H | H |
| 2226 | O | Ar42 | P12 | H | H | P11 | H | H | H |
| 2227 | O | Ar43 | P12 | H | H | P11 | H | H | H |
| 2228 | O | Ar44 | P12 | H | H | P11 | H | H | H |
| 2229 | O | Ar45 | P12 | H | H | P11 | H | H | H |
| 2230 | O | Ar46 | P12 | H | H | P11 | H | H | H |
| 2231 | O | Ar47 | P12 | H | H | P11 | H | H | H |
| 2232 | O | Ar48 | P12 | H | H | P11 | H | H | H |
| 2233 | O | Ar49 | P12 | H | H | P11 | H | H | H |
| 2234 | O | Ar50 | P12 | H | H | P11 | H | H | H |
| 2235 | O | Ar51 | P12 | H | H | P11 | H | H | H |
| 2236 | O | Ar52 | P1 | H | H | P11 | H | H | H |
| 2237 | O | Ar53 | P12 | H | H | P11 | H | H | H |
| 2238 | O | Ar54 | P12 | H | H | P11 | H | H | H |
| 2239 | O | Ar55 | P12 | H | H | P11 | H | H | H |
| 2240 | O | Ar56 | P12 | H | H | P11 | H | H | H |
| 2241 | O | Ar57 | P12 | H | H | P11 | H | H | H |
| 2242 | O | Ar58 | P12 | H | H | P11 | H | H | H |
| 2243 | O | Ar59 | P12 | H | H | P11 | H | H | H |
| 2244 | O | Ar60 | P12 | H | H | P11 | H | H | H |
| 2245 | O | Ar61 | P12 | H | H | P11 | H | H | H |
| 2246 | O | Ar62 | P12 | H | H | P11 | H | H | H |
| 2247 | O | Ar63 | P12 | H | H | P11 | H | H | H |
| 2248 | O | Ar64 | P12 | H | H | P11 | H | H | H |
| 2249 | O | Ar65 | P12 | H | H | P11 | H | H | H |
| 2250 | O | Ar66 | P12 | H | H | P11 | H | H | H |
| 2251 | O | Ar67 | P12 | H | H | P11 | H | H | H |
| 2252 | O | Ar68 | P12 | H | H | P11 | H | H | H |
| 2253 | O | Ar69 | P12 | H | H | P11 | H | H | H |
| 2254 | O | Ar70 | P12 | H | H | P11 | H | H | H |
| 2255 | O | Ar71 | P12 | H | H | P11 | H | H | H |
| 2256 | O | Ar72 | P12 | H | H | P11 | H | H | H |
| 2257 | O | Ar73 | P12 | H | H | P1 | H | H | H |
| 2258 | O | Ar74 | P12 | H | H | P11 | H | H | H |
| 2259 | O | Ar75 | P12 | H | H | P11 | H | H | H |
| 2260 | O | Ar76 | P12 | H | H | P11 | H | H | H |
| 2261 | O | Ar77 | P12 | H | H | P1 | H | H | H |
| 2262 | O | Ar78 | P12 | H | H | P11 | H | H | H |
| 2263 | O | Ar79 | P12 | H | H | P11 | H | H | H |
| 2264 | O | Ar80 | P12 | H | H | P11 | H | H | H |
| 2265 | O | Ar81 | P12 | H | H | P11 | H | H | H |
| 2266 | O | Ar82 | P12 | H | H | P11 | H | H | H |
| 2267 | O | Ar83 | P12 | H | H | P11 | H | H | H |
| 2268 | O | Ar84 | P12 | H | H | P11 | H | H | H |
| 2269 | O | Ar85 | P12 | H | H | P11 | H | H | H |
| 2270 | O | Ar86 | P12 | H | H | P11 | H | H | H |
| 2271 | O | Ar87 | P12 | H | H | P11 | H | H | H |
| 2272 | O | Ar88 | P12 | H | H | P11 | H | H | H |
| 2273 | O | Ar89 | P12 | H | H | P11 | H | H | H |
| 2274 | O | Ar90 | P12 | H | H | P11 | H | H | H |
| 2275 | O | Ar91 | P12 | H | H | P11 | H | H | H |
| 2276 | O | Ar92 | P12 | H | H | P11 | H | H | H |
| 2277 | O | Ar93 | P12 | H | H | P11 | H | H | H |
| 2278 | O | Ar94 | P12 | H | H | P11 | H | H | H |
| 2279 | O | Ar95 | P12 | H | H | P11 | H | H | H |
| 2280 | O | Ar96 | P12 | H | H | P11 | H | H | H |
| 2281 | O | Ar97 | P12 | H | H | P11 | H | H | H |
| 2282 | O | Ar98 | P12 | H | H | P11 | H | H | H |
| 2283 | O | Ar99 | P12 | H | H | P11 | H | H | H |
| 2284 | O | Ar100 | P12 | H | H | P11 | H | H | H |
| 2285 | O | Ar101 | P12 | H | H | P11 | H | H | H |
| 2286 | O | Ar102 | P12 | H | H | P11 | H | H | H |
| 2287 | O | Ar103 | P12 | H | H | P11 | H | H | H |
| 2288 | O | Ar104 | P12 | H | H | P11 | H | H | H |
| 2289 | O | Ar1 | P1 | H | H | P12 | H | H | H |
| 2290 | O | Ar2 | P1 | H | H | P12 | H | H | H |
| 2291 | O | Ar3 | P1 | H | H | P12 | H | H | H |
| 2292 | O | Ar4 | P1 | H | H | P12 | H | H | H |
| 2293 | O | Ar5 | P1 | H | H | P12 | H | H | H |
| 2294 | O | Ar6 | P1 | H | H | P12 | H | H | H |
| 2295 | O | Ar7 | P1 | H | H | P12 | H | H | H |
| 2296 | O | Ar8 | P1 | H | H | P12 | H | H | H |
| 2297 | O | Ar9 | P1 | H | H | P12 | H | H | H |
| 2298 | O | Ar10 | P1 | H | H | P12 | H | H | H |
| 2299 | O | Ar11 | P1 | H | H | P12 | H | H | H |
| 2300 | O | Ar12 | P1 | H | H | P12 | H | H | H |
| 2301 | O | Ar13 | P1 | H | H | P12 | H | H | H |
| 2302 | O | Ar14 | P1 | H | H | P12 | H | H | H |
| 2303 | O | Ar15 | P1 | H | H | P12 | H | H | H |
| 2304 | O | Ar16 | P1 | H | H | P12 | H | H | H |
| 2305 | O | Ar17 | P1 | H | H | P12 | H | H | H |
| 2306 | O | Ar18 | P1 | H | H | P12 | H | H | H |
| 2307 | O | Ar19 | P1 | H | H | P12 | H | H | H |
| 2308 | O | Ar20 | P1 | H | H | P12 | H | H | H |
| 2309 | O | Ar21 | P1 | H | H | P12 | H | H | H |
| 2310 | O | Ar22 | P1 | H | H | P12 | H | H | H |
| 2311 | O | Ar23 | P1 | H | H | P12 | H | H | H |
| 2312 | O | Ar24 | P1 | H | H | P12 | H | H | H |
| 2313 | O | Ar25 | P1 | H | H | P12 | H | H | H |
| 2314 | O | Ar26 | P1 | H | H | P12 | H | H | H |
| 2315 | O | Ar27 | P1 | H | H | P12 | H | H | H |
| 2316 | O | Ar28 | P1 | H | H | P12 | H | H | H |
| 2317 | O | Ar29 | P1 | H | H | P12 | H | H | H |
| 2318 | O | Ar30 | P1 | H | H | P12 | H | H | H |
| 2319 | O | Ar31 | P1 | H | H | P12 | H | H | H |
| 2320 | O | Ar32 | P1 | H | H | P12 | H | H | H |
| 2321 | O | Ar33 | P1 | H | H | P12 | H | H | H |
| 2322 | O | Ar34 | P1 | H | H | P12 | H | H | H |
| 2323 | O | Ar35 | P1 | H | H | P12 | H | H | H |
| 2324 | O | Ar36 | P1 | H | H | P12 | H | H | H |
| 2325 | O | Ar37 | P1 | H | H | P12 | H | H | H |
| 2326 | O | Ar38 | P1 | H | H | P12 | H | H | H |
| 2327 | O | Ar39 | P1 | H | H | P12 | H | H | H |
| 2328 | O | Ar40 | P1 | H | H | P12 | H | H | H |
| 2329 | O | Ar41 | P1 | H | H | P12 | H | H | H |
| 2330 | O | Ar42 | P1 | H | H | P12 | H | H | H |
| 2331 | O | Ar43 | P1 | H | H | P12 | H | H | H |
| 2332 | O | Ar44 | P1 | H | H | P12 | H | H | H |
| 2333 | O | Ar45 | P1 | H | H | P12 | H | H | H |
| 2334 | O | Ar46 | P1 | H | H | P12 | H | H | H |
| 2335 | O | Ar47 | P1 | H | H | P12 | H | H | H |
| 2336 | O | Ar48 | P1 | H | H | P12 | H | H | H |
| 2337 | O | Ar49 | P1 | H | H | P12 | H | H | H |
| 2338 | O | Ar50 | P1 | H | H | P12 | H | H | H |
| 2339 | O | Ar51 | P1 | H | H | P12 | H | H | H |
| 2340 | O | Ar52 | P1 | H | H | P12 | H | H | H |
| 2341 | O | Ar53 | P1 | H | H | P12 | H | H | H |
| 2342 | O | Ar54 | P1 | H | H | P12 | H | H | H |
| 2343 | O | Ar55 | P1 | H | H | P12 | H | H | H |
| 2344 | O | Ar56 | P1 | H | H | P12 | H | H | H |
| 2345 | O | Ar57 | P1 | H | H | P12 | H | H | H |
| 2346 | O | Ar58 | P1 | H | H | P12 | H | H | H |
| 2347 | O | Ar59 | P1 | H | H | P12 | H | H | H |
| 2348 | O | Ar60 | P1 | H | H | P12 | H | H | H |
| 2349 | O | Ar61 | P1 | H | H | P12 | H | H | H |
| 2350 | O | Ar62 | P1 | H | H | P12 | H | H | H |
| 2351 | O | Ar63 | P1 | H | H | P12 | H | H | H |
| 2352 | O | Ar64 | P1 | H | H | P12 | H | H | H |
| 2353 | O | Ar65 | P1 | H | H | P12 | H | H | H |
| 2354 | O | Ar66 | P1 | H | H | P12 | H | H | H |
| 2355 | O | Ar67 | P1 | H | H | P12 | H | H | H |
| 2356 | O | Ar68 | P1 | H | H | P12 | H | H | H |
| 2357 | O | Ar69 | P1 | H | H | P12 | H | H | H |
| 2358 | O | Ar70 | P1 | H | H | P12 | H | H | H |
| 2359 | O | Ar71 | P1 | H | H | P12 | H | H | H |
| 2360 | O | Ar72 | P1 | H | H | P12 | H | H | H |
| 2361 | O | Ar73 | P1 | H | H | P12 | H | H | H |
| 2362 | O | Ar74 | P1 | H | H | P12 | H | H | H |
| 2363 | O | Ar75 | P1 | H | H | P12 | H | H | H |
| 2364 | O | Ar76 | P1 | H | H | P12 | H | H | H |
| 2365 | O | Ar77 | P1 | H | H | P12 | H | H | H |
| 2366 | O | Ar78 | P1 | H | H | P12 | H | H | H |
| 2367 | O | Ar79 | P1 | H | H | P12 | H | H | H |
| 2368 | O | Ar80 | P1 | H | H | P12 | H | H | H |
| 2369 | O | Ar81 | P1 | H | H | P12 | H | H | H |
| 2370 | O | Ar82 | P1 | H | H | P12 | H | H | H |
| 2371 | O | Ar83 | P1 | H | H | P12 | H | H | H |
| 2372 | O | Ar84 | P1 | H | H | P12 | H | H | H |
| 2373 | O | Ar85 | P1 | H | H | P12 | H | H | H |
| 2374 | O | Ar86 | P1 | H | H | P12 | H | H | H |
| 2375 | O | Ar87 | P1 | H | H | P12 | H | H | H |
| 2376 | O | Ar88 | P1 | H | H | P12 | H | H | H |
| 2377 | O | Ar89 | P1 | H | H | P12 | H | H | H |
| 2378 | O | Ar90 | P1 | H | H | P12 | H | H | H |
| 2379 | O | Ar91 | P1 | H | H | P12 | H | H | H |
| 2380 | O | Ar92 | P1 | H | H | P12 | H | H | H |
| 2381 | O | Ar93 | P1 | H | H | P12 | H | H | H |
| 2382 | O | Ar94 | P1 | H | H | P12 | H | H | H |
| 2383 | O | Ar95 | P1 | H | H | P12 | H | H | H |
| 2384 | O | Ar96 | P1 | H | H | P12 | H | H | H |
| 2385 | O | Ar97 | P1 | H | H | P12 | H | H | H |
| 2386 | O | Ar98 | P1 | H | H | P12 | H | H | H |
| 2387 | O | Ar99 | P1 | H | H | P12 | H | H | H |
| 2388 | O | Ar100 | P1 | H | H | P12 | H | H | H |
| 2389 | O | Ar101 | P1 | H | H | P12 | H | H | H |
| 2390 | O | Ar102 | P1 | H | H | P12 | H | H | H |
| 2391 | O | Ar103 | P1 | H | H | P12 | H | H | H |
| 2392 | O | Ar104 | P1 | H | H | P12 | H | H | H |
| 2393 | O | Ar1 | P2 | H | H | P12 | H | H | H |
| 2394 | O | Ar2 | P2 | H | H | P12 | H | H | H |
| 2395 | O | Ar3 | P2 | H | H | P12 | H | H | H |
| 2396 | O | Ar4 | P2 | H | H | P12 | H | H | H |
| 2397 | O | Ar5 | P2 | H | H | P12 | H | H | H |
| 2398 | O | Ar6 | P2 | H | H | P12 | H | H | H |
| 2399 | O | Ar7 | P2 | H | H | P12 | H | H | H |
| 2400 | O | Ar8 | P2 | H | H | P12 | H | H | H |
| 2401 | O | Ar9 | P2 | H | H | P12 | H | H | H |
| 2402 | O | Ar10 | P2 | H | H | P12 | H | H | H |
| 2403 | O | Ar11 | P2 | H | H | P12 | H | H | H |
| 2404 | O | Ar12 | P2 | H | H | P12 | H | H | H |
| 2405 | O | Ar13 | P2 | H | H | P12 | H | H | H |
| 2406 | O | Ar14 | P2 | H | H | P12 | H | H | H |
| 2407 | O | Ar15 | P2 | H | H | P12 | H | H | H |
| 2408 | O | Ar16 | P2 | H | H | P12 | H | H | H |
| 2409 | O | Ar17 | P2 | H | H | P12 | H | H | H |
| 2410 | O | Ar18 | P2 | H | H | P12 | H | H | H |
| 2411 | O | Ar19 | P2 | H | H | P12 | H | H | H |
| 2412 | O | Ar20 | P2 | H | H | P12 | H | H | H |
| 2413 | O | Ar21 | P2 | H | H | P12 | H | H | H |
| 2414 | O | Ar22 | P2 | H | H | P12 | H | H | H |
| 2415 | O | Ar23 | P2 | H | H | P12 | H | H | H |
| 2416 | O | Ar24 | P2 | H | H | P12 | H | H | H |
| 2417 | O | Ar25 | P2 | H | H | P12 | H | H | H |
| 2418 | O | Ar26 | P2 | H | H | P12 | H | H | H |
| 2419 | O | Ar27 | P2 | H | H | P12 | H | H | H |
| 2420 | O | Ar28 | P2 | H | H | P12 | H | H | H |
| 2421 | O | Ar29 | P2 | H | H | P12 | H | H | H |
| 2422 | O | Ar30 | P2 | H | H | P12 | H | H | H |
| 2423 | O | Ar31 | P2 | H | H | P12 | H | H | H |
| 2424 | O | Ar32 | P2 | H | H | P12 | H | H | H |
| 2425 | O | Ar33 | P2 | H | H | P12 | H | H | H |
| 2426 | O | Ar34 | P2 | H | H | P12 | H | H | H |
| 2427 | O | Ar35 | P2 | H | H | P12 | H | H | H |
| 2428 | O | Ar36 | P2 | H | H | P12 | H | H | H |
| 2429 | O | Ar37 | P2 | H | H | P12 | H | H | H |
| 2430 | O | Ar38 | P2 | H | H | P12 | H | H | H |
| 2431 | O | Ar39 | P2 | H | H | P12 | H | H | H |
| 2432 | O | Ar40 | P2 | H | H | P12 | H | H | H |
| 2433 | O | Ar41 | P2 | H | H | P12 | H | H | H |
| 2434 | O | Ar42 | P2 | H | H | P12 | H | H | H |
| 2435 | O | Ar43 | P2 | H | H | P12 | H | H | H |
| 2436 | O | Ar44 | P2 | H | H | P12 | H | H | H |
| 2437 | O | Ar45 | P2 | H | H | P1 | H | H | H |
| 2438 | O | Ar46 | P2 | H | H | P12 | H | H | H |
| 2439 | O | Ar47 | P2 | H | H | P12 | H | H | H |
| 2440 | O | Ar48 | P2 | H | H | P12 | H | H | H |
| 2441 | O | Ar49 | P2 | H | H | P12 | H | H | H |
| 2442 | O | Ar50 | P2 | H | H | P12 | H | H | H |
| 2443 | O | Ar51 | P2 | H | H | P12 | H | H | H |
| 2444 | O | Ar52 | P2 | H | H | P12 | H | H | H |
| 2445 | O | Ar53 | P2 | H | H | P12 | H | H | H |
| 2446 | O | Ar54 | P2 | H | H | P12 | H | H | H |
| 2447 | O | Ar55 | P2 | H | H | P12 | H | H | H |
| 2448 | O | Ar56 | P2 | H | H | P12 | H | H | H |
| 2449 | O | Ar57 | P2 | H | H | P12 | H | H | H |
| 2450 | O | Ar58 | P2 | H | H | P12 | H | H | H |
| 2451 | O | Ar59 | P2 | H | H | P12 | H | H | H |
| 2452 | O | Ar60 | P2 | H | H | P12 | H | H | H |
| 2453 | O | Ar61 | P2 | H | H | P12 | H | H | H |
| 2454 | O | Ar62 | P2 | H | H | P12 | H | H | H |
| 2455 | O | Ar63 | P2 | H | H | P12 | H | H | H |
| 2456 | O | Ar64 | P2 | H | H | P12 | H | H | H |
| 2457 | O | Ar65 | P2 | H | H | P12 | H | H | H |
| 2458 | O | Ar66 | P2 | H | H | P12 | H | H | H |
| 2459 | O | Ar67 | P2 | H | H | P12 | H | H | H |
| 2460 | O | Ar68 | P2 | H | H | P12 | H | H | H |
| 2461 | O | Ar69 | P2 | H | H | P12 | H | H | H |
| 2462 | O | Ar70 | P2 | H | H | P12 | H | H | H |
| 2463 | O | Ar71 | P2 | H | H | P12 | H | H | H |
| 2464 | O | Ar72 | P2 | H | H | P12 | H | H | H |
| 2465 | O | Ar73 | P2 | H | H | P12 | H | H | H |
| 2466 | O | Ar74 | P2 | H | H | P12 | H | H | H |
| 2467 | O | Ar75 | P2 | H | H | P12 | H | H | H |
| 2468 | O | Ar76 | P2 | H | H | P12 | H | H | H |
| 2469 | O | Ar77 | P2 | H | H | P12 | H | H | H |
| 2470 | O | Ar78 | P2 | H | H | P12 | H | H | H |
| 2471 | O | Ar79 | P2 | H | H | P12 | H | H | H |
| 2472 | O | Ar80 | P2 | H | H | P12 | H | H | H |
| 2473 | O | Ar81 | P2 | H | H | P12 | H | H | H |
| 2474 | O | Ar82 | P2 | H | H | P12 | H | H | H |
| 2475 | O | Ar83 | P2 | H | H | P12 | H | H | H |
| 2476 | O | Ar84 | P2 | H | H | P12 | H | H | H |
| 2477 | O | Ar85 | P2 | H | H | P12 | H | H | H |
| 2478 | O | Ar86 | P2 | H | H | P12 | H | H | H |
| 2479 | O | Ar87 | P2 | H | H | P12 | H | H | H |
| 2480 | O | Ar88 | P2 | H | H | P12 | H | H | H |
| 2481 | O | Ar89 | P2 | H | H | P12 | H | H | H |
| 2482 | O | Ar90 | P2 | H | H | P12 | H | H | H |
| 2483 | O | Ar91 | P2 | H | H | P12 | H | H | H |
| 2484 | O | Ar92 | P2 | H | H | P12 | H | H | H |
| 2485 | O | Ar93 | P2 | H | H | P12 | H | H | H |
| 2486 | O | Ar94 | P2 | H | H | P12 | H | H | H |
| 2487 | O | Ar95 | P2 | H | H | P12 | H | H | H |
| 2488 | O | Ar96 | P2 | H | H | P12 | H | H | H |
| 2489 | O | Ar97 | P2 | H | H | P12 | H | H | H |
| 2490 | O | Ar98 | P2 | H | H | P12 | H | H | H |
| 2491 | O | Ar99 | P2 | H | H | P12 | H | H | H |
| 2492 | O | Ar100 | P2 | H | H | P12 | H | H | H |
| 2493 | O | Ar101 | P2 | H | H | P12 | H | H | H |
| 2494 | O | Ar102 | P2 | H | H | P12 | H | H | H |
| 2495 | O | Ar103 | P2 | H | H | P12 | H | H | H |
| 2496 | O | Ar104 | P2 | H | H | P12 | H | H | H |
| 2497 | O | Ar1 | P11 | H | H | P12 | H | H | H |
| 2498 | O | Ar2 | P11 | H | H | P12 | H | H | H |
| 2499 | O | Ar3 | P11 | H | H | P12 | H | H | H |
| 2500 | O | Ar4 | P11 | H | H | P12 | H | H | H |
| 2501 | O | Ar5 | P11 | H | H | P12 | H | H | H |
| 2502 | O | Ar6 | P11 | H | H | P12 | H | H | H |
| 2503 | O | Ar7 | P11 | H | H | P12 | H | H | H |
| 2504 | O | Ar8 | P11 | H | H | P12 | H | H | H |
| 2505 | O | Ar9 | P11 | H | H | P12 | H | H | H |
| 2506 | O | Ar10 | P11 | H | H | P12 | H | H | H |
| 2507 | O | Ar11 | P11 | H | H | P12 | H | H | H |
| 2508 | O | Ar12 | P11 | H | H | P12 | H | H | H |
| 2509 | O | Ar13 | P11 | H | H | P12 | H | H | H |
| 2510 | O | Ar14 | P11 | H | H | P12 | H | H | H |
| 2511 | O | Ar15 | P11 | H | H | P12 | H | H | H |
| 2512 | O | Ar16 | P11 | H | H | P12 | H | H | H |
| 2513 | O | Ar17 | P11 | H | H | P12 | H | H | H |
| 2514 | O | Ar18 | P11 | H | H | P12 | H | H | H |
| 2515 | O | Ar19 | P11 | H | H | P12 | H | H | H |
| 2516 | O | Ar20 | P11 | H | H | P12 | H | H | H |
| 2517 | O | Ar21 | P11 | H | H | P12 | H | H | H |
| 2518 | O | Ar22 | P11 | H | H | P12 | H | H | H |
| 2519 | O | Ar23 | P11 | H | H | P12 | H | H | H |
| 2520 | O | Ar24 | P11 | H | H | P12 | H | H | H |
| 2521 | O | Ar25 | P11 | H | H | P12 | H | H | H |
| 2522 | O | Ar26 | P11 | H | H | P12 | H | H | H |
| 2523 | O | Ar27 | P11 | H | H | P12 | H | H | H |
| 2524 | O | Ar28 | P11 | H | H | P12 | H | H | H |
| 2525 | O | Ar29 | P11 | H | H | P12 | H | H | H |
| 2526 | O | Ar30 | P11 | H | H | P12 | H | H | H |
| 2527 | O | Ar31 | P11 | H | H | P12 | H | H | H |
| 2528 | O | Ar32 | P11 | H | H | P12 | H | H | H |
| 2529 | O | Ar33 | P11 | H | H | P12 | H | H | H |
| 2530 | O | Ar34 | P11 | H | H | P12 | H | H | H |
| 2531 | O | Ar35 | P11 | H | H | P12 | H | H | H |
| 2532 | O | Ar36 | P11 | H | H | P12 | H | H | H |
| 2533 | O | Ar37 | P11 | H | H | P12 | H | H | H |
| 2534 | O | Ar38 | P11 | H | H | P12 | H | H | H |
| 2535 | O | Ar39 | P11 | H | H | P12 | H | H | H |
| 2536 | O | Ar40 | P11 | H | H | P12 | H | H | H |
| 2537 | O | Ar41 | P11 | H | H | P12 | H | H | H |
| 2538 | O | Ar42 | P11 | H | H | P12 | H | H | H |
| 2539 | O | Ar43 | P11 | H | H | P12 | H | H | H |
| 2540 | O | Ar44 | P11 | H | H | P12 | H | H | H |
| 2541 | O | Ar45 | P11 | H | H | P12 | H | H | H |
| 2542 | O | Ar46 | P11 | H | H | P12 | H | H | H |
| 2543 | O | Ar47 | P11 | H | H | P12 | H | H | H |
| 2544 | O | Ar48 | P11 | H | H | P12 | H | H | H |
| 2545 | O | Ar49 | P11 | H | H | P12 | H | H | H |
| 2546 | O | Ar50 | P11 | H | H | P12 | H | H | H |
| 2547 | O | Ar51 | P11 | H | H | P12 | H | H | H |
| 2548 | O | Ar52 | P11 | H | H | P12 | H | H | H |
| 2549 | O | Ar53 | P11 | H | H | P12 | H | H | H |
| 2550 | O | Ar54 | P11 | H | H | P12 | H | H | H |
| 2551 | O | Ar55 | P11 | H | H | P12 | H | H | H |
| 2552 | O | Ar56 | P11 | H | H | P12 | H | H | H |
| 2553 | O | Ar57 | P11 | H | H | P12 | H | H | H |
| 2554 | O | Ar58 | P11 | H | H | P12 | H | H | H |
| 2555 | O | Ar59 | P11 | H | H | P12 | H | H | H |
| 2556 | O | Ar60 | P11 | H | H | P12 | H | H | H |
| 2557 | O | Ar61 | P11 | H | H | P12 | H | H | H |
| 2558 | O | Ar62 | P11 | H | H | P12 | H | H | H |
| 2559 | O | Ar63 | P11 | H | H | P12 | H | H | H |
| 2560 | O | Ar64 | P11 | H | H | P12 | H | H | H |
| 2561 | O | Ar65 | P11 | H | H | P12 | H | H | H |
| 2562 | O | Ar66 | P11 | H | H | P12 | H | H | H |
| 2563 | O | Ar67 | P11 | H | H | P12 | H | H | H |
| 2564 | O | Ar68 | P11 | H | H | P12 | H | H | H |
| 2565 | O | Ar69 | P11 | H | H | P12 | H | H | H |
| 2566 | O | Ar70 | P11 | H | H | P12 | H | H | H |
| 2567 | O | Ar71 | P11 | H | H | P12 | H | H | H |
| 2568 | O | Ar72 | P11 | H | H | P12 | H | H | H |
| 2569 | O | Ar73 | P11 | H | H | P12 | H | H | H |
| 2570 | O | Ar74 | P11 | H | H | P12 | H | H | H |
| 2571 | O | Ar75 | P11 | H | H | P12 | H | H | H |
| 2572 | O | Ar76 | P11 | H | H | P12 | H | H | H |
| 2573 | O | Ar77 | P11 | H | H | P12 | H | H | H |
| 2574 | O | Ar78 | P11 | H | H | P12 | H | H | H |
| 2575 | O | Ar79 | P11 | H | H | P12 | H | H | H |
| 2576 | O | Ar80 | P11 | H | H | P12 | H | H | H |
| 2577 | O | Ar81 | P11 | H | H | P12 | H | H | H |
| 2578 | O | Ar82 | P11 | H | H | P12 | H | H | H |
| 2579 | O | Ar83 | P11 | H | H | P12 | H | H | H |
| 2580 | O | Ar84 | P11 | H | H | P12 | H | H | H |
| 2581 | O | Ar85 | P11 | H | H | P12 | H | H | H |
| 2582 | O | Ar86 | P11 | H | H | P12 | H | H | H |
| 2583 | O | Ar87 | P11 | H | H | P12 | H | H | H |
| 2584 | O | Ar88 | P11 | H | H | P12 | H | H | H |
| 2585 | O | Ar89 | P11 | H | H | P12 | H | H | H |
| 2586 | O | Ar90 | P11 | H | H | P12 | H | H | H |
| 2587 | O | Ar91 | P11 | H | H | P12 | H | H | H |
| 2588 | O | Ar92 | P11 | H | H | P12 | H | H | H |
| 2589 | O | Ar93 | P11 | H | H | P12 | H | H | H |
| 2590 | O | Ar94 | P11 | H | H | P12 | H | H | H |
| 2591 | O | Ar95 | P11 | H | H | P12 | H | H | H |
| 2592 | O | Ar96 | P11 | H | H | P12 | H | H | H |
| 2593 | O | Ar97 | P11 | H | H | P12 | H | H | H |
| 2594 | O | Ar98 | P11 | H | H | P12 | H | H | H |
| 2595 | O | Ar99 | P11 | H | H | P12 | H | H | H |
| 2596 | O | Ar100 | P11 | H | H | P12 | H | H | H |
| 2597 | O | Ar101 | P11 | H | H | P12 | H | H | H |
| 2598 | O | Ar102 | P11 | H | H | P12 | H | H | H |
| 2599 | O | Ar103 | P11 | H | H | P12 | H | H | H |
| 2600 | O | Ar104 | P11 | H | H | P12 | H | H | H |
| 2601 | O | Ar1 | P12 | H | H | P12 | H | H | H |
| 2602 | O | Ar2 | P12 | H | H | P12 | H | H | H |
| 2603 | O | Ar3 | P12 | H | H | P12 | H | H | H |
| 2604 | O | Ar4 | P12 | H | H | P12 | H | H | H |
| 2605 | O | Ar5 | P12 | H | H | P12 | H | H | H |
| 2606 | O | Ar6 | P12 | H | H | P12 | H | H | H |
| 2607 | O | Ar7 | P12 | H | H | P12 | H | H | H |
| 2608 | O | Ar8 | P12 | H | H | P12 | H | H | H |
| 2609 | O | Ar9 | P12 | H | H | P12 | H | H | H |
| 2610 | O | Ar10 | P12 | H | H | P12 | H | H | H |
| 2611 | O | Ar11 | P12 | H | H | P12 | H | H | H |
| 2612 | O | Ar12 | P12 | H | H | P12 | H | H | H |
| 2613 | O | Ar13 | P12 | H | H | P12 | H | H | H |
| 2614 | O | Ar14 | P12 | H | H | P12 | H | H | H |
| 2615 | O | Ar15 | P12 | H | H | P12 | H | H | H |
| 2616 | O | Ar16 | P12 | H | H | P12 | H | H | H |
| 2617 | O | Ar17 | P12 | H | H | P12 | H | H | H |
| 2618 | O | Ar18 | P12 | H | H | P12 | H | H | H |
| 2619 | O | Ar19 | P12 | H | H | P12 | H | H | H |
| 2620 | O | Ar20 | P12 | H | H | P12 | H | H | H |
| 2621 | O | Ar21 | P12 | H | H | P12 | H | H | H |
| 2622 | O | Ar22 | P12 | H | H | P12 | H | H | H |
| 2623 | O | Ar23 | P12 | H | H | P12 | H | H | H |
| 2624 | O | Ar24 | P12 | H | H | P12 | H | H | H |
| 2625 | O | Ar25 | P12 | H | H | P12 | H | H | H |
| 2626 | O | Ar26 | P12 | H | H | P12 | H | H | H |
| 2627 | O | Ar27 | P12 | H | H | P12 | H | H | H |
| 2628 | O | Ar28 | P12 | H | H | P12 | H | H | H |
| 2629 | O | Ar29 | P12 | H | H | P12 | H | H | H |
| 2630 | O | Ar30 | P12 | H | H | P12 | H | H | H |
| 2631 | O | Ar31 | P12 | H | H | P12 | H | H | H |
| 2632 | O | Ar32 | P12 | H | H | P12 | H | H | H |
| 2633 | O | Ar33 | P12 | H | H | P12 | H | H | H |
| 2634 | O | Ar34 | P12 | H | H | P12 | H | H | H |
| 2635 | O | Ar35 | P12 | H | H | P12 | H | H | H |
| 2636 | O | Ar36 | P12 | H | H | P12 | H | H | H |
| 2637 | O | Ar37 | P12 | H | H | P12 | H | H | H |
| 2638 | O | Ar38 | P12 | H | H | P12 | H | H | H |
| 2639 | O | Ar39 | P12 | H | H | P12 | H | H | H |
| 2640 | O | Ar40 | P12 | H | H | P12 | H | H | H |
| 2641 | O | Ar41 | P12 | H | H | P12 | H | H | H |
| 2642 | O | Ar42 | P12 | H | H | P12 | H | H | H |
| 2643 | O | Ar43 | P12 | H | H | P12 | H | H | H |
| 2644 | O | Ar44 | P12 | H | H | P12 | H | H | H |
| 2645 | O | Ar45 | P12 | H | H | P12 | H | H | H |
| 2646 | O | Ar46 | P12 | H | H | P12 | H | H | H |
| 2647 | O | Ar47 | P12 | H | H | P12 | H | H | H |
| 2648 | O | Ar48 | P12 | H | H | P12 | H | H | H |
| 2649 | O | Ar49 | P12 | H | H | P12 | H | H | H |
| 2650 | O | Ar50 | P12 | H | H | P12 | H | H | H |
| 2651 | O | Ar51 | P12 | H | H | P12 | H | H | H |
| 2652 | O | Ar52 | P12 | H | H | P12 | H | H | H |
| 2653 | O | Ar53 | P12 | H | H | P12 | H | H | H |
| 2654 | O | Ar54 | P12 | H | H | P12 | H | H | H |
| 2655 | O | Ar55 | P12 | H | H | P12 | H | H | H |
| 2656 | O | Ar56 | P12 | H | H | P12 | H | H | H |
| 2657 | O | Ar57 | P12 | H | H | P12 | H | H | H |
| 2658 | O | Ar58 | P12 | H | H | P12 | H | H | H |
| 2659 | O | Ar59 | P12 | H | H | P12 | H | H | H |
| 2660 | O | Ar60 | P12 | H | H | P12 | H | H | H |
| 2661 | O | Ar61 | P12 | H | H | P12 | H | H | H |
| 2662 | O | Ar62 | P12 | H | H | P12 | H | H | H |
| 2663 | O | Ar63 | P12 | H | H | P12 | H | H | H |
| 2664 | O | Ar64 | P12 | H | H | P12 | H | H | H |
| 2665 | O | Ar65 | P12 | H | H | P12 | H | H | H |
| 2666 | O | Ar66 | P12 | H | H | P12 | H | H | H |
| 2667 | O | Ar67 | P1 | H | H | P12 | H | H | H |
| 2668 | O | Ar68 | P12 | H | H | P12 | H | H | H |
| 2669 | O | Ar69 | P12 | H | H | P12 | H | H | H |
| 2670 | O | Ar70 | P12 | H | H | P12 | H | H | H |
| 2671 | O | Ar71 | P12 | H | H | P12 | H | H | H |
| 2672 | O | Ar72 | P12 | H | H | P12 | H | H | H |
| 2673 | O | Ar73 | P12 | H | H | P12 | H | H | H |
| 2674 | O | Ar74 | P12 | H | H | P12 | H | H | H |
| 2675 | O | Ar75 | P12 | H | H | P12 | H | H | H |
| 2676 | O | Ar76 | P12 | H | H | P12 | H | H | H |
| 2677 | O | Ar77 | P12 | H | H | P12 | H | H | H |
| 2678 | O | Ar78 | P12 | H | H | P12 | H | H | H |
| 2679 | O | Ar79 | P12 | H | H | P12 | H | H | H |
| 2680 | O | Ar80 | P12 | H | H | P12 | H | H | H |
| 2681 | O | Ar81 | P12 | H | H | P12 | H | H | H |
| 2682 | O | Ar82 | P12 | H | H | P12 | H | H | H |
| 2683 | O | Ar83 | P12 | H | H | P12 | H | H | H |
| 2684 | O | Ar84 | P12 | H | H | P12 | H | H | H |
| 2685 | O | Ar85 | P12 | H | H | P12 | H | H | H |
| 2686 | O | Ar86 | P12 | H | H | P12 | H | H | H |
| 2687 | O | Ar87 | P12 | H | H | P12 | H | H | H |
| 2688 | O | Ar88 | P12 | H | H | P12 | H | H | H |
| 2689 | O | Ar89 | P12 | H | H | P12 | H | H | H |
| 2690 | O | Ar90 | P12 | H | H | P12 | H | H | H |
| 2691 | O | Ar91 | P12 | H | H | P12 | H | H | H |
| 2692 | O | Ar92 | P12 | H | H | P12 | H | H | H |
| 2693 | O | Ar93 | P12 | H | H | P12 | H | H | H |
| 2694 | O | Ar94 | P12 | H | H | P12 | H | H | H |
| 2695 | O | Ar95 | P12 | H | H | P12 | H | H | H |
| 2696 | O | Ar96 | P12 | H | H | P12 | H | H | H |
| 2697 | O | Ar97 | P12 | H | H | P12 | H | H | H |
| 2698 | O | Ar98 | P12 | H | H | P12 | H | H | H |
| 2699 | O | Ar99 | P12 | H | H | P12 | H | H | H |
| 2700 | O | Ar100 | P12 | H | H | P12 | H | H | H |
| 2701 | O | Ar101 | P12 | H | H | P12 | H | H | H |
| 2702 | O | Ar102 | P12 | H | H | P12 | H | H | H |
| 2703 | O | Ar103 | P12 | H | H | P12 | H | H | H |
| 2704 | O | Ar104 | P12 | H | H | P12 | H | H | H |
| 2705 | O | Ar1 | H | H | P1 | P6 | H | H | H |
| 2706 | O | Ar2 | H | H | P1 | P6 | H | H | H |
| 2707 | O | Ar3 | H | H | P1 | P6 | H | H | H |
| 2708 | O | Ar4 | H | H | P1 | P6 | H | H | H |
| 2709 | O | Ar5 | H | H | P1 | P6 | H | H | H |
| 2710 | O | Ar6 | H | H | P1 | P6 | H | H | H |
| 2711 | O | Ar7 | H | H | P1 | P6 | H | H | H |
| 2712 | O | Ar8 | H | H | P1 | P6 | H | H | H |
| 2713 | O | Ar9 | H | H | P1 | P6 | H | H | H |
| 2714 | O | Ar10 | H | H | P1 | P6 | H | H | H |
| 2715 | O | Ar11 | H | H | P1 | P6 | H | H | H |
| 2716 | O | Ar12 | H | H | P1 | P6 | H | H | H |
| 2717 | O | Ar13 | H | H | P1 | P6 | H | H | H |
| 2718 | O | Ar14 | H | H | P1 | P6 | H | H | H |
| 2719 | O | Ar15 | H | H | P1 | P6 | H | H | H |
| 2720 | O | Ar16 | H | H | P1 | P6 | H | H | H |
| 2721 | O | Ar17 | H | H | P1 | P6 | H | H | H |
| 2722 | O | Ar18 | H | H | P1 | P6 | H | H | H |
| 2723 | O | Ar19 | H | H | P1 | P6 | H | H | H |
| 2724 | O | Ar20 | H | H | P1 | P6 | H | H | H |
| 2725 | O | Ar21 | H | H | P1 | P6 | H | H | H |
| 2726 | O | Ar22 | H | H | P1 | P6 | H | H | H |
| 2727 | O | Ar23 | H | H | P1 | P6 | H | H | H |
| 2728 | O | Ar24 | H | H | P1 | P6 | H | H | H |
| 2729 | O | Ar25 | H | H | P1 | P6 | H | H | H |
| 2730 | O | Ar26 | H | H | P1 | P6 | H | H | H |
| 2731 | O | Ar27 | H | H | P1 | P6 | H | H | H |
| 2732 | O | Ar28 | H | H | P1 | P6 | H | H | H |
| 2733 | O | Ar29 | H | H | P1 | P6 | H | H | H |
| 2734 | O | Ar30 | H | H | P1 | P6 | H | H | H |
| 2735 | O | Ar31 | H | H | P1 | P6 | H | H | H |
| 2736 | O | Ar32 | H | H | P1 | P6 | H | H | H |
| 2737 | O | Ar33 | H | H | P1 | P6 | H | H | H |
| 2738 | O | Ar34 | H | H | P1 | P6 | H | H | H |
| 2739 | O | Ar35 | H | H | P1 | P6 | H | H | H |
| 2740 | O | Ar36 | H | H | P1 | P6 | H | H | H |
| 2741 | O | Ar37 | H | H | P1 | P6 | H | H | H |
| 2742 | O | Ar38 | H | H | P1 | P6 | H | H | H |
| 2743 | O | Ar39 | H | H | P1 | P6 | H | H | H |
| 2744 | O | Ar40 | H | H | P1 | P6 | H | H | H |
| 2745 | O | Ar41 | H | H | P1 | P6 | H | H | H |
| 2746 | O | Ar42 | H | H | P1 | P6 | H | H | H |
| 2747 | O | Ar43 | H | H | P1 | P6 | H | H | H |
| 2748 | O | Ar44 | H | H | P1 | P6 | H | H | H |
| 2749 | O | Ar45 | H | H | P1 | P6 | H | H | H |
| 2750 | O | Ar46 | H | H | P1 | P6 | H | H | H |
| 2751 | O | Ar47 | H | H | P1 | P6 | H | H | H |
| 2752 | O | Ar48 | H | H | P1 | P6 | H | H | H |
| 2753 | O | Ar49 | H | H | P1 | P6 | H | H | H |
| 2754 | O | Ar50 | H | H | P1 | P6 | H | H | H |
| 2755 | O | Ar51 | H | H | P1 | P6 | H | H | H |
| 2756 | O | Ar52 | H | H | P1 | P6 | H | H | H |
| 2757 | O | Ar53 | H | H | P1 | P6 | H | H | H |
| 2758 | O | Ar54 | H | H | P1 | P6 | H | H | H |
| 2759 | O | Ar55 | H | H | P1 | P6 | H | H | H |
| 2760 | O | Ar56 | H | H | P1 | P6 | H | H | H |
| 2761 | O | Ar57 | H | H | P1 | P6 | H | H | H |
| 2762 | O | Ar58 | H | H | P1 | P6 | H | H | H |
| 2763 | O | Ar59 | H | H | P1 | P6 | H | H | H |
| 2764 | O | Ar60 | H | H | P1 | P6 | H | H | H |
| 2765 | O | Ar61 | H | H | P1 | P6 | H | H | H |
| 2766 | O | Ar62 | H | H | P1 | P6 | H | H | H |
| 2767 | O | Ar63 | H | H | P1 | P6 | H | H | H |
| 2768 | O | Ar64 | H | H | P1 | P6 | H | H | H |
| 2769 | O | Ar65 | H | H | P1 | P6 | H | H | H |
| 2770 | O | Ar66 | H | H | P1 | P6 | H | H | H |
| 2771 | O | Ar67 | H | H | P1 | P6 | H | H | H |
| 2772 | O | Ar68 | H | H | P1 | P6 | H | H | H |
| 2773 | O | Ar69 | H | H | P1 | P6 | H | H | H |
| 2774 | O | Ar70 | H | H | P1 | P6 | H | H | H |
| 2775 | O | Ar71 | H | H | P1 | P6 | H | H | H |
| 2776 | O | Ar72 | H | H | P1 | P6 | H | H | H |
| 2777 | O | Ar73 | H | H | P1 | P6 | H | H | H |
| 2778 | O | Ar74 | H | H | P1 | P6 | H | H | H |
| 2779 | O | Ar75 | H | H | P1 | P6 | H | H | H |
| 2780 | O | Ar76 | H | H | P1 | P6 | H | H | H |
| 2781 | O | Ar77 | H | H | P1 | P6 | H | H | H |
| 2782 | O | Ar78 | H | H | P1 | P6 | H | H | H |
| 2783 | O | Ar79 | H | H | P1 | P6 | H | H | H |
| 2784 | O | Ar80 | H | H | P1 | P6 | H | H | H |
| 2785 | O | Ar81 | H | H | P1 | P6 | H | H | H |
| 2786 | O | Ar82 | H | H | P1 | P6 | H | H | H |
| 2787 | O | Ar83 | H | H | P1 | P6 | H | H | H |
| 2788 | O | Ar84 | H | H | P1 | P6 | H | H | H |
| 2789 | O | Ar85 | H | H | P1 | P6 | H | H | H |
| 2790 | O | Ar86 | H | H | P1 | P6 | H | H | H |
| 2791 | O | Ar87 | H | H | P1 | P6 | H | H | H |
| 2792 | O | Ar88 | H | H | P1 | P6 | H | H | H |
| 2793 | O | Ar89 | H | H | P1 | P6 | H | H | H |
| 2794 | O | Ar90 | H | H | P1 | P6 | H | H | H |
| 2795 | O | Ar91 | H | H | P1 | P6 | H | H | H |
| 2796 | O | Ar92 | H | H | P1 | P6 | H | H | H |
| 2797 | O | Ar93 | H | H | P1 | P6 | H | H | H |
| 2798 | O | Ar94 | H | H | P1 | P6 | H | H | H |
| 2799 | O | Ar95 | H | H | P1 | P6 | H | H | H |
| 2800 | O | Ar96 | H | H | P1 | P6 | H | H | H |
| 2801 | O | Ar97 | H | H | P1 | P6 | H | H | H |
| 2802 | O | Ar98 | H | H | P1 | P6 | H | H | H |
| 2803 | O | Ar99 | H | H | P1 | P6 | H | H | H |
| 2804 | O | Ar100 | H | H | P1 | P6 | H | H | H |
| 2805 | O | Ar101 | H | H | P1 | P6 | H | H | H |
| 2806 | O | Ar102 | H | H | P1 | P6 | H | H | H |
| 2807 | O | Ar103 | H | H | P1 | P6 | H | H | H |
| 2808 | O | Ar104 | H | H | P1 | P6 | H | H | H |
| 2809 | O | Ar1 | H | H | P2 | P8 | H | H | H |
| 2810 | O | Ar2 | H | H | P2 | P8 | H | H | H |
| 2811 | O | Ar3 | H | H | P2 | P8 | H | H | H |
| 2812 | O | Ar4 | H | H | P2 | P8 | H | H | H |
| 2813 | O | Ar5 | H | H | P2 | P8 | H | H | H |
| 2814 | O | Ar6 | H | H | P2 | P8 | H | H | H |
| 2815 | O | Ar7 | H | H | P2 | P8 | H | H | H |
| 2816 | O | Ar8 | H | H | P2 | P8 | H | H | H |
| 2817 | O | Ar9 | H | H | P2 | P8 | H | H | H |
| 2818 | O | Ar10 | H | H | P2 | P8 | H | H | H |
| 2819 | O | Ar11 | H | H | P2 | P8 | H | H | H |
| 2820 | O | Ar12 | H | H | P2 | P8 | H | H | H |
| 2821 | O | Ar13 | H | H | P2 | P8 | H | H | H |
| 2822 | O | Ar14 | H | H | P2 | P8 | H | H | H |
| 2823 | O | Ar15 | H | H | P2 | P8 | H | H | H |
| 2824 | O | Ar16 | H | H | P2 | P8 | H | H | H |
| 2825 | O | Ar17 | H | H | P2 | P8 | H | H | H |
| 2826 | O | Ar18 | H | H | P2 | P8 | H | H | H |
| 2827 | O | Ar19 | H | H | P2 | P8 | H | H | H |
| 2828 | O | Ar20 | H | H | P2 | P8 | H | H | H |
| 2829 | O | Ar21 | H | H | P2 | P8 | H | H | H |
| 2830 | O | Ar22 | H | H | P2 | P8 | H | H | H |
| 2831 | O | Ar23 | H | H | P2 | P8 | H | H | H |
| 2832 | O | Ar24 | H | H | P2 | P8 | H | H | H |
| 2833 | O | Ar25 | H | H | P2 | P8 | H | H | H |
| 2834 | O | Ar26 | H | H | P2 | P8 | H | H | H |
| 2835 | O | Ar27 | H | H | P2 | P8 | H | H | H |
| 2836 | O | Ar28 | H | H | P2 | P8 | H | H | H |
| 2837 | O | Ar29 | H | H | P2 | P8 | H | H | H |
| 2838 | O | Ar30 | H | H | P2 | P8 | H | H | H |
| 2839 | O | Ar31 | H | H | P2 | P8 | H | H | H |
| 2840 | O | Ar32 | H | H | P2 | P8 | H | H | H |
| 2841 | O | Ar33 | H | H | P2 | P8 | H | H | H |
| 2842 | O | Ar34 | H | H | P2 | P8 | H | H | H |
| 2843 | O | Ar35 | H | H | P2 | P8 | H | H | H |
| 2844 | O | Ar36 | H | H | P2 | P8 | H | H | H |
| 2845 | O | Ar37 | H | H | P2 | P8 | H | H | H |
| 2846 | O | Ar38 | H | H | P2 | P8 | H | H | H |
| 2847 | O | Ar39 | H | H | P2 | P8 | H | H | H |
| 2848 | O | Ar40 | H | H | P2 | P8 | H | H | H |
| 2849 | O | Ar41 | H | H | P2 | P8 | H | H | H |
| 2850 | O | Ar42 | H | H | P2 | P8 | H | H | H |
| 2851 | O | Ar43 | H | H | P2 | P8 | H | H | H |
| 2852 | O | Ar44 | H | H | P2 | P8 | H | H | H |
| 2853 | O | Ar45 | H | H | P2 | P8 | H | H | H |
| 2854 | O | Ar46 | H | H | P2 | P8 | H | H | H |
| 2855 | O | Ar47 | H | H | P2 | P8 | H | H | H |
| 2856 | O | Ar48 | H | H | P2 | P8 | H | H | H |
| 2857 | O | Ar49 | H | H | P2 | P8 | H | H | H |
| 2858 | O | Ar50 | H | H | P2 | P8 | H | H | H |
| 2859 | O | Ar51 | H | H | P2 | P8 | H | H | H |
| 2860 | O | Ar52 | H | H | P2 | P8 | H | H | H |
| 2861 | O | Ar53 | H | H | P2 | P8 | H | H | H |
| 2862 | O | Ar54 | H | H | P2 | P8 | H | H | H |
| 2863 | O | Ar55 | H | H | P2 | P8 | H | H | H |
| 2864 | O | Ar56 | H | H | P2 | P8 | H | H | H |
| 2865 | O | Ar57 | H | H | P2 | P8 | H | H | H |
| 2866 | O | Ar58 | H | H | P2 | P8 | H | H | H |
| 2867 | O | Ar59 | H | H | P2 | P8 | H | H | H |
| 2868 | O | Ar60 | H | H | P2 | P8 | H | H | H |
| 2869 | O | Ar61 | H | H | P2 | P8 | H | H | H |
| 2870 | O | Ar62 | H | H | P2 | P8 | H | H | H |
| 2871 | O | Ar63 | H | H | P2 | P8 | H | H | H |
| 2872 | O | Ar64 | H | H | P2 | P8 | H | H | H |
| 2873 | O | Ar65 | H | H | P2 | P8 | H | H | H |
| 2874 | O | Ar66 | H | H | P2 | P8 | H | H | H |
| 2875 | O | Ar67 | H | H | P2 | P8 | H | H | H |
| 2876 | O | Ar68 | H | H | P2 | P8 | H | H | H |
| 2877 | O | Ar69 | H | H | P2 | P8 | H | H | H |
| 2878 | O | Ar70 | H | H | P2 | P8 | H | H | H |
| 2879 | O | Ar71 | H | H | P2 | P8 | H | H | H |
| 2880 | O | Ar72 | H | H | P2 | P8 | H | H | H |
| 2881 | O | Ar73 | H | H | P2 | P8 | H | H | H |
| 2882 | O | Ar74 | H | H | P2 | P8 | H | H | H |
| 2883 | O | Ar75 | H | H | P2 | P8 | H | H | H |
| 2884 | O | Ar76 | H | H | P2 | P8 | H | H | H |
| 2885 | O | Ar77 | H | H | P2 | P8 | H | H | H |
| 2886 | O | Ar78 | H | H | P2 | P8 | H | H | H |
| 2887 | O | Ar79 | H | H | P2 | P8 | H | H | H |
| 2888 | O | Ar80 | H | H | P2 | P8 | H | H | H |
| 2889 | O | Ar81 | H | H | P2 | P8 | H | H | H |
| 2890 | O | Ar82 | H | H | P2 | P8 | H | H | H |
| 2891 | O | Ar83 | H | H | P2 | P8 | H | H | H |
| 2892 | O | Ar84 | H | H | P2 | P8 | H | H | H |
| 2893 | O | Ar85 | H | H | P2 | P8 | H | H | H |
| 2894 | O | Ar86 | H | H | P2 | P8 | H | H | H |
| 2895 | O | Ar87 | H | H | P2 | P8 | H | H | H |
| 2896 | O | Ar88 | H | H | P2 | P8 | H | H | H |
| 2897 | O | Ar89 | H | H | P2 | P8 | H | H | H |
| 2898 | O | Ar90 | H | H | P2 | P8 | H | H | H |
| 2899 | O | Ar91 | H | H | P2 | P8 | H | H | H |
| 2900 | O | Ar92 | H | H | P2 | P8 | H | H | H |
| 2901 | O | Ar93 | H | H | P2 | P8 | H | H | H |
| 2902 | O | Ar94 | H | H | P2 | P8 | H | H | H |
| 2903 | O | Ar95 | H | H | P2 | P8 | H | H | H |
| 2904 | O | Ar96 | H | H | P2 | P8 | H | H | H |
| 2905 | O | Ar97 | H | H | P2 | P8 | H | H | H |
| 2906 | O | Ar98 | H | H | P2 | P8 | H | H | H |
| 2907 | O | Ar99 | H | H | P2 | P8 | H | H | H |
| 2908 | O | Ar100 | H | H | P2 | P8 | H | H | H |
| 2909 | O | Ar101 | H | H | P2 | P8 | H | H | H |
| 2910 | O | Ar102 | H | H | P2 | P8 | H | H | H |
| 2911 | O | Ar103 | H | H | P2 | P8 | H | H | H |
| 2912 | O | Ar104 | H | H | P2 | P8 | H | H | H |
| 2913 | O | Ar1 | P1 | P1 | H | P8 | H | H | H |
| 2914 | O | Ar1 | P1 | P2 | H | P8 | H | H | H |
| 2915 | O | Ar1 | P1 | P3 | H | P8 | H | H | H |
| 2916 | O | Ar1 | P1 | P4 | H | P8 | H | H | H |
| 2917 | O | Ar1 | P1 | P5 | H | P8 | H | H | H |
| 2918 | O | Ar1 | P1 | P6 | H | P8 | H | H | H |
| 2919 | O | Ar1 | P1 | P7 | H | P8 | H | H | H |
| 2920 | O | Ar1 | P1 | P8 | H | P8 | H | H | H |
| 2921 | O | Ar1 | P1 | P9 | H | P8 | H | H | H |
| 2922 | O | Ar1 | P1 | P10 | H | P8 | H | H | H |
| 2923 | O | Ar1 | P1 | P11 | H | P8 | H | H | H |
| 2924 | O | Ar1 | P1 | P12 | H | P8 | H | H | H |
| 2925 | O | Ar1 | P1 | P13 | H | P8 | H | H | H |
| 2926 | O | Ar1 | P1 | P14 | H | P8 | H | H | H |
| 2927 | O | Ar1 | P1 | P15 | H | P8 | H | H | H |
| 2928 | O | Ar1 | P2 | P1 | H | P8 | H | H | H |
| 2929 | O | Ar1 | P2 | P2 | H | P8 | H | H | H |
| 2930 | O | Ar1 | P2 | P3 | H | P8 | H | H | H |
| 2931 | O | Ar1 | P2 | P4 | H | P8 | H | H | H |
| 2932 | O | Ar1 | P2 | P5 | H | P8 | H | H | H |
| 2933 | O | Ar1 | P2 | P6 | H | P8 | H | H | H |
| 2934 | O | Ar1 | P2 | P7 | H | P8 | H | H | H |
| 2935 | O | Ar1 | P2 | P8 | H | P8 | H | H | H |
| 2936 | O | Ar1 | P2 | P9 | H | P8 | H | H | H |
| 2937 | O | Ar1 | P2 | P1 | H | P8 | H | H | H |
| 2938 | O | Ar1 | P2 | P1 | H | P8 | H | H | H |
| 2939 | O | Ar1 | P2 | P12 | H | P8 | H | H | H |
| 2940 | O | Ar1 | P2 | P13 | H | P8 | H | H | H |
| 2941 | O | Ar1 | P2 | F | H | P8 | H | H | H |
| 2942 | O | Ar1 | P2 | P15 | H | P8 | H | H | H |
| 2943 | O | Ar1 | P1 | P1 | H | P12 | H | H | H |
| 2944 | O | Ar1 | P1 | P2 | H | P12 | H | H | H |
| 2945 | O | Ar1 | P1 | P3 | H | P12 | H | H | H |
| 2946 | O | Ar1 | P1 | P4 | H | P12 | H | H | H |
| 2947 | O | Ar1 | P1 | P5 | H | P12 | H | H | H |
| 2948 | O | Ar1 | P1 | P6 | H | P12 | H | H | H |
| 2949 | O | Ar1 | P1 | P7 | H | P12 | H | H | H |
| 2950 | O | Ar1 | P1 | P8 | H | P12 | H | H | H |
| 2951 | O | Ar1 | P1 | P9 | H | P12 | H | H | H |
| 2952 | O | Ar1 | P1 | P10 | H | P12 | H | H | H |
| 2953 | O | Ar1 | P1 | P11 | H | P12 | H | H | H |
| 2954 | O | Ar1 | P1 | P12 | H | P12 | H | H | H |
| 2955 | O | Ar1 | P1 | P13 | H | P12 | H | H | H |
| 2956 | O | Ar1 | P1 | P14 | H | P12 | H | H | H |
| 2957 | O | Ar1 | P1 | F | H | P12 | H | H | H |
| 2958 | O | Ar1 | P2 | P1 | H | P12 | H | H | H |
| 2959 | O | Ar1 | P2 | P2 | H | P12 | H | H | H |
| 2960 | O | Ar1 | P2 | P3 | H | P12 | H | H | H |
| 2961 | O | Ar1 | P2 | P4 | H | P12 | H | H | H |
| 2962 | O | Ar1 | P2 | P5 | H | P12 | H | H | H |
| 2963 | O | Ar1 | P2 | P6 | H | P12 | H | H | H |
| 2964 | O | Ar1 | P2 | P7 | H | P12 | H | H | H |
| 2965 | O | Ar1 | P2 | P8 | H | P12 | H | H | H |
| 2966 | O | Ar1 | P2 | P9 | H | P12 | H | H | H |
| 2967 | O | Ar1 | P2 | P10 | H | P12 | H | H | H |
| 2968 | O | Ar1 | P2 | P11 | H | P12 | H | H | H |
| 2969 | O | Ar1 | P2 | P12 | H | P12 | H | H | H |
| 2970 | O | Ar1 | P2 | P13 | H | P12 | H | H | H |
| 2971 | O | Ar1 | P2 | P14 | H | P12 | H | H | H |
| 2972 | O | Ar1 | P2 | P15 | H | P12 | H | H | H |
| 2973 | O | Ar2 | P1 | P1 | H | P8 | H | H | H |
| 2974 | O | Ar2 | P1 | P2 | H | P8 | H | H | H |
| 2975 | O | Ar2 | P1 | P3 | H | P8 | H | H | H |
| 2976 | O | Ar2 | P1 | P4 | H | P8 | H | H | H |
| 2977 | O | Ar2 | P1 | P5 | H | P8 | H | H | H |
| 2978 | O | Ar2 | P1 | P6 | H | P8 | H | H | H |
| 2979 | O | Ar2 | P1 | P7 | H | P8 | H | H | H |
| 2980 | O | Ar2 | P1 | P8 | H | P8 | H | H | H |
| 2981 | O | Ar2 | P1 | P9 | H | P8 | H | H | H |
| 2982 | O | Ar2 | P1 | P10 | H | P8 | H | H | H |
| 2983 | O | Ar2 | P1 | P11 | H | P8 | H | H | H |
| 2984 | O | Ar2 | P1 | P12 | H | P8 | H | H | H |
| 2985 | O | Ar2 | P1 | P13 | H | P8 | H | H | H |
| 2986 | O | Ar2 | P1 | F | H | P8 | H | H | H |
| 2987 | O | Ar2 | P1 | P15 | H | P8 | H | H | H |
| 2988 | O | Ar2 | P2 | P1 | H | P8 | H | H | H |
| 2989 | O | Ar2 | P2 | P2 | H | P8 | H | H | H |
| 2990 | O | Ar2 | P2 | P3 | H | P8 | H | H | H |
| 2991 | O | Ar2 | P2 | P4 | H | P8 | H | H | H |
| 2992 | O | Ar2 | P2 | P5 | H | P8 | H | H | H |
| 2993 | O | Ar2 | P2 | P6 | H | P8 | H | H | H |
| 2994 | O | Ar2 | P2 | P7 | H | P8 | H | H | H |
| 2995 | O | Ar2 | P2 | P8 | H | P8 | H | H | H |
| 2996 | O | Ar2 | P2 | P9 | H | P8 | H | H | H |
| 2997 | O | Ar2 | P2 | P10 | H | P8 | H | H | H |
| 2998 | O | Ar2 | P2 | P11 | H | P8 | H | H | H |
| 2999 | O | Ar2 | P2 | P12 | H | P8 | H | H | H |
| 3000 | O | Ar2 | P2 | P13 | H | P8 | H | H | H |
| 3001 | O | Ar2 | P2 | P14 | H | P8 | H | H | H |
| 3002 | O | Ar2 | P2 | P15 | H | P8 | H | H | H |
| 3003 | O | Ar2 | P1 | P1 | H | P12 | H | H | H |
| 3004 | O | Ar2 | P1 | P2 | H | P12 | H | H | H |
| 3005 | O | Ar2 | P1 | P3 | H | P12 | H | H | H |
| 3006 | O | Ar2 | P1 | P4 | H | P12 | H | H | H |
| 3007 | O | Ar2 | P1 | P5 | H | P12 | H | H | H |
| 3008 | O | Ar2 | P1 | P6 | H | P12 | H | H | H |
| 3009 | O | Ar2 | P1 | P7 | H | P12 | H | H | H |
| 3010 | O | Ar2 | P1 | P8 | H | P12 | H | H | H |
| 3011 | O | Ar2 | P1 | P9 | H | P12 | H | H | H |
| 3012 | O | Ar2 | P1 | P10 | H | P12 | H | H | H |
| 3013 | O | Ar2 | P1 | P11 | H | P12 | H | H | H |
| 3014 | O | Ar2 | P1 | P12 | H | P12 | H | H | H |
| 3015 | O | Ar2 | P1 | F | H | P12 | H | H | H |
| 3016 | O | Ar2 | P1 | P14 | H | P12 | H | H | H |
| 3017 | O | Ar2 | P1 | P15 | H | P12 | H | H | H |
| 3018 | O | Ar2 | P2 | P1 | H | P12 | H | H | H |
| 3019 | O | Ar2 | P2 | P2 | H | P12 | H | H | H |
| 3020 | O | Ar2 | P2 | P3 | H | P12 | H | H | H |
| 3021 | O | Ar2 | P2 | P4 | H | P12 | H | H | H |
| 3022 | O | Ar2 | P2 | P5 | H | P12 | H | H | H |
| 3023 | O | Ar2 | P2 | P6 | H | P12 | H | H | H |
| 3024 | O | Ar2 | P2 | P7 | H | P12 | H | H | H |
| 3025 | O | Ar2 | P2 | P8 | H | P12 | H | H | H |
| 3026 | O | Ar2 | P2 | P9 | H | P12 | H | H | H |
| 3027 | O | Ar2 | P2 | P10 | H | P12 | H | H | H |
| 3028 | O | Ar2 | P2 | P11 | H | P12 | H | H | H |
| 3029 | O | Ar2 | P2 | P12 | H | P12 | H | H | H |
| 3030 | O | Ar2 | P2 | P13 | H | P12 | H | H | H |
| 3031 | O | Ar2 | P2 | P14 | H | P12 | H | H | H |
| 3032 | O | Ar2 | P2 | P15 | H | P12 | H | H | H |
| 3033 | O | Ar31 | P1 | P1 | H | P8 | H | H | H |
| 3034 | O | Ar31 | P1 | P2 | H | P8 | H | H | H |
| 3035 | O | Ar31 | P1 | F | H | P8 | H | H | H |
| 3036 | O | Ar31 | P1 | P4 | H | P8 | H | H | H |
| 3037 | O | Ar31 | P1 | P5 | H | P8 | H | H | H |
| 3038 | O | Ar31 | P1 | P6 | H | P8 | H | H | H |
| 3039 | O | Ar31 | P1 | P7 | H | P8 | H | H | H |
| 3040 | O | Ar31 | P1 | P8 | H | P8 | H | H | H |
| 3041 | O | Ar31 | P1 | P9 | H | P8 | H | H | H |
| 3042 | O | Ar31 | P1 | P10 | H | P8 | H | H | H |
| 3043 | O | Ar31 | P1 | P11 | H | P8 | H | H | H |
| 3044 | O | Ar31 | P1 | P12 | H | P8 | H | H | H |
| 3045 | O | Ar31 | P1 | P13 | H | P8 | H | H | H |
| 3046 | O | Ar31 | P1 | P14 | H | P8 | H | H | H |
| 3047 | O | Ar31 | P1 | P15 | H | P8 | H | H | H |
| 3048 | O | Ar31 | P2 | P1 | H | P8 | H | H | H |
| 3049 | O | Ar31 | P2 | P2 | H | P8 | H | H | H |
| 3050 | O | Ar31 | P2 | P3 | H | P8 | H | H | H |
| 3051 | O | Ar31 | P2 | P4 | H | P8 | H | H | H |
| 3052 | O | Ar31 | P2 | P5 | H | P8 | H | H | H |
| 3053 | O | Ar31 | P2 | P6 | H | P8 | H | H | H |
| 3054 | O | Ar31 | P2 | P7 | H | P8 | H | H | H |
| 3055 | O | Ar31 | P2 | P8 | H | P8 | H | H | H |
| 3056 | O | Ar31 | P2 | P9 | H | P8 | H | H | H |
| 3057 | O | Ar31 | P2 | P10 | H | P8 | H | H | H |
| 3058 | O | Ar31 | P2 | P11 | H | P8 | H | H | H |
| 3059 | O | Ar31 | P2 | P12 | H | P8 | H | H | H |
| 3060 | O | Ar31 | P2 | P13 | H | P8 | H | H | H |
| 3061 | O | Ar31 | P2 | P14 | H | P8 | H | H | H |
| 3062 | O | Ar31 | P2 | P15 | H | P8 | H | H | H |
| 3063 | O | Ar31 | P1 | P1 | H | P12 | H | H | H |
| 3064 | O | Ar31 | P1 | P2 | H | P12 | H | H | H |
| 3065 | O | Ar31 | P1 | P3 | H | P12 | H | H | H |
| 3066 | O | Ar31 | P1 | P4 | H | P12 | H | H | H |
| 3067 | O | Ar31 | P1 | P5 | H | P12 | H | H | H |
| 3068 | O | Ar31 | P1 | P6 | H | P12 | H | H | H |
| 3069 | O | Ar31 | P1 | P7 | H | P12 | H | H | H |
| 3070 | O | Ar31 | P1 | P8 | H | P12 | H | H | H |
| 3071 | O | Ar31 | P1 | P9 | H | P12 | H | H | H |
| 3072 | O | Ar31 | P1 | P10 | H | P12 | H | H | H |
| 3073 | O | Ar31 | P1 | P11 | H | P12 | H | H | H |
| 3074 | O | Ar31 | P1 | P12 | H | P12 | H | H | H |
| 3075 | O | Ar31 | P1 | P13 | H | P12 | H | H | H |
| 3076 | O | Ar31 | P1 | P14 | H | P12 | H | H | H |
| 3077 | O | Ar31 | P1 | P15 | H | P12 | H | H | H |
| 3078 | O | Ar31 | P1 | F | H | P12 | H | H | H |
| 3079 | O | Ar31 | P2 | P1 | H | P12 | H | H | H |
| 3080 | O | Ar31 | P2 | P2 | H | P12 | H | H | H |
| 3081 | O | Ar31 | P2 | P3 | H | P12 | H | H | H |
| 3082 | O | Ar31 | P2 | P4 | H | P12 | H | H | H |
| 3083 | O | Ar31 | P2 | P5 | H | P12 | H | H | H |
| 3084 | O | Ar31 | P2 | P6 | H | P12 | H | H | H |
| 3085 | O | Ar31 | P2 | P7 | H | P12 | H | H | H |
| 3086 | O | Ar31 | P2 | P8 | H | P12 | H | H | H |
| 3087 | O | Ar31 | P2 | P9 | H | P12 | H | H | H |
| 3088 | O | Ar31 | P2 | P10 | H | P12 | H | H | H |
| 3089 | O | Ar31 | P2 | P11 | H | P12 | H | H | H |
| 3090 | O | Ar31 | P2 | P12 | H | P12 | H | H | H |
| 3091 | O | Ar31 | P2 | P13 | H | P12 | H | H | H |
| 3092 | O | Ar31 | P2 | P14 | H | P12 | H | H | H |
| 3093 | O | Ar31 | P2 | P15 | H | P12 | H | H | H |
| 3094 | O | Ar31 | P2 | F | H | P12 | H | H | H |
| 3095 | O | Ar32 | P1 | P1 | H | P8 | H | H | H |
| 3096 | O | Ar32 | P1 | P2 | H | P8 | H | H | H |
| 3097 | O | Ar32 | P1 | P3 | H | P8 | H | H | H |
| 3098 | O | Ar32 | P1 | P4 | H | P8 | H | H | H |
| 3099 | O | Ar32 | P1 | P5 | H | P8 | H | H | H |
| 3100 | O | Ar32 | P1 | P6 | H | P8 | H | H | H |
| 3101 | O | Ar32 | P1 | P7 | H | P8 | H | H | H |
| 3102 | O | Ar32 | P1 | P8 | H | P8 | H | H | H |
| 3103 | O | Ar32 | P1 | P9 | H | P8 | H | H | H |
| 3104 | O | Ar32 | P1 | P10 | H | P8 | H | H | H |
| 3105 | O | Ar32 | P1 | P11 | H | P8 | H | H | H |
| 3106 | O | Ar32 | P1 | P12 | H | P8 | H | H | H |
| 3107 | O | Ar32 | P1 | P13 | H | P8 | H | H | H |
| 3108 | O | Ar32 | P1 | P14 | H | P8 | H | H | H |
| 3109 | O | Ar32 | P1 | P15 | H | P8 | H | H | H |
| 3110 | O | Ar32 | P1 | F | H | P8 | H | H | H |
| 3111 | O | Ar32 | P2 | P1 | H | P8 | H | H | H |
| 3112 | O | Ar32 | P2 | P2 | H | P8 | H | H | H |
| 3113 | O | Ar32 | P2 | P3 | H | P8 | H | H | H |
| 3114 | O | Ar32 | P2 | P4 | H | P8 | H | H | H |
| 3115 | O | Ar32 | P2 | P5 | H | P8 | H | H | H |
| 3116 | O | Ar32 | P2 | P6 | H | P8 | H | H | H |
| 3117 | O | Ar32 | P2 | P7 | H | P8 | H | H | H |
| 3118 | O | Ar32 | P2 | P8 | H | P8 | H | H | H |
| 3119 | O | Ar32 | P2 | P9 | H | P8 | H | H | H |
| 3120 | O | Ar32 | P2 | P10 | H | P8 | H | H | H |
| 3121 | O | Ar32 | P2 | P11 | H | P8 | H | H | H |
| 3122 | O | Ar32 | P2 | P12 | H | P8 | H | H | H |
| 3123 | O | Ar32 | P2 | P13 | H | P8 | H | H | H |
| 3124 | O | Ar32 | P2 | P14 | H | P8 | H | H | H |
| 3125 | O | Ar32 | P2 | P15 | H | P8 | H | H | H |
| 3126 | O | Ar32 | P2 | F | H | P8 | H | H | H |
| 3127 | O | Ar32 | P1 | P1 | H | P12 | H | H | H |
| 3128 | O | Ar32 | P1 | P2 | H | P12 | H | H | H |
| 3129 | O | Ar32 | P1 | P3 | H | P12 | H | H | H |
| 3130 | O | Ar32 | P1 | P4 | H | P12 | H | H | H |
| 3131 | O | Ar32 | P1 | P5 | H | P12 | H | H | H |
| 3132 | O | Ar32 | P1 | P6 | H | P12 | H | H | H |
| 3133 | O | Ar32 | P1 | P7 | H | P12 | H | H | H |
| 3134 | O | Ar32 | P1 | P8 | H | P12 | H | H | H |
| 3135 | O | Ar32 | P1 | P9 | H | P12 | H | H | H |
| 3136 | O | Ar32 | P1 | P10 | H | P12 | H | H | H |
| 3137 | O | Ar32 | P1 | P11 | H | P12 | H | H | H |
| 3138 | O | Ar32 | P1 | P12 | H | P12 | H | H | H |
| 3139 | O | Ar32 | P1 | P13 | H | P12 | H | H | H |
| 3140 | O | Ar32 | P1 | P14 | H | P12 | H | H | H |
| 3141 | O | Ar32 | P1 | P15 | H | P12 | H | H | H |
| 3142 | O | Ar32 | P1 | F | H | P12 | H | H | H |
| 3143 | O | Ar32 | P2 | P1 | H | P12 | H | H | H |
| 3144 | O | Ar32 | P2 | P2 | H | P12 | H | H | H |
| 3145 | O | Ar32 | P2 | P3 | H | P12 | H | H | H |
| 3146 | O | Ar32 | P2 | P4 | H | P12 | H | H | H |
| 3147 | O | Ar32 | P2 | P5 | H | P12 | H | H | H |
| 3148 | O | Ar32 | P2 | P6 | H | P12 | H | H | H |
| 3149 | O | Ar32 | P2 | P7 | H | P12 | H | H | H |
| 3150 | O | Ar32 | P2 | P8 | H | P12 | H | H | H |
| 3151 | O | Ar32 | P2 | P9 | H | P12 | H | H | H |
| 3152 | O | Ar32 | P2 | P10 | H | P12 | H | H | H |
| 3153 | O | Ar32 | P2 | P11 | H | P12 | H | H | H |
| 3154 | O | Ar32 | P2 | P12 | H | P12 | H | H | H |
| 3155 | O | Ar32 | P2 | P13 | H | P12 | H | H | H |
| 3156 | O | Ar32 | P2 | P14 | H | P12 | H | H | H |
| 3157 | O | Ar32 | P2 | P15 | H | P12 | H | H | H |
| 3158 | O | Ar32 | P2 | F | H | P12 | H | H | H |
| 3159 | O | Ar35 | P1 | P1 | H | P8 | H | H | H |
| 3160 | O | Ar35 | P1 | P2 | H | P8 | H | H | H |
| 3161 | O | Ar35 | P1 | P3 | H | P8 | H | H | H |
| 3162 | O | Ar35 | P1 | P4 | H | P8 | H | H | H |
| 3163 | O | Ar35 | P1 | P5 | H | P8 | H | H | H |
| 3164 | O | Ar35 | P1 | P6 | H | P8 | H | H | H |
| 3165 | O | Ar35 | P1 | P7 | H | P8 | H | H | H |
| 3166 | O | Ar35 | P1 | P8 | H | P8 | H | H | H |
| 3167 | O | Ar35 | P1 | P9 | H | P8 | H | H | H |
| 3168 | O | Ar35 | P1 | P10 | H | P8 | H | H | H |
| 3169 | O | Ar35 | P1 | P11 | H | P8 | H | H | H |
| 3170 | O | Ar35 | P1 | P12 | H | P8 | H | H | H |
| 3171 | O | Ar35 | P1 | P13 | H | P8 | H | H | H |
| 3172 | O | Ar35 | P1 | P14 | H | P8 | H | H | H |
| 3173 | O | Ar35 | P1 | P15 | H | P8 | H | H | H |
| 3174 | O | Ar35 | P1 | F | H | P8 | H | H | H |
| 3175 | O | Ar35 | P2 | P1 | H | P8 | H | H | H |
| 3176 | O | Ar35 | P2 | P2 | H | P8 | H | H | H |
| 3177 | O | Ar35 | P2 | P3 | H | P8 | H | H | H |
| 3178 | O | Ar35 | P2 | P4 | H | P8 | H | H | H |
| 3179 | O | Ar35 | P2 | P5 | H | P8 | H | H | H |
| 3180 | O | Ar35 | P2 | P6 | H | P8 | H | H | H |
| 3181 | O | Ar35 | P2 | P7 | H | P8 | H | H | H |
| 3182 | O | Ar35 | P2 | P8 | H | P8 | H | H | H |
| 3183 | O | Ar35 | P2 | P9 | H | P8 | H | H | H |
| 3184 | O | Ar35 | P2 | P10 | H | P8 | H | H | H |
| 3185 | O | Ar35 | P2 | P11 | H | P8 | H | H | H |
| 3186 | O | Ar35 | P2 | P12 | H | P8 | H | H | H |
| 3187 | O | Ar35 | P2 | P13 | H | P8 | H | H | H |
| 3188 | O | Ar35 | P2 | P14 | H | P8 | H | H | H |
| 3189 | O | Ar35 | P2 | P15 | H | P8 | H | H | H |
| 3190 | O | Ar35 | P2 | F | H | P8 | H | H | H |
| 3191 | O | Ar35 | P1 | P1 | H | P12 | H | H | H |
| 3192 | O | Ar35 | P1 | P2 | H | P12 | H | H | H |
| 3193 | O | Ar35 | P1 | P3 | H | P12 | H | H | H |
| 3194 | O | Ar35 | P1 | P4 | H | P12 | H | H | H |
| 3195 | O | Ar35 | P1 | P5 | H | P12 | H | H | H |
| 3196 | O | Ar35 | P1 | P6 | H | P12 | H | H | H |
| 3197 | O | Ar35 | P1 | P7 | H | P12 | H | H | H |
| 3198 | O | Ar35 | P1 | P8 | H | P12 | H | H | H |
| 3199 | O | Ar35 | P1 | P9 | H | P12 | H | H | H |
| 3200 | O | Ar35 | P1 | P10 | H | P12 | H | H | H |
| 3201 | O | Ar35 | P1 | P11 | H | P12 | H | H | H |
| 3202 | O | Ar35 | P1 | P12 | H | P12 | H | H | H |
| 3203 | O | Ar35 | P1 | P13 | H | P12 | H | H | H |
| 3204 | O | Ar35 | P1 | P14 | H | P12 | H | H | H |
| 3205 | O | Ar35 | P1 | P15 | H | P12 | H | H | H |
| 3206 | O | Ar35 | P1 | F | H | P12 | H | H | H |
| 3207 | O | Ar35 | P2 | P1 | H | P12 | H | H | H |
| 3208 | O | Ar35 | P2 | P2 | H | P12 | H | H | H |
| 3209 | O | Ar35 | P2 | P3 | H | P12 | H | H | H |
| 3210 | O | Ar35 | P2 | P4 | H | P12 | H | H | H |
| 3211 | O | Ar35 | P2 | P5 | H | P12 | H | H | H |
| 3212 | O | Ar35 | P2 | P6 | H | P12 | H | H | H |
| 3213 | O | Ar35 | P2 | P7 | H | P12 | H | H | H |
| 3214 | O | Ar35 | P2 | P8 | H | P12 | H | H | H |
| 3215 | O | Ar35 | P2 | P9 | H | P12 | H | H | H |
| 3216 | O | Ar35 | P2 | P10 | H | P12 | H | H | H |
| 3217 | O | Ar35 | P2 | P11 | H | P12 | H | H | H |
| 3218 | O | Ar35 | P2 | P12 | H | P12 | H | H | H |
| 3219 | O | Ar35 | P2 | P13 | H | P12 | H | H | H |
| 3220 | O | Ar35 | P2 | P14 | H | P12 | H | H | H |
| 3221 | O | Ar35 | P2 | P15 | H | P12 | H | H | H |
| 3222 | O | Ar35 | P2 | F | H | P12 | H | H | H |
| 3223 | O | Ar1 | P1 | H | H | P3 | H | H | H |
| 3224 | O | Ar1 | P1 | H | H | P4 | H | H | H |
| 3225 | O | Ar1 | P1 | H | H | P5 | H | H | H |
| 3226 | O | Ar1 | P1 | H | P1 | P6 | H | H | H |
| 3227 | O | Ar1 | P1 | H | H | P7 | H | H | H |
| 3228 | O | Ar1 | P1 | H | H | P9 | H | H | H |
| 3229 | O | Ar1 | P1 | H | H | P10 | H | H | H |
| 3230 | O | Ar1 | P1 | H | H | P13 | H | H | H |
| 3231 | O | Ar1 | P1 | H | H | P14 | H | H | H |
| 3232 | O | Ar1 | P1 | H | H | P15 | H | H | H |
| 3233 | O | Ar1 | P1 | H | H | P16 | H | H | H |
| 3234 | O | Ar1 | P1 | H | H | P17 | H | H | H |
| 3235 | O | Ar1 | P1 | H | H | P18 | H | H | H |
| 3236 | O | Ar1 | P1 | H | H | P19 | H | H | H |
| 3237 | O | Ar1 | P1 | H | H | P20 | H | H | H |
| 3238 | O | Ar1 | P1 | H | H | P21 | H | H | H |
| 3239 | O | Ar1 | P1 | H | H | P22 | H | H | H |
| 3240 | O | Ar1 | P1 | H | H | P23 | H | H | H |
| 3241 | O | Ar1 | P1 | H | H | P24 | H | H | H |
| 3242 | O | Ar1 | P1 | H | H | P25 | H | H | H |
| 3243 | O | Ar1 | P1 | H | H | P26 | H | H | H |
| 3244 | O | Ar1 | P1 | H | H | P27 | H | H | H |
| 3245 | O | Ar1 | P1 | H | H | P28 | H | H | H |
| 3246 | O | Ar1 | P2 | H | H | P3 | H | H | H |
| 3247 | O | Ar1 | P2 | H | H | P4 | H | H | H |
| 3248 | O | Ar1 | P2 | H | H | P5 | H | H | H |
| 3249 | O | Ar1 | P2 | H | P2 | P6 | H | H | H |
| 3250 | O | Ar1 | P2 | H | H | P7 | H | H | H |
| 3251 | O | Ar1 | P2 | H | H | P9 | H | H | H |
| 3252 | O | Ar1 | P2 | H | H | P10 | H | H | H |
| 3253 | O | Ar1 | P2 | H | H | P13 | H | H | H |
| 3254 | O | Ar1 | P2 | H | H | P14 | H | H | H |
| 3255 | O | Ar1 | P2 | H | H | P15 | H | H | H |
| 3256 | O | Ar1 | P2 | H | H | P16 | H | H | H |
| 3257 | O | Ar1 | P2 | H | H | P17 | H | H | H |
| 3258 | O | Ar1 | P2 | H | H | P18 | H | H | H |
| 3259 | O | Ar1 | P2 | H | H | P19 | H | H | H |
| 3260 | O | Ar1 | P2 | H | H | P20 | H | H | H |
| 3261 | O | Ar1 | P2 | H | H | P21 | H | H | H |
| 3262 | O | Ar1 | P2 | H | H | P22 | H | H | H |
| 3263 | O | Ar1 | P2 | H | H | P23 | H | H | H |
| 3264 | O | Ar1 | P2 | H | H | P24 | H | H | H |
| 3265 | O | Ar1 | P2 | H | H | P25 | H | H | H |
| 3266 | O | Ar1 | P2 | H | H | P26 | H | H | H |
| 3267 | O | Ar1 | P2 | H | H | P27 | H | H | H |
| 3268 | O | Ar1 | P2 | H | H | P28 | H | H | H |
| 3269 | O | Ar31 | P1 | H | H | P3 | H | H | H |
| 3270 | O | Ar31 | P1 | H | H | P4 | H | H | H |
| 3271 | O | Ar31 | P1 | H | H | P5 | H | H | H |
| 3272 | O | Ar31 | P1 | P8 | H | P6 | H | H | H |
| 3273 | O | Ar31 | P1 | H | H | P7 | H | H | H |
| 3274 | O | Ar31 | P1 | H | H | P9 | H | H | H |
| 3275 | O | Ar31 | P1 | H | H | P10 | H | H | H |
| 3276 | O | Ar31 | P1 | H | H | P13 | H | H | H |
| 3277 | O | Ar31 | P1 | H | H | P14 | H | H | H |
| 3278 | O | Ar31 | P1 | H | H | P15 | H | H | H |
| 3279 | O | Ar31 | P1 | H | H | P16 | H | H | H |
| 3280 | O | Ar31 | P1 | H | H | P17 | H | H | H |
| 3281 | O | Ar31 | P1 | H | H | P18 | H | H | H |
| 3282 | O | Ar31 | P1 | H | H | P19 | H | H | H |
| 3283 | O | Ar31 | P1 | H | H | P20 | H | H | H |
| 3284 | O | Ar31 | P1 | H | H | P21 | H | H | H |
| 3285 | O | Ar31 | P1 | H | H | P22 | H | H | H |
| 3286 | O | Ar31 | P1 | H | H | P23 | H | H | H |
| 3287 | O | Ar31 | P1 | H | H | P24 | H | H | H |
| 3288 | O | Ar31 | P1 | H | H | P25 | H | H | H |
| 3289 | O | Ar31 | P1 | H | H | P26 | H | H | H |
| 3290 | O | Ar31 | P1 | H | H | P27 | H | H | H |
| 3291 | O | Ar31 | P1 | H | H | P28 | H | H | H |
| 3292 | O | Ar31 | P2 | H | H | P3 | H | H | H |
| 3293 | O | Ar31 | P2 | H | H | P4 | H | H | H |
| 3294 | O | Ar31 | P2 | H | H | P5 | H | H | H |
| 3295 | O | Ar31 | P2 | F | H | P6 | H | H | H |
| 3296 | O | Ar31 | P2 | H | H | P7 | H | H | H |
| 3297 | O | Ar31 | P2 | H | H | P9 | H | H | H |
| 3298 | O | Ar31 | P2 | H | H | P10 | H | H | H |
| 3299 | O | Ar31 | P2 | H | H | P13 | H | H | H |
| 3300 | O | Ar31 | P2 | H | H | P14 | H | H | H |
| 3301 | O | Ar31 | P2 | H | H | P15 | H | H | H |
| 3302 | O | Ar31 | P2 | H | H | P16 | H | H | H |
| 3303 | O | Ar31 | P2 | H | H | P17 | H | H | H |
| 3304 | O | Ar31 | P2 | H | H | P18 | H | H | H |
| 3305 | O | Ar31 | P2 | H | H | P19 | H | H | H |
| 3306 | O | Ar31 | P2 | H | H | P2 | H | H | H |
| 3307 | O | Ar31 | P2 | H | H | P21 | H | H | H |
| 3308 | O | Ar31 | P2 | H | H | P22 | H | H | H |
| 3309 | O | Ar31 | P2 | H | H | P23 | H | H | H |
| 3310 | O | Ar31 | P2 | H | H | P2 | H | H | H |
| 3311 | O | Ar31 | P2 | H | H | P25 | H | H | H |
| 3312 | O | Ar31 | P2 | H | H | P26 | H | H | H |
| 3313 | O | Ar31 | P2 | H | H | P27 | H | H | H |
| 3314 | O | Ar31 | P2 | H | H | P28 | H | H | H |
| 3315 | S | Ar1 | P1 | H | H | P12 | H | H | H |
| 3316 | S | Ar2 | P1 | H | H | P12 | H | H | H |
| 3317 | S | Ar3 | P1 | H | H | P12 | H | H | H |
| 3318 | S | Ar4 | P1 | H | H | P12 | H | H | H |
| 3319 | S | Ar5 | P1 | H | H | P12 | H | H | H |
| 3320 | S | Ar6 | P1 | H | H | P12 | H | H | H |
| 3321 | S | Ar7 | P1 | H | H | P12 | H | H | H |
| 3322 | S | Ar8 | P1 | H | H | P12 | H | H | H |
| 3323 | S | Ar9 | P1 | H | H | P12 | H | H | H |
| 3324 | S | Ar10 | P1 | H | H | P12 | H | H | H |
| 3325 | S | Ar11 | P1 | H | H | P12 | H | H | H |
| 3326 | S | Ar12 | P1 | H | H | P12 | H | H | H |
| 3327 | S | Ar13 | P1 | H | H | P12 | H | H | H |
| 3328 | S | Ar14 | P1 | H | H | P12 | H | H | H |
| 3329 | S | Ar15 | P1 | H | H | P12 | H | H | H |
| 3330 | S | Ar16 | P1 | H | H | P12 | H | H | H |
| 3331 | S | Ar17 | P1 | H | H | P12 | H | H | H |
| 3332 | S | Ar18 | P1 | H | H | P12 | H | H | H |
| 3333 | S | Ar19 | P1 | H | H | P12 | H | H | H |
| 3334 | S | Ar20 | P1 | H | H | P12 | H | H | H |
| 3335 | S | Ar21 | P1 | H | H | P12 | H | H | H |
| 3336 | S | Ar22 | P1 | H | H | P12 | H | H | H |
| 3337 | S | Ar23 | P1 | H | H | P12 | H | H | H |
| 3338 | S | Ar24 | P1 | H | H | P12 | H | H | H |
| 3339 | S | Ar25 | P1 | H | H | P12 | H | H | H |
| 3340 | S | Ar26 | P1 | H | H | P12 | H | H | H |
| 3341 | S | Ar27 | P1 | H | H | P12 | H | H | H |
| 3342 | S | Ar28 | P1 | H | H | P12 | H | H | H |
| 3343 | S | Ar29 | P1 | H | H | P12 | H | H | H |
| 3344 | S | Ar30 | P1 | H | H | P12 | H | H | H |
| 3345 | S | Ar31 | P1 | H | H | P12 | H | H | H |
| 3346 | S | Ar32 | P1 | H | H | P12 | H | H | H |
| 3347 | S | Ar33 | P1 | H | H | P12 | H | H | H |
| 3348 | S | Ar34 | P1 | H | H | P12 | H | H | H |
| 3349 | S | Ar35 | P1 | H | H | P12 | H | H | H |
| 3350 | S | Ar36 | P1 | H | H | P12 | H | H | H |
| 3351 | S | Ar37 | P1 | H | H | P12 | H | H | H |
| 3352 | S | Ar38 | P1 | H | H | P12 | H | H | H |
| 3353 | S | Ar39 | P1 | H | H | P12 | H | H | H |
| 3354 | S | Ar40 | P1 | H | H | P12 | H | H | H |
| 3355 | S | Ar41 | P1 | H | H | P12 | H | H | H |
| 3356 | S | Ar42 | P1 | H | H | P12 | H | H | H |
| 3357 | S | Ar43 | P1 | H | H | P12 | H | H | H |
| 3358 | S | Ar44 | P1 | H | H | P12 | H | H | H |
| 3359 | S | Ar45 | P1 | H | H | P12 | H | H | H |
| 3360 | S | Ar46 | P1 | H | H | P12 | H | H | H |
| 3361 | S | Ar47 | P1 | H | H | P12 | H | H | H |
| 3362 | S | Ar48 | P1 | H | H | P12 | H | H | H |
| 3363 | S | Ar49 | P1 | H | H | P12 | H | H | H |
| 3364 | S | Ar50 | P1 | H | H | P12 | H | H | H |
| 3365 | S | Ar51 | P1 | H | H | P12 | H | H | H |
| 3366 | S | Ar52 | P1 | H | H | P12 | H | H | H |
| 3367 | S | Ar53 | P1 | H | H | P12 | H | H | H |
| 3368 | S | Ar54 | P1 | H | H | P12 | H | H | H |
| 3369 | S | Ar55 | P1 | H | H | P12 | H | H | H |
| 3370 | S | Ar56 | P1 | H | H | P12 | H | H | H |
| 3371 | S | Ar57 | P1 | H | H | P12 | H | H | H |
| 3372 | S | Ar58 | P1 | H | H | P12 | H | H | H |
| 3373 | S | Ar59 | P1 | H | H | P12 | H | H | H |
| 3374 | S | Ar60 | P1 | H | H | P12 | H | H | H |
| 3375 | S | Ar61 | P1 | H | H | P12 | H | H | H |
| 3376 | S | Ar62 | P1 | H | H | P12 | H | H | H |
| 3377 | S | Ar63 | P1 | H | H | P12 | H | H | H |
| 3378 | S | Ar64 | P1 | H | H | P12 | H | H | H |
| 3379 | S | Ar65 | P1 | H | H | P12 | H | H | H |
| 3380 | S | Ar66 | P1 | H | H | P12 | H | H | H |
| 3381 | S | Ar67 | P1 | H | H | P12 | H | H | H |
| 3382 | S | Ar68 | P1 | H | H | P12 | H | H | H |
| 3383 | S | Ar69 | P1 | H | H | P12 | H | H | H |
| 3384 | S | Ar70 | P1 | H | H | P12 | H | H | H |
| 3385 | S | Ar71 | P1 | H | H | P12 | H | H | H |
| 3386 | S | Ar72 | P1 | H | H | P12 | H | H | H |
| 3387 | S | Ar73 | P1 | H | H | P12 | H | H | H |
| 3388 | S | Ar74 | P1 | H | H | P12 | H | H | H |
| 3389 | S | Ar75 | P1 | H | H | P12 | H | H | H |
| 3390 | S | Ar76 | P1 | H | H | P12 | H | H | H |
| 3391 | S | Ar77 | P1 | H | H | P12 | H | H | H |
| 3392 | S | Ar78 | P1 | H | H | P12 | H | H | H |
| 3393 | S | Ar79 | P1 | H | H | P12 | H | H | H |
| 3394 | S | Ar80 | P1 | H | H | P12 | H | H | H |
| 3395 | S | Ar81 | P1 | H | H | P12 | H | H | H |
| 3396 | S | Ar82 | P1 | H | H | P12 | H | H | H |
| 3397 | S | Ar83 | P1 | H | H | P12 | H | H | H |
| 3398 | S | Ar84 | P1 | H | H | P12 | H | H | H |
| 3399 | S | Ar85 | P1 | H | H | P12 | H | H | H |
| 3400 | S | Ar86 | P1 | H | H | P12 | H | H | H |
| 3401 | S | Ar87 | P1 | H | H | P12 | H | H | H |
| 3402 | S | Ar88 | P1 | H | H | P12 | H | H | H |
| 3403 | S | Ar89 | P1 | H | H | P12 | H | H | H |
| 3404 | S | Ar90 | P1 | H | H | P12 | H | H | H |
| 3405 | S | Ar91 | P1 | H | H | P12 | H | H | H |
| 3406 | S | Ar92 | P1 | H | H | P12 | H | H | H |
| 3407 | S | Ar93 | P1 | H | H | P12 | H | H | H |
| 3408 | S | Ar94 | P1 | H | H | P12 | H | H | H |
| 3409 | S | Ar95 | P1 | H | H | P12 | H | H | H |
| 3410 | S | Ar96 | P1 | H | H | P12 | H | H | H |
| 3411 | S | Ar97 | P1 | H | H | P12 | H | H | H |
| 3412 | S | Ar98 | P1 | H | H | P12 | H | H | H |
| 3413 | S | Ar99 | P1 | H | H | P12 | H | H | H |
| 3414 | S | Ar100 | P1 | H | H | P12 | H | H | H |
| 3415 | S | Ar101 | P1 | H | H | P12 | H | H | H |
| 3416 | S | Ar102 | P1 | H | H | P12 | H | H | H |
| 3417 | S | Ar103 | P1 | H | H | P12 | H | H | H |
| 3418 | S | Ar104 | P1 | H | H | P12 | H | H | H |
| 3419 | S | Ar1 | P2 | H | H | P12 | H | H | H |
| 3420 | S | Ar2 | P2 | H | H | P12 | H | H | H |
| 3421 | S | Ar3 | P2 | H | H | P12 | H | H | H |
| 3422 | S | Ar4 | P2 | H | H | P12 | H | H | H |
| 3423 | S | Ar5 | P2 | H | H | P12 | H | H | H |
| 3424 | S | Ar6 | P2 | H | H | P12 | H | H | H |
| 3425 | S | Ar7 | P2 | H | H | P12 | H | H | H |
| 3426 | S | Ar8 | P2 | H | H | P12 | H | H | H |
| 3427 | S | Ar9 | P2 | H | H | P12 | H | H | H |
| 3428 | S | Ar10 | P2 | H | H | P12 | H | H | H |
| 3429 | S | Ar11 | P2 | H | H | P12 | H | H | H |
| 3430 | S | Ar12 | P2 | H | H | P12 | H | H | H |
| 3431 | S | Ar13 | P2 | H | H | P12 | H | H | H |
| 3432 | S | Ar14 | P2 | H | H | P12 | H | H | H |
| 3433 | S | Ar15 | P2 | H | H | P12 | H | H | H |
| 3434 | S | Ar16 | P2 | H | H | P12 | H | H | H |
| 3435 | S | Ar17 | P2 | H | H | P12 | H | H | H |
| 3436 | S | Ar18 | P2 | H | H | P12 | H | H | H |
| 3437 | S | Ar19 | P2 | H | H | P12 | H | H | H |
| 3438 | S | Ar20 | P2 | H | H | P12 | H | H | H |
| 3439 | S | Ar21 | P2 | H | H | P12 | H | H | H |
| 3440 | S | Ar22 | P2 | H | H | P12 | H | H | H |
| 3441 | S | Ar23 | P2 | H | H | P12 | H | H | H |
| 3442 | S | Ar24 | P2 | H | H | P12 | H | H | H |
| 3443 | S | Ar25 | P2 | H | H | P12 | H | H | H |
| 3444 | S | Ar26 | P2 | H | H | P12 | H | H | H |
| 3445 | S | Ar27 | P2 | H | H | P12 | H | H | H |
| 3446 | S | Ar28 | P2 | H | H | P12 | H | H | H |
| 3447 | S | Ar29 | P2 | H | H | P12 | H | H | H |
| 3448 | S | Ar30 | P2 | H | H | P12 | H | H | H |
| 3449 | S | Ar31 | P2 | H | H | P12 | H | H | H |
| 3450 | S | Ar32 | P2 | H | H | P12 | H | H | H |
| 3451 | S | Ar33 | P2 | H | H | P12 | H | H | H |
| 3452 | S | Ar34 | P2 | H | H | P12 | H | H | H |
| 3453 | S | Ar35 | P2 | H | H | P12 | H | H | H |
| 3454 | S | Ar36 | P2 | H | H | P12 | H | H | H |
| 3455 | S | Ar37 | P2 | H | H | P12 | H | H | H |
| 3456 | S | Ar38 | P2 | H | H | P12 | H | H | H |
| 3457 | S | Ar39 | P2 | H | H | P12 | H | H | H |
| 3458 | S | Ar40 | P2 | H | H | P12 | H | H | H |
| 3459 | S | Ar41 | P2 | H | H | P12 | H | H | H |
| 3460 | S | Ar42 | P2 | H | H | P12 | H | H | H |
| 3461 | S | Ar43 | P2 | H | H | P12 | H | H | H |
| 3462 | S | Ar44 | P2 | H | H | P12 | H | H | H |
| 3463 | S | Ar45 | P2 | H | H | P12 | H | H | H |
| 3464 | S | Ar46 | P2 | H | H | P12 | H | H | H |
| 3465 | S | Ar47 | P2 | H | H | P12 | H | H | H |
| 3466 | S | Ar48 | P2 | H | H | P12 | H | H | H |
| 3467 | S | Ar49 | P2 | H | H | P12 | H | H | H |
| 3468 | S | Ar50 | P2 | H | H | P12 | H | H | H |
| 3469 | S | Ar51 | P2 | H | H | P12 | H | H | H |
| 3470 | S | Ar52 | P2 | H | H | P12 | H | H | H |
| 3471 | S | Ar53 | P2 | H | H | P12 | H | H | H |
| 3472 | S | Ar54 | P2 | H | H | P12 | H | H | H |
| 3473 | S | Ar55 | P2 | H | H | P12 | H | H | H |
| 3474 | S | Ar56 | P2 | H | H | P12 | H | H | H |
| 3475 | S | Ar57 | P2 | H | H | P12 | H | H | H |
| 3476 | S | Ar58 | P2 | H | H | P12 | H | H | H |
| 3477 | S | Ar59 | P2 | H | H | P12 | H | H | H |
| 3478 | S | Ar60 | P2 | H | H | P12 | H | H | H |
| 3479 | S | Ar61 | P2 | H | H | P12 | H | H | H |
| 3480 | S | Ar62 | P2 | H | H | P12 | H | H | H |
| 3481 | S | Ar63 | P2 | H | H | P12 | H | H | H |
| 3482 | S | Ar64 | P2 | H | H | P12 | H | H | H |
| 3483 | S | Ar65 | P2 | H | H | P12 | H | H | H |
| 3484 | S | Ar66 | P2 | H | H | P12 | H | H | H |
| 3485 | S | Ar67 | P2 | H | H | P12 | H | H | H |
| 3486 | S | Ar68 | P2 | H | H | P12 | H | H | H |
| 3487 | S | Ar69 | P2 | H | H | P12 | H | H | H |
| 3488 | S | Ar70 | P2 | H | H | P12 | H | H | H |
| 3489 | S | Ar71 | P2 | H | H | P12 | H | H | H |
| 3490 | S | Ar72 | P2 | H | H | P12 | H | H | H |
| 3491 | S | Ar73 | P2 | H | H | P12 | H | H | H |
| 3492 | S | Ar74 | P2 | H | H | P12 | H | H | H |
| 3493 | S | Ar75 | P2 | H | H | P12 | H | H | H |
| 3494 | S | Ar76 | P2 | H | H | P12 | H | H | H |
| 3495 | S | Ar77 | P2 | H | H | P12 | H | H | H |
| 3496 | S | Ar78 | P2 | H | H | P12 | H | H | H |
| 3497 | S | Ar79 | P2 | H | H | P12 | H | H | H |
| 3498 | S | Ar80 | P2 | H | H | P12 | H | H | H |
| 3499 | S | Ar81 | P2 | H | H | P12 | H | H | H |
| 3500 | S | Ar82 | P2 | H | H | P12 | H | H | H |
| 3501 | S | Ar83 | P2 | H | H | P12 | H | H | H |
| 3502 | S | Ar84 | P2 | H | H | P12 | H | H | H |
| 3503 | S | Ar85 | P2 | H | H | P12 | H | H | H |
| 3504 | S | Ar86 | P2 | H | H | P12 | H | H | H |
| 3505 | S | Ar87 | P2 | H | H | P12 | H | H | H |
| 3506 | S | Ar88 | P2 | H | H | P12 | H | H | H |
| 3507 | S | Ar89 | P2 | H | H | P12 | H | H | H |
| 3508 | S | Ar90 | P2 | H | H | P12 | H | H | H |
| 3509 | S | Ar91 | P2 | H | H | P12 | H | H | H |
| 3510 | S | Ar92 | P2 | H | H | P12 | H | H | H |
| 3511 | S | Ar93 | P2 | H | H | P12 | H | H | H |
| 3512 | S | Ar94 | P2 | H | H | P12 | H | H | H |
| 3513 | S | Ar95 | P2 | H | H | P12 | H | H | H |
| 3514 | S | Ar96 | P2 | H | H | P12 | H | H | H |
| 3515 | S | Ar97 | P2 | H | H | P12 | H | H | H |
| 3516 | S | Ar98 | P2 | H | H | P12 | H | H | H |
| 3517 | S | Ar99 | P2 | H | H | P12 | H | H | H |
| 3518 | S | Ar100 | P2 | H | H | P12 | H | H | H |
| 3519 | S | Ar101 | P2 | H | H | P12 | H | H | H |
| 3520 | S | Ar102 | P2 | H | H | P12 | H | H | H |
| 3521 | S | Ar103 | P2 | H | H | P12 | H | H | H |
| 3522 | S | Ar104 | P2 | H | H | P12 | H | H | H |
| 3523 | S | Ar1 | P11 | H | H | P12 | H | H | H |
| 3524 | S | Ar2 | P11 | H | H | P12 | H | H | H |
| 3525 | S | Ar3 | P11 | H | H | P12 | H | H | H |
| 3526 | S | Ar4 | P11 | H | H | P12 | H | H | H |
| 3527 | S | Ar5 | P11 | H | H | P12 | H | H | H |
| 3528 | S | Ar6 | P11 | H | H | P12 | H | H | H |
| 3529 | S | Ar7 | P11 | H | H | P12 | H | H | H |
| 3530 | S | Ar8 | P11 | H | H | P12 | H | H | H |
| 3531 | S | Ar9 | P11 | H | H | P12 | H | H | H |
| 3532 | S | Ar10 | P11 | H | H | P12 | H | H | H |
| 3533 | S | Ar11 | P11 | H | H | P12 | H | H | H |
| 3534 | S | Ar12 | P11 | H | H | P12 | H | H | H |
| 3535 | S | Ar13 | P11 | H | H | P12 | H | H | H |
| 3536 | S | Ar14 | P11 | H | H | P12 | H | H | H |
| 3537 | S | Ar15 | P11 | H | H | P12 | H | H | H |
| 3538 | S | Ar16 | P11 | H | H | P12 | H | H | H |
| 3539 | S | Ar17 | P11 | H | H | P12 | H | H | H |
| 3540 | S | Ar18 | P11 | H | H | P12 | H | H | H |
| 3541 | S | Ar19 | P11 | H | H | P12 | H | H | H |
| 3542 | S | Ar20 | P11 | H | H | P12 | H | H | H |
| 3543 | S | Ar21 | P11 | H | H | P12 | H | H | H |
| 3544 | S | Ar22 | P11 | H | H | P12 | H | H | H |
| 3545 | S | Ar23 | P11 | H | H | P12 | H | H | H |
| 3546 | S | Ar24 | P11 | H | H | P12 | H | H | H |
| 3547 | S | Ar25 | P11 | H | H | P12 | H | H | H |
| 3548 | S | Ar26 | P11 | H | H | P12 | H | H | H |
| 3549 | S | Ar27 | P11 | H | H | P12 | H | H | H |
| 3550 | S | Ar28 | P11 | H | H | P12 | H | H | H |
| 3551 | S | Ar29 | P11 | H | H | P12 | H | H | H |
| 3552 | S | Ar30 | P11 | H | H | P12 | H | H | H |
| 3553 | S | Ar31 | P11 | H | H | P12 | H | H | H |
| 3554 | S | Ar32 | P11 | H | H | P12 | H | H | H |
| 3555 | S | Ar33 | P11 | H | H | P12 | H | H | H |
| 3556 | S | Ar34 | P11 | H | H | P12 | H | H | H |
| 3557 | S | Ar35 | P11 | H | H | P12 | H | H | H |
| 3558 | S | Ar36 | P11 | H | H | P12 | H | H | H |
| 3559 | S | Ar37 | P11 | H | H | P12 | H | H | H |
| 3560 | S | Ar38 | P11 | H | H | P12 | H | H | H |
| 3561 | S | Ar39 | P11 | H | H | P12 | H | H | H |
| 3562 | S | Ar40 | P11 | H | H | P12 | H | H | H |
| 3563 | S | Ar41 | P11 | H | H | P12 | H | H | H |
| 3564 | S | Ar42 | P11 | H | H | P12 | H | H | H |
| 3565 | S | Ar43 | P11 | H | H | P12 | H | H | H |
| 3566 | S | Ar44 | P11 | H | H | P12 | H | H | H |
| 3567 | S | Ar45 | P11 | H | H | P12 | H | H | H |
| 3568 | S | Ar46 | P11 | H | H | P12 | H | H | H |
| 3569 | S | Ar47 | P11 | H | H | P12 | H | H | H |
| 3570 | S | Ar48 | P11 | H | H | P12 | H | H | H |
| 3571 | S | Ar49 | P11 | H | H | P12 | H | H | H |
| 3572 | S | Ar50 | P11 | H | H | P12 | H | H | H |
| 3573 | S | Ar51 | P11 | H | H | P12 | H | H | H |
| 3574 | S | Ar52 | P11 | H | H | P12 | H | H | H |
| 3575 | S | Ar53 | P11 | H | H | P12 | H | H | H |
| 3576 | S | Ar54 | P11 | H | H | P12 | H | H | H |
| 3577 | S | Ar55 | P11 | H | H | P12 | H | H | H |
| 3578 | S | Ar56 | P11 | H | H | P12 | H | H | H |
| 3579 | S | Ar57 | P11 | H | H | P12 | H | H | H |
| 3580 | S | Ar58 | P11 | H | H | P12 | H | H | H |
| 3581 | S | Ar59 | P11 | H | H | P12 | H | H | H |
| 3582 | S | Ar60 | P11 | H | H | P12 | H | H | H |
| 3583 | S | Ar61 | P11 | H | H | P12 | H | H | H |
| 3584 | S | Ar62 | P11 | H | H | P12 | H | H | H |
| 3585 | S | Ar63 | P11 | H | H | P12 | H | H | H |
| 3586 | S | Ar64 | P11 | H | H | P12 | H | H | H |
| 3587 | S | Ar65 | P11 | H | H | P12 | H | H | H |
| 3588 | S | Ar66 | P11 | H | H | P12 | H | H | H |
| 3589 | S | Ar67 | P11 | H | H | P12 | H | H | H |
| 3590 | S | Ar68 | P11 | H | H | P12 | H | H | H |
| 3591 | S | Ar69 | P11 | H | H | P12 | H | H | H |
| 3592 | S | Ar70 | P11 | H | H | P12 | H | H | H |
| 3593 | S | Ar71 | P11 | H | H | P12 | H | H | H |
| 3594 | S | Ar72 | P11 | H | H | P12 | H | H | H |
| 3595 | S | Ar73 | P11 | H | H | P12 | H | H | H |
| 3596 | S | Ar74 | P11 | H | H | P12 | H | H | H |
| 3597 | S | Ar75 | P11 | H | H | P12 | H | H | H |
| 3598 | S | Ar76 | P11 | H | H | P12 | H | H | H |
| 3599 | S | Ar77 | P11 | H | H | P12 | H | H | H |
| 3600 | S | Ar78 | P11 | H | H | P12 | H | H | H |
| 3601 | S | Ar79 | P11 | H | H | P12 | H | H | H |
| 3602 | S | Ar80 | P11 | H | H | P12 | H | H | H |
| 3603 | S | Ar81 | P11 | H | H | P12 | H | H | H |
| 3604 | S | Ar82 | P11 | H | H | P12 | H | H | H |
| 3605 | S | Ar83 | P11 | H | H | P12 | H | H | H |
| 3606 | S | Ar84 | P11 | H | H | P12 | H | H | H |
| 3607 | S | Ar85 | P11 | H | H | P12 | H | H | H |
| 3608 | S | Ar86 | P11 | H | H | P12 | H | H | H |
| 3609 | S | Ar87 | P11 | H | H | P12 | H | H | H |
| 3610 | S | Ar88 | P11 | H | H | P12 | H | H | H |
| 3611 | S | Ar89 | P11 | H | H | P12 | H | H | H |
| 3612 | S | Ar90 | P11 | H | H | P12 | H | H | H |
| 3613 | S | Ar91 | P11 | H | H | P12 | H | H | H |
| 3614 | S | Ar92 | P11 | H | H | P12 | H | H | H |
| 3615 | S | Ar93 | P11 | H | H | P12 | H | H | H |
| 3616 | S | Ar94 | P11 | H | H | P12 | H | H | H |
| 3617 | S | Ar95 | P11 | H | H | P12 | H | H | H |
| 3618 | S | Ar96 | P11 | H | H | P12 | H | H | H |
| 3619 | S | Ar97 | P11 | H | H | P12 | H | H | H |
| 3620 | S | Ar98 | P11 | H | H | P12 | H | H | H |
| 3621 | S | Ar99 | P11 | H | H | P12 | H | H | H |
| 3622 | S | Ar100 | P11 | H | H | P12 | H | H | H |
| 3623 | S | Ar101 | P11 | H | H | P12 | H | H | H |
| 3624 | S | Ar102 | P11 | H | H | P12 | H | H | H |
| 3625 | S | Ar103 | P11 | H | H | P12 | H | H | H |
| 3626 | S | Ar104 | P11 | H | H | P12 | H | H | H |
| 3627 | S | Ar1 | P12 | H | H | P12 | H | H | H |
| 3628 | S | Ar2 | P12 | H | H | P12 | H | H | H |
| 3629 | S | Ar3 | P12 | H | H | P12 | H | H | H |
| 3630 | S | Ar4 | P12 | H | H | P12 | H | H | H |
| 3631 | S | Ar5 | P12 | H | H | P12 | H | H | H |
| 3632 | S | Ar6 | P12 | H | H | P12 | H | H | H |
| 3633 | S | Ar7 | P12 | H | H | P12 | H | H | H |
| 3634 | S | Ar8 | P12 | H | H | P12 | H | H | H |
| 3635 | S | Ar9 | P12 | H | H | P12 | H | H | H |
| 3636 | S | Ar10 | P12 | H | H | P12 | H | H | H |
| 3637 | S | Ar11 | P12 | H | H | P12 | H | H | H |
| 3638 | S | Ar12 | P12 | H | H | P12 | H | H | H |
| 3639 | S | Ar13 | P12 | H | H | P12 | H | H | H |
| 3640 | S | Ar14 | P12 | H | H | P12 | H | H | H |
| 3641 | S | Ar15 | P12 | H | H | P12 | H | H | H |
| 3642 | S | Ar16 | P12 | H | H | P12 | H | H | H |
| 3643 | S | Ar17 | P12 | H | H | P12 | H | H | H |
| 3644 | S | Ar18 | P12 | H | H | P12 | H | H | H |
| 3645 | S | Ar19 | P12 | H | H | P12 | H | H | H |
| 3646 | S | Ar20 | P12 | H | H | P12 | H | H | H |
| 3647 | S | Ar21 | P12 | H | H | P12 | H | H | H |
| 3648 | S | Ar22 | P12 | H | H | P12 | H | H | H |
| 3649 | S | Ar23 | P12 | H | H | P12 | H | H | H |
| 3650 | S | Ar24 | P12 | H | H | P12 | H | H | H |
| 3651 | S | Ar25 | P12 | H | H | P12 | H | H | H |
| 3652 | S | Ar26 | P12 | H | H | P12 | H | H | H |
| 3653 | S | Ar27 | P12 | H | H | P12 | H | H | H |
| 3654 | S | Ar28 | P12 | H | H | P12 | H | H | H |
| 3655 | S | Ar29 | P12 | H | H | P12 | H | H | H |
| 3656 | S | Ar30 | P12 | H | H | P12 | H | H | H |
| 3657 | S | Ar31 | P12 | H | H | P12 | H | H | H |
| 3658 | S | Ar32 | P12 | H | H | P12 | H | H | H |
| 3659 | S | Ar33 | P12 | H | H | P12 | H | H | H |
| 3660 | S | Ar34 | P12 | H | H | P12 | H | H | H |
| 3661 | S | Ar35 | P12 | H | H | P12 | H | H | H |
| 3662 | S | Ar36 | P12 | H | H | P12 | H | H | H |
| 3663 | S | Ar37 | P12 | H | H | P12 | H | H | H |
| 3664 | S | Ar38 | P12 | H | H | P12 | H | H | H |
| 3665 | S | Ar39 | P12 | H | H | P12 | H | H | H |
| 3666 | S | Ar40 | P12 | H | H | P12 | H | H | H |
| 3667 | S | Ar41 | P12 | H | H | P12 | H | H | H |
| 3668 | S | Ar42 | P12 | H | H | P12 | H | H | H |
| 3669 | S | Ar43 | P12 | H | H | P12 | H | H | H |
| 3670 | S | Ar44 | P12 | H | H | P12 | H | H | H |
| 3671 | S | Ar45 | P12 | H | H | P12 | H | H | H |
| 3672 | S | Ar46 | P12 | H | H | P12 | H | H | H |
| 3673 | S | Ar47 | P12 | H | H | P12 | H | H | H |
| 3674 | S | Ar48 | P12 | H | H | P12 | H | H | H |
| 3675 | S | Ar49 | P12 | H | H | P12 | H | H | H |
| 3676 | S | Ar50 | P12 | H | H | P12 | H | H | H |
| 3677 | S | Ar51 | P12 | H | H | P12 | H | H | H |
| 3678 | S | Ar52 | P12 | H | H | P12 | H | H | H |
| 3679 | S | Ar53 | P12 | H | H | P12 | H | H | H |
| 3680 | S | Ar54 | P12 | H | H | P12 | H | H | H |
| 3681 | S | Ar55 | P12 | H | H | P12 | H | H | H |
| 3682 | S | Ar56 | P12 | H | H | P12 | H | H | H |
| 3683 | S | Ar57 | P12 | H | H | P12 | H | H | H |
| 3684 | S | Ar58 | P12 | H | H | P12 | H | H | H |
| 3685 | S | Ar59 | P12 | H | H | P12 | H | H | H |
| 3686 | S | Ar60 | P12 | H | H | P12 | H | H | H |
| 3687 | S | Ar61 | P12 | H | H | P12 | H | H | H |
| 3688 | S | Ar62 | P12 | H | H | P12 | H | H | H |
| 3689 | S | Ar63 | P12 | H | H | P12 | H | H | H |
| 3690 | S | Ar64 | P12 | H | H | P12 | H | H | H |
| 3691 | S | Ar65 | P12 | H | H | P12 | H | H | H |
| 3692 | S | Ar66 | P12 | H | H | P12 | H | H | H |
| 3693 | S | Ar67 | P12 | H | H | P12 | H | H | H |
| 3694 | S | Ar68 | P12 | H | H | P12 | H | H | H |
| 3695 | S | Ar69 | P12 | H | H | P12 | H | H | H |
| 3696 | S | Ar70 | P12 | H | H | P12 | H | H | H |
| 3697 | S | Ar71 | P12 | H | H | P12 | H | H | H |
| 3698 | S | Ar72 | P12 | H | H | P12 | H | H | H |
| 3699 | S | Ar73 | P12 | H | H | P12 | H | H | H |
| 3700 | S | Ar74 | P12 | H | H | P12 | H | H | H |
| 3701 | S | Ar75 | P12 | H | H | P12 | H | H | H |
| 3702 | S | Ar76 | P12 | H | H | P12 | H | H | H |
| 3703 | S | Ar77 | P12 | H | H | P12 | H | H | H |
| 3704 | S | Ar78 | P12 | H | H | P12 | H | H | H |
| 3705 | S | Ar79 | P12 | H | H | P12 | H | H | H |
| 3706 | S | Ar80 | P12 | H | H | P12 | H | H | H |
| 3707 | S | Ar81 | P12 | H | H | P12 | H | H | H |
| 3708 | S | Ar82 | P12 | H | H | P12 | H | H | H |
| 3709 | S | Ar83 | P12 | H | H | P12 | H | H | H |
| 3710 | S | Ar84 | P12 | H | H | P12 | H | H | H |
| 3711 | S | Ar85 | P12 | H | H | P12 | H | H | H |
| 3712 | S | Ar86 | P12 | H | H | P12 | H | H | H |
| 3713 | S | Ar87 | P12 | H | H | P12 | H | H | H |
| 3714 | S | Ar88 | P12 | H | H | P12 | H | H | H |
| 3715 | S | Ar89 | P12 | H | H | P12 | H | H | H |
| 3716 | S | Ar90 | P12 | H | H | P12 | H | H | H |
| 3717 | S | Ar91 | P12 | H | H | P12 | H | H | H |
| 3718 | S | Ar92 | P12 | H | H | P12 | H | H | H |
| 3719 | S | Ar93 | P12 | H | H | P12 | H | H | H |
| 3720 | S | Ar94 | P12 | H | H | P12 | H | H | H |
| 3721 | S | Ar95 | P12 | H | H | P12 | H | H | H |
| 3722 | S | Ar96 | P12 | H | H | P12 | H | H | H |
| 3723 | S | Ar97 | P12 | H | H | P12 | H | H | H |
| 3724 | S | Ar98 | P12 | H | H | P12 | H | H | H |
| 3725 | S | Ar99 | P12 | H | H | P12 | H | H | H |
| 3726 | S | Ar100 | P12 | H | H | P12 | H | H | H |
| 3727 | S | Ar101 | P12 | H | H | P12 | H | H | H |
| 3728 | S | Ar102 | P12 | H | H | P12 | H | H | H |
| 3729 | S | Ar103 | P12 | H | H | P12 | H | H | H |
| 3730 | S | Ar104 | P12 | H | H | P12 | H | H | H |
| 3731 | O | Ar1 | P1 | P1 | P1 | P8 | H | H | H |
| 3732 | O | Ar1 | P1 | P2 | P2 | P8 | H | H | H |
| 3733 | O | Ar1 | P1 | P3 | P1 | P8 | H | H | H |
| 3734 | O | Ar1 | P1 | P4 | P1 | P8 | H | H | H |
| 3735 | O | Ar1 | P1 | P5 | P1 | P8 | H | H | H |
| 3736 | O | Ar1 | P1 | P6 | P1 | P8 | H | H | H |
| 3737 | O | Ar1 | P1 | P7 | P1 | P8 | H | H | H |
| 3738 | O | Ar1 | P1 | P8 | P1 | P8 | H | H | H |
| 3739 | O | Ar1 | P1 | P9 | P1 | P8 | H | H | H |
| 3740 | O | Ar1 | P1 | P10 | P1 | P8 | H | H | H |
| 3741 | O | Ar1 | P1 | P11 | P1 | P8 | H | H | H |
| 3742 | O | Ar1 | P1 | P12 | P1 | P8 | H | H | H |
| 3743 | O | Ar1 | P1 | P13 | P1 | P8 | H | H | H |
| 3744 | O | Ar1 | P1 | P14 | P1 | P8 | H | H | H |
| 3745 | O | Ar1 | P1 | P15 | P1 | P8 | H | H | H |
| 3746 | O | Ar1 | P2 | P1 | P2 | P8 | H | H | H |
| 3747 | O | Ar1 | P2 | P2 | P2 | P8 | H | H | H |
| 3748 | O | Ar1 | P2 | P3 | P2 | P8 | H | H | H |
| 3749 | O | Ar1 | P2 | P4 | P2 | P8 | H | H | H |
| 3750 | O | Ar1 | P2 | P5 | P2 | P8 | H | H | H |
| 3751 | O | Ar1 | P2 | P6 | P2 | P8 | H | H | H |
| 3752 | O | Ar1 | P2 | P7 | P2 | P8 | H | H | H |
| 3753 | O | Ar1 | P2 | P8 | P2 | P8 | H | H | H |
| 3754 | O | Ar1 | P2 | P9 | P2 | P8 | H | H | H |
| 3755 | O | Ar1 | P2 | P10 | P2 | P8 | H | H | H |
| 3756 | O | Ar1 | P2 | P11 | P2 | P8 | H | H | H |
| 3757 | O | Ar1 | P2 | P12 | P2 | P8 | H | H | H |
| 3758 | O | Ar1 | P2 | P13 | P2 | P8 | H | H | H |
| 3759 | O | Ar1 | P2 | P14 | P2 | P8 | H | H | H |
| 3760 | O | Ar1 | P2 | P15 | P2 | P8 | H | H | H |
| 3761 | O | Ar1 | P1 | P1 | D | P8 | H | H | D |
| 3762 | O | Ar1 | P2 | P2 | D | P8 | H | H | D |
| 3763 | O | Ar1 | P2 | P3 | D | P8 | H | H | D |
| 3764 | O | Ar1 | P2 | P4 | D | P8 | H | H | D |
| 3765 | O | Ar1 | P2 | P5 | D | P8 | H | H | D |
| 3766 | O | Ar1 | P2 | P6 | D | P8 | H | H | D |
| 3767 | O | Ar1 | P2 | P7 | D | P8 | H | H | D |
| 3768 | O | Ar1 | P2 | P8 | D | P8 | H | H | D |
| 3769 | O | Ar1 | P2 | P9 | D | P8 | H | H | D |
| 3770 | O | Ar1 | P2 | P10 | D | P8 | H | H | D |
| 3771 | O | Ar1 | P2 | P11 | D | P8 | H | H | D |
| 3772 | O | Ar1 | P2 | P12 | D | P8 | H | H | D |
| 3773 | O | Ar1 | P2 | P13 | D | P8 | H | H | D |
| 3774 | O | Ar1 | P2 | P14 | D | P8 | H | H | D |
| 3775 | O | Ar1 | P2 | P15 | D | P8 | H | H | D |
| 3776 | O | Ar1 | P11 | P1 | P1 | P8 | H | H | H |
| 3777 | O | Ar1 | P11 | P2 | P2 | P8 | H | H | H |
| 3778 | O | Ar1 | P11 | P3 | P1 | P8 | H | H | H |
| 3779 | O | Ar1 | P11 | P4 | P1 | P8 | H | H | H |
| 3780 | O | Ar1 | P11 | P5 | P1 | P8 | H | H | H |
| 3781 | O | Ar1 | P11 | P6 | P1 | P8 | H | H | H |
| 3782 | O | Ar1 | P11 | P7 | P1 | P8 | H | H | H |
| 3783 | O | Ar1 | P11 | P8 | P1 | P8 | H | H | H |
| 3784 | O | Ar1 | P11 | P9 | P1 | P8 | H | H | H |
| 3785 | O | Ar1 | P11 | P10 | P1 | P8 | H | H | H |
| 3786 | O | Ar1 | P11 | P11 | P1 | P8 | H | H | H |
| 3787 | O | Ar1 | P11 | P12 | P1 | P8 | H | H | H |
| 3788 | O | Ar1 | P11 | P13 | P1 | P8 | H | H | H |
| 3789 | O | Ar1 | P11 | P14 | P1 | P8 | H | H | H |
| 3790 | O | Ar1 | P11 | P15 | P1 | P8 | H | H | H |
| 3791 | O | Ar1 | P11 | P1 | P2 | P8 | H | H | H |
| 3792 | O | Ar1 | P11 | P2 | P2 | P8 | H | H | H |
| 3793 | O | Ar1 | P11 | P3 | P2 | P8 | H | H | H |
| 3794 | O | Ar1 | P11 | P4 | P2 | P8 | H | H | H |
| 3795 | O | Ar1 | P11 | P5 | P2 | P8 | H | H | H |
| 3796 | O | Ar1 | P11 | P6 | P2 | P8 | H | H | H |
| 3797 | O | Ar1 | P11 | P7 | P2 | P8 | H | H | H |
| 3798 | O | Ar1 | P11 | P8 | P2 | P8 | H | H | H |
| 3799 | O | Ar1 | P11 | P9 | P2 | P8 | H | H | H |
| 3800 | O | Ar1 | P11 | P10 | P2 | P8 | H | H | H |
| 3801 | O | Ar1 | P11 | P11 | P2 | P8 | H | H | H |
| 3802 | O | Ar1 | P11 | P12 | P2 | P8 | H | H | H |
| 3803 | O | Ar1 | P11 | P13 | P2 | P8 | H | H | H |
| 3804 | O | Ar1 | P11 | P14 | P2 | P8 | H | H | H |
| 3805 | O | Ar1 | P11 | P15 | P2 | P8 | H | H | H |
| 3806 | O | Ar1 | P11 | P1 | D | P8 | H | H | D |
| 3807 | O | Ar1 | P11 | P2 | D | P8 | H | H | D |
| 3808 | O | Ar1 | P11 | P3 | D | P8 | H | H | D |
| 3809 | O | Ar1 | P11 | P4 | D | P8 | H | H | D |
| 3810 | O | Ar1 | P11 | P5 | D | P8 | H | H | D |
| 3811 | O | Ar1 | P11 | P6 | D | P8 | H | H | D |
| 3812 | O | Ar1 | P11 | P7 | D | P8 | H | H | D |
| 3813 | O | Ar1 | P11 | P8 | D | P8 | H | H | D |
| 3814 | O | Ar1 | P11 | P9 | D | P8 | H | H | D |
| 3815 | O | Ar1 | P11 | P10 | D | P8 | H | H | D |
| 3816 | O | Ar1 | P11 | P11 | D | P8 | H | H | D |
| 3817 | O | Ar1 | P11 | P12 | D | P8 | H | H | D |
| 3818 | O | Ar1 | P11 | P13 | D | P8 | H | H | D |
| 3819 | O | Ar1 | P11 | P14 | D | P8 | H | H | D |
| 3820 | O | Ar1 | P11 | P15 | D | P8 | H | H | D |
| 3821 | O | Ar1 | P12 | P1 | P1 | P8 | H | H | H |
| 3822 | O | Ar1 | P12 | P2 | P2 | P8 | H | H | H |
| 3823 | O | Ar1 | P12 | P3 | P1 | P8 | H | H | H |
| 3824 | O | Ar1 | P12 | P4 | P1 | P8 | H | H | H |
| 3825 | O | Ar1 | P12 | P5 | P1 | P8 | H | H | H |
| 3826 | O | Ar1 | P12 | P6 | P1 | P8 | H | H | H |
| 3827 | O | Ar1 | P12 | P7 | P1 | P8 | H | H | H |
| 3828 | O | Ar1 | P12 | P8 | P1 | P8 | H | H | H |
| 3829 | O | Ar1 | P12 | P9 | P1 | P8 | H | H | H |
| 3830 | O | Ar1 | P12 | P10 | P1 | P8 | H | H | H |
| 3831 | O | Ar1 | P12 | P11 | P1 | P8 | H | H | H |
| 3832 | O | Ar1 | P12 | P12 | P1 | P8 | H | H | H |
| 3833 | O | Ar1 | P12 | P13 | P1 | P8 | H | H | H |
| 3834 | O | Ar1 | P12 | P14 | P1 | P8 | H | H | H |
| 3835 | O | Ar1 | P12 | P15 | P1 | P8 | H | H | H |
| 3836 | O | Ar1 | P12 | P1 | P2 | P8 | H | H | H |
| 3837 | O | Ar1 | P12 | P2 | P2 | P8 | H | H | H |
| 3838 | O | Ar1 | P12 | P3 | P2 | P8 | H | H | H |
| 3839 | O | Ar1 | P12 | P4 | P2 | P8 | H | H | H |
| 3840 | O | Ar1 | P12 | P5 | P2 | P8 | H | H | H |
| 3841 | O | Ar1 | P12 | P6 | P2 | P8 | H | H | H |
| 3842 | O | Ar1 | P12 | P7 | P2 | P8 | H | H | H |
| 3843 | O | Ar1 | P12 | P8 | P2 | P8 | H | H | H |
| 3844 | O | Ar1 | P12 | P9 | P2 | P8 | H | H | H |
| 3845 | O | Ar1 | P12 | P10 | P2 | P8 | H | H | H |
| 3846 | O | Ar1 | P12 | P11 | P2 | P8 | H | H | H |
| 3847 | O | Ar1 | P12 | P12 | P2 | P8 | H | H | H |
| 3848 | O | Ar1 | P12 | P13 | P2 | P8 | H | H | H |
| 3849 | O | Ar1 | P12 | P14 | P2 | P8 | H | H | H |
| 3850 | O | Ar1 | P12 | P15 | P2 | P8 | H | H | H |
| 3851 | O | Ar1 | P12 | P1 | D | P8 | H | H | D |
| 3852 | O | Ar1 | P12 | P2 | D | P8 | H | H | D |
| 3853 | O | Ar1 | P12 | P3 | D | P8 | H | H | D |
| 3854 | O | Ar1 | P12 | P4 | D | P8 | H | H | D |
| 3855 | O | Ar1 | P12 | P5 | D | P8 | H | H | D |
| 3856 | O | Ar1 | P12 | P6 | D | P8 | H | H | D |
| 3857 | O | Ar1 | P12 | P7 | D | P8 | H | H | D |
| 3858 | O | Ar1 | P12 | P8 | D | P8 | H | H | D |
| 3859 | O | Ar1 | P12 | P9 | D | P8 | H | H | D |
| 3860 | O | Ar1 | P12 | P10 | D | P8 | H | H | D |
| 3861 | O | Ar1 | P12 | P11 | D | P8 | H | H | D |
| 3862 | O | Ar1 | P12 | P12 | D | P8 | H | H | D |
| 3863 | O | Ar1 | P12 | P13 | D | P8 | H | H | D |
| 3864 | O | Ar1 | P12 | P14 | D | P8 | H | H | D |
| 3865 | O | Ar1 | P12 | P15 | D | P8 | H | H | D |
| 3866 | O | Ar2 | P1 | P1 | P1 | P8 | H | H | H |
| 3867 | O | Ar2 | P1 | P2 | P2 | P8 | H | H | H |
| 3868 | O | Ar2 | P1 | P3 | P1 | P8 | H | H | H |
| 3869 | O | Ar2 | P1 | P4 | P1 | P8 | H | H | H |
| 3870 | O | Ar2 | P1 | P5 | P1 | P8 | H | H | H |
| 3871 | O | Ar2 | P1 | P6 | P1 | P8 | H | H | H |
| 3872 | O | Ar2 | P1 | P7 | P1 | P8 | H | H | H |
| 3873 | O | Ar2 | P1 | P8 | P1 | P8 | H | H | H |
| 3874 | O | Ar2 | P1 | P9 | P1 | P8 | H | H | H |
| 3875 | O | Ar2 | P1 | P10 | P1 | P8 | H | H | H |
| 3876 | O | Ar2 | P1 | P11 | P1 | P8 | H | H | H |
| 3877 | O | Ar2 | P1 | P12 | P1 | P8 | H | H | H |
| 3878 | O | Ar2 | P1 | P13 | P1 | P8 | H | H | H |
| 3879 | O | Ar2 | P1 | P14 | P1 | P8 | H | H | H |
| 3880 | O | Ar2 | P1 | P15 | P1 | P8 | H | H | H |
| 3881 | O | Ar2 | P2 | P1 | P2 | P8 | H | H | H |
| 3882 | O | Ar2 | P2 | P2 | P2 | P8 | H | H | H |
| 3883 | O | Ar2 | P2 | P3 | P2 | P8 | H | H | H |
| 3884 | O | Ar2 | P2 | P4 | P2 | P8 | H | H | H |
| 3885 | O | Ar2 | P2 | P5 | P2 | P8 | H | H | H |
| 3886 | O | Ar2 | P2 | P6 | P2 | P8 | H | H | H |
| 3887 | O | Ar2 | P2 | P7 | P2 | P8 | H | H | H |
| 3888 | O | Ar2 | P2 | P8 | P2 | P8 | H | H | H |
| 3889 | O | Ar2 | P2 | P9 | P2 | P8 | H | H | H |
| 3890 | O | Ar2 | P2 | P10 | P2 | P8 | H | H | H |
| 3891 | O | Ar2 | P2 | P11 | P2 | P8 | H | H | H |
| 3892 | O | Ar2 | P2 | P12 | P2 | P8 | H | H | H |
| 3893 | O | Ar2 | P2 | P13 | P2 | P8 | H | H | H |
| 3894 | O | Ar2 | P2 | P14 | P2 | P8 | H | H | H |
| 3895 | O | Ar2 | P2 | P15 | P2 | P8 | H | H | H |
| 3896 | O | Ar2 | P1 | P1 | D | P8 | H | H | D |
| 3897 | O | Ar2 | P2 | P2 | D | P8 | H | H | D |
| 3898 | O | Ar2 | P2 | P3 | D | P8 | H | H | D |
| 3899 | O | Ar2 | P2 | P4 | D | P8 | H | H | D |
| 3900 | O | Ar2 | P2 | P5 | D | P8 | H | H | D |
| 3901 | O | Ar2 | P2 | P6 | D | P8 | H | H | D |
| 3902 | O | Ar2 | P2 | P7 | D | P8 | H | H | D |
| 3903 | O | Ar2 | P2 | P8 | D | P8 | H | H | D |
| 3904 | O | Ar2 | P2 | P9 | D | P8 | H | H | D |
| 3905 | O | Ar2 | P2 | P10 | D | P8 | H | H | D |
| 3906 | O | Ar2 | P2 | P11 | D | P8 | H | H | D |
| 3907 | O | Ar2 | P2 | P12 | D | P8 | H | H | D |
| 3908 | O | Ar2 | P2 | P13 | D | P8 | H | H | D |
| 3909 | O | Ar2 | P2 | P14 | D | P8 | H | H | D |
| 3910 | O | Ar2 | P2 | P15 | D | P8 | H | H | D |
| 3911 | O | Ar2 | P11 | P1 | P1 | P8 | H | H | H |
| 3912 | O | Ar2 | P11 | P2 | P2 | P8 | H | H | H |
| 3913 | O | Ar2 | P11 | P3 | P1 | P8 | H | H | H |
| 3914 | O | Ar2 | P11 | P4 | P1 | P8 | H | H | H |
| 3915 | O | Ar2 | P11 | P5 | P1 | P8 | H | H | H |
| 3916 | O | Ar2 | P11 | P6 | P1 | P8 | H | H | H |
| 3917 | O | Ar2 | P11 | P7 | P1 | P8 | H | H | H |
| 3918 | O | Ar2 | P11 | P8 | P1 | P8 | H | H | H |
| 3919 | O | Ar2 | P11 | P9 | P1 | P8 | H | H | H |
| 3920 | O | Ar2 | P11 | P10 | P1 | P8 | H | H | H |
| 3921 | O | Ar2 | P11 | P11 | P1 | P8 | H | H | H |
| 3922 | O | Ar2 | P11 | P12 | P1 | P8 | H | H | H |
| 3923 | O | Ar2 | P11 | P13 | P1 | P8 | H | H | H |
| 3924 | O | Ar2 | P11 | P14 | P1 | P8 | H | H | H |
| 3925 | O | Ar2 | P11 | P15 | P1 | P8 | H | H | H |
| 3926 | O | Ar2 | P11 | P1 | P2 | P8 | H | H | H |
| 3927 | O | Ar2 | P11 | P2 | P2 | P8 | H | H | H |
| 3928 | O | Ar2 | P11 | P3 | P2 | P8 | H | H | H |
| 3929 | O | Ar2 | P11 | P4 | P2 | P8 | H | H | H |
| 3930 | O | Ar2 | P11 | P5 | P2 | P8 | H | H | H |
| 3931 | O | Ar2 | P11 | P6 | P2 | P8 | H | H | H |
| 3932 | O | Ar2 | P11 | P7 | P2 | P8 | H | H | H |
| 3933 | O | Ar2 | P11 | P8 | P2 | P8 | H | H | H |
| 3934 | O | Ar2 | P11 | P9 | P2 | P8 | H | H | H |
| 3935 | O | Ar2 | P11 | P10 | P2 | P8 | H | H | H |
| 3936 | O | Ar2 | P11 | P11 | P2 | P8 | H | H | H |
| 3937 | O | Ar2 | P11 | P12 | P2 | P8 | H | H | H |
| 3938 | O | Ar2 | P11 | P13 | P2 | P8 | H | H | H |
| 3939 | O | Ar2 | P11 | P14 | P2 | P8 | H | H | H |
| 3940 | O | Ar2 | P11 | P15 | P2 | P8 | H | H | H |
| 3941 | O | Ar2 | P11 | P1 | D | P8 | H | H | D |
| 3942 | O | Ar2 | P11 | P2 | D | P8 | H | H | D |
| 3943 | O | Ar2 | P11 | P3 | D | P8 | H | H | D |
| 3944 | O | Ar2 | P11 | P4 | D | P8 | H | H | D |
| 3945 | O | Ar2 | P11 | P5 | D | P8 | H | H | D |
| 3946 | O | Ar2 | P11 | P6 | D | P8 | H | H | D |
| 3947 | O | Ar2 | P11 | P7 | D | P8 | H | H | D |
| 3948 | O | Ar2 | P11 | P8 | D | P8 | H | H | D |
| 3949 | O | Ar2 | P11 | P9 | D | P8 | H | H | D |
| 3950 | O | Ar2 | P11 | P10 | D | P8 | H | H | D |
| 3951 | O | Ar2 | P11 | P11 | D | P8 | H | H | D |
| 3952 | O | Ar2 | P11 | P12 | D | P8 | H | H | D |
| 3953 | O | Ar2 | P11 | P13 | D | P8 | H | H | D |
| 3954 | O | Ar2 | P11 | P14 | D | P8 | H | H | D |
| 3955 | O | Ar2 | P11 | P15 | D | P8 | H | H | D |
| 3956 | O | Ar2 | P12 | P1 | P1 | P8 | H | H | H |
| 3957 | O | Ar2 | P12 | P2 | P2 | P8 | H | H | H |
| 3958 | O | Ar2 | P12 | P3 | P1 | P8 | H | H | H |
| 3959 | O | Ar2 | P12 | P4 | P1 | P8 | H | H | H |
| 3960 | O | Ar2 | P12 | P5 | P1 | P8 | H | H | H |
| 3961 | O | Ar2 | P12 | P6 | P1 | P8 | H | H | H |
| 3962 | O | Ar2 | P12 | P7 | P1 | P8 | H | H | H |
| 3963 | O | Ar2 | P12 | P8 | P1 | P8 | H | H | H |
| 3964 | O | Ar2 | P12 | P9 | P1 | P8 | H | H | H |
| 3965 | O | Ar2 | P12 | P10 | P1 | P8 | H | H | H |
| 3966 | O | Ar2 | P12 | P11 | P1 | P8 | H | H | H |
| 3967 | O | Ar2 | P12 | P12 | P1 | P8 | H | H | H |
| 3968 | O | Ar2 | P12 | P13 | P1 | P8 | H | H | H |
| 3969 | O | Ar2 | P12 | P14 | P1 | P8 | H | H | H |
| 3970 | O | Ar2 | P12 | P15 | P1 | P8 | H | H | H |
| 3971 | O | Ar2 | P12 | P1 | P2 | P8 | H | H | H |
| 3972 | O | Ar2 | P12 | P2 | P2 | P8 | H | H | H |
| 3973 | O | Ar2 | P12 | P3 | P2 | P8 | H | H | H |
| 3974 | O | Ar2 | P12 | P4 | P2 | P8 | H | H | H |
| 3975 | O | Ar2 | P12 | P5 | P2 | P8 | H | H | H |
| 3976 | O | Ar2 | P12 | P6 | P2 | P8 | H | H | H |
| 3977 | O | Ar2 | P12 | P7 | P2 | P8 | H | H | H |
| 3978 | O | Ar2 | P12 | P8 | P2 | P8 | H | H | H |
| 3979 | O | Ar2 | P12 | P9 | P2 | P8 | H | H | H |
| 3980 | O | Ar2 | P12 | P10 | P2 | P8 | H | H | H |
| 3981 | O | Ar2 | P12 | P11 | P2 | P8 | H | H | H |
| 3982 | O | Ar2 | P12 | P12 | P2 | P8 | H | H | H |
| 3983 | O | Ar2 | P12 | P13 | P2 | P8 | H | H | H |
| 3984 | O | Ar2 | P12 | P14 | P2 | P8 | H | H | H |
| 3985 | O | Ar2 | P12 | P15 | P2 | P8 | H | H | H |
| 3986 | O | Ar2 | P12 | P1 | D | P8 | H | H | D |
| 3987 | O | Ar2 | P12 | P2 | D | P8 | H | H | D |
| 3988 | O | Ar2 | P12 | P3 | D | P8 | H | H | D |
| 3989 | O | Ar2 | P12 | P4 | D | P8 | H | H | D |
| 3990 | O | Ar2 | P12 | P5 | D | P8 | H | H | D |
| 3991 | O | Ar2 | P12 | P6 | D | P8 | H | H | D |
| 3992 | O | Ar2 | P12 | P7 | D | P8 | H | H | D |
| 3993 | O | Ar2 | P12 | P8 | D | P8 | H | H | D |
| 3994 | O | Ar2 | P12 | P9 | D | P8 | H | H | D |
| 3995 | O | Ar2 | P12 | P10 | D | P8 | H | H | D |
| 3996 | O | Ar2 | P12 | P11 | D | P8 | H | H | D |
| 3997 | O | Ar2 | P12 | P12 | D | P8 | H | H | D |
| 3998 | O | Ar2 | P12 | P13 | D | P8 | H | H | D |
| 3999 | O | Ar2 | P12 | P14 | D | P8 | H | H | D |
| 4000 | O | Ar2 | P12 | P15 | D | P8 | H | H | D |
| 4001 | O | Ar31 | P1 | P1 | P1 | P8 | H | H | H |
| 4002 | O | Ar31 | P1 | P2 | P2 | P8 | H | H | H |
| 4003 | O | Ar31 | P1 | P3 | P1 | P8 | H | H | H |
| 4004 | O | Ar31 | P1 | P4 | P1 | P8 | H | H | H |
| 4005 | O | Ar31 | P1 | P5 | P1 | P8 | H | H | H |
| 4006 | O | Ar31 | P1 | P6 | P1 | P8 | H | H | H |
| 4007 | O | Ar31 | P1 | P7 | P1 | P8 | H | H | H |
| 4008 | O | Ar31 | P1 | P8 | P1 | P8 | H | H | H |
| 4009 | O | Ar31 | P1 | P9 | P1 | P8 | H | H | H |
| 4010 | O | Ar31 | P1 | P10 | P1 | P8 | H | H | H |
| 4011 | O | Ar31 | P1 | P11 | P1 | P8 | H | H | H |
| 4012 | O | Ar31 | P1 | P12 | P1 | P8 | H | H | H |
| 4013 | O | Ar31 | P1 | P13 | P1 | P8 | H | H | H |
| 4014 | O | Ar31 | P1 | P14 | P1 | P8 | H | H | H |
| 4015 | O | Ar31 | P1 | P15 | P1 | P8 | H | H | H |
| 4016 | O | Ar31 | P2 | P1 | P2 | P8 | H | H | H |
| 4017 | O | Ar31 | P2 | P2 | P2 | P8 | H | H | H |
| 4018 | O | Ar31 | P2 | P3 | P2 | P8 | H | H | H |
| 4019 | O | Ar31 | P2 | P4 | P2 | P8 | H | H | H |
| 4020 | O | Ar31 | P2 | P5 | P2 | P8 | H | H | H |
| 4021 | O | Ar31 | P2 | P6 | P2 | P8 | H | H | H |
| 4022 | O | Ar31 | P2 | P7 | P2 | P8 | H | H | H |
| 4023 | O | Ar31 | P2 | P8 | P2 | P8 | H | H | H |
| 4024 | O | Ar31 | P2 | P9 | P2 | P8 | H | H | H |
| 4025 | O | Ar31 | P2 | P10 | P2 | P8 | H | H | H |
| 4026 | O | Ar31 | P2 | P11 | P2 | P8 | H | H | H |
| 4027 | O | Ar31 | P2 | P12 | P2 | P8 | H | H | H |
| 4028 | O | Ar31 | P2 | P13 | P2 | P8 | H | H | H |
| 4029 | O | Ar31 | P2 | P14 | P2 | P8 | H | H | H |
| 4030 | O | Ar31 | P2 | P15 | P2 | P8 | H | H | H |
| 4031 | O | Ar31 | P1 | P1 | D | P8 | H | H | D |
| 4032 | O | Ar31 | P2 | P2 | D | P8 | H | H | D |
| 4033 | O | Ar31 | P2 | P3 | D | P8 | H | H | D |
| 4034 | O | Ar31 | P2 | P4 | D | P8 | H | H | D |
| 4035 | O | Ar31 | P2 | P5 | D | P8 | H | H | D |
| 4036 | O | Ar31 | P2 | P6 | D | P8 | H | H | D |
| 4037 | O | Ar31 | P2 | P7 | D | P8 | H | H | D |
| 4038 | O | Ar31 | P2 | P8 | D | P8 | H | H | D |
| 4039 | O | Ar31 | P2 | P9 | D | P8 | H | H | D |
| 4040 | O | Ar31 | P2 | P10 | D | P8 | H | H | D |
| 4041 | O | Ar31 | P2 | P11 | D | P8 | H | H | D |
| 4042 | O | Ar31 | P2 | P12 | D | P8 | H | H | D |
| 4043 | O | Ar31 | P2 | P13 | D | P8 | H | H | D |
| 4044 | O | Ar31 | P2 | P14 | D | P8 | H | H | D |
| 4045 | O | Ar31 | P2 | P15 | D | P8 | H | H | D |
| 4046 | O | Ar31 | P11 | P1 | P1 | P8 | H | H | H |
| 4047 | O | Ar31 | P11 | P2 | P2 | P8 | H | H | H |
| 4048 | O | Ar31 | P11 | P3 | P1 | P8 | H | H | H |
| 4049 | O | Ar31 | P11 | P4 | P1 | P8 | H | H | H |
| 4050 | O | Ar31 | P11 | P5 | P1 | P8 | H | H | H |
| 4051 | O | Ar31 | P11 | P6 | P1 | P8 | H | H | H |
| 4052 | O | Ar31 | P11 | P7 | P1 | P8 | H | H | H |
| 4053 | O | Ar31 | P11 | P8 | P1 | P8 | H | H | H |
| 4054 | O | Ar31 | P11 | P9 | P1 | P8 | H | H | H |
| 4055 | O | Ar31 | P11 | P10 | P1 | P8 | H | H | H |
| 4056 | O | Ar31 | P11 | P11 | P1 | P8 | H | H | H |
| 4057 | O | Ar31 | P11 | P12 | P1 | P8 | H | H | H |
| 4058 | O | Ar31 | P11 | P13 | P1 | P8 | H | H | H |
| 4059 | O | Ar31 | P11 | P14 | P1 | P8 | H | H | H |
| 4060 | O | Ar31 | P11 | P15 | P1 | P8 | H | H | H |
| 4061 | O | Ar31 | P11 | P1 | P2 | P8 | H | H | H |
| 4062 | O | Ar31 | P11 | P2 | P2 | P8 | H | H | H |
| 4063 | O | Ar31 | P11 | P3 | P2 | P8 | H | H | H |
| 4064 | O | Ar31 | P11 | P4 | P2 | P8 | H | H | H |
| 4065 | O | Ar31 | P11 | P5 | P2 | P8 | H | H | H |
| 4066 | O | Ar31 | P11 | P6 | P2 | P8 | H | H | H |
| 4067 | O | Ar31 | P11 | P7 | P2 | P8 | H | H | H |
| 4068 | O | Ar31 | P11 | P8 | P2 | P8 | H | H | H |
| 4069 | O | Ar31 | P11 | P9 | P2 | P8 | H | H | H |
| 4070 | O | Ar31 | P11 | P10 | P2 | P8 | H | H | H |
| 4071 | O | Ar31 | P11 | P11 | P2 | P8 | H | H | H |
| 4072 | O | Ar31 | P11 | P12 | P2 | P8 | H | H | H |
| 4073 | O | Ar31 | P11 | P13 | P2 | P8 | H | H | H |
| 4074 | O | Ar31 | P11 | P14 | P2 | P8 | H | H | H |
| 4075 | O | Ar31 | P11 | P15 | P2 | P8 | H | H | H |
| 4076 | O | Ar31 | P11 | P1 | D | P8 | H | H | D |
| 4077 | O | Ar31 | P11 | P2 | D | P8 | H | H | D |
| 4078 | O | Ar31 | P11 | P3 | D | P8 | H | H | D |
| 4079 | O | Ar31 | P11 | P4 | D | P8 | H | H | D |
| 4080 | O | Ar31 | P11 | P5 | D | P8 | H | H | D |
| 4081 | O | Ar31 | P11 | P6 | D | P8 | H | H | D |
| 4082 | O | Ar31 | P11 | P7 | D | P8 | H | H | D |
| 4083 | O | Ar31 | P11 | P8 | D | P8 | H | H | D |
| 4084 | O | Ar31 | P11 | P9 | D | P8 | H | H | D |
| 4085 | O | Ar31 | P11 | P10 | D | P8 | H | H | D |
| 4086 | O | Ar31 | P11 | P11 | D | P8 | H | H | D |
| 4087 | O | Ar31 | P11 | P12 | D | P8 | H | H | D |
| 4088 | O | Ar31 | P11 | P13 | D | P8 | H | H | D |
| 4089 | O | Ar31 | P11 | P14 | D | P8 | H | H | D |
| 4090 | O | Ar31 | P11 | P15 | D | P8 | H | H | D |
| 4091 | O | Ar31 | P12 | P1 | P1 | P8 | H | H | H |
| 4092 | O | Ar31 | P12 | P2 | P2 | P8 | H | H | H |
| 4093 | O | Ar31 | P12 | P3 | P1 | P8 | H | H | H |
| 4094 | O | Ar31 | P12 | P4 | P1 | P8 | H | H | H |
| 4095 | O | Ar31 | P12 | P5 | P1 | P8 | H | H | H |
| 4096 | O | Ar31 | P12 | P6 | P1 | P8 | H | H | H |
| 4097 | O | Ar31 | P12 | P7 | P1 | P8 | H | H | H |
| 4098 | O | Ar31 | P12 | P8 | P1 | P8 | H | H | H |
| 4099 | O | Ar31 | P12 | P9 | P1 | P8 | H | H | H |
| 4100 | O | Ar31 | P12 | P10 | P1 | P8 | H | H | H |
| 4101 | O | Ar31 | P12 | P11 | P1 | P8 | H | H | H |
| 4102 | O | Ar31 | P12 | P12 | P1 | P8 | H | H | H |
| 4103 | O | Ar31 | P12 | P13 | P1 | P8 | H | H | H |
| 4104 | O | Ar31 | P12 | P14 | P1 | P8 | H | H | H |
| 4105 | O | Ar31 | P12 | P15 | P1 | P8 | H | H | H |
| 4106 | O | Ar31 | P12 | P1 | P2 | P8 | H | H | H |
| 4107 | O | Ar31 | P12 | P2 | P2 | P8 | H | H | H |
| 4108 | O | Ar31 | P12 | P3 | P2 | P8 | H | H | H |
| 4109 | O | Ar31 | P12 | P4 | P2 | P8 | H | H | H |
| 4110 | O | Ar31 | P12 | P5 | P2 | P8 | H | H | H |
| 4111 | O | Ar31 | P12 | P6 | P2 | P8 | H | H | H |
| 4112 | O | Ar31 | P12 | P7 | P2 | P8 | H | H | H |
| 4113 | O | Ar31 | P12 | P8 | P2 | P8 | H | H | H |
| 4114 | O | Ar31 | P12 | P9 | P2 | P8 | H | H | H |
| 4115 | O | Ar31 | P12 | P10 | P2 | P8 | H | H | H |
| 4116 | O | Ar31 | P12 | P11 | P2 | P8 | H | H | H |
| 4117 | O | Ar31 | P12 | P12 | P2 | P8 | H | H | H |
| 4118 | O | Ar31 | P12 | P13 | P2 | P8 | H | H | H |
| 4119 | O | Ar31 | P12 | P14 | P2 | P8 | H | H | H |
| 4120 | O | Ar31 | P12 | P15 | P2 | P8 | H | H | H |
| 4121 | O | Ar31 | P12 | P1 | D | P8 | H | H | D |
| 4122 | O | Ar31 | P12 | P2 | D | P8 | H | H | D |
| 4123 | O | Ar31 | P12 | P3 | D | P8 | H | H | D |
| 4124 | O | Ar31 | P12 | P4 | D | P8 | H | H | D |
| 4125 | O | Ar31 | P12 | P5 | D | P8 | H | H | D |
| 4126 | O | Ar31 | P12 | P6 | D | P8 | H | H | D |
| 4127 | O | Ar31 | P12 | P7 | D | P8 | H | H | D |
| 4128 | O | Ar31 | P12 | P8 | D | P8 | H | H | D |
| 4129 | O | Ar31 | P12 | P9 | D | P8 | H | H | D |
| 4130 | O | Ar31 | P12 | P10 | D | P8 | H | H | D |
| 4131 | O | Ar31 | P12 | P11 | D | P8 | H | H | D |
| 4132 | O | Ar31 | P12 | P12 | D | P8 | H | H | D |
| 4133 | O | Ar31 | P12 | P13 | D | P8 | H | H | D |
| 4134 | O | Ar31 | P12 | P14 | D | P8 | H | H | D |
| 4135 | O | Ar31 | P12 | P15 | D | P8 | H | H | D |
| 4136 | O | Ar32 | P1 | P1 | P1 | P8 | H | H | H |
| 4137 | O | Ar32 | P1 | P2 | P2 | P8 | H | H | H |
| 4138 | O | Ar32 | P1 | P3 | P1 | P8 | H | H | H |
| 4139 | O | Ar32 | P1 | P4 | P1 | P8 | H | H | H |
| 4140 | O | Ar32 | P1 | P5 | P1 | P8 | H | H | H |
| 4141 | O | Ar32 | P1 | P6 | P1 | P8 | H | H | H |
| 4142 | O | Ar32 | P1 | P7 | P1 | P8 | H | H | H |
| 4143 | O | Ar32 | P1 | P8 | P1 | P8 | H | H | H |
| 4144 | O | Ar32 | P1 | P9 | P1 | P8 | H | H | H |
| 4145 | O | Ar32 | P1 | P10 | P1 | P8 | H | H | H |
| 4146 | O | Ar32 | P1 | P11 | P1 | P8 | H | H | H |
| 4147 | O | Ar32 | P1 | P12 | P1 | P8 | H | H | H |
| 4148 | O | Ar32 | P1 | P13 | P1 | P8 | H | H | H |
| 4149 | O | Ar32 | P1 | P14 | P1 | P8 | H | H | H |
| 4150 | O | Ar32 | P1 | P15 | P1 | P8 | H | H | H |
| 4151 | O | Ar32 | P2 | P1 | P2 | P8 | H | H | H |
| 4152 | O | Ar32 | P2 | P2 | P2 | P8 | H | H | H |
| 4153 | O | Ar32 | P2 | P3 | P2 | P8 | H | H | H |
| 4154 | O | Ar32 | P2 | P4 | P2 | P8 | H | H | H |
| 4155 | O | Ar32 | P2 | P5 | P2 | P8 | H | H | H |
| 4156 | O | Ar32 | P2 | P6 | P2 | P8 | H | H | H |
| 4157 | O | Ar32 | P2 | P7 | P2 | P8 | H | H | H |
| 4158 | O | Ar32 | P2 | P8 | P2 | P8 | H | H | H |
| 4159 | O | Ar32 | P2 | P9 | P2 | P8 | H | H | H |
| 4160 | O | Ar32 | P2 | P10 | P2 | P8 | H | H | H |
| 4161 | O | Ar32 | P2 | P11 | P2 | P8 | H | H | H |
| 4162 | O | Ar32 | P2 | P12 | P2 | P8 | H | H | H |
| 4163 | O | Ar32 | P2 | P13 | P2 | P8 | H | H | H |
| 4164 | O | Ar32 | P2 | P14 | P2 | P8 | H | H | H |
| 4165 | O | Ar32 | P2 | P15 | P2 | P8 | H | H | H |
| 4166 | O | Ar32 | P1 | P1 | D | P8 | H | H | D |
| 4167 | O | Ar32 | P2 | P2 | D | P8 | H | H | D |
| 4168 | O | Ar32 | P2 | P3 | D | P8 | H | H | D |
| 4169 | O | Ar32 | P2 | P4 | D | P8 | H | H | D |
| 4170 | O | Ar32 | P2 | P5 | D | P8 | H | H | D |
| 4171 | O | Ar32 | P2 | P6 | D | P8 | H | H | D |
| 4172 | O | Ar32 | P2 | P7 | D | P8 | H | H | D |
| 4173 | O | Ar32 | P2 | P8 | D | P8 | H | H | D |
| 4174 | O | Ar32 | P2 | P9 | D | P8 | H | H | D |
| 4175 | O | Ar32 | P2 | P10 | D | P8 | H | H | D |
| 4176 | O | Ar32 | P2 | P11 | D | P8 | H | H | D |
| 4177 | O | Ar32 | P2 | P12 | D | P8 | H | H | D |
| 4178 | O | Ar32 | P2 | P13 | D | P8 | H | H | D |
| 4179 | O | Ar32 | P2 | P14 | D | P8 | H | H | D |
| 4180 | O | Ar32 | P2 | P15 | D | P8 | H | H | D |
| 4181 | O | Ar32 | P11 | P1 | P1 | P8 | H | H | H |
| 4182 | O | Ar32 | P11 | P2 | P2 | P8 | H | H | H |
| 4183 | O | Ar32 | P11 | P3 | P1 | P8 | H | H | H |
| 4184 | O | Ar32 | P11 | P4 | P1 | P8 | H | H | H |
| 4185 | O | Ar32 | P11 | P5 | P1 | P8 | H | H | H |
| 4186 | O | Ar32 | P11 | P6 | P1 | P8 | H | H | H |
| 4187 | O | Ar32 | P11 | P7 | P1 | P8 | H | H | H |
| 4188 | O | Ar32 | P11 | P8 | P1 | P8 | H | H | H |
| 4189 | O | Ar32 | P11 | P9 | P1 | P8 | H | H | H |
| 4190 | O | Ar32 | P11 | P10 | P1 | P8 | H | H | H |
| 4191 | O | Ar32 | P11 | P11 | P1 | P8 | H | H | H |
| 4192 | O | Ar32 | P11 | P12 | P1 | P8 | H | H | H |
| 4193 | O | Ar32 | P11 | P13 | P1 | P8 | H | H | H |
| 4194 | O | Ar32 | P11 | P14 | P1 | P8 | H | H | H |
| 4195 | O | Ar32 | P11 | P15 | P1 | P8 | H | H | H |
| 4196 | O | Ar32 | P11 | P1 | P2 | P8 | H | H | H |
| 4197 | O | Ar32 | P11 | P2 | P2 | P8 | H | H | H |
| 4198 | O | Ar32 | P11 | P3 | P2 | P8 | H | H | H |
| 4199 | O | Ar32 | P11 | P4 | P2 | P8 | H | H | H |
| 4200 | O | Ar32 | P11 | P5 | P2 | P8 | H | H | H |
| 4201 | O | Ar32 | P11 | P6 | P2 | P8 | H | H | H |
| 4202 | O | Ar32 | P11 | P7 | P2 | P8 | H | H | H |
| 4203 | O | Ar32 | P11 | P8 | P2 | P8 | H | H | H |
| 4204 | O | Ar32 | P11 | P9 | P2 | P8 | H | H | H |
| 4205 | O | Ar32 | P11 | P10 | P2 | P8 | H | H | H |
| 4206 | O | Ar32 | P11 | P11 | P2 | P8 | H | H | H |
| 4207 | O | Ar32 | P11 | P12 | P2 | P8 | H | H | H |
| 4208 | O | Ar32 | P11 | P13 | P2 | P8 | H | H | H |
| 4209 | O | Ar32 | P11 | P14 | P2 | P8 | H | H | H |
| 4210 | O | Ar32 | P11 | P15 | P2 | P8 | H | H | H |
| 4211 | O | Ar32 | P11 | P1 | D | P8 | H | H | D |
| 4212 | O | Ar32 | P11 | P2 | D | P8 | H | H | D |
| 4213 | O | Ar32 | P11 | P3 | D | P8 | H | H | D |
| 4214 | O | Ar32 | P11 | P4 | D | P8 | H | H | D |
| 4215 | O | Ar32 | P11 | P5 | D | P8 | H | H | D |
| 4216 | O | Ar32 | P11 | P6 | D | P8 | H | H | D |
| 4217 | O | Ar32 | P11 | P7 | D | P8 | H | H | D |
| 4218 | O | Ar32 | P11 | P8 | D | P8 | H | H | D |
| 4219 | O | Ar32 | P11 | P9 | D | P8 | H | H | D |
| 4220 | O | Ar32 | P11 | P10 | D | P8 | H | H | D |
| 4221 | O | Ar32 | P11 | P11 | D | P8 | H | H | D |
| 4222 | O | Ar32 | P11 | P12 | D | P8 | H | H | D |
| 4223 | O | Ar32 | P11 | P13 | D | P8 | H | H | D |
| 4224 | O | Ar32 | P11 | P14 | D | P8 | H | H | D |
| 4225 | O | Ar32 | P11 | P15 | D | P8 | H | H | D |
| 4226 | O | Ar32 | P12 | P1 | P1 | P8 | H | H | H |
| 4227 | O | Ar32 | P12 | P2 | P2 | P8 | H | H | H |
| 4228 | O | Ar32 | P12 | P3 | P1 | P8 | H | H | H |
| 4229 | O | Ar32 | P12 | P4 | P1 | P8 | H | H | H |
| 4230 | O | Ar32 | P12 | P5 | P1 | P8 | H | H | H |
| 4231 | O | Ar32 | P12 | P6 | P1 | P8 | H | H | H |
| 4232 | O | Ar32 | P12 | P7 | P1 | P8 | H | H | H |
| 4233 | O | Ar32 | P12 | P8 | P1 | P8 | H | H | H |
| 4234 | O | Ar32 | P12 | P9 | P1 | P8 | H | H | H |
| 4235 | O | Ar32 | P12 | P10 | P1 | P8 | H | H | H |
| 4236 | O | Ar32 | P12 | P11 | P1 | P8 | H | H | H |
| 4237 | O | Ar32 | P12 | P12 | P1 | P8 | H | H | H |
| 4238 | O | Ar32 | P12 | P13 | P1 | P8 | H | H | H |
| 4239 | O | Ar32 | P12 | P14 | P1 | P8 | H | H | H |
| 4240 | O | Ar32 | P12 | P15 | P1 | P8 | H | H | H |
| 4241 | O | Ar32 | P12 | P1 | P2 | P8 | H | H | H |
| 4242 | O | Ar32 | P12 | P2 | P2 | P8 | H | H | H |
| 4243 | O | Ar32 | P12 | P3 | P2 | P8 | H | H | H |
| 4244 | O | Ar32 | P12 | P4 | P2 | P8 | H | H | H |
| 4245 | O | Ar32 | P12 | P5 | P2 | P8 | H | H | H |
| 4246 | O | Ar32 | P12 | P6 | P2 | P8 | H | H | H |
| 4247 | O | Ar32 | P12 | P7 | P2 | P8 | H | H | H |
| 4248 | O | Ar32 | P12 | P8 | P2 | P8 | H | H | H |
| 4249 | O | Ar32 | P12 | P9 | P2 | P8 | H | H | H |
| 4250 | O | Ar32 | P12 | P10 | P2 | P8 | H | H | H |
| 4251 | O | Ar32 | P12 | P11 | P2 | P8 | H | H | H |
| 4252 | O | Ar32 | P12 | P12 | P2 | P8 | H | H | H |
| 4253 | O | Ar32 | P12 | P13 | P2 | P8 | H | H | H |
| 4254 | O | Ar32 | P12 | P14 | P2 | P8 | H | H | H |
| 4255 | O | Ar32 | P12 | P15 | P2 | P8 | H | H | H |
| 4256 | O | Ar32 | P12 | P1 | D | P8 | H | H | D |
| 4257 | O | Ar32 | P12 | P2 | D | P8 | H | H | D |
| 4258 | O | Ar32 | P12 | P3 | D | P8 | H | H | D |
| 4259 | O | Ar32 | P12 | P4 | D | P8 | H | H | D |
| 4260 | O | Ar32 | P12 | P5 | D | P8 | H | H | D |
| 4261 | O | Ar32 | P12 | P6 | D | P8 | H | H | D |
| 4262 | O | Ar32 | P12 | P7 | D | P8 | H | H | D |
| 4263 | O | Ar32 | P12 | P8 | D | P8 | H | H | D |
| 4264 | O | Ar32 | P12 | P9 | D | P8 | H | H | D |
| 4265 | O | Ar32 | P12 | P10 | D | P8 | H | H | D |
| 4266 | O | Ar32 | P12 | P11 | D | P8 | H | H | D |
| 4267 | O | Ar32 | P12 | P12 | D | P8 | H | H | D |
| 4268 | O | Ar32 | P12 | P13 | D | P8 | H | H | D |
| 4269 | O | Ar32 | P12 | P14 | D | P8 | H | H | D |
| 4270 | O | Ar32 | P12 | P15 | D | P8 | H | H | D |
| 4271 | O | Ar35 | P1 | P1 | P1 | P8 | H | H | H |
| 4272 | O | Ar35 | P1 | P2 | P2 | P8 | H | H | H |
| 4273 | O | Ar35 | P1 | P3 | P1 | P8 | H | H | H |
| 4274 | O | Ar35 | P1 | P4 | P1 | P8 | H | H | H |
| 4275 | O | Ar35 | P1 | P5 | P1 | P8 | H | H | H |
| 4276 | O | Ar35 | P1 | P6 | P1 | P8 | H | H | H |
| 4277 | O | Ar35 | P1 | P7 | P1 | P8 | H | H | H |
| 4278 | O | Ar35 | P1 | P8 | P1 | P8 | H | H | H |
| 4279 | O | Ar35 | P1 | P9 | P1 | P8 | H | H | H |
| 4280 | O | Ar35 | P1 | P10 | P1 | P8 | H | H | H |
| 4281 | O | Ar35 | P1 | P11 | P1 | P8 | H | H | H |
| 4282 | O | Ar35 | P1 | P12 | P1 | P8 | H | H | H |
| 4283 | O | Ar35 | P1 | P13 | P1 | P8 | H | H | H |
| 4284 | O | Ar35 | P1 | P14 | P1 | P8 | H | H | H |
| 4285 | O | Ar35 | P1 | P15 | P1 | P8 | H | H | H |
| 4286 | O | Ar35 | P2 | P1 | P2 | P8 | H | H | H |
| 4287 | O | Ar35 | P2 | P2 | P2 | P8 | H | H | H |
| 4288 | O | Ar35 | P2 | P3 | P2 | P8 | H | H | H |
| 4289 | O | Ar35 | P2 | P4 | P2 | P8 | H | H | H |
| 4290 | O | Ar35 | P2 | P5 | P2 | P8 | H | H | H |
| 4291 | O | Ar35 | P2 | P6 | P2 | P8 | H | H | H |
| 4292 | O | Ar35 | P2 | P7 | P2 | P8 | H | H | H |
| 4293 | O | Ar35 | P2 | P8 | P2 | P8 | H | H | H |
| 4294 | O | Ar35 | P2 | P9 | P2 | P8 | H | H | H |
| 4295 | O | Ar35 | P2 | P10 | P2 | P8 | H | H | H |
| 4296 | O | Ar35 | P2 | P11 | P2 | P8 | H | H | H |
| 4297 | O | Ar35 | P2 | P12 | P2 | P8 | H | H | H |
| 4298 | O | Ar35 | P2 | P13 | P2 | P8 | H | H | H |
| 4299 | O | Ar35 | P2 | P14 | P2 | P8 | H | H | H |
| 4300 | O | Ar35 | P2 | P15 | P2 | P8 | H | H | H |
| 4301 | O | Ar35 | P1 | P1 | D | P8 | H | H | D |
| 4302 | O | Ar35 | P2 | P2 | D | P8 | H | H | D |
| 4303 | O | Ar35 | P2 | P3 | D | P8 | H | H | D |
| 4304 | O | Ar35 | P2 | P4 | D | P8 | H | H | D |
| 4305 | O | Ar35 | P2 | P5 | D | P8 | H | H | D |
| 4306 | O | Ar35 | P2 | P6 | D | P8 | H | H | D |
| 4307 | O | Ar35 | P2 | P7 | D | P8 | H | H | D |
| 4308 | O | Ar35 | P2 | P8 | D | P8 | H | H | D |
| 4309 | O | Ar35 | P2 | P9 | D | P8 | H | H | D |
| 4310 | O | Ar35 | P2 | P10 | D | P8 | H | H | D |
| 4311 | O | Ar35 | P2 | P11 | D | P8 | H | H | D |
| 4312 | O | Ar35 | P2 | P12 | D | P8 | H | H | D |
| 4313 | O | Ar35 | P2 | P13 | D | P8 | H | H | D |
| 4314 | O | Ar35 | P2 | P14 | D | P8 | H | H | D |
| 4315 | O | Ar35 | P2 | P15 | D | P8 | H | H | D |
| 4316 | O | Ar35 | P11 | P1 | P1 | P8 | H | H | H |
| 4317 | O | Ar35 | P11 | P2 | P2 | P8 | H | H | H |
| 4318 | O | Ar35 | P11 | P3 | P1 | P8 | H | H | H |
| 4319 | O | Ar35 | P11 | P4 | P1 | P8 | H | H | H |
| 4320 | O | Ar35 | P11 | P5 | P1 | P8 | H | H | H |
| 4321 | O | Ar35 | P11 | P6 | P1 | P8 | H | H | H |
| 4322 | O | Ar35 | P11 | P7 | P1 | P8 | H | H | H |
| 4323 | O | Ar35 | P11 | P8 | P1 | P8 | H | H | H |
| 4324 | O | Ar35 | P11 | P9 | P1 | P8 | H | H | H |
| 4325 | O | Ar35 | P11 | P10 | P1 | P8 | H | H | H |
| 4326 | O | Ar35 | P11 | P11 | P1 | P8 | H | H | H |
| 4327 | O | Ar35 | P11 | P12 | P1 | P8 | H | H | H |
| 4328 | O | Ar35 | P11 | P13 | P1 | P8 | H | H | H |
| 4329 | O | Ar35 | P11 | P14 | P1 | P8 | H | H | H |
| 4330 | O | Ar35 | P11 | P15 | P1 | P8 | H | H | H |
| 4331 | O | Ar35 | P11 | P1 | P2 | P8 | H | H | H |
| 4332 | O | Ar35 | P11 | P2 | P2 | P8 | H | H | H |
| 4333 | O | Ar35 | P11 | P3 | P2 | P8 | H | H | H |
| 4334 | O | Ar35 | P11 | P4 | P2 | P8 | H | H | H |
| 4335 | O | Ar35 | P11 | P5 | P2 | P8 | H | H | H |
| 4336 | O | Ar35 | P11 | P6 | P2 | P8 | H | H | H |
| 4337 | O | Ar35 | P11 | P7 | P2 | P8 | H | H | H |
| 4338 | O | Ar35 | P11 | P8 | P2 | P8 | H | H | H |
| 4339 | O | Ar35 | P11 | P9 | P2 | P8 | H | H | H |
| 4340 | O | Ar35 | P11 | P10 | P2 | P8 | H | H | H |
| 4341 | O | Ar35 | P11 | P11 | P2 | P8 | H | H | H |
| 4342 | O | Ar35 | P11 | P12 | P2 | P8 | H | H | H |
| 4343 | O | Ar35 | P11 | P13 | P2 | P8 | H | H | H |
| 4344 | O | Ar35 | P11 | P14 | P2 | P8 | H | H | H |
| 4345 | O | Ar35 | P11 | P15 | P2 | P8 | H | H | H |
| 4346 | O | Ar35 | P11 | P1 | D | P8 | H | H | D |
| 4347 | O | Ar35 | P11 | P2 | D | P8 | H | H | D |
| 4348 | O | Ar35 | P11 | P3 | D | P8 | H | H | D |
| 4349 | O | Ar35 | P11 | P4 | D | P8 | H | H | D |
| 4350 | O | Ar35 | P11 | P5 | D | P8 | H | H | D |
| 4351 | O | Ar35 | P11 | P6 | D | P8 | H | H | D |
| 4352 | O | Ar35 | P11 | P7 | D | P8 | H | H | D |
| 4353 | O | Ar35 | P11 | P8 | D | P8 | H | H | D |
| 4354 | O | Ar35 | P11 | P9 | D | P8 | H | H | D |
| 4355 | O | Ar35 | P11 | P10 | D | P8 | H | H | D |
| 4356 | O | Ar35 | P11 | P11 | D | P8 | H | H | D |
| 4357 | O | Ar35 | P11 | P12 | D | P8 | H | H | D |
| 4358 | O | Ar35 | P11 | P13 | D | P8 | H | H | D |
| 4359 | O | Ar35 | P11 | P14 | D | P8 | H | H | D |
| 4360 | O | Ar35 | P11 | P15 | D | P8 | H | H | D |
| 4361 | O | Ar35 | P12 | P1 | P1 | P8 | H | H | H |
| 4362 | O | Ar35 | P12 | P2 | P2 | P8 | H | H | H |
| 4363 | O | Ar35 | P12 | P3 | P1 | P8 | H | H | H |
| 4364 | O | Ar35 | P12 | P4 | P1 | P8 | H | H | H |
| 4365 | O | Ar35 | P12 | P5 | P1 | P8 | H | H | H |
| 4366 | O | Ar35 | P12 | P6 | P1 | P8 | H | H | H |
| 4367 | O | Ar35 | P12 | P7 | P1 | P8 | H | H | H |
| 4368 | O | Ar35 | P12 | P8 | P1 | P8 | H | H | H |
| 4369 | O | Ar35 | P12 | P9 | P1 | P8 | H | H | H |
| 4370 | O | Ar35 | P12 | P10 | P1 | P8 | H | H | H |
| 4371 | O | Ar35 | P12 | P11 | P1 | P8 | H | H | H |
| 4372 | O | Ar35 | P12 | P12 | P1 | P8 | H | H | H |
| 4373 | O | Ar35 | P12 | P13 | P1 | P8 | H | H | H |
| 4374 | O | Ar35 | P12 | P14 | P1 | P8 | H | H | H |
| 4375 | O | Ar35 | P12 | P15 | P1 | P8 | H | H | H |
| 4376 | O | Ar35 | P12 | P1 | P2 | P8 | H | H | H |
| 4377 | O | Ar35 | P12 | P2 | P2 | P8 | H | H | H |
| 4378 | O | Ar35 | P12 | P3 | P2 | P8 | H | H | H |
| 4379 | O | Ar35 | P12 | P4 | P2 | P8 | H | H | H |
| 4380 | O | Ar35 | P12 | P5 | P2 | P8 | H | H | H |
| 4381 | O | Ar35 | P12 | P6 | P2 | P8 | H | H | H |
| 4382 | O | Ar35 | P12 | P7 | P2 | P8 | H | H | H |
| 4383 | O | Ar35 | P12 | P8 | P2 | P8 | H | H | H |
| 4384 | O | Ar35 | P12 | P9 | P2 | P8 | H | H | H |
| 4385 | O | Ar35 | P12 | P10 | P2 | P8 | H | H | H |
| 4386 | O | Ar35 | P12 | P11 | P2 | P8 | H | H | H |
| 4387 | O | Ar35 | P12 | P12 | P2 | P8 | H | H | H |
| 4388 | O | Ar35 | P12 | P13 | P2 | P8 | H | H | H |
| 4389 | O | Ar35 | P12 | P14 | P2 | P8 | H | H | H |
| 4390 | O | Ar35 | P12 | P15 | P2 | P8 | H | H | H |
| 4391 | O | Ar35 | P12 | P1 | D | P8 | H | H | D |
| 4392 | O | Ar35 | P12 | P2 | D | P8 | H | H | D |
| 4393 | O | Ar35 | P12 | P3 | D | P8 | H | H | D |
| 4394 | O | Ar35 | P12 | P4 | D | P8 | H | H | D |
| 4395 | O | Ar35 | P12 | P5 | D | P8 | H | H | D |
| 4396 | O | Ar35 | P12 | P6 | D | P8 | H | H | D |
| 4397 | O | Ar35 | P12 | P7 | D | P8 | H | H | D |
| 4398 | O | Ar35 | P12 | P8 | D | P8 | H | H | D |
| 4399 | O | Ar35 | P12 | P9 | D | P8 | H | H | D |
| 4400 | O | Ar35 | P12 | P10 | D | P8 | H | H | D |
| 4401 | O | Ar35 | P12 | P11 | D | P8 | H | H | D |
| 4402 | O | Ar35 | P12 | P12 | D | P8 | H | H | D |
| 4403 | O | Ar35 | P12 | P13 | D | P8 | H | H | D |
| 4404 | O | Ar35 | P12 | P14 | D | P8 | H | H | D |
| 4405 | O | Ar35 | P12 | P15 | D | P8 | H | H | D |
| 4406 | O | Ar1 | P1 | P1 | P1 | P11 | H | H | H |
| 4407 | O | Ar1 | P1 | P2 | P2 | P11 | H | H | H |
| 4408 | O | Ar1 | P1 | P3 | P1 | P11 | H | H | H |
| 4409 | O | Ar1 | P1 | P4 | P1 | P11 | H | H | H |
| 4410 | O | Ar1 | P1 | P5 | P1 | P11 | H | H | H |
| 4411 | O | Ar1 | P1 | P6 | P1 | P11 | H | H | H |
| 4412 | O | Ar1 | P1 | P7 | P1 | P11 | H | H | H |
| 4413 | O | Ar1 | P1 | P8 | P1 | P11 | H | H | H |
| 4414 | O | Ar1 | P1 | P9 | P1 | P11 | H | H | H |
| 4415 | O | Ar1 | P1 | P10 | P1 | P11 | H | H | H |
| 4416 | O | Ar1 | P1 | P11 | P1 | P11 | H | H | H |
| 4417 | O | Ar1 | P1 | P12 | P1 | P11 | H | H | H |
| 4418 | O | Ar1 | P1 | P13 | P1 | P11 | H | H | H |
| 4419 | O | Ar1 | P1 | P14 | P1 | P11 | H | H | H |
| 4420 | O | Ar1 | P1 | P15 | P1 | P11 | H | H | H |
| 4421 | O | Ar1 | P2 | P1 | P2 | P11 | H | H | H |
| 4422 | O | Ar1 | P2 | P2 | P2 | P11 | H | H | H |
| 4423 | O | Ar1 | P2 | P3 | P2 | P11 | H | H | H |
| 4424 | O | Ar1 | P2 | P4 | P2 | P11 | H | H | H |
| 4425 | O | Ar1 | P2 | P5 | P2 | P11 | H | H | H |
| 4426 | O | Ar1 | P2 | P6 | P2 | P11 | H | H | H |
| 4427 | O | Ar1 | P2 | P7 | P2 | P11 | H | H | H |
| 4428 | O | Ar1 | P2 | P8 | P2 | P11 | H | H | H |
| 4429 | O | Ar1 | P2 | P9 | P2 | P11 | H | H | H |
| 4430 | O | Ar1 | P2 | P10 | P2 | P11 | H | H | H |
| 4431 | O | Ar1 | P2 | P11 | P2 | P11 | H | H | H |
| 4432 | O | Ar1 | P2 | P12 | P2 | P11 | H | H | H |
| 4433 | O | Ar1 | P2 | P13 | P2 | P11 | H | H | H |
| 4434 | O | Ar1 | P2 | P1 | P2 | P11 | H | H | H |
| 4435 | O | Ar1 | P2 | P15 | P2 | P11 | H | H | H |
| 4436 | O | Ar1 | P1 | P1 | D | P11 | H | H | D |
| 4437 | O | Ar1 | P2 | P2 | D | P11 | H | H | D |
| 4438 | O | Ar1 | P2 | P3 | D | P11 | H | H | D |
| 4439 | O | Ar1 | P2 | P4 | D | P11 | H | H | D |
| 4440 | O | Ar1 | P2 | P5 | D | P11 | H | H | D |
| 4441 | O | Ar1 | P2 | P6 | D | P11 | H | H | D |
| 4442 | O | Ar1 | P2 | P7 | D | P11 | H | H | D |
| 4443 | O | Ar1 | P2 | P8 | D | P11 | H | H | D |
| 4444 | O | Ar1 | P2 | P9 | D | P11 | H | H | D |
| 4445 | O | Ar1 | P2 | P10 | D | P11 | H | H | D |
| 4446 | O | Ar1 | P2 | P11 | D | P11 | H | H | D |
| 4447 | O | Ar1 | P2 | P12 | D | P11 | H | H | D |
| 4448 | O | Ar1 | P2 | P13 | D | P11 | H | H | D |
| 4449 | O | Ar1 | P2 | P14 | D | P11 | H | H | D |
| 4450 | O | Ar1 | P2 | P15 | D | P11 | H | H | D |
| 4451 | O | Ar1 | P11 | P1 | P1 | P11 | H | H | H |
| 4452 | O | Ar1 | P11 | P2 | P2 | P11 | H | H | H |
| 4453 | O | Ar1 | P11 | P3 | P1 | P11 | H | H | H |
| 4454 | O | Ar1 | P11 | P4 | P1 | P11 | H | H | H |
| 4455 | O | Ar1 | P11 | P5 | P1 | P11 | H | H | H |
| 4456 | O | Ar1 | P11 | P6 | P1 | P11 | H | H | H |
| 4457 | O | Ar1 | P11 | P7 | P1 | P11 | H | H | H |
| 4458 | O | Ar1 | P11 | P8 | P1 | P11 | H | H | H |
| 4459 | O | Ar1 | P11 | P9 | P1 | P11 | H | H | H |
| 4460 | O | Ar1 | P11 | P10 | P1 | P11 | H | H | H |
| 4461 | O | Ar1 | P11 | P11 | P1 | P11 | H | H | H |
| 4462 | O | Ar1 | P11 | P12 | P1 | P11 | H | H | H |
| 4463 | O | Ar1 | P11 | P13 | P1 | P11 | H | H | H |
| 4464 | O | Ar1 | P11 | P14 | P1 | P11 | H | H | H |
| 4465 | O | Ar1 | P11 | P15 | P1 | P11 | H | H | H |
| 4466 | O | Ar1 | P11 | P1 | P2 | P11 | H | H | H |
| 4467 | O | Ar1 | P11 | P2 | P2 | P11 | H | H | H |
| 4468 | O | Ar1 | P11 | P3 | P2 | P11 | H | H | H |
| 4469 | O | Ar1 | P11 | P4 | P2 | P11 | H | H | H |
| 4470 | O | Ar1 | P11 | P5 | P2 | P11 | H | H | H |
| 4471 | O | Ar1 | P11 | P6 | P2 | P11 | H | H | H |
| 4472 | O | Ar1 | P11 | P7 | P2 | P11 | H | H | H |
| 4473 | O | Ar1 | P11 | P8 | P2 | P11 | H | H | H |
| 4474 | O | Ar1 | P11 | P9 | P2 | P11 | H | H | H |
| 4475 | O | Ar1 | P11 | P10 | P2 | P11 | H | H | H |
| 4476 | O | Ar1 | P11 | P11 | P2 | P11 | H | H | H |
| 4477 | O | Ar1 | P11 | P12 | P2 | P11 | H | H | H |
| 4478 | O | Ar1 | P11 | P13 | P2 | P11 | H | H | H |
| 4479 | O | Ar1 | P11 | P14 | P2 | P11 | H | H | H |
| 4480 | O | Ar1 | P11 | P15 | P2 | P11 | H | H | H |
| 4481 | O | Ar1 | P11 | P1 | D | P11 | H | H | D |
| 4482 | O | Ar1 | P11 | P2 | D | P11 | H | H | D |
| 4483 | O | Ar1 | P11 | P3 | D | P11 | H | H | D |
| 4484 | O | Ar1 | P11 | P4 | D | P11 | H | H | D |
| 4485 | O | Ar1 | P11 | P5 | D | P11 | H | H | D |
| 4486 | O | Ar1 | P11 | P6 | D | P11 | H | H | D |
| 4487 | O | Ar1 | P11 | P7 | D | P11 | H | H | D |
| 4488 | O | Ar1 | P11 | P8 | D | P11 | H | H | D |
| 4489 | O | Ar1 | P11 | P9 | D | P11 | H | H | D |
| 4490 | O | Ar1 | P11 | P10 | D | P11 | H | H | D |
| 4491 | O | Ar1 | P11 | P11 | D | P11 | H | H | D |
| 4492 | O | Ar1 | P11 | P12 | D | P11 | H | H | D |
| 4493 | O | Ar1 | P11 | P13 | D | P11 | H | H | D |
| 4494 | O | Ar1 | P11 | P14 | D | P11 | H | H | D |
| 4495 | O | Ar1 | P11 | P15 | D | P11 | H | H | D |
| 4496 | O | Ar1 | P12 | P1 | P1 | P11 | H | H | H |
| 4497 | O | Ar1 | P12 | P2 | P2 | P11 | H | H | H |
| 4498 | O | Ar1 | P12 | P3 | P1 | P11 | H | H | H |
| 4499 | O | Ar1 | P12 | P4 | P1 | P11 | H | H | H |
| 4500 | O | Ar1 | P12 | P5 | P1 | P11 | H | H | H |
| 4501 | O | Ar1 | P12 | P6 | P1 | P11 | H | H | H |
| 4502 | O | Ar1 | P12 | P7 | P1 | P11 | H | H | H |
| 4503 | O | Ar1 | P12 | P8 | P1 | P11 | H | H | H |
| 4504 | O | Ar1 | P12 | P9 | P1 | P11 | H | H | H |
| 4505 | O | Ar1 | P12 | P10 | P1 | P11 | H | H | H |
| 4506 | O | Ar1 | P12 | P11 | P1 | P11 | H | H | H |
| 4507 | O | Ar1 | P12 | P12 | P1 | P11 | H | H | H |
| 4508 | O | Ar1 | P12 | P13 | P1 | P11 | H | H | H |
| 4509 | O | Ar1 | P12 | P14 | P1 | P1 | H | H | H |
| 4510 | O | Ar1 | P12 | P15 | P1 | P11 | H | H | H |
| 4511 | O | Ar1 | P12 | P1 | P2 | P11 | H | H | H |
| 4512 | O | Ar1 | P12 | P2 | P2 | P11 | H | H | H |
| 4513 | O | Ar1 | P12 | P3 | P2 | P11 | H | H | H |
| 4514 | O | Ar1 | P12 | P4 | P2 | P11 | H | H | H |
| 4515 | O | Ar1 | P12 | P5 | P2 | P11 | H | H | H |
| 4516 | O | Ar1 | P12 | P6 | P2 | P11 | H | H | H |
| 4517 | O | Ar1 | P12 | P7 | P2 | P11 | H | H | H |
| 4518 | O | Ar1 | P12 | P8 | P2 | P11 | H | H | H |
| 4519 | O | Ar1 | P12 | P9 | P2 | P11 | H | H | H |
| 4520 | O | Ar1 | P12 | P10 | P2 | P11 | H | H | H |
| 4521 | O | Ar1 | P12 | P11 | P2 | P11 | H | H | H |
| 4522 | O | Ar1 | P12 | P12 | P2 | P11 | H | H | H |
| 4523 | O | Ar1 | P12 | P13 | P2 | P11 | H | H | H |
| 4524 | O | Ar1 | P12 | P14 | P2 | P11 | H | H | H |
| 4525 | O | Ar1 | P12 | P15 | P2 | P11 | H | H | H |
| 4526 | O | Ar1 | P12 | P1 | D | P11 | H | H | D |
| 4527 | O | Ar1 | P12 | P2 | D | P11 | H | H | D |
| 4528 | O | Ar1 | P12 | P3 | D | P11 | H | H | D |
| 4529 | O | Ar1 | P12 | P4 | D | P11 | H | H | D |
| 4530 | O | Ar1 | P12 | P5 | D | P11 | H | H | D |
| 4531 | O | Ar1 | P12 | P6 | D | P11 | H | H | D |
| 4532 | O | Ar1 | P12 | P7 | D | P11 | H | H | D |
| 4533 | O | Ar1 | P12 | P8 | D | P11 | H | H | D |
| 4534 | O | Ar1 | P12 | P9 | D | P11 | H | H | D |
| 4535 | O | Ar1 | P12 | P10 | D | P11 | H | H | D |
| 4536 | O | Ar1 | P12 | P11 | D | P11 | H | H | D |
| 4537 | O | Ar1 | P12 | P12 | D | P11 | H | H | D |
| 4538 | O | Ar1 | P12 | P13 | D | P11 | H | H | D |
| 4539 | O | Ar1 | P12 | P14 | D | P11 | H | H | D |
| 4540 | O | Ar1 | P12 | P15 | D | P11 | H | H | D |
| 4541 | O | Ar2 | P1 | P1 | P1 | P11 | H | H | H |
| 4542 | O | Ar2 | P1 | P2 | P2 | P11 | H | H | H |
| 4543 | O | Ar2 | P1 | P3 | P1 | P11 | H | H | H |
| 4544 | O | Ar2 | P1 | P4 | P1 | P11 | H | H | H |
| 4545 | O | Ar2 | P1 | P5 | P1 | P11 | H | H | H |
| 4546 | O | Ar2 | P1 | P6 | P1 | P11 | H | H | H |
| 4547 | O | Ar2 | P1 | P7 | P1 | P11 | H | H | H |
| 4548 | O | Ar2 | P1 | P8 | P1 | P11 | H | H | H |
| 4549 | O | Ar2 | P1 | P9 | P1 | P11 | H | H | H |
| 4550 | O | Ar2 | P1 | P10 | P1 | P11 | H | H | H |
| 4551 | O | Ar2 | P1 | P11 | P1 | P11 | H | H | H |
| 4552 | O | Ar2 | P1 | P12 | P1 | P11 | H | H | H |
| 4553 | O | Ar2 | P1 | P13 | P1 | P11 | H | H | H |
| 4554 | O | Ar2 | P1 | P14 | P1 | P11 | H | H | H |
| 4555 | O | Ar2 | P1 | P15 | P1 | P11 | H | H | H |
| 4556 | O | Ar2 | P2 | P1 | P2 | P11 | H | H | H |
| 4557 | O | Ar2 | P2 | P2 | P2 | P11 | H | H | H |
| 4558 | O | Ar2 | P2 | P3 | P2 | P11 | H | H | H |
| 4559 | O | Ar2 | P2 | P4 | P2 | P11 | H | H | H |
| 4560 | O | Ar2 | P2 | P5 | P2 | P11 | H | H | H |
| 4561 | O | Ar2 | P2 | P6 | P2 | P11 | H | H | H |
| 4562 | O | Ar2 | P2 | P7 | P2 | P11 | H | H | H |
| 4563 | O | Ar2 | P2 | P8 | P2 | P11 | H | H | H |
| 4564 | O | Ar2 | P2 | P9 | P2 | P11 | H | H | H |
| 4565 | O | Ar2 | P2 | P10 | P2 | P11 | H | H | H |
| 4566 | O | Ar2 | P2 | P11 | P2 | P11 | H | H | H |
| 4567 | O | Ar2 | P2 | P12 | P2 | P11 | H | H | H |
| 4568 | O | Ar2 | P2 | P13 | P2 | P11 | H | H | H |
| 4569 | O | Ar2 | P2 | P14 | P2 | P11 | H | H | H |
| 4570 | O | Ar2 | P2 | P15 | P2 | P11 | H | H | H |
| 4571 | O | Ar2 | P1 | P1 | D | P11 | H | H | D |
| 4572 | O | Ar2 | P2 | P2 | D | P11 | H | H | D |
| 4573 | O | Ar2 | P2 | P3 | D | P11 | H | H | D |
| 4574 | O | Ar2 | P2 | P4 | D | P11 | H | H | D |
| 4575 | O | Ar2 | P2 | P5 | D | P11 | H | H | D |
| 4576 | O | Ar2 | P2 | P6 | D | P11 | H | H | D |
| 4577 | O | Ar2 | P2 | P7 | D | P11 | H | H | D |
| 4578 | O | Ar2 | P2 | P8 | D | P11 | H | H | D |
| 4579 | O | Ar2 | P2 | P9 | D | P11 | H | H | D |
| 4580 | O | Ar2 | P2 | P10 | D | P11 | H | H | D |
| 4581 | O | Ar2 | P2 | P11 | D | P11 | H | H | D |
| 4582 | O | Ar2 | P2 | P12 | D | P11 | H | H | D |
| 4583 | O | Ar2 | P2 | P13 | D | P11 | H | H | D |
| 4584 | O | Ar2 | P2 | P14 | D | P11 | H | H | D |
| 4585 | O | Ar2 | P2 | P15 | D | P11 | H | H | D |
| 4586 | O | Ar2 | P11 | P1 | P1 | P11 | H | H | H |
| 4587 | O | Ar2 | P11 | P2 | P2 | P11 | H | H | H |
| 4588 | O | Ar2 | P11 | P3 | P1 | P11 | H | H | H |
| 4589 | O | Ar2 | P11 | P4 | P1 | P11 | H | H | H |
| 4590 | O | Ar2 | P11 | P5 | P1 | P11 | H | H | H |
| 4591 | O | Ar2 | P11 | P6 | P1 | P11 | H | H | H |
| 4592 | O | Ar2 | P11 | P7 | P1 | P11 | H | H | H |
| 4593 | O | Ar2 | P11 | P8 | P1 | P11 | H | H | H |
| 4594 | O | Ar2 | P11 | P9 | P1 | P11 | H | H | H |
| 4595 | O | Ar2 | P11 | P10 | P1 | P11 | H | H | H |
| 4596 | O | Ar2 | P11 | P11 | P1 | P11 | H | H | H |
| 4597 | O | Ar2 | P11 | P12 | P1 | P11 | H | H | H |
| 4598 | O | Ar2 | P11 | P13 | P1 | P11 | H | H | H |
| 4599 | O | Ar2 | P11 | P14 | P1 | P11 | H | H | H |
| 4600 | O | Ar2 | P11 | P15 | P1 | P11 | H | H | H |
| 4601 | O | Ar2 | P11 | P1 | P2 | P11 | H | H | H |
| 4602 | O | Ar2 | P11 | P2 | P2 | P11 | H | H | H |
| 4603 | O | Ar2 | P11 | P3 | P2 | P11 | H | H | H |
| 4604 | O | Ar2 | P11 | P4 | P2 | P11 | H | H | H |
| 4605 | O | Ar2 | P11 | P5 | P2 | P11 | H | H | H |
| 4606 | O | Ar2 | P11 | P6 | P2 | P11 | H | H | H |
| 4607 | O | Ar2 | P11 | P7 | P2 | P11 | H | H | H |
| 4608 | O | Ar2 | P11 | P8 | P2 | P11 | H | H | H |
| 4609 | O | Ar2 | P11 | P9 | P2 | P11 | H | H | H |
| 4610 | O | Ar2 | P11 | P10 | P2 | P11 | H | H | H |
| 4611 | O | Ar2 | P11 | P11 | P2 | P11 | H | H | H |
| 4612 | O | Ar2 | P11 | P12 | P2 | P11 | H | H | H |
| 4613 | O | Ar2 | P11 | P13 | P2 | P11 | H | H | H |
| 4614 | O | Ar2 | P11 | P14 | P2 | P11 | H | H | H |
| 4615 | O | Ar2 | P11 | P15 | P2 | P11 | H | H | H |
| 4616 | O | Ar2 | P11 | P1 | D | P11 | H | H | D |
| 4617 | O | Ar2 | P11 | P2 | D | P11 | H | H | D |
| 4618 | O | Ar2 | P11 | P3 | D | P11 | H | H | D |
| 4619 | O | Ar2 | P11 | P4 | D | P11 | H | H | D |
| 4620 | O | Ar2 | P11 | P5 | D | P11 | H | H | D |
| 4621 | O | Ar2 | P11 | P6 | D | P11 | H | H | D |
| 4622 | O | Ar2 | P11 | P7 | D | P11 | H | H | D |
| 4623 | O | Ar2 | P11 | P8 | D | P11 | H | H | D |
| 4624 | O | Ar2 | P11 | P9 | D | P11 | H | H | D |
| 4625 | O | Ar2 | P11 | P10 | D | P11 | H | H | D |
| 4626 | O | Ar2 | P11 | P11 | D | P11 | H | H | D |
| 4627 | O | Ar2 | P11 | P12 | D | P11 | H | H | D |
| 4628 | O | Ar2 | P11 | P13 | D | P11 | H | H | D |
| 4629 | O | Ar2 | P11 | P14 | D | P11 | H | H | D |
| 4630 | O | Ar2 | P11 | P15 | D | P11 | H | H | D |
| 4631 | O | Ar2 | P12 | P1 | P1 | P11 | H | H | H |
| 4632 | O | Ar2 | P12 | P2 | P2 | P11 | H | H | H |
| 4633 | O | Ar2 | P12 | P3 | P1 | P11 | H | H | H |
| 4634 | O | Ar2 | P12 | P4 | P1 | P11 | H | H | H |
| 4635 | O | Ar2 | P12 | P5 | P1 | P11 | H | H | H |
| 4636 | O | Ar2 | P12 | P6 | P1 | P11 | H | H | H |
| 4637 | O | Ar2 | P12 | P7 | P1 | P11 | H | H | H |
| 4638 | O | Ar2 | P12 | P8 | P1 | P11 | H | H | H |
| 4639 | O | Ar2 | P12 | P9 | P1 | P11 | H | H | H |
| 4640 | O | Ar2 | P12 | P10 | P1 | P11 | H | H | H |
| 4641 | O | Ar2 | P12 | P11 | P1 | P11 | H | H | H |
| 4642 | O | Ar2 | P12 | P12 | P1 | P11 | H | H | H |
| 4643 | O | Ar2 | P12 | P13 | P1 | P11 | H | H | H |
| 4644 | O | Ar2 | P12 | P14 | P1 | P11 | H | H | H |
| 4645 | O | Ar2 | P12 | P15 | P1 | P11 | H | H | H |
| 4646 | O | Ar2 | P12 | P1 | P2 | P11 | H | H | H |
| 4647 | O | Ar2 | P12 | P2 | P2 | P11 | H | H | H |
| 4648 | O | Ar2 | P12 | P3 | P2 | P11 | H | H | H |
| 4649 | O | Ar2 | P12 | P4 | P2 | P11 | H | H | H |
| 4650 | O | Ar2 | P12 | P5 | P2 | P11 | H | H | H |
| 4651 | O | Ar2 | P12 | P6 | P2 | P11 | H | H | H |
| 4652 | O | Ar2 | P12 | P7 | P2 | P11 | H | H | H |
| 4653 | O | Ar2 | P12 | P8 | P2 | P11 | H | H | H |
| 4654 | O | Ar2 | P12 | P9 | P2 | P11 | H | H | H |
| 4655 | O | Ar2 | P12 | P10 | P2 | P11 | H | H | H |
| 4656 | O | Ar2 | P12 | P11 | P2 | P11 | H | H | H |
| 4657 | O | Ar2 | P12 | P12 | P2 | P11 | H | H | H |
| 4658 | O | Ar2 | P12 | P13 | P2 | P11 | H | H | H |
| 4659 | O | Ar2 | P12 | P14 | P2 | P11 | H | H | H |
| 4660 | O | Ar2 | P12 | P15 | P2 | P11 | H | H | H |
| 4661 | O | Ar2 | P12 | P1 | D | P11 | H | H | D |
| 4662 | O | Ar2 | P12 | P2 | D | P11 | H | H | D |
| 4663 | O | Ar2 | P12 | P3 | D | P11 | H | H | D |
| 4664 | O | Ar2 | P12 | P4 | D | P11 | H | H | D |
| 4665 | O | Ar2 | P12 | P5 | D | P11 | H | H | D |
| 4666 | O | Ar2 | P12 | P6 | D | P11 | H | H | D |
| 4667 | O | Ar2 | P12 | P7 | D | P11 | H | H | D |
| 4668 | O | Ar2 | P12 | P8 | D | P11 | H | H | D |
| 4669 | O | Ar2 | P12 | P9 | D | P11 | H | H | D |
| 4670 | O | Ar2 | P12 | P10 | D | P11 | H | H | D |
| 4671 | O | Ar2 | P12 | P11 | D | P11 | H | H | D |
| 4672 | O | Ar2 | P12 | P12 | D | P11 | H | H | D |
| 4673 | O | Ar2 | P12 | P13 | D | P11 | H | H | D |
| 4674 | O | Ar2 | P12 | P14 | D | P11 | H | H | D |
| 4675 | O | Ar2 | P12 | P15 | D | P11 | H | H | D |
| 4676 | O | Ar31 | P1 | P1 | P1 | P11 | H | H | H |
| 4677 | O | Ar31 | P1 | P2 | P2 | P11 | H | H | H |
| 4678 | O | Ar31 | P1 | P3 | P1 | P11 | H | H | H |
| 4679 | O | Ar31 | P1 | P4 | P1 | P11 | H | H | H |
| 4680 | O | Ar31 | P1 | P5 | P1 | P11 | H | H | H |
| 4681 | O | Ar31 | P1 | P6 | P1 | P11 | H | H | H |
| 4682 | O | Ar31 | P1 | P7 | P1 | P11 | H | H | H |
| 4683 | O | Ar31 | P1 | P8 | P1 | P11 | H | H | H |
| 4684 | O | Ar31 | P1 | P9 | P1 | P11 | H | H | H |
| 4685 | O | Ar31 | P1 | P10 | P1 | P11 | H | H | H |
| 4686 | O | Ar31 | P1 | P11 | P1 | P11 | H | H | H |
| 4687 | O | Ar31 | P1 | P12 | P1 | P11 | H | H | H |
| 4688 | O | Ar31 | P1 | P13 | P1 | P11 | H | H | H |
| 4689 | O | Ar31 | P1 | P14 | P1 | P11 | H | H | H |
| 4690 | O | Ar31 | P1 | P15 | P1 | P11 | H | H | H |
| 4691 | O | Ar31 | P2 | P1 | P2 | P11 | H | H | H |
| 4692 | O | Ar31 | P2 | P2 | P2 | P11 | H | H | H |
| 4693 | O | Ar31 | P2 | P3 | P2 | P11 | H | H | H |
| 4694 | O | Ar31 | P2 | P4 | P2 | P11 | H | H | H |
| 4695 | O | Ar31 | P2 | P5 | P2 | P11 | H | H | H |
| 4696 | O | Ar31 | P2 | P6 | P2 | P11 | H | H | H |
| 4697 | O | Ar31 | P2 | P7 | P2 | P11 | H | H | H |
| 4698 | O | Ar31 | P2 | P8 | P2 | P11 | H | H | H |
| 4699 | O | Ar31 | P2 | P9 | P2 | P11 | H | H | H |
| 4700 | O | Ar31 | P2 | P10 | P2 | P11 | H | H | H |
| 4701 | O | Ar31 | P2 | P11 | P2 | P11 | H | H | H |
| 4702 | O | Ar31 | P2 | P12 | P2 | P11 | H | H | H |
| 4703 | O | Ar31 | P2 | P13 | P2 | P11 | H | H | H |
| 4704 | O | Ar31 | P2 | P14 | P2 | P11 | H | H | H |
| 4705 | O | Ar31 | P2 | P15 | P2 | P11 | H | H | H |
| 4706 | O | Ar31 | P1 | P1 | D | P11 | H | H | D |
| 4707 | O | Ar31 | P2 | P2 | D | P11 | H | H | D |
| 4708 | O | Ar31 | P2 | P3 | D | P11 | H | H | D |
| 4709 | O | Ar31 | P2 | P4 | D | P1 | H | H | D |
| 4710 | O | Ar31 | P2 | P5 | D | P11 | H | H | D |
| 4711 | O | Ar31 | P2 | P6 | D | P11 | H | H | D |
| 4712 | O | Ar31 | P2 | P7 | D | P11 | H | H | D |
| 4713 | O | Ar31 | P2 | P8 | D | P11 | H | H | D |
| 4714 | O | Ar31 | P2 | P9 | D | P11 | H | H | D |
| 4715 | O | Ar31 | P2 | P10 | D | P11 | H | H | D |
| 4716 | O | Ar31 | P2 | P11 | D | P11 | H | H | D |
| 4717 | O | Ar31 | P2 | P12 | D | P11 | H | H | D |
| 4718 | O | Ar31 | P2 | P13 | D | P11 | H | H | D |
| 4719 | O | Ar31 | P2 | P14 | D | P11 | H | H | D |
| 4720 | O | Ar31 | P2 | P15 | D | P11 | H | H | D |
| 4721 | O | Ar31 | P11 | P1 | P1 | P11 | H | H | H |
| 4722 | O | Ar31 | P11 | P2 | P2 | P11 | H | H | H |
| 4723 | O | Ar31 | P11 | P3 | P1 | P1 | H | H | H |
| 4724 | O | Ar31 | P11 | P4 | P1 | P11 | H | H | H |
| 4725 | O | Ar31 | P11 | P5 | P1 | P11 | H | H | H |
| 4726 | O | Ar31 | P11 | P6 | P1 | P11 | H | H | H |
| 4727 | O | Ar31 | P11 | P7 | P1 | P11 | H | H | H |
| 4728 | O | Ar31 | P11 | P8 | P1 | P11 | H | H | H |
| 4729 | O | Ar31 | P11 | P9 | P1 | P11 | H | H | H |
| 4730 | O | Ar31 | P11 | P10 | P1 | P11 | H | H | H |
| 4731 | O | Ar31 | P11 | P11 | P1 | P11 | H | H | H |
| 4732 | O | Ar31 | P11 | P12 | P1 | P11 | H | H | H |
| 4733 | O | Ar31 | P11 | P13 | P1 | P11 | H | H | H |
| 4734 | O | Ar31 | P11 | P14 | P1 | P11 | H | H | H |
| 4735 | O | Ar31 | P11 | P15 | P1 | P11 | H | H | H |
| 4736 | O | Ar31 | P11 | P1 | P2 | P11 | H | H | H |
| 4737 | O | Ar31 | P11 | P2 | P2 | P11 | H | H | H |
| 4738 | O | Ar31 | P11 | P3 | P2 | P11 | H | H | H |
| 4739 | O | Ar31 | P11 | P4 | P2 | P11 | H | H | H |
| 4740 | O | Ar31 | P11 | P5 | P2 | P11 | H | H | H |
| 4741 | O | Ar31 | P11 | P6 | P2 | P11 | H | H | H |
| 4742 | O | Ar31 | P11 | P7 | P2 | P11 | H | H | H |
| 4743 | O | Ar31 | P11 | P8 | P2 | P11 | H | H | H |
| 4744 | O | Ar31 | P11 | P9 | P2 | P11 | H | H | H |
| 4745 | O | Ar31 | P11 | P10 | P2 | P11 | H | H | H |
| 4746 | O | Ar31 | P11 | P11 | P2 | P11 | H | H | H |
| 4747 | O | Ar31 | P11 | P12 | P2 | P11 | H | H | H |
| 4748 | O | Ar31 | P11 | P13 | P2 | P11 | H | H | H |
| 4749 | O | Ar31 | P11 | P14 | P2 | P11 | H | H | H |
| 4750 | O | Ar31 | P11 | P15 | P2 | P11 | H | H | H |
| 4751 | O | Ar31 | P11 | P1 | D | P11 | H | H | D |
| 4752 | O | Ar31 | P11 | P2 | D | P11 | H | H | D |
| 4753 | O | Ar31 | P11 | P3 | D | P11 | H | H | D |
| 4754 | O | Ar31 | P11 | P4 | D | P11 | H | H | D |
| 4755 | O | Ar31 | P11 | P5 | D | P11 | H | H | D |
| 4756 | O | Ar31 | P11 | P6 | D | P11 | H | H | D |
| 4757 | O | Ar31 | P11 | P7 | D | P11 | H | H | D |
| 4758 | O | Ar31 | P11 | P8 | D | P11 | H | H | D |
| 4759 | O | Ar31 | P11 | P9 | D | P11 | H | H | D |
| 4760 | O | Ar31 | P11 | P10 | D | P11 | H | H | D |
| 4761 | O | Ar31 | P11 | P11 | D | P11 | H | H | D |
| 4762 | O | Ar31 | P11 | P12 | D | P11 | H | H | D |
| 4763 | O | Ar31 | P11 | P13 | D | P11 | H | H | D |
| 4764 | O | Ar31 | P11 | P14 | D | P11 | H | H | D |
| 4765 | O | Ar31 | P11 | P15 | D | P11 | H | H | D |
| 4766 | O | Ar31 | P12 | P1 | P1 | P11 | H | H | H |
| 4767 | O | Ar31 | P12 | P2 | P2 | P11 | H | H | H |
| 4768 | O | Ar31 | P12 | P3 | P1 | P11 | H | H | H |
| 4769 | O | Ar31 | P12 | P4 | P1 | P11 | H | H | H |
| 4770 | O | Ar31 | P12 | P5 | P1 | P11 | H | H | H |
| 4771 | O | Ar31 | P12 | P6 | P1 | P11 | H | H | H |
| 4772 | O | Ar31 | P12 | P7 | P1 | P11 | H | H | H |
| 4773 | O | Ar31 | P12 | P8 | P1 | P11 | H | H | H |
| 4774 | O | Ar31 | P12 | P9 | P1 | P11 | H | H | H |
| 4775 | O | Ar31 | P12 | P10 | P1 | P11 | H | H | H |
| 4776 | O | Ar31 | P12 | P11 | P1 | P11 | H | H | H |
| 4777 | O | Ar31 | P12 | P12 | P1 | P11 | H | H | H |
| 4778 | O | Ar31 | P12 | P13 | P1 | P11 | H | H | H |
| 4779 | O | Ar31 | P12 | P14 | P1 | P11 | H | H | H |
| 4780 | O | Ar31 | P12 | P15 | P1 | P11 | H | H | H |
| 4781 | O | Ar31 | P12 | P1 | P2 | P11 | H | H | H |
| 4782 | O | Ar31 | P12 | P2 | P2 | P11 | H | H | H |
| 4783 | O | Ar31 | P12 | P3 | P2 | P11 | H | H | H |
| 4784 | O | Ar31 | P12 | P4 | P2 | P11 | H | H | H |
| 4785 | O | Ar31 | P12 | P5 | P2 | P11 | H | H | H |
| 4786 | O | Ar31 | P12 | P6 | P2 | P11 | H | H | H |
| 4787 | O | Ar31 | P12 | P7 | P2 | P11 | H | H | H |
| 4788 | O | Ar31 | P12 | P8 | P2 | P11 | H | H | H |
| 4789 | O | Ar31 | P12 | P9 | P2 | P11 | H | H | H |
| 4790 | O | Ar31 | P12 | P10 | P2 | P11 | H | H | H |
| 4791 | O | Ar31 | P12 | P11 | P2 | P11 | H | H | H |
| 4792 | O | Ar31 | P12 | P12 | P2 | P11 | H | H | H |
| 4793 | O | Ar31 | P12 | P13 | P2 | P11 | H | H | H |
| 4794 | O | Ar31 | P12 | P14 | P2 | P11 | H | H | H |
| 4795 | O | Ar31 | P12 | P15 | P2 | P11 | H | H | H |
| 4796 | O | Ar31 | P12 | P1 | D | P11 | H | H | D |
| 4797 | O | Ar31 | P12 | P2 | D | P11 | H | H | D |
| 4798 | O | Ar31 | P12 | P3 | D | P11 | H | H | D |
| 4799 | O | Ar31 | P12 | P4 | D | P11 | H | H | D |
| 4800 | O | Ar31 | P12 | P5 | D | P11 | H | H | D |
| 4801 | O | Ar31 | P12 | P6 | D | P11 | H | H | D |
| 4802 | O | Ar31 | P12 | P7 | D | P11 | H | H | D |
| 4803 | O | Ar31 | P12 | P8 | D | P11 | H | H | D |
| 4804 | O | Ar31 | P12 | P9 | D | P11 | H | H | D |
| 4805 | O | Ar31 | P12 | P10 | D | P11 | H | H | D |
| 4806 | O | Ar31 | P12 | P11 | D | P11 | H | H | D |
| 4807 | O | Ar31 | P12 | P12 | D | P11 | H | H | D |
| 4808 | O | Ar31 | P12 | P13 | D | P11 | H | H | D |
| 4809 | O | Ar31 | P12 | P14 | D | P11 | H | H | D |
| 4810 | O | Ar31 | P12 | P15 | D | P11 | H | H | D |
| 4811 | O | Ar32 | P1 | P1 | P1 | P11 | H | H | H |
| 4812 | O | Ar32 | P1 | P2 | P2 | P11 | H | H | H |
| 4813 | O | Ar32 | P1 | P3 | P1 | P11 | H | H | H |
| 4814 | O | Ar32 | P1 | P4 | P1 | P11 | H | H | H |
| 4815 | O | Ar32 | P1 | P5 | P1 | P11 | H | H | H |
| 4816 | O | Ar32 | P1 | P6 | P1 | P11 | H | H | H |
| 4817 | O | Ar32 | P1 | P7 | P1 | P11 | H | H | H |
| 4818 | O | Ar32 | P1 | P8 | P1 | P11 | H | H | H |
| 4819 | O | Ar32 | P1 | P9 | P1 | P11 | H | H | H |
| 4820 | O | Ar32 | P1 | P10 | P1 | P11 | H | H | H |
| 4821 | O | Ar32 | P1 | P11 | P1 | P11 | H | H | H |
| 4822 | O | Ar32 | P1 | P12 | P1 | P11 | H | H | H |
| 4823 | O | Ar32 | P1 | P13 | P1 | P11 | H | H | H |
| 4824 | O | Ar32 | P1 | P14 | P1 | P1 | H | H | H |
| 4825 | O | Ar32 | P1 | P15 | P1 | P11 | H | H | H |
| 4826 | O | Ar32 | P2 | P1 | P2 | P11 | H | H | H |
| 4827 | O | Ar32 | P2 | P2 | P2 | P11 | H | H | H |
| 4828 | O | Ar32 | P2 | P3 | P2 | P11 | H | H | H |
| 4829 | O | Ar32 | P2 | P4 | P2 | P11 | H | H | H |
| 4830 | O | Ar32 | P2 | P5 | P2 | P11 | H | H | H |
| 4831 | O | Ar32 | P2 | P6 | P2 | P11 | H | H | H |
| 4832 | O | Ar32 | P2 | P7 | P2 | P11 | H | H | H |
| 4833 | O | Ar32 | P2 | P8 | P2 | P11 | H | H | H |
| 4834 | O | Ar32 | P2 | P9 | P2 | P11 | H | H | H |
| 4835 | O | Ar32 | P2 | P10 | P2 | P1 | H | H | H |
| 4836 | O | Ar32 | P2 | P1 | P2 | P11 | H | H | H |
| 4837 | O | Ar32 | P2 | P12 | P2 | P11 | H | H | H |
| 4838 | O | Ar32 | P2 | P13 | P2 | P11 | H | H | H |
| 4839 | O | Ar32 | P2 | P14 | P2 | P11 | H | H | H |
| 4840 | O | Ar32 | P2 | P15 | P2 | P1 | H | H | H |
| 4841 | O | Ar32 | P1 | P1 | D | P11 | H | H | D |
| 4842 | O | Ar32 | P2 | P2 | D | P11 | H | H | D |
| 4843 | O | Ar32 | P2 | P3 | D | P11 | H | H | D |
| 4844 | O | Ar32 | P2 | P4 | D | P11 | H | H | D |
| 4845 | O | Ar32 | P2 | P5 | D | P11 | H | H | D |
| 4846 | O | Ar32 | P2 | P6 | D | P11 | H | H | D |
| 4847 | O | Ar32 | P2 | P7 | D | P11 | H | H | D |
| 4848 | O | Ar32 | P2 | P8 | D | P11 | H | H | D |
| 4849 | O | Ar32 | P2 | P9 | D | P11 | H | H | D |
| 4850 | O | Ar32 | P2 | P10 | D | P11 | H | H | D |
| 4851 | O | Ar32 | P2 | P11 | D | P11 | H | H | D |
| 4852 | O | Ar32 | P2 | P12 | D | P11 | H | H | D |
| 4853 | O | Ar32 | P2 | P13 | D | P1 | H | H | D |
| 4854 | O | Ar32 | P2 | P14 | D | P11 | H | H | D |
| 4855 | O | Ar32 | P2 | P15 | D | P11 | H | H | D |
| 4856 | O | Ar32 | P11 | P1 | P1 | P11 | H | H | H |
| 4857 | O | Ar32 | P11 | P2 | P2 | P11 | H | H | H |
| 4858 | O | Ar32 | P11 | P3 | P1 | P1 | H | H | H |
| 4859 | O | Ar32 | P11 | P4 | P1 | P11 | H | H | H |
| 4860 | O | Ar32 | P11 | P5 | P1 | P11 | H | H | H |
| 4861 | O | Ar32 | P11 | P6 | P1 | P11 | H | H | H |
| 4862 | O | Ar32 | P11 | P7 | P1 | P11 | H | H | H |
| 4863 | O | Ar32 | P11 | P8 | P1 | P1 | H | H | H |
| 4864 | O | Ar32 | P11 | P9 | P1 | P11 | H | H | H |
| 4865 | O | Ar32 | P11 | P10 | P1 | P11 | H | H | H |
| 4866 | O | Ar32 | P11 | P11 | P1 | P11 | H | H | H |
| 4867 | O | Ar32 | P11 | P12 | P1 | P11 | H | H | H |
| 4868 | O | Ar32 | P11 | P13 | P1 | P11 | H | H | H |
| 4869 | O | Ar32 | P11 | P14 | P1 | P11 | H | H | H |
| 4870 | O | Ar32 | P11 | P15 | P1 | P11 | H | H | H |
| 4871 | O | Ar32 | P11 | P1 | P2 | P11 | H | H | H |
| 4872 | O | Ar32 | P11 | P2 | P2 | P11 | H | H | H |
| 4873 | O | Ar32 | P11 | P3 | P2 | P11 | H | H | H |
| 4874 | O | Ar32 | P11 | P4 | P2 | P11 | H | H | H |
| 4875 | O | Ar32 | P11 | P5 | P2 | P11 | H | H | H |
| 4876 | O | Ar32 | P11 | P6 | P2 | P11 | H | H | H |
| 4877 | O | Ar32 | P11 | P7 | P2 | P11 | H | H | H |
| 4878 | O | Ar32 | P11 | P8 | P2 | P11 | H | H | H |
| 4879 | O | Ar32 | P11 | P9 | P2 | P11 | H | H | H |
| 4880 | O | Ar32 | P11 | P10 | P2 | P11 | H | H | H |
| 4881 | O | Ar32 | P11 | P11 | P2 | P11 | H | H | H |
| 4882 | O | Ar32 | P11 | P12 | P2 | P11 | H | H | H |
| 4883 | O | Ar32 | P11 | P13 | P2 | P11 | H | H | H |
| 4884 | O | Ar32 | P11 | P14 | P2 | P11 | H | H | H |
| 4885 | O | Ar32 | P11 | P15 | P2 | P11 | H | H | H |
| 4886 | O | Ar32 | P11 | P1 | D | P11 | H | H | D |
| 4887 | O | Ar32 | P11 | P2 | D | P11 | H | H | D |
| 4888 | O | Ar32 | P11 | P3 | D | P11 | H | H | D |
| 4889 | O | Ar32 | P11 | P4 | D | P11 | H | H | D |
| 4890 | O | Ar32 | P11 | P5 | D | P11 | H | H | D |
| 4891 | O | Ar32 | P11 | P6 | D | P11 | H | H | D |
| 4892 | O | Ar32 | P11 | P7 | D | P11 | H | H | D |
| 4893 | O | Ar32 | P11 | P8 | D | P11 | H | H | D |
| 4894 | O | Ar32 | P11 | P9 | D | P11 | H | H | D |
| 4895 | O | Ar32 | P11 | P10 | D | P11 | H | H | D |
| 4896 | O | Ar32 | P11 | P11 | D | P11 | H | H | D |
| 4897 | O | Ar32 | P11 | P12 | D | P11 | H | H | D |
| 4898 | O | Ar32 | P11 | P13 | D | P11 | H | H | D |
| 4899 | O | Ar32 | P11 | P14 | D | P11 | H | H | D |
| 4900 | O | Ar32 | P11 | P15 | D | P11 | H | H | D |
| 4901 | O | Ar32 | P12 | P1 | P1 | P11 | H | H | H |
| 4902 | O | Ar32 | P12 | P2 | P2 | P11 | H | H | H |
| 4903 | O | Ar32 | P12 | P3 | P1 | P11 | H | H | H |
| 4904 | O | Ar32 | P12 | P4 | P1 | P11 | H | H | H |
| 4905 | O | Ar32 | P12 | P5 | P1 | P11 | H | H | H |
| 4906 | O | Ar32 | P12 | P6 | P1 | P11 | H | H | H |
| 4907 | O | Ar32 | P12 | P7 | P1 | P11 | H | H | H |
| 4908 | O | Ar32 | P12 | P8 | P1 | P11 | H | H | H |
| 4909 | O | Ar32 | P12 | P9 | P1 | P11 | H | H | H |
| 4910 | O | Ar32 | P12 | P10 | P1 | P11 | H | H | H |
| 4911 | O | Ar32 | P12 | P11 | P1 | P11 | H | H | H |
| 4912 | O | Ar32 | P12 | P12 | P1 | P11 | H | H | H |
| 4913 | O | Ar32 | P12 | P13 | P1 | P11 | H | H | H |
| 4914 | O | Ar32 | P12 | P14 | P1 | P11 | H | H | H |
| 4915 | O | Ar32 | P12 | P15 | P1 | P11 | H | H | H |
| 4916 | O | Ar32 | P12 | P1 | P2 | P11 | H | H | H |
| 4917 | O | Ar32 | P12 | P2 | P2 | P11 | H | H | H |
| 4918 | O | Ar32 | P12 | P3 | P2 | P11 | H | H | H |
| 4919 | O | Ar32 | P12 | P4 | P2 | P11 | H | H | H |
| 4920 | O | Ar32 | P12 | P5 | P2 | P11 | H | H | H |
| 4921 | O | Ar32 | P12 | P6 | P2 | P11 | H | H | H |
| 4922 | O | Ar32 | P12 | P7 | P2 | P11 | H | H | H |
| 4923 | O | Ar32 | P12 | P8 | P2 | P11 | H | H | H |
| 4924 | O | Ar32 | P12 | P9 | P2 | P11 | H | H | H |
| 4925 | O | Ar32 | P12 | P10 | P2 | P11 | H | H | H |
| 4926 | O | Ar32 | P12 | P11 | P2 | P11 | H | H | H |
| 4927 | O | Ar32 | P12 | P12 | P2 | P11 | H | H | H |
| 4928 | O | Ar32 | P12 | P13 | P2 | P11 | H | H | H |
| 4929 | O | Ar32 | P12 | P14 | P2 | P11 | H | H | H |
| 4930 | O | Ar32 | P12 | P15 | P2 | P11 | H | H | H |
| 4931 | O | Ar32 | P12 | P1 | D | P11 | H | H | D |
| 4932 | O | Ar32 | P12 | P2 | D | P11 | H | H | D |
| 4933 | O | Ar32 | P12 | P3 | D | P11 | H | H | D |
| 4934 | O | Ar32 | P12 | P4 | D | P11 | H | H | D |
| 4935 | O | Ar32 | P12 | P5 | D | P11 | H | H | D |
| 4936 | O | Ar32 | P12 | P6 | D | P11 | H | H | D |
| 4937 | O | Ar32 | P12 | P7 | D | P11 | H | H | D |
| 4938 | O | Ar32 | P12 | P8 | D | P11 | H | H | D |
| 4939 | O | Ar32 | P12 | P9 | D | P11 | H | H | D |
| 4940 | O | Ar32 | P12 | P10 | D | P11 | H | H | D |
| 4941 | O | Ar32 | P12 | P11 | D | P11 | H | H | D |
| 4942 | O | Ar32 | P12 | P12 | D | P11 | H | H | D |
| 4943 | O | Ar32 | P12 | P13 | D | P11 | H | H | D |
| 4944 | O | Ar32 | P12 | P14 | D | P11 | H | H | D |
| 4945 | O | Ar32 | P12 | P15 | D | P11 | H | H | D |
| 4946 | O | Ar35 | P1 | P1 | P1 | P11 | H | H | H |
| 4947 | O | Ar35 | P1 | P2 | P2 | P11 | H | H | H |
| 4948 | O | Ar35 | P1 | P3 | P1 | P11 | H | H | H |
| 4949 | O | Ar35 | P1 | P4 | P1 | P11 | H | H | H |
| 4950 | O | Ar35 | P1 | P5 | P1 | P11 | H | H | H |
| 4951 | O | Ar35 | P1 | P6 | P1 | P11 | H | H | H |
| 4952 | O | Ar35 | P1 | P7 | P1 | P11 | H | H | H |
| 4953 | O | Ar35 | P1 | P8 | P1 | P11 | H | H | H |
| 4954 | O | Ar35 | P1 | P9 | P1 | P11 | H | H | H |
| 4955 | O | Ar35 | P1 | P10 | P1 | P11 | H | H | H |
| 4956 | O | Ar35 | P1 | P11 | P1 | P11 | H | H | H |
| 4957 | O | Ar35 | P1 | P12 | P1 | P11 | H | H | H |
| 4958 | O | Ar35 | P1 | P13 | P1 | P11 | H | H | H |
| 4959 | O | Ar35 | P1 | P14 | P1 | P11 | H | H | H |
| 4960 | O | Ar35 | P1 | P15 | P1 | P11 | H | H | H |
| 4961 | O | Ar35 | P2 | P1 | P2 | P11 | H | H | H |
| 4962 | O | Ar35 | P2 | P2 | P2 | P11 | H | H | H |
| 4963 | O | Ar35 | P2 | P3 | P2 | P11 | H | H | H |
| 4964 | O | Ar35 | P2 | P4 | P2 | P11 | H | H | H |
| 4965 | O | Ar35 | P2 | P5 | P2 | P11 | H | H | H |
| 4966 | O | Ar35 | P2 | P6 | P2 | P11 | H | H | H |
| 4967 | O | Ar35 | P2 | P7 | P2 | P11 | H | H | H |
| 4968 | O | Ar35 | P2 | P8 | P2 | P11 | H | H | H |
| 4969 | O | Ar35 | P2 | P9 | P2 | P11 | H | H | H |
| 4970 | O | Ar35 | P2 | P10 | P2 | P11 | H | H | H |
| 4971 | O | Ar35 | P2 | P11 | P2 | P11 | H | H | H |
| 4972 | O | Ar35 | P2 | P12 | P2 | P11 | H | H | H |
| 4973 | O | Ar35 | P2 | P13 | P2 | P11 | H | H | H |
| 4974 | O | Ar35 | P2 | P14 | P2 | P11 | H | H | H |
| 4975 | O | Ar35 | P2 | P15 | P2 | P11 | H | H | H |
| 4976 | O | Ar35 | P1 | P1 | D | P11 | H | H | D |
| 4977 | O | Ar35 | P2 | P2 | D | P11 | H | H | D |
| 4978 | O | Ar35 | P2 | P3 | D | P11 | H | H | D |
| 4979 | O | Ar35 | P2 | P4 | D | P11 | H | H | D |
| 4980 | O | Ar35 | P2 | P5 | D | P11 | H | H | D |
| 4981 | O | Ar35 | P2 | P6 | D | P11 | H | H | D |
| 4982 | O | Ar35 | P2 | P7 | D | P11 | H | H | D |
| 4983 | O | Ar35 | P2 | P8 | D | P11 | H | H | D |
| 4984 | O | Ar35 | P2 | P9 | D | P11 | H | H | D |
| 4985 | O | Ar35 | P2 | P10 | D | P11 | H | H | D |
| 4986 | O | Ar35 | P2 | P11 | D | P11 | H | H | D |
| 4987 | O | Ar35 | P2 | P12 | D | P11 | H | H | D |
| 4988 | O | Ar35 | P2 | P13 | D | P11 | H | H | D |
| 4989 | O | Ar35 | P2 | P14 | D | P11 | H | H | D |
| 4990 | O | Ar35 | P2 | P15 | D | P11 | H | H | D |
| 4991 | O | Ar35 | P11 | P1 | P1 | P11 | H | H | H |
| 4992 | O | Ar35 | P11 | P2 | P2 | P11 | H | H | H |
| 4993 | O | Ar35 | P11 | P3 | P1 | P11 | H | H | H |
| 4994 | O | Ar35 | P11 | P4 | P1 | P11 | H | H | H |
| 4995 | O | Ar35 | P11 | P5 | P1 | P11 | H | H | H |
| 4996 | O | Ar35 | P11 | P6 | P1 | P11 | H | H | H |
| 4997 | O | Ar35 | P11 | P7 | P1 | P11 | H | H | H |
| 4998 | O | Ar35 | P11 | P8 | P1 | P11 | H | H | H |
| 4999 | O | Ar35 | P11 | P9 | P1 | P11 | H | H | H |
| 5000 | O | Ar35 | P11 | P10 | P1 | P11 | H | H | H |
| 5001 | O | Ar35 | P11 | P11 | P1 | P11 | H | H | H |
| 5002 | O | Ar35 | P11 | P12 | P1 | P11 | H | H | H |
| 5003 | O | Ar35 | P11 | P13 | P1 | P11 | H | H | H |
| 5004 | O | Ar35 | P11 | P14 | P1 | P11 | H | H | H |
| 5005 | O | Ar35 | P11 | P15 | P1 | P11 | H | H | H |
| 5006 | O | Ar35 | P11 | P1 | P2 | P11 | H | H | H |
| 5007 | O | Ar35 | P11 | P2 | P2 | P11 | H | H | H |
| 5008 | O | Ar35 | P11 | P3 | P2 | P11 | H | H | H |
| 5009 | O | Ar35 | P11 | P4 | P2 | P11 | H | H | H |
| 5010 | O | Ar35 | P11 | P5 | P2 | P11 | H | H | H |
| 5011 | O | Ar35 | P11 | P6 | P2 | P11 | H | H | H |
| 5012 | O | Ar35 | P11 | P7 | P2 | P11 | H | H | H |
| 5013 | O | Ar35 | P11 | P8 | P2 | P11 | H | H | H |
| 5014 | O | Ar35 | P11 | P9 | P2 | P11 | H | H | H |
| 5015 | O | Ar35 | P11 | P10 | P2 | P11 | H | H | H |
| 5016 | O | Ar35 | P11 | P11 | P2 | P11 | H | H | H |
| 5017 | O | Ar35 | P11 | P12 | P2 | P11 | H | H | H |
| 5018 | O | Ar35 | P11 | P13 | P2 | P11 | H | H | H |
| 5019 | O | Ar35 | P11 | P14 | P2 | P11 | H | H | H |
| 5020 | O | Ar35 | P11 | P15 | P2 | P11 | H | H | H |
| 5021 | O | Ar35 | P11 | P1 | D | P11 | H | H | D |
| 5022 | O | Ar35 | P11 | P2 | D | P11 | H | H | D |
| 5023 | O | Ar35 | P11 | P3 | D | P11 | H | H | D |
| 5024 | O | Ar35 | P11 | P4 | D | P11 | H | H | D |
| 5025 | O | Ar35 | P11 | P5 | D | P11 | H | H | D |
| 5026 | O | Ar35 | P11 | P6 | D | P11 | H | H | D |
| 5027 | O | Ar35 | P11 | P7 | D | P11 | H | H | D |
| 5028 | O | Ar35 | P11 | P8 | D | P11 | H | H | D |
| 5029 | O | Ar35 | P11 | P9 | D | P11 | H | H | D |
| 5030 | O | Ar35 | P11 | P10 | D | P11 | H | H | D |
| 5031 | O | Ar35 | P11 | P11 | D | P11 | H | H | D |
| 5032 | O | Ar35 | P11 | P12 | D | P11 | H | H | D |
| 5033 | O | Ar35 | P11 | P13 | D | P11 | H | H | D |
| 5034 | O | Ar35 | P11 | P14 | D | P11 | H | H | D |
| 5035 | O | Ar35 | P11 | P15 | D | P11 | H | H | D |
| 5036 | O | Ar35 | P12 | P1 | P1 | P11 | H | H | H |
| 5037 | O | Ar35 | P12 | P2 | P2 | P11 | H | H | H |
| 5038 | O | Ar35 | P12 | P3 | P1 | P11 | H | H | H |
| 5039 | O | Ar35 | P12 | P4 | P1 | P11 | H | H | H |
| 5040 | O | Ar35 | P12 | P5 | P1 | P11 | H | H | H |
| 5041 | O | Ar35 | P12 | P6 | P1 | P11 | H | H | H |
| 5042 | O | Ar35 | P12 | P7 | P1 | P11 | H | H | H |
| 5043 | O | Ar35 | P12 | P8 | P1 | P11 | H | H | H |
| 5044 | O | Ar35 | P12 | P9 | P1 | P11 | H | H | H |
| 5045 | O | Ar35 | P12 | P10 | P1 | P11 | H | H | H |
| 5046 | O | Ar35 | P12 | P11 | P1 | P11 | H | H | H |
| 5047 | O | Ar35 | P12 | P12 | P1 | P11 | H | H | H |
| 5048 | O | Ar35 | P12 | P13 | P1 | P11 | H | H | H |
| 5049 | O | Ar35 | P12 | P14 | P1 | P11 | H | H | H |
| 5050 | O | Ar35 | P12 | P15 | P1 | P11 | H | H | H |
| 5051 | O | Ar35 | P12 | P1 | P2 | P11 | H | H | H |
| 5052 | O | Ar35 | P12 | P2 | P2 | P11 | H | H | H |
| 5053 | O | Ar35 | P12 | P3 | P2 | P11 | H | H | H |
| 5054 | O | Ar35 | P12 | P4 | P2 | P11 | H | H | H |
| 5055 | O | Ar35 | P12 | P5 | P2 | P11 | H | H | H |
| 5056 | O | Ar35 | P12 | P6 | P2 | P11 | H | H | H |
| 5057 | O | Ar35 | P12 | P7 | P2 | P11 | H | H | H |
| 5058 | O | Ar35 | P12 | P8 | P2 | P11 | H | H | H |
| 5059 | O | Ar35 | P12 | P9 | P2 | P11 | H | H | H |
| 5060 | O | Ar35 | P12 | P10 | P2 | P11 | H | H | H |
| 5061 | O | Ar35 | P12 | P11 | P2 | P11 | H | H | H |
| 5062 | O | Ar35 | P12 | P12 | P2 | P11 | H | H | H |
| 5063 | O | Ar35 | P12 | P13 | P2 | P11 | H | H | H |
| 5064 | O | Ar35 | P12 | P14 | P2 | P11 | H | H | H |
| 5065 | O | Ar35 | P12 | P15 | P2 | P11 | H | H | H |
| 5066 | O | Ar35 | P12 | P1 | D | P11 | H | H | D |
| 5067 | O | Ar35 | P12 | P2 | D | P11 | H | H | D |
| 5068 | O | Ar35 | P12 | P3 | D | P11 | H | H | D |
| 5069 | O | Ar35 | P12 | P4 | D | P11 | H | H | D |
| 5070 | O | Ar35 | P12 | P5 | D | P11 | H | H | D |
| 5071 | O | Ar35 | P12 | P6 | D | P11 | H | H | D |
| 5072 | O | Ar35 | P12 | P7 | D | P11 | H | H | D |
| 5073 | O | Ar35 | P12 | P8 | D | P11 | H | H | D |
| 5074 | O | Ar35 | P12 | P9 | D | P11 | H | H | D |
| 5075 | O | Ar35 | P12 | P10 | D | P11 | H | H | D |
| 5076 | O | Ar35 | P12 | P11 | D | P11 | H | H | D |
| 5077 | O | Ar35 | P12 | P12 | D | P11 | H | H | D |
| 5078 | O | Ar35 | P12 | P13 | D | P11 | H | H | D |
| 5079 | O | Ar35 | P12 | P14 | D | P11 | H | H | D |
| 5080 | O | Ar35 | P12 | P15 | D | P11 | H | H | D |

wherein P1 to P28 have the following structures: 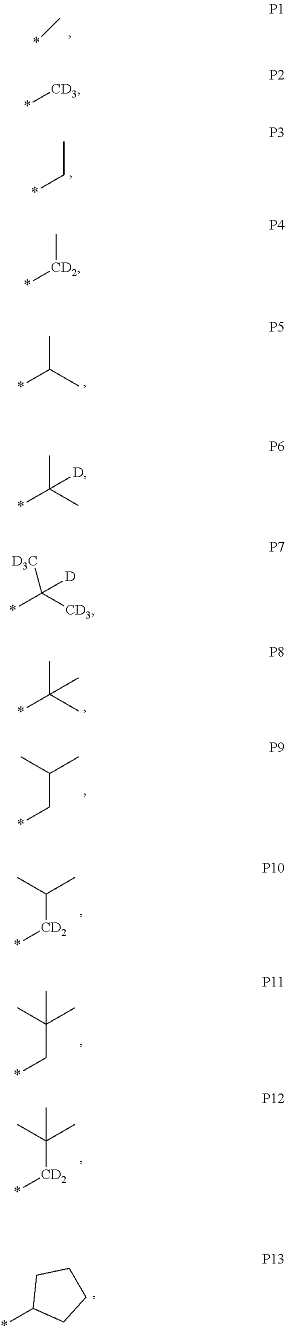 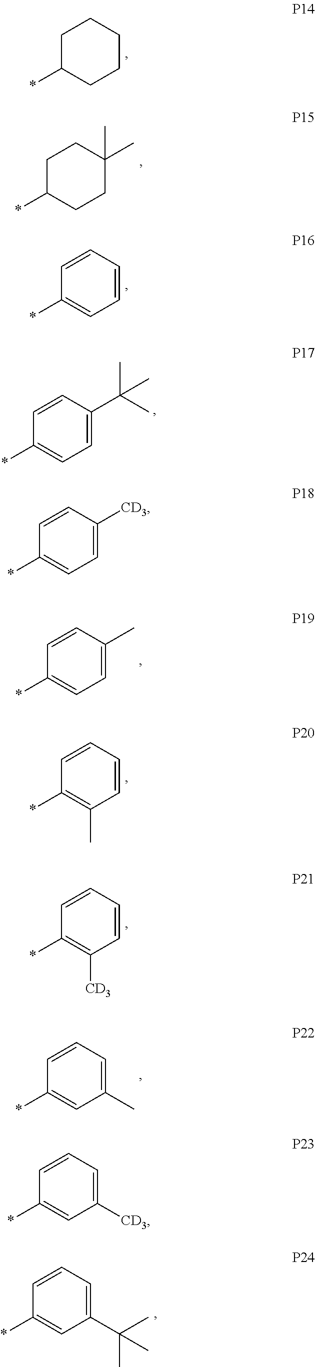 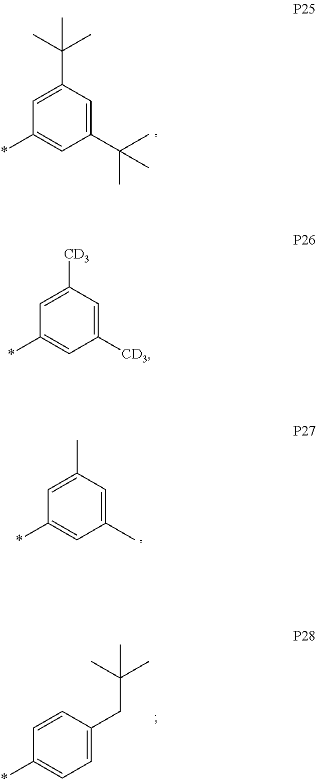
wherein optionally, hydrogen in the structures of La-1-k and La-2-k can be partially or fully substituted with deuterium.

18. The metal complex according to claim 17, wherein Lb is, at each occurrence identically or differently, selected from the group consisting of Lb1 to Lb167, wherein the structures of Lb1 to Lb167 are as follows: 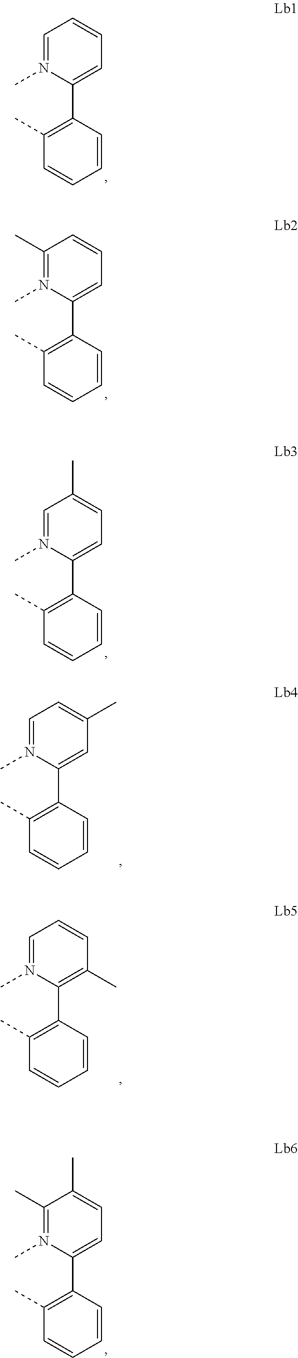 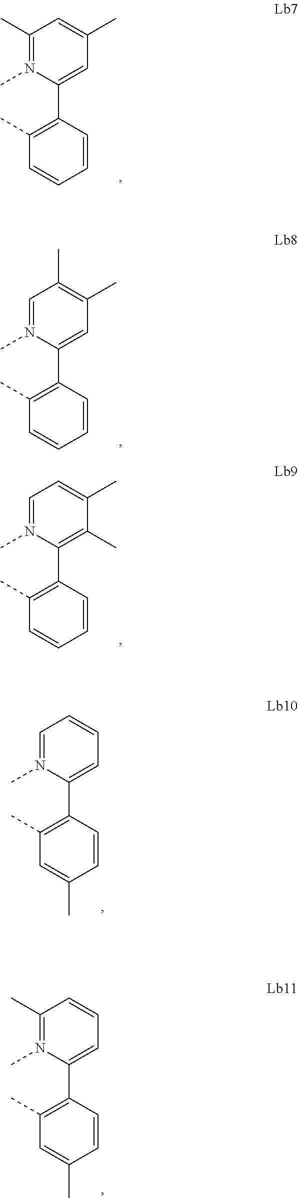 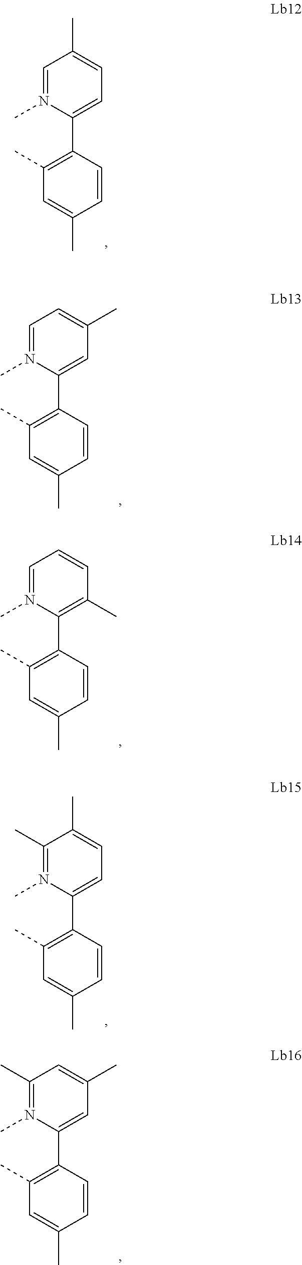 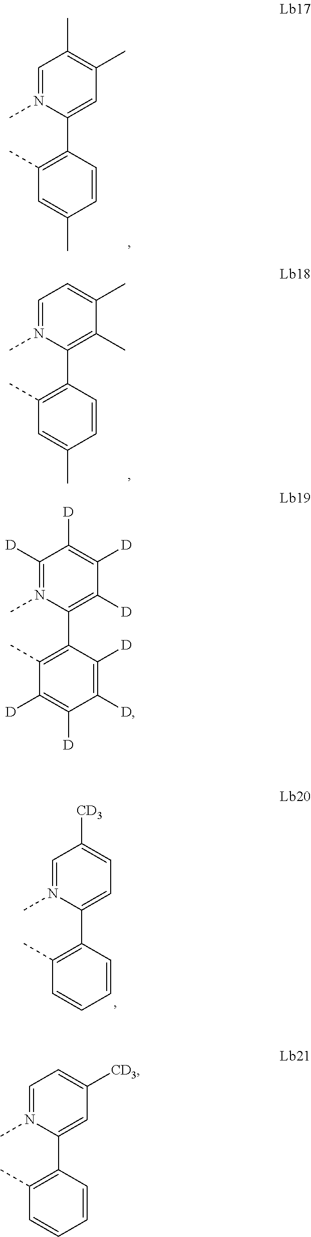 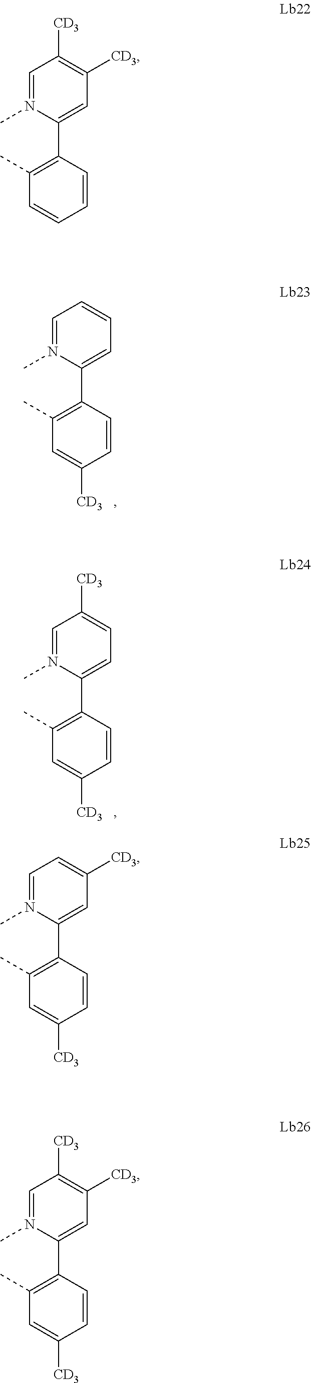 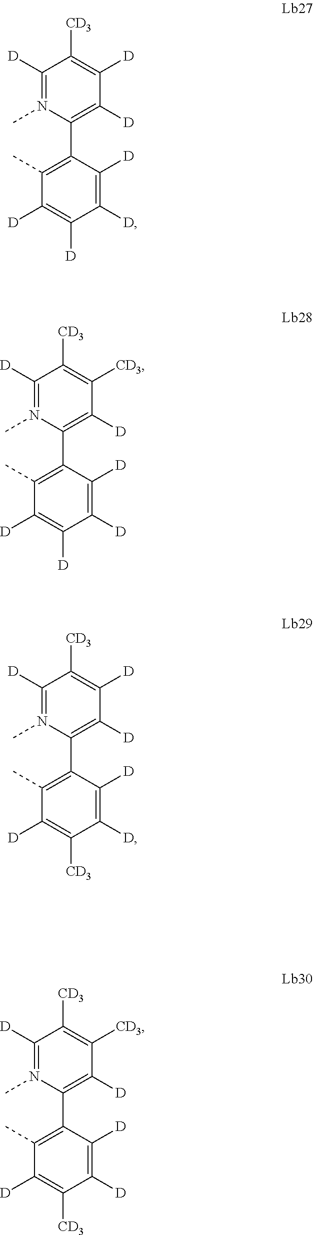 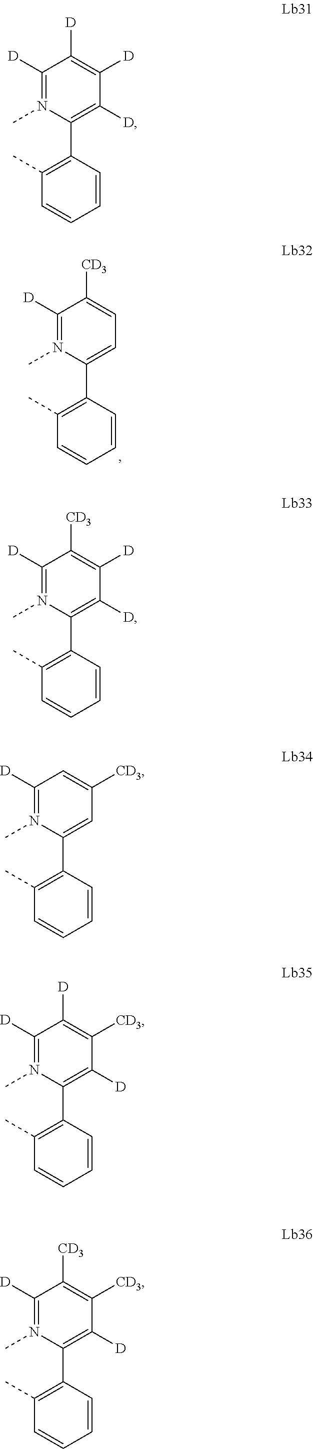 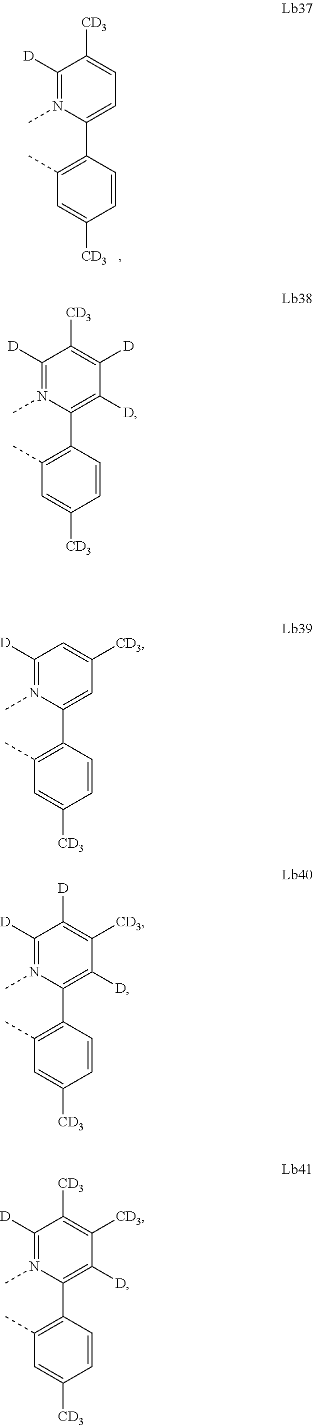 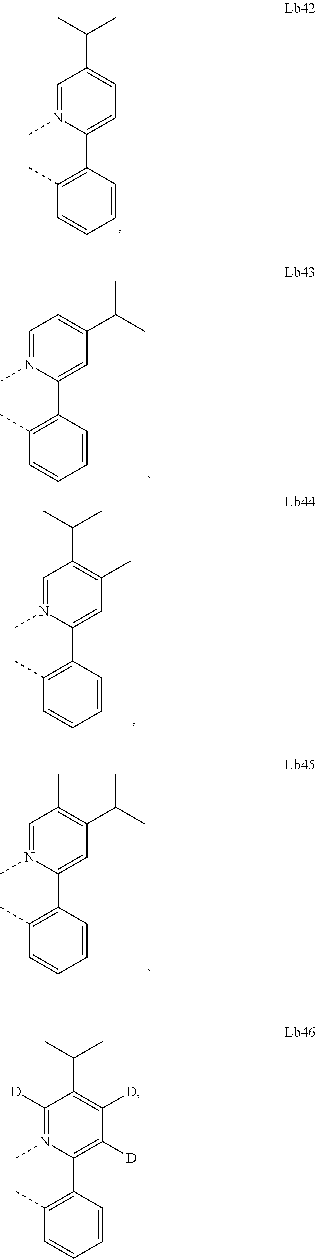 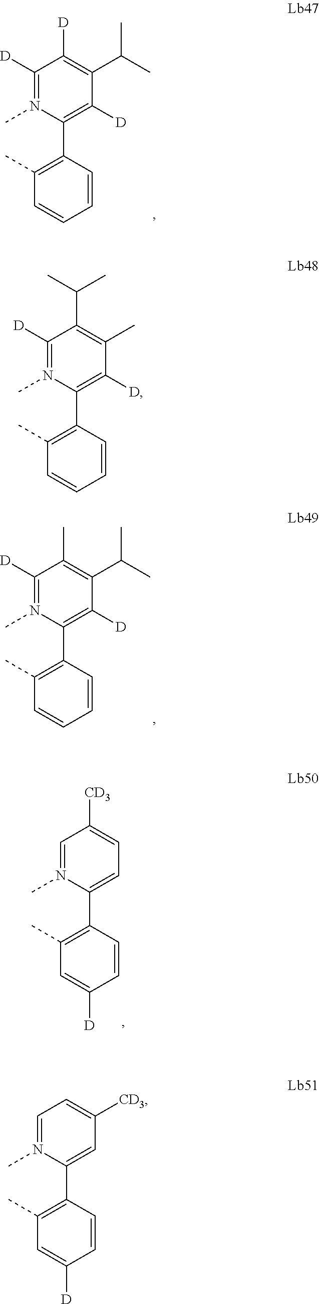 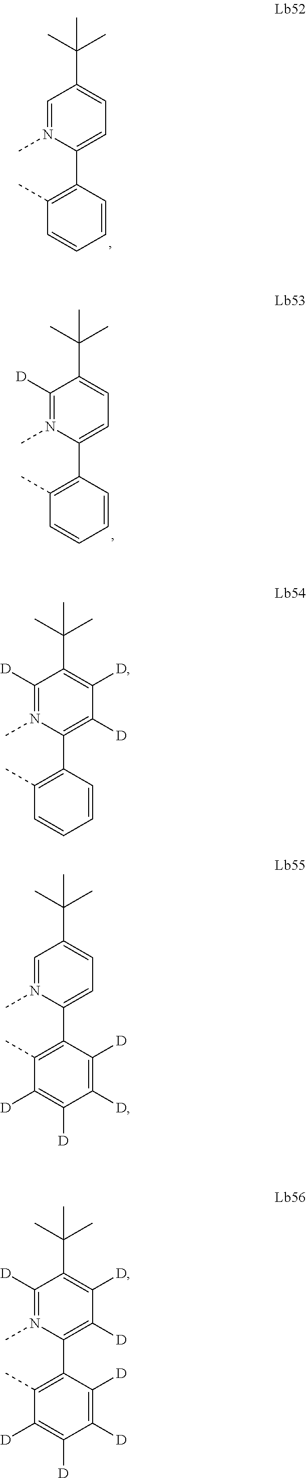 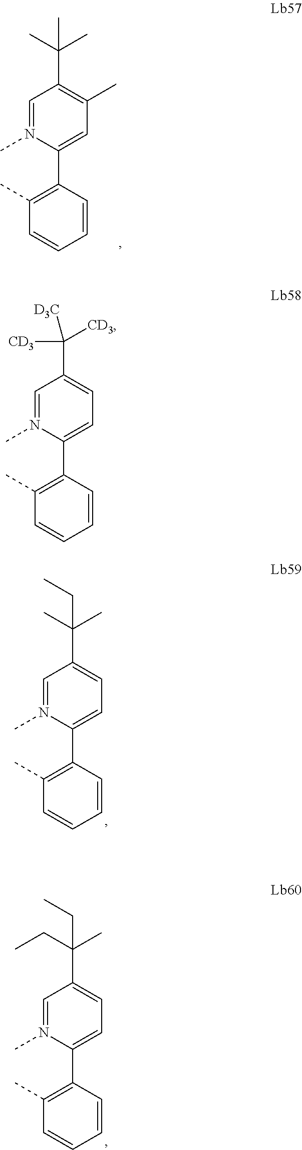 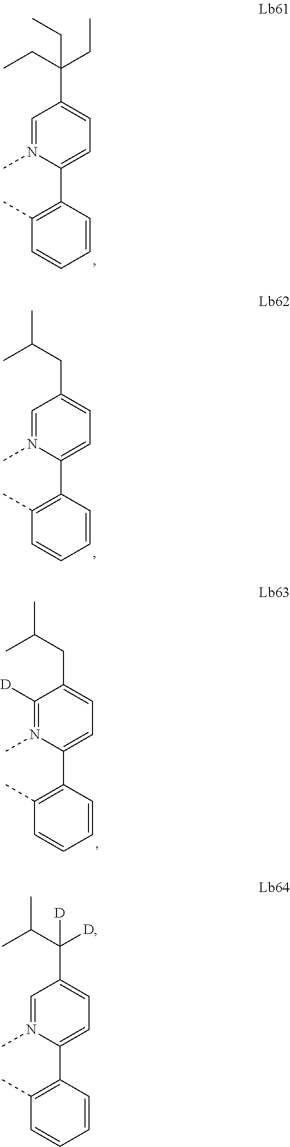 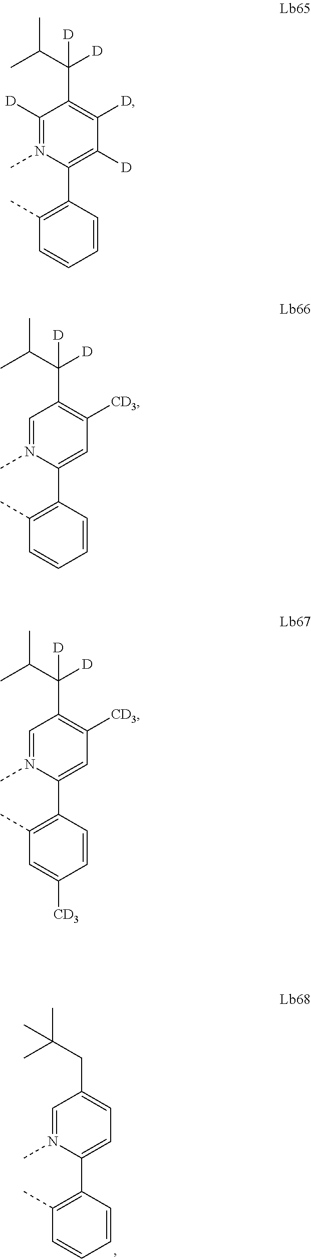 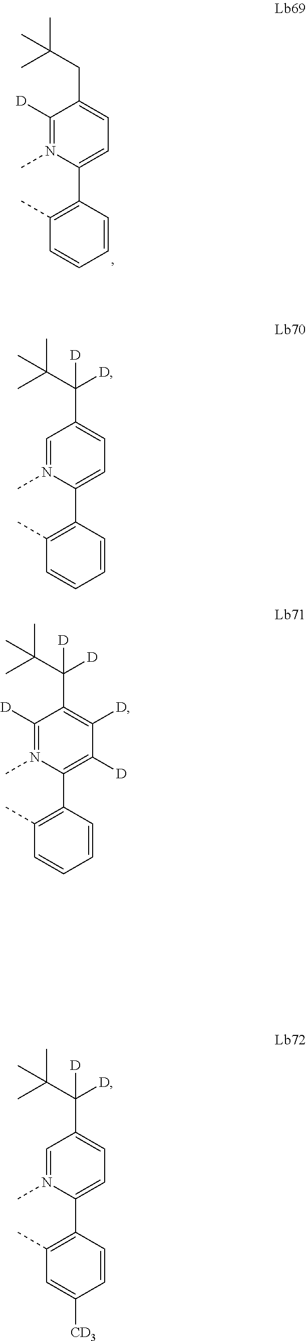 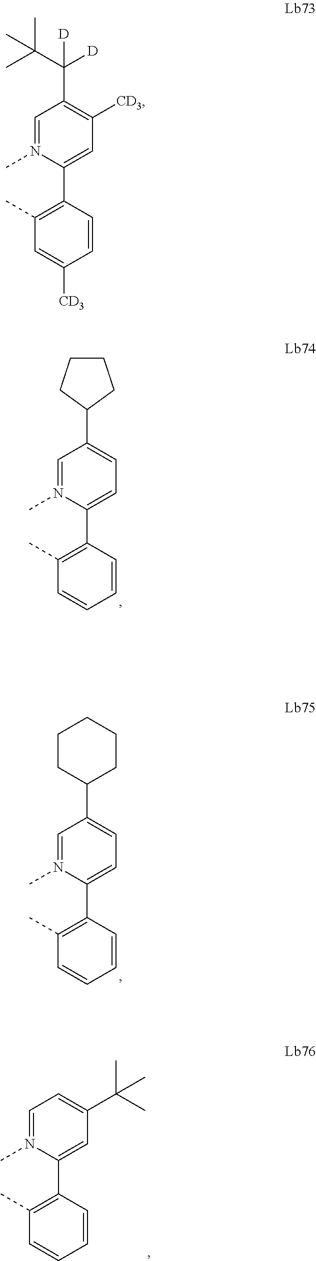 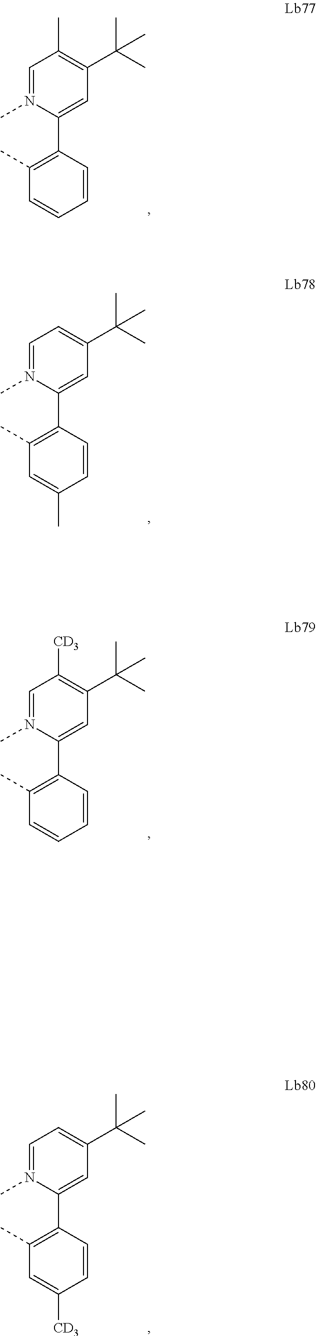 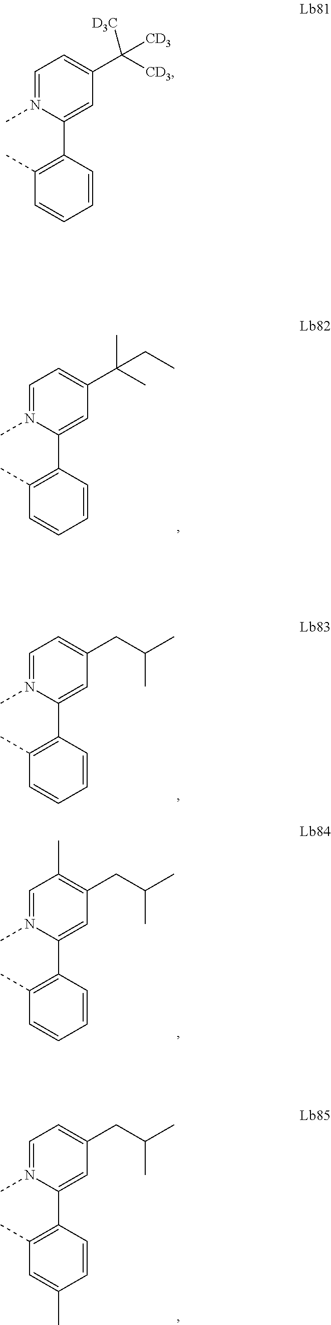 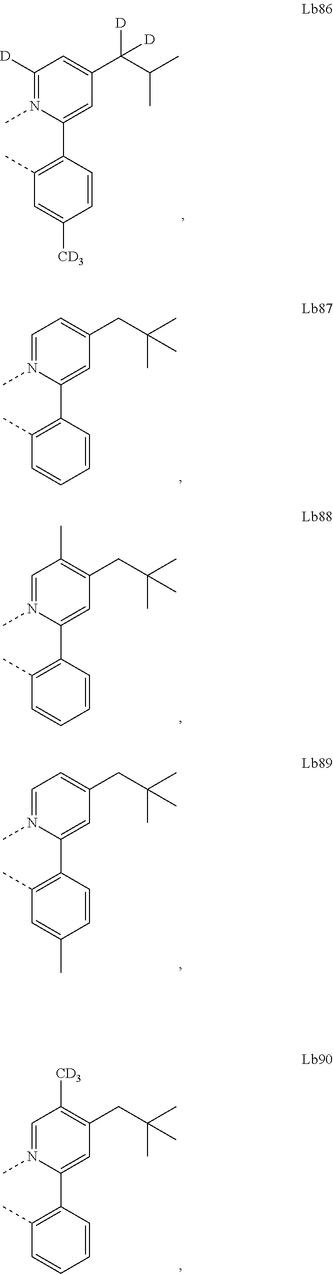 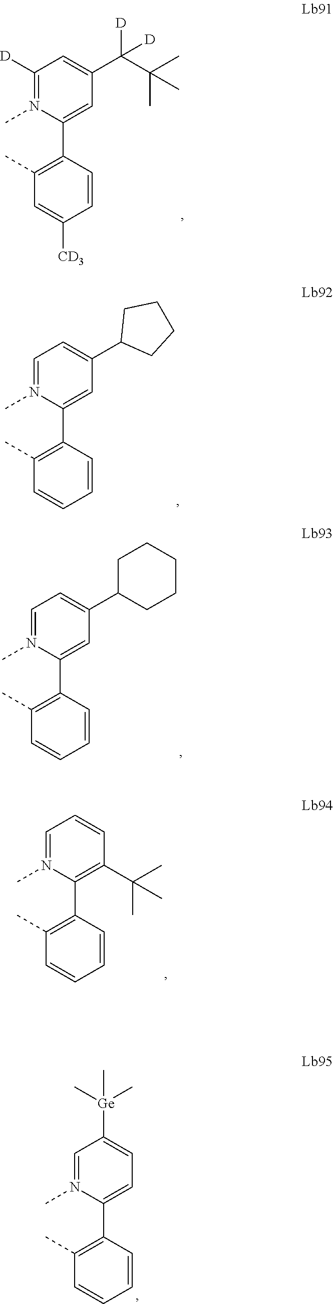 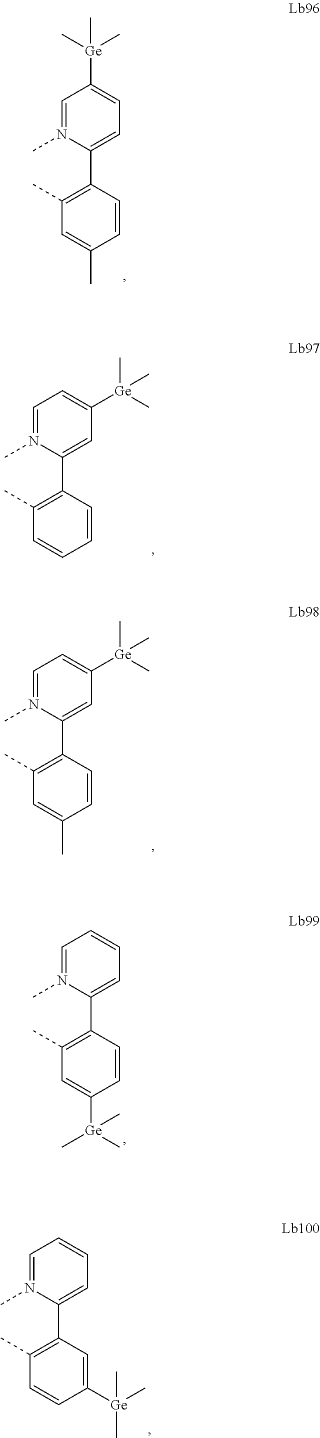 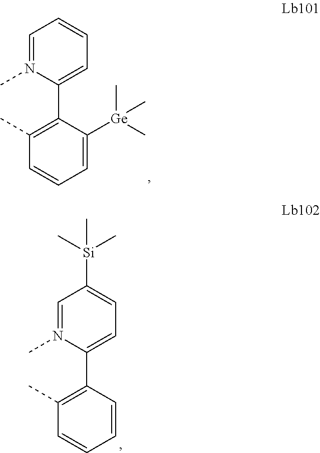 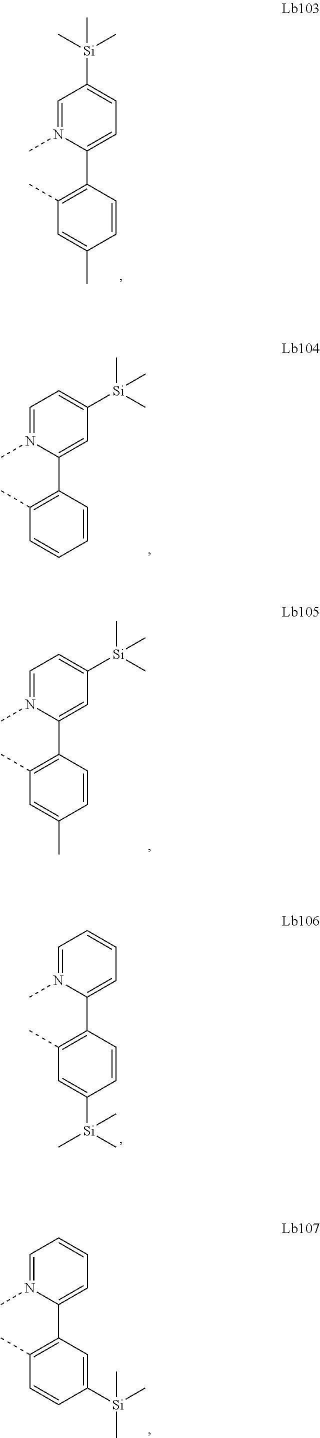 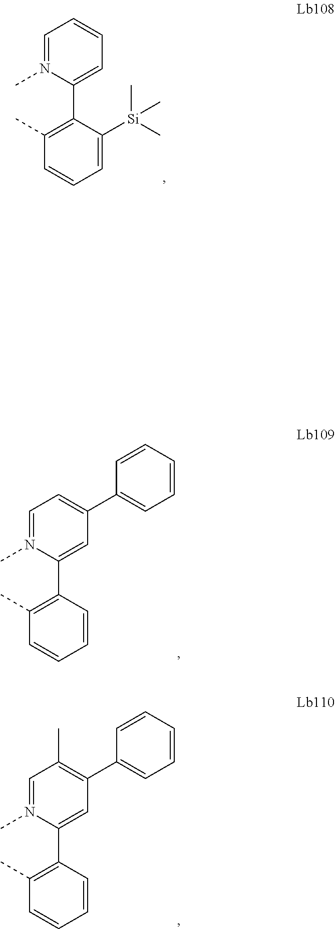 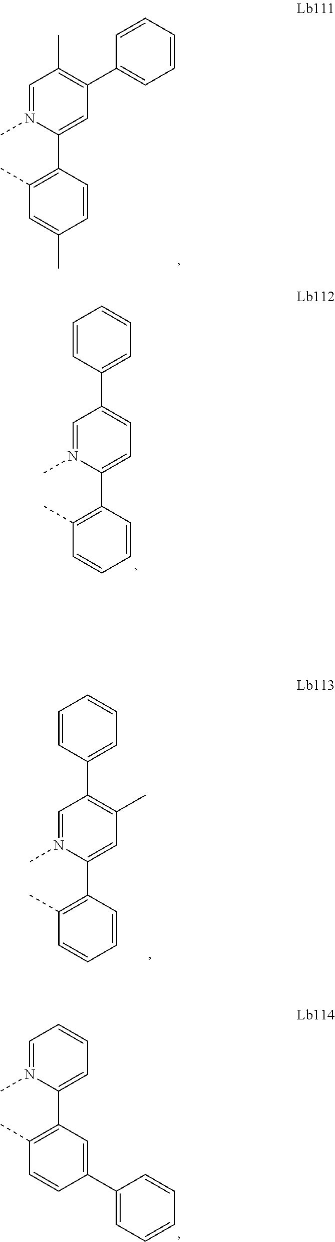 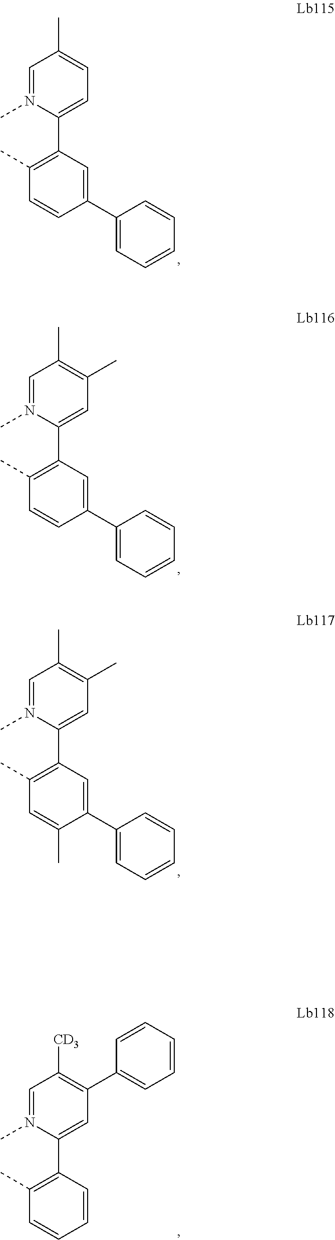 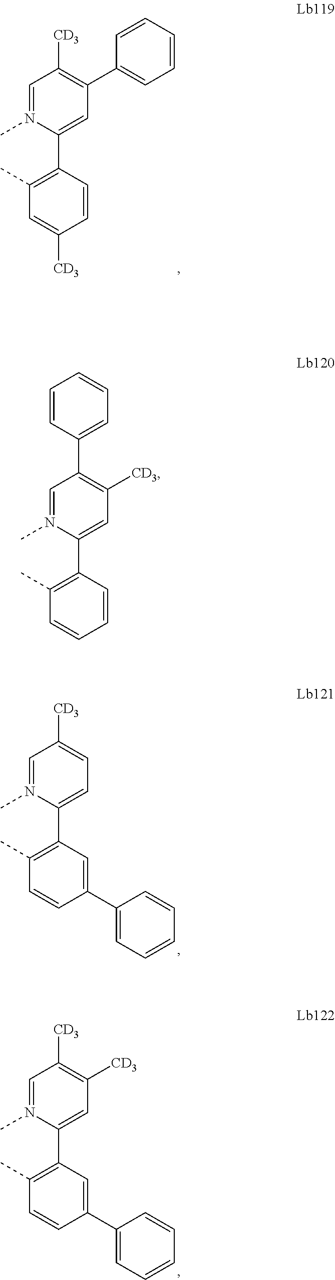 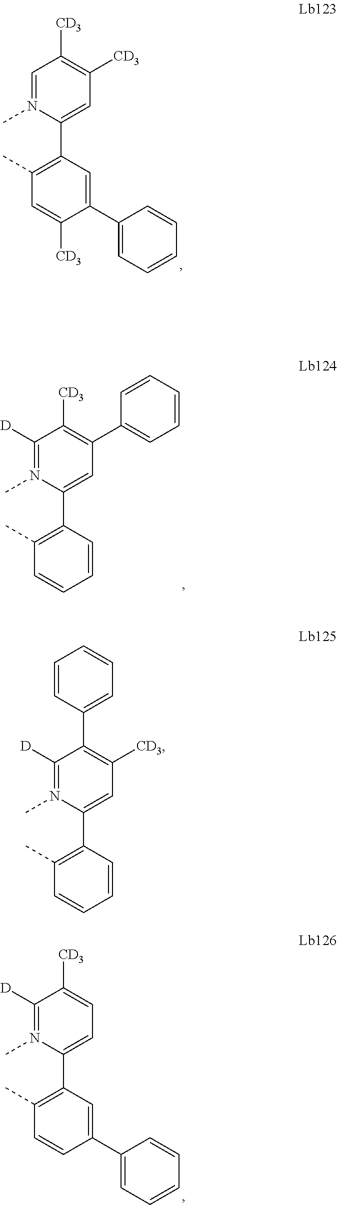 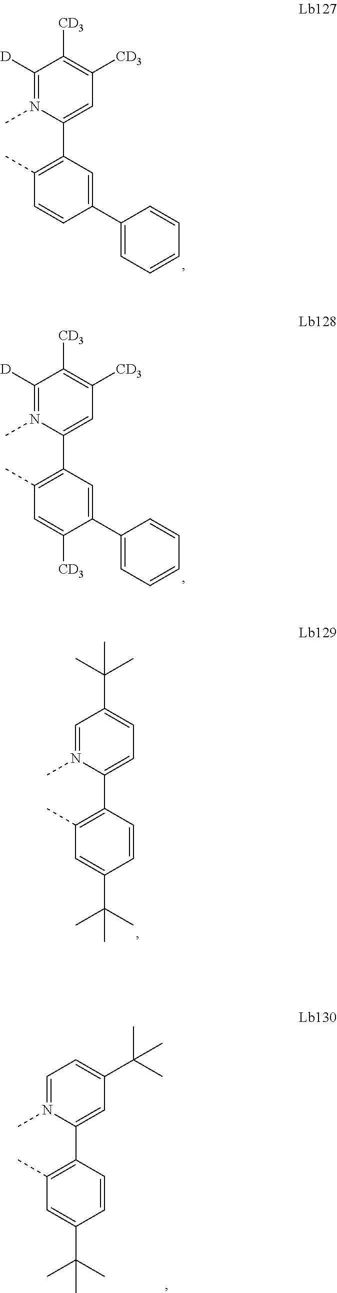 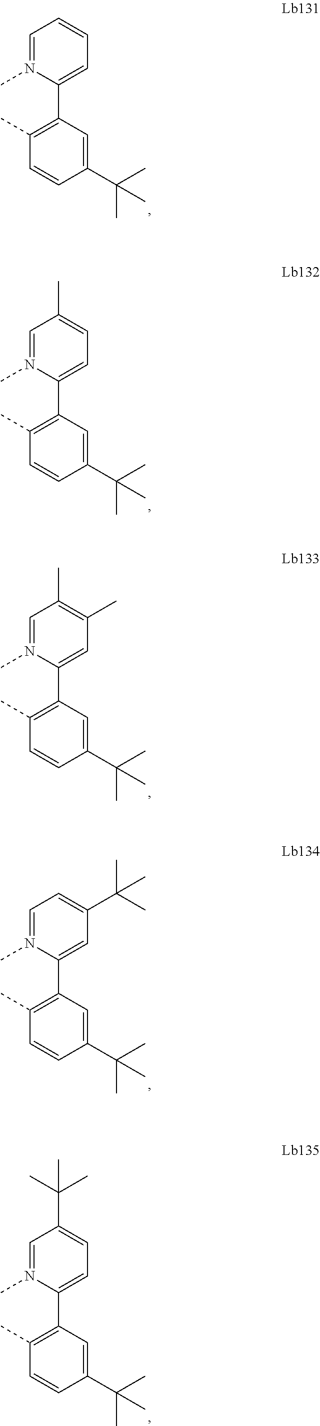 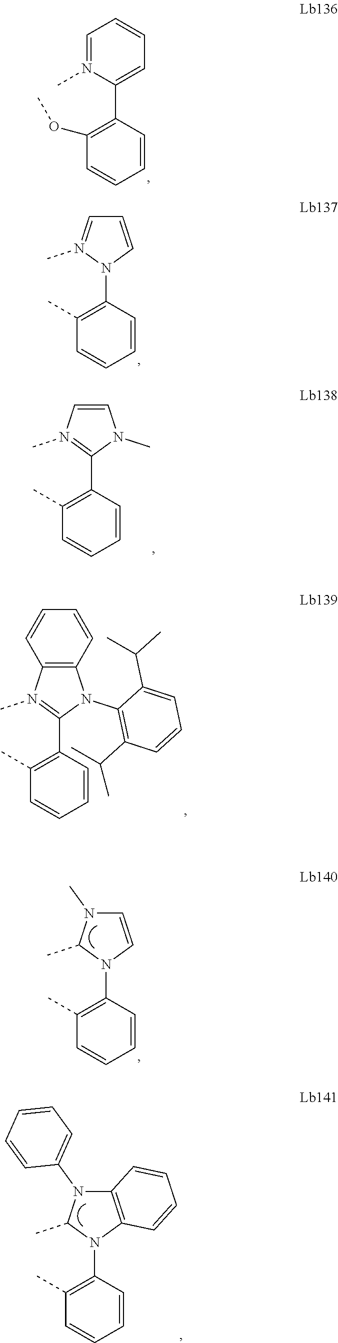 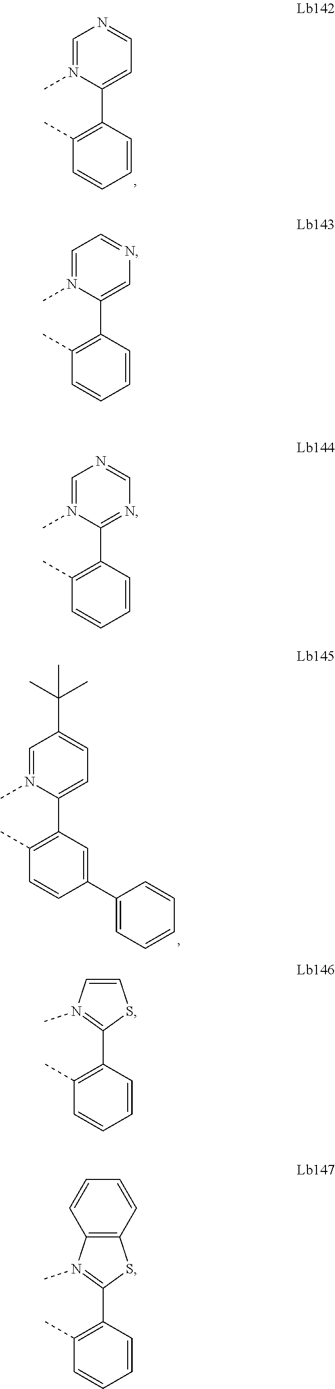 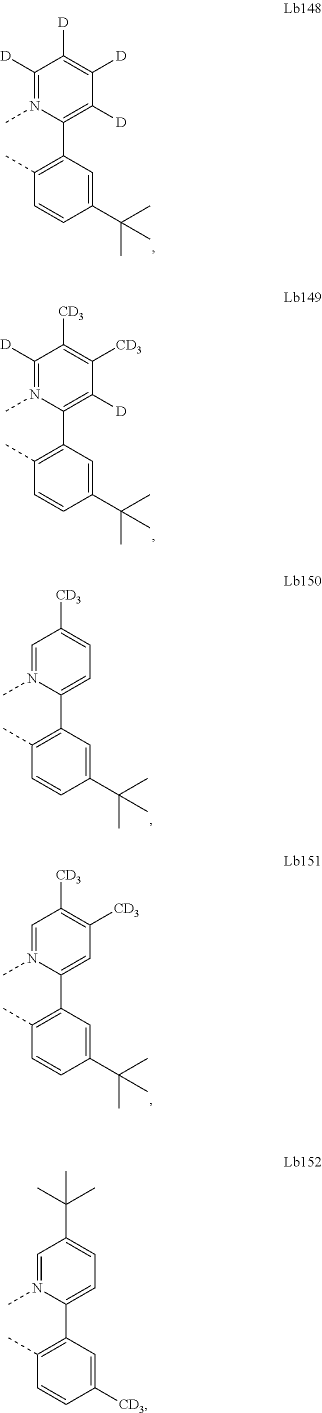 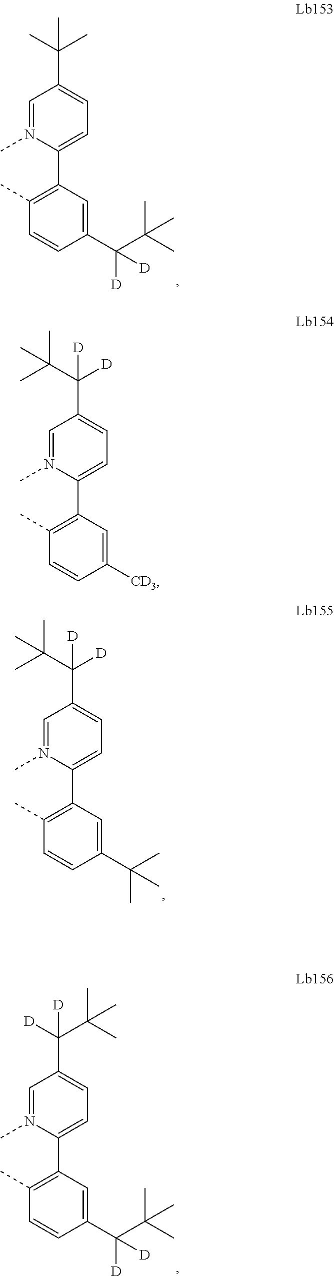 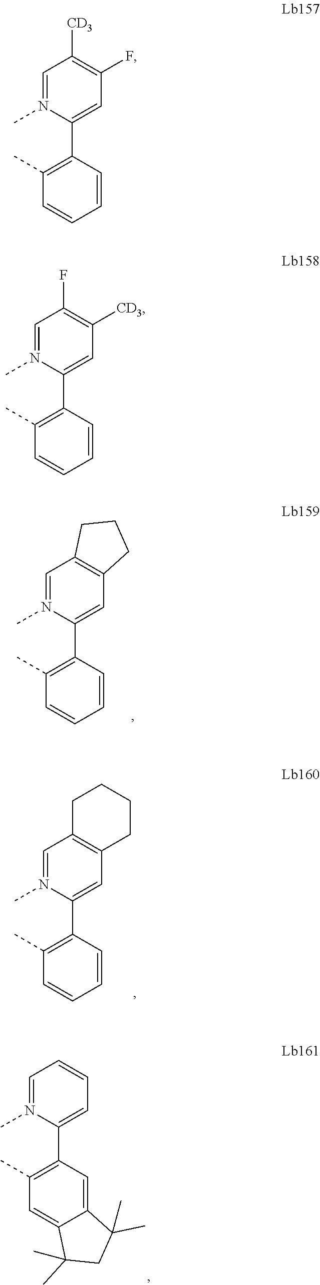 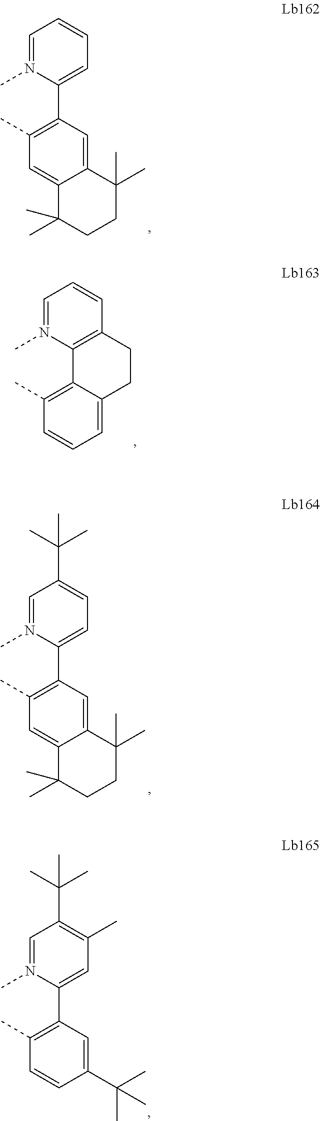 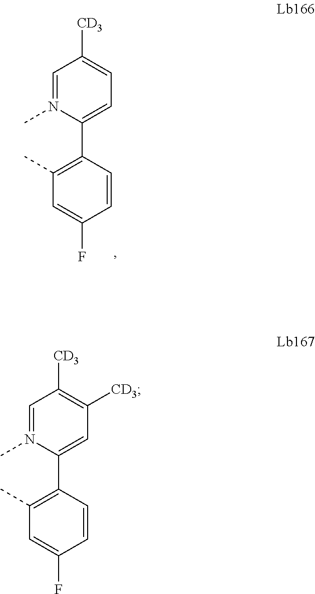
wherein optionally, hydrogen in Lb1 to Lb167 can be partially or fully substituted with deuterium.

19. The metal complex according to claim 18, wherein the metal complex has a structure of IrLa(Lb)₂, wherein the two Lb are the same, La is selected from the group consisting of La-1-k and La-2-k, k is selected from 1 to 5080, and Lb is selected from the group consisting of Lb1 to Lb167;
preferably, the metal complex is selected from the group consisting of Metal Complex 1 to Metal Complex 3815, wherein Metal Complex 1 to Metal Complex 3796 have the structure of IrLa(Lb)₂, wherein the two Lb are the same, and La and Lb correspond to structures shown in the following table, respectively:

| Metal Complex No. | La | Lb | Metal Complex No. | La | Lb |
|---|---|---|---|---|---|
| 1 | La-1-1 | Lb1 | 2 | La-1-1 | Lb20 |
| 3 | La-1-2 | Lb1 | 4 | La-1-2 | Lb20 |
| 5 | La-1-3 | Lb1 | 6 | La-1-3 | Lb20 |
| 7 | La-2-1 | Lb1 | 8 | La-2-1 | Lb20 |
| 9 | La-2-2 | Lb1 | 10 | La-2-2 | Lb20 |
| 11 | La-2-3 | Lb1 | 12 | La-2-3 | Lb20 |
| 13 | La-1-9 | Lb1 | 14 | La-1-9 | Lb20 |
| 15 | La-1-10 | Lb1 | 16 | La-1-10 | Lb20 |
| 17 | La-1-11 | Lb1 | 18 | La-1-11 | Lb20 |
| 19 | La-2-11 | Lb1 | 20 | La-2-11 | Lb20 |
| 21 | La-2-12 | Lb1 | 22 | La-2-12 | Lb20 |
| 23 | La-2-13 | Lb1 | 24 | La-2-13 | Lb20 |
| 25 | La-1-16 | Lb1 | 26 | La-1-16 | Lb20 |
| 27 | La-1-17 | Lb1 | 28 | La-1-17 | Lb20 |
| 29 | La-1-18 | Lb1 | 30 | La-1-18 | Lb20 |
| 31 | La-1-19 | Lb1 | 32 | La-1-19 | Lb20 |
| 33 | La-1-20 | Lb1 | 34 | La-1-20 | Lb20 |
| 35 | La-2-16 | Lb1 | 36 | La-2-16 | Lb20 |
| 37 | La-2-17 | Lb1 | 38 | La-2-17 | Lb20 |
| 39 | La-2-18 | Lb1 | 40 | La-2-18 | Lb20 |
| 41 | La-2-19 | Lb1 | 42 | La-2-19 | Lb20 |
| 43 | La-2-20 | Lb1 | 44 | La-2-20 | Lb20 |
| 45 | La-1-31 | Lb1 | 46 | La-1-31 | Lb20 |
| 47 | La-1-32 | Lb1 | 48 | La-1-32 | Lb20 |
| 49 | La-1-33 | Lb1 | 50 | La-1-33 | Lb20 |
| 51 | La-1-34 | Lb1 | 52 | La-1-34 | Lb20 |
| 53 | La-1-35 | Lb1 | 54 | La-1-35 | Lb20 |
| 55 | La-2-31 | Lb1 | 56 | La-2-31 | Lb20 |
| 57 | La-2-32 | Lb1 | 58 | La-2-32 | Lb20 |
| 59 | La-2-33 | Lb1 | 60 | La-2-33 | Lb20 |
| 61 | La-2-34 | Lb1 | 62 | La-2-34 | Lb20 |
| 63 | La-2-35 | Lb1 | 64 | La-2-35 | Lb20 |
| 65 | La-1-90 | Lb1 | 66 | La-1-90 | Lb20 |
| 67 | La-1-91 | Lb1 | 68 | La-1-91 | Lb20 |
| 69 | La-1-92 | Lb1 | 70 | La-1-92 | Lb20 |
| 71 | La-1-93 | Lb1 | 72 | La-1-93 | Lb20 |
| 73 | La-1-94 | Lb1 | 74 | La-1-94 | Lb20 |
| 75 | La-2-99 | Lb1 | 76 | La-2-99 | Lb20 |
| 77 | La-2-100 | Lb1 | 78 | La-2-100 | Lb20 |
| 79 | La-2-101 | Lb1 | 80 | La-2-101 | Lb20 |
| 81 | La-2-102 | Lb1 | 82 | La-2-102 | Lb20 |
| 83 | La-1-104 | Lb1 | 84 | La-1-104 | Lb20 |
| 85 | La-1-105 | Lb1 | 86 | La-1-105 | Lb20 |
| 87 | La-1-106 | Lb1 | 88 | La-1-106 | Lb20 |
| 89 | La-2-104 | Lb1 | 90 | La-2-104 | Lb20 |
| 91 | La-2-105 | Lb1 | 92 | La-2-105 | Lb20 |
| 93 | La-2-106 | Lb1 | 94 | La-2-106 | Lb20 |
| 95 | La-1-109 | Lb1 | 96 | La-1-109 | Lb20 |
| 97 | La-1-110 | Lb1 | 98 | La-1-110 | Lb20 |
| 99 | La-1-111 | Lb1 | 100 | La-1-111 | Lb20 |
| 101 | La-2-110 | Lb1 | 102 | La-2-110 | Lb20 |
| 103 | La-2-111 | Lb1 | 104 | La-2-111 | Lb20 |
| 105 | La-2-112 | Lb1 | 106 | La-2-112 | Lb20 |
| 107 | La-2-113 | Lb1 | 108 | La-2-113 | Lb20 |
| 109 | La-1-131 | Lb1 | 110 | La-1-131 | Lb20 |
| 111 | La-1-132 | Lb1 | 112 | La-1-132 | Lb20 |
| 113 | La-1-133 | Lb1 | 114 | La-1-133 | Lb20 |
| 115 | La-1-134 | Lb1 | 116 | La-1-134 | Lb20 |
| 117 | La-1-135 | Lb1 | 118 | La-1-135 | Lb20 |
| 119 | La-1-136 | Lb1 | 120 | La-1-136 | Lb20 |
| 121 | La-1-137 | Lb1 | 122 | La-1-137 | Lb20 |
| 123 | La-1-138 | Lb1 | 124 | La-1-138 | Lb20 |
| 125 | La-1-139 | Lb1 | 126 | La-1-139 | Lb20 |
| 127 | La-1-140 | Lb1 | 128 | La-1-140 | Lb20 |
| 129 | La-2-134 | Lb1 | 130 | La-2-134 | Lb20 |
| 131 | La-2-135 | Lb1 | 132 | La-2-135 | Lb20 |
| 133 | La-2-136 | Lb1 | 134 | La-2-136 | Lb20 |
| 135 | La-2-137 | Lb1 | 136 | La-2-137 | Lb20 |
| 137 | La-2-138 | Lb1 | 138 | La-2-138 | Lb20 |
| 139 | La-2-139 | Lb1 | 140 | La-2-139 | Lb20 |
| 141 | La-1-208 | Lb1 | 142 | La-1-208 | Lb20 |
| 143 | La-1-209 | Lb1 | 144 | La-1-209 | Lb20 |
| 145 | La-1-210 | Lb1 | 146 | La-1-210 | Lb20 |
| 147 | La-1-211 | Lb1 | 148 | La-1-211 | Lb20 |
| 149 | La-2-208 | Lb1 | 150 | La-2-208 | Lb20 |
| 151 | La-2-209 | Lb1 | 152 | La-2-209 | Lb20 |
| 153 | La-1-219 | Lb1 | 154 | La-1-219 | Lb20 |
| 155 | La-1-220 | Lb1 | 156 | La-1-220 | Lb20 |
| 157 | La-2-227 | Lb1 | 158 | La-2-227 | Lb20 |
| 159 | La-2-228 | Lb1 | 160 | La-2-228 | Lb20 |
| 161 | La-2-229 | Lb1 | 162 | La-2-229 | Lb20 |
| 163 | La-2-230 | Lb1 | 164 | La-2-230 | Lb20 |
| 165 | La-1-238 | Lb1 | 166 | La-1-238 | Lb20 |
| 167 | La-1-239 | Lb1 | 168 | La-1-239 | Lb20 |
| 169 | La-1-240 | Lb1 | 170 | La-1-240 | Lb20 |
| 171 | La-1-241 | Lb1 | 172 | La-1-241 | Lb20 |
| 173 | La-1-242 | Lb1 | 174 | La-1-242 | Lb20 |
| 175 | La-1-243 | Lb1 | 176 | La-1-243 | Lb20 |
| 177 | La-2-238 | Lb1 | 178 | La-2-238 | Lb20 |
| 179 | La-2-239 | Lb1 | 180 | La-2-239 | Lb20 |
| 181 | La-2-240 | Lb1 | 182 | La-2-240 | Lb20 |
| 183 | La-2-241 | Lb1 | 184 | La-2-241 | Lb20 |
| 185 | La-2-242 | Lb1 | 186 | La-2-242 | Lb20 |
| 187 | La-2-243 | Lb1 | 188 | La-2-243 | Lb20 |
| 189 | La-1-254 | Lb1 | 190 | La-1-254 | Lb20 |
| 191 | La-1-255 | Lb1 | 192 | La-1-255 | Lb20 |
| 193 | La-1-313 | Lb1 | 194 | La-1-313 | Lb20 |
| 195 | La-1-314 | Lb1 | 196 | La-1-314 | Lb20 |
| 197 | La-2-313 | Lb1 | 198 | La-2-313 | Lb20 |
| 199 | La-2-314 | Lb1 | 200 | La-2-314 | Lb20 |
| 201 | La-1-343 | Lb1 | 202 | La-1-343 | Lb20 |
| 203 | La-1-344 | Lb1 | 204 | La-1-344 | Lb20 |
| 205 | La-1-345 | Lb1 | 206 | La-1-345 | Lb20 |
| 207 | La-1-346 | Lb1 | 208 | La-1-346 | Lb20 |
| 209 | La-1-347 | Lb1 | 210 | La-1-347 | Lb20 |
| 211 | La-2-343 | Lb1 | 212 | La-2-343 | Lb20 |
| 213 | La-2-344 | Lb1 | 214 | La-2-344 | Lb20 |
| 215 | La-2-345 | Lb1 | 216 | La-2-345 | Lb20 |
| 217 | La-2-346 | Lb1 | 218 | La-2-346 | Lb20 |
| 219 | La-2-347 | Lb1 | 220 | La-2-347 | Lb20 |
| 221 | La-1-417 | Lb1 | 222 | La-1-417 | Lb20 |
| 223 | La-1-418 | Lb1 | 224 | La-1-418 | Lb20 |
| 225 | La-1-419 | Lb1 | 226 | La-1-419 | Lb20 |
| 227 | La-1-420 | Lb1 | 228 | La-1-420 | Lb20 |
| 229 | La-2-417 | Lb1 | 230 | La-2-417 | Lb20 |
| 231 | La-2-418 | Lb1 | 232 | La-2-418 | Lb20 |
| 233 | La-2-419 | Lb1 | 234 | La-2-419 | Lb20 |
| 235 | La-2-420 | Lb1 | 236 | La-2-420 | Lb20 |
| 237 | La-1-447 | Lb1 | 238 | La-1-447 | Lb20 |
| 239 | La-1-448 | Lb1 | 240 | La-1-448 | Lb20 |
| 241 | La-1-449 | Lb1 | 242 | La-1-449 | Lb20 |
| 243 | La-1-450 | Lb1 | 244 | La-1-450 | Lb20 |
| 245 | La-1-451 | Lb1 | 246 | La-1-451 | Lb20 |
| 247 | La-2-447 | Lb1 | 248 | La-2-447 | Lb20 |
| 249 | La-2-448 | Lb1 | 250 | La-2-448 | Lb20 |
| 251 | La-2-449 | Lb1 | 252 | La-2-449 | Lb20 |
| 253 | La-2-450 | Lb1 | 254 | La-2-450 | Lb20 |
| 255 | La-2-451 | Lb1 | 256 | La-2-451 | Lb20 |
| 257 | La-1-467 | Lb1 | 258 | La-1-467 | Lb20 |
| 259 | La-1-468 | Lb1 | 260 | La-1-468 | Lb20 |
| 261 | La-1-469 | Lb1 | 262 | La-1-469 | Lb20 |
| 263 | La-2-495 | Lb1 | 264 | La-2-495 | Lb20 |
| 265 | La-2-496 | Lb1 | 266 | La-2-496 | Lb20 |
| 267 | La-2-497 | Lb1 | 268 | La-2-497 | Lb20 |
| 269 | La-1-521 | Lb1 | 270 | La-1-521 | Lb20 |
| 271 | La-1-522 | Lb1 | 272 | La-1-522 | Lb20 |
| 273 | La-2-521 | Lb1 | 274 | La-2-521 | Lb20 |
| 275 | La-2-522 | Lb1 | 276 | La-2-522 | Lb20 |
| 277 | La-1-551 | Lb1 | 278 | La-1-551 | Lb20 |
| 279 | La-1-552 | Lb1 | 280 | La-1-552 | Lb20 |
| 281 | La-1-553 | Lb1 | 282 | La-1-553 | Lb20 |
| 283 | La-1-554 | Lb1 | 284 | La-1-554 | Lb20 |
| 285 | La-1-555 | Lb1 | 286 | La-1-555 | Lb20 |
| 287 | La-2-551 | Lb1 | 288 | La-2-551 | Lb20 |
| 289 | La-2-552 | Lb1 | 290 | La-2-552 | Lb20 |
| 291 | La-2-553 | Lb1 | 292 | La-2-553 | Lb20 |
| 293 | La-2-554 | Lb1 | 294 | La-2-554 | Lb20 |
| 295 | La-2-555 | Lb1 | 296 | La-2-555 | Lb20 |
| 297 | La-1-559 | Lb1 | 298 | La-1-559 | Lb20 |
| 299 | La-1-560 | Lb1 | 300 | La-1-560 | Lb20 |
| 301 | La-1-561 | Lb1 | 302 | La-1-561 | Lb20 |
| 303 | La-2-569 | Lb1 | 304 | La-2-569 | Lb20 |
| 305 | La-2-570 | Lb1 | 306 | La-2-570 | Lb20 |
| 307 | La-1-625 | Lb1 | 308 | La-1-625 | Lb20 |
| 309 | La-1-626 | Lb1 | 310 | La-1-626 | Lb20 |
| 311 | La-2-625 | Lb1 | 312 | La-2-625 | Lb20 |
| 313 | La-2-626 | Lb1 | 314 | La-2-626 | Lb20 |
| 315 | La-1-655 | Lb1 | 316 | La-1-655 | Lb20 |
| 317 | La-1-656 | Lb1 | 318 | La-1-656 | Lb20 |
| 319 | La-1-657 | Lb1 | 320 | La-1-657 | Lb20 |
| 321 | La-1-658 | Lb1 | 322 | La-1-658 | Lb20 |
| 323 | La-1-659 | Lb1 | 324 | La-1-659 | Lb20 |
| 325 | La-2-655 | Lb1 | 326 | La-2-655 | Lb20 |
| 327 | La-2-656 | Lb1 | 328 | La-2-656 | Lb20 |
| 329 | La-2-657 | Lb1 | 330 | La-2-657 | Lb20 |
| 331 | La-2-658 | Lb1 | 332 | La-2-658 | Lb20 |
| 333 | La-2-659 | Lb1 | 334 | La-2-659 | Lb20 |
| 335 | La-1-663 | Lb1 | 336 | La-1-663 | Lb20 |
| 337 | La-1-664 | Lb1 | 338 | La-1-664 | Lb20 |
| 339 | La-2-669 | Lb1 | 340 | La-2-669 | Lb20 |
| 341 | La-2-670 | Lb1 | 342 | La-2-670 | Lb20 |
| 343 | La-1-833 | Lb1 | 344 | La-1-833 | Lb20 |
| 345 | La-1-834 | Lb1 | 346 | La-1-834 | Lb20 |
| 347 | La-2-833 | Lb1 | 348 | La-2-833 | Lb20 |
| 349 | La-2-834 | Lb1 | 350 | La-2-834 | Lb20 |
| 351 | La-1-863 | Lb1 | 352 | La-1-863 | Lb20 |
| 353 | La-1-864 | Lb1 | 354 | La-1-864 | Lb20 |
| 355 | La-1-865 | Lb1 | 356 | La-1-865 | Lb20 |
| 357 | La-1-866 | Lb1 | 358 | La-1-866 | Lb20 |
| 359 | La-1-867 | Lb1 | 360 | La-1-867 | Lb20 |
| 361 | La-2-863 | Lb1 | 362 | La-2-863 | Lb20 |
| 363 | La-2-864 | Lb1 | 364 | La-2-864 | Lb20 |
| 365 | La-2-865 | Lb1 | 366 | La-2-865 | Lb20 |
| 367 | La-2-866 | Lb1 | 368 | La-2-866 | Lb20 |
| 369 | La-2-867 | Lb1 | 370 | La-2-867 | Lb20 |
| 371 | La-2-871 | Lb1 | 372 | La-2-871 | Lb20 |
| 373 | La-2-872 | Lb1 | 374 | La-2-872 | Lb20 |
| 375 | La-2-873 | Lb1 | 376 | La-2-873 | Lb20 |
| 377 | La-2-874 | Lb1 | 378 | La-2-874 | Lb20 |
| 379 | La-2-875 | Lb1 | 380 | La-2-875 | Lb20 |
| 381 | La-1-881 | Lb1 | 382 | La-1-881 | Lb20 |
| 383 | La-1-882 | Lb1 | 384 | La-1-882 | Lb20 |
| 385 | La-1-883 | Lb1 | 386 | La-1-883 | Lb20 |
| 387 | La-1-884 | Lb1 | 388 | La-1-884 | Lb20 |
| 389 | La-2-886 | Lb1 | 390 | La-2-886 | Lb20 |
| 391 | La-2-887 | Lb1 | 392 | La-2-887 | Lb20 |
| 393 | La-2-888 | Lb1 | 394 | La-2-888 | Lb20 |
| 395 | La-1-936 | Lb1 | 396 | La-1-936 | Lb20 |
| 397 | La-1-937 | Lb1 | 398 | La-1-937 | Lb20 |
| 399 | La-2-936 | Lb1 | 400 | La-2-936 | Lb20 |
| 401 | La-2-937 | Lb1 | 402 | La-2-937 | Lb20 |
| 403 | La-1-967 | Lb1 | 404 | La-1-967 | Lb20 |
| 405 | La-1-968 | Lb1 | 406 | La-1-968 | Lb20 |
| 407 | La-1-969 | Lb1 | 408 | La-1-969 | Lb20 |
| 409 | La-1-970 | Lb1 | 410 | La-1-970 | Lb20 |
| 411 | La-2-978 | Lb1 | 412 | La-2-978 | Lb20 |
| 413 | La-2-979 | Lb1 | 414 | La-2-979 | Lb20 |
| 415 | La-2-980 | Lb1 | 416 | La-2-980 | Lb20 |
| 417 | La-1-1041 | Lb1 | 418 | La-1-1041 | Lb20 |
| 419 | La-1-1042 | Lb1 | 420 | La-1-1042 | Lb20 |
| 421 | La-2-1041 | Lb1 | 422 | La-2-1041 | Lb20 |
| 423 | La-2-1042 | Lb1 | 424 | La-2-1042 | Lb20 |
| 425 | La-1-1071 | Lb1 | 426 | La-1-1071 | Lb20 |
| 427 | La-1-1072 | Lb1 | 428 | La-1-1072 | Lb20 |
| 429 | La-1-1073 | Lb1 | 430 | La-1-1073 | Lb20 |
| 431 | La-1-1074 | Lb1 | 432 | La-1-1074 | Lb20 |
| 433 | La-2-1071 | Lb1 | 434 | La-2-1071 | Lb20 |
| 435 | La-2-1072 | Lb1 | 436 | La-2-1072 | Lb20 |
| 437 | La-2-1073 | Lb1 | 438 | La-2-1073 | Lb20 |
| 439 | La-2-1074 | Lb1 | 440 | La-2-1074 | Lb20 |
| 441 | La-1-1145 | Lb1 | 442 | La-1-1145 | Lb20 |
| 443 | La-1-1146 | Lb1 | 444 | La-1-1146 | Lb20 |
| 445 | La-2-1145 | Lb1 | 446 | La-2-1145 | Lb20 |
| 447 | La-2-1146 | Lb1 | 448 | La-2-1146 | Lb20 |
| 449 | La-1-1174 | Lb1 | 450 | La-1-1174 | Lb20 |
| 451 | La-1-1175 | Lb1 | 452 | La-1-1175 | Lb20 |
| 453 | La-1-1176 | Lb1 | 454 | La-1-1176 | Lb20 |
| 455 | La-1-1177 | Lb1 | 456 | La-1-1177 | Lb20 |
| 457 | La-1-1178 | Lb1 | 458 | La-1-1178 | Lb20 |
| 459 | La-2-1174 | Lb1 | 460 | La-2-1174 | Lb20 |
| 461 | La-2-1175 | Lb1 | 462 | La-2-1175 | Lb20 |
| 463 | La-2-1176 | Lb1 | 464 | La-2-1176 | Lb20 |
| 465 | La-2-1177 | Lb1 | 466 | La-2-1177 | Lb20 |
| 467 | La-2-1178 | Lb1 | 468 | La-2-1178 | Lb20 |
| 469 | La-1-1249 | Lb1 | 470 | La-1-1249 | Lb20 |
| 471 | La-1-1250 | Lb1 | 472 | La-1-1250 | Lb20 |
| 473 | La-2-1249 | Lb1 | 474 | La-2-1249 | Lb20 |
| 475 | La-2-1250 | Lb1 | 476 | La-2-1250 | Lb20 |
| 477 | La-1-1256 | Lb1 | 478 | La-1-1256 | Lb20 |
| 479 | La-1-1260 | Lb1 | 480 | La-1-1260 | Lb20 |
| 481 | La-1-1261 | Lb1 | 482 | La-1-1261 | Lb20 |
| 483 | La-1-1262 | Lb1 | 484 | La-1-1262 | Lb20 |
| 485 | La-1-1266 | Lb1 | 486 | La-1-1266 | Lb20 |
| 487 | La-2-1256 | Lb1 | 488 | La-2-1256 | Lb20 |
| 489 | La-2-1260 | Lb1 | 490 | La-2-1260 | Lb20 |
| 491 | La-2-1261 | Lb1 | 492 | La-2-1261 | Lb20 |
| 493 | La-2-1262 | Lb1 | 494 | La-2-1262 | Lb20 |
| 495 | La-2-1266 | Lb1 | 496 | La-2-1266 | Lb20 |
| 497 | La-1-1279 | Lb1 | 498 | La-1-1279 | Lb20 |
| 499 | La-1-1280 | Lb1 | 500 | La-1-1280 | Lb20 |
| 501 | La-1-1281 | Lb1 | 502 | La-1-1281 | Lb20 |
| 503 | La-1-1282 | Lb1 | 504 | La-1-1282 | Lb20 |
| 505 | La-1-1283 | Lb1 | 506 | La-1-1283 | Lb20 |
| 507 | La-2-1279 | Lb1 | 508 | La-2-1279 | Lb20 |
| 509 | La-2-1280 | Lb1 | 510 | La-2-1280 | Lb20 |
| 511 | La-2-1281 | Lb1 | 512 | La-2-1281 | Lb20 |
| 513 | La-2-1282 | Lb1 | 514 | La-2-1282 | Lb20 |
| 515 | La-2-1283 | Lb1 | 516 | La-2-1283 | Lb20 |
| 517 | La-1-1287 | Lb1 | 518 | La-1-1287 | Lb20 |
| 519 | La-1-1288 | Lb1 | 520 | La-1-1288 | Lb20 |
| 521 | La-1-1289 | Lb1 | 522 | La-1-1289 | Lb20 |
| 523 | La-2-1287 | Lb1 | 524 | La-2-1287 | Lb20 |
| 525 | La-2-1288 | Lb1 | 526 | La-2-1288 | Lb20 |
| 527 | La-2-1289 | Lb1 | 528 | La-2-1289 | Lb20 |
| 529 | La-1-1297 | Lb1 | 530 | La-1-1297 | Lb20 |
| 531 | La-1-1298 | Lb1 | 532 | La-1-1298 | Lb20 |
| 533 | La-1-1299 | Lb1 | 534 | La-1-1299 | Lb20 |
| 535 | La-1-1300 | Lb1 | 536 | La-1-1300 | Lb20 |
| 537 | La-1-1301 | Lb1 | 538 | La-1-1301 | Lb20 |
| 539 | La-1-1302 | Lb1 | 540 | La-1-1302 | Lb20 |
| 541 | La-2-1299 | Lb1 | 542 | La-2-1299 | Lb20 |
| 543 | La-2-1300 | Lb1 | 544 | La-2-1300 | Lb20 |
| 545 | La-2-1301 | Lb1 | 546 | La-2-1301 | Lb20 |
| 547 | La-2-1302 | Lb1 | 548 | La-2-1302 | Lb20 |
| 549 | La-1-1313 | Lb1 | 550 | La-1-1313 | Lb20 |
| 551 | La-1-1314 | Lb1 | 552 | La-1-1314 | Lb20 |
| 553 | La-1-1315 | Lb1 | 554 | La-1-1315 | Lb20 |
| 555 | La-2-1320 | Lb1 | 556 | La-2-1320 | Lb20 |
| 557 | La-2-1321 | Lb1 | 558 | La-2-1321 | Lb20 |
| 559 | La-2-1322 | Lb1 | 560 | La-2-1322 | Lb20 |
| 561 | La-2-1323 | Lb1 | 562 | La-2-1323 | Lb20 |
| 563 | La-2-1324 | Lb1 | 564 | La-2-1324 | Lb20 |
| 565 | La-1-1329 | Lb1 | 566 | La-1-1329 | Lb20 |
| 567 | La-1-1330 | Lb1 | 568 | La-1-1330 | Lb20 |
| 569 | La-1-1331 | Lb1 | 570 | La-1-1331 | Lb20 |
| 571 | La-2-1339 | Lb1 | 572 | La-2-1339 | Lb20 |
| 573 | La-2-1340 | Lb1 | 574 | La-2-1340 | Lb20 |
| 575 | La-2-1341 | Lb1 | 576 | La-2-1341 | Lb20 |
| 577 | La-2-1342 | Lb1 | 578 | La-2-1342 | Lb20 |
| 579 | La-2-1343 | Lb1 | 580 | La-2-1343 | Lb20 |
| 581 | La-1-1353 | Lb1 | 582 | La-1-1353 | Lb20 |
| 583 | La-1-1354 | Lb1 | 584 | La-1-1354 | Lb20 |
| 585 | La-2-1353 | Lb1 | 586 | La-2-1353 | Lb20 |
| 587 | La-2-1354 | Lb1 | 588 | La-2-1354 | Lb20 |
| 589 | La-1-1383 | Lb1 | 590 | La-1-1383 | Lb20 |
| 591 | La-1-1384 | Lb1 | 592 | La-1-1384 | Lb20 |
| 593 | La-1-1385 | Lb1 | 594 | La-1-1385 | Lb20 |
| 595 | La-1-1386 | Lb1 | 596 | La-1-1386 | Lb20 |
| 597 | La-1-1387 | Lb1 | 598 | La-1-1387 | Lb20 |
| 599 | La-2-1383 | Lb1 | 600 | La-2-1383 | Lb20 |
| 601 | La-2-1384 | Lb1 | 602 | La-2-1384 | Lb20 |
| 603 | La-2-1385 | Lb1 | 604 | La-2-1385 | Lb20 |
| 605 | La-2-1386 | Lb1 | 606 | La-2-1386 | Lb20 |
| 607 | La-2-1387 | Lb1 | 608 | La-2-1387 | Lb20 |
| 609 | La-1-1408 | Lb1 | 610 | La-1-1408 | Lb20 |
| 611 | La-1-1409 | Lb1 | 612 | La-1-1409 | Lb20 |
| 613 | La-1-1410 | Lb1 | 614 | La-1-1410 | Lb20 |
| 615 | La-1-1411 | Lb1 | 616 | La-1-1411 | Lb20 |
| 617 | La-2-1412 | Lb1 | 618 | La-2-1412 | Lb20 |
| 619 | La-2-1413 | Lb1 | 620 | La-2-1413 | Lb20 |
| 621 | La-2-1414 | Lb1 | 622 | La-2-1414 | Lb20 |
| 623 | La-2-1415 | Lb1 | 624 | La-2-1415 | Lb20 |
| 625 | La-2-1416 | Lb1 | 626 | La-2-1416 | Lb20 |
| 627 | La-2-1417 | Lb1 | 628 | La-2-1417 | Lb20 |
| 629 | La-1-1456 | Lb1 | 630 | La-1-1456 | Lb20 |
| 631 | La-1-1457 | Lb1 | 632 | La-1-1457 | Lb20 |
| 633 | La-1-1458 | Lb1 | 634 | La-1-1458 | Lb20 |
| 635 | La-2-1457 | Lb1 | 636 | La-2-1457 | Lb20 |
| 637 | La-2-1458 | Lb1 | 638 | La-2-1458 | Lb20 |
| 639 | La-1-1487 | Lb1 | 640 | La-1-1487 | Lb20 |
| 641 | La-1-1488 | Lb1 | 642 | La-1-1488 | Lb20 |
| 643 | La-1-1489 | Lb1 | 644 | La-1-1489 | Lb20 |
| 645 | La-1-1490 | Lb1 | 646 | La-1-1490 | Lb20 |
| 647 | La-1-1491 | Lb1 | 648 | La-1-1491 | Lb20 |
| 649 | La-2-1487 | Lb1 | 650 | La-2-1487 | Lb20 |
| 651 | La-2-1488 | Lb1 | 652 | La-2-1488 | Lb20 |
| 653 | La-2-1489 | Lb1 | 654 | La-2-1489 | Lb20 |
| 655 | La-2-1490 | Lb1 | 656 | La-2-1490 | Lb20 |
| 657 | La-2-1491 | Lb1 | 658 | La-2-1491 | Lb20 |
| 659 | La-1-1496 | Lb1 | 660 | La-1-1496 | Lb20 |
| 661 | La-1-1497 | Lb1 | 662 | La-1-1497 | Lb20 |
| 663 | La-1-1498 | Lb1 | 664 | La-1-1498 | Lb20 |
| 665 | La-1-1499 | Lb1 | 666 | La-1-1499 | Lb20 |
| 667 | La-1-1500 | Lb1 | 668 | La-1-1500 | Lb20 |
| 669 | La-1-1501 | Lb1 | 670 | La-1-1501 | Lb20 |
| 671 | La-2-1513 | Lb1 | 672 | La-2-1513 | Lb20 |
| 673 | La-2-1514 | Lb1 | 674 | La-2-1514 | Lb20 |
| 675 | La-2-1515 | Lb1 | 676 | La-2-1515 | Lb20 |
| 677 | La-2-1516 | Lb1 | 678 | La-2-1516 | Lb20 |
| 679 | La-2-1517 | Lb1 | 680 | La-2-1517 | Lb20 |
| 681 | La-2-1518 | Lb1 | 682 | La-2-1518 | Lb20 |
| 683 | La-1-1521 | Lb1 | 684 | La-1-1521 | Lb20 |
| 685 | La-1-1522 | Lb1 | 686 | La-1-1522 | Lb20 |
| 687 | La-1-1523 | Lb1 | 688 | La-1-1523 | Lb20 |
| 689 | La-1-1524 | Lb1 | 690 | La-1-1524 | Lb20 |
| 691 | La-1-1525 | Lb1 | 692 | La-1-1525 | Lb20 |
| 693 | La-1-1526 | Lb1 | 694 | La-1-1526 | Lb20 |
| 695 | La-1-1527 | Lb1 | 696 | La-1-1527 | Lb20 |
| 697 | La-1-1536 | Lb1 | 698 | La-1-1536 | Lb20 |
| 699 | La-1-1537 | Lb1 | 700 | La-1-1537 | Lb20 |
| 701 | La-2-1544 | Lb1 | 702 | La-2-1544 | Lb20 |
| 703 | La-2-1545 | Lb1 | 704 | La-2-1545 | Lb20 |
| 705 | La-2-1546 | Lb1 | 706 | La-2-1546 | Lb20 |
| 707 | La-1-1556 | Lb1 | 708 | La-1-1556 | Lb20 |
| 709 | La-1-1557 | Lb1 | 710 | La-1-1557 | Lb20 |
| 711 | La-2-1558 | Lb1 | 712 | La-2-1558 | Lb20 |
| 713 | La-2-1559 | Lb1 | 714 | La-2-1559 | Lb20 |
| 715 | La-1-1561 | Lb1 | 716 | La-1-1561 | Lb20 |
| 717 | La-1-1562 | Lb1 | 718 | La-1-1562 | Lb20 |
| 719 | La-2-1561 | Lb1 | 720 | La-2-1561 | Lb20 |
| 721 | La-2-1562 | Lb1 | 722 | La-2-1562 | Lb20 |
| 723 | La-1-1591 | Lb1 | 724 | La-1-1591 | Lb20 |
| 725 | La-1-1592 | Lb1 | 726 | La-1-1592 | Lb20 |
| 727 | La-1-1593 | Lb1 | 728 | La-1-1593 | Lb20 |
| 729 | La-1-1594 | Lb1 | 730 | La-1-1594 | Lb20 |
| 731 | La-1-1595 | Lb1 | 732 | La-1-1595 | Lb20 |
| 733 | La-2-1591 | Lb1 | 734 | La-2-1591 | Lb20 |
| 735 | La-2-1592 | Lb1 | 736 | La-2-1592 | Lb20 |
| 737 | La-2-1593 | Lb1 | 738 | La-2-1593 | Lb20 |
| 739 | La-2-1594 | Lb1 | 740 | La-2-1594 | Lb20 |
| 741 | La-2-1595 | Lb1 | 742 | La-2-1595 | Lb20 |
| 743 | La-1-1641 | Lb1 | 744 | La-1-1641 | Lb20 |
| 745 | La-1-1642 | Lb1 | 746 | La-1-1642 | Lb20 |
| 747 | La-2-1654 | Lb1 | 748 | La-2-1654 | Lb20 |
| 749 | La-2-1655 | Lb1 | 750 | La-2-1655 | Lb20 |
| 751 | La-2-1656 | Lb1 | 752 | La-2-1656 | Lb20 |
| 753 | La-1-1665 | Lb1 | 754 | La-1-1665 | Lb20 |
| 755 | La-1-1666 | Lb1 | 756 | La-1-1666 | Lb20 |
| 757 | La-2-1665 | Lb1 | 758 | La-2-1665 | Lb20 |
| 759 | La-2-1666 | Lb1 | 760 | La-2-1666 | Lb20 |
| 761 | La-1-1695 | Lb1 | 762 | La-1-1695 | Lb20 |
| 763 | La-1-1696 | Lb1 | 764 | La-1-1696 | Lb20 |
| 765 | La-1-1697 | Lb1 | 766 | La-1-1697 | Lb20 |
| 767 | La-1-1698 | Lb1 | 768 | La-1-1698 | Lb20 |
| 769 | La-1-1699 | Lb1 | 770 | La-1-1699 | Lb20 |
| 771 | La-2-1695 | Lb1 | 772 | La-2-1695 | Lb20 |
| 773 | La-2-1696 | Lb1 | 774 | La-2-1696 | Lb20 |
| 775 | La-2-1697 | Lb1 | 776 | La-2-1697 | Lb20 |
| 777 | La-2-1698 | Lb1 | 778 | La-2-1698 | Lb20 |
| 779 | La-2-1699 | Lb1 | 780 | La-2-1699 | Lb20 |
| 781 | La-1-1769 | Lb1 | 782 | La-1-1769 | Lb20 |
| 783 | La-1-1770 | Lb1 | 784 | La-1-1770 | Lb20 |
| 785 | La-2-1769 | Lb1 | 786 | La-2-1769 | Lb20 |
| 787 | La-2-1770 | Lb1 | 788 | La-2-1770 | Lb20 |
| 789 | La-1-1799 | Lb1 | 790 | La-1-1799 | Lb20 |
| 791 | La-1-1800 | Lb1 | 792 | La-1-1800 | Lb20 |
| 793 | La-1-1801 | Lb1 | 794 | La-1-1801 | Lb20 |
| 795 | La-1-1802 | Lb1 | 796 | La-1-1802 | Lb20 |
| 797 | La-1-1803 | Lb1 | 798 | La-1-1803 | Lb20 |
| 799 | La-1-1828 | Lb1 | 800 | La-1-1828 | Lb20 |
| 801 | La-1-1829 | Lb1 | 802 | La-1-1829 | Lb20 |
| 803 | La-1-1872 | Lb1 | 804 | La-1-1872 | Lb20 |
| 805 | La-1-1873 | Lb1 | 806 | La-1-1873 | Lb20 |
| 807 | La-1-1874 | Lb1 | 808 | La-1-1874 | Lb20 |
| 809 | La-1-1903 | Lb1 | 810 | La-1-1903 | Lb20 |
| 811 | La-1-1904 | Lb1 | 812 | La-1-1904 | Lb20 |
| 813 | La-1-1905 | Lb1 | 814 | La-1-1905 | Lb20 |
| 815 | La-1-1906 | Lb1 | 816 | La-1-1906 | Lb20 |
| 817 | La-1-1907 | Lb1 | 818 | La-1-1907 | Lb20 |
| 819 | La-1-1977 | Lb1 | 820 | La-1-1977 | Lb20 |
| 821 | La-1-1978 | Lb1 | 822 | La-1-1978 | Lb20 |
| 823 | La-1-2007 | Lb1 | 824 | La-1-2007 | Lb20 |
| 825 | La-1-2008 | Lb1 | 826 | La-1-2008 | Lb20 |
| 827 | La-1-2009 | Lb1 | 828 | La-1-2009 | Lb20 |
| 829 | La-1-2010 | Lb1 | 830 | La-1-2010 | Lb20 |
| 831 | La-1-2011 | Lb1 | 832 | La-1-2011 | Lb20 |
| 833 | La-1-2036 | Lb1 | 834 | La-1-2036 | Lb20 |
| 835 | La-1-2037 | Lb1 | 836 | La-1-2037 | Lb20 |
| 837 | La-1-2038 | Lb1 | 838 | La-1-2038 | Lb20 |
| 839 | La-1-2080 | Lb1 | 840 | La-1-2080 | Lb20 |
| 841 | La-1-2081 | Lb1 | 842 | La-1-2081 | Lb20 |
| 843 | La-1-2111 | Lb1 | 844 | La-1-2111 | Lb20 |
| 845 | La-1-2112 | Lb1 | 846 | La-1-2112 | Lb20 |
| 847 | La-1-2113 | Lb1 | 848 | La-1-2113 | Lb20 |
| 849 | La-1-2114 | Lb1 | 850 | La-1-2114 | Lb20 |
| 851 | La-1-2115 | Lb1 | 852 | La-1-2115 | Lb20 |
| 853 | La-1-2185 | Lb1 | 854 | La-1-2185 | Lb20 |
| 855 | La-1-2186 | Lb1 | 856 | La-1-2186 | Lb20 |
| 857 | La-1-2215 | Lb1 | 858 | La-1-2215 | Lb20 |
| 859 | La-1-2216 | Lb1 | 860 | La-1-2216 | Lb20 |
| 861 | La-1-2217 | Lb1 | 862 | La-1-2217 | Lb20 |
| 863 | La-1-2218 | Lb1 | 864 | La-1-2218 | Lb20 |
| 865 | La-1-2219 | Lb1 | 866 | La-1-2219 | Lb20 |
| 867 | La-1-2234 | Lb1 | 868 | La-1-2234 | Lb20 |
| 869 | La-1-2235 | Lb1 | 870 | La-1-2235 | Lb20 |
| 871 | La-1-2236 | Lb1 | 872 | La-1-2236 | Lb20 |
| 873 | La-1-2237 | Lb1 | 874 | La-1-2237 | Lb20 |
| 875 | La-1-2238 | Lb1 | 876 | La-1-2238 | Lb20 |
| 877 | La-1-2289 | Lb1 | 878 | La-1-2289 | Lb20 |
| 879 | La-1-2290 | Lb1 | 880 | La-1-2290 | Lb20 |
| 881 | La-1-2319 | Lb1 | 882 | La-1-2319 | Lb20 |
| 883 | La-1-2320 | Lb1 | 884 | La-1-2320 | Lb20 |
| 885 | La-1-2321 | Lb1 | 886 | La-1-2321 | Lb20 |
| 887 | La-1-2322 | Lb1 | 888 | La-1-2322 | Lb20 |
| 889 | La-1-2323 | Lb1 | 890 | La-1-2323 | Lb20 |
| 891 | La-1-2393 | Lb1 | 892 | La-1-2393 | Lb20 |
| 893 | La-1-2394 | Lb1 | 894 | La-1-2394 | Lb20 |
| 895 | La-1-2423 | Lb1 | 896 | La-1-2423 | Lb20 |
| 897 | La-1-2424 | Lb1 | 898 | La-1-2424 | Lb20 |
| 899 | La-1-2425 | Lb1 | 900 | La-1-2425 | Lb20 |
| 901 | La-1-2426 | Lb1 | 902 | La-1-2426 | Lb20 |
| 903 | La-1-2427 | Lb1 | 904 | La-1-2427 | Lb20 |
| 905 | La-1-2497 | Lb1 | 906 | La-1-2497 | Lb20 |
| 907 | La-1-2498 | Lb1 | 908 | La-1-2498 | Lb20 |
| 909 | La-1-2527 | Lb1 | 910 | La-1-2527 | Lb20 |
| 911 | La-1-2528 | Lb1 | 912 | La-1-2528 | Lb20 |
| 913 | La-1-2529 | Lb1 | 914 | La-1-2529 | Lb20 |
| 915 | La-1-2530 | Lb1 | 916 | La-1-2530 | Lb20 |
| 917 | La-1-2531 | Lb1 | 918 | La-1-2531 | Lb20 |
| 919 | La-1-2601 | Lb1 | 920 | La-1-2601 | Lb20 |
| 921 | La-1-2602 | Lb1 | 922 | La-1-2602 | Lb20 |
| 923 | La-1-2631 | Lb1 | 924 | La-1-2631 | Lb20 |
| 925 | La-1-2632 | Lb1 | 926 | La-1-2632 | Lb20 |
| 927 | La-1-2633 | Lb1 | 928 | La-1-2633 | Lb20 |
| 929 | La-1-2634 | Lb1 | 930 | La-1-2634 | Lb20 |
| 931 | La-1-2635 | Lb1 | 932 | La-1-2635 | Lb20 |
| 933 | La-1-2705 | Lb1 | 934 | La-1-2705 | Lb20 |
| 935 | La-1-2706 | Lb1 | 936 | La-1-2706 | Lb20 |
| 937 | La-1-2735 | Lb1 | 938 | La-1-2735 | Lb20 |
| 939 | La-1-2736 | Lb1 | 940 | La-1-2736 | Lb20 |
| 941 | La-1-2737 | Lb1 | 942 | La-1-2737 | Lb20 |
| 943 | La-1-2738 | Lb1 | 944 | La-1-2738 | Lb20 |
| 945 | La-1-2739 | Lb1 | 946 | La-1-2739 | Lb20 |
| 947 | La-1-2809 | Lb1 | 948 | La-1-2809 | Lb20 |
| 949 | La-1-2810 | Lb1 | 950 | La-1-2810 | Lb20 |
| 951 | La-1-2839 | Lb1 | 952 | La-1-2839 | Lb20 |
| 953 | La-1-2840 | Lb1 | 954 | La-1-2840 | Lb20 |
| 955 | La-1-2841 | Lb1 | 956 | La-1-2841 | Lb20 |
| 957 | La-1-2842 | Lb1 | 958 | La-1-2842 | Lb20 |
| 959 | La-1-2843 | Lb1 | 960 | La-1-2843 | Lb20 |
| 961 | La-1-2918 | Lb1 | 962 | La-1-2918 | Lb20 |
| 963 | La-1-2919 | Lb1 | 964 | La-1-2919 | Lb20 |
| 965 | La-1-2920 | Lb1 | 966 | La-1-2920 | Lb20 |
| 967 | La-1-2921 | Lb1 | 968 | La-1-2921 | Lb20 |
| 969 | La-1-2922 | Lb1 | 970 | La-1-2922 | Lb20 |
| 971 | La-1-2943 | Lb1 | 972 | La-1-2943 | Lb20 |
| 973 | La-1-2944 | Lb1 | 974 | La-1-2944 | Lb20 |
| 975 | La-1-2928 | Lb1 | 976 | La-1-2928 | Lb20 |
| 977 | La-1-2929 | Lb1 | 978 | La-1-2929 | Lb20 |
| 979 | La-1-2957 | Lb1 | 980 | La-1-2957 | Lb20 |
| 981 | La-1-2958 | Lb1 | 982 | La-1-2958 | Lb20 |
| 983 | La-1-2959 | Lb1 | 984 | La-1-2959 | Lb20 |
| 985 | La-1-2973 | Lb1 | 986 | La-1-2973 | Lb20 |
| 987 | La-1-2974 | Lb1 | 988 | La-1-2974 | Lb20 |
| 989 | La-1-2986 | Lb1 | 990 | La-1-2986 | Lb20 |
| 991 | La-1-2987 | Lb1 | 992 | La-1-2987 | Lb20 |
| 993 | La-1-2988 | Lb1 | 994 | La-1-2988 | Lb20 |
| 995 | La-1-2989 | Lb1 | 996 | La-1-2989 | Lb20 |
| 997 | La-1-3003 | Lb1 | 998 | La-1-3003 | Lb20 |
| 999 | La-1-3015 | Lb1 | 1000 | La-1-3015 | Lb20 |
| 1001 | La-1-3019 | Lb1 | 1002 | La-1-3019 | Lb20 |
| 1003 | La-1-3035 | Lb1 | 1004 | La-1-3035 | Lb20 |
| 1005 | La-1-3048 | Lb1 | 1006 | La-1-3048 | Lb20 |
| 1007 | La-1-3049 | Lb1 | 1008 | La-1-3049 | Lb20 |
| 1009 | La-1-3040 | Lb1 | 1010 | La-1-3040 | Lb20 |
| 1011 | La-1-3041 | Lb1 | 1012 | La-1-3041 | Lb20 |
| 1013 | La-1-3042 | Lb1 | 1014 | La-1-3042 | Lb20 |
| 1015 | La-1-3043 | Lb1 | 1016 | La-1-3043 | Lb20 |
| 1017 | La-1-3044 | Lb1 | 1018 | La-1-3044 | Lb20 |
| 1019 | La-1-3045 | Lb1 | 1020 | La-1-3045 | Lb20 |
| 1021 | La-1-3046 | Lb1 | 1022 | La-1-3046 | Lb20 |
| 1023 | La-1-3047 | Lb1 | 1024 | La-1-3047 | Lb20 |
| 1025 | La-1-3055 | Lb1 | 1026 | La-1-3055 | Lb20 |
| 1027 | La-1-3058 | Lb1 | 1028 | La-1-3058 | Lb20 |
| 1029 | La-1-3059 | Lb1 | 1030 | La-1-3059 | Lb20 |
| 1031 | La-1-3070 | Lb1 | 1032 | La-1-3070 | Lb20 |
| 1033 | La-1-3077 | Lb1 | 1034 | La-1-3077 | Lb20 |
| 1035 | La-1-3078 | Lb1 | 1036 | La-1-3078 | Lb20 |
| 1037 | La-1-3079 | Lb1 | 1038 | La-1-3079 | Lb20 |
| 1039 | La-1-3093 | Lb1 | 1040 | La-1-3093 | Lb20 |
| 1041 | La-1-3094 | Lb1 | 1042 | La-1-3094 | Lb20 |
| 1043 | La-1-3095 | Lb1 | 1044 | La-1-3095 | Lb20 |
| 1045 | La-1-3096 | Lb1 | 1046 | La-1-3096 | Lb20 |
| 1047 | La-1-3097 | Lb1 | 1048 | La-1-3097 | Lb20 |
| 1049 | La-1-3098 | Lb1 | 1050 | La-1-3098 | Lb20 |
| 1051 | La-1-3099 | Lb1 | 1052 | La-1-3099 | Lb20 |
| 1053 | La-1-3100 | Lb1 | 1054 | La-1-3100 | Lb20 |
| 1055 | La-1-3101 | Lb1 | 1056 | La-1-3101 | Lb20 |
| 1057 | La-1-3102 | Lb1 | 1058 | La-1-3102 | Lb20 |
| 1059 | La-1-3103 | Lb1 | 1060 | La-1-3103 | Lb20 |
| 1061 | La-1-3104 | Lb1 | 1062 | La-1-3104 | Lb20 |
| 1063 | La-1-3105 | Lb1 | 1064 | La-1-3105 | Lb20 |
| 1065 | La-1-3106 | Lb1 | 1066 | La-1-3106 | Lb20 |
| 1067 | La-1-3107 | Lb1 | 1068 | La-1-3107 | Lb20 |
| 1069 | La-1-3108 | Lb1 | 1070 | La-1-3108 | Lb20 |
| 1071 | La-1-3109 | Lb1 | 1072 | La-1-3109 | Lb20 |
| 1073 | La-1-3110 | Lb1 | 1074 | La-1-3110 | Lb20 |
| 1075 | La-1-3118 | Lb1 | 1076 | La-1-3118 | Lb20 |
| 1077 | La-1-3142 | Lb1 | 1078 | La-1-3142 | Lb20 |
| 1079 | La-1-3150 | Lb1 | 1080 | La-1-3150 | Lb20 |
| 1081 | La-1-3154 | Lb1 | 1082 | La-1-3154 | Lb20 |
| 1083 | La-1-3165 | Lb1 | 1084 | La-1-3165 | Lb20 |
| 1085 | La-1-3166 | Lb1 | 1086 | La-1-3166 | Lb20 |
| 1087 | La-1-3174 | Lb1 | 1088 | La-1-3174 | Lb20 |
| 1089 | La-1-3182 | Lb1 | 1090 | La-1-3182 | Lb20 |
| 1091 | La-1-3185 | Lb1 | 1092 | La-1-3185 | Lb20 |
| 1093 | La-1-3186 | Lb1 | 1094 | La-1-3186 | Lb20 |
| 1095 | La-1-3198 | Lb1 | 1096 | La-1-3198 | Lb20 |
| 1097 | La-1-3217 | Lb1 | 1098 | La-1-3217 | Lb20 |
| 1099 | La-1-3218 | Lb1 | 1100 | La-1-3218 | Lb20 |
| 1101 | La-1-3226 | Lb1 | 1102 | La-1-3226 | Lb20 |
| 1103 | La-1-3227 | Lb1 | 1104 | La-1-3227 | Lb20 |
| 1105 | La-1-3228 | Lb1 | 1106 | La-1-3228 | Lb20 |
| 1107 | La-1-3256 | Lb1 | 1108 | La-1-3256 | Lb20 |
| 1109 | La-1-3257 | Lb1 | 1110 | La-1-3257 | Lb20 |
| 1111 | La-1-3258 | Lb1 | 1112 | La-1-3258 | Lb20 |
| 1113 | La-1-3259 | Lb1 | 1114 | La-1-3259 | Lb20 |
| 1115 | La-1-3288 | Lb1 | 1116 | La-1-3288 | Lb20 |
| 1117 | La-1-3289 | Lb1 | 1118 | La-1-3289 | Lb20 |
| 1119 | La-1-3290 | Lb1 | 1120 | La-1-3290 | Lb20 |
| 1121 | La-1-3291 | Lb1 | 1122 | La-1-3291 | Lb20 |
| 1123 | La-1-3315 | Lb1 | 1124 | La-1-3315 | Lb20 |
| 1125 | La-1-3316 | Lb1 | 1126 | La-1-3316 | Lb20 |
| 1127 | La-1-3345 | Lb1 | 1128 | La-1-3345 | Lb20 |
| 1129 | La-1-3346 | Lb1 | 1130 | La-1-3346 | Lb20 |
| 1131 | La-1-3347 | Lb1 | 1132 | La-1-3347 | Lb20 |
| 1133 | La-1-3348 | Lb1 | 1134 | La-1-3348 | Lb20 |
| 1135 | La-1-3349 | Lb1 | 1136 | La-1-3349 | Lb20 |
| 1137 | La-1-3449 | Lb1 | 1138 | La-1-3449 | Lb20 |
| 1139 | La-1-3450 | Lb1 | 1140 | La-1-3450 | Lb20 |
| 1141 | La-1-3451 | Lb1 | 1142 | La-1-3451 | Lb20 |
| 1143 | La-1-3452 | Lb1 | 1144 | La-1-3452 | Lb20 |
| 1145 | La-1-3453 | Lb1 | 1146 | La-1-3453 | Lb20 |
| 1147 | La-1-3523 | Lb1 | 1148 | La-1-3523 | Lb20 |
| 1149 | La-1-3524 | Lb1 | 1150 | La-1-3524 | Lb20 |
| 1151 | La-1-3657 | Lb1 | 1152 | La-1-3657 | Lb20 |
| 1153 | La-1-3658 | Lb1 | 1154 | La-1-3658 | Lb20 |
| 1155 | La-1-3659 | Lb1 | 1156 | La-1-3659 | Lb20 |
| 1157 | La-1-3660 | Lb1 | 1158 | La-1-3660 | Lb20 |
| 1159 | La-1-3661 | Lb1 | 1160 | La-1-3661 | Lb20 |
| 1161 | La-1-3730 | Lb1 | 1162 | La-1-3730 | Lb20 |
| 1163 | La-2-1799 | Lb1 | 1164 | La-2-1799 | Lb20 |
| 1165 | La-2-1800 | Lb1 | 1166 | La-2-1800 | Lb20 |
| 1167 | La-2-1801 | Lb1 | 1168 | La-2-1801 | Lb20 |
| 1169 | La-2-1802 | Lb1 | 1170 | La-2-1802 | Lb20 |
| 1171 | La-2-1803 | Lb1 | 1172 | La-2-1803 | Lb20 |
| 1173 | La-2-1828 | Lb1 | 1174 | La-2-1828 | Lb20 |
| 1175 | La-2-1829 | Lb1 | 1176 | La-2-1829 | Lb20 |
| 1177 | La-2-1872 | Lb1 | 1178 | La-2-1872 | Lb20 |
| 1179 | La-2-1873 | Lb1 | 1180 | La-2-1873 | Lb20 |
| 1181 | La-2-1874 | Lb1 | 1182 | La-2-1874 | Lb20 |
| 1183 | La-2-1903 | Lb1 | 1184 | La-2-1903 | Lb20 |
| 1185 | La-2-1904 | Lb1 | 1186 | La-2-1904 | Lb20 |
| 1187 | La-2-1905 | Lb1 | 1188 | La-2-1905 | Lb20 |
| 1189 | La-2-1906 | Lb1 | 1190 | La-2-1906 | Lb20 |
| 1191 | La-2-1907 | Lb1 | 1192 | La-2-1907 | Lb20 |
| 1193 | La-2-1977 | Lb1 | 1194 | La-2-1977 | Lb20 |
| 1195 | La-2-1978 | Lb1 | 1196 | La-2-1978 | Lb20 |
| 1197 | La-2-2007 | Lb1 | 1198 | La-2-2007 | Lb20 |
| 1199 | La-2-2008 | Lb1 | 1200 | La-2-2008 | Lb20 |
| 1201 | La-2-2009 | Lb1 | 1202 | La-2-2009 | Lb20 |
| 1203 | La-2-2010 | Lb1 | 1204 | La-2-2010 | Lb20 |
| 1205 | La-2-2011 | Lb1 | 1206 | La-2-2011 | Lb20 |
| 1207 | La-2-2036 | Lb1 | 1208 | La-2-2036 | Lb20 |
| 1209 | La-2-2037 | Lb1 | 1210 | La-2-2037 | Lb20 |
| 1211 | La-2-2038 | Lb1 | 1212 | La-2-2038 | Lb20 |
| 1213 | La-2-2080 | Lb1 | 1214 | La-2-2080 | Lb20 |
| 1215 | La-2-2081 | Lb1 | 1216 | La-2-2081 | Lb20 |
| 1217 | La-2-2111 | Lb1 | 1218 | La-2-2111 | Lb20 |
| 1219 | La-2-2112 | Lb1 | 1220 | La-2-2112 | Lb20 |
| 1221 | La-2-2113 | Lb1 | 1222 | La-2-2113 | Lb20 |
| 1223 | La-2-2114 | Lb1 | 1224 | La-2-2114 | Lb20 |
| 1225 | La-2-2115 | Lb1 | 1226 | La-2-2115 | Lb20 |
| 1227 | La-2-2185 | Lb1 | 1228 | La-2-2185 | Lb20 |
| 1229 | La-2-2186 | Lb1 | 1230 | La-2-2186 | Lb20 |
| 1231 | La-2-2215 | Lb1 | 1232 | La-2-2215 | Lb20 |
| 1233 | La-2-2216 | Lb1 | 1234 | La-2-2216 | Lb20 |
| 1235 | La-2-2217 | Lb1 | 1236 | La-2-2217 | Lb20 |
| 1237 | La-2-2218 | Lb1 | 1238 | La-2-2218 | Lb20 |
| 1239 | La-2-2219 | Lb1 | 1240 | La-2-2219 | Lb20 |
| 1241 | La-2-2234 | Lb1 | 1242 | La-2-2234 | Lb20 |
| 1243 | La-2-2235 | Lb1 | 1244 | La-2-2235 | Lb20 |
| 1245 | La-2-2236 | Lb1 | 1246 | La-2-2236 | Lb20 |
| 1247 | La-2-2237 | Lb1 | 1248 | La-2-2237 | Lb20 |
| 1249 | La-2-2238 | Lb1 | 1250 | La-2-2238 | Lb20 |
| 1251 | La-2-2289 | Lb1 | 1252 | La-2-2289 | Lb20 |
| 1253 | La-2-2290 | Lb1 | 1254 | La-2-2290 | Lb20 |
| 1255 | La-2-2319 | Lb1 | 1256 | La-2-2319 | Lb20 |
| 1257 | La-2-2320 | Lb1 | 1258 | La-2-2320 | Lb20 |
| 1259 | La-2-2321 | Lb1 | 1260 | La-2-2321 | Lb20 |
| 1261 | La-2-2322 | Lb1 | 1262 | La-2-2322 | Lb20 |
| 1263 | La-2-2323 | Lb1 | 1264 | La-2-2323 | Lb20 |
| 1265 | La-2-2393 | Lb1 | 1266 | La-2-2393 | Lb20 |
| 1267 | La-2-2394 | Lb1 | 1268 | La-2-2394 | Lb20 |
| 1269 | La-2-2423 | Lb1 | 1270 | La-2-2423 | Lb20 |
| 1271 | La-2-2424 | Lb1 | 1272 | La-2-2424 | Lb20 |
| 1273 | La-2-2425 | Lb1 | 1274 | La-2-2425 | Lb20 |
| 1275 | La-2-2426 | Lb1 | 1276 | La-2-2426 | Lb20 |
| 1277 | La-2-2427 | Lb1 | 1278 | La-2-2427 | Lb20 |
| 1279 | La-2-2497 | Lb1 | 1280 | La-2-2497 | Lb20 |
| 1281 | La-2-2498 | Lb1 | 1282 | La-2-2498 | Lb20 |
| 1283 | La-2-2527 | Lb1 | 1284 | La-2-2527 | Lb20 |
| 1285 | La-2-2528 | Lb1 | 1286 | La-2-2528 | Lb20 |
| 1287 | La-2-2529 | Lb1 | 1288 | La-2-2529 | Lb20 |
| 1289 | La-2-2530 | Lb1 | 1290 | La-2-2530 | Lb20 |
| 1291 | La-2-2531 | Lb1 | 1292 | La-2-2531 | Lb20 |
| 1293 | La-2-2601 | Lb1 | 1294 | La-2-2601 | Lb20 |
| 1295 | La-2-2602 | Lb1 | 1296 | La-2-2602 | Lb20 |
| 1297 | La-2-2631 | Lb1 | 1298 | La-2-2631 | Lb20 |
| 1299 | La-2-2632 | Lb1 | 1300 | La-2-2632 | Lb20 |
| 1301 | La-2-2633 | Lb1 | 1302 | La-2-2633 | Lb20 |
| 1303 | La-2-2634 | Lb1 | 1304 | La-2-2634 | Lb20 |
| 1305 | La-2-2635 | Lb1 | 1306 | La-2-2635 | Lb20 |
| 1307 | La-2-2705 | Lb1 | 1308 | La-2-2705 | Lb20 |
| 1309 | La-2-2706 | Lb1 | 1310 | La-2-2706 | Lb20 |
| 1311 | La-2-2735 | Lb1 | 1312 | La-2-2735 | Lb20 |
| 1313 | La-2-2736 | Lb1 | 1314 | La-2-2736 | Lb20 |
| 1315 | La-2-2737 | Lb1 | 1316 | La-2-2737 | Lb20 |
| 1317 | La-2-2738 | Lb1 | 1318 | La-2-2738 | Lb20 |
| 1319 | La-2-2739 | Lb1 | 1320 | La-2-2739 | Lb20 |
| 1321 | La-2-2809 | Lb1 | 1322 | La-2-2809 | Lb20 |
| 1323 | La-2-2810 | Lb1 | 1324 | La-2-2810 | Lb20 |
| 1325 | La-2-2839 | Lb1 | 1326 | La-2-2839 | Lb20 |
| 1327 | La-2-2840 | Lb1 | 1328 | La-2-2840 | Lb20 |
| 1329 | La-2-2841 | Lb1 | 1330 | La-2-2841 | Lb20 |
| 1331 | La-2-2842 | Lb1 | 1332 | La-2-2842 | Lb20 |
| 1333 | La-2-2843 | Lb1 | 1334 | La-2-2843 | Lb20 |
| 1335 | La-2-2918 | Lb1 | 1336 | La-2-2918 | Lb20 |
| 1337 | La-2-2919 | Lb1 | 1338 | La-2-2919 | Lb20 |
| 1339 | La-2-2920 | Lb1 | 1340 | La-2-2920 | Lb20 |
| 1341 | La-2-2921 | Lb1 | 1342 | La-2-2921 | Lb20 |
| 1343 | La-2-2922 | Lb1 | 1344 | La-2-2922 | Lb20 |
| 1345 | La-2-2943 | Lb1 | 1346 | La-2-2943 | Lb20 |
| 1347 | La-2-2944 | Lb1 | 1348 | La-2-2944 | Lb20 |
| 1349 | La-2-2928 | Lb1 | 1350 | La-2-2928 | Lb20 |
| 1351 | La-2-2929 | Lb1 | 1352 | La-2-2929 | Lb20 |
| 1353 | La-2-2957 | Lb1 | 1354 | La-2-2957 | Lb20 |
| 1355 | La-2-2958 | Lb1 | 1356 | La-2-2958 | Lb20 |
| 1357 | La-2-2959 | Lb1 | 1358 | La-2-2959 | Lb20 |
| 1359 | La-2-2973 | Lb1 | 1360 | La-2-2973 | Lb20 |
| 1361 | La-2-2974 | Lb1 | 1362 | La-2-2974 | Lb20 |
| 1363 | La-2-2986 | Lb1 | 1364 | La-2-2986 | Lb20 |
| 1365 | La-2-2987 | Lb1 | 1366 | La-2-2987 | Lb20 |
| 1367 | La-2-2988 | Lb1 | 1368 | La-2-2988 | Lb20 |
| 1369 | La-2-2989 | Lb1 | 1370 | La-2-2989 | Lb20 |
| 1371 | La-2-3003 | Lb1 | 1372 | La-2-3003 | Lb20 |
| 1373 | La-2-3015 | Lb1 | 1374 | La-2-3015 | Lb20 |
| 1375 | La-2-3019 | Lb1 | 1376 | La-2-3019 | Lb20 |
| 1377 | La-2-3035 | Lb1 | 1378 | La-2-3035 | Lb20 |
| 1379 | La-2-3048 | Lb1 | 1380 | La-2-3048 | Lb20 |
| 1381 | La-2-3049 | Lb1 | 1382 | La-2-3049 | Lb20 |
| 1383 | La-2-3040 | Lb1 | 1384 | La-2-3040 | Lb20 |
| 1385 | La-2-3041 | Lb1 | 1386 | La-2-3041 | Lb20 |
| 1387 | La-2-3042 | Lb1 | 1388 | La-2-3042 | Lb20 |
| 1389 | La-2-3043 | Lb1 | 1390 | La-2-3043 | Lb20 |
| 1391 | La-2-3044 | Lb1 | 1392 | La-2-3044 | Lb20 |
| 1393 | La-2-3045 | Lb1 | 1394 | La-2-3045 | Lb20 |
| 1395 | La-2-3046 | Lb1 | 1396 | La-2-3046 | Lb20 |
| 1397 | La-2-3047 | Lb1 | 1398 | La-2-3047 | Lb20 |
| 1399 | La-2-3055 | Lb1 | 1400 | La-2-3055 | Lb20 |
| 1401 | La-2-3058 | Lb1 | 1402 | La-2-3058 | Lb20 |
| 1403 | La-2-3059 | Lb1 | 1404 | La-2-3059 | Lb20 |
| 1405 | La-2-3070 | Lb1 | 1406 | La-2-3070 | Lb20 |
| 1407 | La-2-3077 | Lb1 | 1408 | La-2-3077 | Lb20 |
| 1409 | La-2-3078 | Lb1 | 1410 | La-2-3078 | Lb20 |
| 1411 | La-2-3079 | Lb1 | 1412 | La-2-3079 | Lb20 |
| 1413 | La-2-3093 | Lb1 | 1414 | La-2-3093 | Lb20 |
| 1415 | La-2-3094 | Lb1 | 1416 | La-2-3094 | Lb20 |
| 1417 | La-2-3095 | Lb1 | 1418 | La-2-3095 | Lb20 |
| 1419 | La-2-3096 | Lb1 | 1420 | La-2-3096 | Lb20 |
| 1421 | La-2-3097 | Lb1 | 1422 | La-2-3097 | Lb20 |
| 1423 | La-2-3098 | Lb1 | 1424 | La-2-3098 | Lb20 |
| 1425 | La-2-3099 | Lb1 | 1426 | La-2-3099 | Lb20 |
| 1427 | La-2-3100 | Lb1 | 1428 | La-2-3100 | Lb20 |
| 1429 | La-2-3101 | Lb1 | 1430 | La-2-3101 | Lb20 |
| 1431 | La-2-3102 | Lb1 | 1432 | La-2-3102 | Lb20 |
| 1433 | La-2-3103 | Lb1 | 1434 | La-2-3103 | Lb20 |
| 1435 | La-2-3104 | Lb1 | 1436 | La-2-3104 | Lb20 |
| 1437 | La-2-3105 | Lb1 | 1438 | La-2-3105 | Lb20 |
| 1439 | La-2-3106 | Lb1 | 1440 | La-2-3106 | Lb20 |
| 1441 | La-2-3107 | Lb1 | 1442 | La-2-3107 | Lb20 |
| 1443 | La-2-3108 | Lb1 | 1444 | La-2-3108 | Lb20 |
| 1445 | La-2-3109 | Lb1 | 1446 | La-2-3109 | Lb20 |
| 1447 | La-2-3110 | Lb1 | 1448 | La-2-3110 | Lb20 |
| 1449 | La-2-3118 | Lb1 | 1450 | La-2-3118 | Lb20 |
| 1451 | La-2-3142 | Lb1 | 1452 | La-2-3142 | Lb20 |
| 1453 | La-2-3150 | Lb1 | 1454 | La-2-3150 | Lb20 |
| 1455 | La-2-3154 | Lb1 | 1456 | La-2-3154 | Lb20 |
| 1457 | La-2-3165 | Lb1 | 1458 | La-2-3165 | Lb20 |
| 1459 | La-2-3166 | Lb1 | 1460 | La-2-3166 | Lb20 |
| 1461 | La-2-3174 | Lb1 | 1462 | La-2-3174 | Lb20 |
| 1463 | La-2-3182 | Lb1 | 1464 | La-2-3182 | Lb20 |
| 1465 | La-2-3185 | Lb1 | 1466 | La-2-3185 | Lb20 |
| 1467 | La-2-3186 | Lb1 | 1468 | La-2-3186 | Lb20 |
| 1469 | La-2-3198 | Lb1 | 1470 | La-2-3198 | Lb20 |
| 1471 | La-2-3217 | Lb1 | 1472 | La-2-3217 | Lb20 |
| 1473 | La-2-3218 | Lb1 | 1474 | La-2-3218 | Lb20 |
| 1475 | La-2-3226 | Lb1 | 1476 | La-2-3226 | Lb20 |
| 1477 | La-2-3227 | Lb1 | 1478 | La-2-3227 | Lb20 |
| 1479 | La-2-3228 | Lb1 | 1480 | La-2-3228 | Lb20 |
| 1481 | La-2-3256 | Lb1 | 1482 | La-2-3256 | Lb20 |
| 1483 | La-2-3257 | Lb1 | 1484 | La-2-3257 | Lb20 |
| 1485 | La-2-3258 | Lb1 | 1486 | La-2-3258 | Lb20 |
| 1487 | La-2-3259 | Lb1 | 1488 | La-2-3259 | Lb20 |
| 1489 | La-2-3288 | Lb1 | 1490 | La-2-3288 | Lb20 |
| 1491 | La-2-3289 | Lb1 | 1492 | La-2-3289 | Lb20 |
| 1493 | La-2-3290 | Lb1 | 1494 | La-2-3290 | Lb20 |
| 1495 | La-2-3291 | Lb1 | 1496 | La-2-3291 | Lb20 |
| 1497 | La-2-3315 | Lb1 | 1498 | La-2-3315 | Lb20 |
| 1499 | La-2-3316 | Lb1 | 1500 | La-2-3316 | Lb20 |
| 1501 | La-2-3345 | Lb1 | 1502 | La-2-3345 | Lb20 |
| 1503 | La-2-3346 | Lb1 | 1504 | La-2-3346 | Lb20 |
| 1505 | La-2-3347 | Lb1 | 1506 | La-2-3347 | Lb20 |
| 1507 | La-2-3348 | Lb1 | 1508 | La-2-3348 | Lb20 |
| 1509 | La-2-3349 | Lb1 | 1510 | La-2-3349 | Lb20 |
| 1511 | La-2-3449 | Lb1 | 1512 | La-2-3449 | Lb20 |
| 1513 | La-2-3450 | Lb1 | 1514 | La-2-3450 | Lb20 |
| 1515 | La-2-3451 | Lb1 | 1516 | La-2-3451 | Lb20 |
| 1517 | La-2-3452 | Lb1 | 1518 | La-2-3452 | Lb20 |
| 1519 | La-2-3453 | Lb1 | 1520 | La-2-3453 | Lb20 |
| 1521 | La-2-3523 | Lb1 | 1522 | La-2-3523 | Lb20 |
| 1523 | La-2-3524 | Lb1 | 1524 | La-2-3524 | Lb20 |
| 1525 | La-2-3657 | Lb1 | 1526 | La-2-3657 | Lb20 |
| 1527 | La-2-3658 | Lb1 | 1528 | La-2-3658 | Lb20 |
| 1529 | La-2-3659 | Lb1 | 1530 | La-2-3659 | Lb20 |
| 1531 | La-2-3660 | Lb1 | 1532 | La-2-3660 | Lb20 |
| 1533 | La-2-3661 | Lb1 | 1534 | La-2-3661 | Lb20 |
| 1535 | La-2-3730 | Lb1 | 1536 | La-2-3730 | Lb20 |
| 1537 | La-1-1 | Lb52 | 1538 | La-1-1 | Lb135 |
| 1539 | La-1-2 | Lb52 | 1540 | La-1-2 | Lb135 |
| 1541 | La-1-3 | Lb52 | 1542 | La-1-3 | Lb135 |
| 1543 | La-2-1 | Lb52 | 1544 | La-2-1 | Lb135 |
| 1545 | La-2-2 | Lb52 | 1546 | La-2-2 | Lb135 |
| 1547 | La-2-3 | Lb52 | 1548 | La-2-3 | Lb135 |
| 1549 | La-1-9 | Lb52 | 1550 | La-1-9 | Lb135 |
| 1551 | La-1-10 | Lb52 | 1552 | La-1-10 | Lb135 |
| 1553 | La-1-11 | Lb52 | 1554 | La-1-11 | Lb135 |
| 1555 | La-2-11 | Lb52 | 1556 | La-2-11 | Lb135 |
| 1557 | La-2-12 | Lb52 | 1558 | La-2-12 | Lb135 |
| 1559 | La-2-13 | Lb52 | 1560 | La-2-13 | Lb135 |
| 1561 | La-1-16 | Lb52 | 1562 | La-1-16 | Lb135 |
| 1563 | La-1-17 | Lb52 | 1564 | La-1-17 | Lb135 |
| 1565 | La-1-18 | Lb52 | 1566 | La-1-18 | Lb135 |
| 1567 | La-1-19 | Lb52 | 1568 | La-1-19 | Lb135 |
| 1569 | La-1-20 | Lb52 | 1570 | La-1-20 | Lb135 |
| 1571 | La-2-16 | Lb52 | 1572 | La-2-16 | Lb135 |
| 1573 | La-2-17 | Lb52 | 1574 | La-2-17 | Lb135 |
| 1575 | La-2-18 | Lb52 | 1576 | La-2-18 | Lb135 |
| 1577 | La-2-19 | Lb52 | 1578 | La-2-19 | Lb135 |
| 1579 | La-2-20 | Lb52 | 1580 | La-2-20 | Lb135 |
| 1581 | La-1-31 | Lb52 | 1582 | La-1-31 | Lb135 |
| 1583 | La-1-32 | Lb52 | 1584 | La-1-32 | Lb135 |
| 1585 | La-1-33 | Lb52 | 1586 | La-1-33 | Lb135 |
| 1587 | La-1-34 | Lb52 | 1588 | La-1-34 | Lb135 |
| 1589 | La-1-35 | Lb52 | 1590 | La-1-35 | Lb135 |
| 1591 | La-2-31 | Lb52 | 1592 | La-2-31 | Lb135 |
| 1593 | La-2-32 | Lb52 | 1594 | La-2-32 | Lb135 |
| 1595 | La-2-33 | Lb52 | 1596 | La-2-33 | Lb135 |
| 1597 | La-2-34 | Lb52 | 1598 | La-2-34 | Lb135 |
| 1599 | La-2-35 | Lb52 | 1600 | La-2-35 | Lb135 |
| 1601 | La-1-90 | Lb52 | 1602 | La-1-90 | Lb135 |
| 1603 | La-1-91 | Lb52 | 1604 | La-1-91 | Lb135 |
| 1605 | La-1-92 | Lb52 | 1606 | La-1-92 | Lb135 |
| 1607 | La-1-93 | Lb52 | 1608 | La-1-93 | Lb135 |
| 1609 | La-1-94 | Lb52 | 1610 | La-1-94 | Lb135 |
| 1611 | La-2-99 | Lb52 | 1612 | La-2-99 | Lb135 |
| 1613 | La-2-100 | Lb52 | 1614 | La-2-100 | Lb135 |
| 1615 | La-2-101 | Lb52 | 1616 | La-2-101 | Lb135 |
| 1617 | La-2-102 | Lb52 | 1618 | La-2-102 | Lb135 |
| 1619 | La-1-104 | Lb52 | 1620 | La-1-104 | Lb135 |
| 1621 | La-1-105 | Lb52 | 1622 | La-1-105 | Lb135 |
| 1623 | La-1-106 | Lb52 | 1624 | La-1-106 | Lb135 |
| 1625 | La-2-104 | Lb52 | 1626 | La-2-104 | Lb135 |
| 1627 | La-2-105 | Lb52 | 1628 | La-2-105 | Lb135 |
| 1629 | La-2-106 | Lb52 | 1630 | La-2-106 | Lb135 |
| 1631 | La-1-109 | Lb52 | 1632 | La-1-109 | Lb135 |
| 1633 | La-1-110 | Lb52 | 1634 | La-1-110 | Lb135 |
| 1635 | La-1-111 | Lb52 | 1636 | La-1-111 | Lb135 |
| 1637 | La-2-110 | Lb52 | 1638 | La-2-110 | Lb135 |
| 1639 | La-2-111 | Lb52 | 1640 | La-2-111 | Lb135 |
| 1641 | La-2-112 | Lb52 | 1642 | La-2-112 | Lb135 |
| 1643 | La-2-113 | Lb52 | 1644 | La-2-113 | Lb135 |
| 1645 | La-1-131 | Lb52 | 1646 | La-1-131 | Lb135 |
| 1647 | La-1-132 | Lb52 | 1648 | La-1-132 | Lb135 |
| 1649 | La-1-133 | Lb52 | 1650 | La-1-133 | Lb135 |
| 1651 | La-1-134 | Lb52 | 1652 | La-1-134 | Lb135 |
| 1653 | La-1-135 | Lb52 | 1654 | La-1-135 | Lb135 |
| 1655 | La-1-136 | Lb52 | 1656 | La-1-136 | Lb135 |
| 1657 | La-1-137 | Lb52 | 1658 | La-1-137 | Lb135 |
| 1659 | La-1-138 | Lb52 | 1660 | La-1-138 | Lb135 |
| 1661 | La-1-139 | Lb52 | 1662 | La-1-139 | Lb135 |
| 1663 | La-1-140 | Lb52 | 1664 | La-1-140 | Lb135 |
| 1665 | La-2-134 | Lb52 | 1666 | La-2-134 | Lb135 |
| 1667 | La-2-135 | Lb52 | 1668 | La-2-135 | Lb135 |
| 1669 | La-2-136 | Lb52 | 1670 | La-2-136 | Lb135 |
| 1671 | La-2-137 | Lb52 | 1672 | La-2-137 | Lb135 |
| 1673 | La-2-138 | Lb52 | 1674 | La-2-138 | Lb135 |
| 1675 | La-2-139 | Lb52 | 1676 | La-2-139 | Lb135 |
| 1677 | La-1-208 | Lb52 | 1678 | La-1-208 | Lb135 |
| 1679 | La-1-209 | Lb52 | 1680 | La-1-209 | Lb135 |
| 1681 | La-1-210 | Lb52 | 1682 | La-1-210 | Lb135 |
| 1683 | La-1-211 | Lb52 | 1684 | La-1-211 | Lb135 |
| 1685 | La-2-208 | Lb52 | 1686 | La-2-208 | Lb135 |
| 1687 | La-2-209 | Lb52 | 1688 | La-2-209 | Lb135 |
| 1689 | La-1-219 | Lb52 | 1690 | La-1-219 | Lb135 |
| 1691 | La-1-220 | Lb52 | 1692 | La-1-220 | Lb135 |
| 1693 | La-2-227 | Lb52 | 1694 | La-2-227 | Lb135 |
| 1695 | La-2-228 | Lb52 | 1696 | La-2-228 | Lb135 |
| 1697 | La-2-229 | Lb52 | 1698 | La-2-229 | Lb135 |
| 1699 | La-2-230 | Lb52 | 1700 | La-2-230 | Lb135 |
| 1701 | La-1-238 | Lb52 | 1702 | La-1-238 | Lb135 |
| 1703 | La-1-239 | Lb52 | 1704 | La-1-239 | Lb135 |
| 1705 | La-1-240 | Lb52 | 1706 | La-1-240 | Lb135 |
| 1707 | La-1-241 | Lb52 | 1708 | La-1-241 | Lb135 |
| 1709 | La-1-242 | Lb52 | 1710 | La-1-242 | Lb135 |
| 1711 | La-1-243 | Lb52 | 1712 | La-1-243 | Lb135 |
| 1713 | La-2-238 | Lb52 | 1714 | La-2-238 | Lb135 |
| 1715 | La-2-239 | Lb52 | 1716 | La-2-239 | Lb135 |
| 1717 | La-2-240 | Lb52 | 1718 | La-2-240 | Lb135 |
| 1719 | La-2-241 | Lb52 | 1720 | La-2-241 | Lb135 |
| 1721 | La-2-242 | Lb52 | 1722 | La-2-242 | Lb135 |
| 1723 | La-2-243 | Lb52 | 1724 | La-2-243 | Lb135 |
| 1725 | La-1-254 | Lb52 | 1726 | La-1-254 | Lb135 |
| 1727 | La-1-255 | Lb52 | 1728 | La-1-255 | Lb135 |
| 1729 | La-1-313 | Lb52 | 1730 | La-1-313 | Lb135 |
| 1731 | La-1-314 | Lb52 | 1732 | La-1-314 | Lb135 |
| 1733 | La-2-313 | Lb52 | 1734 | La-2-313 | Lb135 |
| 1735 | La-2-314 | Lb52 | 1736 | La-2-314 | Lb135 |
| 1737 | La-1-343 | Lb52 | 1738 | La-1-343 | Lb135 |
| 1739 | La-1-344 | Lb52 | 1740 | La-1-344 | Lb135 |
| 1741 | La-1-345 | Lb52 | 1742 | La-1-345 | Lb135 |
| 1743 | La-1-346 | Lb52 | 1744 | La-1-346 | Lb135 |
| 1745 | La-1-347 | Lb52 | 1746 | La-1-347 | Lb135 |
| 1747 | La-2-343 | Lb52 | 1748 | La-2-343 | Lb135 |
| 1749 | La-2-344 | Lb52 | 1750 | La-2-344 | Lb135 |
| 1751 | La-2-345 | Lb52 | 1752 | La-2-345 | Lb135 |
| 1753 | La-2-346 | Lb52 | 1754 | La-2-346 | Lb135 |
| 1755 | La-2-347 | Lb52 | 1756 | La-2-347 | Lb135 |
| 1757 | La-1-417 | Lb52 | 1758 | La-1-417 | Lb135 |
| 1759 | La-1-418 | Lb52 | 1760 | La-1-418 | Lb135 |
| 1761 | La-1-419 | Lb52 | 1762 | La-1-419 | Lb135 |
| 1763 | La-1-420 | Lb52 | 1764 | La-1-420 | Lb135 |
| 1765 | La-2-417 | Lb52 | 1766 | La-2-417 | Lb135 |
| 1767 | La-2-418 | Lb52 | 1768 | La-2-418 | Lb135 |
| 1769 | La-2-419 | Lb52 | 1770 | La-2-419 | Lb135 |
| 1771 | La-2-420 | Lb52 | 1772 | La-2-420 | Lb135 |
| 1773 | La-1-447 | Lb52 | 1774 | La-1-447 | Lb135 |
| 1775 | La-1-448 | Lb52 | 1776 | La-1-448 | Lb135 |
| 1777 | La-1-449 | Lb52 | 1778 | La-1-449 | Lb135 |
| 1779 | La-1-450 | Lb52 | 1780 | La-1-450 | Lb135 |
| 1781 | La-1-451 | Lb52 | 1782 | La-1-451 | Lb135 |
| 1783 | La-2-447 | Lb52 | 1784 | La-2-447 | Lb135 |
| 1785 | La-2-448 | Lb52 | 1786 | La-2-448 | Lb135 |
| 1787 | La-2-449 | Lb52 | 1788 | La-2-449 | Lb135 |
| 1789 | La-2-450 | Lb52 | 1790 | La-2-450 | Lb135 |
| 1791 | La-2-451 | Lb52 | 1792 | La-2-451 | Lb135 |
| 1793 | La-1-467 | Lb52 | 1794 | La-1-467 | Lb135 |
| 1795 | La-1-468 | Lb52 | 1796 | La-1-468 | Lb135 |
| 1797 | La-1-469 | Lb52 | 1798 | La-1-469 | Lb135 |
| 1799 | La-2-495 | Lb52 | 1800 | La-2-495 | Lb135 |
| 1801 | La-2-496 | Lb52 | 1802 | La-2-496 | Lb135 |
| 1803 | La-2-497 | Lb52 | 1804 | La-2-497 | Lb135 |
| 1805 | La-1-521 | Lb52 | 1806 | La-1-521 | Lb135 |
| 1807 | La-1-522 | Lb52 | 1808 | La-1-522 | Lb135 |
| 1809 | La-2-521 | Lb52 | 1810 | La-2-521 | Lb135 |
| 1811 | La-2-522 | Lb52 | 1812 | La-2-522 | Lb135 |
| 1813 | La-1-551 | Lb52 | 1814 | La-1-551 | Lb135 |
| 1815 | La-1-552 | Lb52 | 1816 | La-1-552 | Lb135 |
| 1817 | La-1-553 | Lb52 | 1818 | La-1-553 | Lb135 |
| 1819 | La-1-554 | Lb52 | 1820 | La-1-554 | Lb135 |
| 1821 | La-1-555 | Lb52 | 1822 | La-1-555 | Lb135 |
| 1823 | La-2-551 | Lb52 | 1824 | La-2-551 | Lb135 |
| 1825 | La-2-552 | Lb52 | 1826 | La-2-552 | Lb135 |
| 1827 | La-2-553 | Lb52 | 1828 | La-2-553 | Lb135 |
| 1829 | La-2-554 | Lb52 | 1830 | La-2-554 | Lb135 |
| 1831 | La-2-555 | Lb52 | 1832 | La-2-555 | Lb135 |
| 1833 | La-1-559 | Lb52 | 1834 | La-1-559 | Lb135 |
| 1835 | La-1-560 | Lb52 | 1836 | La-1-560 | Lb135 |
| 1837 | La-1-561 | Lb52 | 1838 | La-1-561 | Lb135 |
| 1839 | La-2-569 | Lb52 | 1840 | La-2-569 | Lb135 |
| 1841 | La-2-570 | Lb52 | 1842 | La-2-570 | Lb135 |
| 1843 | La-1-625 | Lb52 | 1844 | La-1-625 | Lb135 |
| 1845 | La-1-626 | Lb52 | 1846 | La-1-626 | Lb135 |
| 1847 | La-2-625 | Lb52 | 1848 | La-2-625 | Lb135 |
| 1849 | La-2-626 | Lb52 | 1850 | La-2-626 | Lb135 |
| 1851 | La-1-655 | Lb52 | 1852 | La-1-655 | Lb135 |
| 1853 | La-1-656 | Lb52 | 1854 | La-1-656 | Lb135 |
| 1855 | La-1-657 | Lb52 | 1856 | La-1-657 | Lb135 |
| 1857 | La-1-658 | Lb52 | 1858 | La-1-658 | Lb135 |
| 1859 | La-1-659 | Lb52 | 1860 | La-1-659 | Lb135 |
| 1861 | La-2-655 | Lb52 | 1862 | La-2-655 | Lb135 |
| 1863 | La-2-656 | Lb52 | 1864 | La-2-656 | Lb135 |
| 1865 | La-2-657 | Lb52 | 1866 | La-2-657 | Lb135 |
| 1867 | La-2-658 | Lb52 | 1868 | La-2-658 | Lb135 |
| 1869 | La-2-659 | Lb52 | 1870 | La-2-659 | Lb135 |
| 1871 | La-1-663 | Lb52 | 1872 | La-1-663 | Lb135 |
| 1873 | La-1-664 | Lb52 | 1874 | La-1-664 | Lb135 |
| 1875 | La-2-669 | Lb52 | 1876 | La-2-669 | Lb135 |
| 1877 | La-2-670 | Lb52 | 1878 | La-2-670 | Lb135 |
| 1879 | La-1-833 | Lb52 | 1880 | La-1-833 | Lb135 |
| 1881 | La-1-834 | Lb52 | 1882 | La-1-834 | Lb135 |
| 1883 | La-2-833 | Lb52 | 1884 | La-2-833 | Lb135 |
| 1885 | La-2-834 | Lb52 | 1886 | La-2-834 | Lb135 |
| 1887 | La-1-863 | Lb52 | 1888 | La-1-863 | Lb135 |
| 1889 | La-1-864 | Lb52 | 1890 | La-1-864 | Lb135 |
| 1891 | La-1-865 | Lb52 | 1892 | La-1-865 | Lb135 |
| 1893 | La-1-866 | Lb52 | 1894 | La-1-866 | Lb135 |
| 1895 | La-1-867 | Lb52 | 1896 | La-1-867 | Lb135 |
| 1897 | La-2-863 | Lb52 | 1898 | La-2-863 | Lb135 |
| 1899 | La-2-864 | Lb52 | 1900 | La-2-864 | Lb135 |
| 1901 | La-2-865 | Lb52 | 1902 | La-2-865 | Lb135 |
| 1903 | La-2-866 | Lb52 | 1904 | La-2-866 | Lb135 |
| 1905 | La-2-867 | Lb52 | 1906 | La-2-867 | Lb135 |
| 1907 | La-2-871 | Lb52 | 1908 | La-2-871 | Lb135 |
| 1909 | La-2-872 | Lb52 | 1910 | La-2-872 | Lb135 |
| 1911 | La-2-873 | Lb52 | 1912 | La-2-873 | Lb135 |
| 1913 | La-2-874 | Lb52 | 1914 | La-2-874 | Lb135 |
| 1915 | La-2-875 | Lb52 | 1916 | La-2-875 | Lb135 |
| 1917 | La-1-881 | Lb52 | 1918 | La-1-881 | Lb135 |
| 1919 | La-1-882 | Lb52 | 1920 | La-1-882 | Lb135 |
| 1921 | La-1-883 | Lb52 | 1922 | La-1-883 | Lb135 |
| 1923 | La-1-884 | Lb52 | 1924 | La-1-884 | Lb135 |
| 1925 | La-2-886 | Lb52 | 1926 | La-2-886 | Lb135 |
| 1927 | La-2-887 | Lb52 | 1928 | La-2-887 | Lb135 |
| 1929 | La-2-888 | Lb52 | 1930 | La-2-888 | Lb135 |
| 1931 | La-1-936 | Lb52 | 1932 | La-1-936 | Lb135 |
| 1933 | La-1-937 | Lb52 | 1934 | La-1-937 | Lb135 |
| 1935 | La-2-936 | Lb52 | 1936 | La-2-936 | Lb135 |
| 1937 | La-2-937 | Lb52 | 1938 | La-2-937 | Lb135 |
| 1939 | La-1-967 | Lb52 | 1940 | La-1-967 | Lb135 |
| 1941 | La-1-968 | Lb52 | 1942 | La-1-968 | Lb135 |
| 1943 | La-1-969 | Lb52 | 1944 | La-1-969 | Lb135 |
| 1945 | La-1-970 | Lb52 | 1946 | La-1-970 | Lb135 |
| 1947 | La-2-978 | Lb52 | 1948 | La-2-978 | Lb135 |
| 1949 | La-2-979 | Lb52 | 1950 | La-2-979 | Lb135 |
| 1951 | La-2-980 | Lb52 | 1952 | La-2-980 | Lb135 |
| 1953 | La-1-1041 | Lb52 | 1954 | La-1-1041 | Lb135 |
| 1955 | La-1-1042 | Lb52 | 1956 | La-1-1042 | Lb135 |
| 1957 | La-2-1041 | Lb52 | 1958 | La-2-1041 | Lb135 |
| 1959 | La-2-1042 | Lb52 | 1960 | La-2-1042 | Lb135 |
| 1961 | La-1-1071 | Lb52 | 1962 | La-1-1071 | Lb135 |
| 1963 | La-1-1072 | Lb52 | 1964 | La-1-1072 | Lb135 |
| 1965 | La-1-1073 | Lb52 | 1966 | La-1-1073 | Lb135 |
| 1967 | La-1-1074 | Lb52 | 1968 | La-1-1074 | Lb135 |
| 1969 | La-2-1071 | Lb52 | 1970 | La-2-1071 | Lb135 |
| 1971 | La-2-1072 | Lb52 | 1972 | La-2-1072 | Lb135 |
| 1973 | La-2-1073 | Lb52 | 1974 | La-2-1073 | Lb135 |
| 1975 | La-2-1074 | Lb52 | 1976 | La-2-1074 | Lb135 |
| 1977 | La-1-1145 | Lb52 | 1978 | La-1-1145 | Lb135 |
| 1979 | La-1-1146 | Lb52 | 1980 | La-1-1146 | Lb135 |
| 1981 | La-2-1145 | Lb52 | 1982 | La-2-1145 | Lb135 |
| 1983 | La-2-1146 | Lb52 | 1984 | La-2-1146 | Lb135 |
| 1985 | La-1-1174 | Lb52 | 1986 | La-1-1174 | Lb135 |
| 1987 | La-1-1175 | Lb52 | 1988 | La-1-1175 | Lb135 |
| 1989 | La-1-1176 | Lb52 | 1990 | La-1-1176 | Lb135 |
| 1991 | La-1-1177 | Lb52 | 1992 | La-1-1177 | Lb135 |
| 1993 | La-1-1178 | Lb52 | 1994 | La-1-1178 | Lb135 |
| 1995 | La-2-1174 | Lb52 | 1996 | La-2-1174 | Lb135 |
| 1997 | La-2-1175 | Lb52 | 1998 | La-2-1175 | Lb135 |
| 1999 | La-2-1176 | Lb52 | 2000 | La-2-1176 | Lb135 |
| 2001 | La-2-1177 | Lb52 | 2002 | La-2-1177 | Lb135 |
| 2003 | La-2-1178 | Lb52 | 2004 | La-2-1178 | Lb135 |
| 2005 | La-1-1249 | Lb52 | 2006 | La-1-1249 | Lb135 |
| 2007 | La-1-1250 | Lb52 | 2008 | La-1-1250 | Lb135 |
| 2009 | La-2-1249 | Lb52 | 2010 | La-2-1249 | Lb135 |
| 2011 | La-2-1250 | Lb52 | 2012 | La-2-1250 | Lb135 |
| 2013 | La-1-1256 | Lb52 | 2014 | La-1-1256 | Lb135 |
| 2015 | La-1-1260 | Lb52 | 2016 | La-1-1260 | Lb135 |
| 2017 | La-1-1261 | Lb52 | 2018 | La-1-1261 | Lb135 |
| 2019 | La-1-1262 | Lb52 | 2020 | La-1-1262 | Lb135 |
| 2021 | La-1-1266 | Lb52 | 2022 | La-1-1266 | Lb135 |
| 2023 | La-2-1256 | Lb52 | 2024 | La-2-1256 | Lb135 |
| 2025 | La-2-1260 | Lb52 | 2026 | La-2-1260 | Lb135 |
| 2027 | La-2-1261 | Lb52 | 2028 | La-2-1261 | Lb135 |
| 2029 | La-2-1262 | Lb52 | 2030 | La-2-1262 | Lb135 |
| 2031 | La-2-1266 | Lb52 | 2032 | La-2-1266 | Lb135 |
| 2033 | La-1-1279 | Lb52 | 2034 | La-1-1279 | Lb135 |
| 2035 | La-1-1280 | Lb52 | 2036 | La-1-1280 | Lb135 |
| 2037 | La-1-1281 | Lb52 | 2038 | La-1-1281 | Lb135 |
| 2039 | La-1-1282 | Lb52 | 2040 | La-1-1282 | Lb135 |
| 2041 | La-1-1283 | Lb52 | 2042 | La-1-1283 | Lb135 |
| 2043 | La-2-1279 | Lb52 | 2044 | La-2-1279 | Lb135 |
| 2045 | La-2-1280 | Lb52 | 2046 | La-2-1280 | Lb135 |
| 2047 | La-2-1281 | Lb52 | 2048 | La-2-1281 | Lb135 |
| 2049 | La-2-1282 | Lb52 | 2050 | La-2-1282 | Lb135 |
| 2051 | La-2-1283 | Lb52 | 2052 | La-2-1283 | Lb135 |
| 2053 | La-1-1287 | Lb52 | 2054 | La-1-1287 | Lb135 |
| 2055 | La-1-1288 | Lb52 | 2056 | La-1-1288 | Lb135 |
| 2057 | La-1-1289 | Lb52 | 2058 | La-1-1289 | Lb135 |
| 2059 | La-2-1287 | Lb52 | 2060 | La-2-1287 | Lb135 |
| 2061 | La-2-1288 | Lb52 | 2062 | La-2-1288 | Lb135 |
| 2063 | La-2-1289 | Lb52 | 2064 | La-2-1289 | Lb135 |
| 2065 | La-1-1297 | Lb52 | 2066 | La-1-1297 | Lb135 |
| 2067 | La-1-1298 | Lb52 | 2068 | La-1-1298 | Lb135 |
| 2069 | La-1-1299 | Lb52 | 2070 | La-1-1299 | Lb135 |
| 2071 | La-1-1300 | Lb52 | 2072 | La-1-1300 | Lb135 |
| 2073 | La-1-1301 | Lb52 | 2074 | La-1-1301 | Lb135 |
| 2075 | La-1-1302 | Lb52 | 2076 | La-1-1302 | Lb135 |
| 2077 | La-2-1299 | Lb52 | 2078 | La-2-1299 | Lb135 |
| 2079 | La-2-1300 | Lb52 | 2080 | La-2-1300 | Lb135 |
| 2081 | La-2-1301 | Lb52 | 2082 | La-2-1301 | Lb135 |
| 2083 | La-2-1302 | Lb52 | 2084 | La-2-1302 | Lb135 |
| 2085 | La-1-1313 | Lb52 | 2086 | La-1-1313 | Lb135 |
| 2087 | La-1-1314 | Lb52 | 2088 | La-1-1314 | Lb135 |
| 2089 | La-1-1315 | Lb52 | 2090 | La-1-1315 | Lb135 |
| 2091 | La-2-1320 | Lb52 | 2092 | La-2-1320 | Lb135 |
| 2093 | La-2-1321 | Lb52 | 2094 | La-2-1321 | Lb135 |
| 2095 | La-2-1322 | Lb52 | 2096 | La-2-1322 | Lb135 |
| 2097 | La-2-1323 | Lb52 | 2098 | La-2-1323 | Lb135 |
| 2099 | La-2-1324 | Lb52 | 2100 | La-2-1324 | Lb135 |
| 2101 | La-1-1329 | Lb52 | 2102 | La-1-1329 | Lb135 |
| 2103 | La-1-1330 | Lb52 | 2104 | La-1-1330 | Lb135 |
| 2105 | La-1-1331 | Lb52 | 2106 | La-1-1331 | Lb135 |
| 2107 | La-2-1339 | Lb52 | 2108 | La-2-1339 | Lb135 |
| 2109 | La-2-1340 | Lb52 | 2110 | La-2-1340 | Lb135 |
| 2111 | La-2-1341 | Lb52 | 2112 | La-2-1341 | Lb135 |
| 2113 | La-2-1342 | Lb52 | 2114 | La-2-1342 | Lb135 |
| 2115 | La-2-1343 | Lb52 | 2116 | La-2-1343 | Lb135 |
| 2117 | La-1-1353 | Lb52 | 2118 | La-1-1353 | Lb135 |
| 2119 | La-1-1354 | Lb52 | 2120 | La-1-1354 | Lb135 |
| 2121 | La-2-1353 | Lb52 | 2122 | La-2-1353 | Lb135 |
| 2123 | La-2-1354 | Lb52 | 2124 | La-2-1354 | Lb135 |
| 2125 | La-1-1383 | Lb52 | 2126 | La-1-1383 | Lb135 |
| 2127 | La-1-1384 | Lb52 | 2128 | La-1-1384 | Lb135 |
| 2129 | La-1-1385 | Lb52 | 2130 | La-1-1385 | Lb135 |
| 2131 | La-1-1386 | Lb52 | 2132 | La-1-1386 | Lb135 |
| 2133 | La-1-1387 | Lb52 | 2134 | La-1-1387 | Lb135 |
| 2135 | La-2-1383 | Lb52 | 2136 | La-2-1383 | Lb135 |
| 2137 | La-2-1384 | Lb52 | 2138 | La-2-1384 | Lb135 |
| 2139 | La-2-1385 | Lb52 | 2140 | La-2-1385 | Lb135 |
| 2141 | La-2-1386 | Lb52 | 2142 | La-2-1386 | Lb135 |
| 2143 | La-2-1387 | Lb52 | 2144 | La-2-1387 | Lb135 |
| 2145 | La-1-1408 | Lb52 | 2146 | La-1-1408 | Lb135 |
| 2147 | La-1-1409 | Lb52 | 2148 | La-1-1409 | Lb135 |
| 2149 | La-1-1410 | Lb52 | 2150 | La-1-1410 | Lb135 |
| 2151 | La-1-1411 | Lb52 | 2152 | La-1-1411 | Lb135 |
| 2153 | La-2-1412 | Lb52 | 2154 | La-2-1412 | Lb135 |
| 2155 | La-2-1413 | Lb52 | 2156 | La-2-1413 | Lb135 |
| 2157 | La-2-1414 | Lb52 | 2158 | La-2-1414 | Lb135 |
| 2159 | La-2-1415 | Lb52 | 2160 | La-2-1415 | Lb135 |
| 2161 | La-2-1416 | Lb52 | 2162 | La-2-1416 | Lb135 |
| 2163 | La-2-1417 | Lb52 | 2164 | La-2-1417 | Lb135 |
| 2165 | La-1-1456 | Lb52 | 2166 | La-1-1456 | Lb135 |
| 2167 | La-1-1457 | Lb52 | 2168 | La-1-1457 | Lb135 |
| 2169 | La-1-1458 | Lb52 | 2170 | La-1-1458 | Lb135 |
| 2171 | La-2-1457 | Lb52 | 2172 | La-2-1457 | Lb135 |
| 2173 | La-2-1458 | Lb52 | 2174 | La-2-1458 | Lb135 |
| 2175 | La-1-1487 | Lb52 | 2176 | La-1-1487 | Lb135 |
| 2177 | La-1-1488 | Lb52 | 2178 | La-1-1488 | Lb135 |
| 2179 | La-1-1489 | Lb52 | 2180 | La-1-1489 | Lb135 |
| 2181 | La-1-1490 | Lb52 | 2182 | La-1-1490 | Lb135 |
| 2183 | La-1-1491 | Lb52 | 2184 | La-1-1491 | Lb135 |
| 2185 | La-2-1487 | Lb52 | 2186 | La-2-1487 | Lb135 |
| 2187 | La-2-1488 | Lb52 | 2188 | La-2-1488 | Lb135 |
| 2189 | La-2-1489 | Lb52 | 2190 | La-2-1489 | Lb135 |
| 2191 | La-2-1490 | Lb52 | 2192 | La-2-1490 | Lb135 |
| 2193 | La-2-1491 | Lb52 | 2194 | La-2-1491 | Lb135 |
| 2195 | La-1-1496 | Lb52 | 2196 | La-1-1496 | Lb135 |
| 2197 | La-1-1497 | Lb52 | 2198 | La-1-1497 | Lb135 |
| 2199 | La-1-1498 | Lb52 | 2200 | La-1-1498 | Lb135 |
| 2201 | La-1-1499 | Lb52 | 2202 | La-1-1499 | Lb135 |
| 2203 | La-1-1500 | Lb52 | 2204 | La-1-1500 | Lb135 |
| 2205 | La-1-1501 | Lb52 | 2206 | La-1-1501 | Lb135 |
| 2207 | La-2-1513 | Lb52 | 2208 | La-2-1513 | Lb135 |
| 2209 | La-2-1514 | Lb52 | 2210 | La-2-1514 | Lb135 |
| 2211 | La-2-1515 | Lb52 | 2212 | La-2-1515 | Lb135 |
| 2213 | La-2-1516 | Lb52 | 2214 | La-2-1516 | Lb135 |
| 2215 | La-2-1517 | Lb52 | 2216 | La-2-1517 | Lb135 |
| 2217 | La-2-1518 | Lb52 | 2218 | La-2-1518 | Lb135 |
| 2219 | La-1-1521 | Lb52 | 2220 | La-1-1521 | Lb135 |
| 2221 | La-1-1522 | Lb52 | 2222 | La-1-1522 | Lb135 |
| 2223 | La-1-1523 | Lb52 | 2224 | La-1-1523 | Lb135 |
| 2225 | La-1-1524 | Lb52 | 2226 | La-1-1524 | Lb135 |
| 2227 | La-1-1525 | Lb52 | 2228 | La-1-1525 | Lb135 |
| 2229 | La-1-1526 | Lb52 | 2230 | La-1-1526 | Lb135 |
| 2231 | La-1-1527 | Lb52 | 2232 | La-1-1527 | Lb135 |
| 2233 | La-1-1536 | Lb52 | 2234 | La-1-1536 | Lb135 |
| 2235 | La-1-1537 | Lb52 | 2236 | La-1-1537 | Lb135 |
| 2237 | La-2-1544 | Lb52 | 2238 | La-2-1544 | Lb135 |
| 2239 | La-2-1545 | Lb52 | 2240 | La-2-1545 | Lb135 |
| 2241 | La-2-1546 | Lb52 | 2242 | La-2-1546 | Lb135 |
| 2243 | La-1-1556 | Lb52 | 2244 | La-1-1556 | Lb135 |
| 2245 | La-1-1557 | Lb52 | 2246 | La-1-1557 | Lb135 |
| 2247 | La-2-1558 | Lb52 | 2248 | La-2-1558 | Lb135 |
| 2249 | La-2-1559 | Lb52 | 2250 | La-2-1559 | Lb135 |
| 2251 | La-1-1561 | Lb52 | 2252 | La-1-1561 | Lb135 |
| 2253 | La-1-1562 | Lb52 | 2254 | La-1-1562 | Lb135 |
| 2255 | La-2-1561 | Lb52 | 2256 | La-2-1561 | Lb135 |
| 2257 | La-2-1562 | Lb52 | 2258 | La-2-1562 | Lb135 |
| 2259 | La-1-1591 | Lb52 | 2260 | La-1-1591 | Lb135 |
| 2261 | La-1-1592 | Lb52 | 2262 | La-1-1592 | Lb135 |
| 2263 | La-1-1593 | Lb52 | 2264 | La-1-1593 | Lb135 |
| 2265 | La-1-1594 | Lb52 | 2266 | La-1-1594 | Lb135 |
| 2267 | La-1-1595 | Lb52 | 2268 | La-1-1595 | Lb135 |
| 2269 | La-2-1591 | Lb52 | 2270 | La-2-1591 | Lb135 |
| 2271 | La-2-1592 | Lb52 | 2272 | La-2-1592 | Lb135 |
| 2273 | La-2-1593 | Lb52 | 2274 | La-2-1593 | Lb135 |
| 2275 | La-2-1594 | Lb52 | 2276 | La-2-1594 | Lb135 |
| 2277 | La-2-1595 | Lb52 | 2278 | La-2-1595 | Lb135 |
| 2279 | La-1-1641 | Lb52 | 2280 | La-1-1641 | Lb135 |
| 2281 | La-1-1642 | Lb52 | 2282 | La-1-1642 | Lb135 |
| 2283 | La-2-1654 | Lb52 | 2284 | La-2-1654 | Lb135 |
| 2285 | La-2-1655 | Lb52 | 2286 | La-2-1655 | Lb135 |
| 2287 | La-2-1656 | Lb52 | 2288 | La-2-1656 | Lb135 |
| 2289 | La-1-1665 | Lb52 | 2290 | La-1-1665 | Lb135 |
| 2291 | La-1-1666 | Lb52 | 2292 | La-1-1666 | Lb135 |
| 2293 | La-2-1665 | Lb52 | 2294 | La-2-1665 | Lb135 |
| 2295 | La-2-1666 | Lb52 | 2296 | La-2-1666 | Lb135 |
| 2297 | La-1-1695 | Lb52 | 2298 | La-1-1695 | Lb135 |
| 2299 | La-1-1696 | Lb52 | 2300 | La-1-1696 | Lb135 |
| 2301 | La-1-1697 | Lb52 | 2302 | La-1-1697 | Lb135 |
| 2303 | La-1-1698 | Lb52 | 2304 | La-1-1698 | Lb135 |
| 2305 | La-1-1699 | Lb52 | 2306 | La-1-1699 | Lb135 |
| 2307 | La-2-1695 | Lb52 | 2308 | La-2-1695 | Lb135 |
| 2309 | La-2-1696 | Lb52 | 2310 | La-2-1696 | Lb135 |
| 2311 | La-2-1697 | Lb52 | 2312 | La-2-1697 | Lb135 |
| 2313 | La-2-1698 | Lb52 | 2314 | La-2-1698 | Lb135 |
| 2315 | La-2-1699 | Lb52 | 2316 | La-2-1699 | Lb135 |
| 2317 | La-1-1769 | Lb52 | 2318 | La-1-1769 | Lb135 |
| 2319 | La-1-1770 | Lb52 | 2320 | La-1-1770 | Lb135 |
| 2321 | La-2-1769 | Lb52 | 2322 | La-2-1769 | Lb135 |
| 2323 | La-2-1770 | Lb52 | 2324 | La-2-1770 | Lb135 |
| 2325 | La-1-1799 | Lb52 | 2326 | La-1-1799 | Lb135 |
| 2327 | La-1-1800 | Lb52 | 2328 | La-1-1800 | Lb135 |
| 2329 | La-1-1801 | Lb52 | 2330 | La-1-1801 | Lb135 |
| 2331 | La-1-1802 | Lb52 | 2332 | La-1-1802 | Lb135 |
| 2333 | La-1-1803 | Lb52 | 2334 | La-1-1803 | Lb135 |
| 2335 | La-1-1828 | Lb52 | 2336 | La-1-1828 | Lb135 |
| 2337 | La-1-1829 | Lb52 | 2338 | La-1-1829 | Lb135 |
| 2339 | La-1-1872 | Lb52 | 2340 | La-1-1872 | Lb135 |
| 2341 | La-1-1873 | Lb52 | 2342 | La-1-1873 | Lb135 |
| 2343 | La-1-1874 | Lb52 | 2344 | La-1-1874 | Lb135 |
| 2345 | La-1-1903 | Lb52 | 2346 | La-1-1903 | Lb135 |
| 2347 | La-1-1904 | Lb52 | 2348 | La-1-1904 | Lb135 |
| 2349 | La-1-1905 | Lb52 | 2350 | La-1-1905 | Lb135 |
| 2351 | La-1-1906 | Lb52 | 2352 | La-1-1906 | Lb135 |
| 2353 | La-1-1907 | Lb52 | 2354 | La-1-1907 | Lb135 |
| 2355 | La-1-1977 | Lb52 | 2356 | La-1-1977 | Lb135 |
| 2357 | La-1-1978 | Lb52 | 2358 | La-1-1978 | Lb135 |
| 2359 | La-1-2007 | Lb52 | 2360 | La-1-2007 | Lb135 |
| 2361 | La-1-2008 | Lb52 | 2362 | La-1-2008 | Lb135 |
| 2363 | La-1-2009 | Lb52 | 2364 | La-1-2009 | Lb135 |
| 2365 | La-1-2010 | Lb52 | 2366 | La-1-2010 | Lb135 |
| 2367 | La-1-2011 | Lb52 | 2368 | La-1-2011 | Lb135 |
| 2369 | La-1-2036 | Lb52 | 2370 | La-1-2036 | Lb135 |
| 2371 | La-1-2037 | Lb52 | 2372 | La-1-2037 | Lb135 |
| 2373 | La-1-2038 | Lb52 | 2374 | La-1-2038 | Lb135 |
| 2375 | La-1-2080 | Lb52 | 2376 | La-1-2080 | Lb135 |
| 2377 | La-1-2081 | Lb52 | 2378 | La-1-2081 | Lb135 |
| 2379 | La-1-2111 | Lb52 | 2380 | La-1-2111 | Lb135 |
| 2381 | La-1-2112 | Lb52 | 2382 | La-1-2112 | Lb135 |
| 2383 | La-1-2113 | Lb52 | 2384 | La-1-2113 | Lb135 |
| 2385 | La-1-2114 | Lb52 | 2386 | La-1-2114 | Lb135 |
| 2387 | La-1-2115 | Lb52 | 2388 | La-1-2115 | Lb135 |
| 2389 | La-1-2185 | Lb52 | 2390 | La-1-2185 | Lb135 |
| 2391 | La-1-2186 | Lb52 | 2392 | La-1-2186 | Lb135 |
| 2393 | La-1-2215 | Lb52 | 2394 | La-1-2215 | Lb135 |
| 2395 | La-1-2216 | Lb52 | 2396 | La-1-2216 | Lb135 |
| 2397 | La-1-2217 | Lb52 | 2398 | La-1-2217 | Lb135 |
| 2399 | La-1-2218 | Lb52 | 2400 | La-1-2218 | Lb135 |
| 2401 | La-1-2219 | Lb52 | 2402 | La-1-2219 | Lb135 |
| 2403 | La-1-2234 | Lb52 | 2404 | La-1-2234 | Lb135 |
| 2405 | La-1-2235 | Lb52 | 2406 | La-1-2235 | Lb135 |
| 2407 | La-1-2236 | Lb52 | 2408 | La-1-2236 | Lb135 |
| 2409 | La-1-2237 | Lb52 | 2410 | La-1-2237 | Lb135 |
| 2411 | La-1-2238 | Lb52 | 2412 | La-1-2238 | Lb135 |
| 2413 | La-1-2289 | Lb52 | 2414 | La-1-2289 | Lb135 |
| 2415 | La-1-2290 | Lb52 | 2416 | La-1-2290 | Lb135 |
| 2417 | La-1-2319 | Lb52 | 2418 | La-1-2319 | Lb135 |
| 2419 | La-1-2320 | Lb52 | 2420 | La-1-2320 | Lb135 |
| 2421 | La-1-2321 | Lb52 | 2422 | La-1-2321 | Lb135 |
| 2423 | La-1-2322 | Lb52 | 2424 | La-1-2322 | Lb135 |
| 2425 | La-1-2323 | Lb52 | 2426 | La-1-2323 | Lb135 |
| 2427 | La-1-2393 | Lb52 | 2428 | La-1-2393 | Lb135 |
| 2429 | La-1-2394 | Lb52 | 2430 | La-1-2394 | Lb135 |
| 2431 | La-1-2423 | Lb52 | 2432 | La-1-2423 | Lb135 |
| 2433 | La-1-2424 | Lb52 | 2434 | La-1-2424 | Lb135 |
| 2435 | La-1-2425 | Lb52 | 2436 | La-1-2425 | Lb135 |
| 2437 | La-1-2426 | Lb52 | 2438 | La-1-2426 | Lb135 |
| 2439 | La-1-2427 | Lb52 | 2440 | La-1-2427 | Lb135 |
| 2441 | La-1-2497 | Lb52 | 2442 | La-1-2497 | Lb135 |
| 2443 | La-1-2498 | Lb52 | 2444 | La-1-2498 | Lb135 |
| 2445 | La-1-2527 | Lb52 | 2446 | La-1-2527 | Lb135 |
| 2447 | La-1-2528 | Lb52 | 2448 | La-1-2528 | Lb135 |
| 2449 | La-1-2529 | Lb52 | 2450 | La-1-2529 | Lb135 |
| 2451 | La-1-2530 | Lb52 | 2452 | La-1-2530 | Lb135 |
| 2453 | La-1-2531 | Lb52 | 2454 | La-1-2531 | Lb135 |
| 2455 | La-1-2601 | Lb52 | 2456 | La-1-2601 | Lb135 |
| 2457 | La-1-2602 | Lb52 | 2458 | La-1-2602 | Lb135 |
| 2459 | La-1-2631 | Lb52 | 2460 | La-1-2631 | Lb135 |
| 2461 | La-1-2632 | Lb52 | 2462 | La-1-2632 | Lb135 |
| 2463 | La-1-2633 | Lb52 | 2464 | La-1-2633 | Lb135 |
| 2465 | La-1-2634 | Lb52 | 2466 | La-1-2634 | Lb135 |
| 2467 | La-1-2635 | Lb52 | 2468 | La-1-2635 | Lb135 |
| 2469 | La-1-2705 | Lb52 | 2470 | La-1-2705 | Lb135 |
| 2471 | La-1-2706 | Lb52 | 2472 | La-1-2706 | Lb135 |
| 2473 | La-1-2735 | Lb52 | 2474 | La-1-2735 | Lb135 |
| 2475 | La-1-2736 | Lb52 | 2476 | La-1-2736 | Lb135 |
| 2477 | La-1-2737 | Lb52 | 2478 | La-1-2737 | Lb135 |
| 2479 | La-1-2738 | Lb52 | 2480 | La-1-2738 | Lb135 |
| 2481 | La-1-2739 | Lb52 | 2482 | La-1-2739 | Lb135 |
| 2483 | La-1-2809 | Lb52 | 2484 | La-1-2809 | Lb135 |
| 2485 | La-1-2810 | Lb52 | 2486 | La-1-2810 | Lb135 |
| 2487 | La-1-2839 | Lb52 | 2488 | La-1-2839 | Lb135 |
| 2489 | La-1-2840 | Lb52 | 2490 | La-1-2840 | Lb135 |
| 2491 | La-1-2841 | Lb52 | 2492 | La-1-2841 | Lb135 |
| 2493 | La-1-2842 | Lb52 | 2494 | La-1-2842 | Lb135 |
| 2495 | La-1-2843 | Lb52 | 2496 | La-1-2843 | Lb135 |
| 2497 | La-1-2918 | Lb52 | 2498 | La-1-2918 | Lb135 |
| 2499 | La-1-2919 | Lb52 | 2500 | La-1-2919 | Lb135 |
| 2501 | La-1-2920 | Lb52 | 2502 | La-1-2920 | Lb135 |
| 2503 | La-1-2921 | Lb52 | 2504 | La-1-2921 | Lb135 |
| 2505 | La-1-2922 | Lb52 | 2506 | La-1-2922 | Lb135 |
| 2507 | La-1-2943 | Lb52 | 2508 | La-1-2943 | Lb135 |
| 2509 | La-1-2944 | Lb52 | 2510 | La-1-2944 | Lb135 |
| 2511 | La-1-2928 | Lb52 | 2512 | La-1-2928 | Lb135 |
| 2513 | La-1-2929 | Lb52 | 2514 | La-1-2929 | Lb135 |
| 2515 | La-1-2957 | Lb52 | 2516 | La-1-2957 | Lb135 |
| 2517 | La-1-2958 | Lb52 | 2518 | La-1-2958 | Lb135 |
| 2519 | La-1-2959 | Lb52 | 2520 | La-1-2959 | Lb135 |
| 2521 | La-1-2973 | Lb52 | 2522 | La-1-2973 | Lb135 |
| 2523 | La-1-2974 | Lb52 | 2524 | La-1-2974 | Lb135 |
| 2525 | La-1-2986 | Lb52 | 2526 | La-1-2986 | Lb135 |
| 2527 | La-1-2987 | Lb52 | 2528 | La-1-2987 | Lb135 |
| 2529 | La-1-2988 | Lb52 | 2530 | La-1-2988 | Lb135 |
| 2531 | La-1-2989 | Lb52 | 2532 | La-1-2989 | Lb135 |
| 2533 | La-1-3003 | Lb52 | 2534 | La-1-3003 | Lb135 |
| 2535 | La-1-3015 | Lb52 | 2536 | La-1-3015 | Lb135 |
| 2537 | La-1-3019 | Lb52 | 2538 | La-1-3019 | Lb135 |
| 2539 | La-1-3035 | Lb52 | 2540 | La-1-3035 | Lb135 |
| 2541 | La-1-3048 | Lb52 | 2542 | La-1-3048 | Lb135 |
| 2543 | La-1-3049 | Lb52 | 2544 | La-1-3049 | Lb135 |
| 2545 | La-1-3040 | Lb52 | 2546 | La-1-3040 | Lb135 |
| 2547 | La-1-3041 | Lb52 | 2548 | La-1-3041 | Lb135 |
| 2549 | La-1-3042 | Lb52 | 2550 | La-1-3042 | Lb135 |
| 2551 | La-1-3043 | Lb52 | 2552 | La-1-3043 | Lb135 |
| 2553 | La-1-3044 | Lb52 | 2554 | La-1-3044 | Lb135 |
| 2555 | La-1-3045 | Lb52 | 2556 | La-1-3045 | Lb135 |
| 2557 | La-1-3046 | Lb52 | 2558 | La-1-3046 | Lb135 |
| 2559 | La-1-3047 | Lb52 | 2560 | La-1-3047 | Lb135 |
| 2561 | La-1-3055 | Lb52 | 2562 | La-1-3055 | Lb135 |
| 2563 | La-1-3058 | Lb52 | 2564 | La-1-3058 | Lb135 |
| 2565 | La-1-3059 | Lb52 | 2566 | La-1-3059 | Lb135 |
| 2567 | La-1-3070 | Lb52 | 2568 | La-1-3070 | Lb135 |
| 2569 | La-1-3077 | Lb52 | 2570 | La-1-3077 | Lb135 |
| 2571 | La-1-3078 | Lb52 | 2572 | La-1-3078 | Lb135 |
| 2573 | La-1-3079 | Lb52 | 2574 | La-1-3079 | Lb135 |
| 2575 | La-1-3093 | Lb52 | 2576 | La-1-3093 | Lb135 |
| 2577 | La-1-3094 | Lb52 | 2578 | La-1-3094 | Lb135 |
| 2579 | La-1-3095 | Lb52 | 2580 | La-1-3095 | Lb135 |
| 2581 | La-1-3096 | Lb52 | 2582 | La-1-3096 | Lb135 |
| 2583 | La-1-3097 | Lb52 | 2584 | La-1-3097 | Lb135 |
| 2585 | La-1-3098 | Lb52 | 2586 | La-1-3098 | Lb135 |
| 2587 | La-1-3099 | Lb52 | 2588 | La-1-3099 | Lb135 |
| 2589 | La-1-3100 | Lb52 | 2590 | La-1-3100 | Lb135 |
| 2591 | La-1-3101 | Lb52 | 2592 | La-1-3101 | Lb135 |
| 2593 | La-1-3102 | Lb52 | 2594 | La-1-3102 | Lb135 |
| 2595 | La-1-3103 | Lb52 | 2596 | La-1-3103 | Lb135 |
| 2597 | La-1-3104 | Lb52 | 2598 | La-1-3104 | Lb135 |
| 2599 | La-1-3105 | Lb52 | 2600 | La-1-3105 | Lb135 |
| 2601 | La-1-3106 | Lb52 | 2602 | La-1-3106 | Lb135 |
| 2603 | La-1-3107 | Lb52 | 2604 | La-1-3107 | Lb135 |
| 2605 | La-1-3108 | Lb52 | 2606 | La-1-3108 | Lb135 |
| 2607 | La-1-3109 | Lb52 | 2608 | La-1-3109 | Lb135 |
| 2609 | La-1-3110 | Lb52 | 2610 | La-1-3110 | Lb135 |
| 2611 | La-1-3118 | Lb52 | 2612 | La-1-3118 | Lb135 |
| 2613 | La-1-3142 | Lb52 | 2614 | La-1-3142 | Lb135 |
| 2615 | La-1-3150 | Lb52 | 2616 | La-1-3150 | Lb135 |
| 2617 | La-1-3154 | Lb52 | 2618 | La-1-3154 | Lb135 |
| 2619 | La-1-3165 | Lb52 | 2620 | La-1-3165 | Lb135 |
| 2621 | La-1-3166 | Lb52 | 2622 | La-1-3166 | Lb135 |
| 2623 | La-1-3174 | Lb52 | 2624 | La-1-3174 | Lb135 |
| 2625 | La-1-3182 | Lb52 | 2626 | La-1-3182 | Lb135 |
| 2627 | La-1-3185 | Lb52 | 2628 | La-1-3185 | Lb135 |
| 2629 | La-1-3186 | Lb52 | 2630 | La-1-3186 | Lb135 |
| 2631 | La-1-3198 | Lb52 | 2632 | La-1-3198 | Lb135 |
| 2633 | La-1-3217 | Lb52 | 2634 | La-1-3217 | Lb135 |
| 2635 | La-1-3218 | Lb52 | 2636 | La-1-3218 | Lb135 |
| 2637 | La-1-3226 | Lb52 | 2638 | La-1-3226 | Lb135 |
| 2639 | La-1-3227 | Lb52 | 2640 | La-1-3227 | Lb135 |
| 2641 | La-1-3228 | Lb52 | 2642 | La-1-3228 | Lb135 |
| 2643 | La-1-3256 | Lb52 | 2644 | La-1-3256 | Lb135 |
| 2645 | La-1-3257 | Lb52 | 2646 | La-1-3257 | Lb135 |
| 2647 | La-1-3258 | Lb52 | 2648 | La-1-3258 | Lb135 |
| 2649 | La-1-3259 | Lb52 | 2650 | La-1-3259 | Lb135 |
| 2651 | La-1-3288 | Lb52 | 2652 | La-1-3288 | Lb135 |
| 2653 | La-1-3289 | Lb52 | 2654 | La-1-3289 | Lb135 |
| 2655 | La-1-3290 | Lb52 | 2656 | La-1-3290 | Lb135 |
| 2657 | La-1-3291 | Lb52 | 2658 | La-1-3291 | Lb135 |
| 2659 | La-1-3315 | Lb52 | 2660 | La-1-3315 | Lb135 |
| 2661 | La-1-3316 | Lb52 | 2662 | La-1-3316 | Lb135 |
| 2663 | La-1-3345 | Lb52 | 2664 | La-1-3345 | Lb135 |
| 2665 | La-1-3346 | Lb52 | 2666 | La-1-3346 | Lb135 |
| 2667 | La-1-3347 | Lb52 | 2668 | La-1-3347 | Lb135 |
| 2669 | La-1-3348 | Lb52 | 2670 | La-1-3348 | Lb135 |
| 2671 | La-1-3349 | Lb52 | 2672 | La-1-3349 | Lb135 |
| 2673 | La-1-3449 | Lb52 | 2674 | La-1-3449 | Lb135 |
| 2675 | La-1-3450 | Lb52 | 2676 | La-1-3450 | Lb135 |
| 2677 | La-1-3451 | Lb52 | 2678 | La-1-3451 | Lb135 |
| 2679 | La-1-3452 | Lb52 | 2680 | La-1-3452 | Lb135 |
| 2681 | La-1-3453 | Lb52 | 2682 | La-1-3453 | Lb135 |
| 2683 | La-1-3523 | Lb52 | 2684 | La-1-3523 | Lb135 |
| 2685 | La-1-3524 | Lb52 | 2686 | La-1-3524 | Lb135 |
| 2687 | La-1-3657 | Lb52 | 2688 | La-1-3657 | Lb135 |
| 2689 | La-1-3658 | Lb52 | 2690 | La-1-3658 | Lb135 |
| 2691 | La-1-3659 | Lb52 | 2692 | La-1-3659 | Lb135 |
| 2693 | La-1-3660 | Lb52 | 2694 | La-1-3660 | Lb135 |
| 2695 | La-1-3661 | Lb52 | 2696 | La-1-3661 | Lb135 |
| 2697 | La-1-3730 | Lb52 | 2698 | La-1-3730 | Lb135 |
| 2699 | La-2-1799 | Lb52 | 2700 | La-2-1799 | Lb135 |
| 2701 | La-2-1800 | Lb52 | 2702 | La-2-1800 | Lb135 |
| 2703 | La-2-1801 | Lb52 | 2704 | La-2-1801 | Lb135 |
| 2705 | La-2-1802 | Lb52 | 2706 | La-2-1802 | Lb135 |
| 2707 | La-2-1803 | Lb52 | 2708 | La-2-1803 | Lb135 |
| 2709 | La-2-1828 | Lb52 | 2710 | La-2-1828 | Lb135 |
| 2711 | La-2-1829 | Lb52 | 2712 | La-2-1829 | Lb135 |
| 2713 | La-2-1872 | Lb52 | 2714 | La-2-1872 | Lb135 |
| 2715 | La-2-1873 | Lb52 | 2716 | La-2-1873 | Lb135 |
| 2717 | La-2-1874 | Lb52 | 2718 | La-2-1874 | Lb135 |
| 2719 | La-2-1903 | Lb52 | 2720 | La-2-1903 | Lb135 |
| 2721 | La-2-1904 | Lb52 | 2722 | La-2-1904 | Lb135 |
| 2723 | La-2-1905 | Lb52 | 2724 | La-2-1905 | Lb135 |
| 2725 | La-2-1906 | Lb52 | 2726 | La-2-1906 | Lb135 |
| 2727 | La-2-1907 | Lb52 | 2728 | La-2-1907 | Lb135 |
| 2729 | La-2-1977 | Lb52 | 2730 | La-2-1977 | Lb135 |
| 2731 | La-2-1978 | Lb52 | 2732 | La-2-1978 | Lb135 |
| 2733 | La-2-2007 | Lb52 | 2734 | La-2-2007 | Lb135 |
| 2735 | La-2-2008 | Lb52 | 2736 | La-2-2008 | Lb135 |
| 2737 | La-2-2009 | Lb52 | 2738 | La-2-2009 | Lb135 |
| 2739 | La-2-2010 | Lb52 | 2740 | La-2-2010 | Lb135 |
| 2741 | La-2-2011 | Lb52 | 2742 | La-2-2011 | Lb135 |
| 2743 | La-2-2036 | Lb52 | 2744 | La-2-2036 | Lb135 |
| 2745 | La-2-2037 | Lb52 | 2746 | La-2-2037 | Lb135 |
| 2747 | La-2-2038 | Lb52 | 2748 | La-2-2038 | Lb135 |
| 2749 | La-2-2080 | Lb52 | 2750 | La-2-2080 | Lb135 |
| 2751 | La-2-2081 | Lb52 | 2752 | La-2-2081 | Lb135 |
| 2753 | La-2-2111 | Lb52 | 2754 | La-2-2111 | Lb135 |
| 2755 | La-2-2112 | Lb52 | 2756 | La-2-2112 | Lb135 |
| 2757 | La-2-2113 | Lb52 | 2758 | La-2-2113 | Lb135 |
| 2759 | La-2-2114 | Lb52 | 2760 | La-2-2114 | Lb135 |
| 2761 | La-2-2115 | Lb52 | 2762 | La-2-2115 | Lb135 |
| 2763 | La-2-2185 | Lb52 | 2764 | La-2-2185 | Lb135 |
| 2765 | La-2-2186 | Lb52 | 2766 | La-2-2186 | Lb135 |
| 2767 | La-2-2215 | Lb52 | 2768 | La-2-2215 | Lb135 |
| 2769 | La-2-2216 | Lb52 | 2770 | La-2-2216 | Lb135 |
| 2771 | La-2-2217 | Lb52 | 2772 | La-2-2217 | Lb135 |
| 2773 | La-2-2218 | Lb52 | 2774 | La-2-2218 | Lb135 |
| 2775 | La-2-2219 | Lb52 | 2776 | La-2-2219 | Lb135 |
| 2777 | La-2-2234 | Lb52 | 2778 | La-2-2234 | Lb135 |
| 2779 | La-2-2235 | Lb52 | 2780 | La-2-2235 | Lb135 |
| 2781 | La-2-2236 | Lb52 | 2782 | La-2-2236 | Lb135 |
| 2783 | La-2-2237 | Lb52 | 2784 | La-2-2237 | Lb135 |
| 2785 | La-2-2238 | Lb52 | 2786 | La-2-2238 | Lb135 |
| 2787 | La-2-2289 | Lb52 | 2788 | La-2-2289 | Lb135 |
| 2789 | La-2-2290 | Lb52 | 2790 | La-2-2290 | Lb135 |
| 2791 | La-2-2319 | Lb52 | 2792 | La-2-2319 | Lb135 |
| 2793 | La-2-2320 | Lb52 | 2794 | La-2-2320 | Lb135 |
| 2795 | La-2-2321 | Lb52 | 2796 | La-2-2321 | Lb135 |
| 2797 | La-2-2322 | Lb52 | 2798 | La-2-2322 | Lb135 |
| 2799 | La-2-2323 | Lb52 | 2800 | La-2-2323 | Lb135 |
| 2801 | La-2-2393 | Lb52 | 2802 | La-2-2393 | Lb135 |
| 2803 | La-2-2394 | Lb52 | 2804 | La-2-2394 | Lb135 |
| 2805 | La-2-2423 | Lb52 | 2806 | La-2-2423 | Lb135 |
| 2807 | La-2-2424 | Lb52 | 2808 | La-2-2424 | Lb135 |
| 2809 | La-2-2425 | Lb52 | 2810 | La-2-2425 | Lb135 |
| 2811 | La-2-2426 | Lb52 | 2812 | La-2-2426 | Lb135 |
| 2813 | La-2-2427 | Lb52 | 2814 | La-2-2427 | Lb135 |
| 2815 | La-2-2497 | Lb52 | 2816 | La-2-2497 | Lb135 |
| 2817 | La-2-2498 | Lb52 | 2818 | La-2-2498 | Lb135 |
| 2819 | La-2-2527 | Lb52 | 2820 | La-2-2527 | Lb135 |
| 2821 | La-2-2528 | Lb52 | 2822 | La-2-2528 | Lb135 |
| 2823 | La-2-2529 | Lb52 | 2824 | La-2-2529 | Lb135 |
| 2825 | La-2-2530 | Lb52 | 2826 | La-2-2530 | Lb135 |
| 2827 | La-2-2531 | Lb52 | 2828 | La-2-2531 | Lb135 |
| 2829 | La-2-2601 | Lb52 | 2830 | La-2-2601 | Lb135 |
| 2831 | La-2-2602 | Lb52 | 2832 | La-2-2602 | Lb135 |
| 2833 | La-2-2631 | Lb52 | 2834 | La-2-2631 | Lb135 |
| 2835 | La-2-2632 | Lb52 | 2836 | La-2-2632 | Lb135 |
| 2837 | La-2-2633 | Lb52 | 2838 | La-2-2633 | Lb135 |
| 2839 | La-2-2634 | Lb52 | 2840 | La-2-2634 | Lb135 |
| 2841 | La-2-2635 | Lb52 | 2842 | La-2-2635 | Lb135 |
| 2843 | La-2-2705 | Lb52 | 2844 | La-2-2705 | Lb135 |
| 2845 | La-2-2706 | Lb52 | 2846 | La-2-2706 | Lb135 |
| 2847 | La-2-2735 | Lb52 | 2848 | La-2-2735 | Lb135 |
| 2849 | La-2-2736 | Lb52 | 2850 | La-2-2736 | Lb135 |
| 2851 | La-2-2737 | Lb52 | 2852 | La-2-2737 | Lb135 |
| 2853 | La-2-2738 | Lb52 | 2854 | La-2-2738 | Lb135 |
| 2855 | La-2-2739 | Lb52 | 2856 | La-2-2739 | Lb135 |
| 2857 | La-2-2809 | Lb52 | 2858 | La-2-2809 | Lb135 |
| 2859 | La-2-2810 | Lb52 | 2860 | La-2-2810 | Lb135 |
| 2861 | La-2-2839 | Lb52 | 2862 | La-2-2839 | Lb135 |
| 2863 | La-2-2840 | Lb52 | 2864 | La-2-2840 | Lb135 |
| 2865 | La-2-2841 | Lb52 | 2866 | La-2-2841 | Lb135 |
| 2867 | La-2-2842 | Lb52 | 2868 | La-2-2842 | Lb135 |
| 2869 | La-2-2843 | Lb52 | 2870 | La-2-2843 | Lb135 |
| 2871 | La-2-2918 | Lb52 | 2872 | La-2-2918 | Lb135 |
| 2873 | La-2-2919 | Lb52 | 2874 | La-2-2919 | Lb135 |
| 2875 | La-2-2920 | Lb52 | 2876 | La-2-2920 | Lb135 |
| 2877 | La-2-2921 | Lb52 | 2878 | La-2-2921 | Lb135 |
| 2879 | La-2-2922 | Lb52 | 2880 | La-2-2922 | Lb135 |
| 2881 | La-2-2943 | Lb52 | 2882 | La-2-2943 | Lb135 |
| 2883 | La-2-2944 | Lb52 | 2884 | La-2-2944 | Lb135 |
| 2885 | La-2-2928 | Lb52 | 2886 | La-2-2928 | Lb135 |
| 2887 | La-2-2929 | Lb52 | 2888 | La-2-2929 | Lb135 |
| 2889 | La-2-2957 | Lb52 | 2890 | La-2-2957 | Lb135 |
| 2891 | La-2-2958 | Lb52 | 2892 | La-2-2958 | Lb135 |
| 2893 | La-2-2959 | Lb52 | 2894 | La-2-2959 | Lb135 |
| 2895 | La-2-2973 | Lb52 | 2896 | La-2-2973 | Lb135 |
| 2897 | La-2-2974 | Lb52 | 2898 | La-2-2974 | Lb135 |
| 2899 | La-2-2986 | Lb52 | 2900 | La-2-2986 | Lb135 |
| 2901 | La-2-2987 | Lb52 | 2902 | La-2-2987 | Lb135 |
| 2903 | La-2-2988 | Lb52 | 2904 | La-2-2988 | Lb135 |
| 2905 | La-2-2989 | Lb52 | 2906 | La-2-2989 | Lb135 |
| 2907 | La-2-3003 | Lb52 | 2908 | La-2-3003 | Lb135 |
| 2909 | La-2-3015 | Lb52 | 2910 | La-2-3015 | Lb135 |
| 2911 | La-2-3019 | Lb52 | 2912 | La-2-3019 | Lb135 |
| 2913 | La-2-3035 | Lb52 | 2914 | La-2-3035 | Lb135 |
| 2915 | La-2-3048 | Lb52 | 2916 | La-2-3048 | Lb135 |
| 2917 | La-2-3049 | Lb52 | 2918 | La-2-3049 | Lb135 |
| 2919 | La-2-3040 | Lb52 | 2920 | La-2-3040 | Lb135 |
| 2921 | La-2-3041 | Lb52 | 2922 | La-2-3041 | Lb135 |
| 2923 | La-2-3042 | Lb52 | 2924 | La-2-3042 | Lb135 |
| 2925 | La-2-3043 | Lb52 | 2926 | La-2-3043 | Lb135 |
| 2927 | La-2-3044 | Lb52 | 2928 | La-2-3044 | Lb135 |
| 2929 | La-2-3045 | Lb52 | 2930 | La-2-3045 | Lb135 |
| 2931 | La-2-3046 | Lb52 | 2932 | La-2-3046 | Lb135 |
| 2933 | La-2-3047 | Lb52 | 2934 | La-2-3047 | Lb135 |
| 2935 | La-2-3055 | Lb52 | 2936 | La-2-3055 | Lb135 |
| 2937 | La-2-3058 | Lb52 | 2938 | La-2-3058 | Lb135 |
| 2939 | La-2-3059 | Lb52 | 2940 | La-2-3059 | Lb135 |
| 2941 | La-2-3070 | Lb52 | 2942 | La-2-3070 | Lb135 |
| 2943 | La-2-3077 | Lb52 | 2944 | La-2-3077 | Lb135 |
| 2945 | La-2-3078 | Lb52 | 2946 | La-2-3078 | Lb135 |
| 2947 | La-2-3079 | Lb52 | 2948 | La-2-3079 | Lb135 |
| 2949 | La-2-3093 | Lb52 | 2950 | La-2-3093 | Lb135 |
| 2951 | La-2-3094 | Lb52 | 2952 | La-2-3094 | Lb135 |
| 2953 | La-2-3095 | Lb52 | 2954 | La-2-3095 | Lb135 |
| 2955 | La-2-3096 | Lb52 | 2956 | La-2-3096 | Lb135 |
| 2957 | La-2-3097 | Lb52 | 2958 | La-2-3097 | Lb135 |
| 2959 | La-2-3098 | Lb52 | 2960 | La-2-3098 | Lb135 |
| 2961 | La-2-3099 | Lb52 | 2962 | La-2-3099 | Lb135 |
| 2963 | La-2-3100 | Lb52 | 2964 | La-2-3100 | Lb135 |
| 2965 | La-2-3101 | Lb52 | 2966 | La-2-3101 | Lb135 |
| 2967 | La-2-3102 | Lb52 | 2968 | La-2-3102 | Lb135 |
| 2969 | La-2-3103 | Lb52 | 2970 | La-2-3103 | Lb135 |
| 2971 | La-2-3104 | Lb52 | 2972 | La-2-3104 | Lb135 |
| 2973 | La-2-3105 | Lb52 | 2974 | La-2-3105 | Lb135 |
| 2975 | La-2-3106 | Lb52 | 2976 | La-2-3106 | Lb135 |
| 2977 | La-2-3107 | Lb52 | 2978 | La-2-3107 | Lb135 |
| 2979 | La-2-3108 | Lb52 | 2980 | La-2-3108 | Lb135 |
| 2981 | La-2-3109 | Lb52 | 2982 | La-2-3109 | Lb135 |
| 2983 | La-2-3110 | Lb52 | 2984 | La-2-3110 | Lb135 |
| 2985 | La-2-3118 | Lb52 | 2986 | La-2-3118 | Lb135 |
| 2987 | La-2-3142 | Lb52 | 2988 | La-2-3142 | Lb135 |
| 2989 | La-2-3150 | Lb52 | 2990 | La-2-3150 | Lb135 |
| 2991 | La-2-3154 | Lb52 | 2992 | La-2-3154 | Lb135 |
| 2993 | La-2-3165 | Lb52 | 2994 | La-2-3165 | Lb135 |
| 2995 | La-2-3166 | Lb52 | 2996 | La-2-3166 | Lb135 |
| 2997 | La-2-3174 | Lb52 | 2998 | La-2-3174 | Lb135 |
| 2999 | La-2-3182 | Lb52 | 3000 | La-2-3182 | Lb135 |
| 3001 | La-2-3185 | Lb52 | 3002 | La-2-3185 | Lb135 |
| 3003 | La-2-3186 | Lb52 | 3004 | La-2-3186 | Lb135 |
| 3005 | La-2-3198 | Lb52 | 3006 | La-2-3198 | Lb135 |
| 3007 | La-2-3217 | Lb52 | 3008 | La-2-3217 | Lb135 |
| 3009 | La-2-3218 | Lb52 | 3010 | La-2-3218 | Lb135 |
| 3011 | La-2-3226 | Lb52 | 3012 | La-2-3226 | Lb135 |
| 3013 | La-2-3227 | Lb52 | 3014 | La-2-3227 | Lb135 |
| 3015 | La-2-3228 | Lb52 | 3016 | La-2-3228 | Lb135 |
| 3017 | La-2-3256 | Lb52 | 3018 | La-2-3256 | Lb135 |
| 3019 | La-2-3257 | Lb52 | 3020 | La-2-3257 | Lb135 |
| 3021 | La-2-3258 | Lb52 | 3022 | La-2-3258 | Lb135 |
| 3023 | La-2-3259 | Lb52 | 3024 | La-2-3259 | Lb135 |
| 3025 | La-2-3288 | Lb52 | 3026 | La-2-3288 | Lb135 |
| 3027 | La-2-3289 | Lb52 | 3028 | La-2-3289 | Lb135 |
| 3029 | La-2-3290 | Lb52 | 3030 | La-2-3290 | Lb135 |
| 3031 | La-2-3291 | Lb52 | 3032 | La-2-3291 | Lb135 |
| 3033 | La-2-3315 | Lb52 | 3034 | La-2-3315 | Lb135 |
| 3035 | La-2-3316 | Lb52 | 3036 | La-2-3316 | Lb135 |
| 3037 | La-2-3345 | Lb52 | 3038 | La-2-3345 | Lb135 |
| 3039 | La-2-3346 | Lb52 | 3040 | La-2-3346 | Lb135 |
| 3041 | La-2-3347 | Lb52 | 3042 | La-2-3347 | Lb135 |
| 3043 | La-2-3348 | Lb52 | 3044 | La-2-3348 | Lb135 |
| 3045 | La-2-3349 | Lb52 | 3046 | La-2-3349 | Lb135 |
| 3047 | La-2-3449 | Lb52 | 3048 | La-2-3449 | Lb135 |
| 3049 | La-2-3450 | Lb52 | 3050 | La-2-3450 | Lb135 |
| 3051 | La-2-3451 | Lb52 | 3052 | La-2-3451 | Lb135 |
| 3053 | La-2-3452 | Lb52 | 3054 | La-2-3452 | Lb135 |
| 3055 | La-2-3453 | Lb52 | 3056 | La-2-3453 | Lb135 |
| 3057 | La-2-3523 | Lb52 | 3058 | La-2-3523 | Lb135 |
| 3059 | La-2-3524 | Lb52 | 3060 | La-2-3524 | Lb135 |
| 3061 | La-2-3657 | Lb52 | 3062 | La-2-3657 | Lb135 |
| 3063 | La-2-3658 | Lb52 | 3064 | La-2-3658 | Lb135 |
| 3065 | La-2-3659 | Lb52 | 3066 | La-2-3659 | Lb135 |
| 3067 | La-2-3660 | Lb52 | 3068 | La-2-3660 | Lb135 |
| 3069 | La-2-3661 | Lb52 | 3070 | La-2-3661 | Lb135 |
| 3071 | La-2-3730 | Lb52 | 3072 | La-2-3730 | Lb135 |
| 3073 | La-1-1487 | Lb2 | 3074 | La-2-1487 | Lb2 |
| 3075 | La-1-1487 | Lb3 | 3076 | La-2-1487 | Lb3 |
| 3077 | La-1-1487 | Lb4 | 3078 | La-2-1487 | Lb4 |
| 3079 | La-1-1487 | Lb5 | 3080 | La-2-1487 | Lb5 |
| 3081 | La-1-1487 | Lb6 | 3082 | La-2-1487 | Lb6 |
| 3083 | La-1-1487 | Lb7 | 3084 | La-2-1487 | Lb7 |
| 3085 | La-1-1487 | Lb8 | 3086 | La-2-1487 | Lb8 |
| 3087 | La-1-1487 | Lb9 | 3088 | La-2-1487 | Lb9 |
| 3089 | La-1-1487 | Lb10 | 3090 | La-2-1487 | Lb10 |
| 3091 | La-1-1487 | Lb11 | 3092 | La-2-1487 | Lb11 |
| 3093 | La-1-1487 | Lb12 | 3094 | La-2-1487 | Lb12 |
| 3095 | La-1-1487 | Lb13 | 3096 | La-2-1487 | Lb13 |
| 3097 | La-1-1487 | Lb14 | 3098 | La-2-1487 | Lb14 |
| 3099 | La-1-1487 | Lb15 | 3100 | La-2-1487 | Lb15 |
| 3101 | La-1-1487 | Lb16 | 3102 | La-2-1487 | Lb16 |
| 3103 | La-1-1487 | Lb17 | 3104 | La-2-1487 | Lb17 |
| 3105 | La-1-1487 | Lb18 | 3106 | La-2-1487 | Lb18 |
| 3107 | La-1-1487 | Lb19 | 3108 | La-2-1487 | Lb19 |
| 3109 | La-1-1487 | Lb21 | 3110 | La-2-1487 | Lb21 |
| 3111 | La-1-1487 | Lb22 | 3112 | La-2-1487 | Lb22 |
| 3113 | La-1-1487 | Lb23 | 3114 | La-2-1487 | Lb23 |
| 3115 | La-1-1487 | Lb24 | 3116 | La-2-1487 | Lb24 |
| 3117 | La-1-1487 | Lb25 | 3118 | La-2-1487 | Lb25 |
| 3119 | La-1-1487 | Lb26 | 3120 | La-2-1487 | Lb26 |
| 3121 | La-1-1487 | Lb27 | 3122 | La-2-1487 | Lb27 |
| 3123 | La-1-1487 | Lb28 | 3124 | La-2-1487 | Lb28 |
| 3125 | La-1-1487 | Lb29 | 3126 | La-2-1487 | Lb29 |
| 3127 | La-1-1487 | Lb30 | 3128 | La-2-1487 | Lb30 |
| 3129 | La-1-1487 | Lb31 | 3130 | La-2-1487 | Lb31 |
| 3131 | La-1-1487 | Lb32 | 3132 | La-2-1487 | Lb32 |
| 3133 | La-1-1487 | Lb33 | 3134 | La-2-1487 | Lb33 |
| 3135 | La-1-1487 | Lb34 | 3136 | La-2-1487 | Lb34 |
| 3137 | La-1-1487 | Lb35 | 3138 | La-2-1487 | Lb35 |
| 3139 | La-1-1487 | Lb36 | 3140 | La-2-1487 | Lb36 |
| 3141 | La-1-1487 | Lb37 | 3142 | La-2-1487 | Lb37 |
| 3143 | La-1-1487 | Lb38 | 3144 | La-2-1487 | Lb38 |
| 3145 | La-1-1487 | Lb39 | 3146 | La-2-1487 | Lb39 |
| 3147 | La-1-1487 | Lb40 | 3148 | La-2-1487 | Lb40 |
| 3149 | La-1-1487 | Lb41 | 3150 | La-2-1487 | Lb41 |
| 3151 | La-1-1487 | Lb42 | 3152 | La-2-1487 | Lb42 |
| 3153 | La-1-1487 | Lb43 | 3154 | La-2-1487 | Lb43 |
| 3155 | La-1-1487 | Lb44 | 3156 | La-2-1487 | Lb44 |
| 3157 | La-1-1487 | Lb45 | 3158 | La-2-1487 | Lb45 |
| 3159 | La-1-1487 | Lb46 | 3160 | La-2-1487 | Lb46 |
| 3161 | La-1-1487 | Lb47 | 3162 | La-2-1487 | Lb47 |
| 3163 | La-1-1487 | Lb48 | 3164 | La-2-1487 | Lb48 |
| 3165 | La-1-1487 | Lb49 | 3166 | La-2-1487 | Lb49 |
| 3167 | La-1-1487 | Lb50 | 3168 | La-2-1487 | Lb50 |
| 3169 | La-1-1487 | Lb51 | 3170 | La-2-1487 | Lb51 |
| 3171 | La-1-1487 | Lb53 | 3172 | La-2-1487 | Lb53 |
| 3173 | La-1-1487 | Lb54 | 3174 | La-2-1487 | Lb54 |
| 3175 | La-1-1487 | Lb55 | 3176 | La-2-1487 | Lb55 |
| 3177 | La-1-1487 | Lb56 | 3178 | La-2-1487 | Lb56 |
| 3179 | La-1-1487 | Lb57 | 3180 | La-2-1487 | Lb57 |
| 3181 | La-1-1487 | Lb58 | 3182 | La-2-1487 | Lb58 |
| 3183 | La-1-1487 | Lb59 | 3184 | La-2-1487 | Lb59 |
| 3185 | La-1-1487 | Lb60 | 3186 | La-2-1487 | Lb60 |
| 3187 | La-1-1487 | Lb61 | 3188 | La-2-1487 | Lb61 |
| 3189 | La-1-1487 | Lb62 | 3190 | La-2-1487 | Lb62 |
| 3191 | La-1-1487 | Lb63 | 3192 | La-2-1487 | Lb63 |
| 3193 | La-1-1487 | Lb64 | 3194 | La-2-1487 | Lb64 |
| 3195 | La-1-1487 | Lb65 | 3196 | La-2-1487 | Lb65 |
| 3197 | La-1-1487 | Lb66 | 3198 | La-2-1487 | Lb66 |
| 3199 | La-1-1487 | Lb67 | 3200 | La-2-1487 | Lb67 |
| 3201 | La-1-1487 | Lb68 | 3202 | La-2-1487 | Lb68 |
| 3203 | La-1-1487 | Lb69 | 3204 | La-2-1487 | Lb69 |
| 3205 | La-1-1487 | Lb70 | 3206 | La-2-1487 | Lb70 |
| 3207 | La-1-1487 | Lb71 | 3208 | La-2-1487 | Lb71 |
| 3209 | La-1-1487 | Lb72 | 3210 | La-2-1487 | Lb72 |
| 3211 | La-1-1487 | Lb73 | 3212 | La-2-1487 | Lb73 |
| 3213 | La-1-1487 | Lb74 | 3214 | La-2-1487 | Lb74 |
| 3215 | La-1-1487 | Lb75 | 3216 | La-2-1487 | Lb75 |
| 3217 | La-1-1487 | Lb76 | 3218 | La-2-1487 | Lb76 |
| 3219 | La-1-1487 | Lb77 | 3220 | La-2-1487 | Lb77 |
| 3221 | La-1-1487 | Lb78 | 3222 | La-2-1487 | Lb78 |
| 3223 | La-1-1487 | Lb79 | 3224 | La-2-1487 | Lb79 |
| 3225 | La-1-1487 | Lb80 | 3226 | La-2-1487 | Lb80 |
| 3227 | La-1-1487 | Lb81 | 3228 | La-2-1487 | Lb81 |
| 3229 | La-1-1487 | Lb82 | 3230 | La-2-1487 | Lb82 |
| 3231 | La-1-1487 | Lb83 | 3232 | La-2-1487 | Lb83 |
| 3233 | La-1-1487 | Lb84 | 3234 | La-2-1487 | Lb84 |
| 3235 | La-1-1487 | Lb85 | 3236 | La-2-1487 | Lb85 |
| 3237 | La-1-1487 | Lb86 | 3238 | La-2-1487 | Lb86 |
| 3239 | La-1-1487 | Lb87 | 3240 | La-2-1487 | Lb87 |
| 3241 | La-1-1487 | Lb88 | 3242 | La-2-1487 | Lb88 |
| 3243 | La-1-1487 | Lb89 | 3244 | La-2-1487 | Lb89 |
| 3245 | La-1-1487 | Lb90 | 3246 | La-2-1487 | Lb90 |
| 3247 | La-1-1487 | Lb91 | 3248 | La-2-1487 | Lb91 |
| 3249 | La-1-1487 | Lb92 | 3250 | La-2-1487 | Lb92 |
| 3251 | La-1-1487 | Lb93 | 3252 | La-2-1487 | Lb93 |
| 3253 | La-1-1487 | Lb94 | 3254 | La-2-1487 | Lb94 |
| 3255 | La-1-1487 | Lb95 | 3256 | La-2-1487 | Lb95 |
| 3257 | La-1-1487 | Lb96 | 3258 | La-2-1487 | Lb96 |
| 3259 | La-1-1487 | Lb97 | 3260 | La-2-1487 | Lb97 |
| 3261 | La-1-1487 | Lb98 | 3262 | La-2-1487 | Lb98 |
| 3263 | La-1-1487 | Lb99 | 3264 | La-2-1487 | Lb99 |
| 3265 | La-1-1487 | Lb100 | 3266 | La-2-1487 | Lb100 |
| 3267 | La-1-1487 | Lb101 | 3268 | La-2-1487 | Lb101 |
| 3269 | La-1-1487 | Lb102 | 3270 | La-2-1487 | Lb102 |
| 3271 | La-1-1487 | Lb103 | 3272 | La-2-1487 | Lb103 |
| 3273 | La-1-1487 | Lb104 | 3274 | La-2-1487 | Lb104 |
| 3275 | La-1-1487 | Lb105 | 3276 | La-2-1487 | Lb105 |
| 3277 | La-1-1487 | Lb106 | 3278 | La-2-1487 | Lb106 |
| 3279 | La-1-1487 | Lb107 | 3280 | La-2-1487 | Lb107 |
| 3281 | La-1-1487 | Lb108 | 3282 | La-2-1487 | Lb108 |
| 3283 | La-1-1487 | Lb109 | 3284 | La-2-1487 | Lb109 |
| 3285 | La-1-1487 | Lb110 | 3286 | La-2-1487 | Lb110 |
| 3287 | La-1-1487 | Lb111 | 3288 | La-2-1487 | Lb111 |
| 3289 | La-1-1487 | Lb112 | 3290 | La-2-1487 | Lb112 |
| 3291 | La-1-1487 | Lb113 | 3292 | La-2-1487 | Lb113 |
| 3293 | La-1-1487 | Lb114 | 3294 | La-2-1487 | Lb114 |
| 3295 | La-1-1487 | Lb115 | 3296 | La-2-1487 | Lb115 |
| 3297 | La-1-1487 | Lb116 | 3298 | La-2-1487 | Lb116 |
| 3299 | La-1-1487 | Lb117 | 3300 | La-2-1487 | Lb117 |
| 3301 | La-1-1487 | Lb118 | 3302 | La-2-1487 | Lb118 |
| 3303 | La-1-1487 | Lb119 | 3304 | La-2-1487 | Lb119 |
| 3305 | La-1-1487 | Lb120 | 3306 | La-2-1487 | Lb120 |
| 3307 | La-1-1487 | Lb121 | 3308 | La-2-1487 | Lb121 |
| 3309 | La-1-1487 | Lb122 | 3310 | La-2-1487 | Lb122 |
| 3311 | La-1-1487 | Lb123 | 3312 | La-2-1487 | Lb123 |
| 3313 | La-1-1487 | Lb124 | 3314 | La-2-1487 | Lb124 |
| 3315 | La-1-1487 | Lb125 | 3316 | La-2-1487 | Lb125 |
| 3317 | La-1-1487 | Lb126 | 3318 | La-2-1487 | Lb126 |
| 3319 | La-1-1487 | Lb127 | 3320 | La-2-1487 | Lb127 |
| 3321 | La-1-1487 | Lb128 | 3322 | La-2-1487 | Lb128 |
| 3323 | La-1-1487 | Lb129 | 3324 | La-2-1487 | Lb129 |
| 3325 | La-1-1487 | Lb130 | 3326 | La-2-1487 | Lb130 |
| 3327 | La-1-1487 | Lb131 | 3328 | La-2-1487 | Lb131 |
| 3329 | La-1-1487 | Lb132 | 3330 | La-2-1487 | Lb132 |
| 3331 | La-1-1487 | Lb133 | 3332 | La-2-1487 | Lb133 |
| 3333 | La-1-1487 | Lb134 | 3334 | La-2-1487 | Lb134 |
| 3335 | La-1-1487 | Lb136 | 3336 | La-2-1487 | Lb136 |
| 3337 | La-1-1487 | Lb137 | 3338 | La-2-1487 | Lb137 |
| 3339 | La-1-1487 | Lb138 | 3340 | La-2-1487 | Lb138 |
| 3341 | La-1-1487 | Lb139 | 3342 | La-2-1487 | Lb139 |
| 3343 | La-1-1487 | Lb140 | 3344 | La-2-1487 | Lb140 |
| 3345 | La-1-1487 | Lb141 | 3346 | La-2-1487 | Lb141 |
| 3347 | La-1-1487 | Lb142 | 3348 | La-2-1487 | Lb142 |
| 3349 | La-1-1487 | Lb143 | 3350 | La-2-1487 | Lb143 |
| 3351 | La-1-1487 | Lb144 | 3352 | La-2-1487 | Lb144 |
| 3353 | La-1-1487 | Lb145 | 3354 | La-2-1487 | Lb145 |
| 3355 | La-1-1487 | Lb146 | 3356 | La-2-1487 | Lb146 |
| 3357 | La-1-1487 | Lb147 | 3358 | La-2-1487 | Lb147 |
| 3359 | La-1-1487 | Lb148 | 3360 | La-2-1487 | Lb148 |
| 3361 | La-1-1487 | Lb149 | 3362 | La-2-1487 | Lb149 |
| 3363 | La-1-1487 | Lb150 | 3364 | La-2-1487 | Lb150 |
| 3365 | La-1-1487 | Lb151 | 3366 | La-2-1487 | Lb151 |
| 3367 | La-1-1487 | Lb152 | 3368 | La-2-1487 | Lb152 |
| 3369 | La-1-1487 | Lb153 | 3370 | La-2-1487 | Lb153 |
| 3371 | La-1-1487 | Lb154 | 3372 | La-2-1487 | Lb154 |
| 3373 | La-1-1487 | Lb155 | 3374 | La-2-1487 | Lb155 |
| 3375 | La-1-1487 | Lb156 | 3376 | La-2-1487 | Lb156 |
| 3377 | La-1-1487 | Lb157 | 3378 | La-2-1487 | Lb157 |
| 3379 | La-1-1487 | Lb158 | 3380 | La-2-1487 | Lb158 |
| 3381 | La-1-1487 | Lb159 | 3382 | La-2-1487 | Lb159 |
| 3383 | La-1-1487 | Lb160 | 3384 | La-2-1487 | Lb160 |
| 3385 | La-1-1487 | Lb161 | 3386 | La-2-1487 | Lb161 |
| 3387 | La-1-1487 | Lb162 | 3388 | La-2-1487 | Lb162 |
| 3389 | La-1-1487 | Lb163 | 3390 | La-2-1487 | Lb163 |
| 3391 | La-1-1487 | Lb164 | 3392 | La-2-1487 | Lb164 |
| 3393 | La-1-1487 | Lb165 | 3394 | La-2-1487 | Lb165 |
| 3395 | La-1-1487 | Lb166 | 3396 | La-2-1487 | Lb166 |
| 3397 | La-1-1487 | Lb167 | 3398 | La-2-1487 | Lb167 |
| 3399 | La-1-1591 | Lb2 | 3400 | La-1-2977 | Lb2 |
| 3401 | La-1-1591 | Lb3 | 3402 | La-1-2978 | Lb3 |
| 3403 | La-1-1591 | Lb4 | 3404 | La-1-2979 | Lb4 |
| 3405 | La-1-1591 | Lb5 | 3406 | La-1-2980 | Lb5 |
| 3407 | La-1-1591 | Lb6 | 3408 | La-1-2981 | Lb6 |
| 3409 | La-1-1591 | Lb7 | 3410 | La-2-2977 | Lb7 |
| 3411 | La-1-1591 | Lb8 | 3412 | La-2-2978 | Lb8 |
| 3413 | La-1-1591 | Lb9 | 3414 | La-2-2979 | Lb9 |
| 3415 | La-1-1591 | Lb10 | 3416 | La-2-2980 | Lb10 |
| 3417 | La-1-1591 | Lb11 | 3418 | La-2-2981 | Lb11 |
| 3419 | La-1-1591 | Lb12 | 3420 | La-2-2982 | Lb12 |
| 3421 | La-1-1591 | Lb13 | 3422 | La-2-2983 | Lb13 |
| 3423 | La-1-1591 | Lb14 | 3424 | La-2-2984 | Lb14 |
| 3425 | La-1-1591 | Lb15 | 3426 | La-2-3083 | Lb15 |
| 3427 | La-1-1591 | Lb16 | 3428 | La-2-3084 | Lb16 |
| 3429 | La-1-1591 | Lb17 | 3430 | La-2-3085 | Lb17 |
| 3431 | La-1-1591 | Lb18 | 3432 | La-2-3086 | Lb18 |
| 3433 | La-1-1591 | Lb19 | 3434 | La-2-3087 | Lb19 |
| 3435 | La-1-1591 | Lb21 | 3436 | La-2-3088 | Lb21 |
| 3437 | La-1-1591 | Lb22 | 3438 | La-1-2549 | Lb22 |
| 3439 | La-1-1591 | Lb23 | 3440 | La-1-2550 | Lb23 |
| 3441 | La-1-1591 | Lb24 | 3442 | La-1-2551 | Lb24 |
| 3443 | La-1-1591 | Lb25 | 3444 | La-1-2552 | Lb25 |
| 3445 | La-1-1591 | Lb26 | 3446 | La-1-2553 | Lb26 |
| 3447 | La-1-1591 | Lb27 | 3448 | La-2-2438 | Lb27 |
| 3449 | La-1-1591 | Lb28 | 3450 | La-2-2439 | Lb28 |
| 3451 | La-1-1591 | Lb29 | 3452 | La-2-2440 | Lb29 |
| 3453 | La-1-1591 | Lb30 | 3454 | La-2-2441 | Lb30 |
| 3455 | La-1-1591 | Lb31 | 3456 | La-2-2442 | Lb31 |
| 3457 | La-1-1591 | Lb32 | 3458 | La-2-2443 | Lb32 |
| 3459 | La-1-1591 | Lb33 | 3460 | La-2-2444 | Lb33 |
| 3461 | La-1-1591 | Lb34 | 3462 | La-1-2346 | Lb34 |
| 3463 | La-1-1591 | Lb35 | 3464 | La-1-2347 | Lb35 |
| 3465 | La-1-1591 | Lb36 | 3466 | La-1-2348 | Lb36 |
| 3467 | La-1-1591 | Lb37 | 3468 | La-1-2349 | Lb37 |
| 3469 | La-1-1591 | Lb38 | 3470 | La-1-2350 | Lb38 |
| 3471 | La-1-1591 | Lb39 | 3472 | La-1-2351 | Lb39 |
| 3473 | La-1-1591 | Lb40 | 3474 | La-1-1721 | Lb40 |
| 3475 | La-1-1591 | Lb41 | 3476 | La-1-1722 | Lb41 |
| 3477 | La-1-1591 | Lb42 | 3478 | La-1-1723 | Lb42 |
| 3479 | La-1-1591 | Lb43 | 3480 | La-1-1724 | Lb43 |
| 3481 | La-1-1591 | Lb44 | 3482 | La-1-1725 | Lb44 |
| 3483 | La-1-1591 | Lb45 | 3484 | La-1-1726 | Lb45 |
| 3485 | La-1-1591 | Lb46 | 3486 | La-2-1703 | Lb46 |
| 3487 | La-1-1591 | Lb47 | 3488 | La-2-1704 | Lb47 |
| 3489 | La-1-1591 | Lb48 | 3490 | La-2-1705 | Lb48 |
| 3491 | La-1-1591 | Lb49 | 3492 | La-2-1706 | Lb49 |
| 3493 | La-1-1591 | Lb50 | 3494 | La-2-1707 | Lb50 |
| 3495 | La-1-1591 | Lb51 | 3496 | La-2-1708 | Lb51 |
| 3497 | La-1-1591 | Lb53 | 3498 | La-1-1606 | Lb53 |
| 3499 | La-1-1591 | Lb54 | 3500 | La-1-1607 | Lb54 |
| 3501 | La-1-1591 | Lb55 | 3502 | La-1-1608 | Lb55 |
| 3503 | La-1-1591 | Lb56 | 3504 | La-1-1609 | Lb56 |
| 3505 | La-1-1591 | Lb57 | 3506 | La-1-1610 | Lb57 |
| 3507 | La-1-1591 | Lb58 | 3508 | La-2-1617 | Lb58 |
| 3509 | La-1-1591 | Lb59 | 3510 | La-2-1618 | Lb59 |
| 3511 | La-1-1591 | Lb60 | 3512 | La-2-1619 | Lb60 |
| 3513 | La-1-1591 | Lb61 | 3514 | La-2-1620 | Lb61 |
| 3515 | La-1-1591 | Lb62 | 3516 | La-2-1621 | Lb62 |
| 3517 | La-1-1591 | Lb63 | 3518 | La-2-1622 | Lb63 |
| 3519 | La-1-1591 | Lb64 | 3520 | La-1-1570 | Lb64 |
| 3521 | La-1-1591 | Lb65 | 3522 | La-1-1571 | Lb65 |
| 3523 | La-1-1591 | Lb66 | 3524 | La-1-1572 | Lb66 |
| 3525 | La-1-1591 | Lb67 | 3526 | La-1-1573 | Lb67 |
| 3527 | La-1-1591 | Lb68 | 3528 | La-1-1574 | Lb68 |
| 3529 | La-1-1591 | Lb69 | 3530 | La-2-1440 | Lb69 |
| 3531 | La-1-1591 | Lb70 | 3532 | La-2-1441 | Lb70 |
| 3533 | La-1-1591 | Lb71 | 3534 | La-2-1442 | Lb71 |
| 3535 | La-1-1591 | Lb72 | 3536 | La-2-1443 | Lb72 |
| 3537 | La-1-1591 | Lb73 | 3538 | La-2-1444 | Lb73 |
| 3539 | La-1-1591 | Lb74 | 3540 | La-1-1193 | Lb74 |
| 3541 | La-1-1591 | Lb75 | 3542 | La-1-1194 | Lb75 |
| 3543 | La-1-1591 | Lb76 | 3544 | La-1-1195 | Lb76 |
| 3545 | La-1-1591 | Lb77 | 3546 | La-1-1196 | Lb77 |
| 3547 | La-1-1591 | Lb78 | 3548 | La-1-1197 | Lb78 |
| 3549 | La-1-1591 | Lb79 | 3550 | La-1-3128 | Lb79 |
| 3551 | La-1-1591 | Lb80 | 3552 | La-1-3129 | Lb80 |
| 3553 | La-1-1591 | Lb81 | 3554 | La-1-3130 | Lb81 |
| 3555 | La-1-1591 | Lb82 | 3556 | La-1-3131 | Lb82 |
| 3557 | La-1-1591 | Lb83 | 3558 | La-1-3132 | Lb83 |
| 3559 | La-1-1591 | Lb84 | 3560 | La-1-3133 | Lb84 |
| 3561 | La-1-1591 | Lb85 | 3562 | La-1-3134 | Lb85 |
| 3563 | La-1-1591 | Lb86 | 3564 | La-1-3135 | Lb86 |
| 3565 | La-1-1591 | Lb87 | 3566 | La-2-3144 | Lb87 |
| 3567 | La-1-1591 | Lb88 | 3568 | La-2-3145 | Lb88 |
| 3569 | La-1-1591 | Lb89 | 3570 | La-2-3146 | Lb89 |
| 3571 | La-1-1591 | Lb90 | 3572 | La-2-3147 | Lb90 |
| 3573 | La-1-1591 | Lb91 | 3574 | La-2-3148 | Lb91 |
| 3575 | La-1-1591 | Lb92 | 3576 | La-2-3149 | Lb92 |
| 3577 | La-1-1591 | Lb93 | 3578 | La-2-3188 | Lb93 |
| 3579 | La-1-1591 | Lb94 | 3580 | La-2-3189 | Lb94 |
| 3581 | La-1-1591 | Lb95 | 3582 | La-2-3190 | Lb95 |
| 3583 | La-1-1591 | Lb96 | 3584 | La-2-3191 | Lb96 |
| 3585 | La-1-1591 | Lb97 | 3586 | La-2-3192 | Lb97 |
| 3587 | La-1-1591 | Lb98 | 3588 | La-1-3246 | Lb98 |
| 3589 | La-1-1591 | Lb99 | 3590 | La-1-3247 | Lb99 |
| 3591 | La-1-1591 | Lb100 | 3592 | La-1-3248 | Lb100 |
| 3593 | La-1-1591 | Lb101 | 3594 | La-1-3249 | Lb101 |
| 3595 | La-1-1591 | Lb102 | 3596 | La-1-3250 | Lb102 |
| 3597 | La-1-1591 | Lb103 | 3598 | La-2-3276 | Lb103 |
| 3599 | La-1-1591 | Lb104 | 3600 | La-2-3277 | Lb104 |
| 3601 | La-1-1591 | Lb105 | 3602 | La-2-3278 | Lb105 |
| 3603 | La-1-1591 | Lb106 | 3604 | La-2-3279 | Lb106 |
| 3605 | La-1-1591 | Lb107 | 3606 | La-2-3280 | Lb107 |
| 3607 | La-1-1591 | Lb108 | 3608 | La-2-3281 | Lb108 |
| 3609 | La-1-1591 | Lb109 | 3610 | La-1-2803 | Lb109 |
| 3611 | La-1-1591 | Lb110 | 3612 | La-1-2804 | Lb110 |
| 3613 | La-1-1591 | Lb111 | 3614 | La-1-2805 | Lb111 |
| 3615 | La-1-1591 | Lb112 | 3616 | La-1-2806 | Lb112 |
| 3617 | La-1-1591 | Lb113 | 3618 | La-1-2807 | Lb113 |
| 3619 | La-1-1591 | Lb114 | 3620 | La-1-2808 | Lb114 |
| 3621 | La-1-1591 | Lb115 | 3622 | La-2-2701 | Lb115 |
| 3623 | La-1-1591 | Lb116 | 3624 | La-2-2702 | Lb116 |
| 3625 | La-1-1591 | Lb117 | 3626 | La-2-2703 | Lb117 |
| 3627 | La-1-1591 | Lb118 | 3628 | La-2-2704 | Lb118 |
| 3629 | La-1-1591 | Lb119 | 3630 | La-1-1591 | Lb144 |
| 3631 | La-1-1591 | Lb120 | 3632 | La-1-1591 | Lb145 |
| 3633 | La-1-1591 | Lb121 | 3634 | La-1-1591 | Lb146 |
| 3635 | La-1-1591 | Lb122 | 3636 | La-1-1591 | Lb147 |
| 3637 | La-1-1591 | Lb123 | 3638 | La-1-1591 | Lb148 |
| 3639 | La-1-1591 | Lb124 | 3640 | La-1-1591 | Lb149 |
| 3641 | La-1-1591 | Lb125 | 3642 | La-1-1591 | Lb150 |
| 3643 | La-1-1591 | Lb126 | 3644 | La-1-1591 | Lb151 |
| 3645 | La-1-1591 | Lb127 | 3646 | La-1-1591 | Lb152 |
| 3647 | La-1-1591 | Lb128 | 3648 | La-1-1591 | Lb153 |
| 3649 | La-1-1591 | Lb129 | 3650 | La-1-1591 | Lb154 |
| 3651 | La-1-1591 | Lb130 | 3652 | La-1-1591 | Lb155 |
| 3653 | La-1-1591 | Lb131 | 3654 | La-1-1591 | Lb156 |
| 3655 | La-1-1591 | Lb132 | 3656 | La-1-1591 | Lb157 |
| 3657 | La-1-1591 | Lb133 | 3658 | La-1-1591 | Lb158 |
| 3659 | La-1-1591 | Lb134 | 3660 | La-1-1591 | Lb159 |
| 3661 | La-1-1591 | Lb136 | 3662 | La-1-1591 | Lb160 |
| 3663 | La-1-1591 | Lb137 | 3664 | La-1-1591 | Lb161 |
| 3665 | La-1-1591 | Lb138 | 3666 | La-1-1591 | Lb162 |
| 3667 | La-1-1591 | Lb139 | 3668 | La-1-1591 | Lb163 |
| 3669 | La-1-1591 | Lb140 | 3670 | La-1-1591 | Lb164 |
| 3671 | La-1-1591 | Lb141 | 3672 | La-1-1591 | Lb165 |
| 3673 | La-1-1591 | Lb142 | 3674 | La-1-1591 | Lb166 |
| 3675 | La-1-1591 | Lb143 | 3676 | La-1-1591 | Lb167 |
| 3677 | La-1-4498 | Lb135 | 3678 | La-1-3773 | Lb135 |
| 3679 | La-1-4499 | Lb135 | 3680 | La-1-3774 | Lb135 |
| 3681 | La-1-4500 | Lb135 | 3682 | La-1-3775 | Lb135 |
| 3683 | La-1-4501 | Lb135 | 3684 | La-1-3776 | Lb135 |
| 3685 | La-2-4508 | Lb135 | 3686 | La-1-3777 | Lb135 |
| 3687 | La-2-4509 | Lb135 | 3688 | La-2-3804 | Lb135 |
| 3689 | La-2-4510 | Lb135 | 3690 | La-2-3805 | Lb135 |
| 3691 | La-2-4511 | Lb135 | 3692 | La-2-3806 | Lb135 |
| 3693 | La-2-4512 | Lb135 | 3694 | La-2-3807 | Lb135 |
| 3695 | La-1-4011 | Lb135 | 3696 | La-2-4019 | Lb135 |
| 3697 | La-1-4012 | Lb135 | 3698 | La-2-4020 | Lb135 |
| 3699 | La-1-4013 | Lb52 | 3700 | La-2-4021 | Lb52 |
| 3701 | La-1-4021 | Lb52 | 3702 | La-2-4041 | Lb52 |
| 3703 | La-1-4022 | Lb52 | 3704 | La-2-4042 | Lb52 |
| 3705 | La-1-4023 | Lb52 | 3706 | La-2-4043 | Lb52 |
| 3707 | La-1-4024 | Lb52 | 3708 | La-2-4044 | Lb52 |
| 3709 | La-1-4025 | Lb52 | 3710 | La-2-4045 | Lb52 |
| 3711 | La-1-4114 | Lb52 | 3712 | La-2-4046 | Lb52 |
| 3713 | La-1-4115 | Lb52 | 3714 | La-2-4151 | Lb52 |
| 3715 | La-1-4116 | Lb52 | 3716 | La-2-4152 | Lb52 |
| 3717 | La-1-4117 | Lb52 | 3718 | La-2-4153 | Lb52 |
| 3719 | La-1-4118 | Lb52 | 3720 | La-2-4154 | Lb52 |
| 3721 | La-1-4224 | Lb52 | 3722 | La-2-4155 | Lb52 |
| 3723 | La-1-4225 | Lb52 | 3724 | La-2-4156 | Lb52 |
| 3725 | La-1-4226 | Lb52 | 3726 | La-2-4257 | Lb52 |
| 3727 | La-1-4227 | Lb52 | 3728 | La-2-4258 | Lb52 |
| 3729 | La-1-4228 | Lb52 | 3730 | La-2-4259 | Lb52 |
| 3731 | La-1-4312 | Lb20 | 3732 | La-2-4260 | Lb1 |
| 3733 | La-1-4313 | Lb20 | 3734 | La-2-4360 | Lb1 |
| 3735 | La-1-4314 | Lb20 | 3736 | La-2-4361 | Lb1 |
| 3737 | La-1-4315 | Lb20 | 3738 | La-2-4362 | Lb1 |
| 3739 | La-1-4316 | Lb20 | 3740 | La-2-4363 | Lb1 |
| 3741 | La-1-4411 | Lb20 | 3742 | La-2-4465 | Lb1 |
| 3743 | La-1-4412 | Lb20 | 3744 | La-2-4466 | Lb1 |
| 3745 | La-1-4413 | Lb20 | 3746 | La-2-4467 | Lb1 |
| 3747 | La-1-4414 | Lb20 | 3748 | La-2-4560 | Lb1 |
| 3749 | La-1-4537 | Lb20 | 3750 | La-2-4561 | Lb1 |
| 3751 | La-1-4538 | Lb20 | 3752 | La-2-4562 | Lb1 |
| 3753 | La-1-4539 | Lb20 | 3754 | La-2-4563 | Lb1 |
| 3755 | La-1-4540 | Lb20 | 3756 | La-2-4564 | Lb1 |
| 3757 | La-1-4612 | Lb20 | 3758 | La-2-4565 | Lb1 |
| 3759 | La-1-4613 | Lb20 | 3760 | La-2-4640 | Lb1 |
| 3761 | La-1-4614 | Lb20 | 3762 | La-2-4641 | Lb1 |
| 3763 | La-1-4660 | Lb20 | 3764 | La-2-4642 | Lb1 |
| 3765 | La-1-4661 | Lb20 | 3766 | La-2-4643 | Lb1 |
| 3767 | La-1-4662 | Lb20 | 3768 | La-2-4768 | Lb1 |
| 3769 | La-1-4834 | Lb20 | 3770 | La-2-4769 | Lb1 |
| 3771 | La-1-4835 | Lb20 | 3772 | La-2-4770 | Lb1 |
| 3773 | La-1-4836 | Lb20 | 3774 | La-2-4771 | Lb1 |
| 3775 | La-1-4837 | Lb123 | 3776 | La-2-4772 | Lb129 |
| 3777 | La-1-4838 | Lb123 | 3778 | La-1-4966 | Lb129 |
| 3779 | La-2-4896 | Lb123 | 3780 | La-1-4967 | Lb129 |
| 3781 | La-2-4897 | Lb123 | 3782 | La-1-4968 | Lb129 |
| 3783 | La-2-4898 | Lb123 | 3784 | La-1-4969 | Lb129 |
| 3785 | La-2-4899 | Lb123 | 3786 | La-1-4970 | Lb129 |
| 3787 | La-2-5025 | Lb123 | 3788 | La-1-5072 | Lb129 |
| 3789 | La-2-5026 | Lb123 | 3790 | La-1-5073 | Lb129 |
| 3791 | La-2-5027 | Lb123 | 3792 | La-1-5074 | Lb129 |
| 3793 | La-2-5028 | Lb123 | 3794 | La-1-5075 | Lb129 |
| 3795 | La-2-5029 | Lb123 | 3796 | La-2-5080 | Lb129 |

Metal Complex 3797 to Metal Complex 3815 have the following structures. 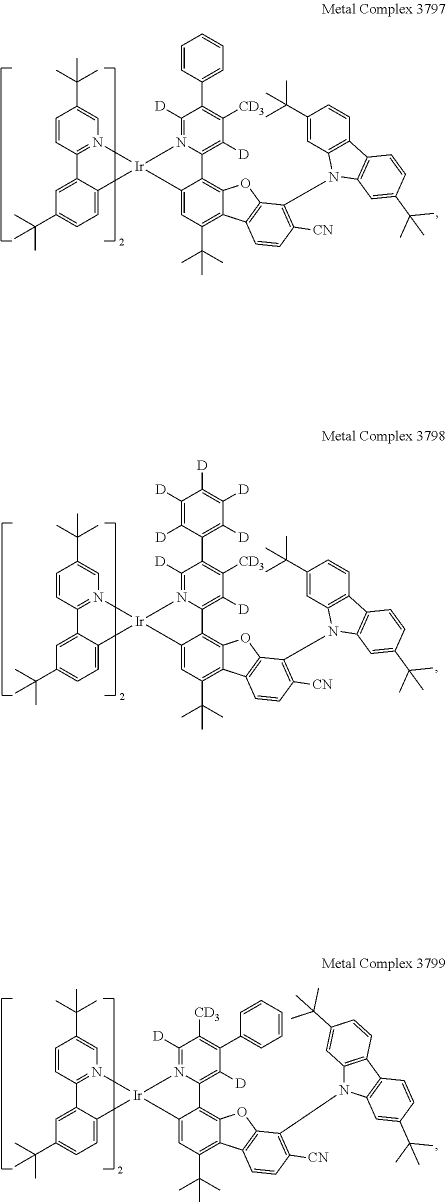 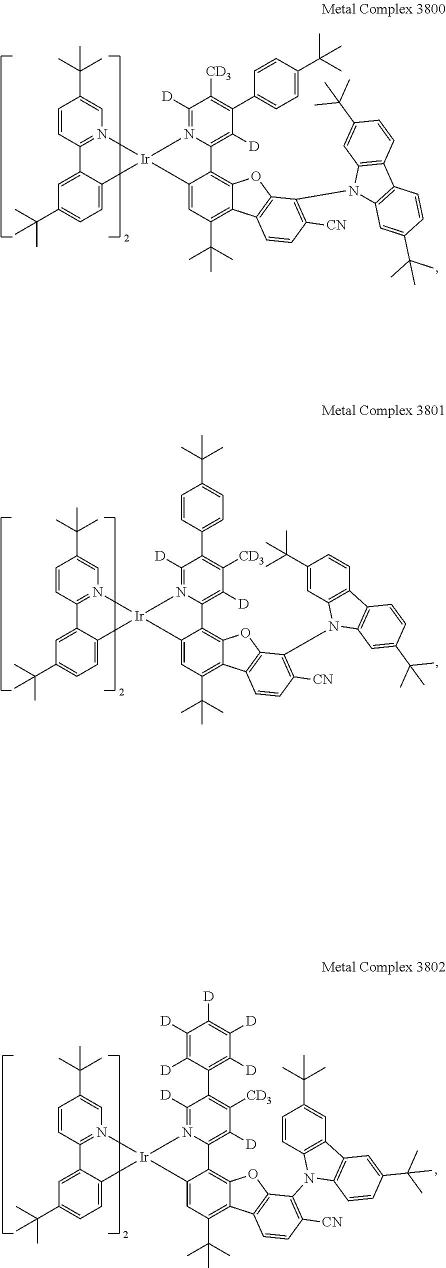 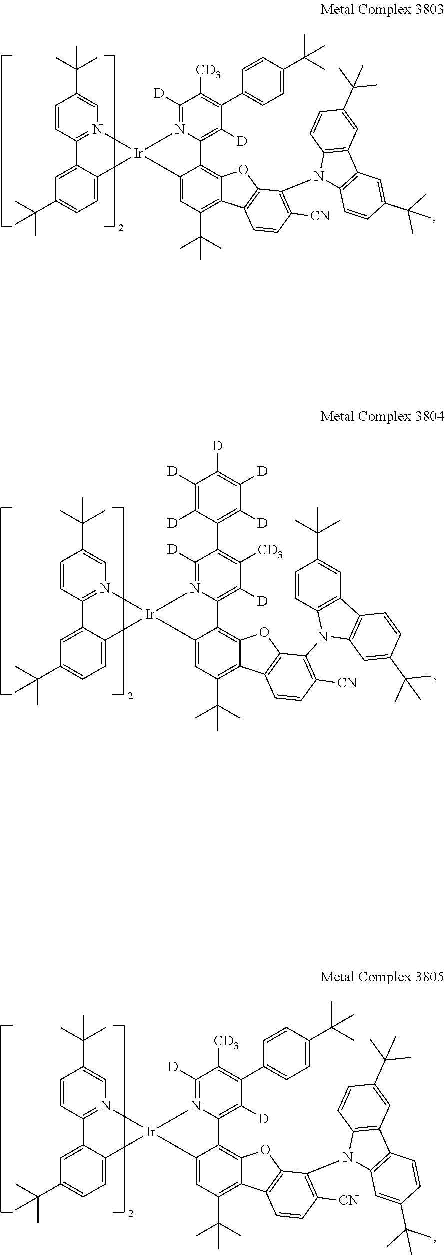 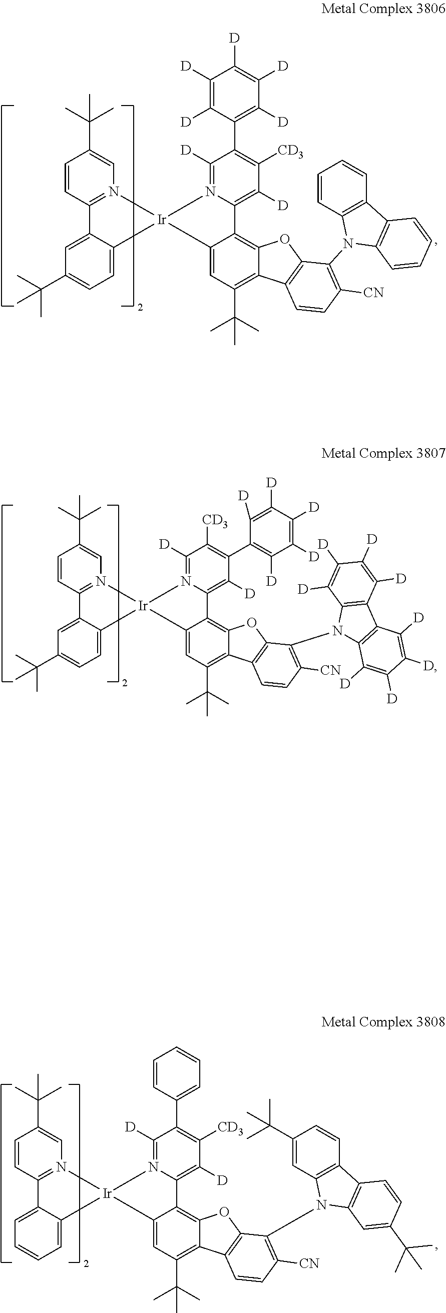 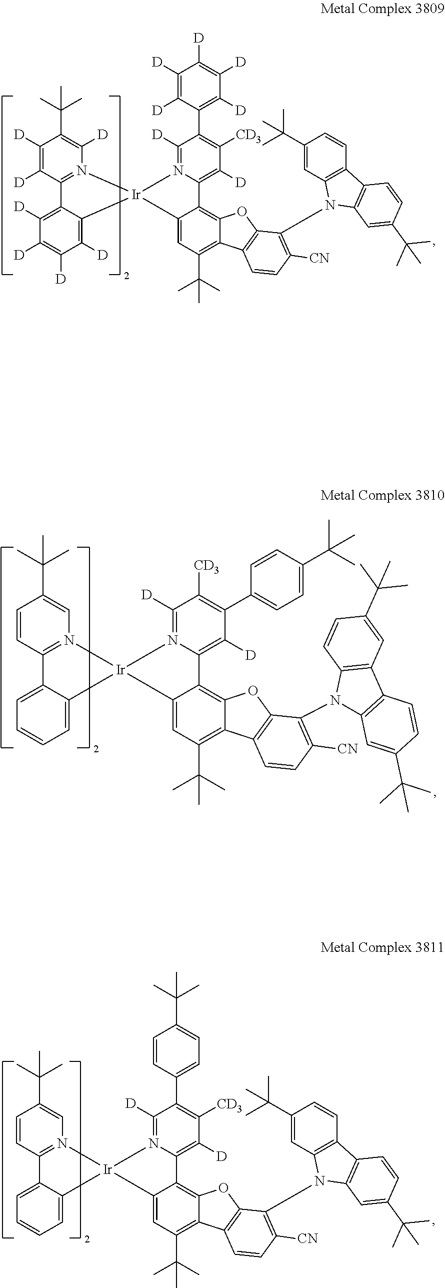 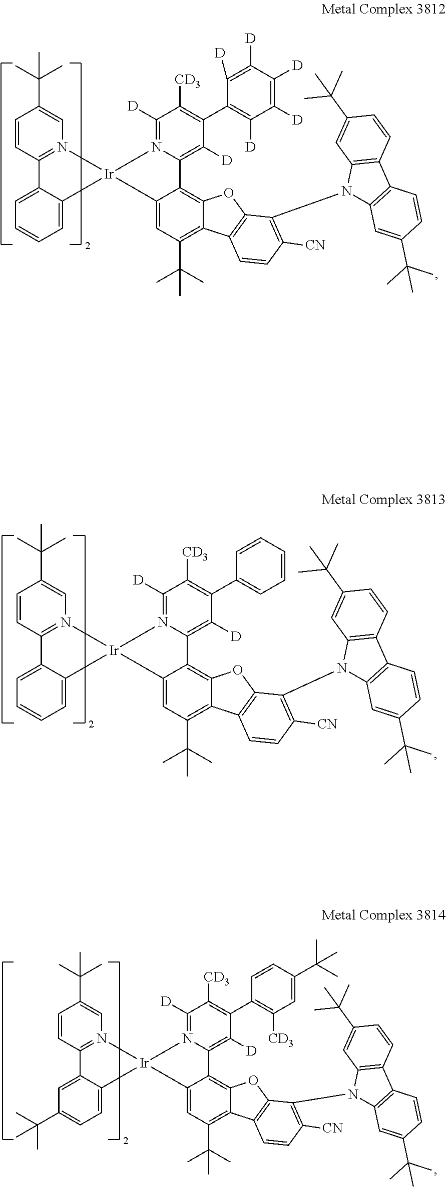 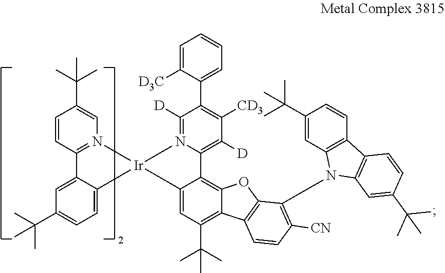
wherein optionally, hydrogen in Metal Complex 1 to Metal Complex 3815 can be partially or fully substituted with deuterium.

20. An electroluminescent device, comprising an anode, a cathode and an organic layer disposed between the anode and the cathode, wherein the organic layer comprises the metal complex according to claim 1.

21. The electroluminescent device according to claim 20, wherein the organic layer is a light-emitting layer, and the metal complex is a light-emitting material.

22. The electroluminescent device according to claim 21, wherein the light-emitting layer emits green light or white light.

23. The electroluminescent device according to claim 20, wherein the organic layer further comprises a host material.

24. The electroluminescent device according to claim 21, wherein the light-emitting layer comprises a first host compound;
preferably, the light-emitting layer further comprises a second host compound;
preferably, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

25. The electroluminescent device according to claim 24, wherein in the light-emitting layer, the metal complex is doped in the first host compound and the second host compound, and a weight of the metal complex accounts for 1% to 30% of a total weight of the light-emitting layer; and
preferably, the weight of the metal complex accounts for 3% to 13% of the total weight of the light-emitting layer.

26. A compound combination, comprising the metal complex according to claim 1.
